(19) United States
(12) Patent Application Publication
(10) Pub. No.: US 2024/0122071 A1
(43) Pub. Date: Apr. 11, 2024

(54) LIGHT EMITTING ELEMENT AND POLYCYCLIC COMPOUND FOR THE SAME, AND ELECTRONIC DEVICE

(71) Applicant: Samsung Display Co., Ltd., Yongin-si (KR)

(72) Inventors: MUN-KI SIM, Yongin-si (KR); Kyoung SUNWOO, Yongin-si (KR); SUN YOUNG PAK, Yongin-si (KR); JUNHA PARK, Yongin-si (KR); JANG YEOL BAEK, Yongin-si (KR); CHANSEOK OH, Yongin-si (KR)

(73) Assignee: Samsung Display Co., Ltd., Yongin-si (KR)

(21) Appl. No.: 18/348,682

(22) Filed: Jul. 7, 2023

(30) Foreign Application Priority Data
Aug. 26, 2022 (KR) 10-2022-0107962

(51) Int. Cl. H10K 85/60; C09K 11/06; H10K 50/12

(52) U.S. Cl. CPC H10K 85/658; C09K 11/06; H10K 50/12; H10K 85/615; H10K 85/653; H10K 85/654; H10K 85/655; C09K 2211/104

(57) ABSTRACT

Embodiments provide a light emitting element that includes a first electrode, a second electrode facing the first electrode, and an emission layer disposed between the first electrode and the second electrode, wherein the emission layer includes a polycyclic compound represented by Formula 1, which is explained in the specification:

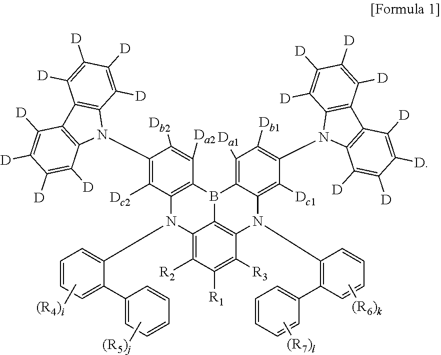

### CROSS-REFERENCE TO RELATED APPLICATION(S)

This application claims priority to and benefits of Korean Patent Application No. 10-2022-0107962 under 35 U.S.C. § 119, filed on Aug. 26, 2022, in the Korean Intellectual Property Office, the entire contents of which are incorporated herein by reference.

### BACKGROUND

### 1. Technical Field

The disclosure relates to a polycyclic compound, a light emitting element including the same, and an electronic device including the light emitting element.

### 2. Description of the Related Art

Active development continues for an organic electroluminescence display device as an image display device. The organic electroluminescence display device includes a so-called self-luminescent light emitting element in which holes and electrons respectively injected from a first electrode and a second electrode recombine in an emission layer, so that a luminescent material in the emission layer emits light to achieve display.

In the application of a light emitting element to a display device, there is a demand for a light emitting element having low driving voltage, high luminous efficiency, and a long service life, and continuous development is required on materials for a light emitting element that are capable of stably attaining such characteristics.

In order to implement a highly efficient organic electroluminescence device, technologies pertaining to phosphorescence emission using triplet state energy or to delayed fluorescence using triplet-triplet annihilation (TTA) in which singlet excitons are generated by collision of triplet excitons are being developed, and development is currently directed to thermally activated delayed fluorescence (TADF) materials using delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having improved service life.

The disclosure also provides a polycyclic compound that is capable of improving service life of a light emitting element.

The disclosure also provides an electronic device including a light emitting element having improved service life.

An embodiment provides a light emitting element which may include a first electrode, a second electrode disposed on the first electrode, and an emission layer disposed between the first electrode and the second electrode, wherein the emission layer may include: a first compound represented by Formula 1; and at least one of a second compound represented by Formula HT, a third compound represented by Formula ET, or a fourth compound represented by Formula M-b:

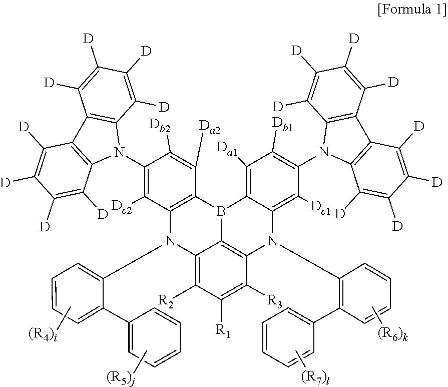

In Formula 1, D, Dₐ₁, and Dₐ₂ may each be a deuterium atom, and D_{b1}, D_{b2}, D_{c1}, and D_{c2} may each independently be a hydrogen atom or a deuterium atom. In Formula 1, R₁ to R₃ may each independently be a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms. In Formula 1, R₄ to R₇ may each independently be a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring; i and k may each independently be an integer from 0 to 4; and j and l may each independently be an integer from 0 to 5.

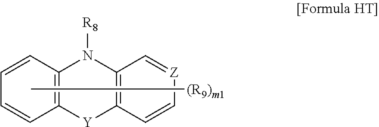

In Formula HT, m1 may be an integer from 0 to 8; R₈ and R₉ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; Y may be a direct linkage, C(R_{y1})(R_{y2}), or Si(R_{y3})(R_{y4}); Z may be C(R_{z}) or N; R_{y1} to R_{y4} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; and R_{z} may be a hydrogen atom or a deuterium atom.

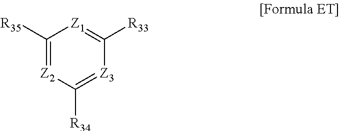

In Formula ET, Z₁ to Z₃ may each independently be N or C(R₃₆); and at least one of Z₁ to Z₃ may each be N. In Formula ET, R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring.

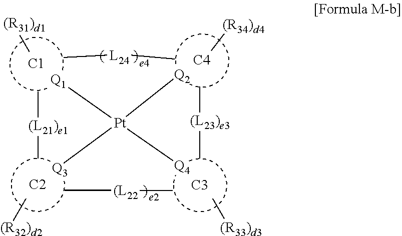

In Formula M-b, Q1 to Q4 may each independently be C or N; C1 to C4 may each independently be a substituted or unsubstituted hydrocarbon ring group having 5 to 30 ring-forming carbon atoms or a substituted or unsubstituted heterocyclic group having 2 to 30 ring-forming carbon atoms; e1 to e4 may each independently be 0 or 1; L₂₁ to L₂₄ may each independently be a direct linkage,

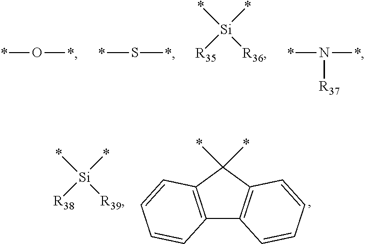

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; and d1 to d4 may each independently be an integer from 0 to 4. In Formula M-b R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In an embodiment, the first compound represented by Formula 1 may be represented by Formula 1-1, which is explained below.

In an embodiment, the first compound represented by Formula 1 may be represented by Formula 2, which is explained below.

In an embodiment, the first compound represented by Formula 1 may be represented by Formula 3, which is explained below.

In an embodiment, the first compound represented by Formula 1 may be represented by Formula 4-1 or Formula 4-2, which are explained below.

In an embodiment, the first compound represented by Formula 4-1 may be represented by Formula 4-1a, which is explained below.

In an embodiment, R₁ to R₃ may each independently be a hydrogen atom, a deuterium atom, a substituted or unsubstituted t-butyl group, a substituted or unsubstituted phenyl group, a substituted or unsubstituted dibenzofuran group, or a substituted or unsubstituted carbazole group.

In an embodiment, R₄ to R₇ may each independently be a hydrogen atom, a deuterium atom, a substituted or unsubstituted t-butyl group, or a substituted or unsubstituted phenyl group, or may be bonded to an adjacent group to form a ring.

In an embodiment, the emission layer may include the first compound, the second compound, and the third compound.

In an embodiment, the emission layer may include the first compound, the second compound, the third compound, and the fourth compound.

In an embodiment, the first compound represented by Formula 1 may include at least one compound selected from Compound Group 1, which is explained below.

Embodiments provide a light emitting element which may include a first electrode, a second electrode disposed on the first electrode, and at least one functional layer disposed between the first electrode and the second electrode, wherein the at least one functional layer includes a polycyclic compound represented by Formula 1, which is explained herein.

In an embodiment, the at least one functional layer may include a hole transport region disposed on the first electrode, an emission layer disposed on the hole transport region, and an electron transport region disposed on the emission layer; and the emission layer may include the polycyclic compound.

In an embodiment, the emission layer may emit delayed fluorescence.

In an embodiment, the emission layer may include a host and a dopant, and the dopant may include the polycyclic compound.

In an embodiment, the at least one functional layer may further include a polycyclic compound represented by Formula 3, which is explained below.

Embodiments provide a polycyclic compound which may be represented by Formula 1, which is explained herein.

In an embodiment, Formula 1 may be represented by Formula 2, which is explained below.

In an embodiment, Formula 1 may be represented by Formula 3, which is explained below.

In an embodiment, Formula 1 may be represented by Formula 4-1 or Formula 4-2, which are explained below.

In an embodiment, Formula 4-1 may be represented by Formula 4-1a, which is explained below.

In an embodiment, R₁ to R₃ may each independently be a hydrogen atom, a deuterium atom, a substituted or unsubstituted t-butyl group, a substituted or unsubstituted phenyl group, a substituted or unsubstituted dibenzofuran group, or a substituted or unsubstituted carbazole group.

In an embodiment, R₄ to R₇ may each independently be a hydrogen atom, a deuterium atom, a substituted or unsubstituted t-butyl group, or a substituted or unsubstituted phenyl group, or may be bonded to an adjacent group to form a ring.

In an embodiment, the polycyclic compound represented by Formula 1 may be selected from Compound Group 1, which is explained below.

Embodiments provide an electronic device which may include a display device including light emitting elements, wherein each of the light emitting elements may include a first electrode, a hole transport region disposed on an upper portion of the first electrode, an emission layer disposed on an upper portion of the hole transport region, an electron transport region disposed on an upper portion of the emission layer, and a second electrode disposed on an upper portion of the electron transport region, and the emission layer may include a polycyclic compound represented by Formula 1, which is explained herein.

In an embodiment, the electronic device maybe a vehicle, a television, a game console, a tablet, a smart phone, a camera, a laptop computer, a personal computer, a personal digital terminal, or an advertising board.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic perspective view of an electronic device including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is unsubstituted or substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not specifically limited, but may be 2 to 30, 2 to 20, or 2 to 10. Examples of an alkenyl group may include a vinyl group, a 1-butenyl group, a 1-pentenyl group, a 1,3-butadienyl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. Although the number of carbon atoms in an alkynyl group is not specifically limited, it may be 2 to 30, 2 to 20, or 2 to 10. Examples of an alkynyl group may include an ethynyl group, a propynyl group, etc., without limitation.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of substituted fluorenyl groups are as follows. However, embodiments are not limited thereto.

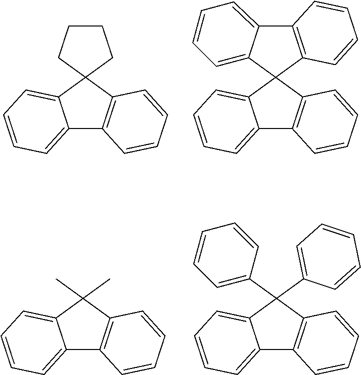

In the specification, a heterocyclic group may be any functional group or substituent derived from a ring that includes at least one of B, O, N, P, Si, or Se as a heteroatom. A heterocyclic group may be an aliphatic heterocyclic group or an aromatic heterocyclic group. An aromatic heterocyclic group may be a heteroaryl group. An aliphatic heterocycle and an aromatic heterocycle may each independently be monocyclic or polycyclic. If a heterocyclic group includes two or more heteroatoms, the two or more heteroatoms may be the same as or different from each other.

In the specification, an aliphatic heterocyclic group may include at least one of B, O, N, P, Si, or S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, or S as a heteroatom. When a heteroaryl group contains two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that the arylene group is a divalent group. The above description of a heteroaryl group may be applied to a heteroarylene group, except that the heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in an amino group is not specifically limited, but may be 1 to 30. An amino group may be an alkyl amino group, an aryl amino group, or a heteroaryl amino group. Examples of an amino group may include a methylamino group, a dimethylamino group, a phenylamino group, a diphenylamino group, a naphthylamino group, a 9-methyl-anthracenylamino group, etc., but embodiments are not limited thereto.

In the specification, the number of carbon atoms in a carbonyl group is not specifically limited, but may be 1 to 40, 1 to 30, or 1 to 20. For example, a carbonyl group may have one of the following structures, but embodiments are not limited thereto.

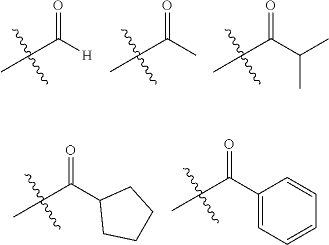

In the specification, the number of carbon atoms in a sulfinyl group or a sulfonyl group is not particularly limited, but may each independently be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not specifically limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not specifically limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the specification, an alkyl group in an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group in an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

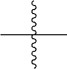

and -* each represent a bonding site to a neighboring atom.

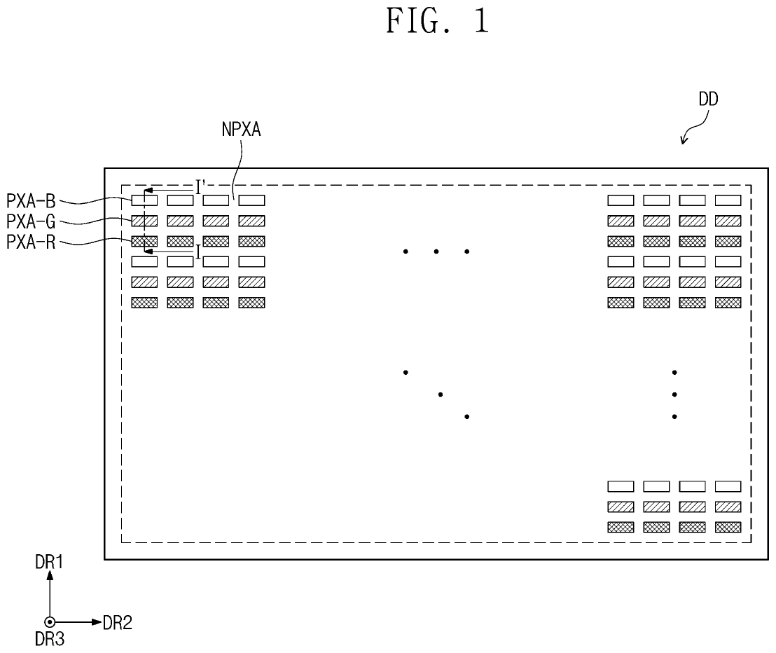

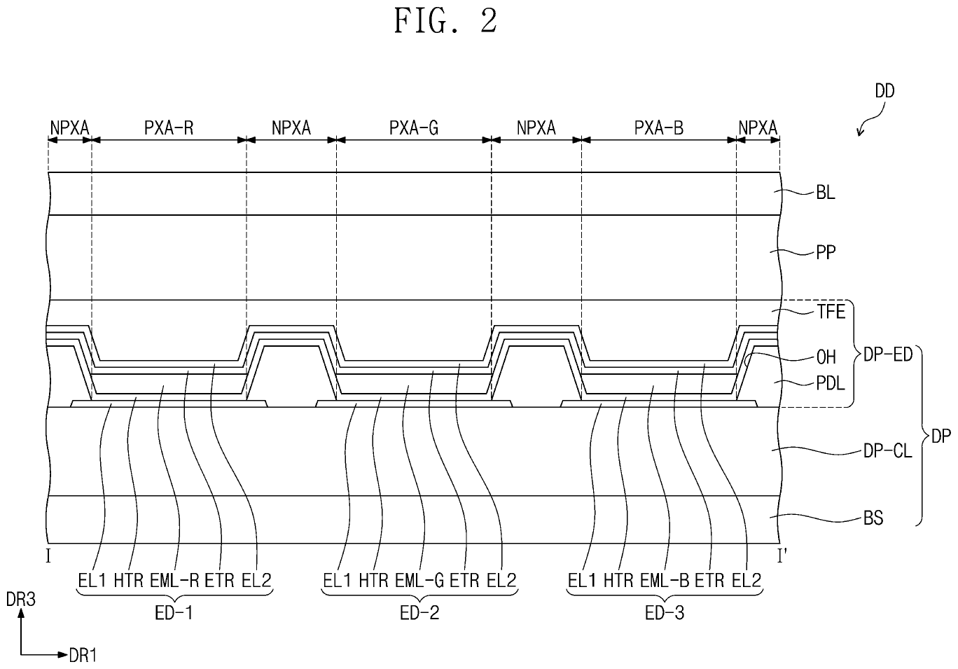

FIG. 1 is a schematic plan view of an embodiment of a display device DD. FIG. 2 is a schematic cross-sectional view of a display device DD according to an embodiment. FIG. 2 is a schematic cross-sectional view illustrating a part taken along line I-I′ of FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP and may control light reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

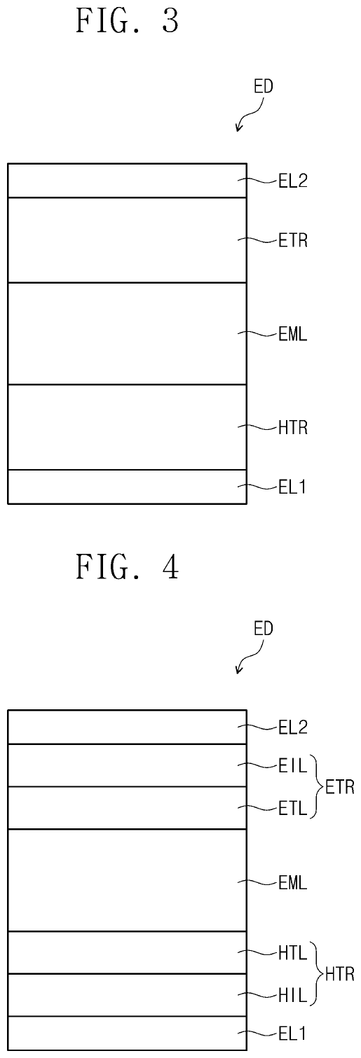

The light emitting elements ED-1, ED-2, and ED-3 may each have a structure of alight emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for all of the light emitting elements ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed of a single layer or formed of multiple layers. The encapsulation layer TFE may include at least one insulation layer. In an embodiment, the encapsulation layer TFE may include at least one inorganic film (hereinafter, an encapsulation-inorganic film). In another embodiment, the encapsulation layer TFE may include at least one organic film (hereinafter, an encapsulation-organic film) and at least one encapsulation-inorganic film.

The encapsulation-inorganic film may protect the display element layer DP-ED from moisture and/or oxygen, and the encapsulation-organic film may protect the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region which emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting regions NPXA may be areas between adjacent light emitting regions PXA-R, PXA-G, and PXA-B, which may correspond to the pixel defining film PDL. For example, in an embodiment, the light emitting regions PXA-R, PXA-G, and PXA-B may each respectively correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light are illustrated. For example, the display device DD may include a red light emitting region PXA-R, a green light emitting region PXA-G, and a blue light emitting region PXA-B, which are separated from each other.

In the display device DD according to an embodiment, the light emitting elements ED-1, ED-2, and ED-3 may emit light having different wavelengths from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may each emit light in a same wavelength range or at least one light emitting element may emit a light in a wavelength range that is different from the others. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be arranged along a second directional axis DR2. In another embodiment, the red light emitting region PXA-R, the green light emitting region PXA-G, and the blue light emitting region PXA-B may be alternately arranged in this order along a first directional axis DR1.

FIGS. 1 and 2 illustrate that the light emitting regions PXA-R, PXA-G, and PXA-B each have a similar area, but embodiments are not limited thereto. Thus, the light emitting regions PXA-R, PXA-G, and PXA-B may have different areas from each other according to a wavelength range of emitted light. For example, the areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required for the display device DD. For example, the light emitting regions PXA-R, PXA-G, and PXA-B may arranged in a pentile configuration (such as a PENTILE® configuration) or in a diamond configuration (such as a Diamond Pixel® configuration).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

In the display device DD according to an embodiment illustrated in FIG. 2, at least one of the first to third light emitting elements ED-1, ED-2, and ED-3 may include a polycyclic compound according to an embodiment, which will be described below.

Hereinafter, FIGS. 3 to 6 are each a schematic cross-sectional view of a light emitting element according to an embodiment. The light emitting elements ED according to embodiments may each include a first electrode EL1, a second electrode EL2 facing the first electrode EL1, and at least one functional layer disposed between the first electrode EL1 and the second electrode EL2. The light emitting element ED according to an embodiment may include a polycyclic compound, which will be described below, in the at least one functional layer. In the specification, the polycyclic compound according to an embodiment may be referred to as a first compound.

The light emitting element ED may include, as the at least one functional layer, a hole transport region HTR, an emission layer EML, and an electron transport region ETR, which are stacked in that order. Referring to FIG. 3, a light emitting element ED may include a first electrode EL1, a hole transport region HTR, an emission layer EML, an electron transport region ETR, and a second electrode EL2, which are stacked in that order. The light emitting element ED may include a polycyclic compound according to an embodiment, which will be described below, in the emission layer EML.

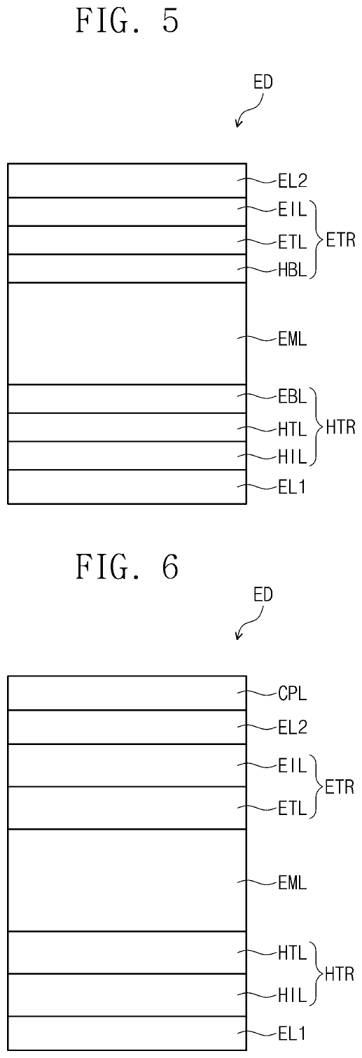

In comparison to FIG. 3, FIG. 4 shows a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison FIG. 3, FIG. 5 shows a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 shows a schematic cross-sectional view of a light emitting element ED according to an embodiment that includes a capping layer CPL disposed on a second electrode EL2.

In the light emitting element ED, the first electrode EL1 has conductivity. The first electrode EL1 may be formed of a metal material, a metal alloy, or a conductive compound.

The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective layer or a transflective layer formed of the above-described materials, and a transparent conductive layer formed of ITO, IZO, ZnO, ITZO, etc. For example, the first electrode EL1 may have a three-layer structure of ITO/Ag/ITO, but embodiments are not limited thereto. The first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may be a layer consisting of a single material, a layer including different materials, or a structure including multiple layers including different materials.

The hole transport region HTR may include at least one of a hole injection layer HIL, a hole transport layer HTL, a buffer layer (not shown), an emission-auxiliary layer (not shown), or an electron blocking layer EBL. Although not shown in the drawings, in an embodiment, the hole transport region HTR may include multiple hole transport layers.

In other embodiments, the hole transport region HTR may have a single layer structure of a hole injection layer HIL or a hole transport layer HTL, or may have a single layer structure formed of a hole injection material and a hole transport material. In an embodiment, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), or a hole transport layer HTL/buffer layer (not shown) are stacked in its respective stated order from the first electrode EL1, but embodiments are not limited thereto.

A thickness of the hole transport region HTR may be, for example, in a range of about 50 Å to about 15,000 Å. The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

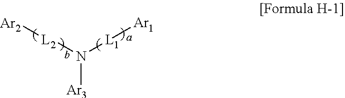

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups and multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent.

In still other embodiments, the compound represented by Formula H-1 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-1 may be any compound selected from Compound Group H. However, the compounds listed in Compound Group H are only examples, and the compound represented by Formula H-1 is not limited Compound Group H:

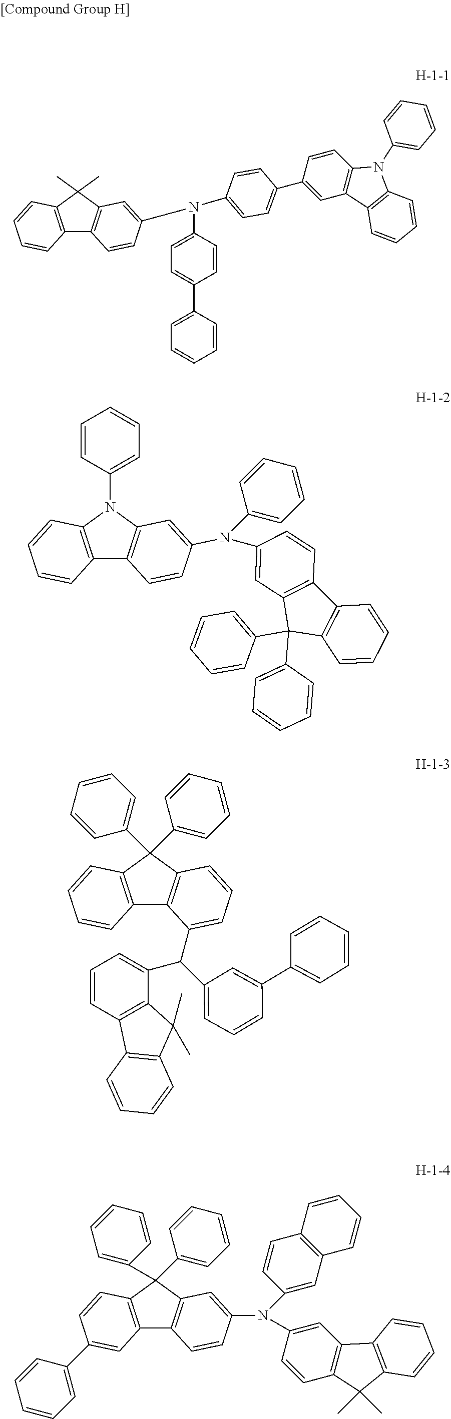

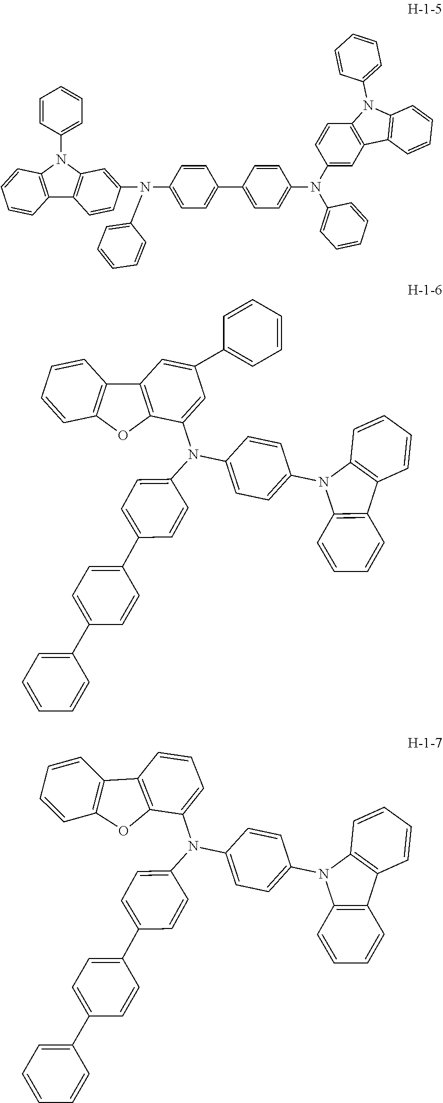 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-n5c6ccccc6c6ccccc65)cc4)c4cccc5c4oc4ccccc45)cc3)cc2)cc1]

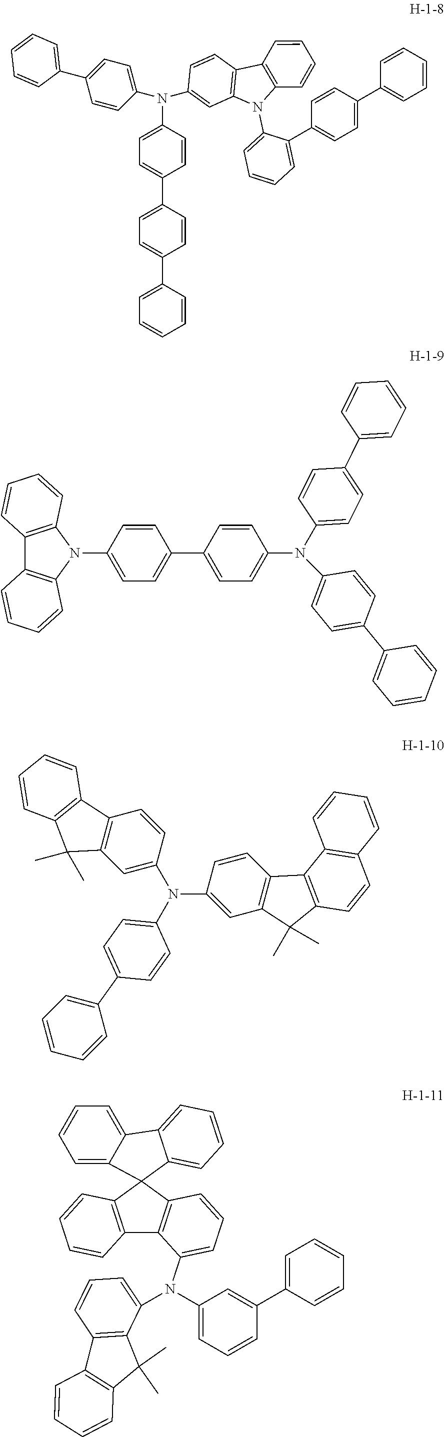 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21]

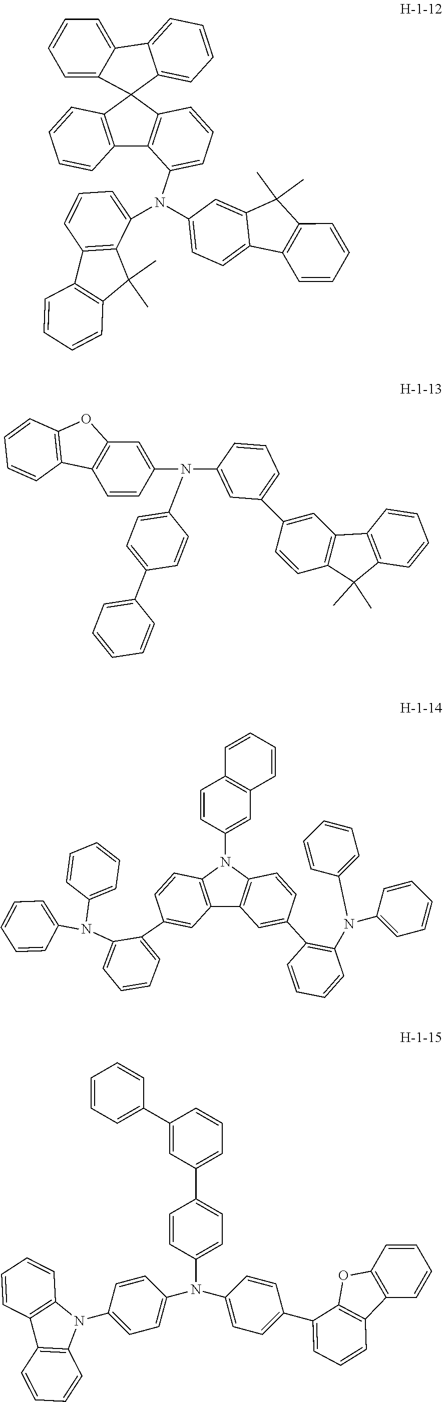 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

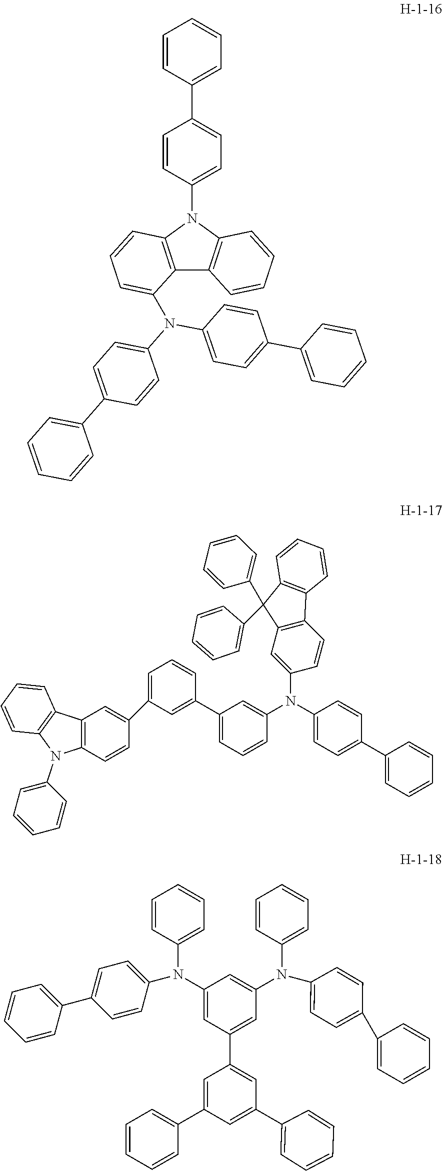 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

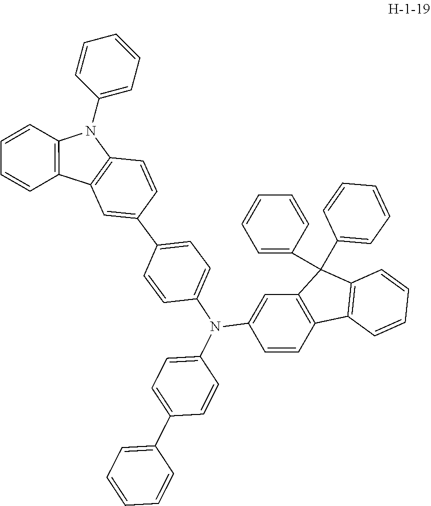 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may further include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(1-naphthyl)-N-phenylamino]-triphenylamine (1-TNATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB or NPD or α-NPD), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenyl amine-based derivative such as 4,4′,4″-tris(N-carbazolyl)triphenylamine (TCTA), or N,N′-bis(3-methylphenyl)-N,N′-diphenyl-[1,1′-biphenyl]-4,4′-diamine (TPD), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have, for example, a thickness in a range of about 30 Å to about 1,000 Å. When the hole transport region HTR includes a hole transport layer HTL, the hole transport layer HTL may have a thickness in a range of about 30 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown), an emission-auxiliary layer (not shown), or an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material included in the buffer layer (not shown). The electron blocking layer EBL may prevent the injection of electrons from an electron transport region ETR to a hole transport region HTR. The emission-auxiliary layer (not shown) may improve charge balance between holes and electrons. When the hole transport region HTR includes an electron blocking layer EBL, the electron blocking layer EBL may include the function of the emission-auxiliary layer.

The emission layer EML is provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

In the light emitting element ED according to an embodiment, the emission layer EML may include a first compound. The first compound may include a polycyclic compound according to an embodiment. The polycyclic compound may include a fused ring core that includes a boron atom (B) and two nitrogen atoms (N) as ring-forming atoms. In the polycyclic compound, the fused ring core may have a structure in which first to third aromatic rings are fused with a boron atom and two nitrogen atoms. The first aromatic ring and the second aromatic ring may be symmetric to each other with respect to the boron atom in the fused ring core. The third aromatic ring may be bonded to each of the boron atom and the two nitrogen atoms in the fused ring core.

In the polycyclic compound, deuterium atoms and a substituent containing deuterium atoms may be linked to the first aromatic ring and the second aromatic ring of the fused ring core. The substituent containing deuterium atoms may be a carbazole group substituted with deuterium atoms, and may be linked at a para-position to the boron atom of the fused ring core.

In the polycyclic compound, the fused ring core to which deuterium atoms and substituents containing deuterium atoms are linked to the first aromatic ring and the second aromatic ring may have a structure as shown in Formula A. In Formula A, D may be a deuterium atom, and each of Dₐ, D_{b}, and D_{c} may be positions which may be substituted with deuterium atoms. For convenience of description, substituents that are linked to remaining positions other than the positions at which deuterium atoms and substituents containing deuterium atoms may be linked are omitted from Formula A.

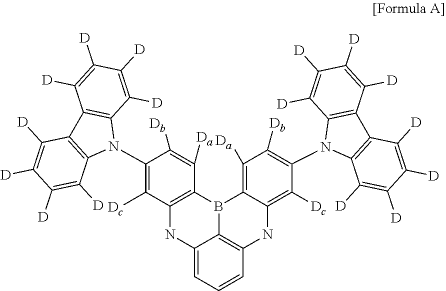

In an embodiment, a deuteration rate of the two Dₐ groups may be in a range of about 30% to about 100%. For example, the deuteration rate of the two Dₐ groups may be equal to or greater than about 60%. For example, the deuteration rate of the two Dₐ groups may be equal to or greater than about 70%. For example, the deuteration rate of the two Dₐ groups may be about 100%. In an embodiment, Dₐ in Formula A may have a deuteration rate of about 100%. Thus, in Formula A, Dₐ may each be a deuterium atom. However, embodiments are not limited thereto, and the Dₐ groups in Formula A may be not substituted with a deuterium atom and may each be a hydrogen atom.

In an embodiment, the deuteration rate of the two D_{b} groups and the two De groups may each independently be in a range of about 0% to about 100%. For example, two D_{b} groups may each independently be deuterated at a rate of about 100% or may not be substituted with deuterium atoms. For example, two De groups may each independently be deuterated at a rate of about 100% or may not be substituted with deuterium atoms. For example, in Formula A, D_{b} and D_{c} may each independently be a hydrogen atom or a deuterium atom. Two D_{b} groups may be the same as or different from each other, and two De groups may be the same as or different from each other.

In the specification, a “deuteration rate” of a substituent is expressed as a percentage rate at which deuterium atoms are substituted in place of a hydrogen atom for that substituent. The deuteration rate may be, for example, measured using a nuclear magnetic resonance spectroscope (¹H-NMR). For example, when a “deuteration rate” is analyzed with the nuclear magnetic resonance spectroscope (¹H-NMR), the deuteration rate (for example, a deuterium substitution rate) may be calculated from an integrated quantity of total peaks through the integration ratio in ¹H-NMR.

The light emitting element ED may include a polycyclic compound represented by Formula 1 as a first compound in the emission layer EML. Formula 1 represents a case wherein in Formula A, both Dₐ groups are deuterium atoms in the fused ring core. The polycyclic compound represented by Formula 1 includes deuterium atoms at each of the two positions indicated by Dₐ (referring to Formula A) having lowest electron density in the molecule, so that molecular structure may be stabilized, and thus the polycyclic compound may contribute to an improvement in service life of the light emitting element ED.

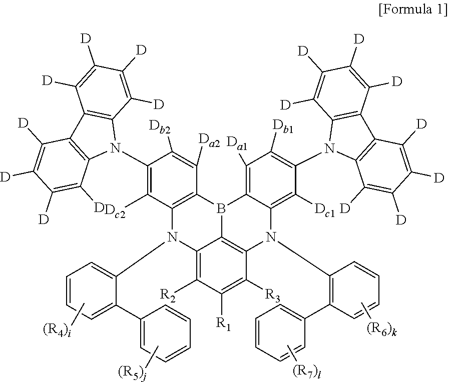

In Formula 1, D, Dₐ₁, and Dₐ₂ may each be a deuterium atom. In Formula 1, D_{b1}, D_{b2}, D_{c1}, and D_{c2} may each independently be a hydrogen atom or a deuterium atom. In Formula 1, the benzene ring to which Dₐ₁, D_{b1}, and D_{c1} are bonded may correspond to the above-described first aromatic ring, and the benzene ring to which Dₐ₂, D_{b2}, and D_{c2} are bonded may correspond to the above-described second aromatic ring.

In Formula 1, R₁ to R₃ may each independently be a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms. In an embodiment, R₁ to R₃ may each independently be a hydrogen atom, a deuterium atom, a substituted or unsubstituted alkyl group having 1 to 10 carbon atoms, a substituted or unsubstituted aryl group having 6 to 15 ring-forming carbon atoms, or a substituted or unsubstituted heteroaryl group having 2 to 15 ring-forming carbon atoms. In an embodiment, R₁ to R₃ may each independently be a hydrogen atom, a deuterium atom, a substituted or unsubstituted t-butyl group, a substituted or unsubstituted phenyl group, a substituted or unsubstituted dibenzofuran group, or a substituted or unsubstituted carbazole group. When each of R₁ to R₃ is substituted, each of R₁ to R₃ may itself be substituted with a deuterium atom, a t-butyl group, a phenyl group, etc., but embodiments are not limited thereto. In Formula 1, the benzene ring to which R₁ to R₃ are bonded may correspond to the above-described third aromatic ring.

In Formula 1, R₄ to R₇ may each independently be a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. In an embodiment, R₄ to R₇ may each independently be a hydrogen atom, a deuterium atom, a substituted or unsubstituted alkyl group having 1 to 10 carbon atoms, a substituted or unsubstituted aryl group having 6 to 15 ring-forming carbon atoms, or a substituted or unsubstituted heteroaryl group having 2 to 15 ring-forming carbon atoms.

In an embodiment, R₄ to R₇ may each independently be a hydrogen atom, a deuterium atom, a substituted or unsubstituted t-butyl group, or a substituted or unsubstituted phenyl group, or may be bonded to an adjacent group to form a ring. For example, R₄ and R₅ may be bonded to each other to form a ring, or R₆ and R₇ may be bonded to each other to form a ring. For example, R₄ and R₅ may be bonded to each other to form a substituted or unsubstituted dibenzofuran group, a substituted or unsubstituted dibenzothiophene group, a substituted or unsubstituted carbazole group, or a substituted or unsubstituted fluorenyl group. For example, R₆ and R₇ may be bonded to each other to form a substituted or unsubstituted dibenzofuran group, a substituted or unsubstituted dibenzothiophene group, a substituted or unsubstituted carbazole group, or a substituted or unsubstituted fluorenyl group.

In Formula 1, i and k may each independently be an integer from 0 to 4; and j and l may each independently be an integer from 0 to 5. For example, i and k may each independently be 0, 1, 2, or 4. For example, j and l may each independently be 0, 1, or 5. When i to 1 are each 2 or more, multiple groups of each of R₄, R₅, R₆, and R₇ may be the same or at least one thereof may be different from the rest.

A case where i is 0 may be the same as a case where i is 4 and R₄ groups are all hydrogen atoms. It may be understood that when i is 0, the polycyclic compound represented by Formula 1 does not include R₄ as a substituent. A case where j is 0 may be the same as a case where j is 5 and R₅ groups are all hydrogen atoms. It may be understood that when j is 0, the polycyclic compound represented by Formula 1 does not include R₅ as a substituent. A case where k is 0 may be the same as a case where k is 4 and R₆ groups are all hydrogen atoms. It may be understood that when k is 0, the polycyclic compound represented by Formula 1 does not include R₆ as a substituent. A case where 1 is 0 may be the same as a case where 1 is 5 and R₇ groups are all hydrogen atoms. It may be understood that when j is 0, the polycyclic compound represented by Formula 1 does not include R₇ as a substituent.

In an embodiment, the polycyclic compound represented by Formula 1 may be represented by Formula 1-1. The polycyclic compound represented by Formula 1-1 corresponds to a case wherein in Formula 1, Dₐ₁, Dₐ₂, D_{b1}, D_{b2}, D_{c1}, and D_{c2} are all deuterium atoms.

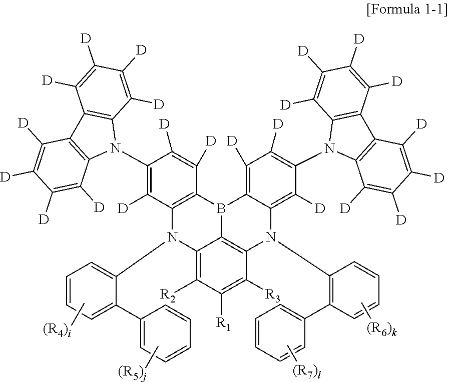

In Formula 1-1, D, R₁ to R₇, and i to 1 are the same as described in Formula 1.

In an embodiment, the polycyclic compound represented by Formula 1 may be represented by Formula 2. Formula 2 represents a case wherein in Formula 1, a substituent bonded to the third aromatic ring is further defined. Formula 2 represents a structure in which R₁ is a substituent of the third aromatic ring of the polycyclic compound represented by Formula 1.

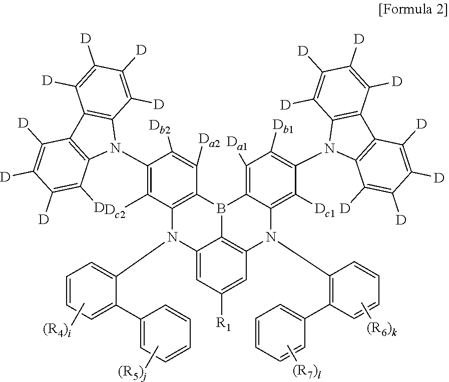

In Formula 2, D, Dₐ₁, Dₐ₂, D_{b1}, D_{b2}, D_{c1}, D_{c2}, R₁, R₄ to R₇, and i to 1 are the same as described in Formula 1.

In an embodiment, the polycyclic compound represented by Formula 1 may be represented by Formula 3. Formula 3 corresponds to a case where substituents R₄ and R₆ are further defined in Formula 1. Formula 3 illustrates a structure in which an R₄ group and an R₆ group are respectively bonded at an ortho-position to a nitrogen atom of the fused ring core of Formula 1. In Formula 3, R₁, D, Dₐ₁, Dₐ₂, D_{b1}, D_{b2}, D_{c1}, and D_{c2} are the same as described in Formula 1.

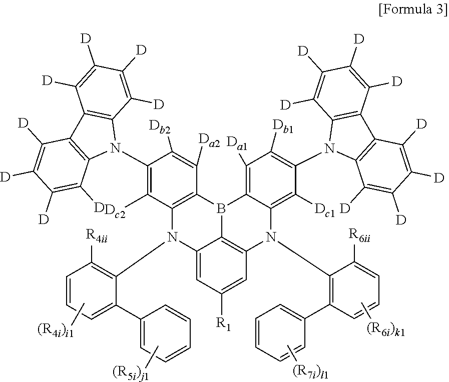

In Formula 3, R₄ᵢ, R₅ᵢ, R₆ᵢ, and R₇ᵢ may each independently be a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. In an embodiment, R₄ᵢ, R₅ᵢ, R₆ᵢ, and R₇ᵢ may each independently be a hydrogen atom, a deuterium atom, a substituted or unsubstituted alkyl group having 1 to 10 carbon atoms, a substituted or unsubstituted aryl group having 6 to 15 ring-forming carbon atoms, or a substituted or unsubstituted heteroaryl group having 2 to 15 ring-forming carbon atoms. For example, R₄ᵢ, R₅ᵢ, R₆ᵢ, and R₇ᵢ may each independently be a hydrogen atom, a deuterium atom, a substituted or unsubstituted t-butyl group, or a substituted or unsubstituted phenyl group. In another embodiment, R₄ᵢ, R₅ᵢ, R₆ᵢ, and R₇ᵢ may each be bonded to an adjacent group to form a ring. For example, R₄ᵢ and R₅ᵢ may be bonded to each other to form a ring, and R₆ᵢ and R₇ᵢ may be bonded to each other to form a ring. For example, R₄ᵢ and R₅ᵢ may be bonded to each other to form a substituted or unsubstituted dibenzofuran group, a substituted or unsubstituted dibenzothiophene group, a substituted or unsubstituted carbazole group, or a substituted or unsubstituted fluorenyl group. For example, R₆ᵢ and R₇ᵢ may be bonded to each other to form a substituted or unsubstituted dibenzofuran group, a substituted or unsubstituted dibenzothiophene group, a substituted or unsubstituted carbazole group, or a substituted or unsubstituted fluorenyl group.

In Formula 3, i1 and k1 may each independently be an integer from 0 to 3; and j1 and 11 may each independently be an integer from 0 to 5. For example, i and k may each independently be 1, 2 or 3. For example, j and l may each independently be 0, 1, or 5. When I1 to I1 are each 2 or more, multiple groups of each of R₄ᵢ, R₅ᵢ, R₆ᵢ, and R₇ᵢ may be the same as each other, or at least one thereof may be different from the rest.

A case where i1 is 0 may be a same as the case where i1 is 3 and R₄ᵢ groups are all hydrogen atoms. It may be understood that when i1 is 0, the polycyclic compound represented by Formula 3 does not include R₄ᵢ as a substituent. A case where j1 is 0 may be the same as a case where j1 is 5 and R₅ᵢ groups are all hydrogen atoms. It may be understood that when j is 0, the polycyclic compound represented by Formula 3 does not include R₅ᵢ as a substituent. A case where k1 is 0 may be the same as a case where k1 is 3 and R₆ᵢ groups are all hydrogen atoms. It may be understood that when k1 is 0, the polycyclic compound represented by Formula 3 does not include R₆ᵢ as a substituent. A case where 11 is 0 may be the same as a case where 11 is 5 and R₇ᵢ groups are all hydrogen atoms. It may be understood that when 11 is 0, the polycyclic compound represented by Formula 3 does not include R₇ᵢ as a substituent.

In Formula 3, R₄ᵢᵢ and R₆ᵢᵢ may each independently be a hydrogen atom, a deuterium atom, or a substituted or unsubstituted aryl group having 6 to 15 ring-forming carbon atoms. For example, R₄ᵢᵢ and R₆ᵢᵢ may each independently be a hydrogen atom, a deuterium atom, or a substituted or unsubstituted phenyl group.

In an embodiment, the polycyclic compound represented by Formula 1 may be represented by Formula 4-1 or Formula 4-2. Formula 4-1 and Formula 4-2 each correspond to a case wherein in Formula 1, R₄ to R₇ are further defined. In Formula 4-1 and Formula 4-2, D, Dₐ₁, Dₐ₂, D_{b1}, D_{b2}, D_{c1}, D_{c2}, R₁ to R₃, and i to 1 are the same as described in Formula 1.

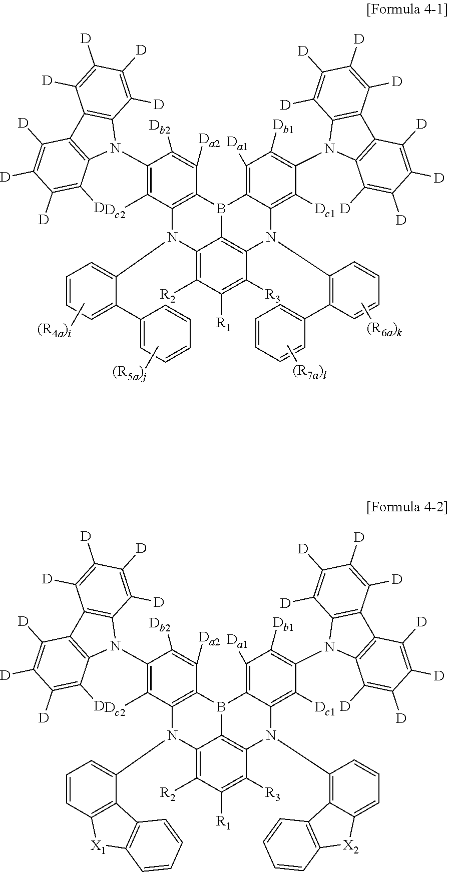

In Formula 4-1, R₄ₐ to R₇ₐ may each independently be a hydrogen atom, a deuterium atom, a substituted or unsubstituted alkyl group having 1 to 10 carbon atoms, a substituted or unsubstituted aryl group having 6 to 15 ring-forming carbon atoms, or a substituted or unsubstituted heteroaryl group having 2 to 15 ring-forming carbon atoms. For example, R₄ₐ to R₇ₐ may each independently be a hydrogen atom, a deuterium atom, a substituted or unsubstituted t-butyl group, or a substituted or unsubstituted phenyl group.

In Formula 4-2, X₁ and X₂ may each independently an oxygen atom (O), a sulfur atom (S), C(Rₐ)(R_{b}), or N(R_{c}). For example, in Formula 4-2, X₁ and X₂ may both be O, S, C(Rₐ)(R_{b}), or N(Re). However, embodiments are not limited thereto, and X₁ and X₂ may be different from each other. In Formula 4-2, Rₐ to R_{c} may each independently be a hydrogen atom, a deuterium atom, or a substituted or unsubstituted aryl group having 6 to 15 ring-forming carbon atoms, or may be bonded to an adjacent group to form a ring. For example, Rₐ to R_{c} may each independently be a hydrogen atom, a deuterium atom, or a substituted or unsubstituted phenyl group, or Rₐ and R_{b} may be bonded to each other to form a spiro ring.

In an embodiment, the polycyclic compound represented by Formula 4-1 may be represented by Formula 4-1a. Formula 4-1a represents a case wherein in Formula 4-1, R₄ₐ and R₆ₐ are further defined. In Formula 4-1a, D, Dₐ₁, Dₐ₂, D_{b1}, D_{b2}, D_{c1}, D_{c2}, R₁ to R₃, j, and 1 are the same as described in Formula 1; and R₅ₐ and R₇ₐ are the same as described in Formula 4-1.

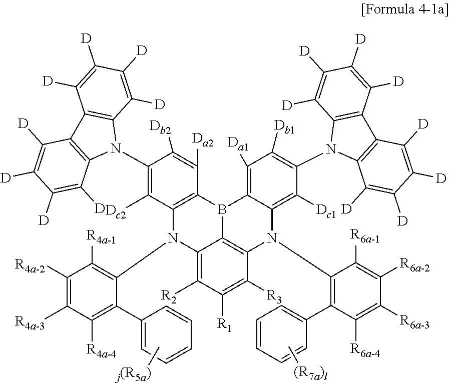

In Formula 4-1a, R₄ₐ₋₁ and R₆ₐ₋₁ may each independently be a hydrogen atom, a deuterium atom, or a substituted or unsubstituted phenyl group. In Formula 4-1a, R₄ₐ₋₂ to R₄ₐ₋₄ and R₆ₐ₋₂ to R₆ₐ₋₄ may each independently be a hydrogen atom, a deuterium atom, a substituted or unsubstituted alkyl group having 1 to 10 carbon atoms, or a substituted or unsubstituted aryl group having 6 to 15 ring-forming carbon atoms. For example, R₄ₐ₋₂ to R₄ₐ₋₄ and R₆ₐ₋₂ to R₆ₐ₋₄ may each independently be a hydrogen atom, a deuterium atom, or a substituted or unsubstituted phenyl group. When R₄ₐ₋₂ to R₄ₐ₋₄ and R₆ₐ₋₂ to R₆ₐ₋₄ are each substituted, each may itself be substituted with a t-butyl group, etc.

The polycyclic compound may be any compound selected from Compound Group 1. The light emitting element ED according to an embodiment may include at least one compound selected from Compound Group 1. In Compound Group 1, D is a deuterium atom.

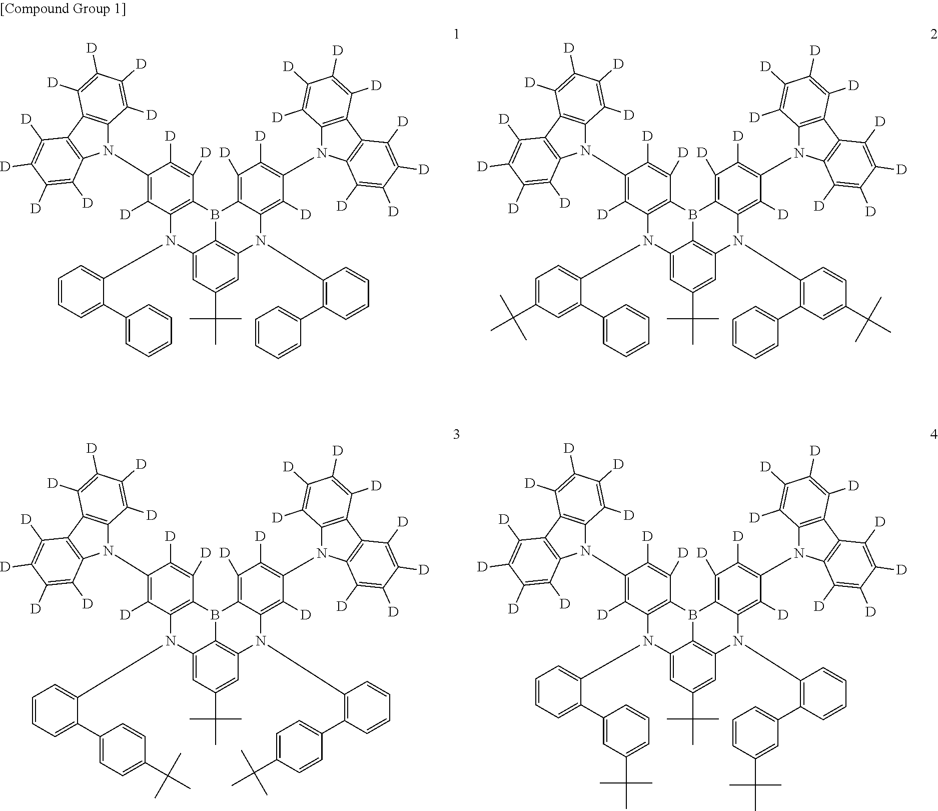

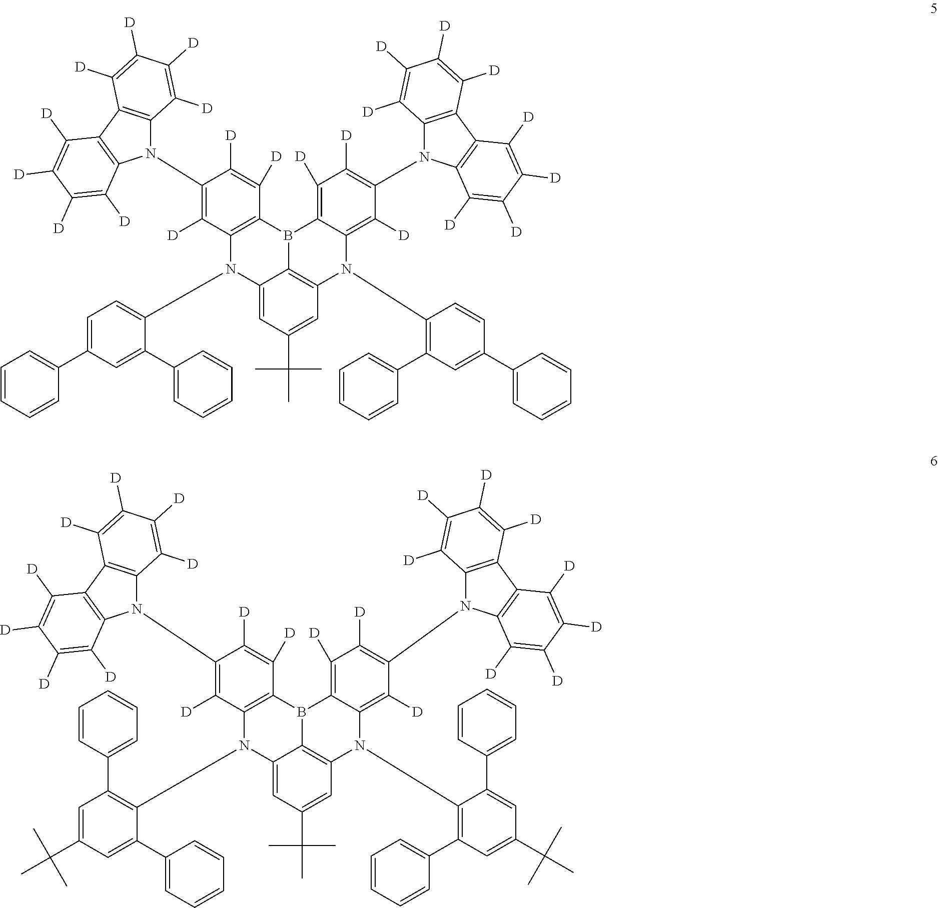

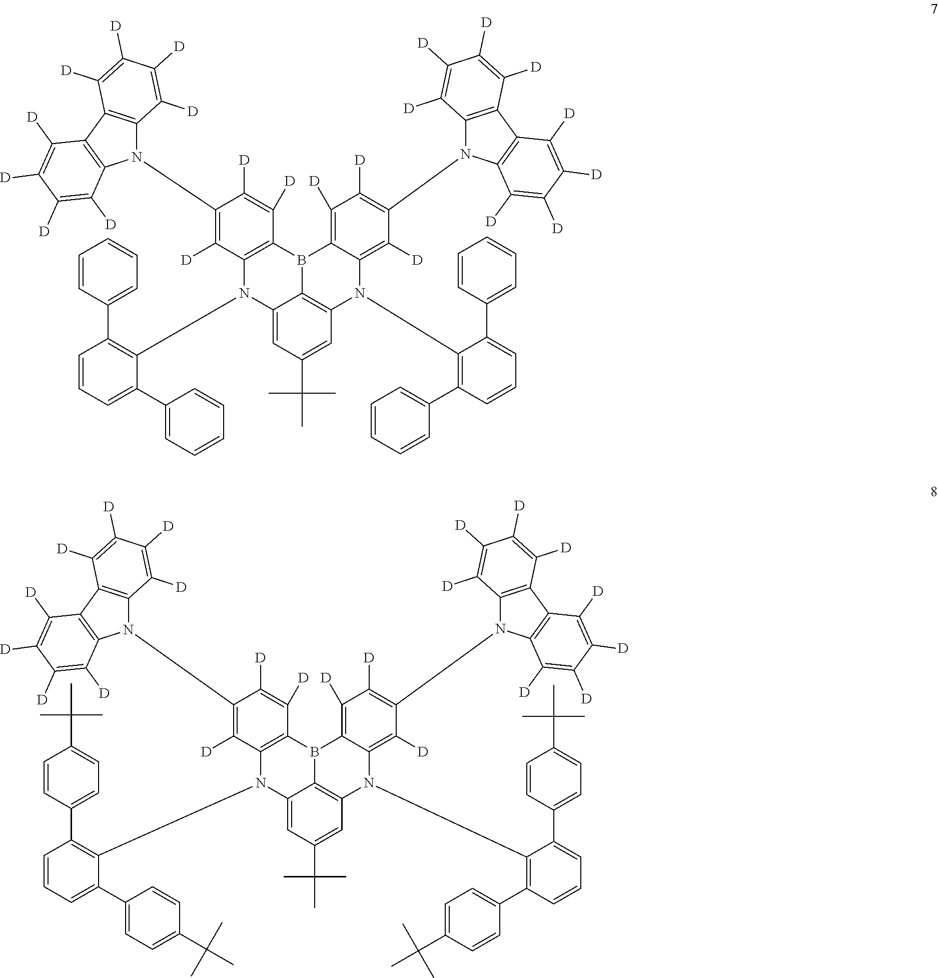

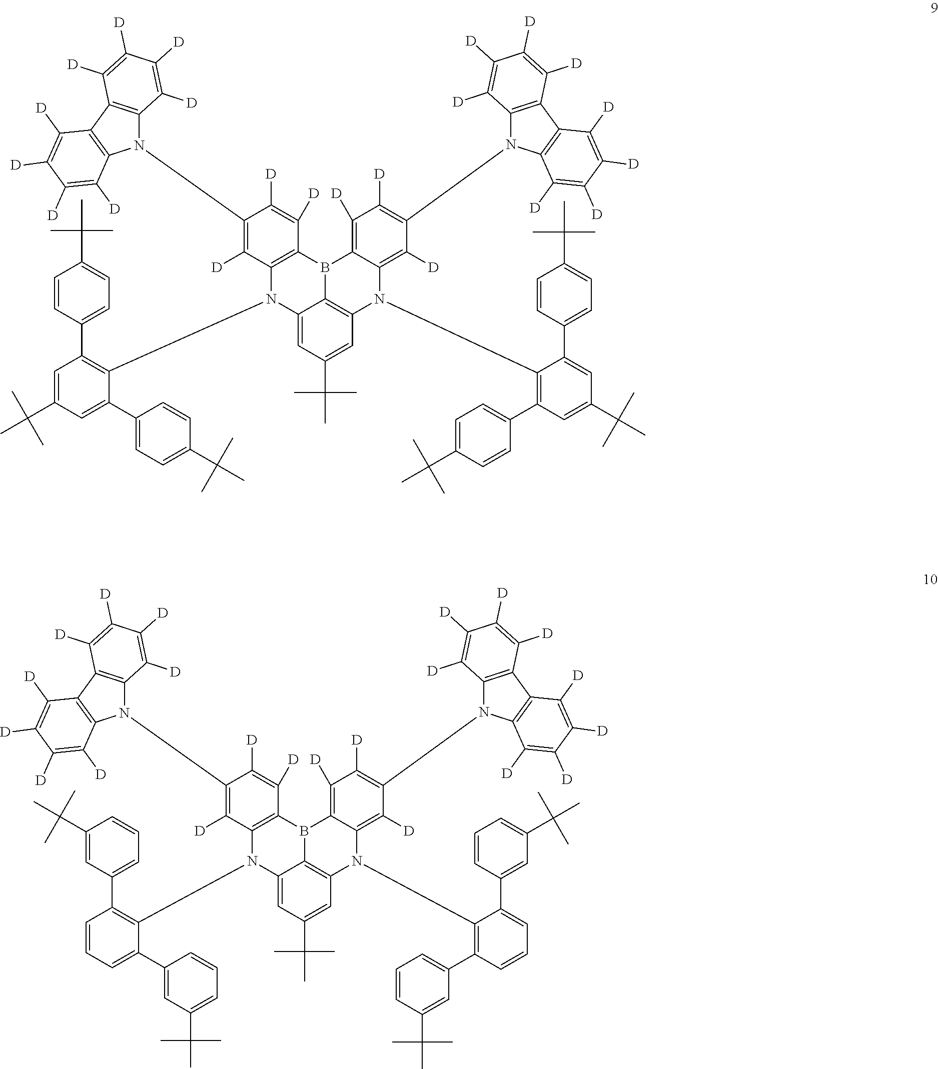

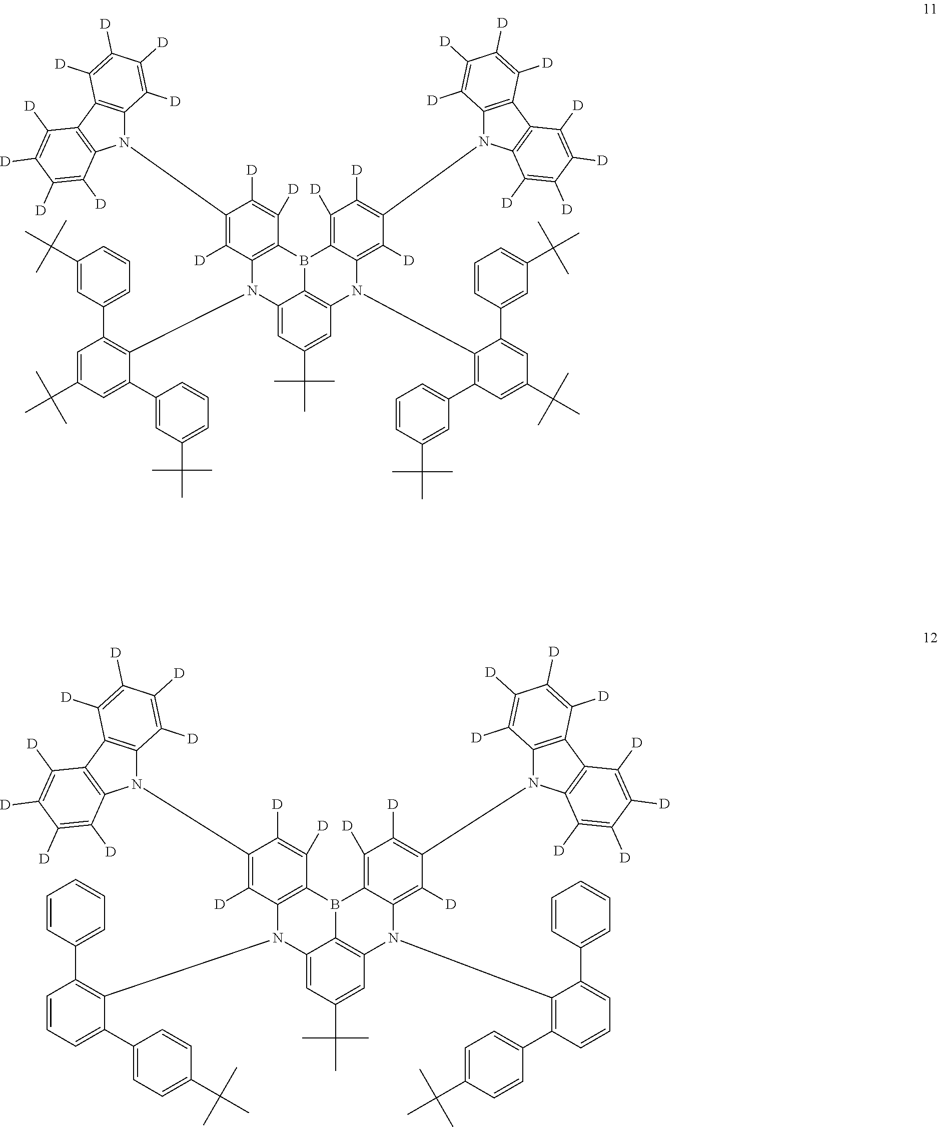

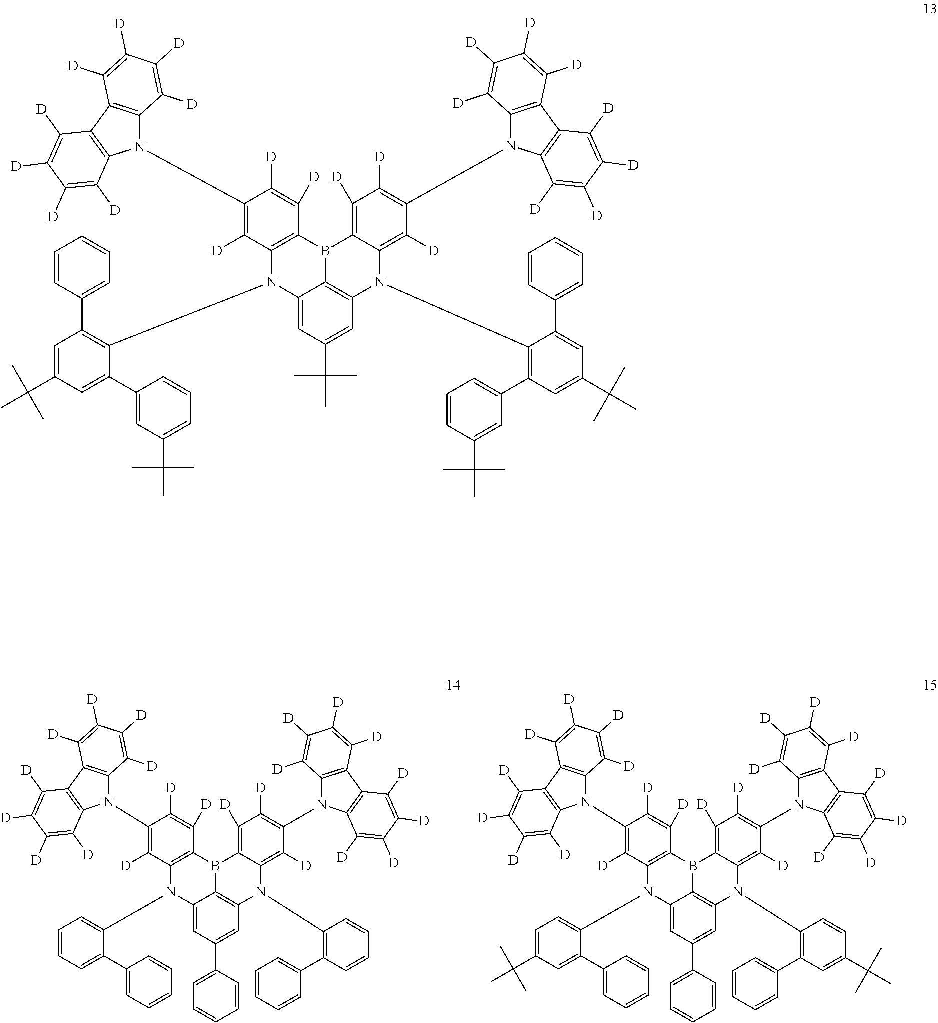

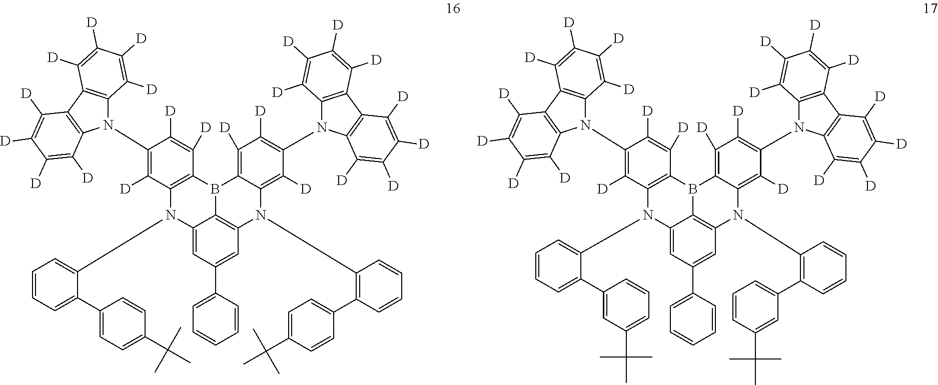

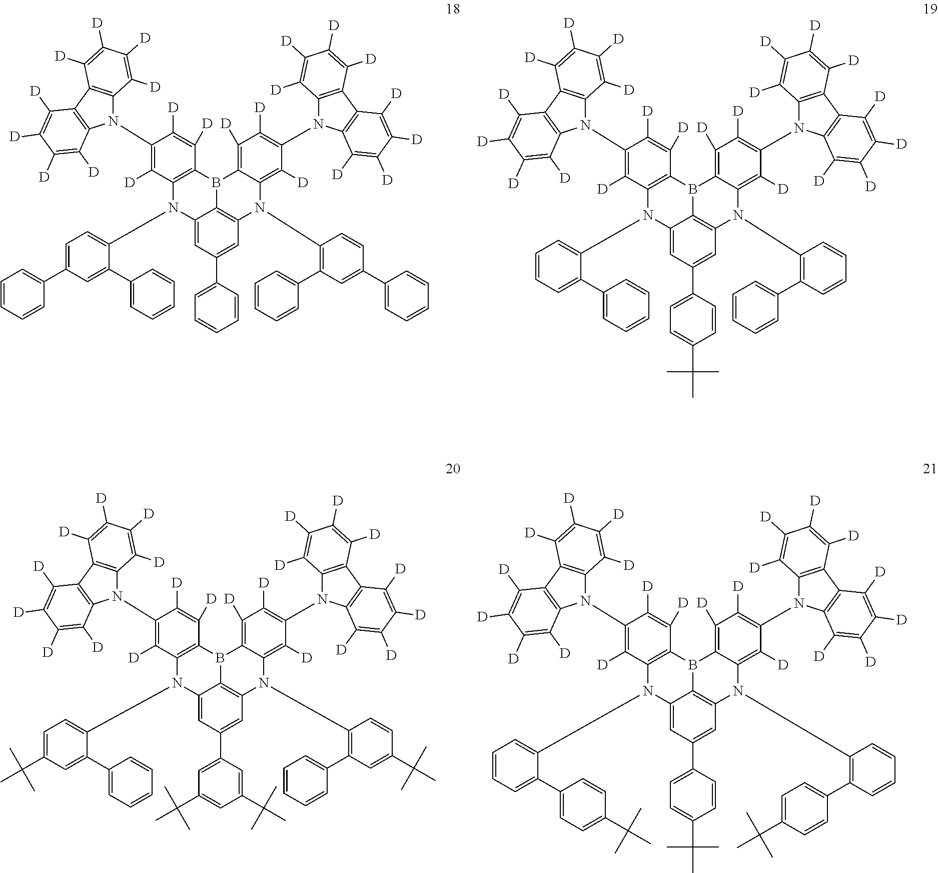

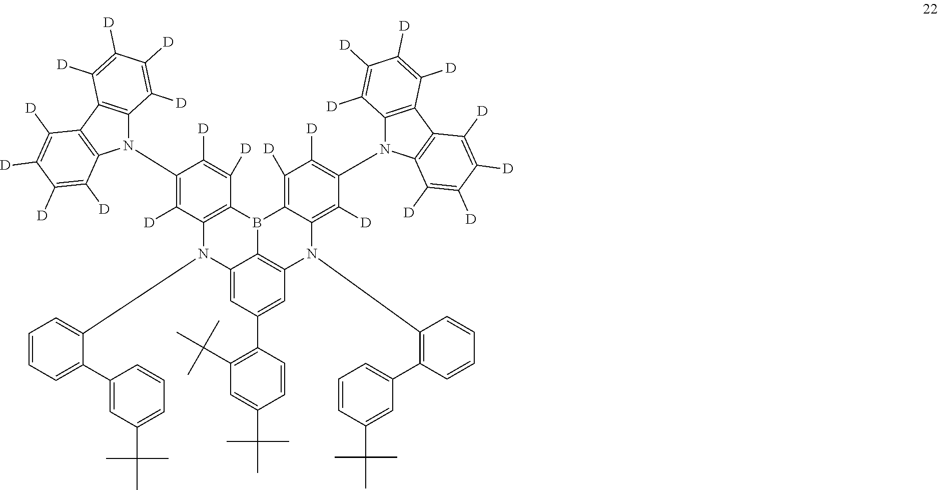 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(-c4ccc(C(C)(C)C)cc4C(C)(C)C)cc3N(c3ccccc3-c3cccc(C(C)(C)C)c3)c3c([2H])c(-n4c5c([2H])c([2H])c([2H])c([2H])c5c5c([2H])c([2H])c([2H])c([2H])c54)c([2H])c([2H])c31)N2c1ccccc1-c1cccc(C(C)(C)C)c1]

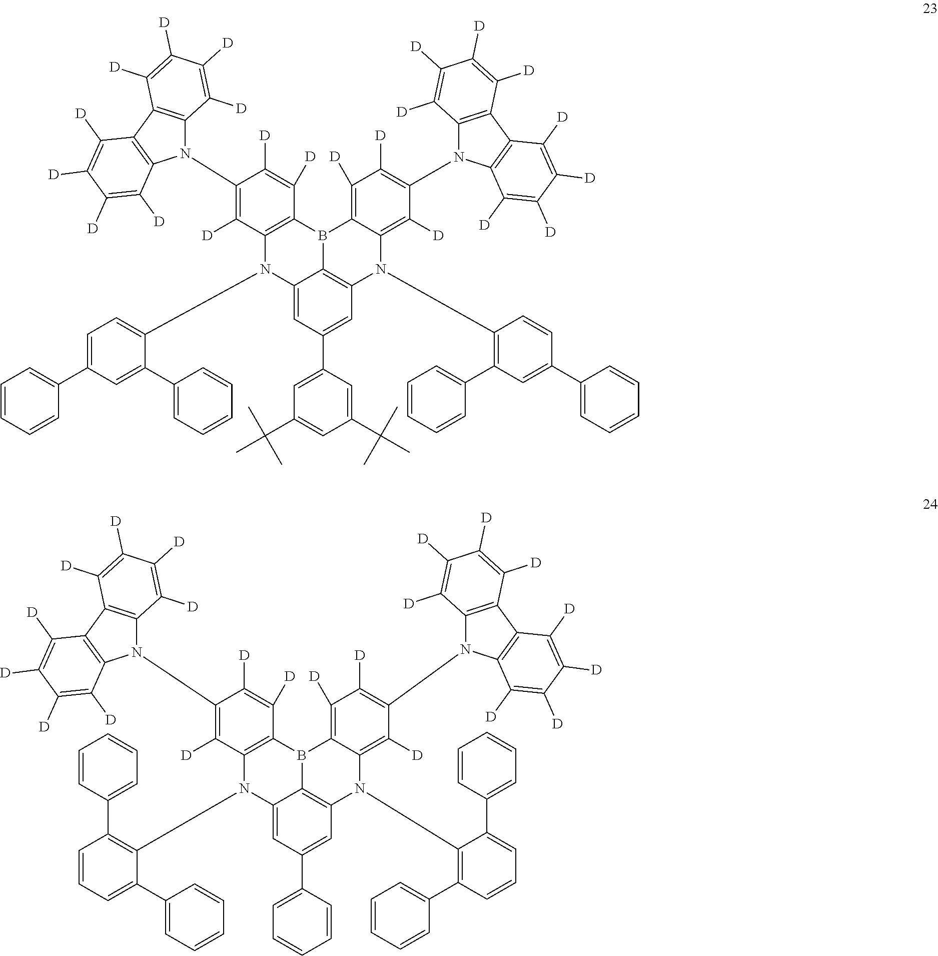

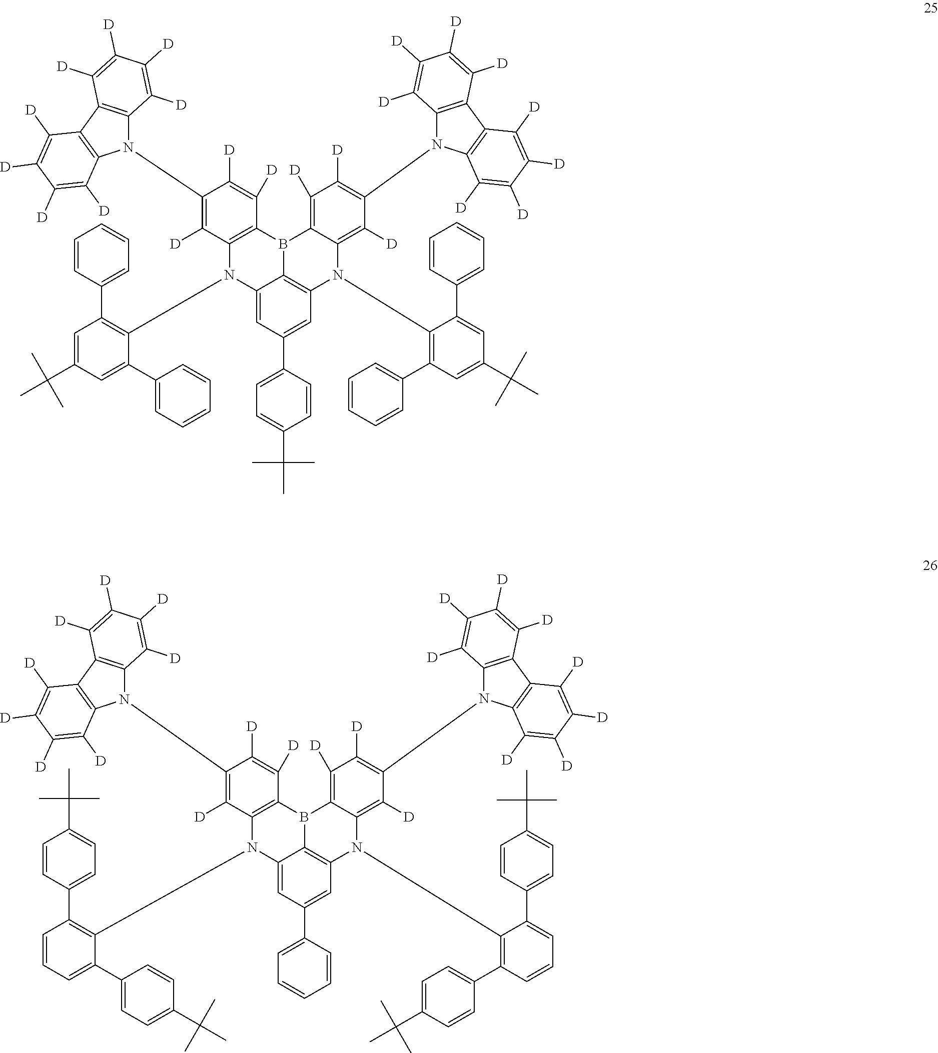

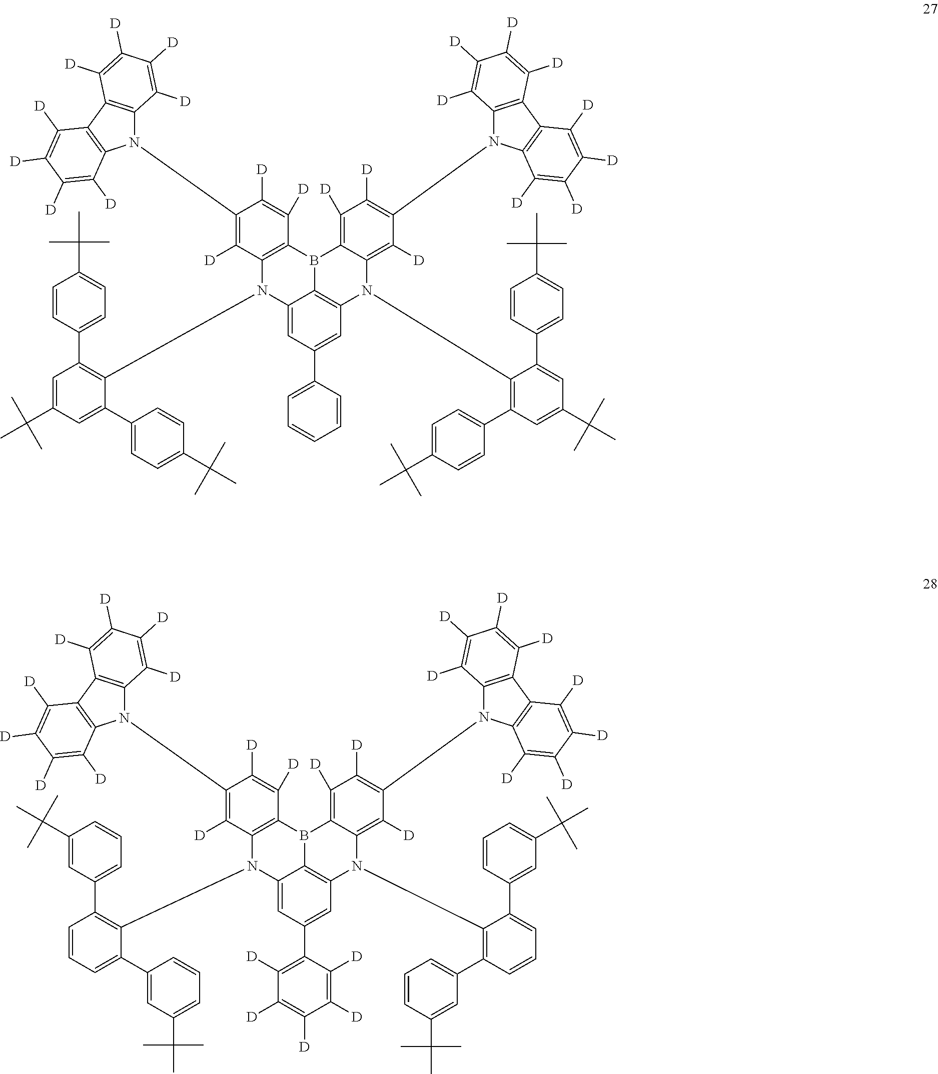

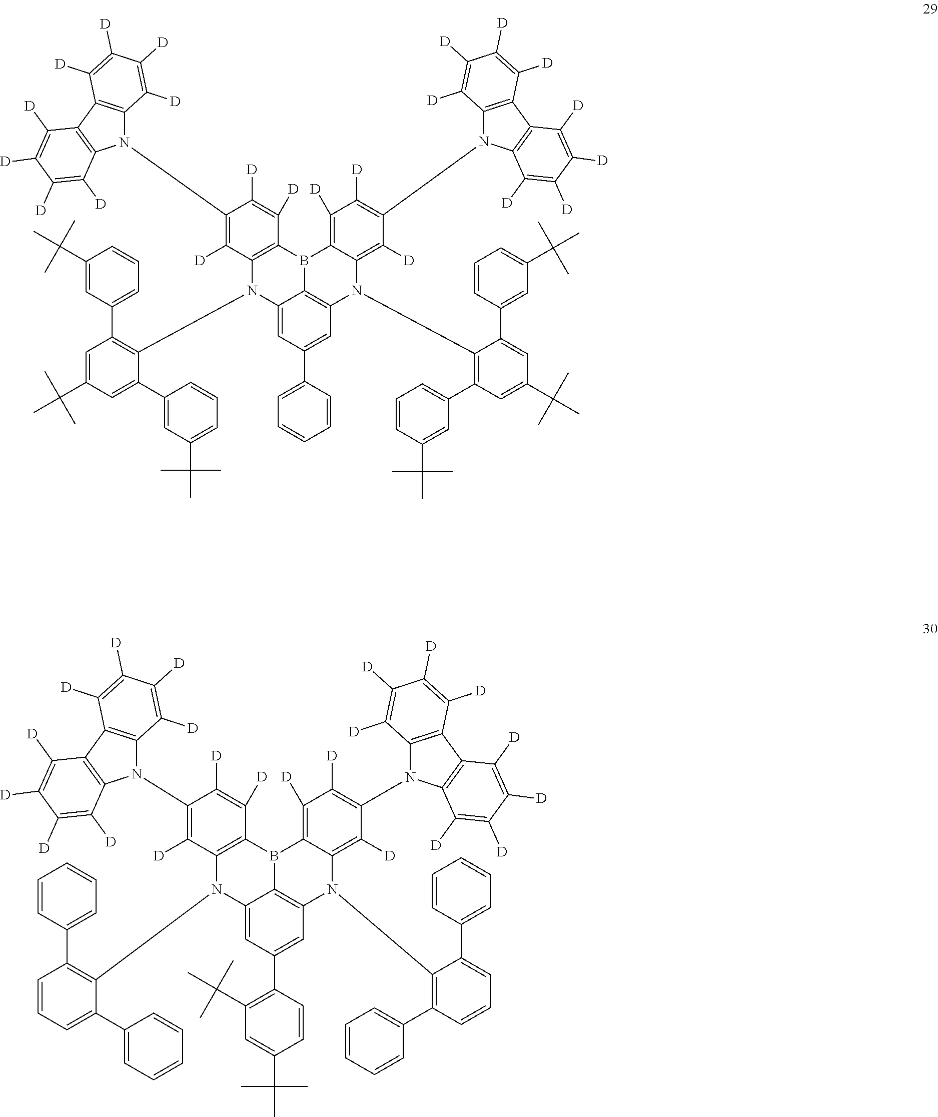

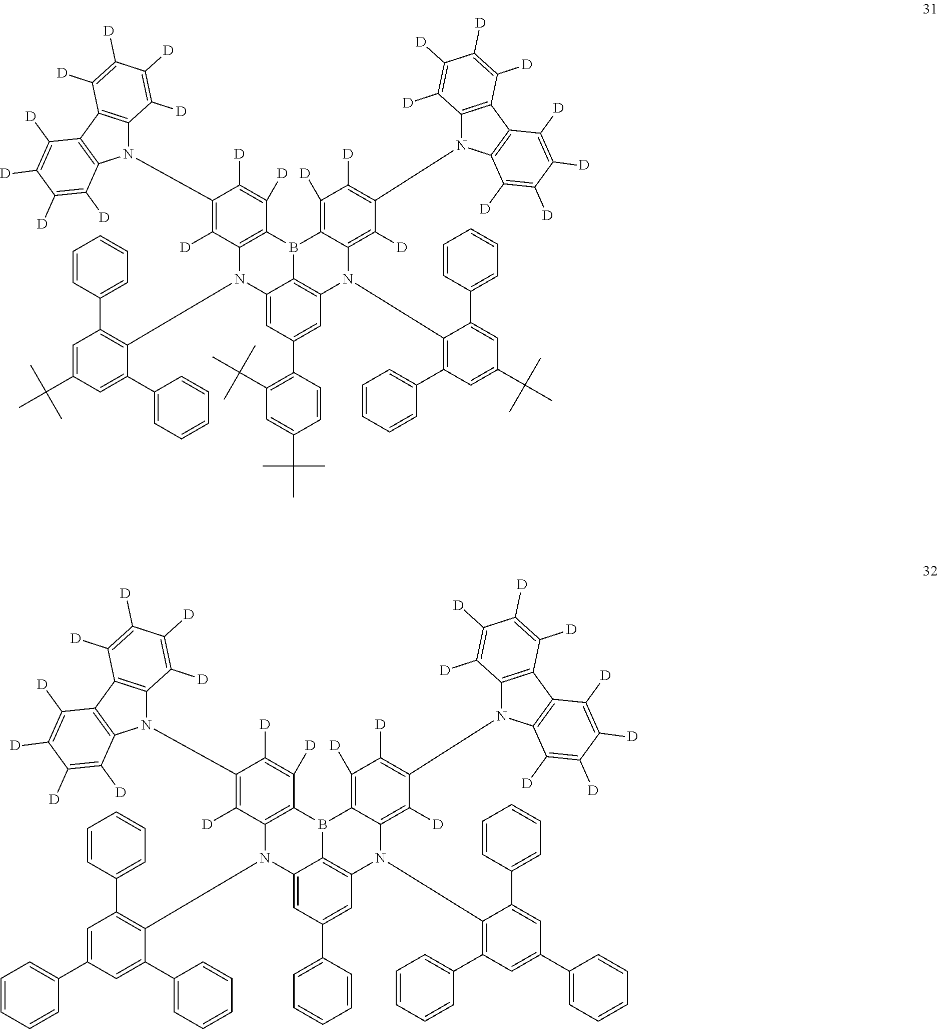

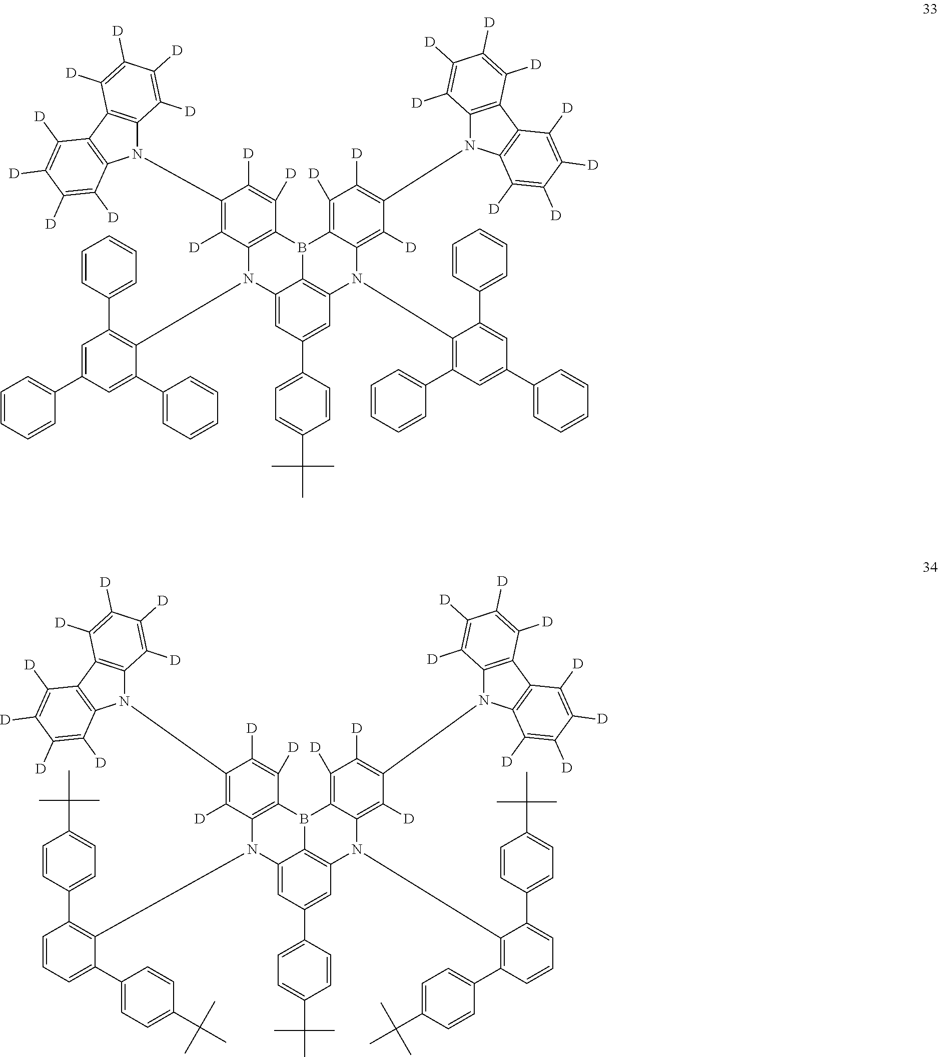

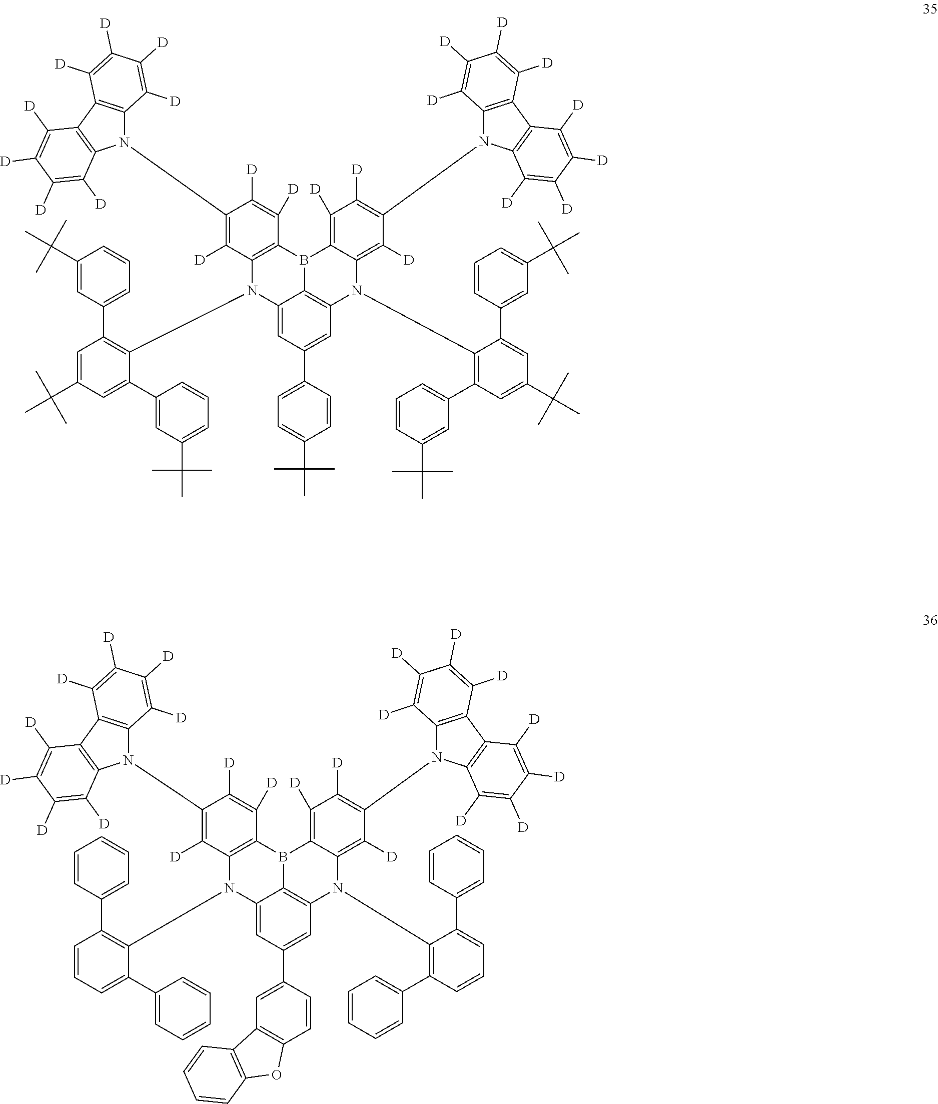

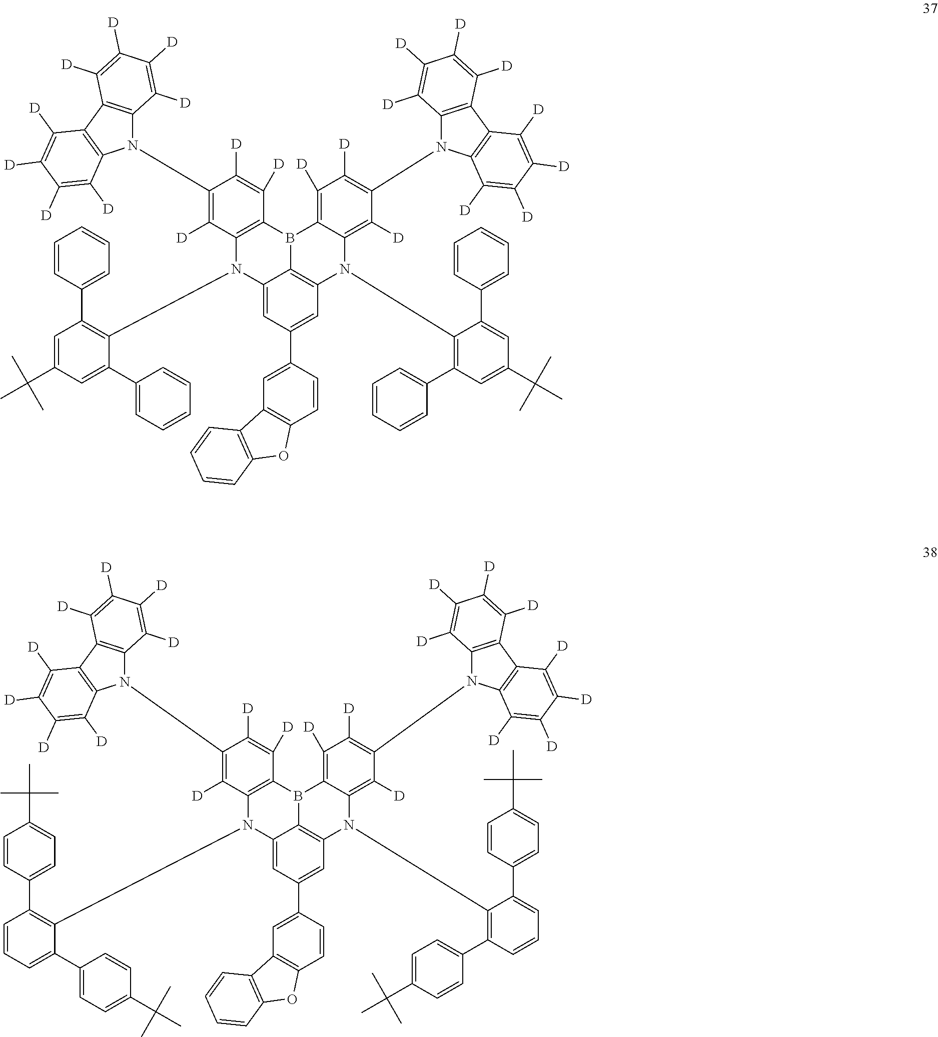

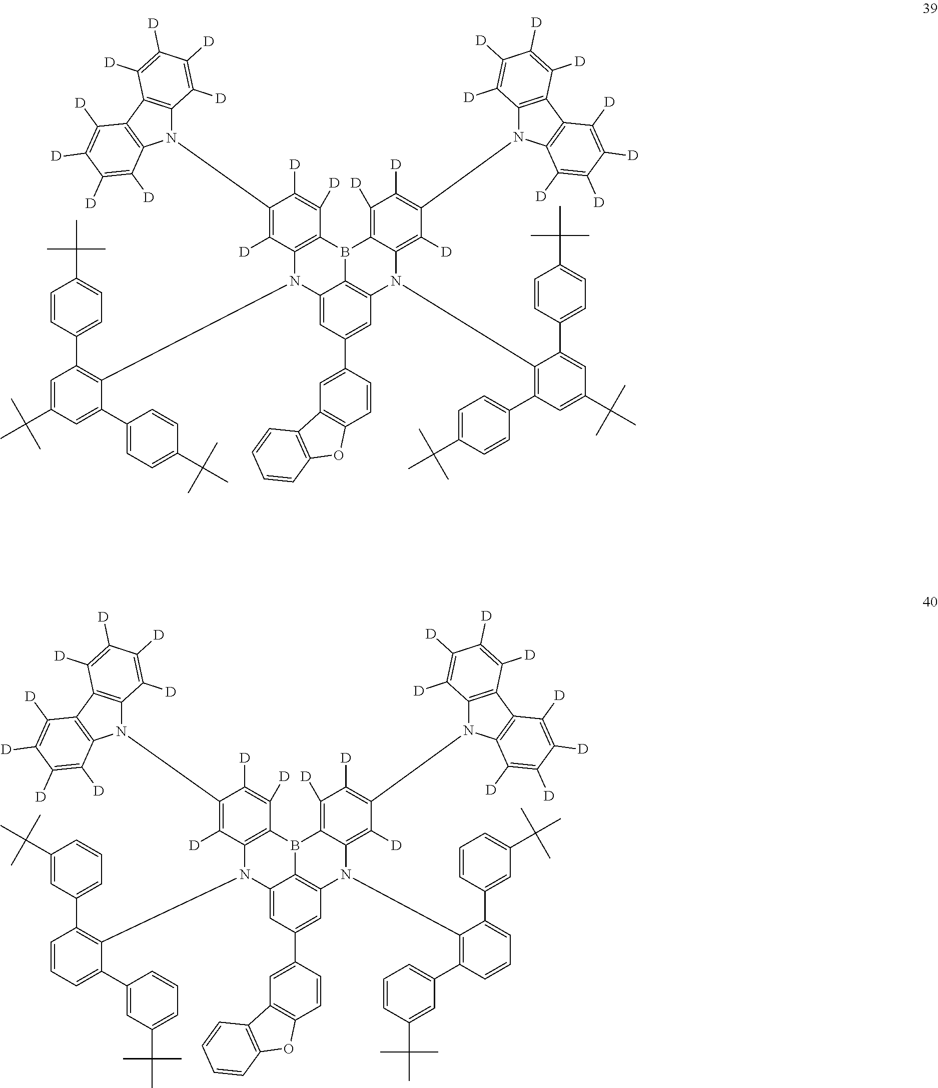

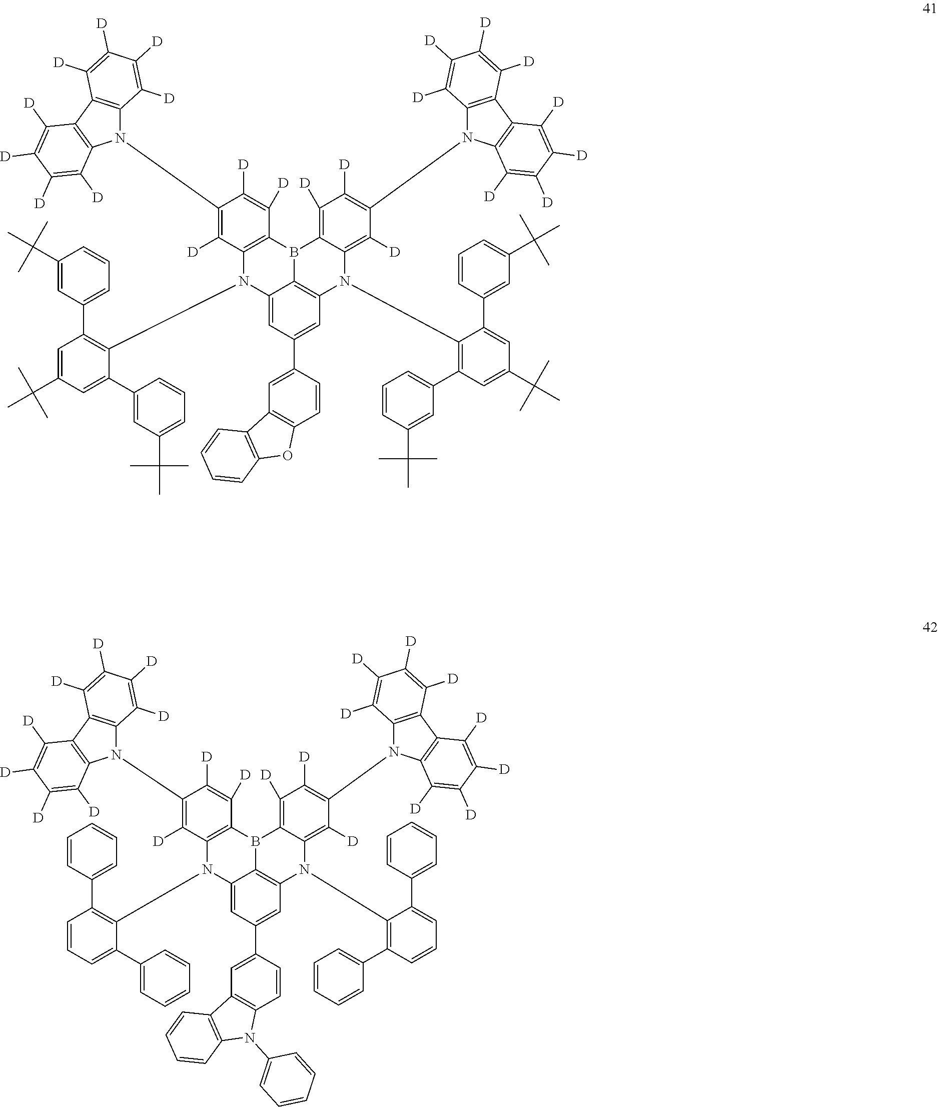

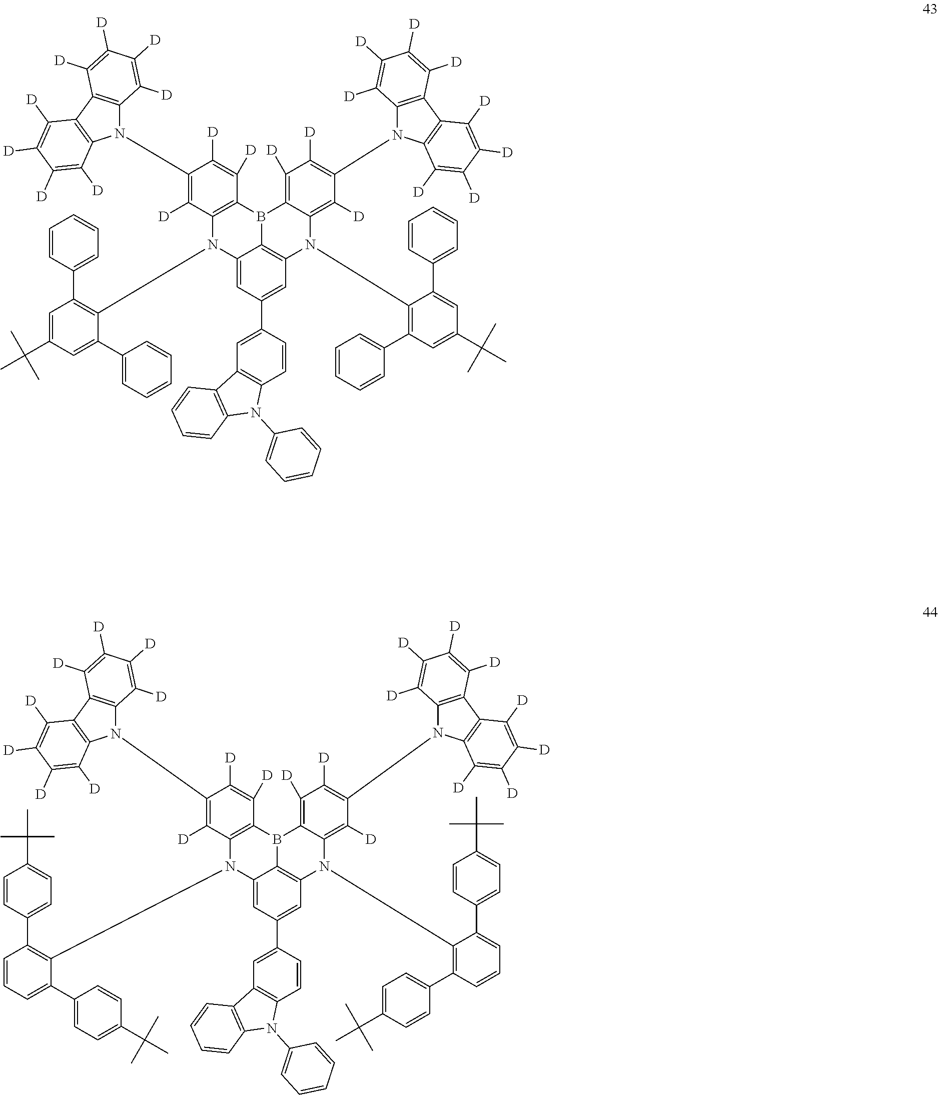

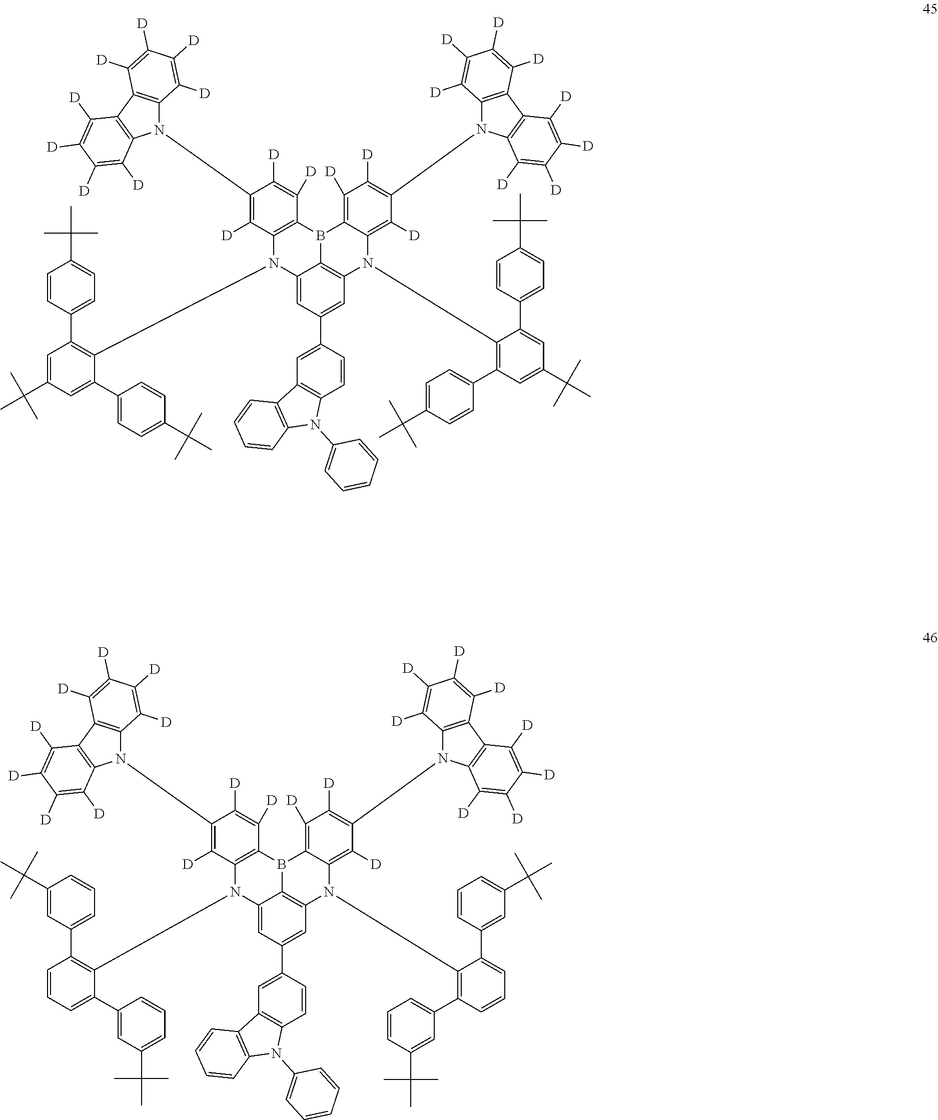

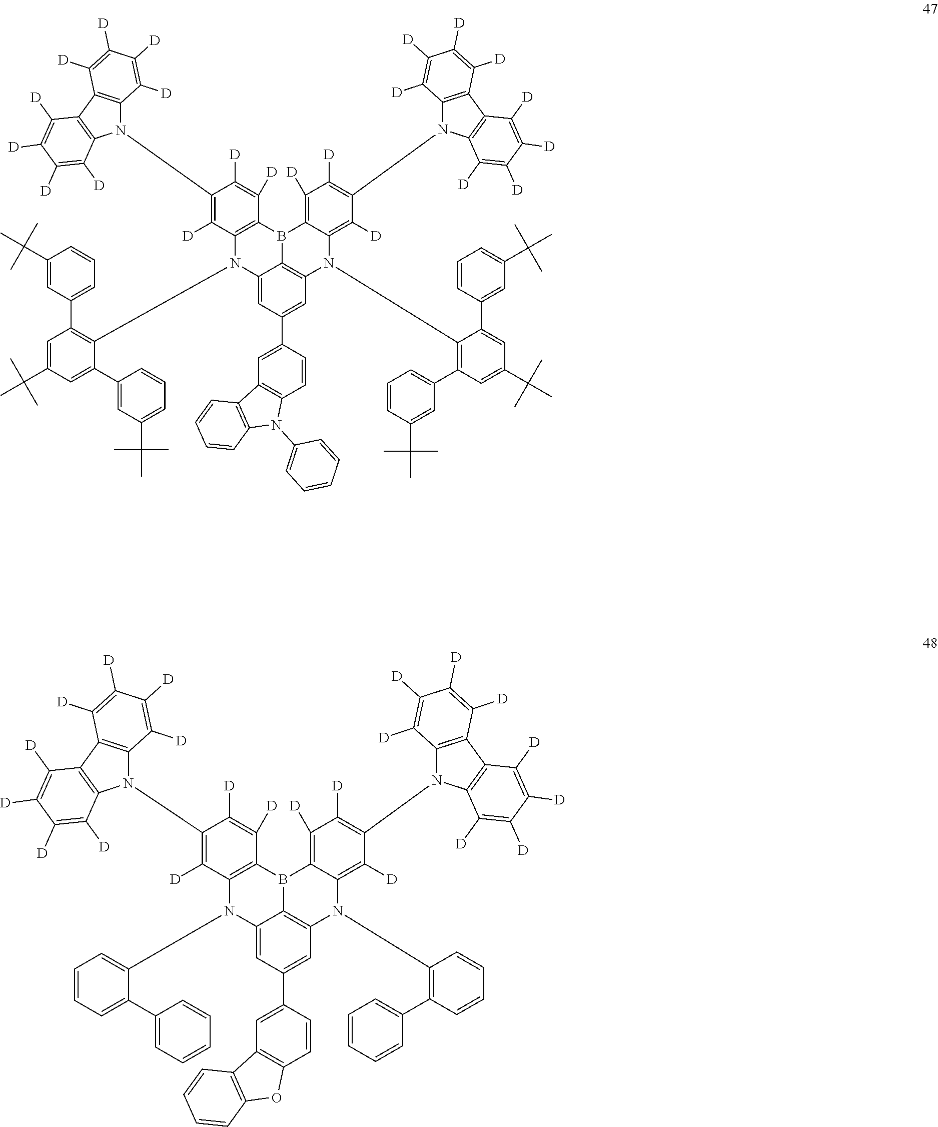

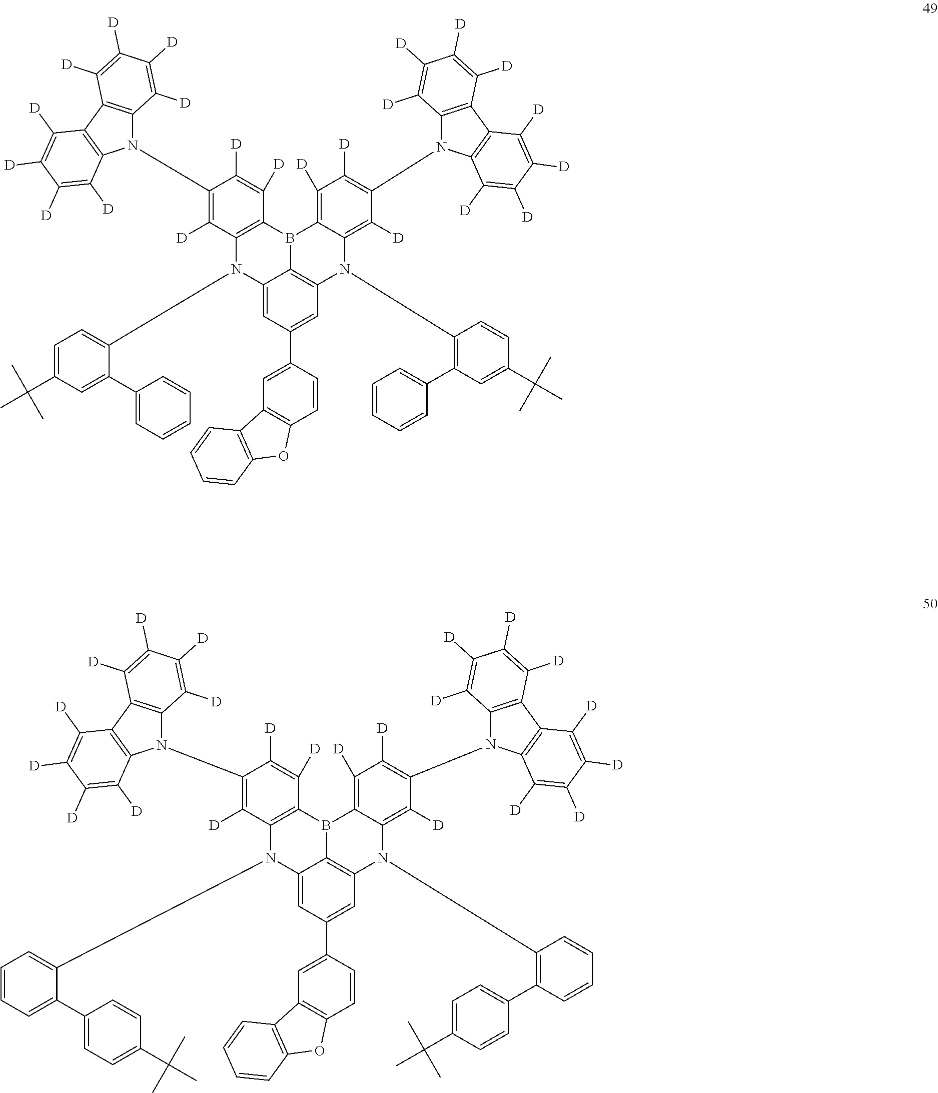

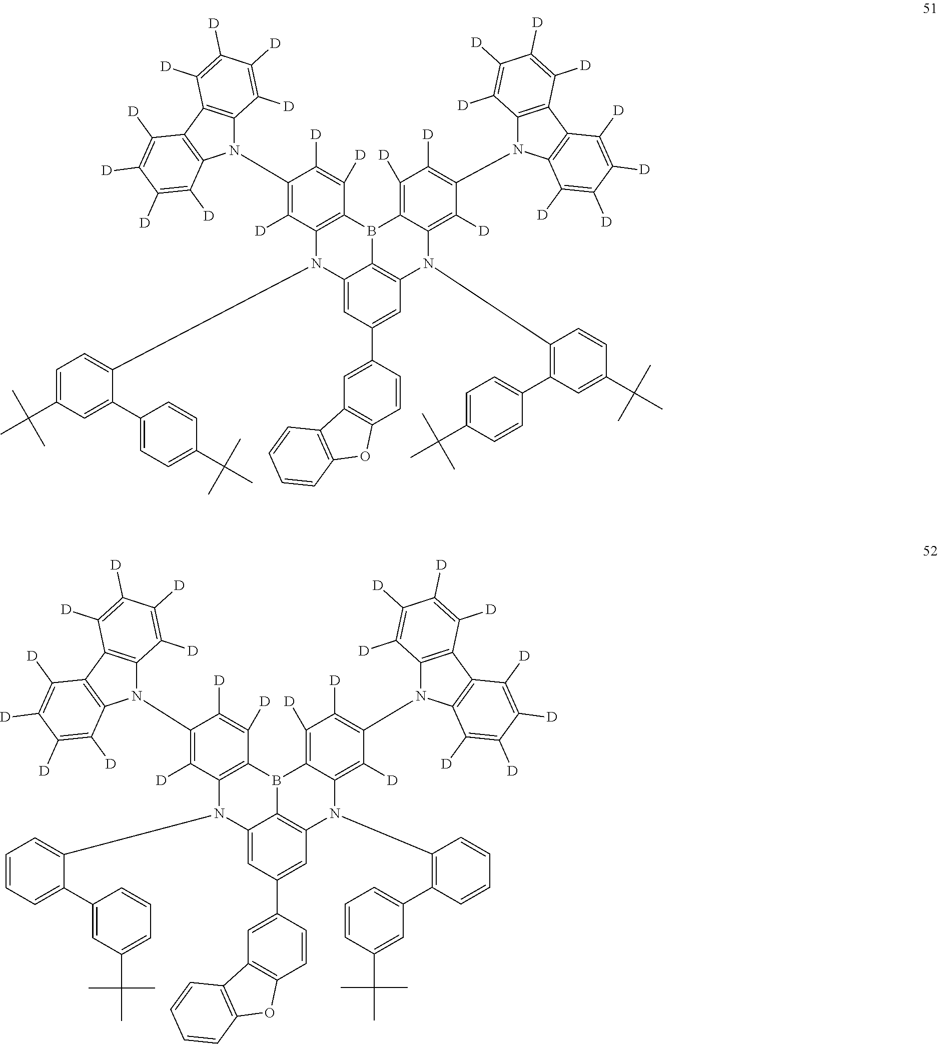

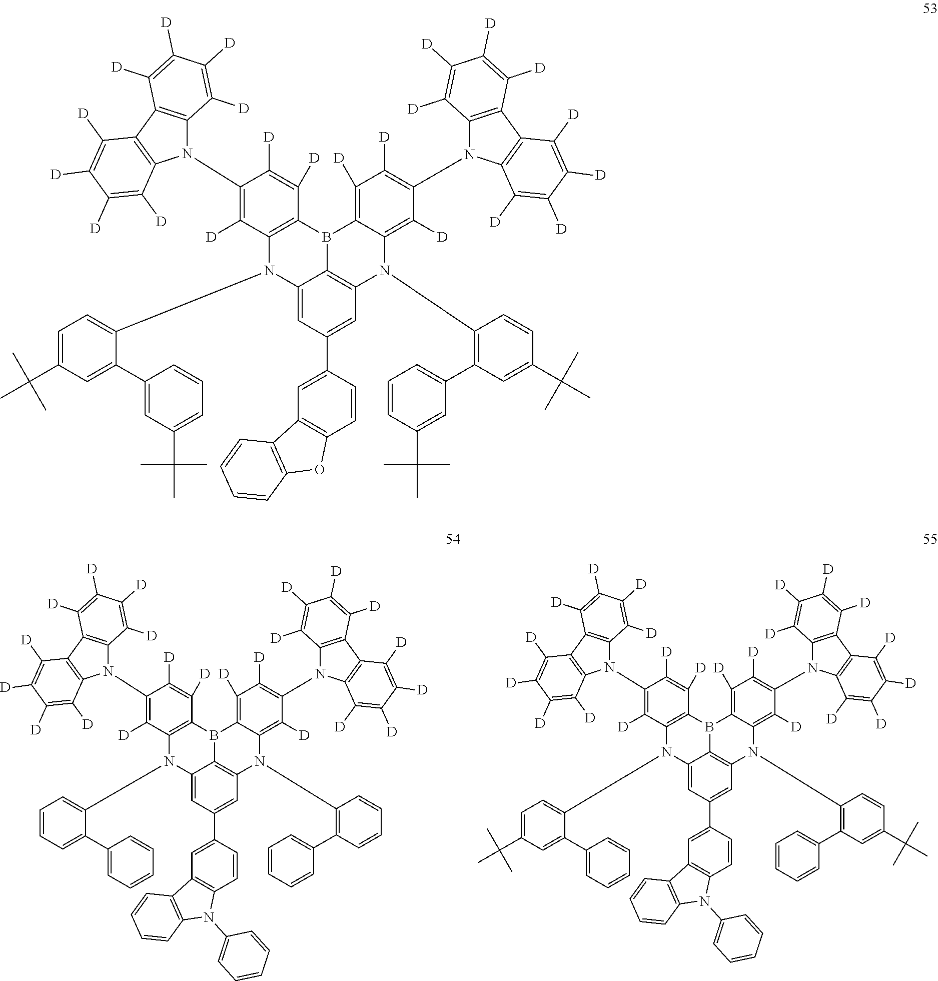

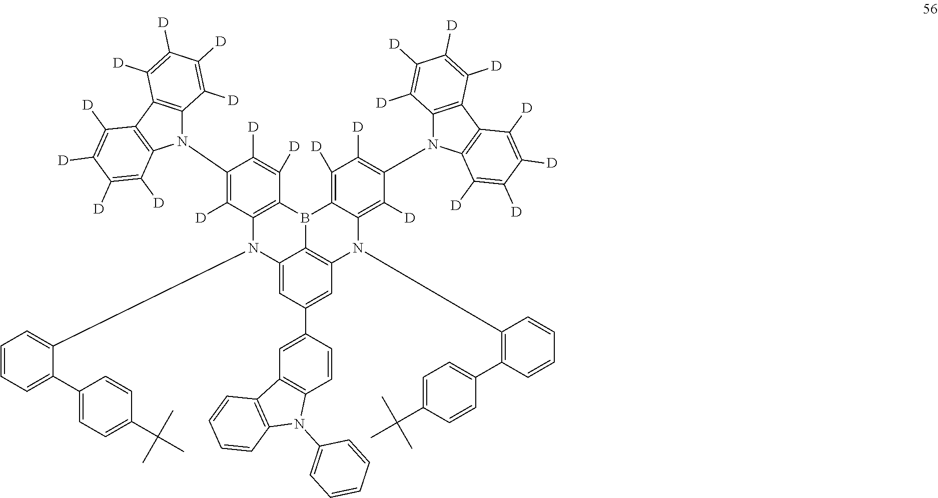 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(-c4ccc5c(c4)c4ccccc4n5-c4ccccc4)cc3N(c3ccccc3-c3ccc(C(C)(C)C)cc3)c3c([2H])c(-n4c5c([2H])c([2H])c([2H])c([2H])c5c5c([2H])c([2H])c([2H])c([2H])c54)c([2H])c([2H])c31)N2c1ccccc1-c1ccc(C(C)(C)C)cc1]

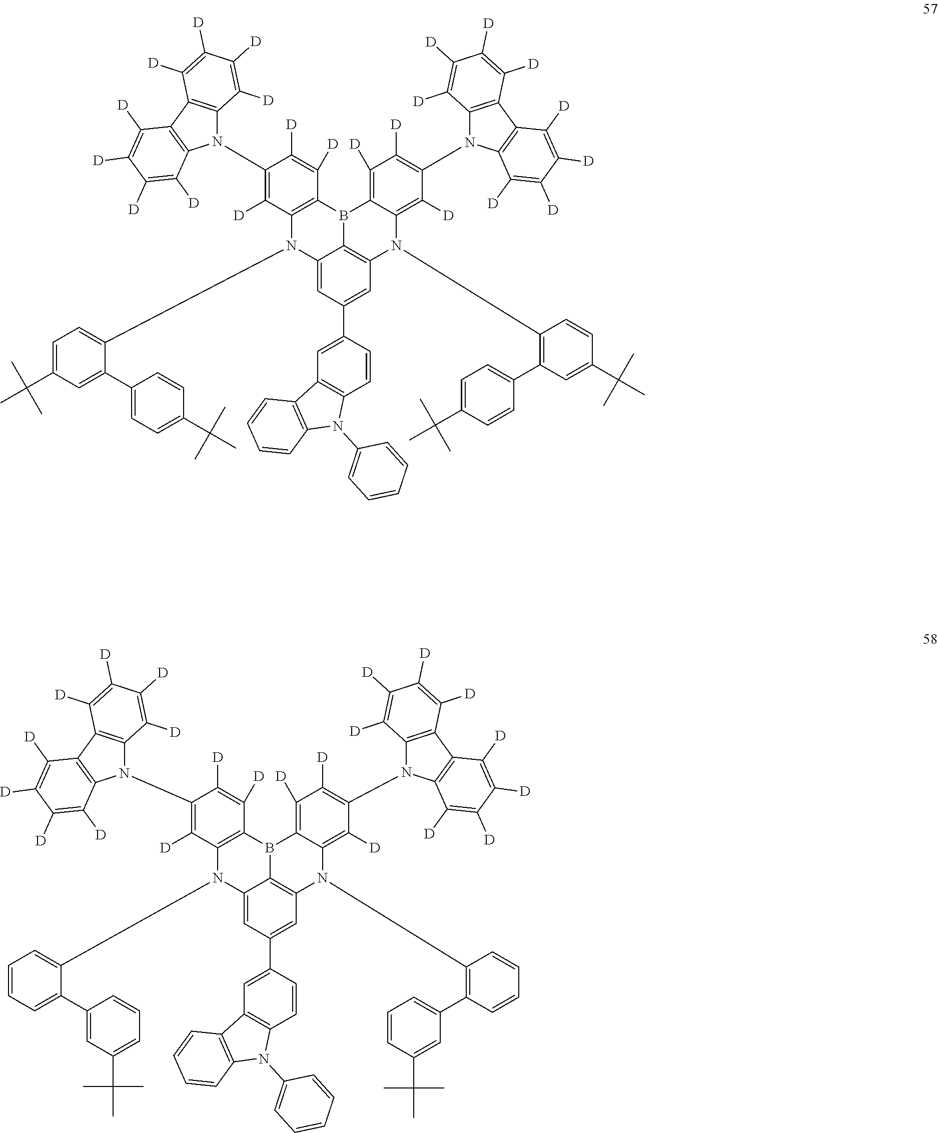

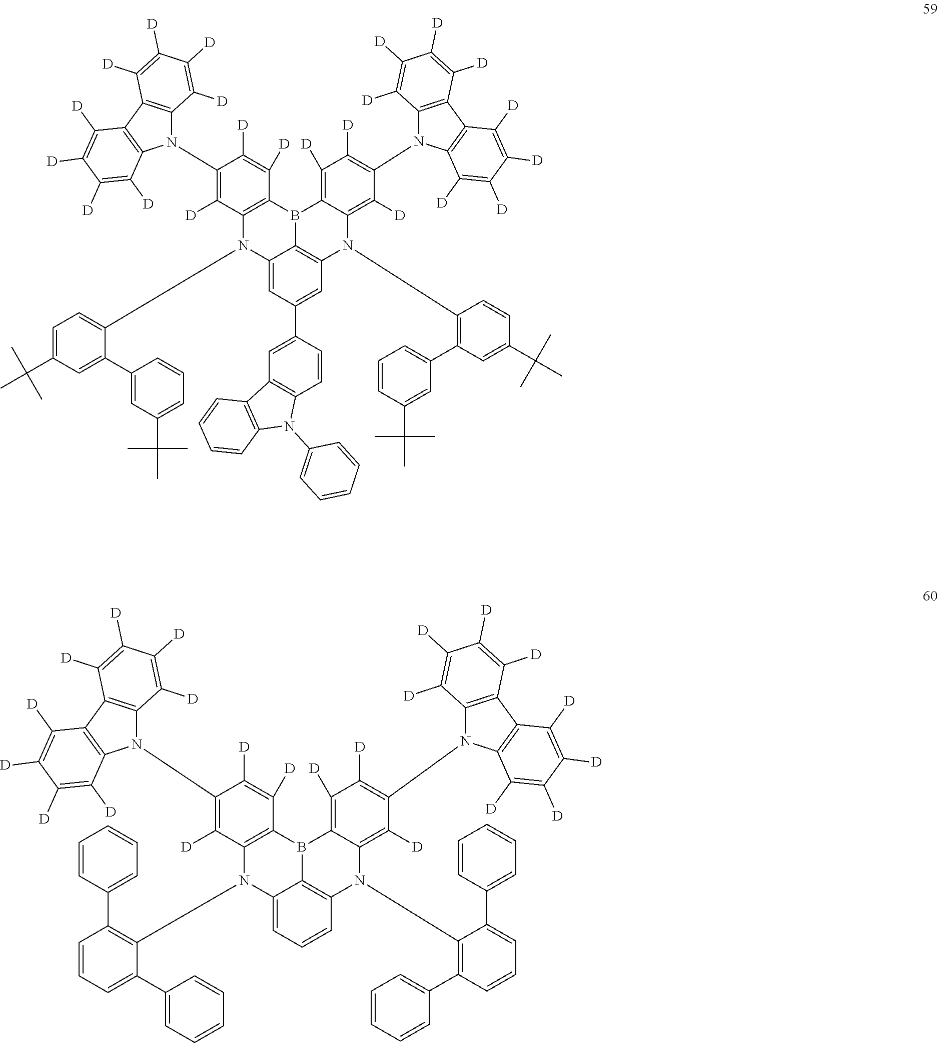

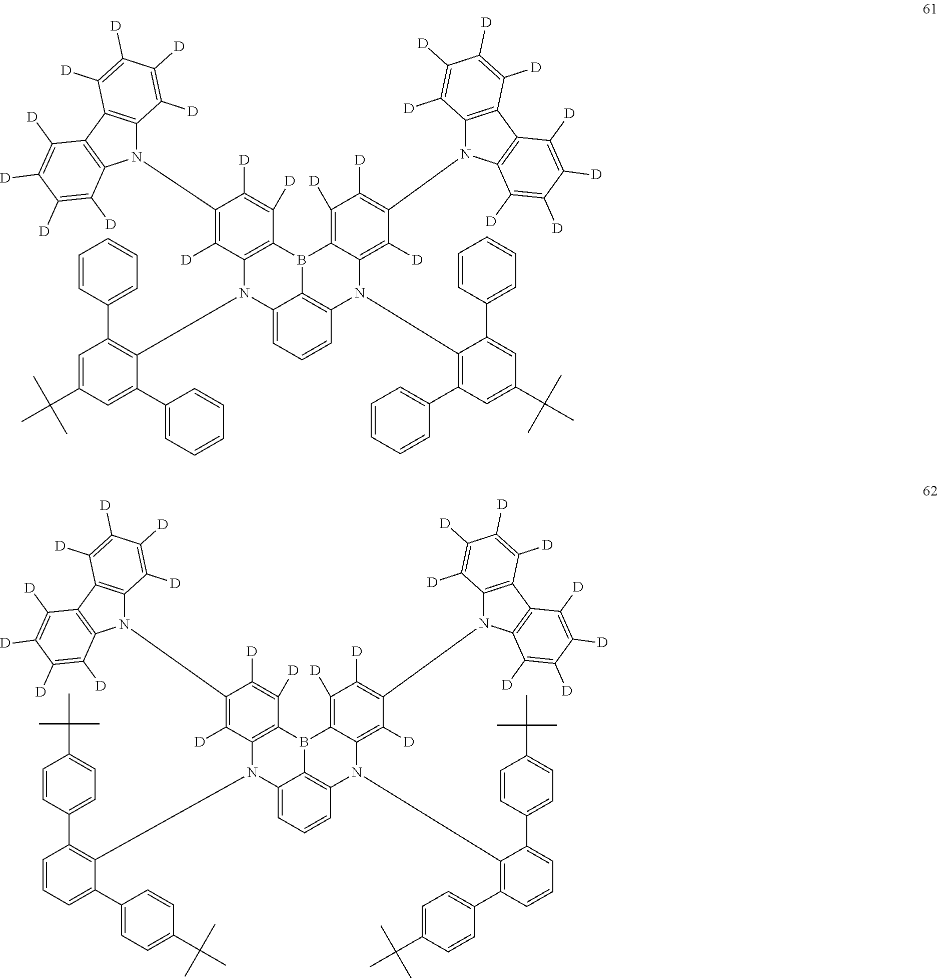

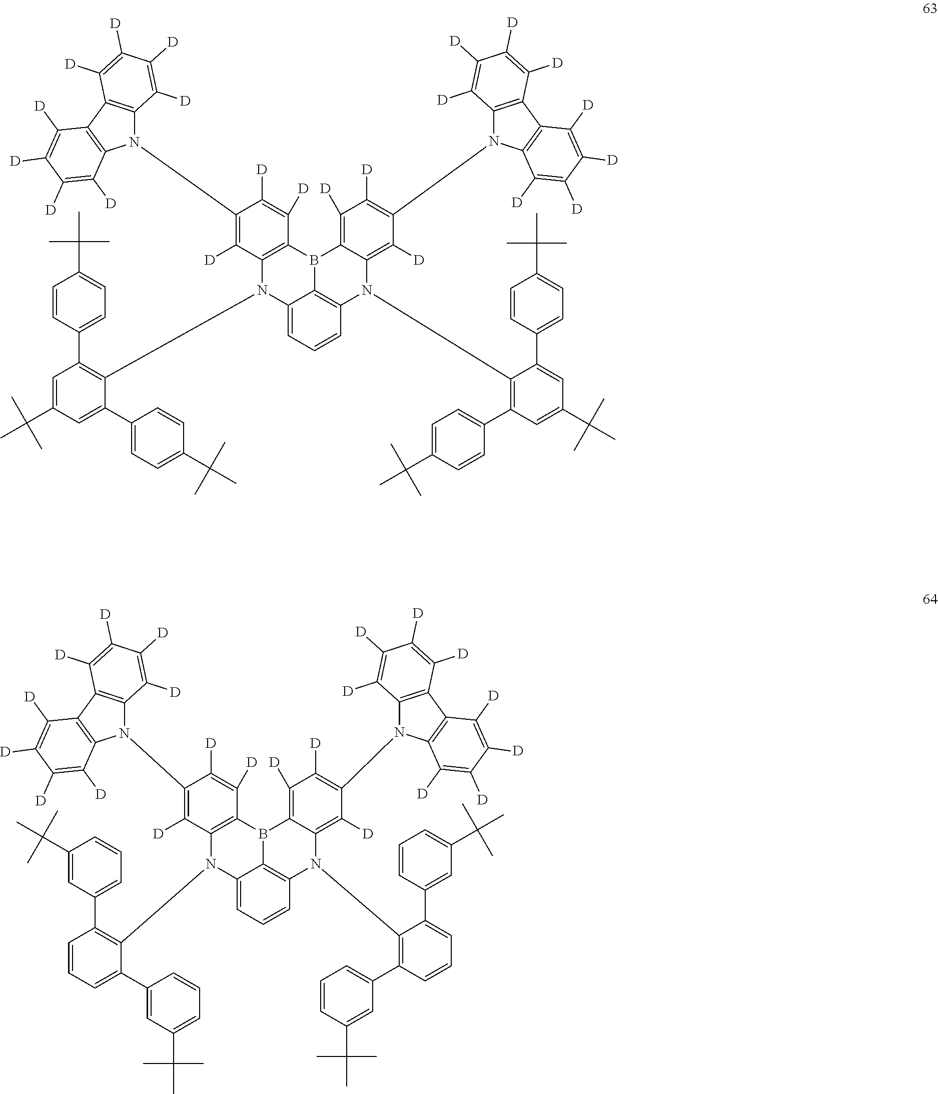

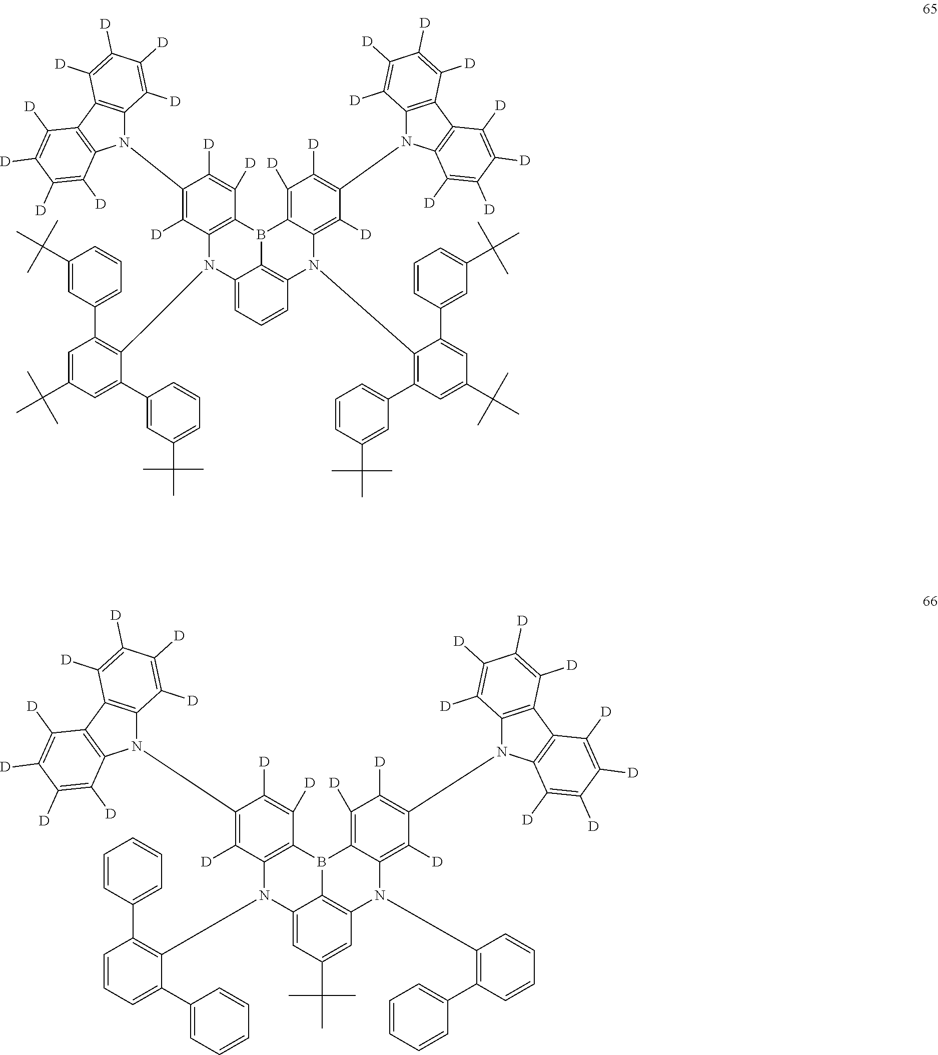

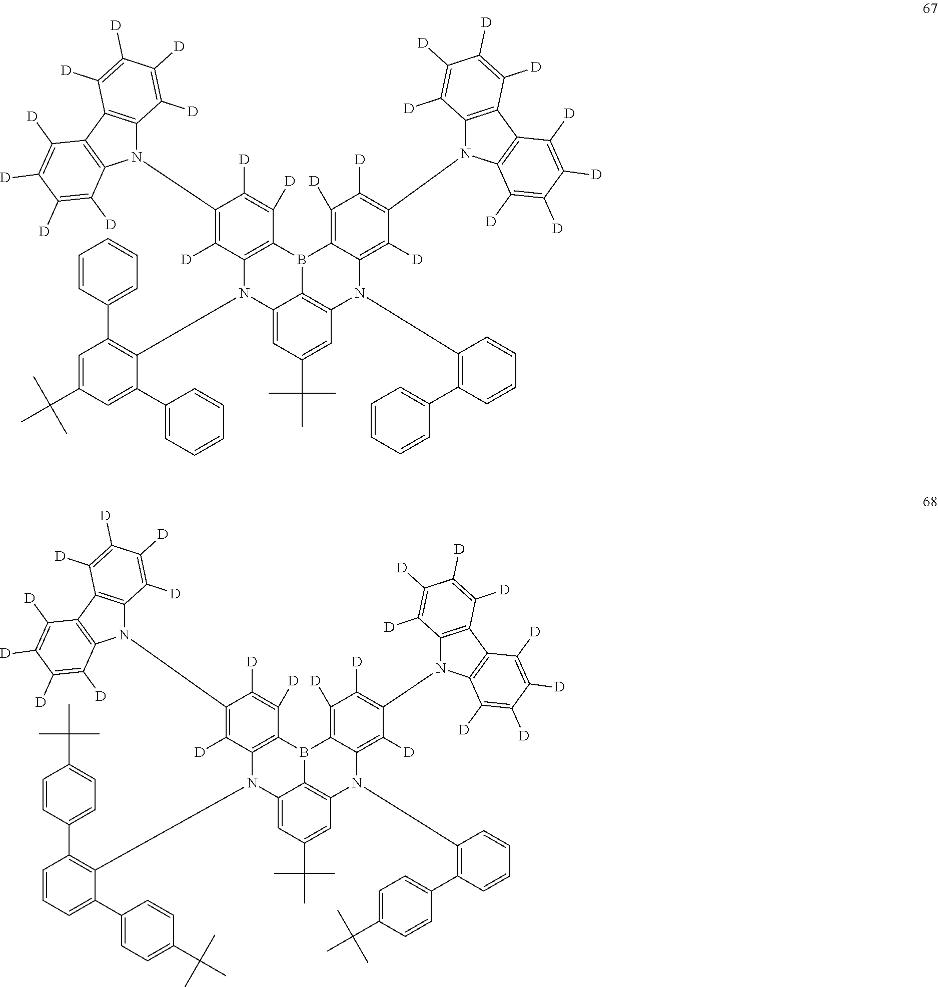

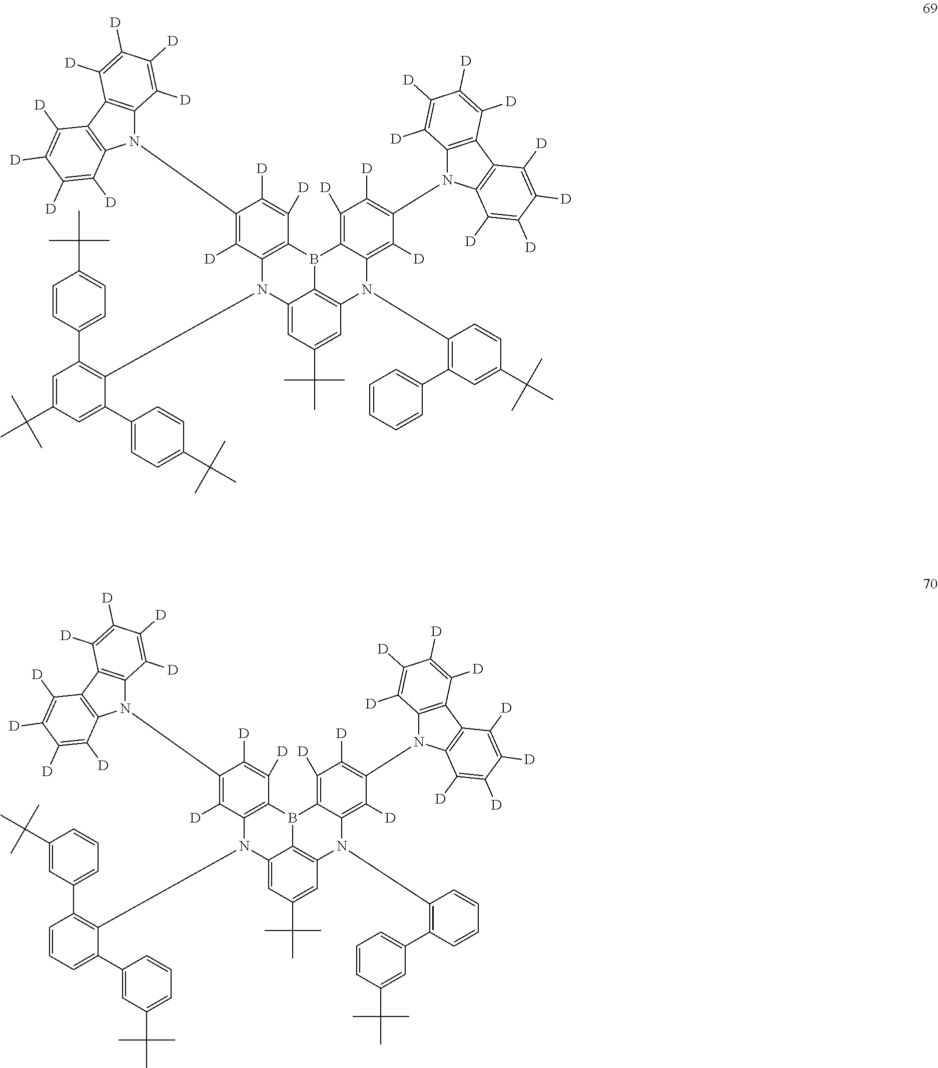

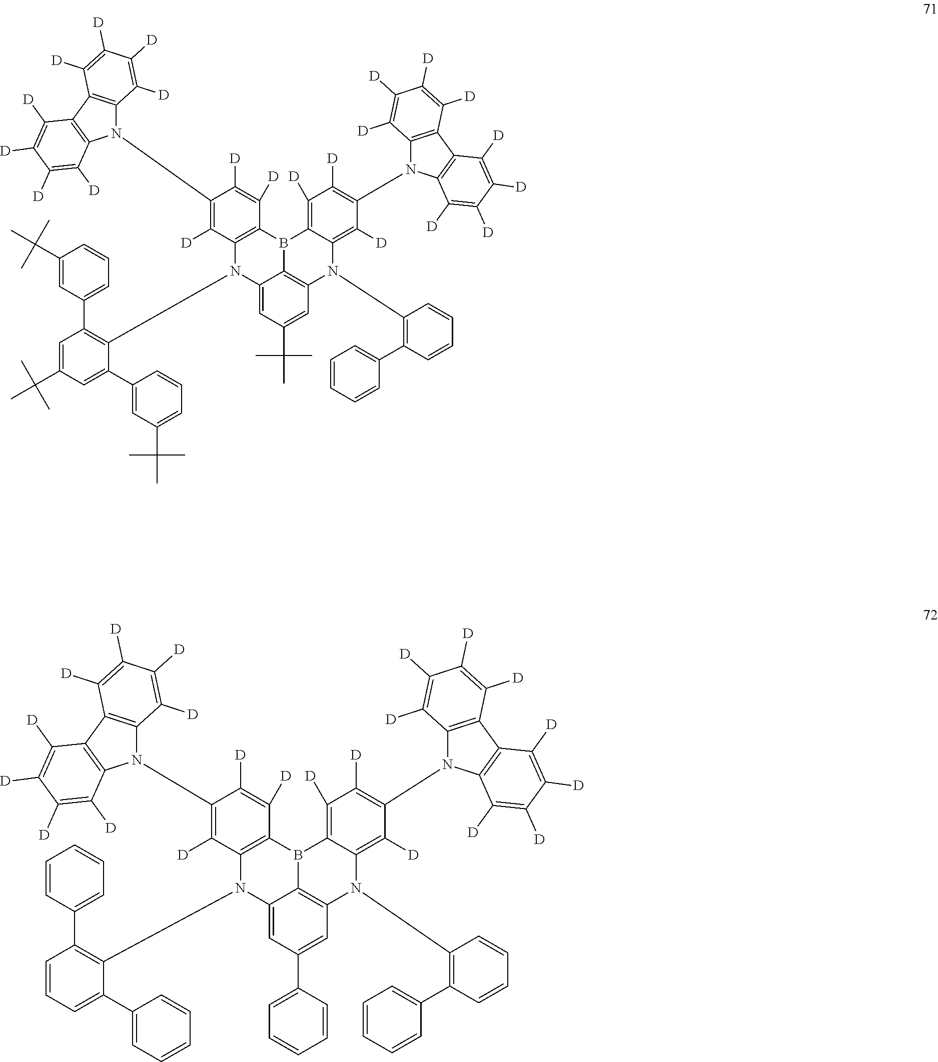

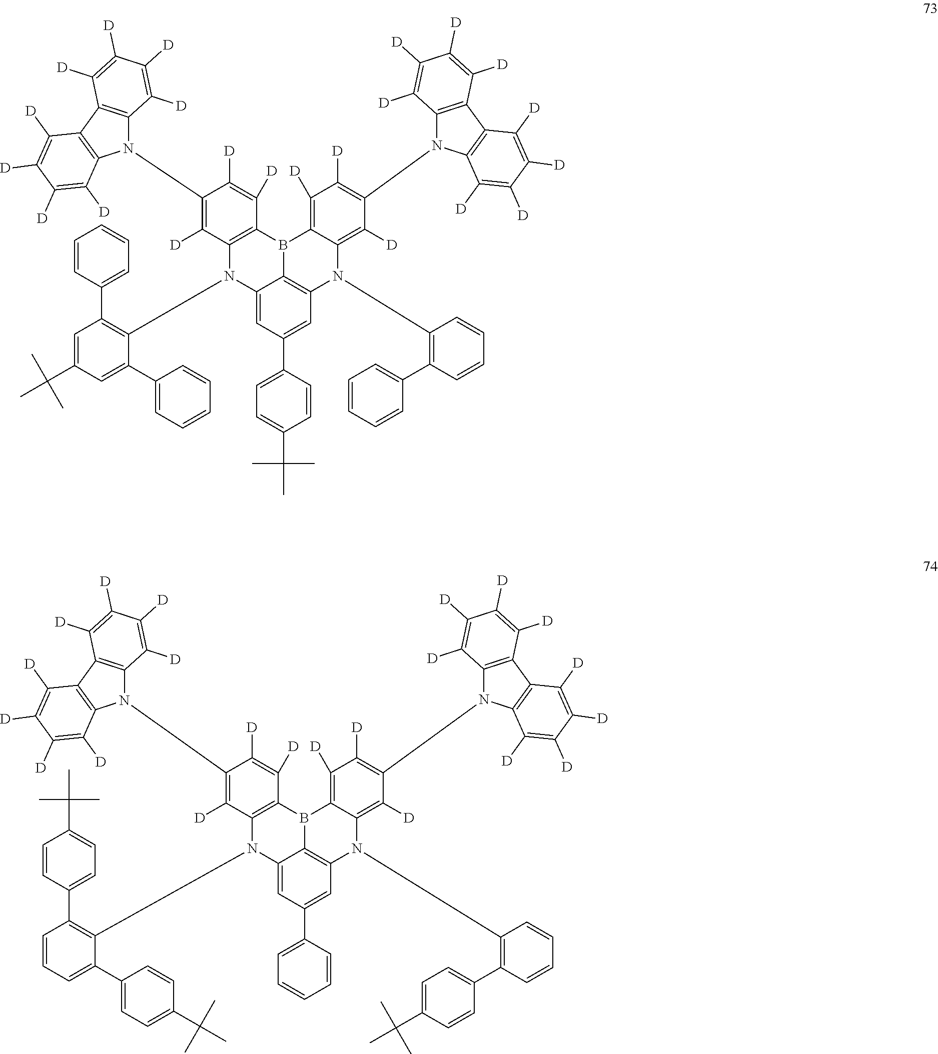

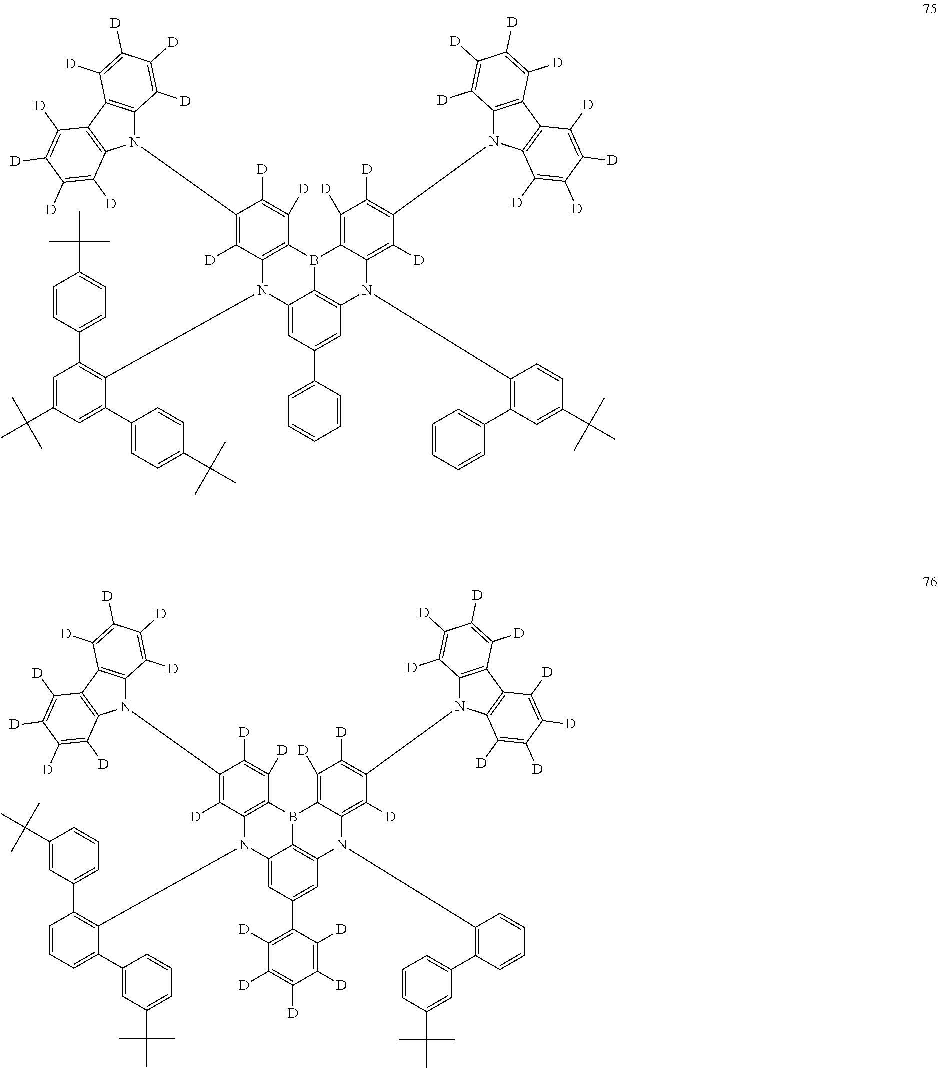

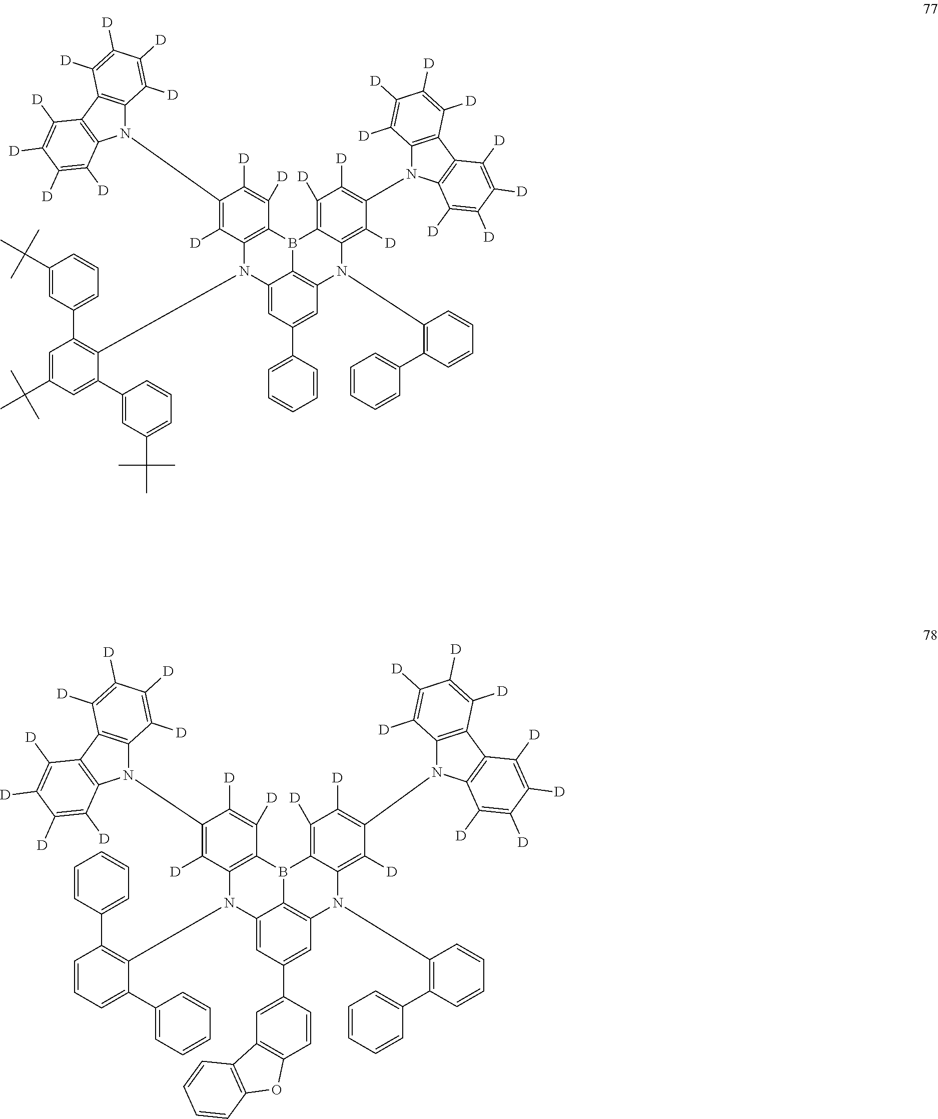

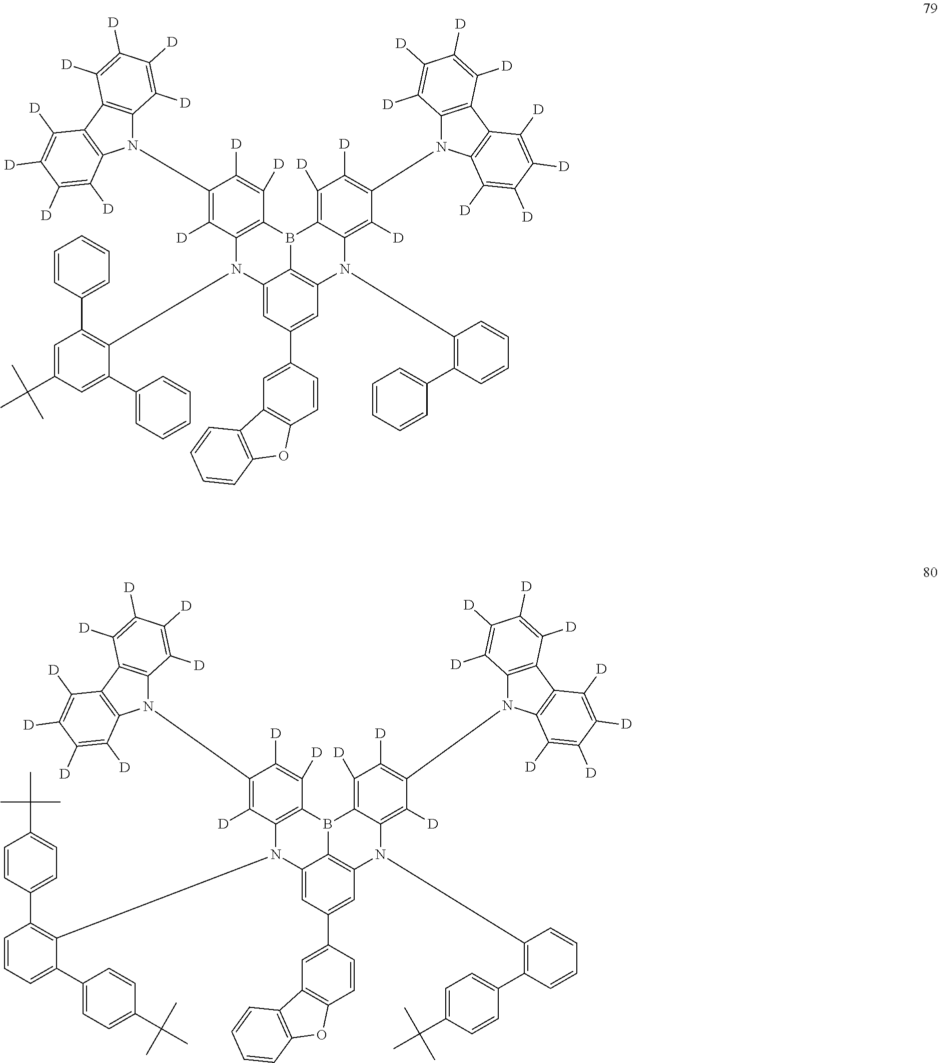

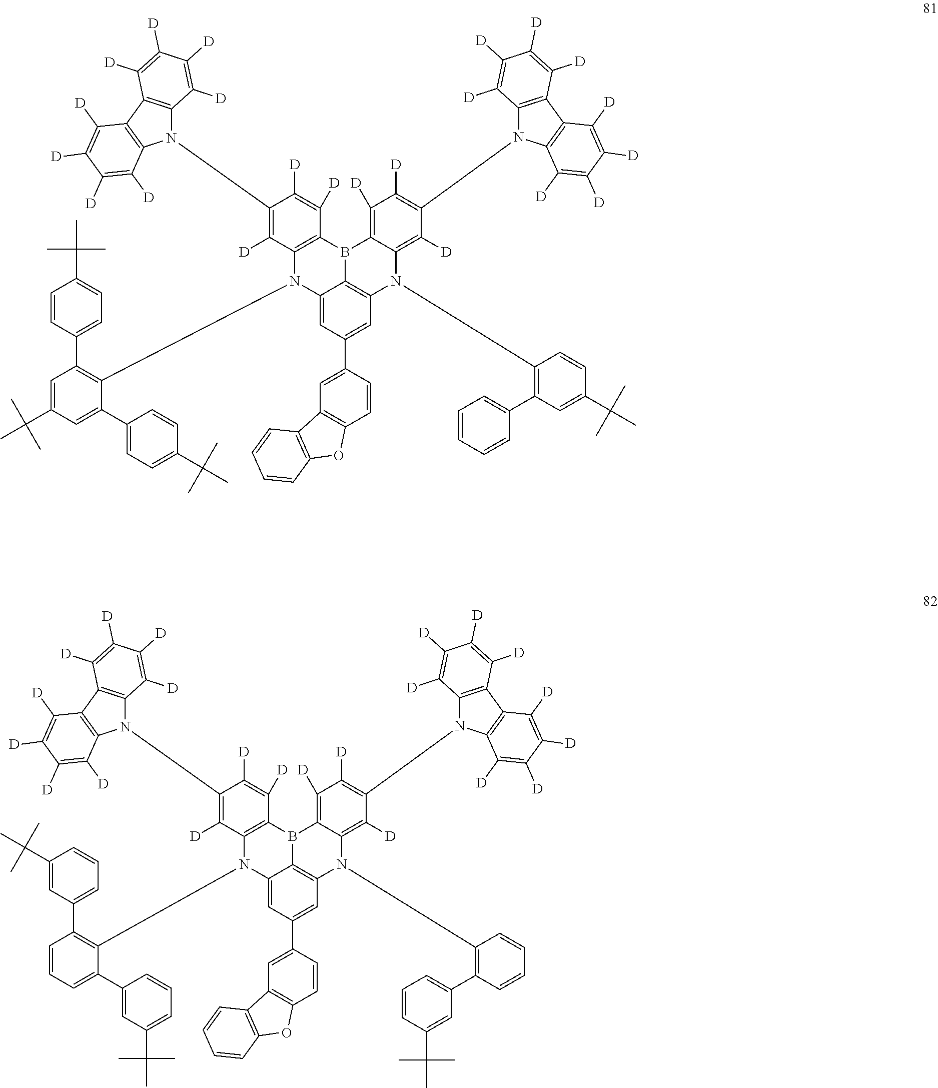

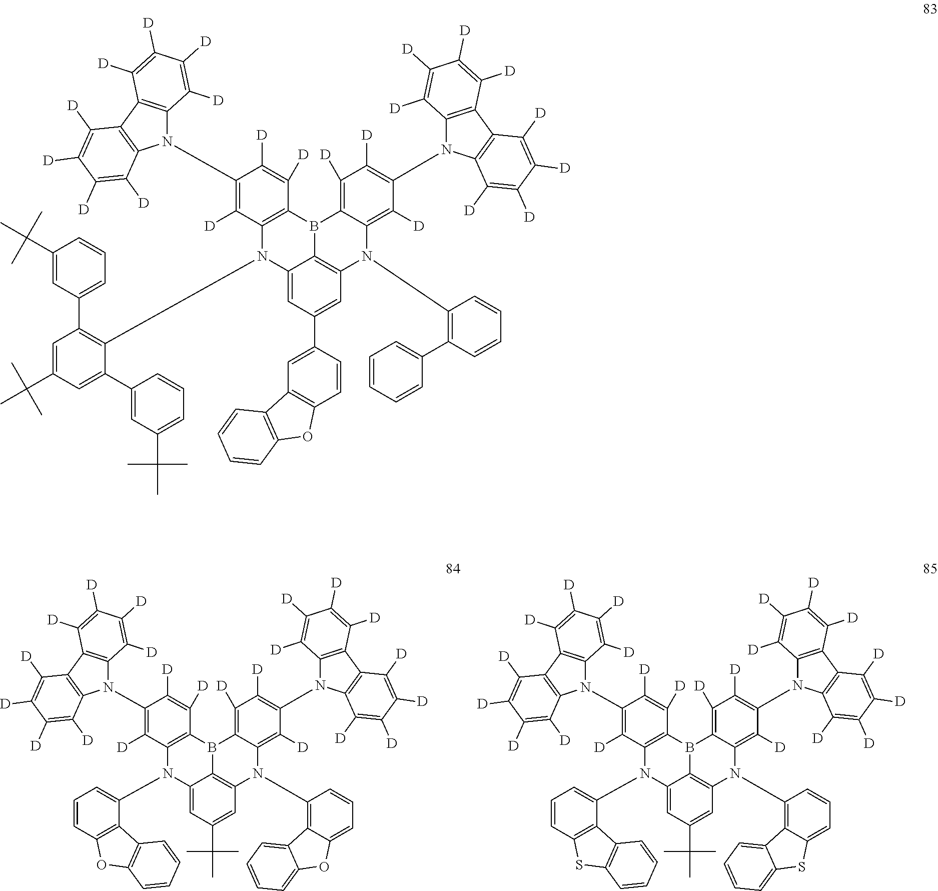

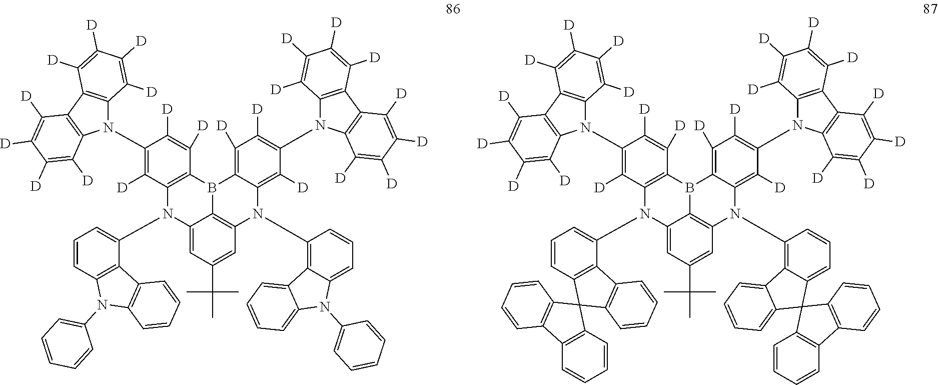

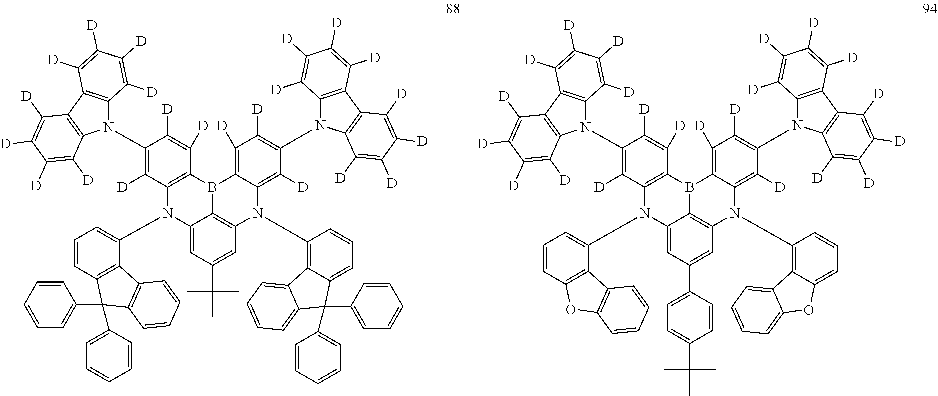

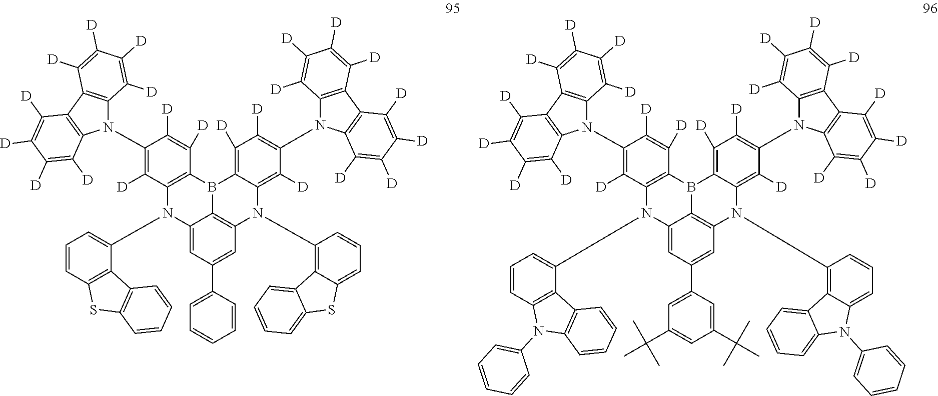

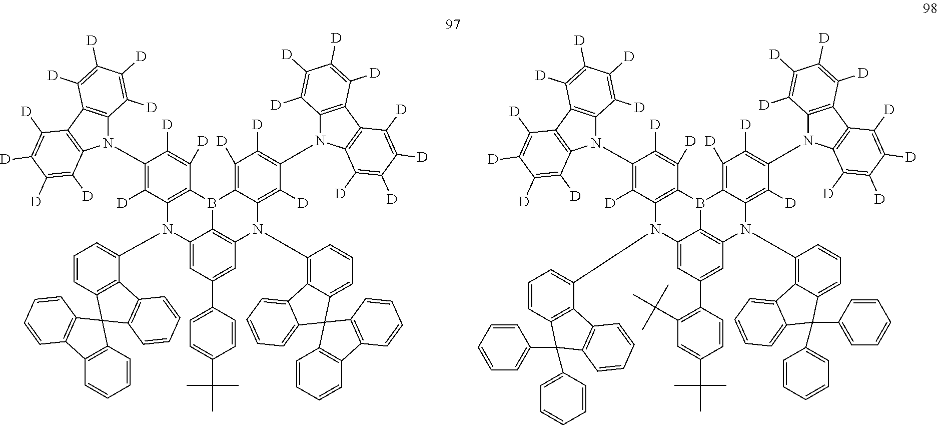

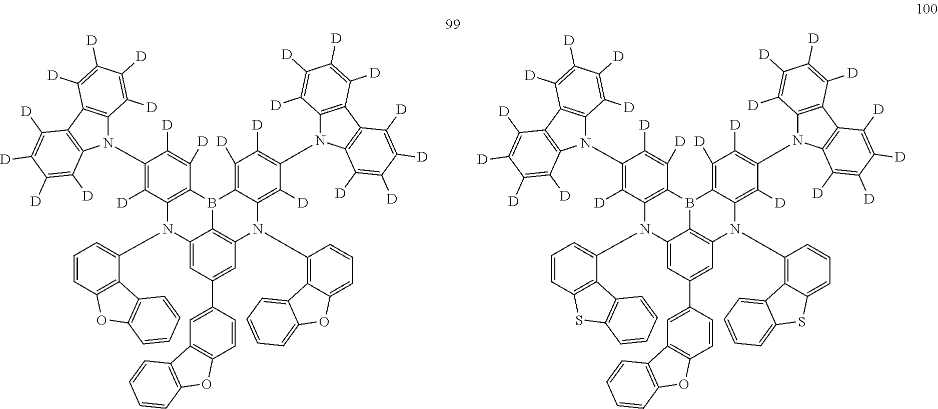

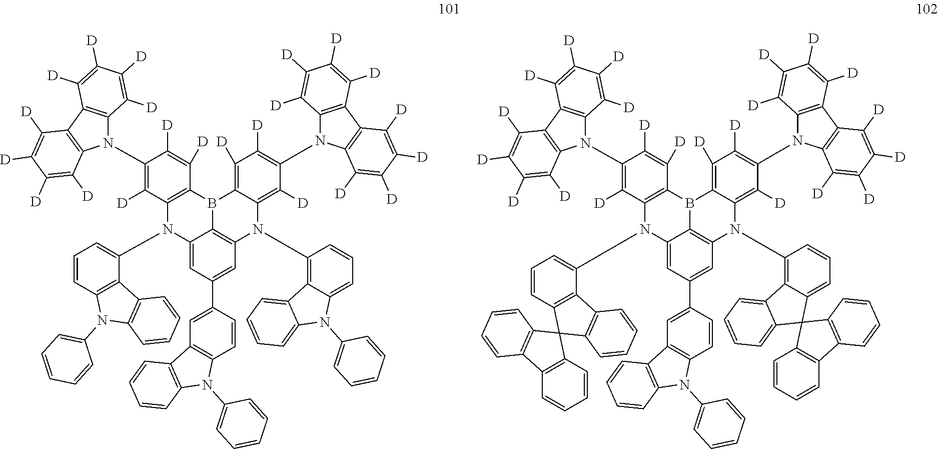

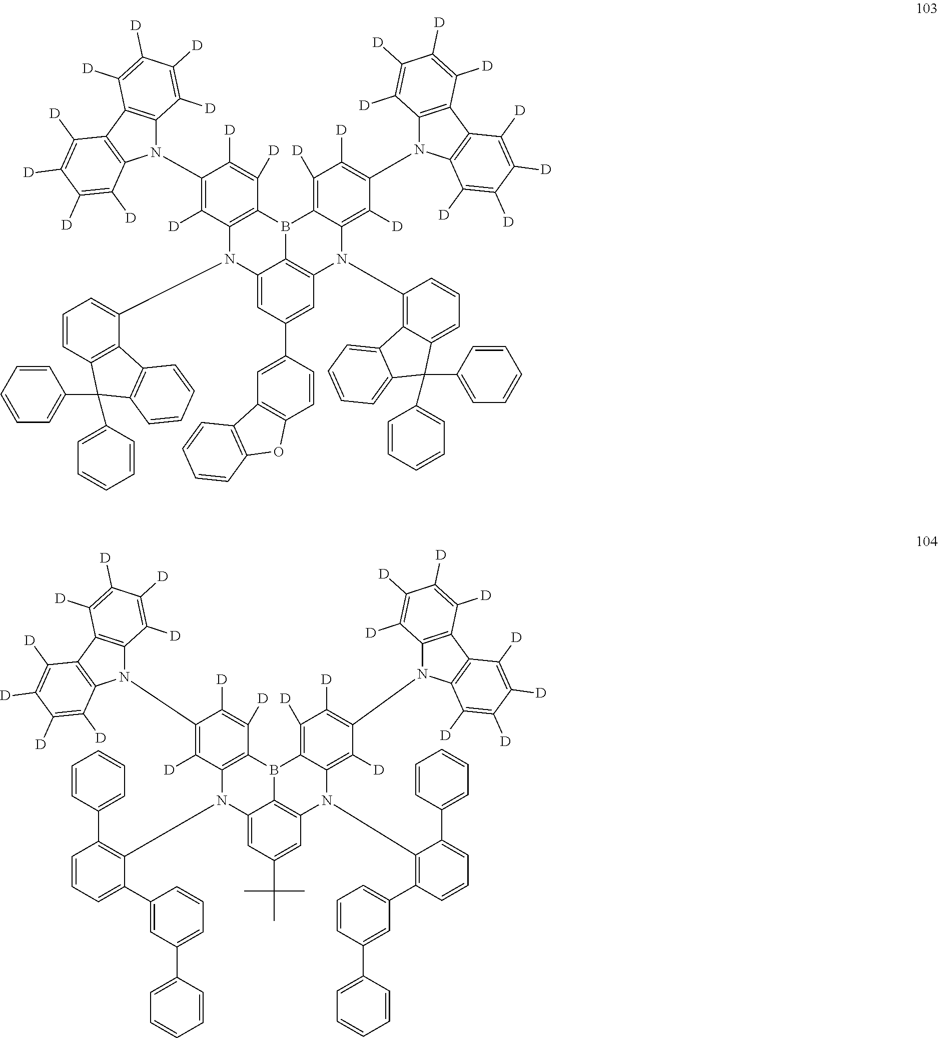

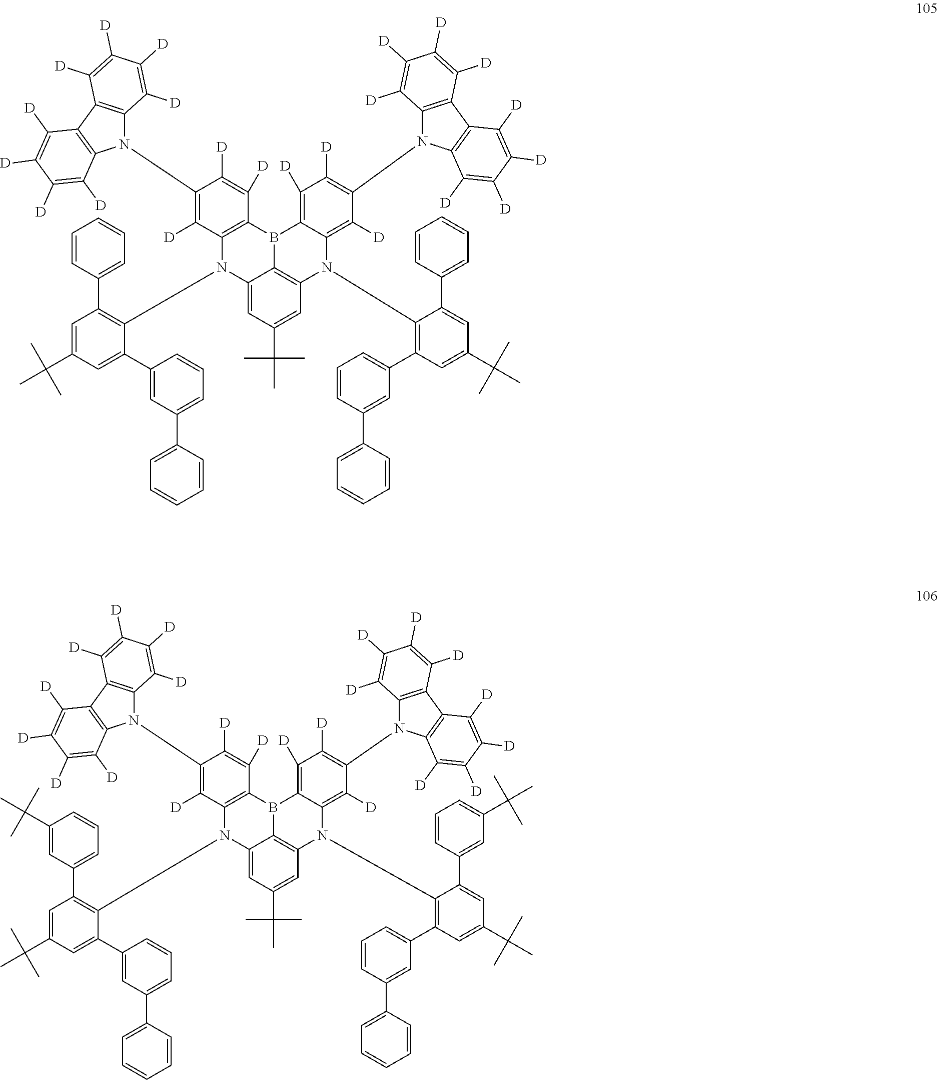

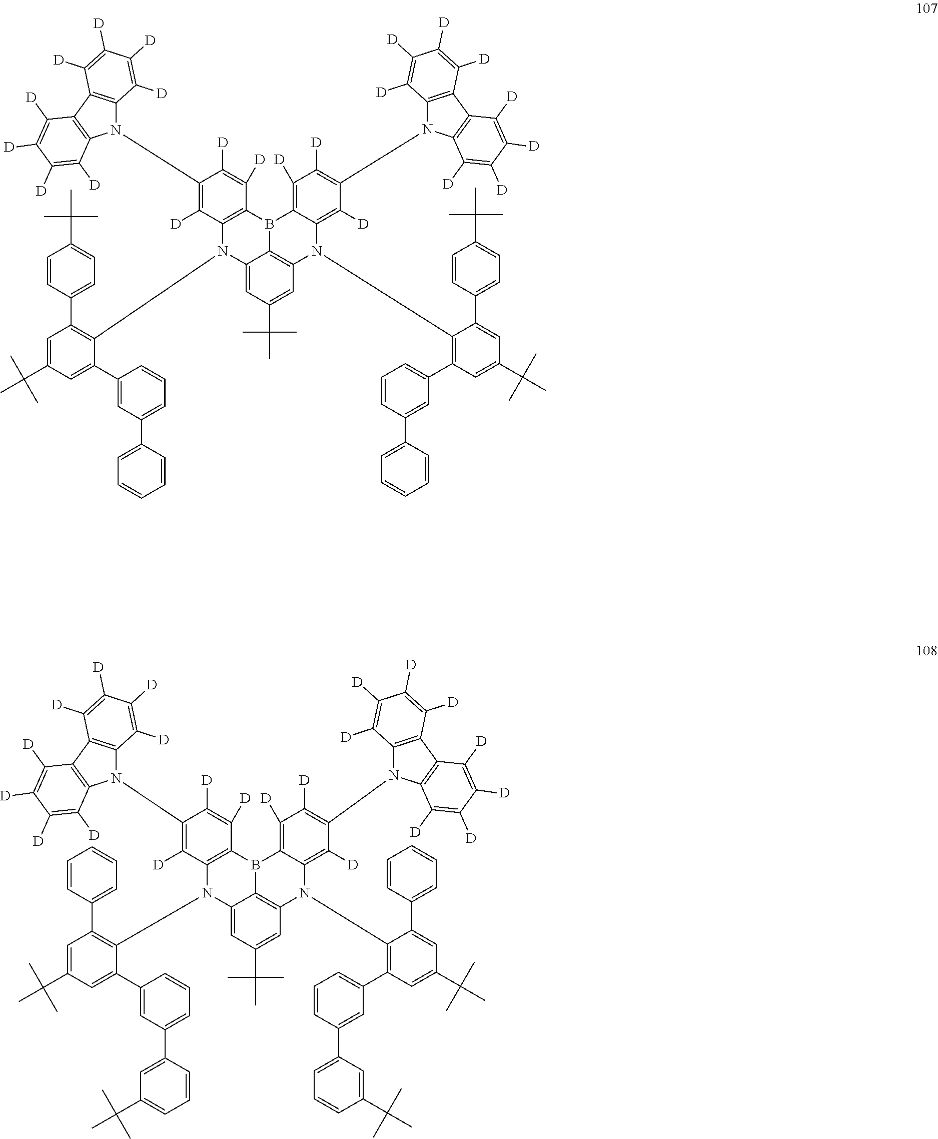

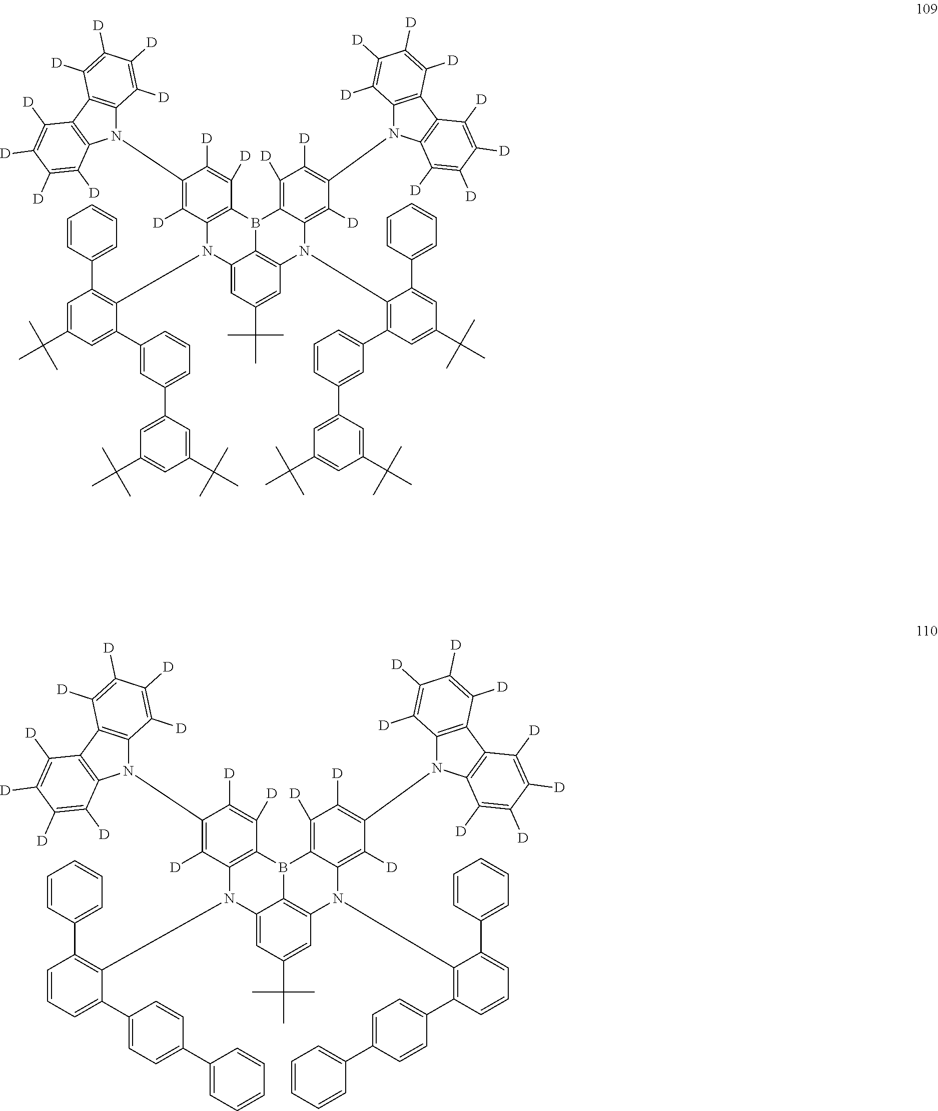

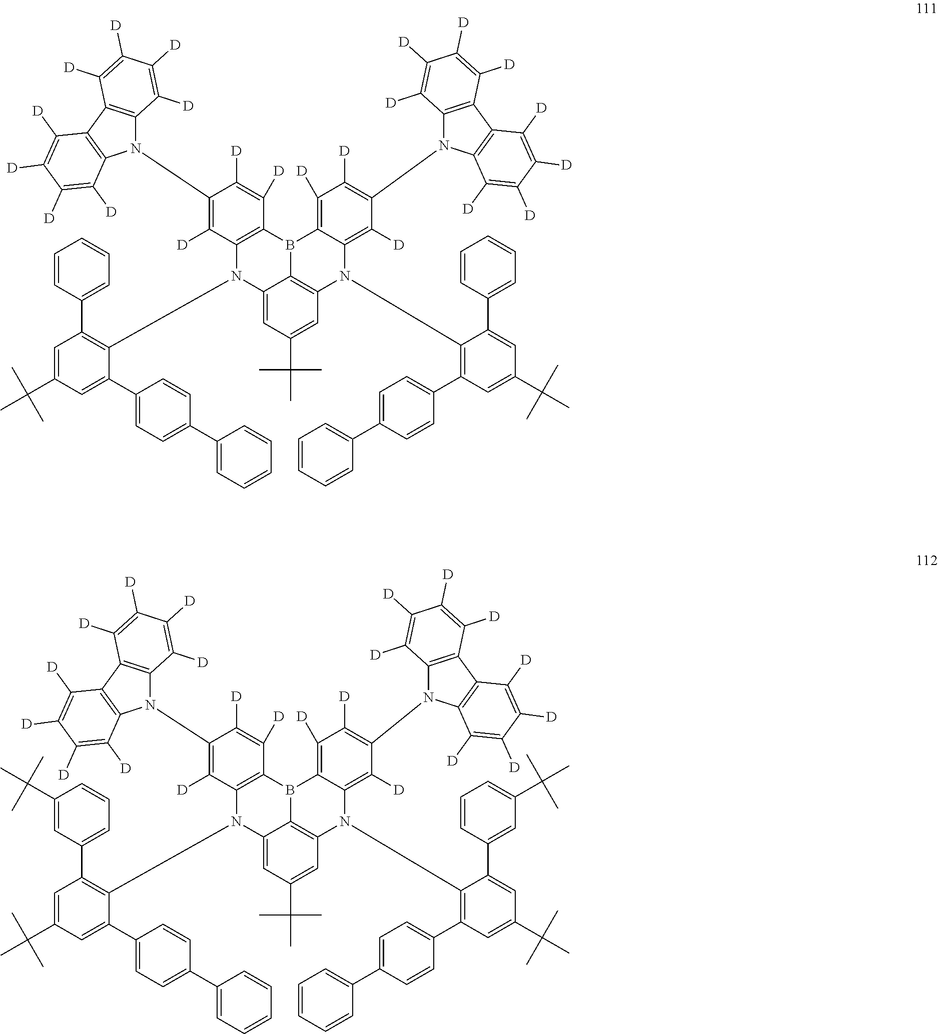

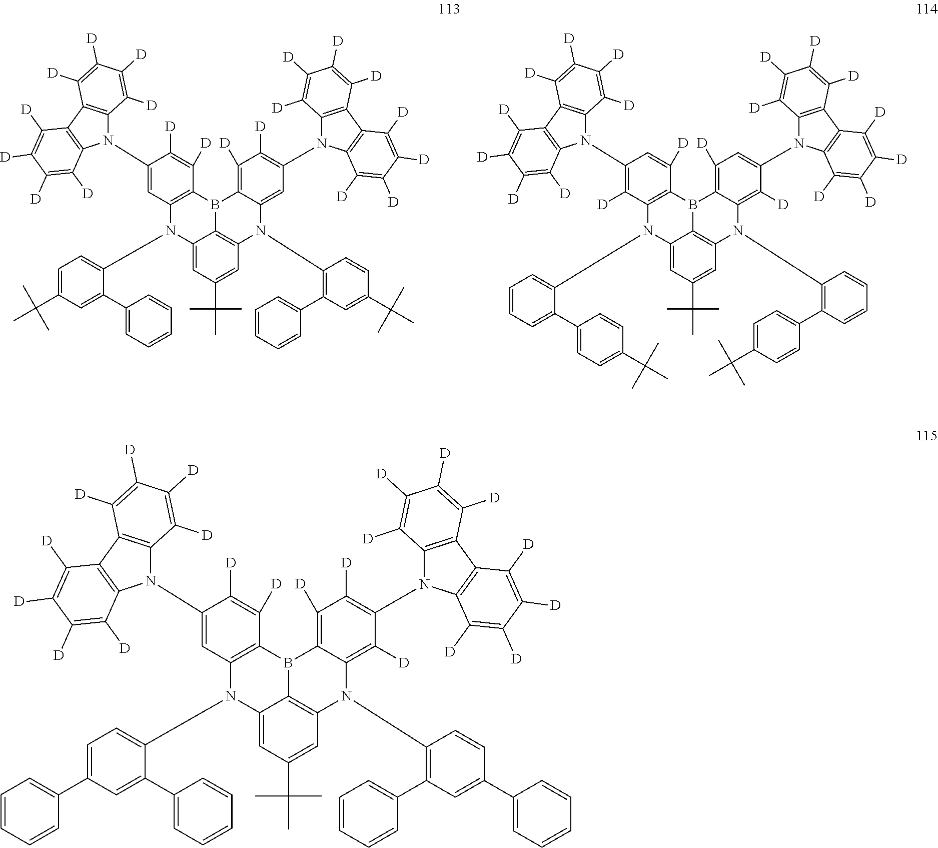

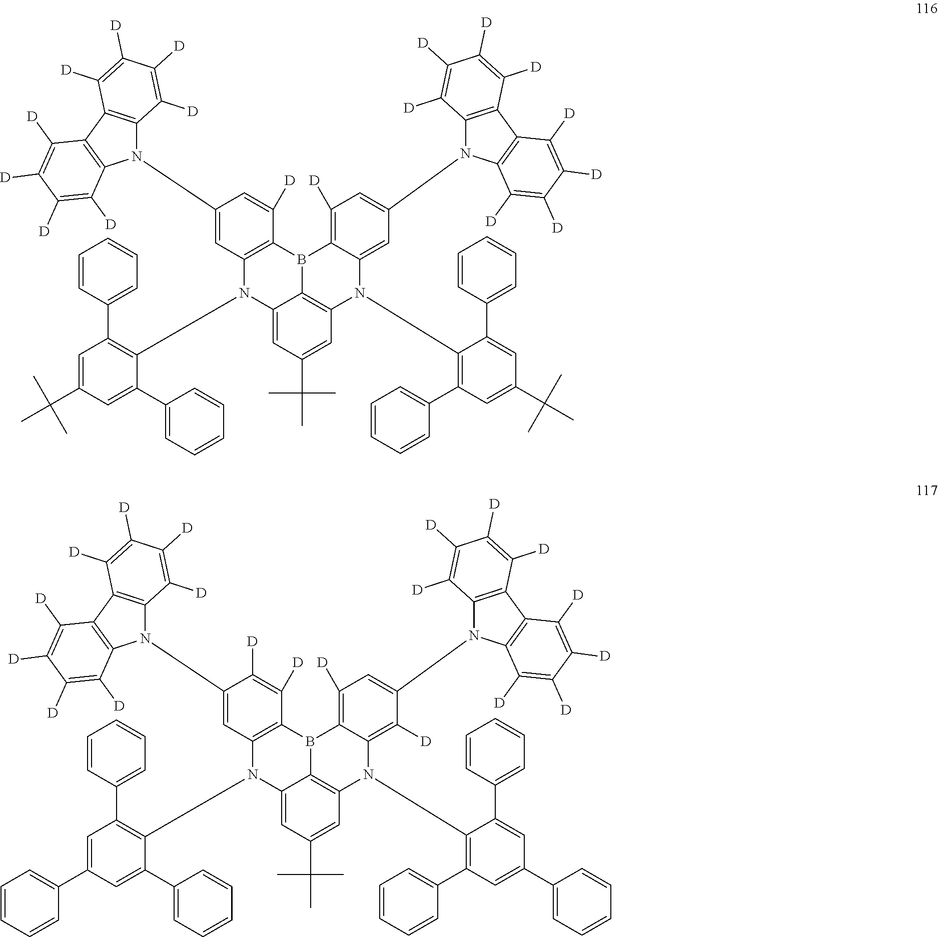

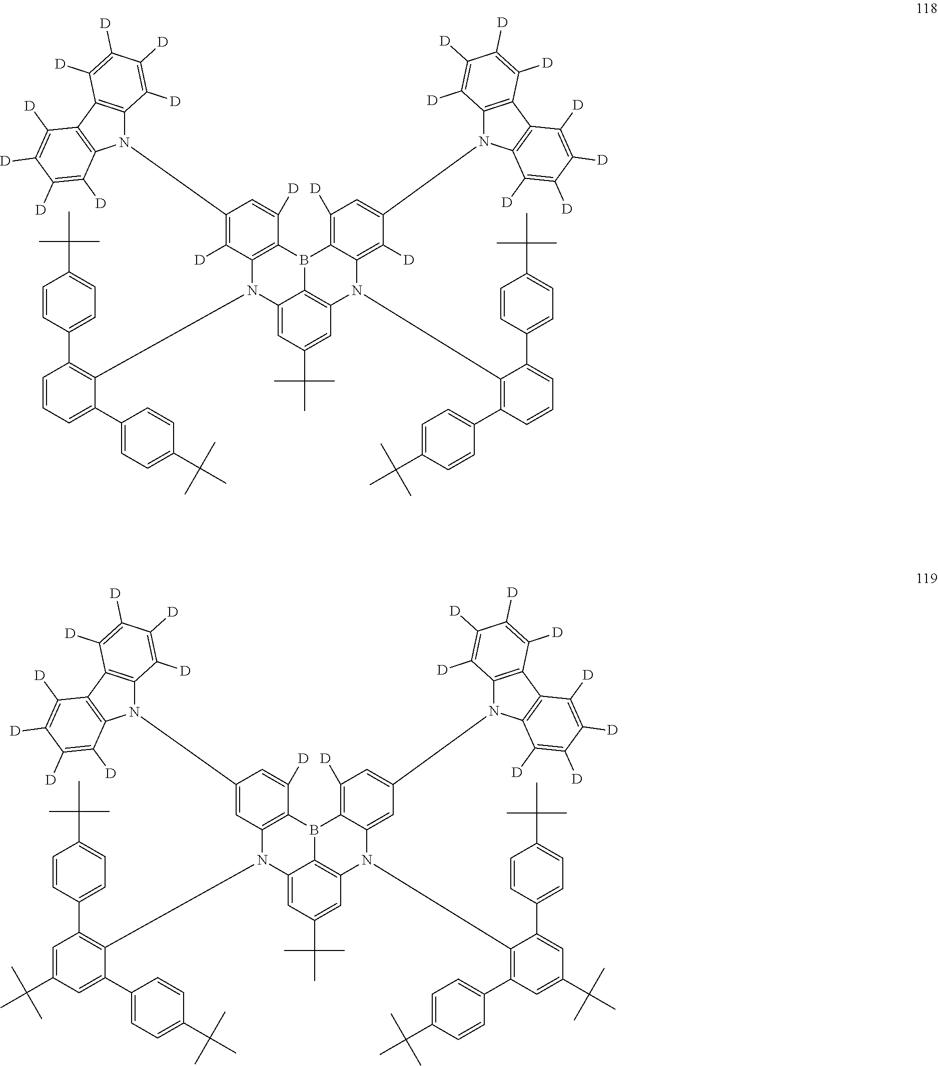

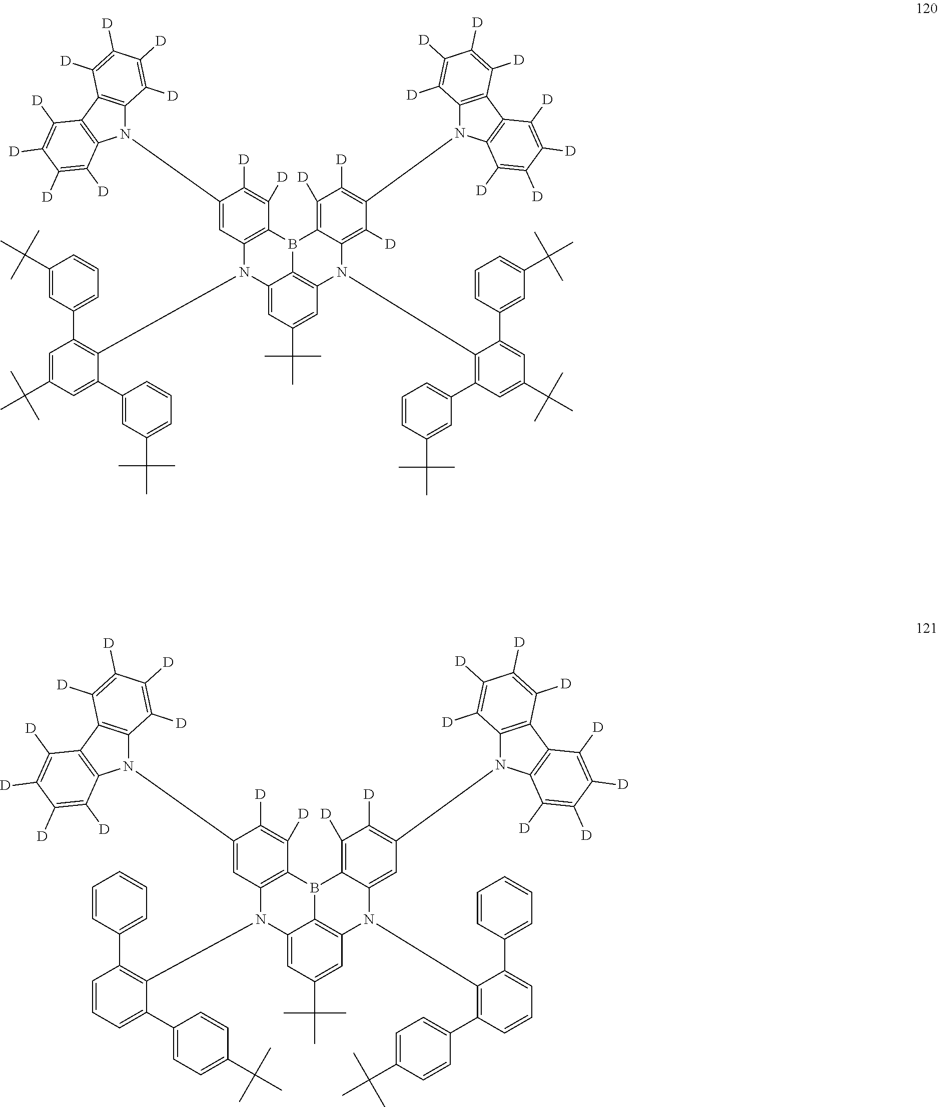

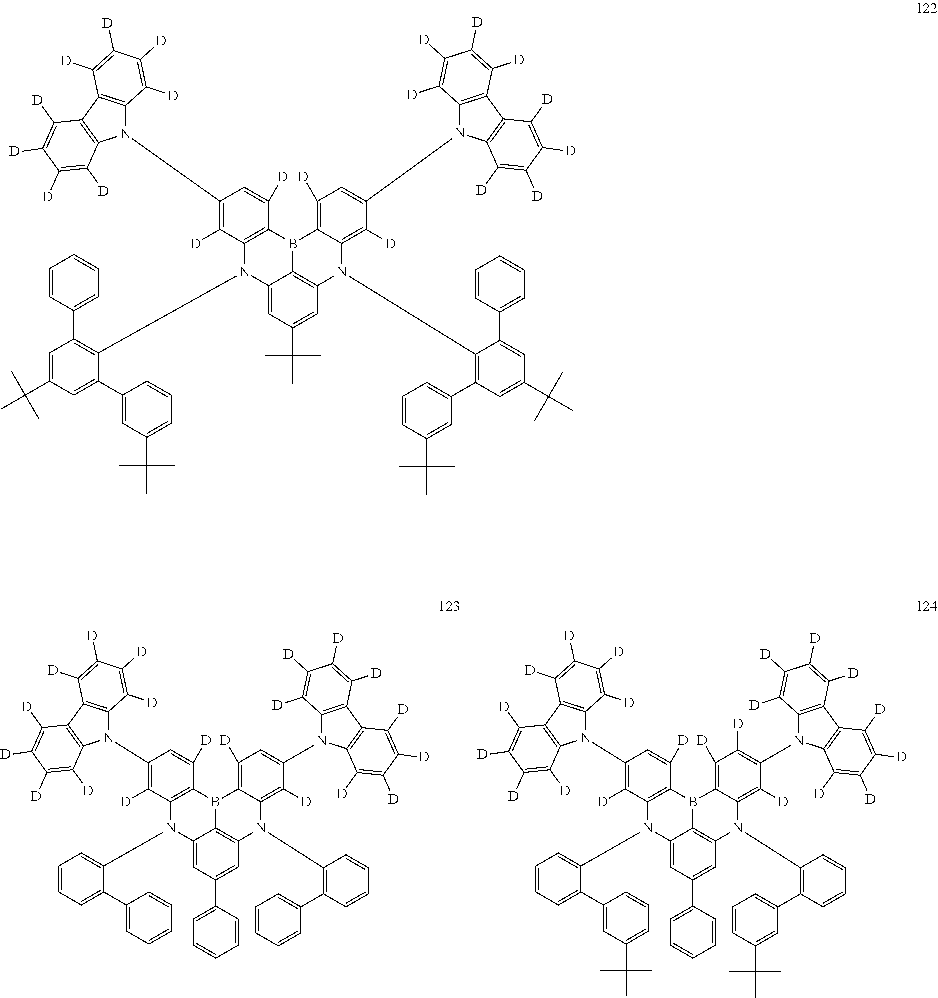

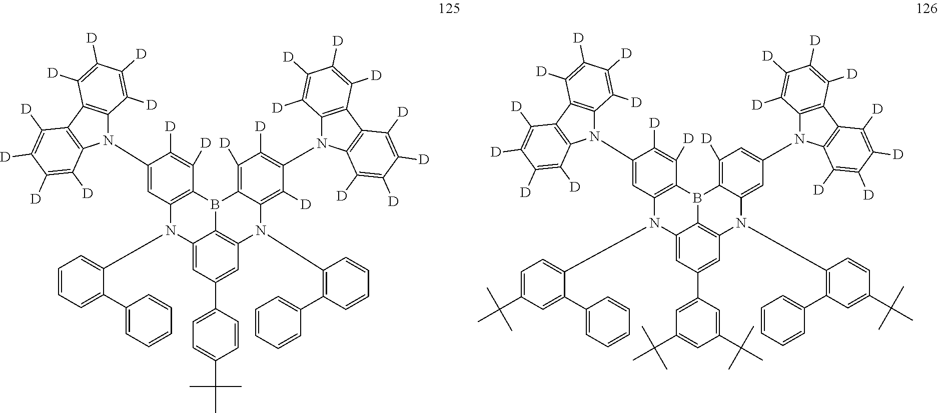

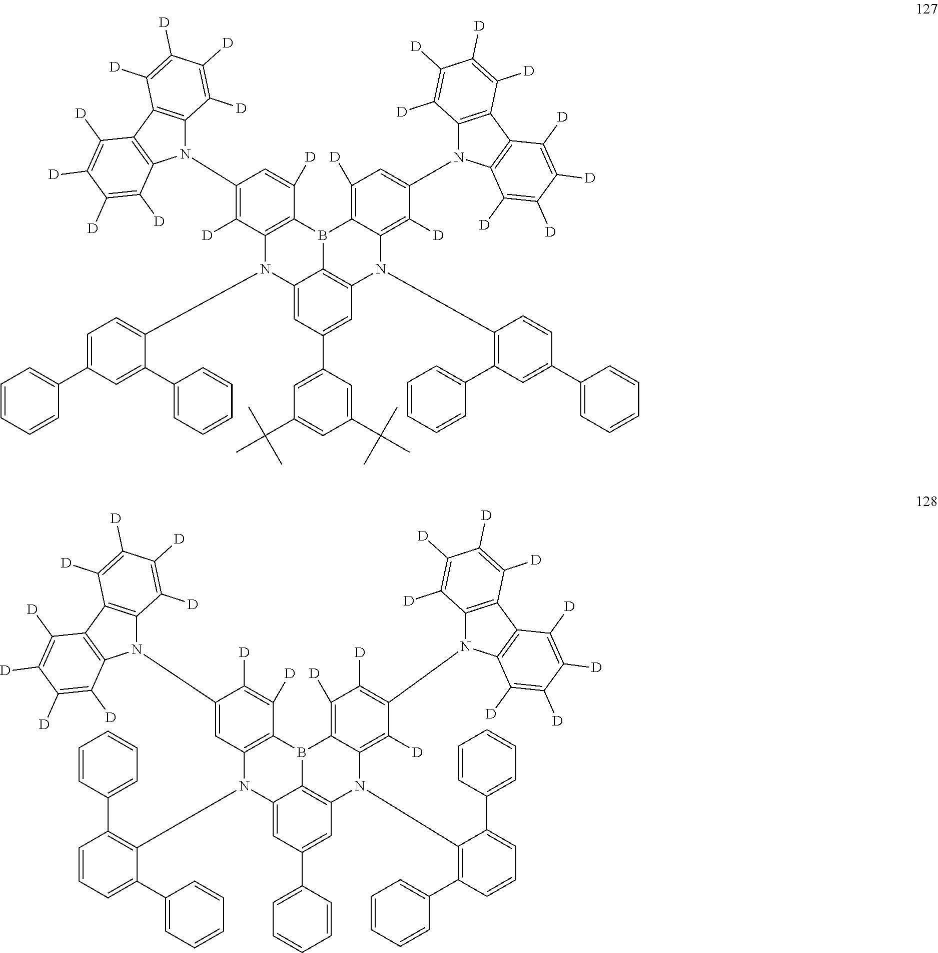

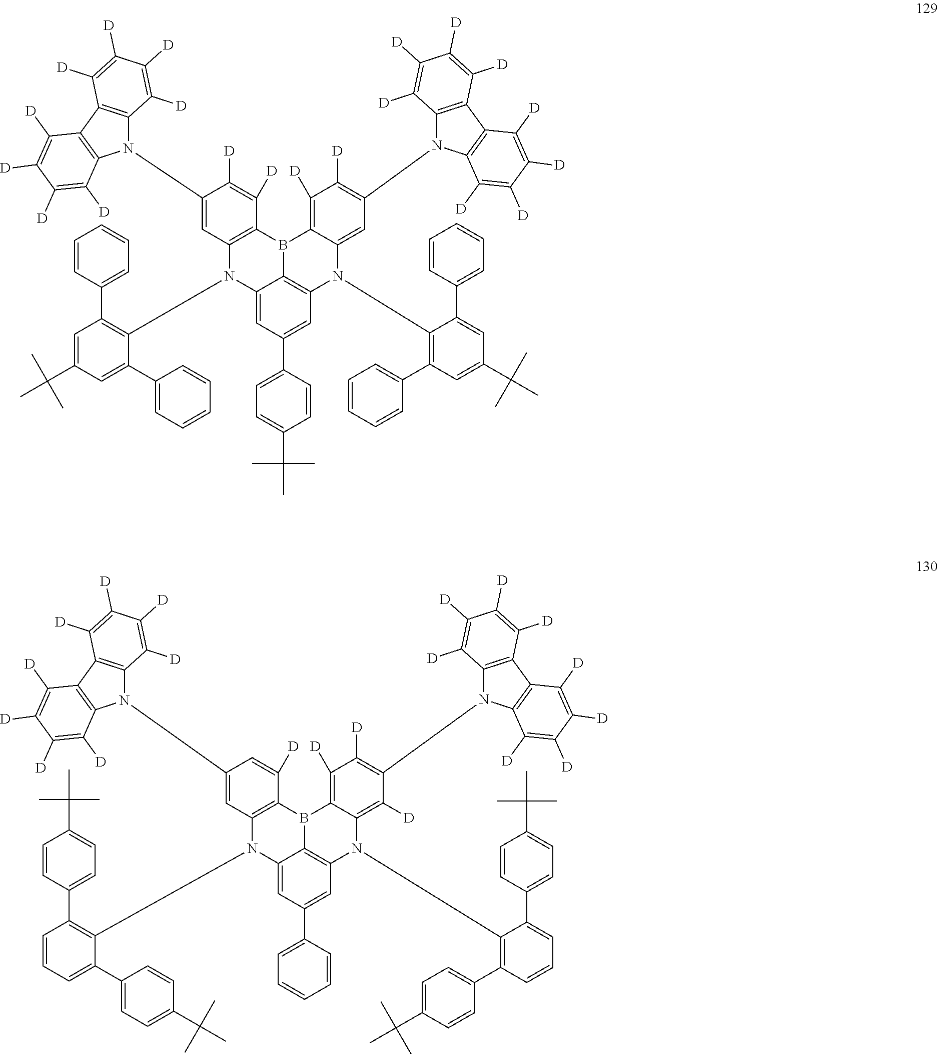

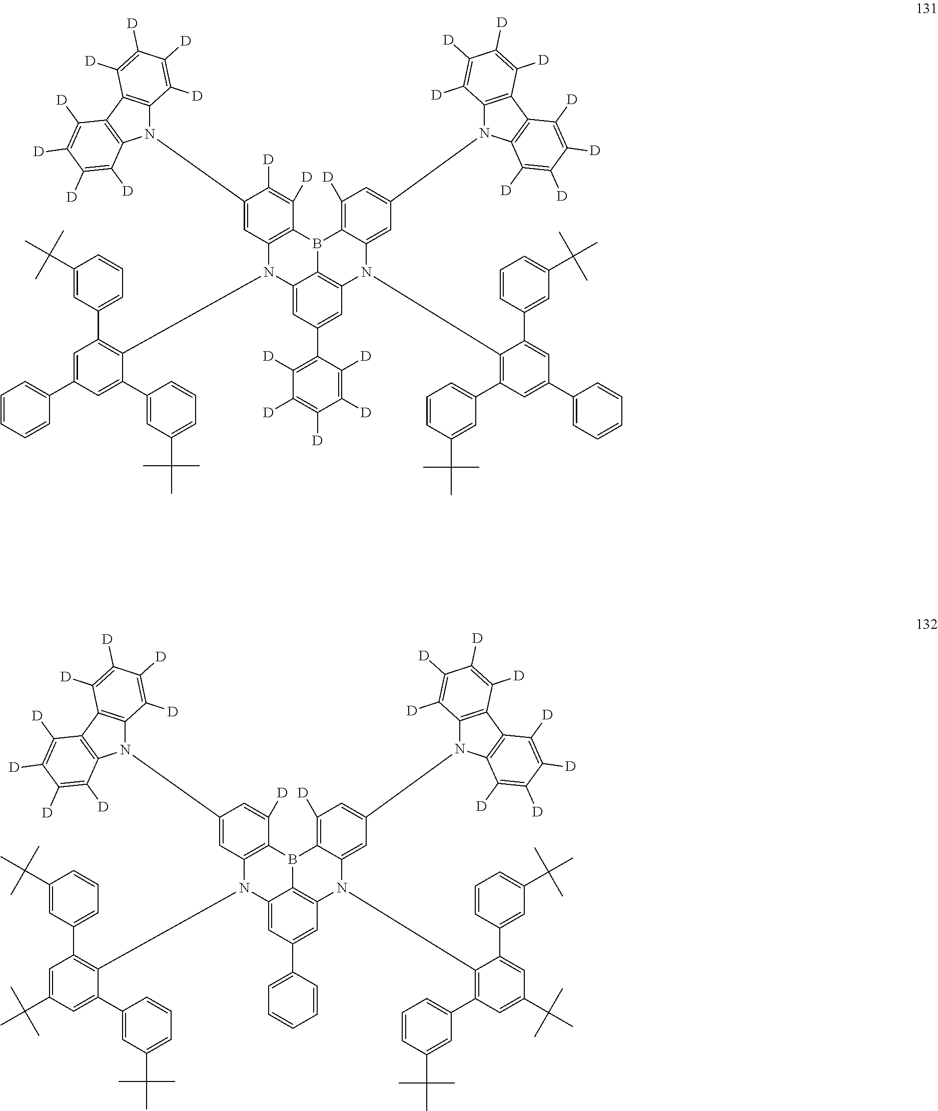

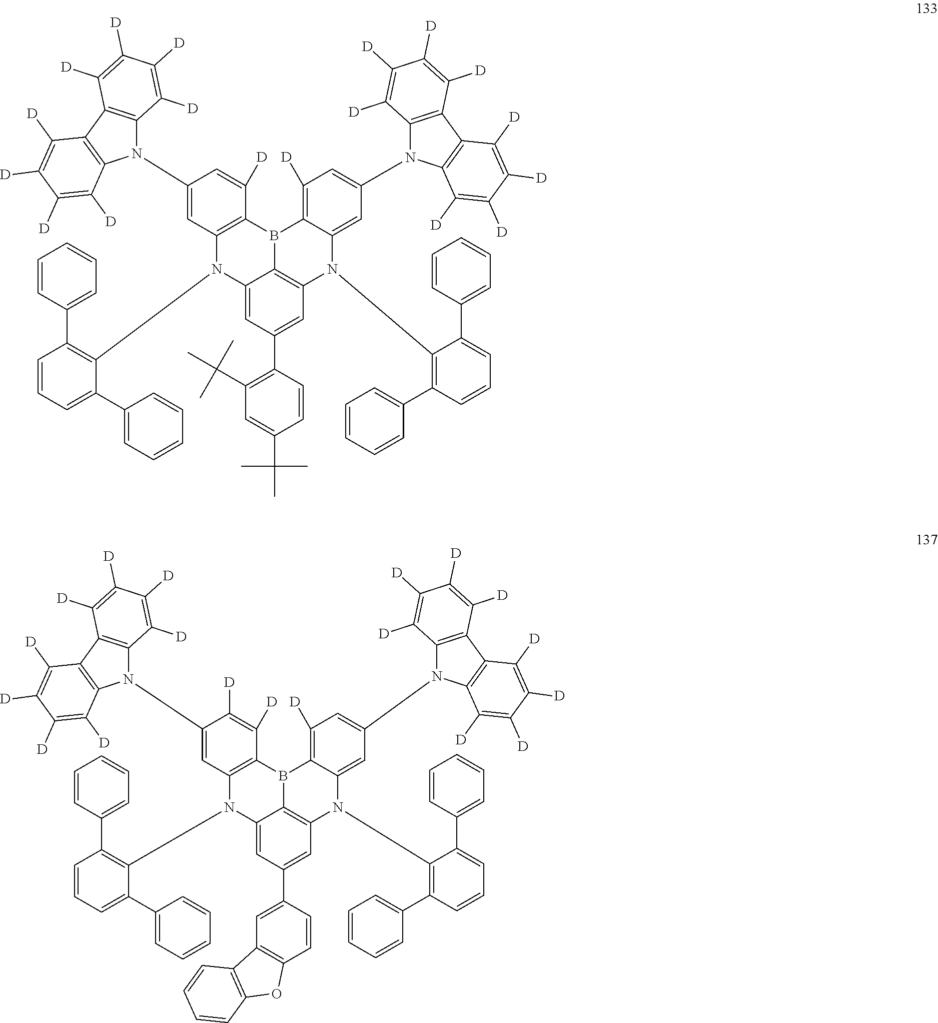

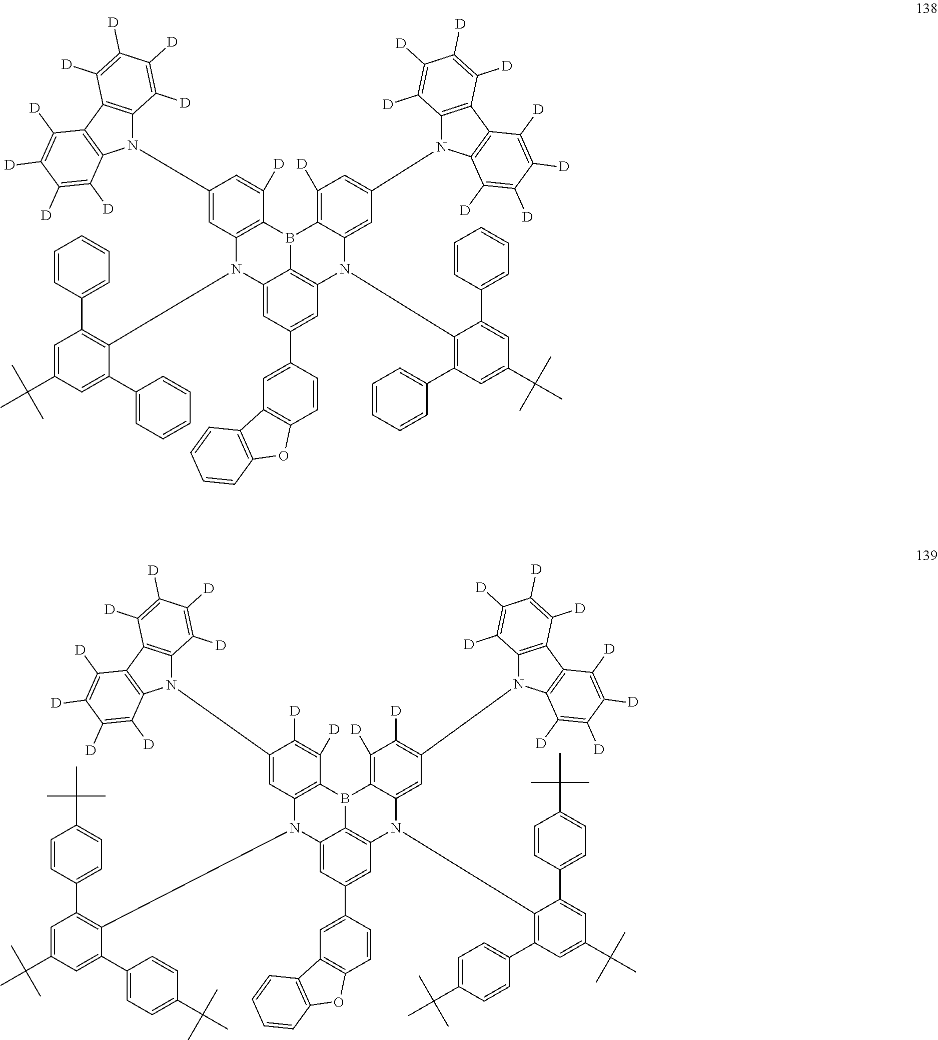

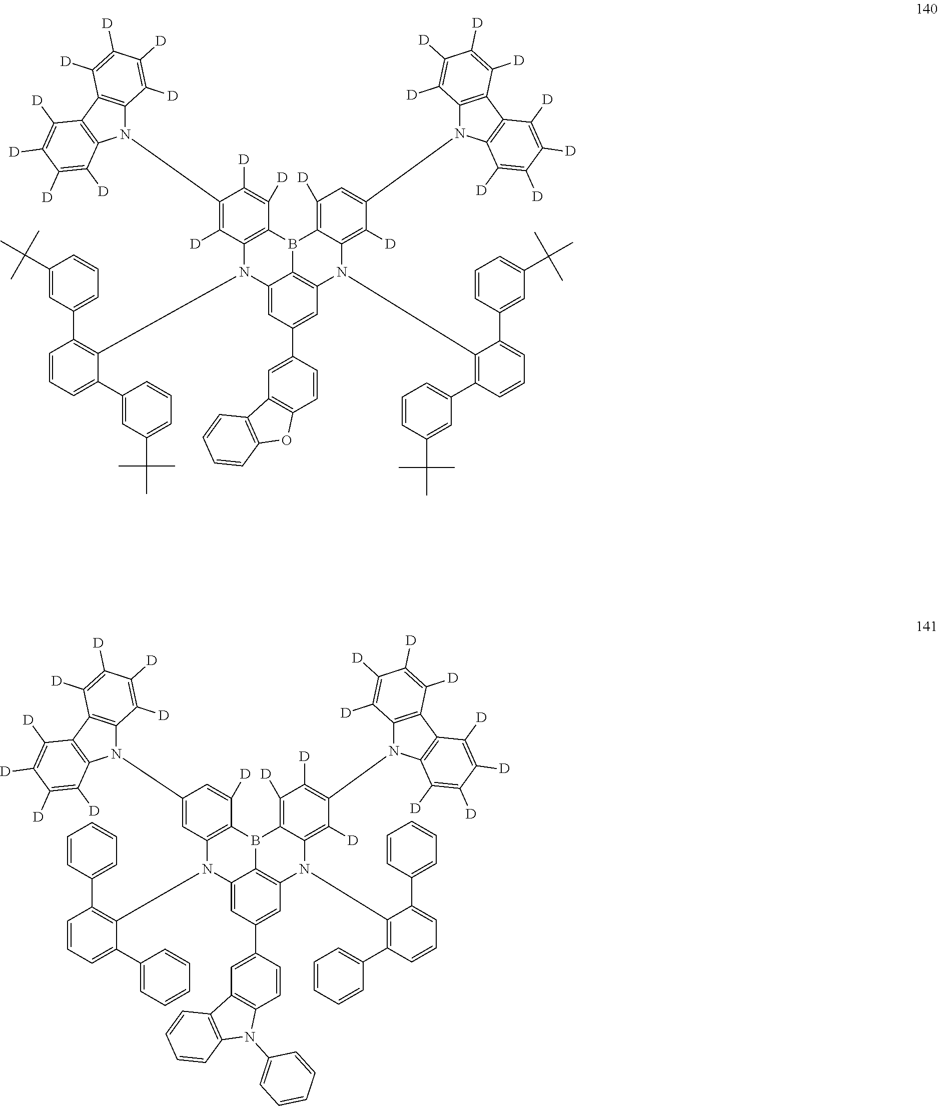

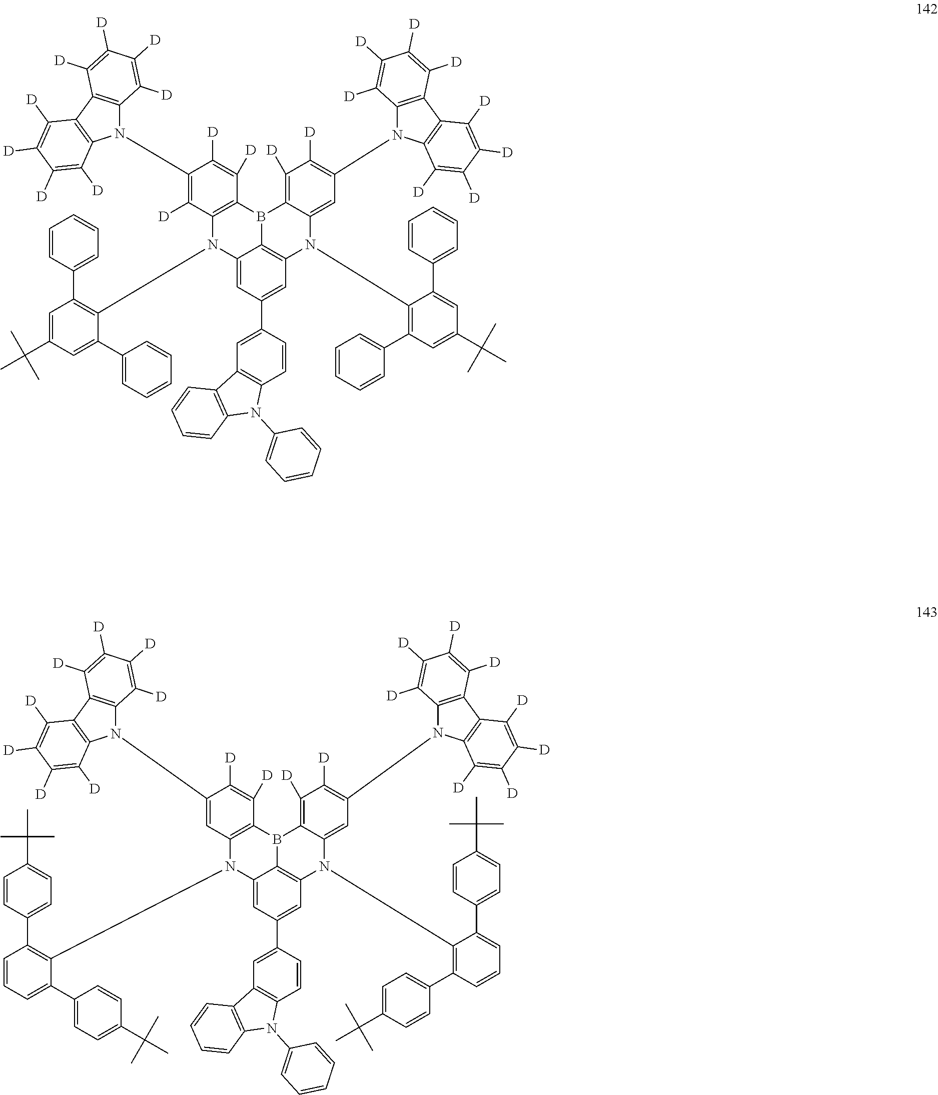

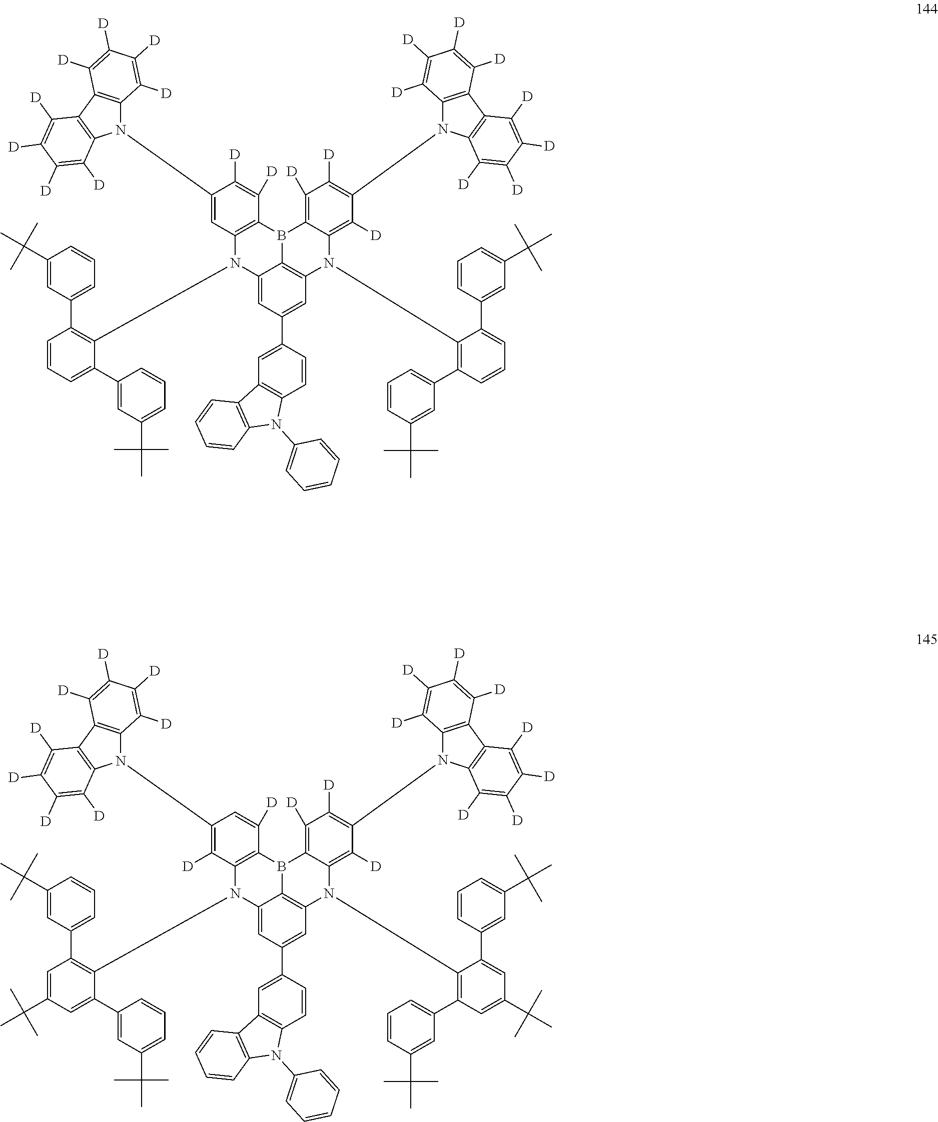

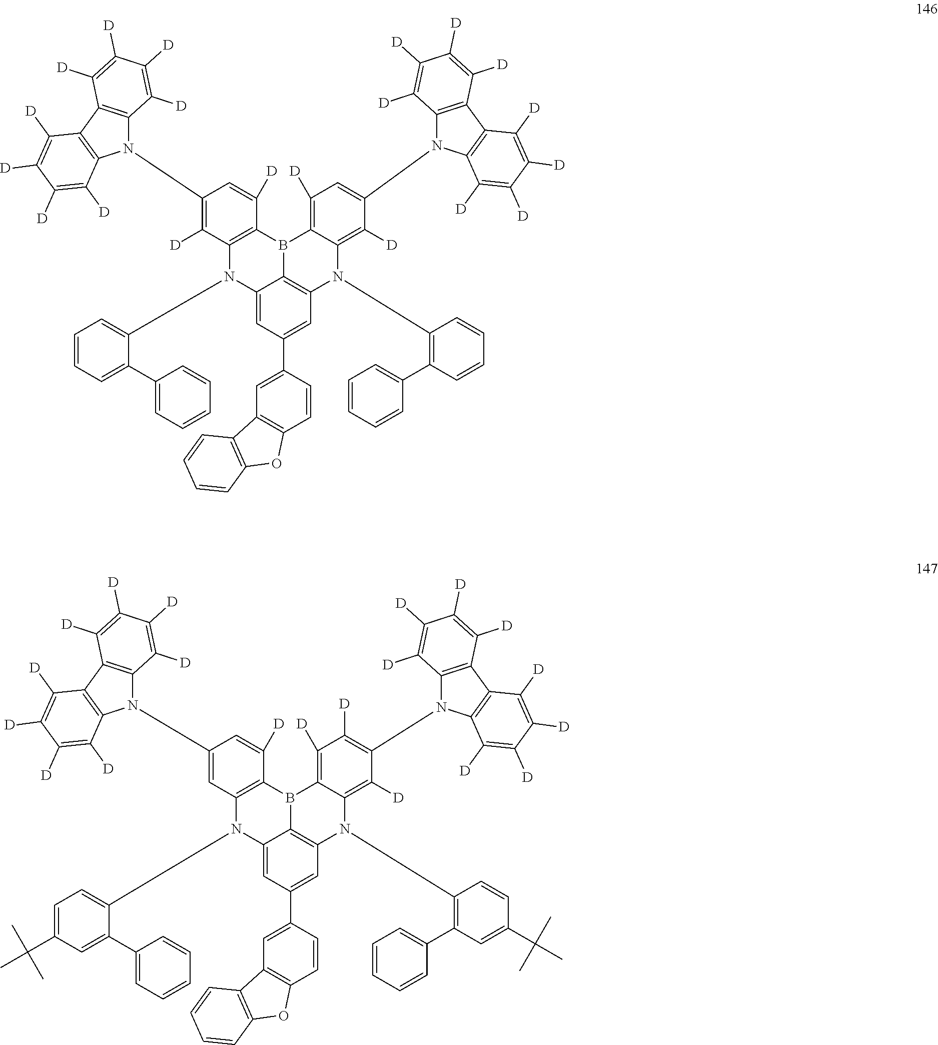

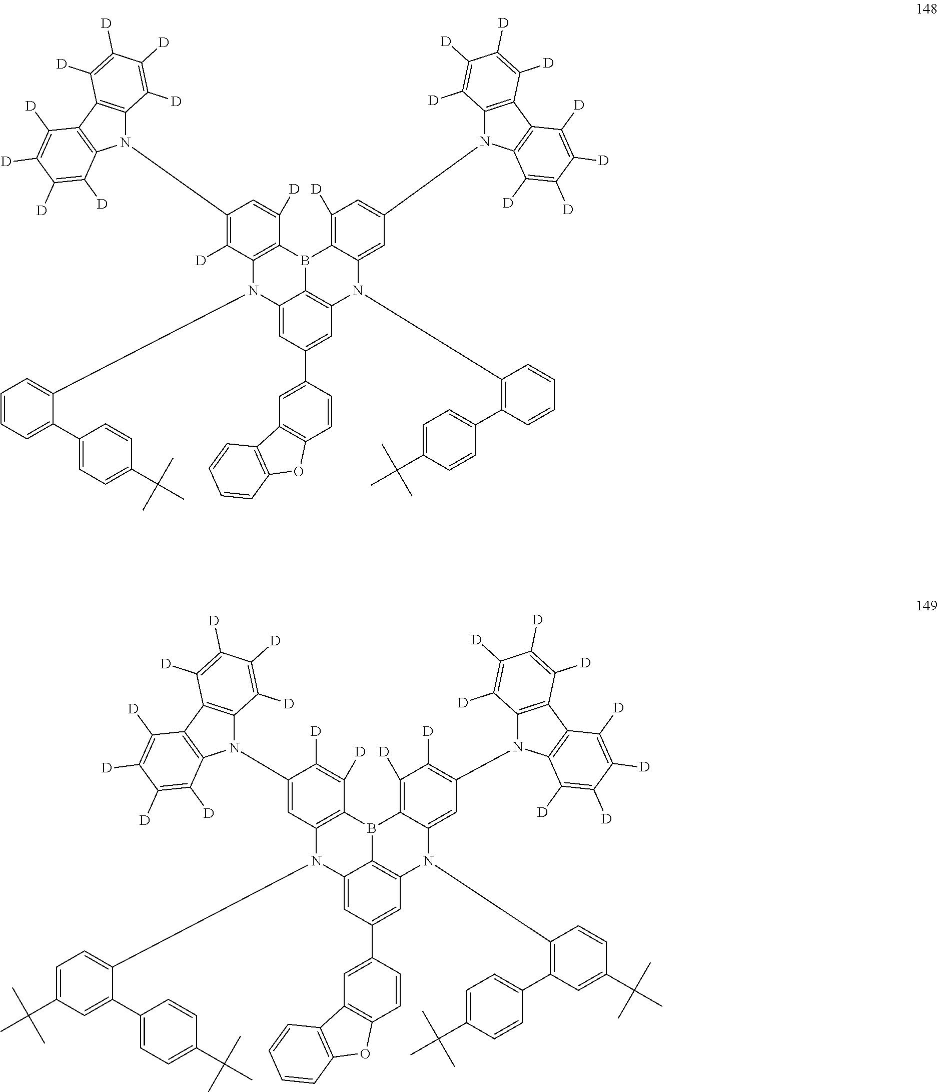

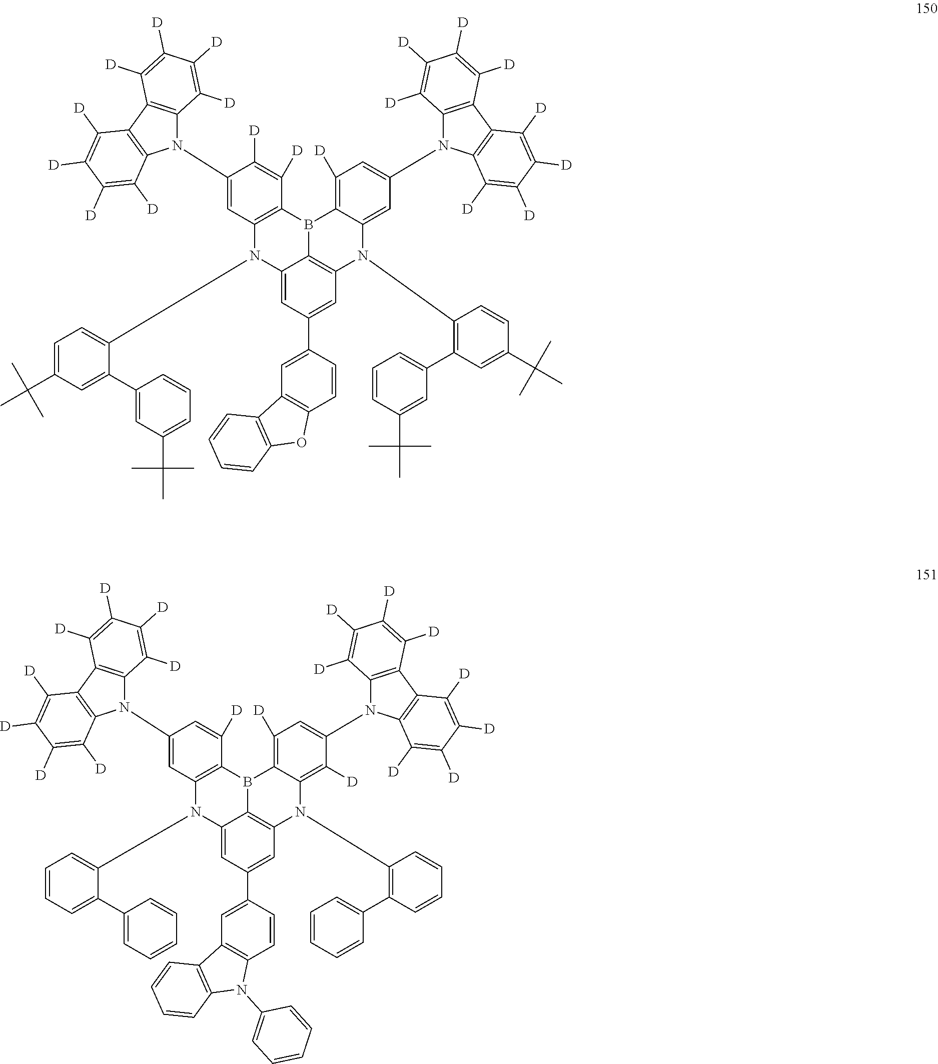

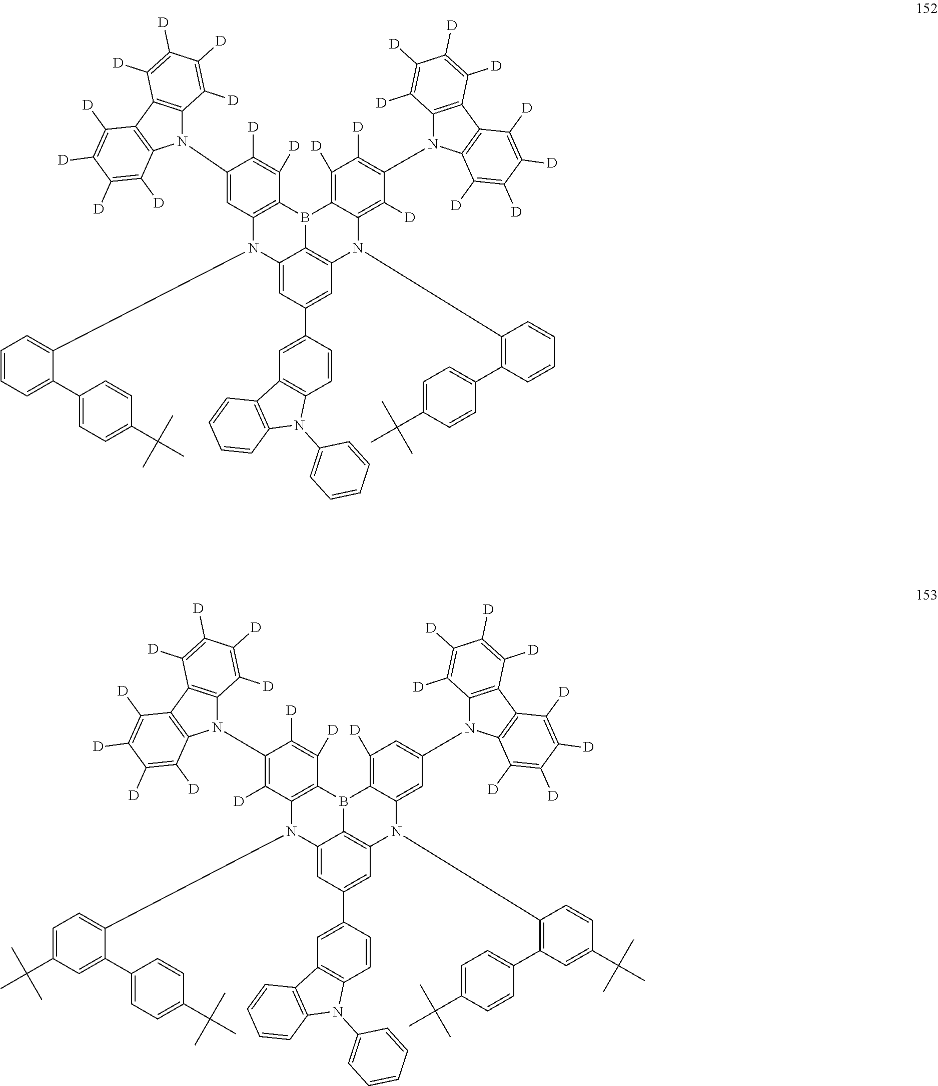

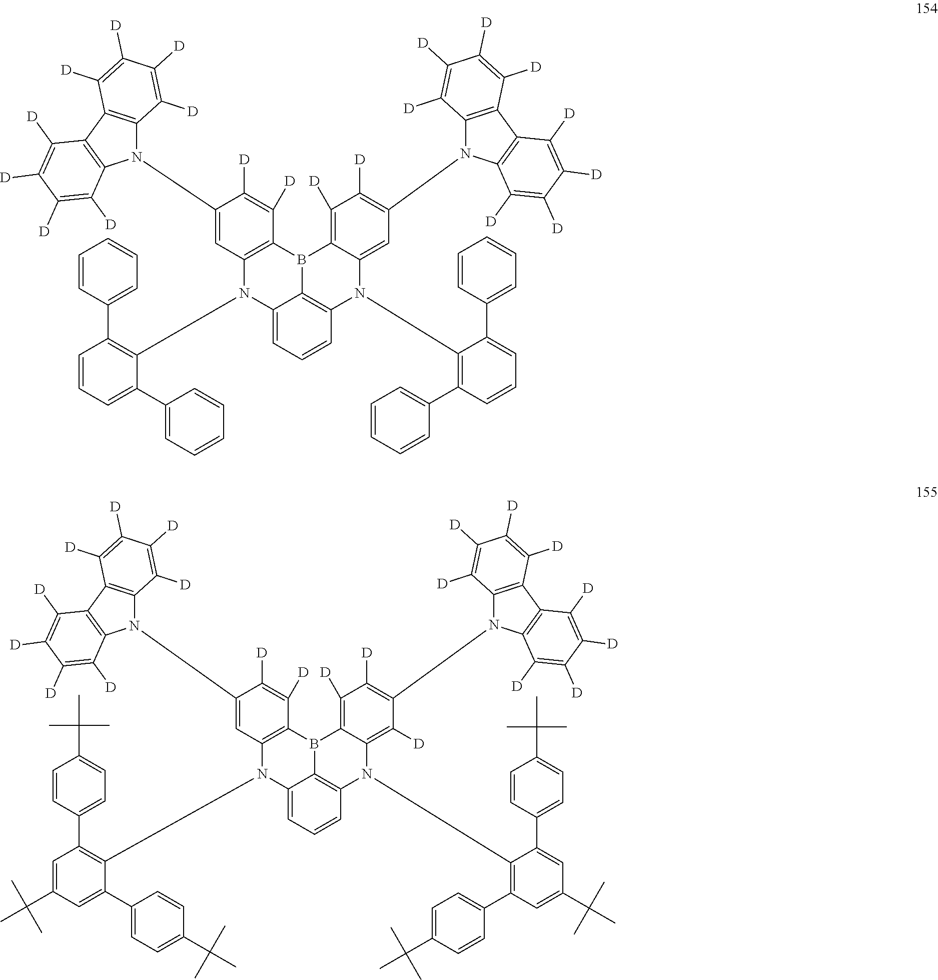

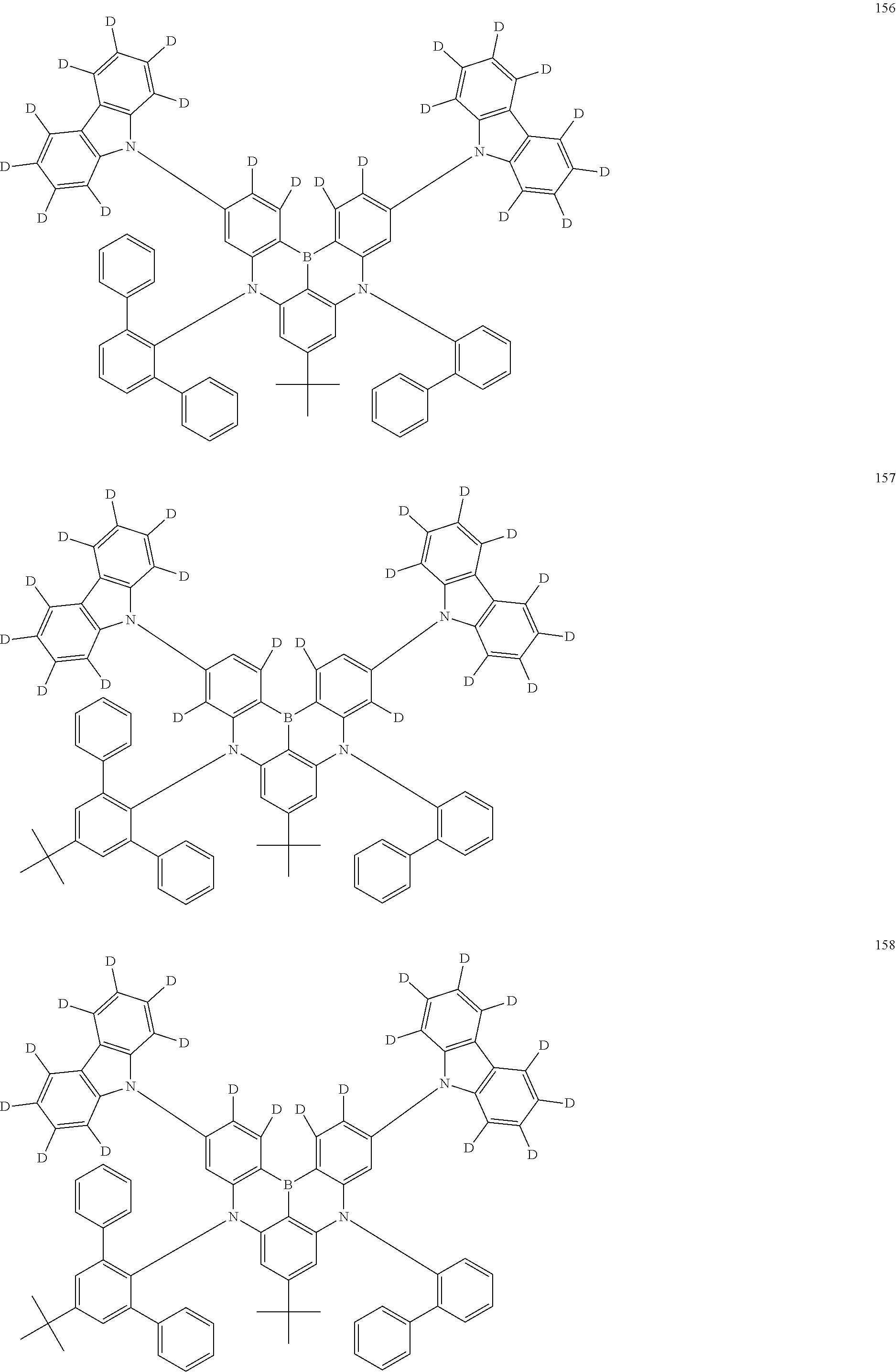

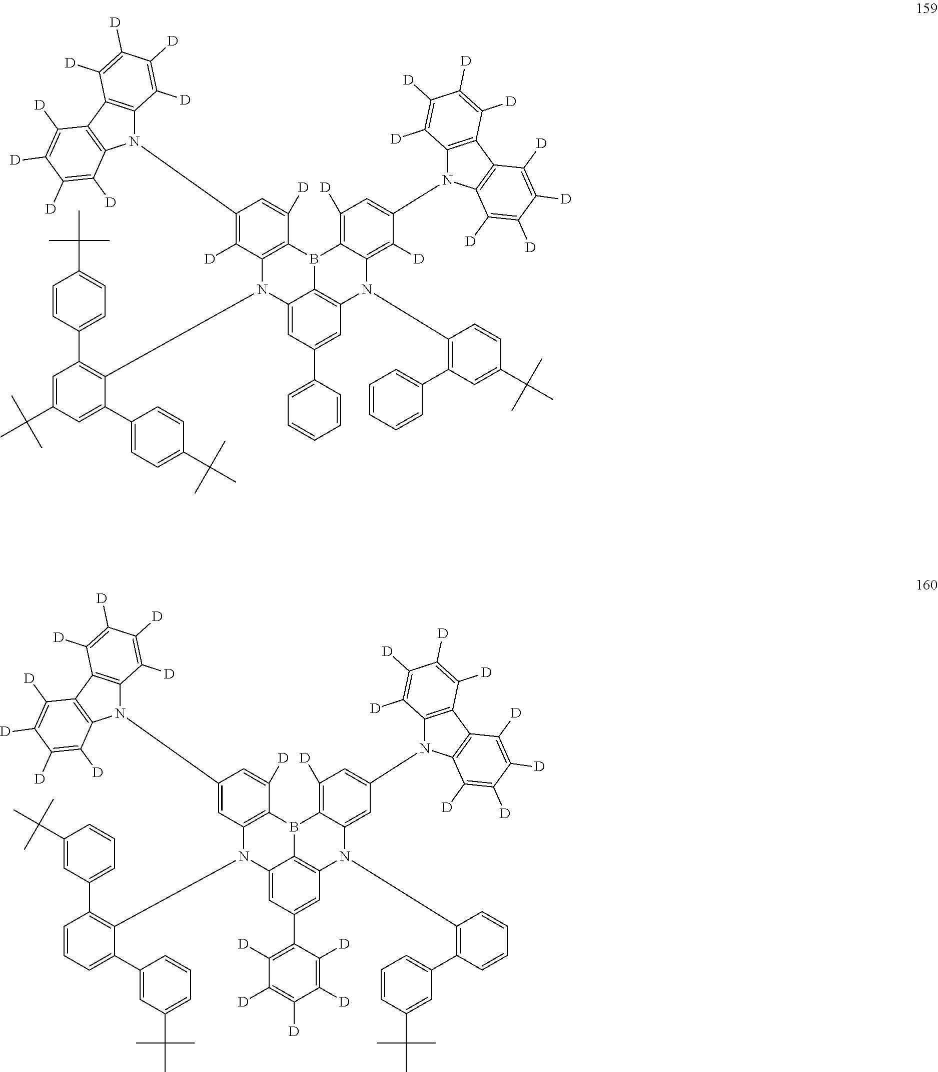

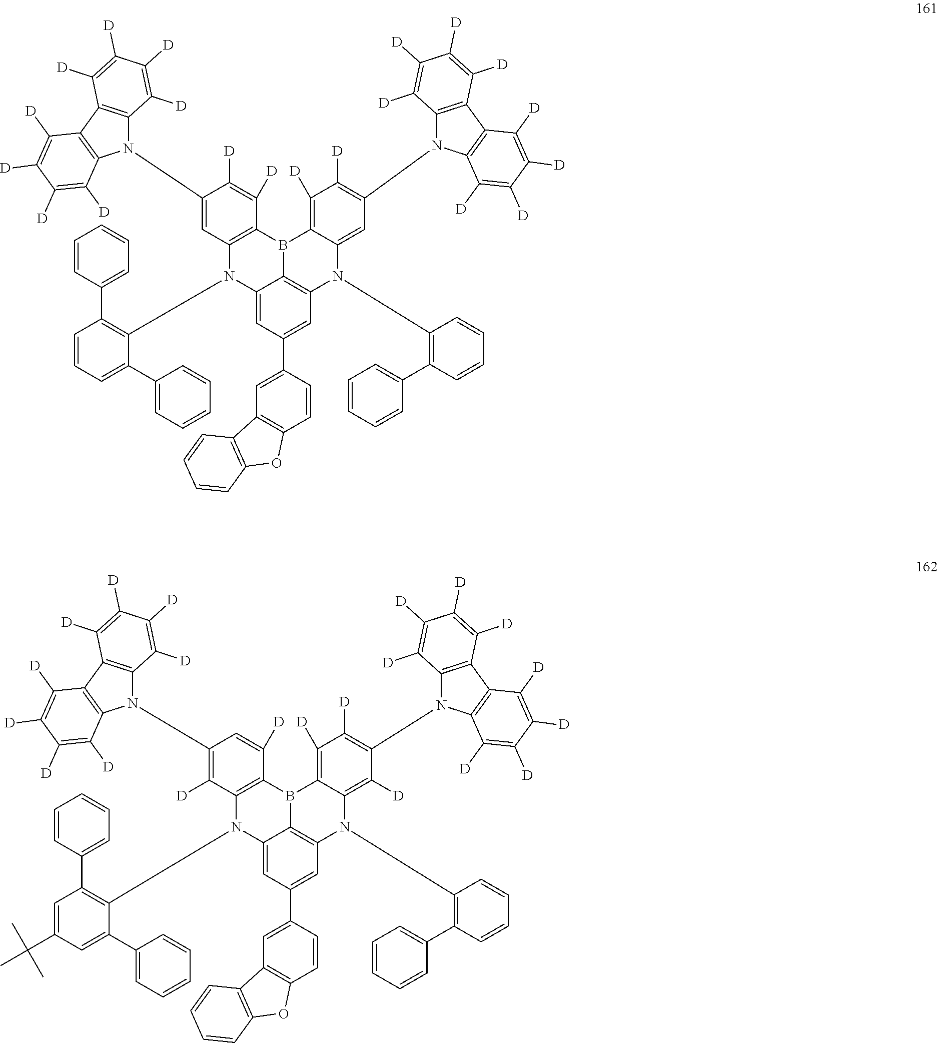

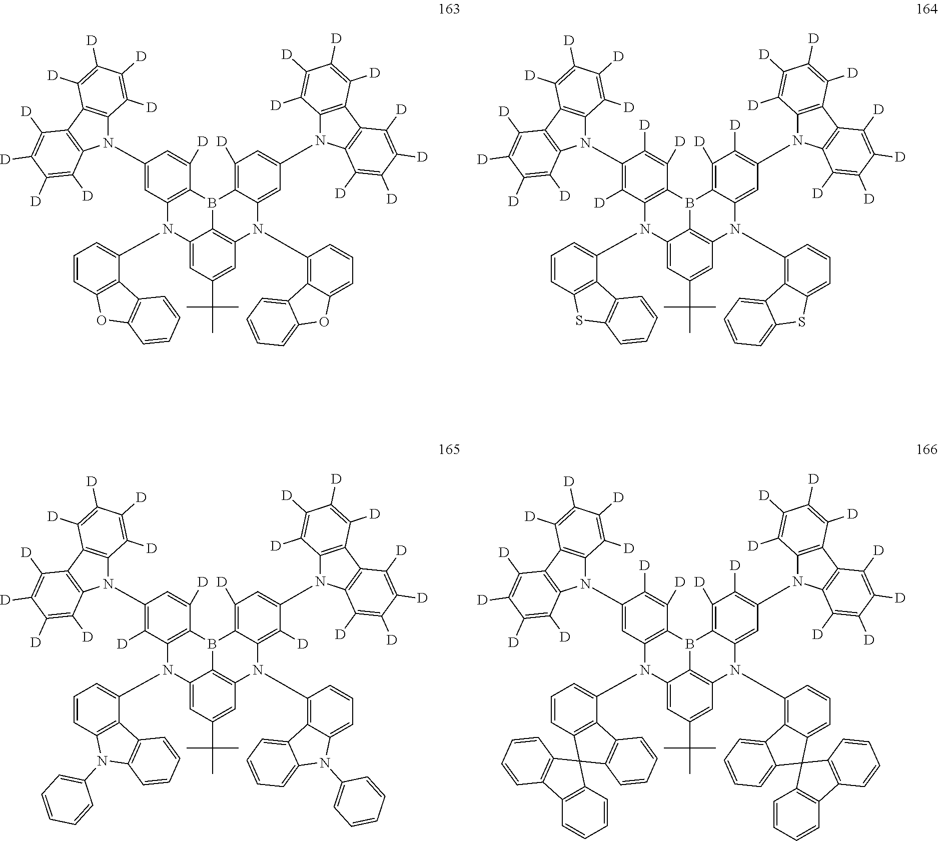

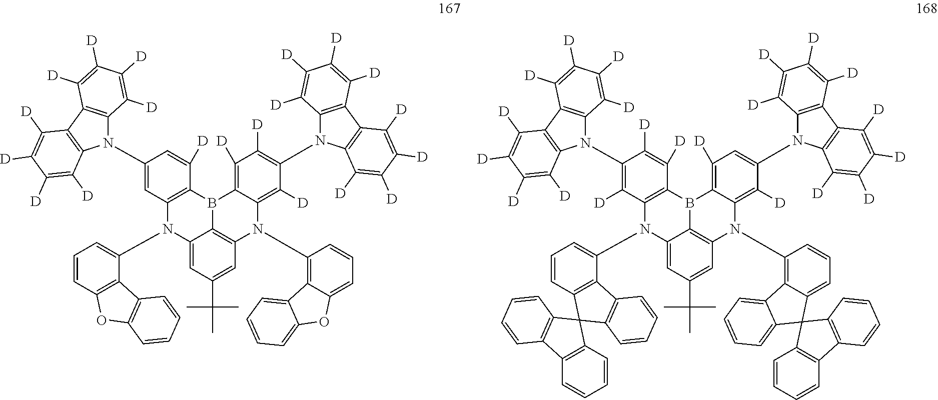

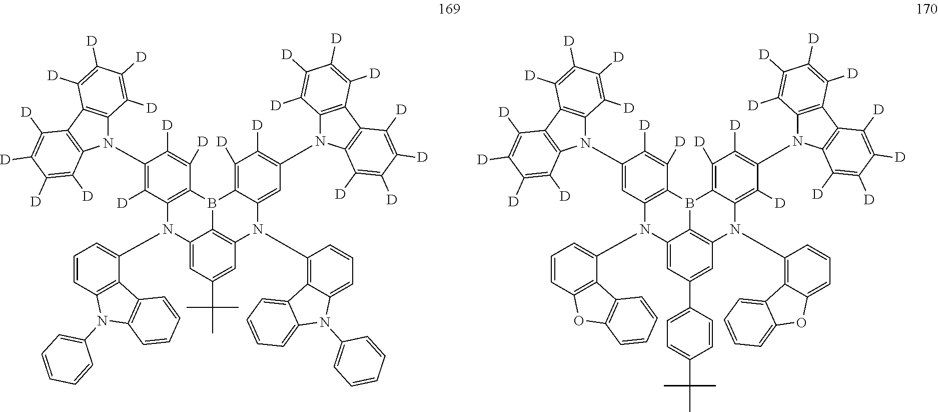

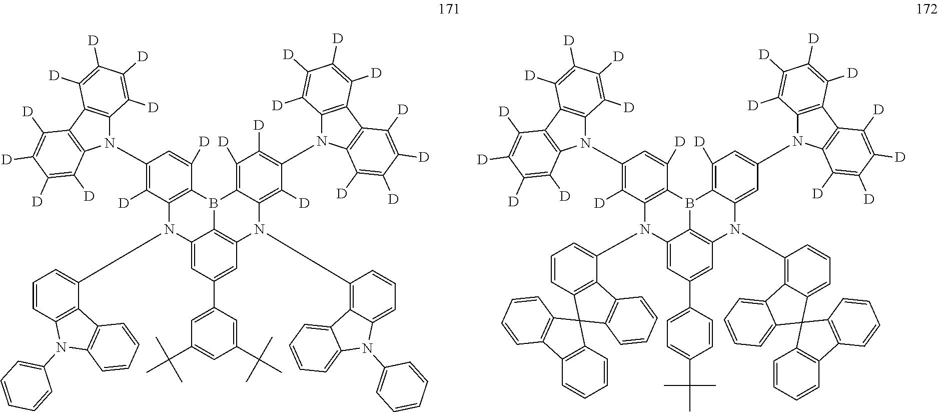

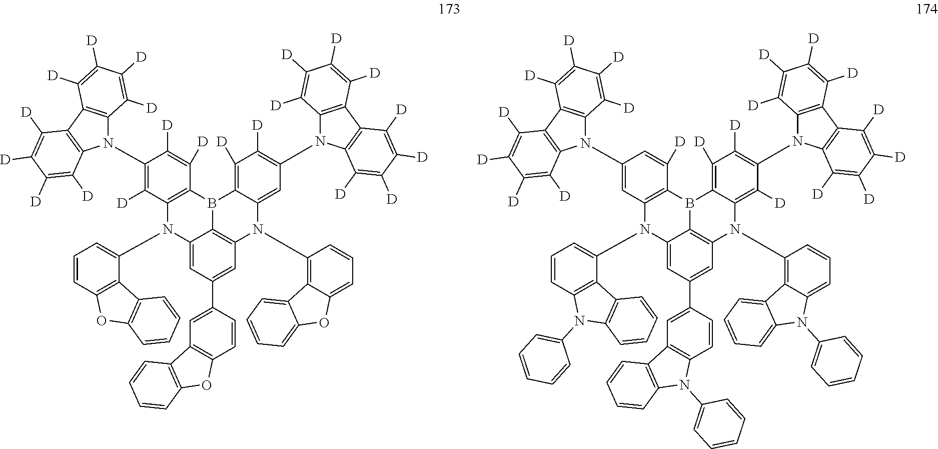

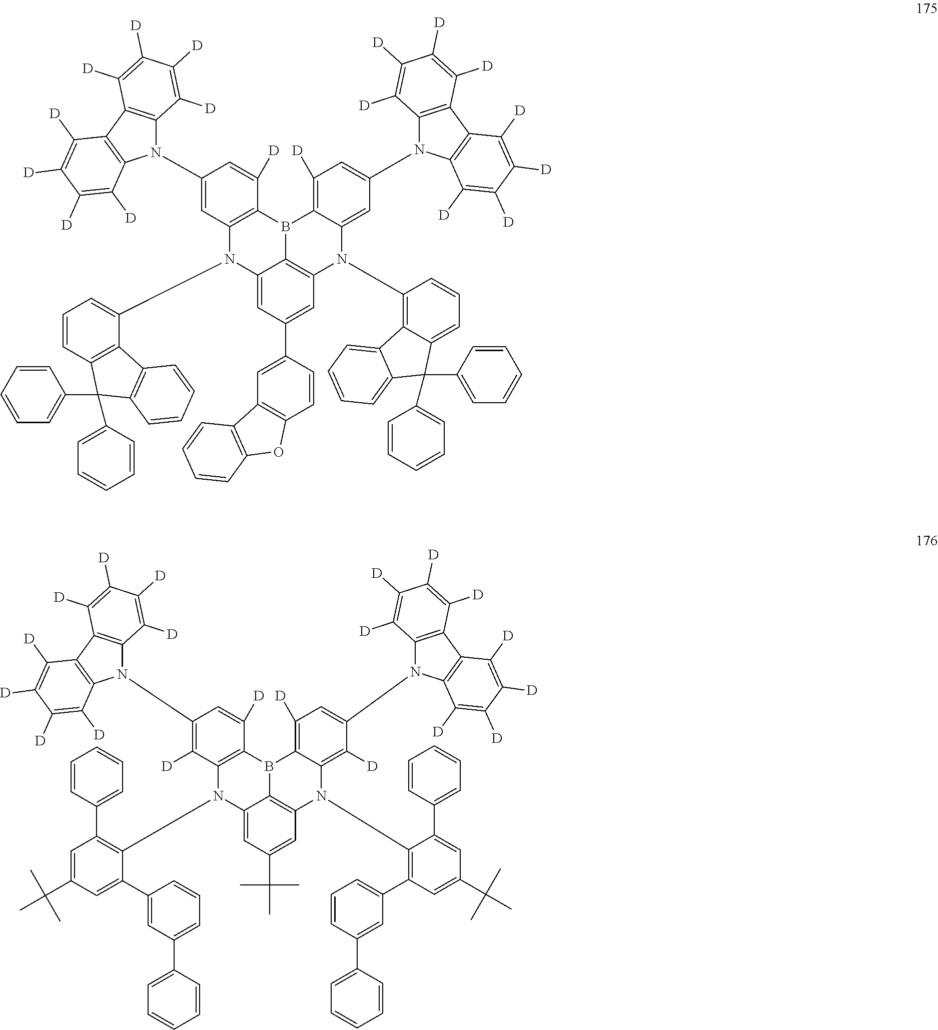

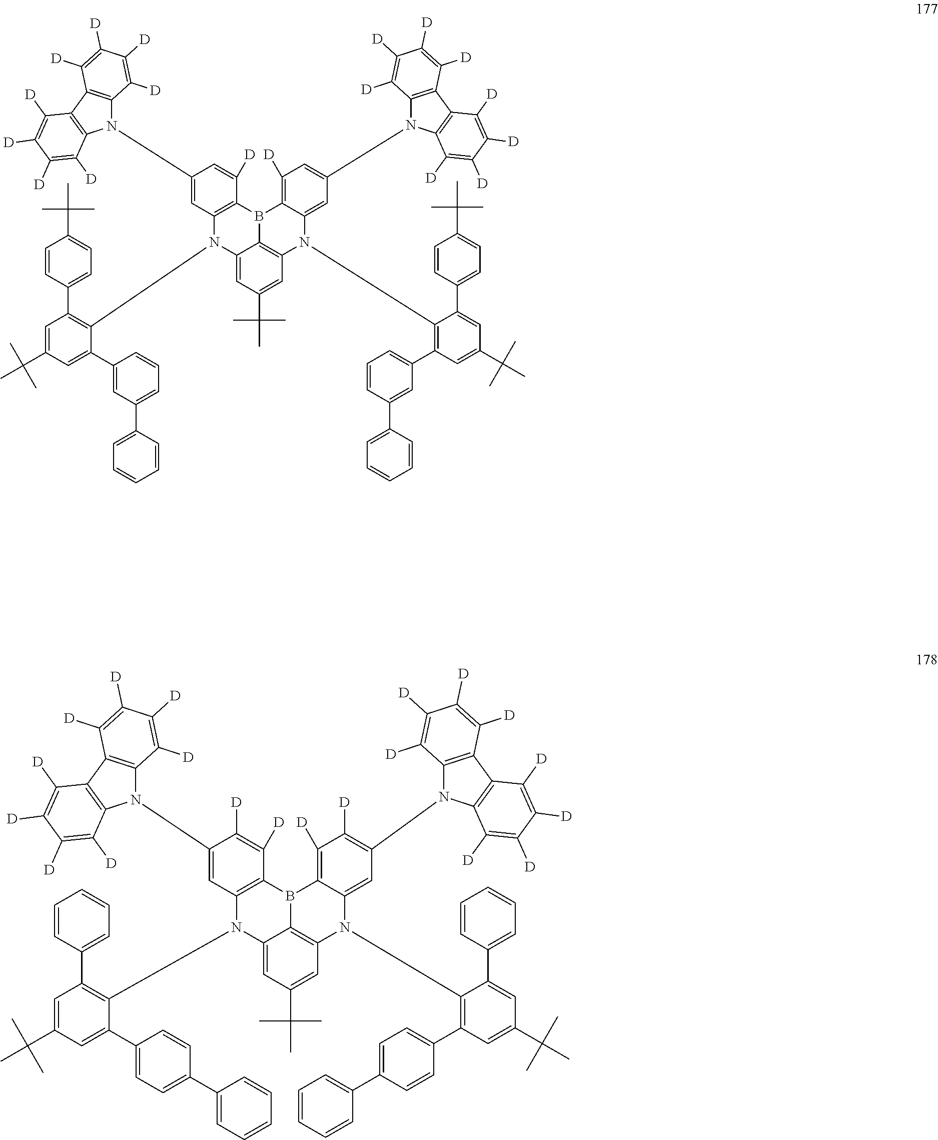

The polycyclic compound represented by Formula 1 may include a fused ring core that includes a boron atom (B) and two nitrogen atoms (N) as ring-forming atoms, and further includes deuterium atoms and substituents containing deuterium atoms that are bonded to the fused ring core. The deuterium atoms and the substituents containing deuterium atoms may be bonded to the first aromatic ring and to the second aromatic ring, where electron density is relatively low in the fused ring core. In the polycyclic compound, the substituent containing deuterium atoms may be a carbazole-d8.

The polycyclic compound includes C-D (carbon-deuterium) bonds, which have a shorter bond length and stronger bond strength relative to C—H (carbon-hydrogen) bonds, at positions having the lowest electron density in the molecule, and thereby contributing to the improvement in the service life of a light emitting element due to a kinetic isotope effect, which inhibits a reaction rate of a dissociation reaction of hydrogen atoms (H). For example, a variety of deterioration products including radicals may be present in the light emitting element. The deterioration products may cause a side reaction in a highly chemically reactive position to cause a chain of deterioration of materials, and this process may be accompanied by dissociation of hydrogen atoms. The polycyclic compound represented by Formula 1 includes deuterium atoms bonded to a fused ring core and substituents containing deuterium atoms, thereby delaying deterioration, and contributing to the improvement of service life of a light emitting element.

In the polycyclic compound according to an embodiment, substituents containing deuterium atoms may be bonded to the fused ring core at a para-position to the boron atom. For example, the polycyclic compound includes carbazole-d8 groups bonded to the fused ring core at a para-position to the boron atom. Accordingly, as the polycyclic compound includes the carbazole-d8 groups, hole mobility is improved, thereby facilitating the migration of trapped holes, so that a trap-assisted recombination (TAR) phenomenon is reduced, and triplet concentration in the emission layer EML is reduced, which may contribute to the improvement in the service life of the light emitting element.

The polycyclic compound of an embodiment may include a substituent having a large steric hindrance that is bonded to the nitrogen atom of the fused ring core. For example, the substituent having a large steric hindrance may be a substituted or unsubstituted biphenyl group, a substituted or unsubstituted terphenyl group, a substituted or unsubstituted carbazole group, a substituted or unsubstituted dibenzofuran group, a substituted or unsubstituted dibenzothiophene group, or a substituted or unsubstituted fluorenyl group. The polycyclic compound includes a substituent having a large steric hindrance that is bonded to the fused ring core, and thus may protect a p-orbital of the boron atom, thereby controlling intermolecular distance and thus, intermolecular interaction, such as Dexter energy transfer, may be effectively controlled.

The polycyclic compound of an embodiment has a fused ring core containing a boron atom and two nitrogen atoms and a structure in which deuterium atoms, substituents containing deuterium atoms, and a substituent having a large steric hindrance are introduced at specific positions of the fused ring core, and thus may exhibit the characteristics of the increased stability of the compound. Accordingly, the polycyclic compound may contribute to the improvement of service life of the light emitting element ED.

In embodiments, the light emitting element ED includes the polycyclic compound represented by Formula 1 as a first compound in the emission layer EML, and may further include a polycyclic compound represented by Formula 1-A as a first-1 compound. The polycyclic compound represented by Formula 1-A corresponds to a case where at least one of the two Dₐ substituents of the fused ring core, described with reference to Formula A, is a hydrogen atom.

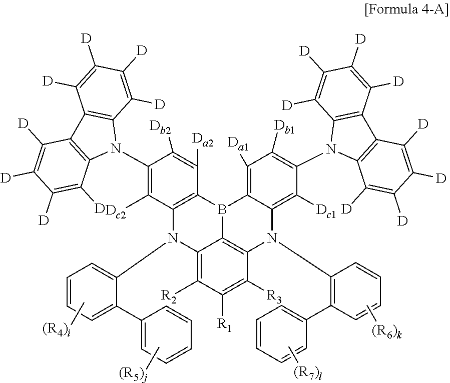

In Formula 1-A, at least one of Dₐ₃ or Dₐ₄ may be a hydrogen atom, and the remainder of Dₐ₃ and Dₐ₄ may be a deuterium atom. For example, Dₐ₃ and Dₐ₄ may each be a hydrogen atom, or any one of Dₐ₃ or Dₐ₄ may be a hydrogen atom, and the other of Dₐ₃ and Dₐ₄ may be a deuterium atom.

In Formula 1-A, D, D_{b1}, D_{b2}, D_{c1}, D_{c2}, R₁ to R₇, and i to 1 are the same as described in Formula 1.

The light emitting element ED according to an embodiment may include the first compound in the emission layer EML, and may further include the first-1 compound. For example, the emission layer EML may include an amount of the first compound in a range of about 30 wt % to about 100 wt %, with respect to the total weight of the first compound and the first-1 compound, but embodiments are not limited thereto.

The polycyclic compound represented by Formula 1 may be included in the emission layer EML. The polycyclic compound may be included as a dopant material in the emission layer EML. The polycyclic compound may be a thermally activated delayed fluorescence material. The polycyclic compound may be used as a thermally activated delayed fluorescence (TADF) dopant. For example, in the light emitting element ED according to an embodiment, the emission layer EML may include, as a thermally activated delayed fluorescence dopant, at least one compound selected from Compound Group 1 as described above. However, a use of the polycyclic compound is not limited thereto.

The polycyclic compound may be a luminescent material having a central emission wavelength in a range of about 430 nm to about 490 nm. For example, the polycyclic compound may emit blue light. For example, the polycyclic compound may have a central emission wavelength in a range of about 455 nm to about 465 nm. The polycyclic compound may have an absorption wavelength in a range of about 440 nm to about 460 nm.

The polycyclic compound may be a blue thermally activated delayed fluorescence (TADF) dopant. However, embodiments are not limited thereto.

In an embodiment, the emission layer EML may include at least one of a second compound, a third compound, or a fourth compound. The second compound may include a substituted or unsubstituted carbazole moiety. The third compound may include a hexagonal ring containing at least one nitrogen atom as a ring-forming atom. The fourth compound may be an organometallic compound. The fourth compound may be an organometallic compound containing platinum (Pt), palladium (Pd), copper (Cu), osmium (Os), ruthenium (Ru), rhodium (Rh), or iridium (Ir) as a central metal. In an embodiment, the second compound may be represented by Formula HT, and the third compound may be represented by Formula ET. In an embodiment, the fourth compound may contain platinum (Pt) as a central metal, and may be represented by Formula M-b.

In an embodiment, the emission layer EML may include a second compound represented by Formula HT. In an embodiment, the second compound represented by Formula HT may be used as a hole transporting host material of the emission layer EML.

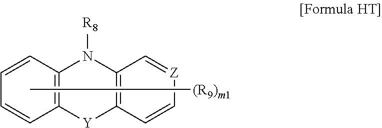

In Formula HT, m1 may be an integer from 0 to 7. When m1 is or more, multiple R₉ groups may be the same as each other or at least one thereof may be different from the others. In Formula HT, R₈ and R₉ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₈ may be a substituted phenyl group, an unsubstituted dibenzofuran group, or a substituted fluorenyl group. For example, R₉ may be a hydrogen atom, a deuterium atom, or a substituted or unsubstituted carbazole group. For example, two adjacent R₉ groups may be bonded to each other to form a substituted or unsubstituted heterocycle.

In Formula HT, Y may be a direct linkage, C(R_{y1})(R_{y2}), or Si(R_{y3})(R_{y4}). For example, when Y is a direct linkage, the second compound represented by Formula HT may include a carbazole moiety. In Formula HT, R_{y1} to R_{y4} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms. For example, R_{y1} to R_{y4} may each independently be a methyl group or a phenyl group.

In Formula HT, Z may be C(R_{z}) or a nitrogen atom (N). For example, Y may be a direct linkage, and when Z is C(R_{z}), Formula HT may include a carbazole moiety. For example, Y may be a direct linkage, and when Z is a nitrogen atom, Formula HT may include a pyridoindole moiety. In Formula HT, R_{z} may be a hydrogen atom or a deuterium atom.

In an embodiment, the second compound represented by Formula HT may be selected from Compound Group 2. In an embodiment, in the light emitting element ED, the second compound may include at least one compound selected from Compound Group 2. In Compound Group 2, D is a deuterium atom, and Ph is a phenyl group.

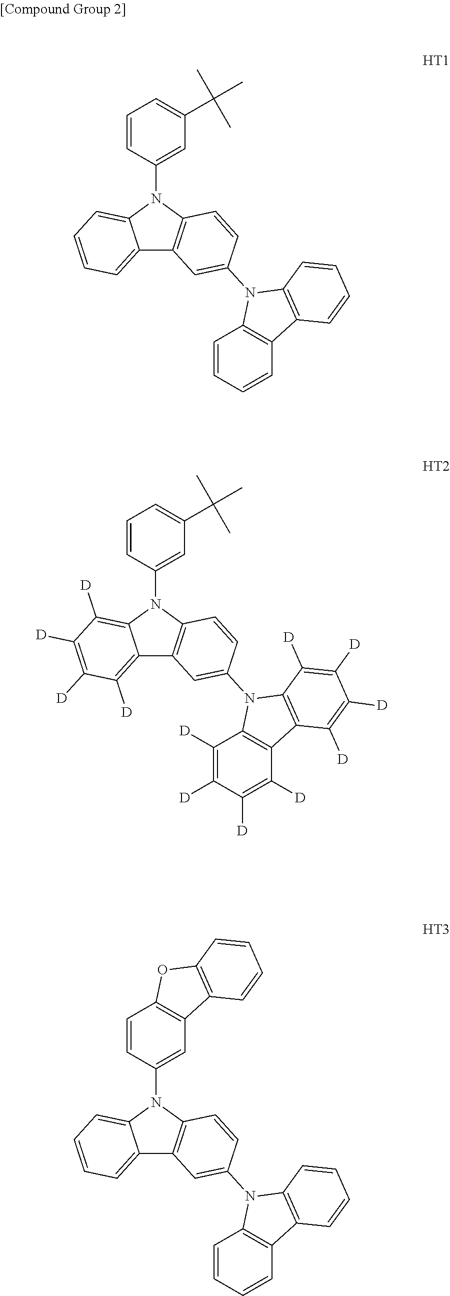 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

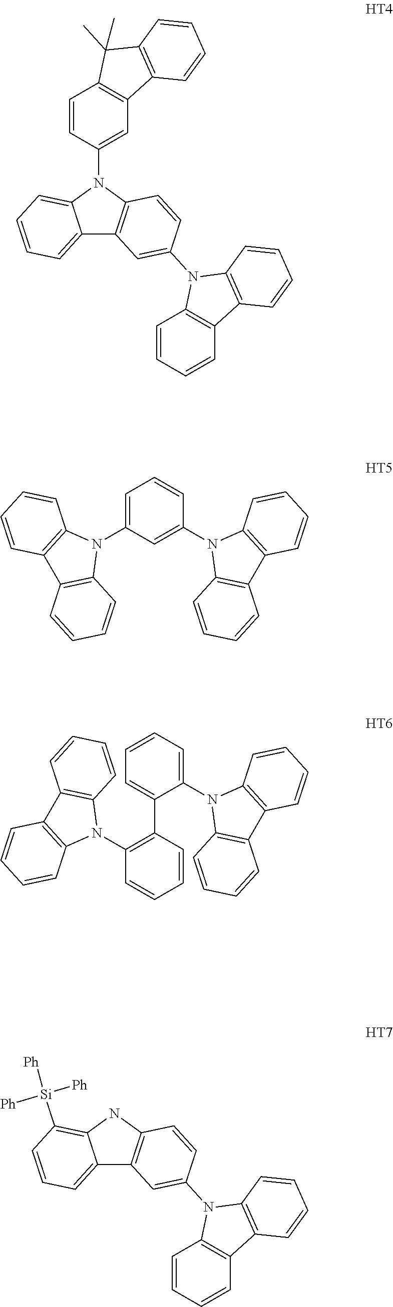 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2[nH]c2ccc(-n4c5ccccc5c5ccccc54)cc23)cc1]

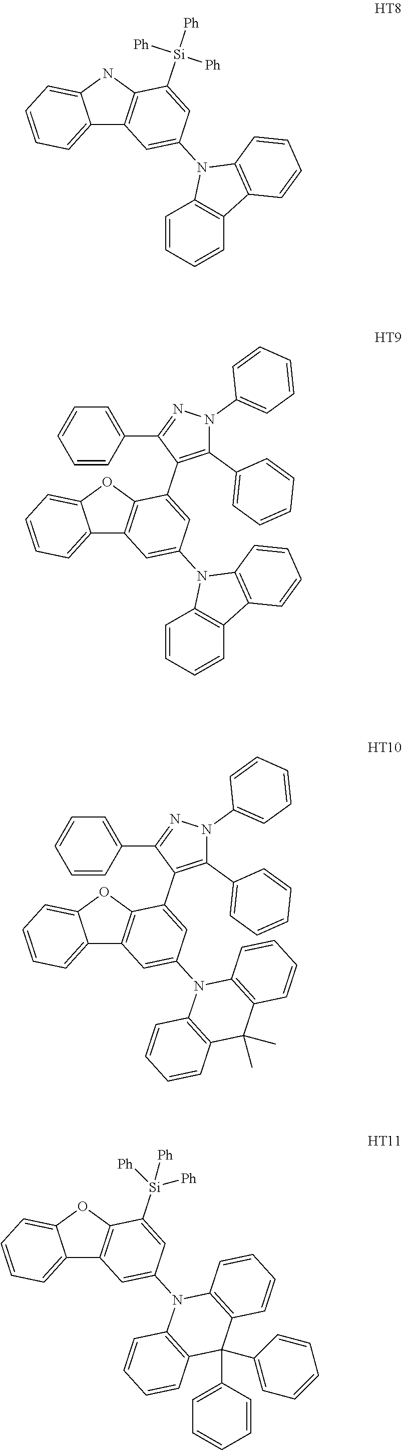 [SMILES: c1ccc([Si](c2ccccc2)(c2ccccc2)c2cc(-n3c4ccccc4c4ccccc43)cc3c2[nH]c2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

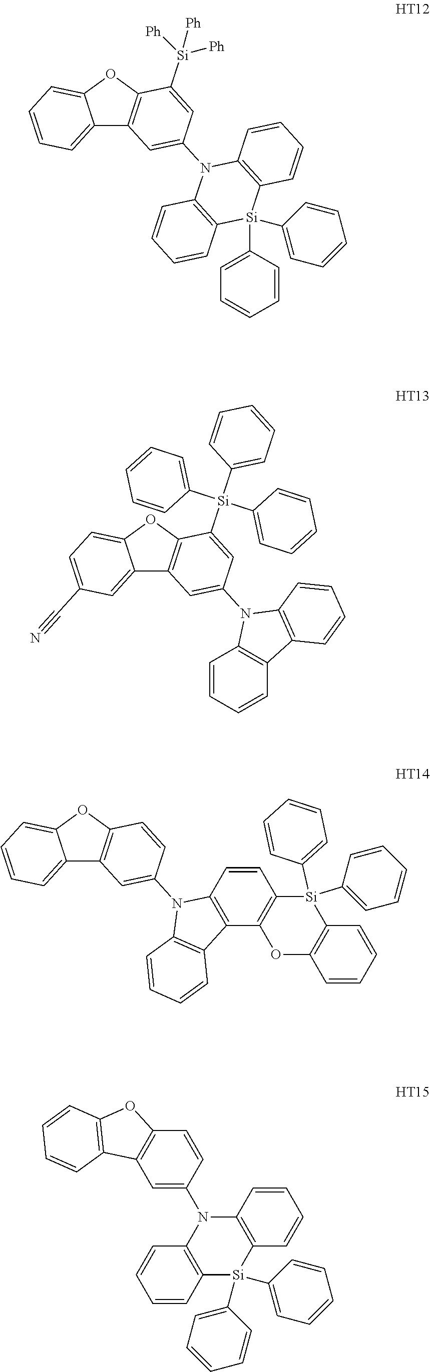 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

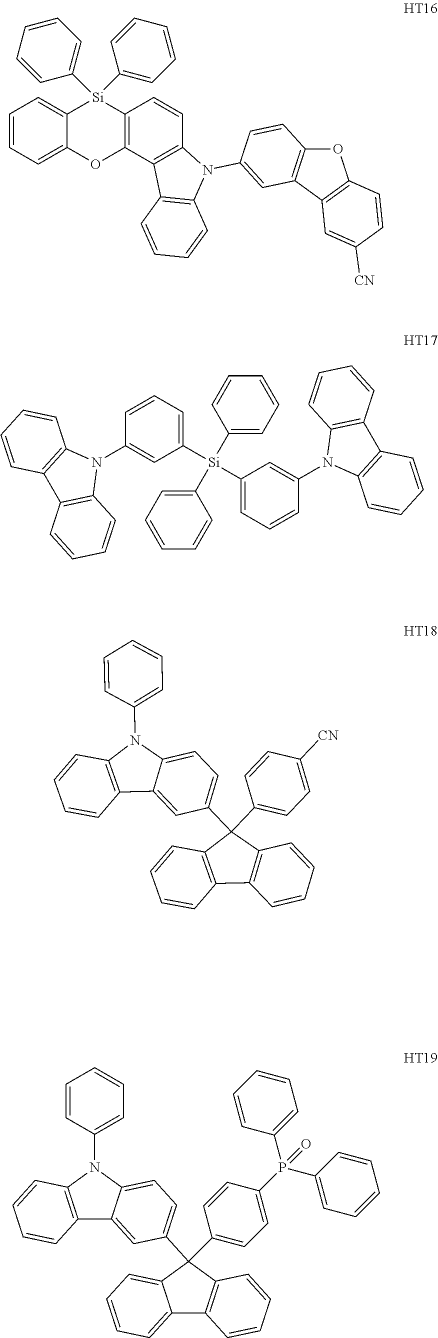 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

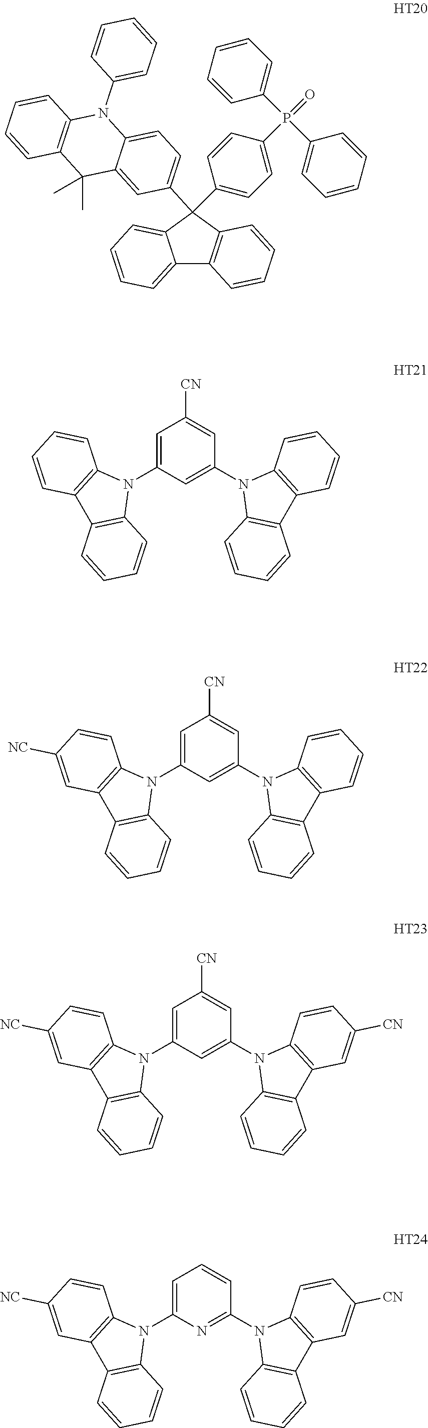 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

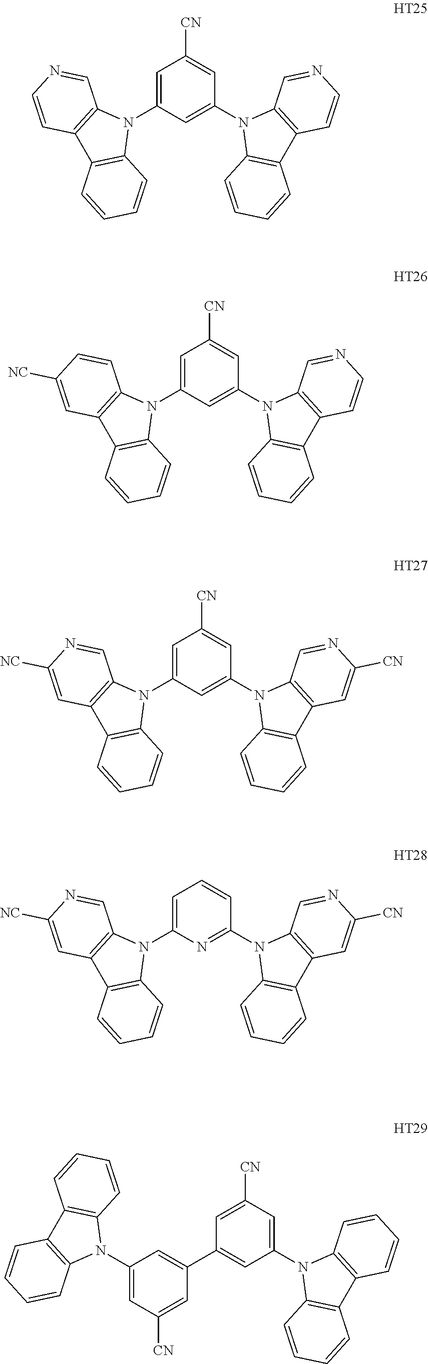 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

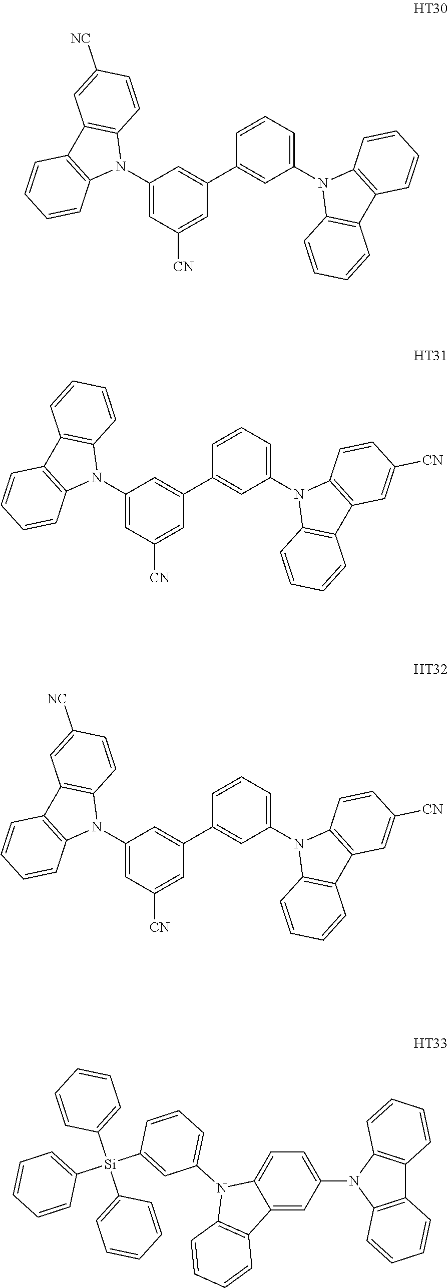 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

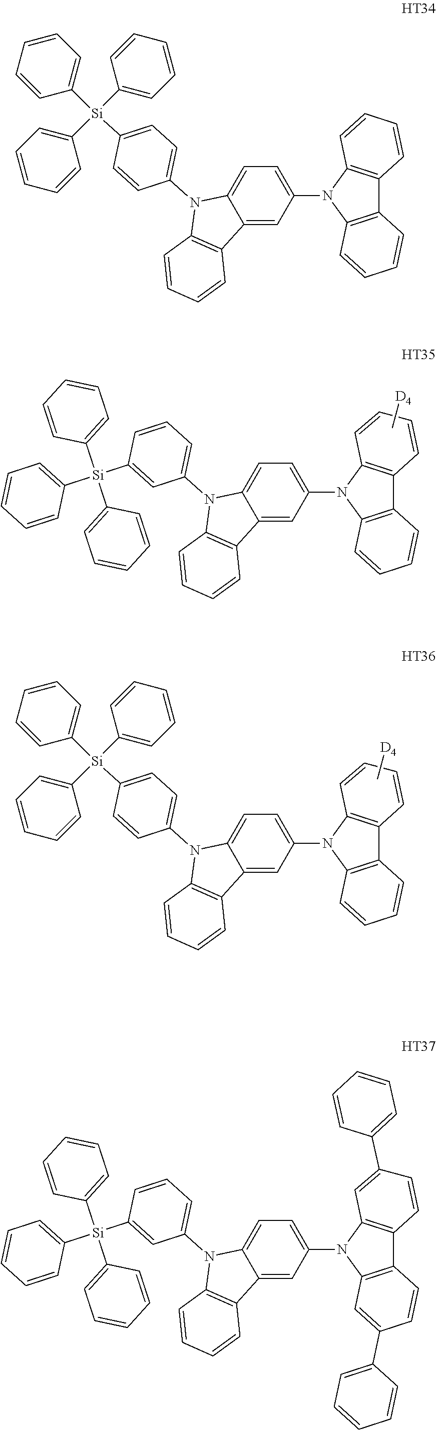

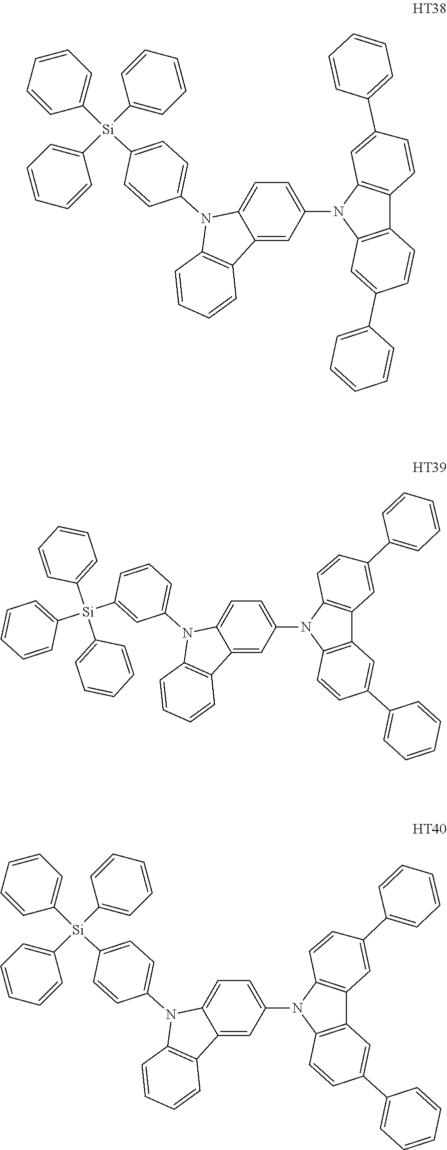 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

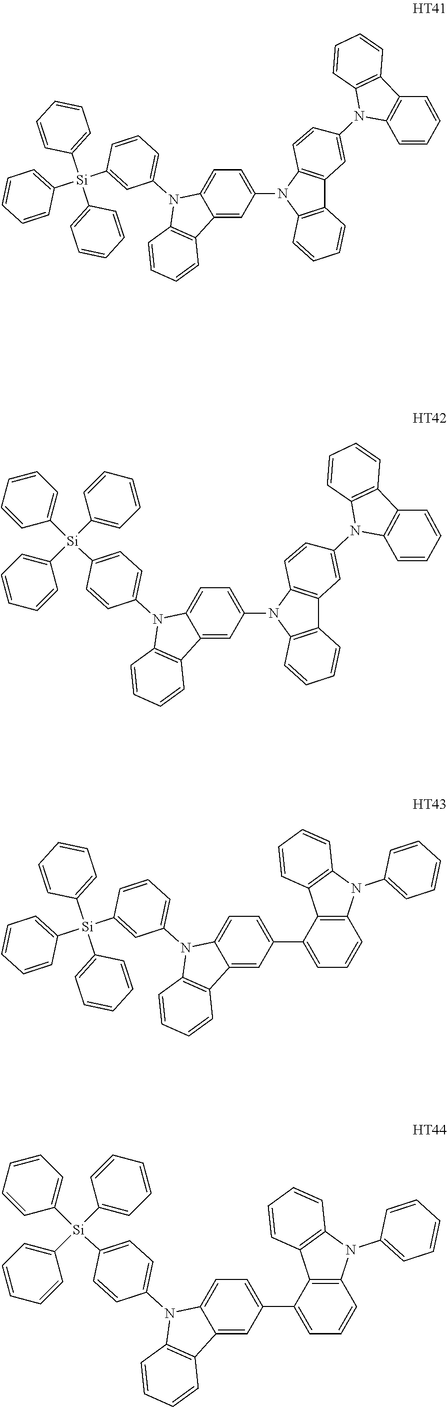 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

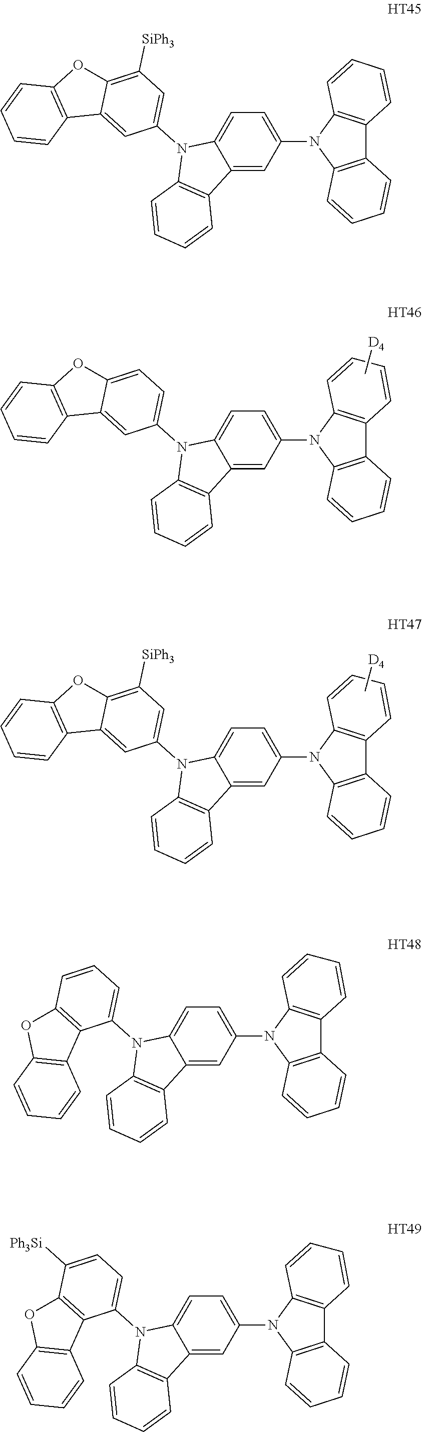

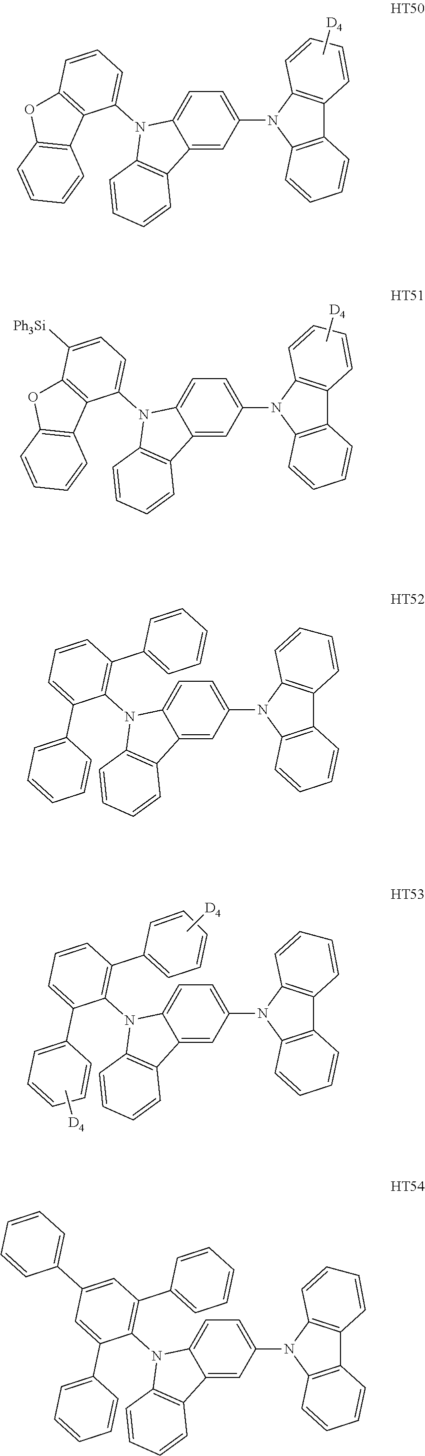

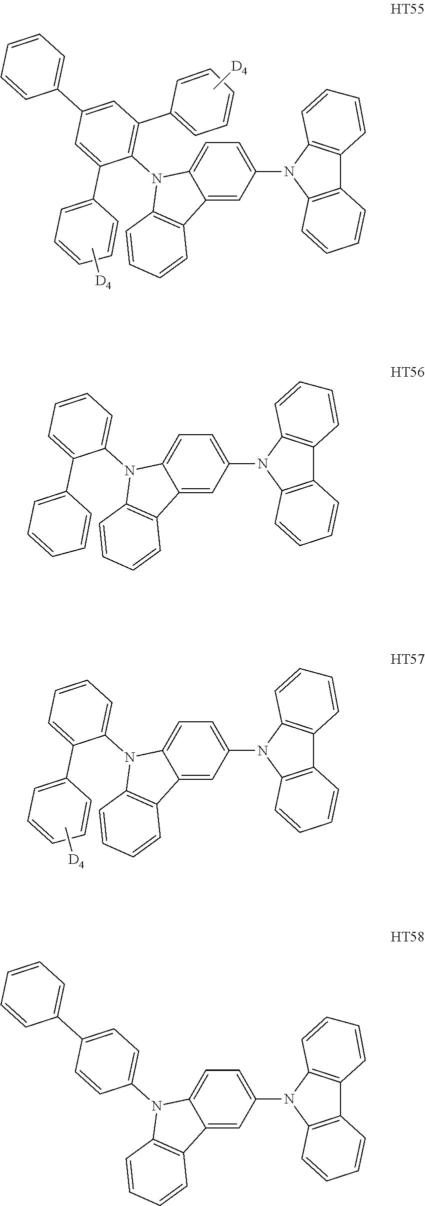

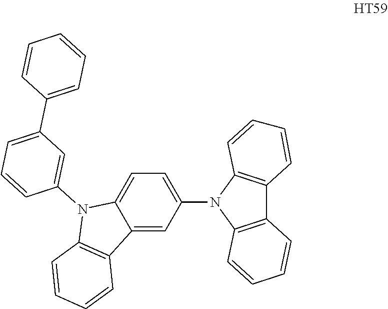 [SMILES: c1ccc(-c2cccc(-n3c4ccccc4c4cc(-n5c6ccccc6c6ccccc65)ccc43)c2)cc1]

In an embodiment, the emission layer EML may include a third compound represented by Formula ET. In an embodiment, the third compound represented by Formula ET may be used as an electron transport host material for the emission layer EML.

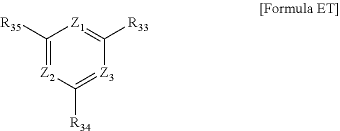

In Formula ET, Z₁ to Z₃ may each independently be N or C(R₃₆); and at least one of Z₁ to Z₃ may each be N. For example, Z₁ to Z₃ may each be N. As another example, any two of Z₁ to Z₃ may each be N, and the remainder thereof may be C(R₃₆). As yet another example, any one of Z₁ to Z₃ may be N, and the remainder thereof may each independently be C(R₃₆).

In Formula ET, R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₃₃ to R₃₆ may each independently be a substituted or unsubstituted phenyl group, a substituted or unsubstituted carbazole group, etc., but embodiments are limited thereto.

In an embodiment, the third compound represented by Formula ET may be selected from Compound Group 3. In an embodiment, in the light emitting element ED, the third compound may include at least one compound selected from Compound Group 3. In Compound Group 3, D is a deuterium atom.

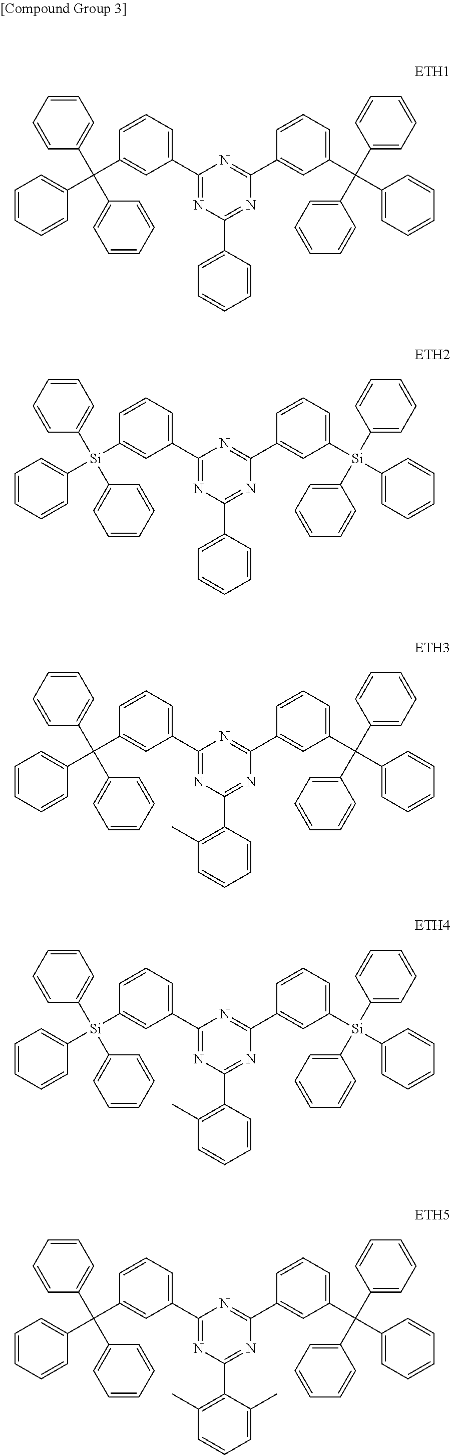

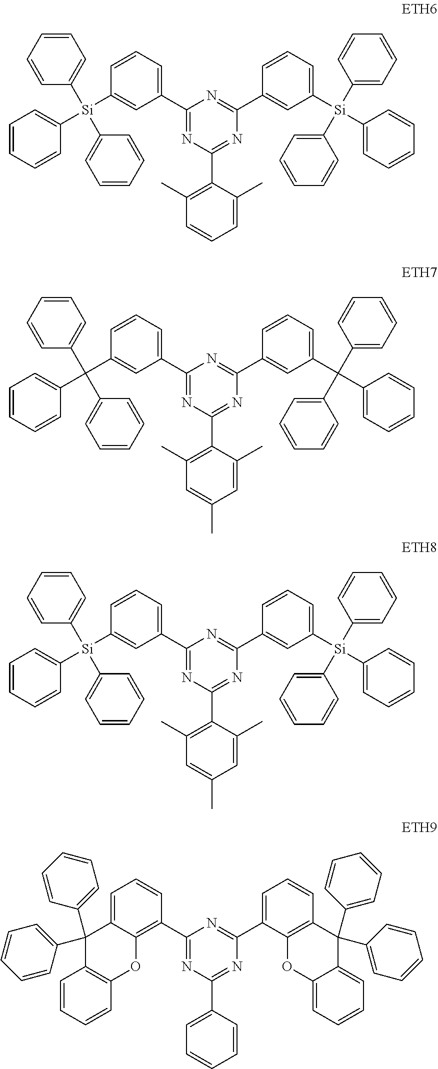 [SMILES: Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1]

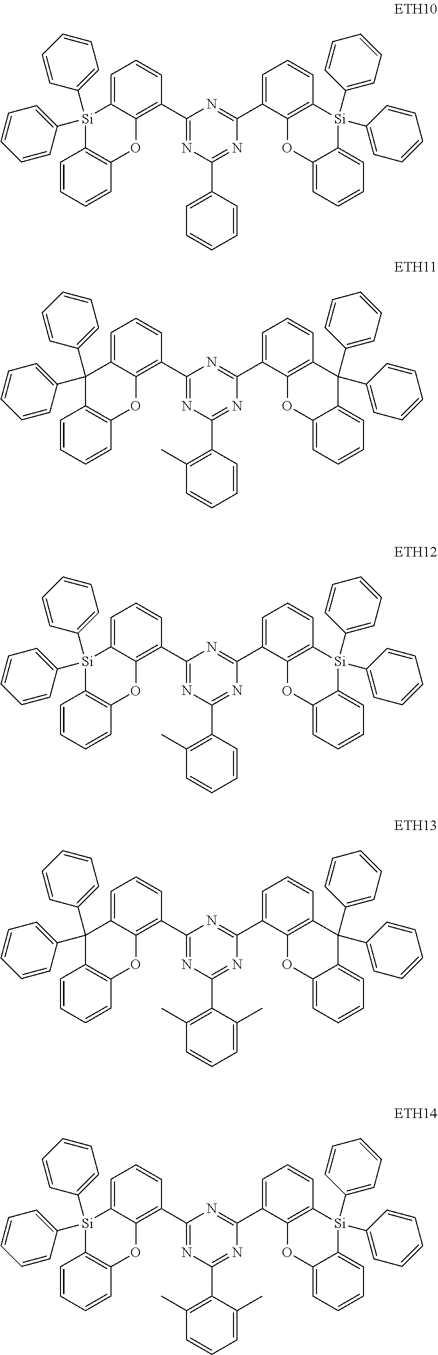

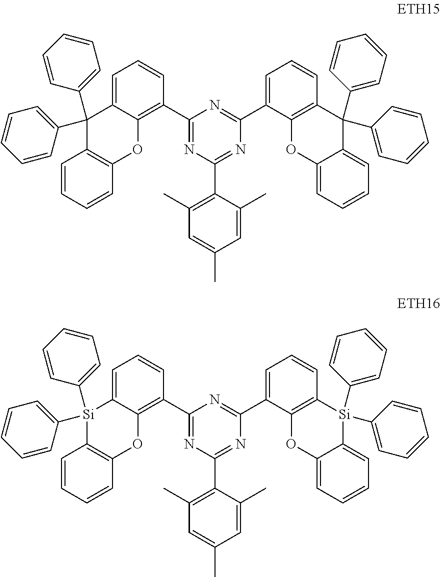 [SMILES: Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

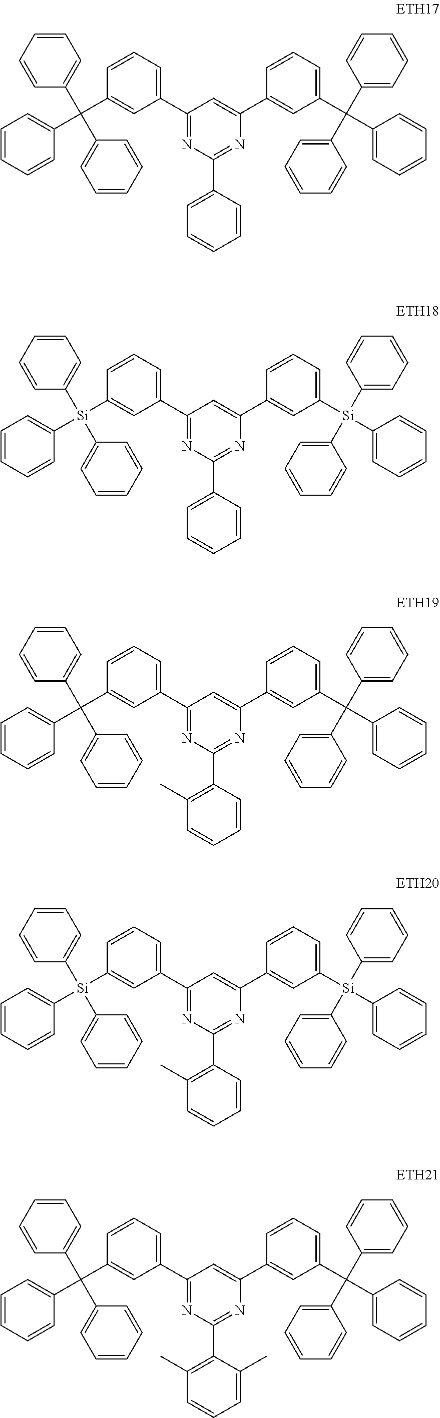

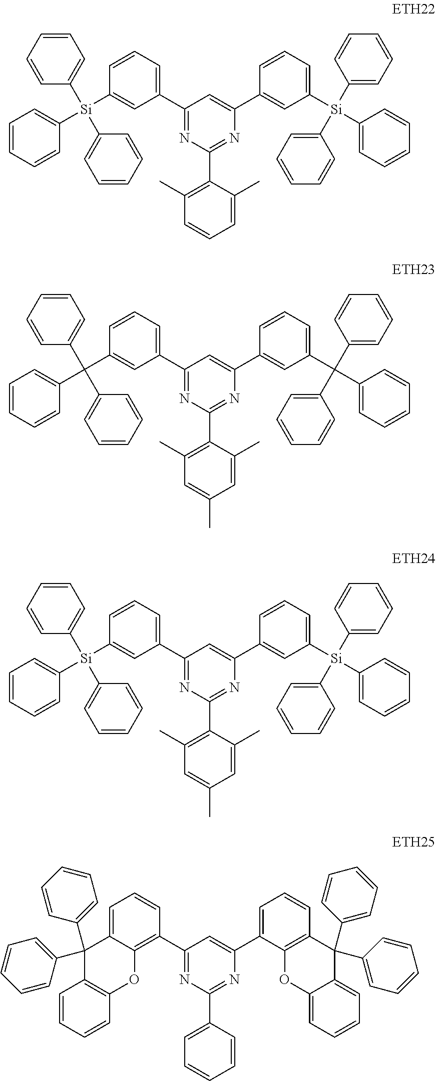 [SMILES: Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1]

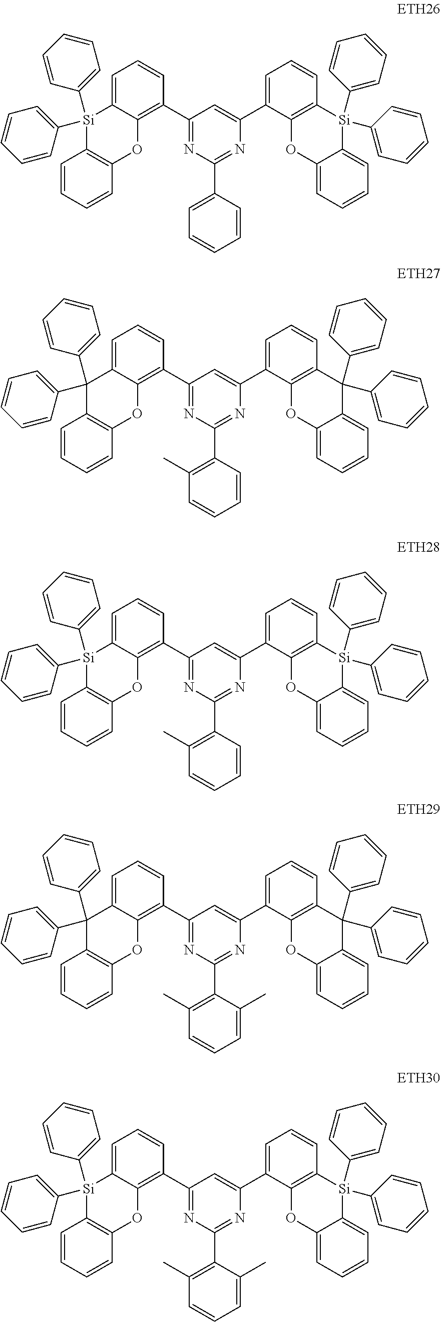

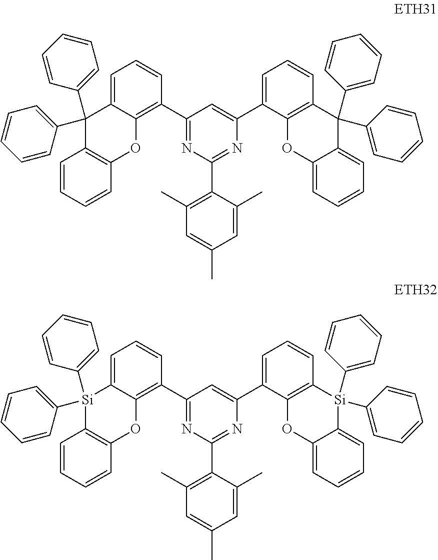 [SMILES: Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

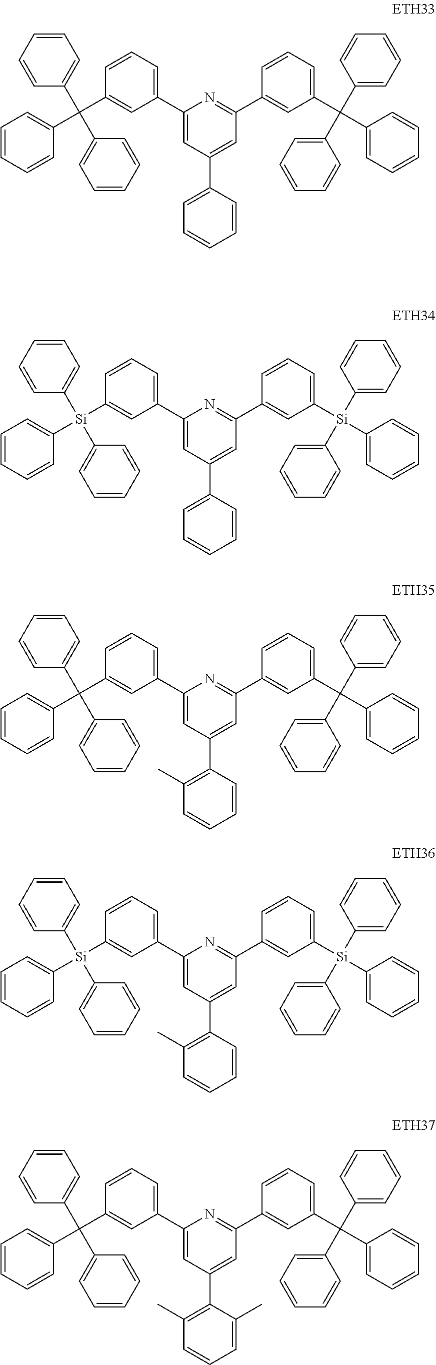

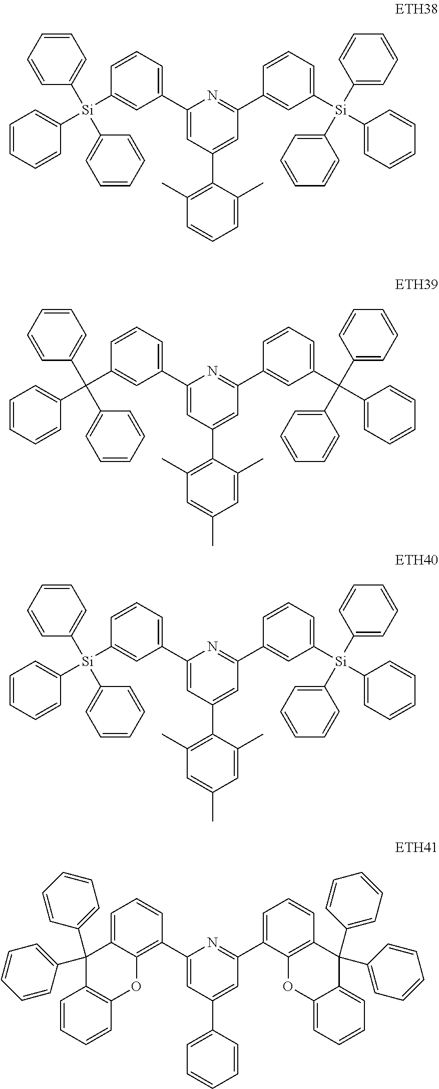 [SMILES: Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1 ; c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1]

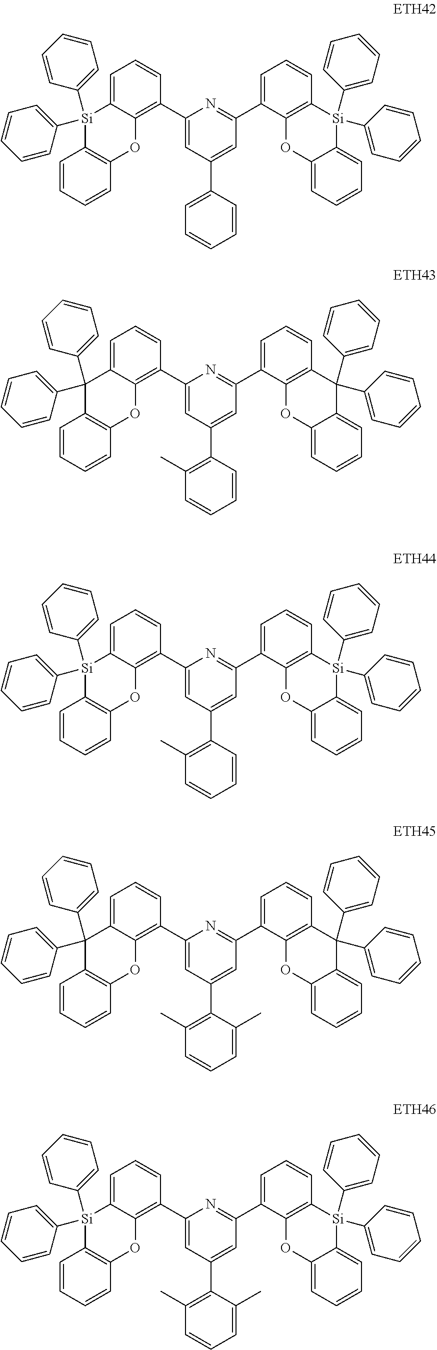

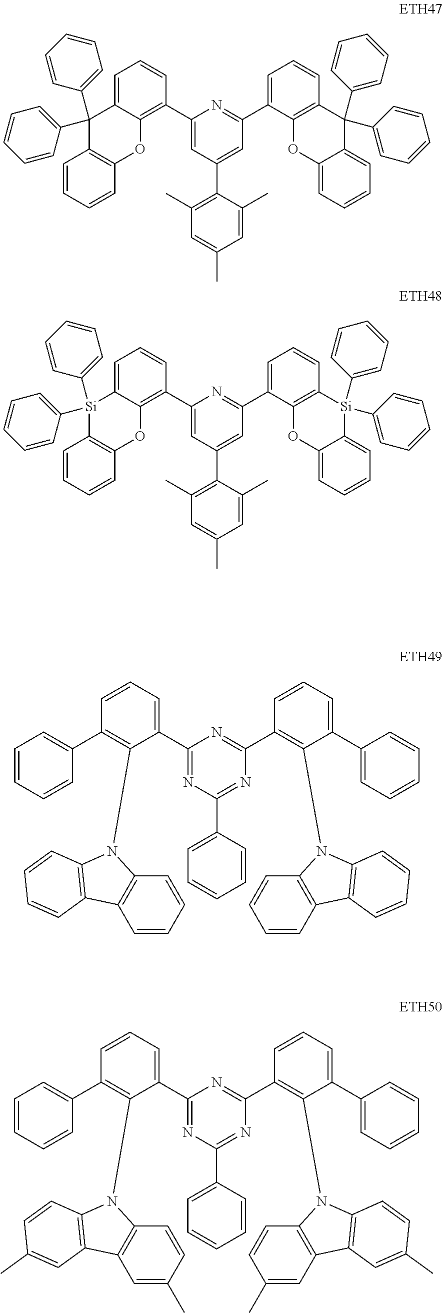

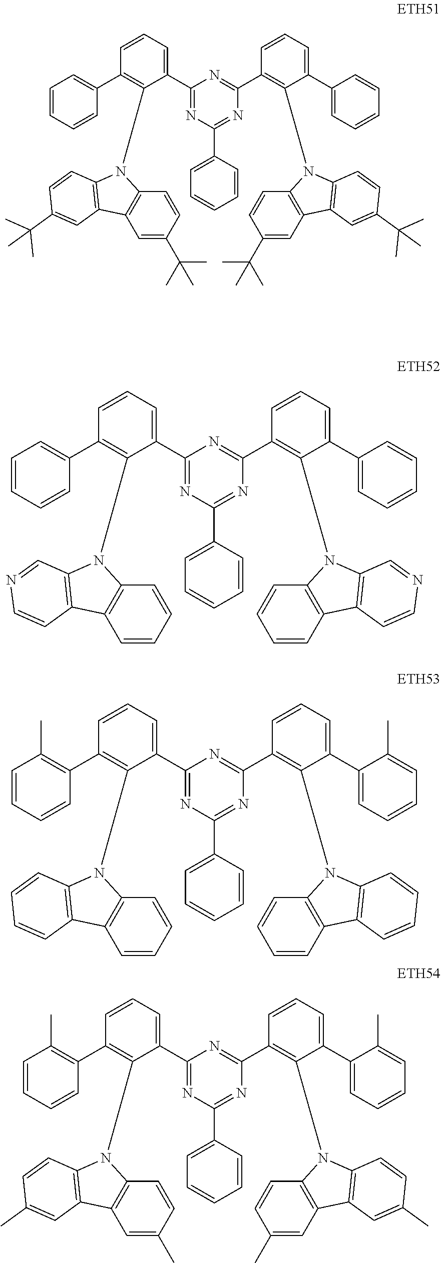

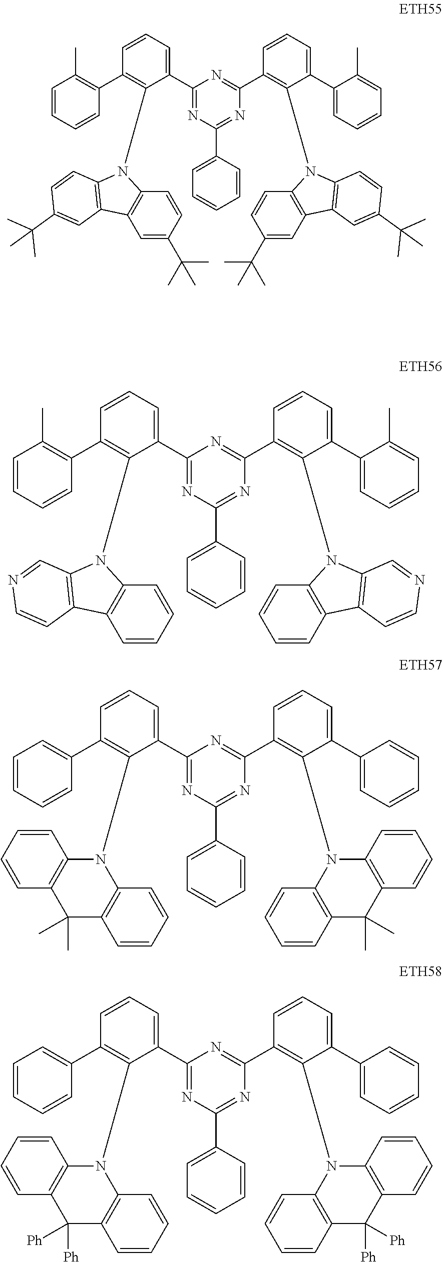

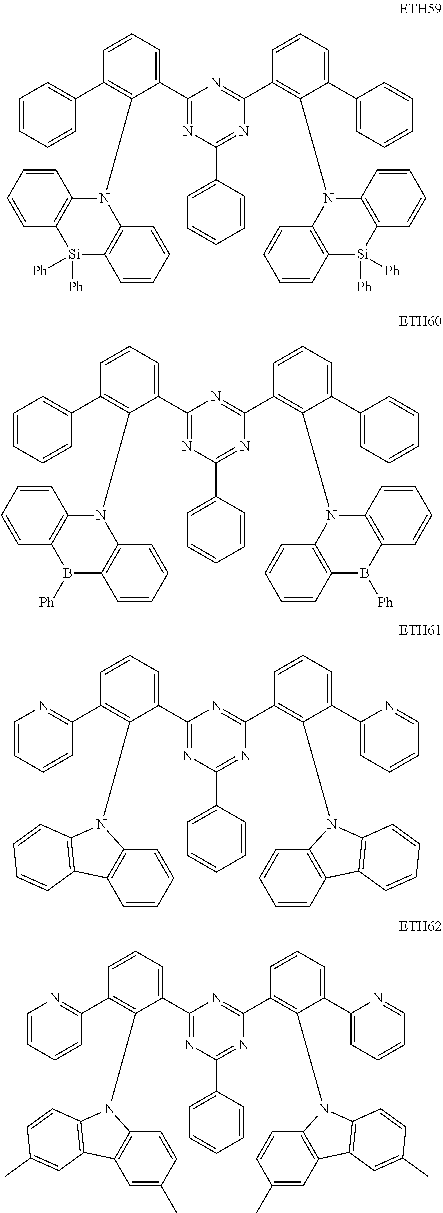

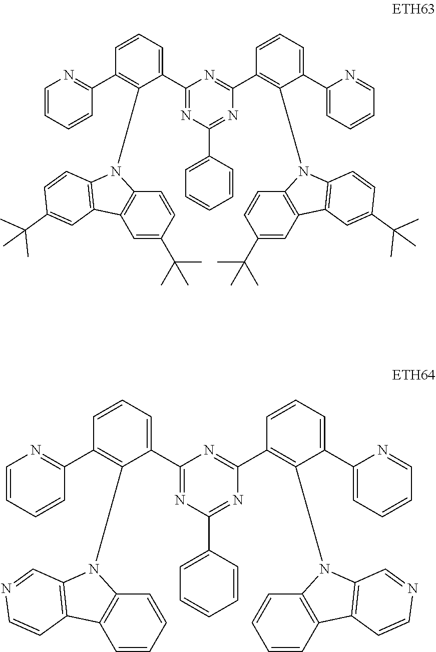 [SMILES: CC(C)(C)c1ccc2c(c1)c1cc(C(C)(C)C)ccc1n2-c1c(-c2ccccn2)cccc1-c1nc(-c2ccccc2)nc(-c2cccc(-c3ccccn3)c2-n2c3ccc(C(C)(C)C)cc3c3cc(C(C)(C)C)ccc32)n1 ; c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1]

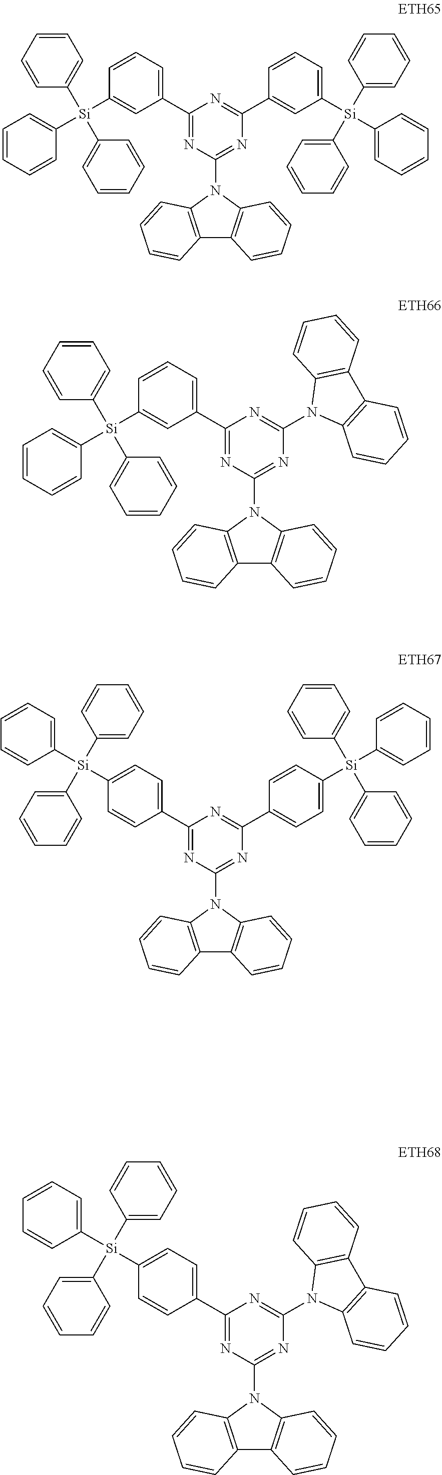 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

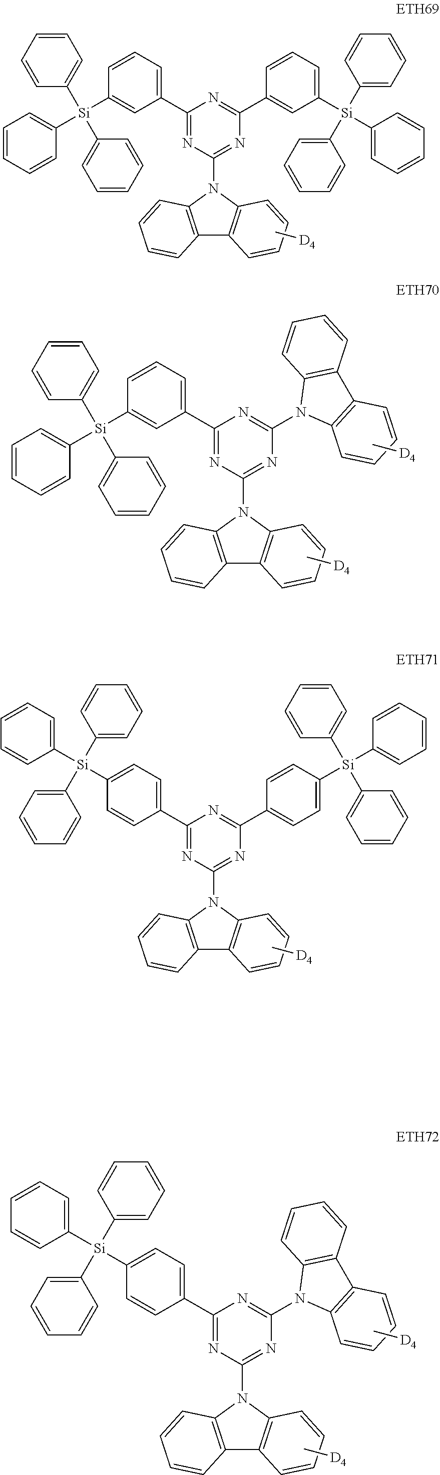

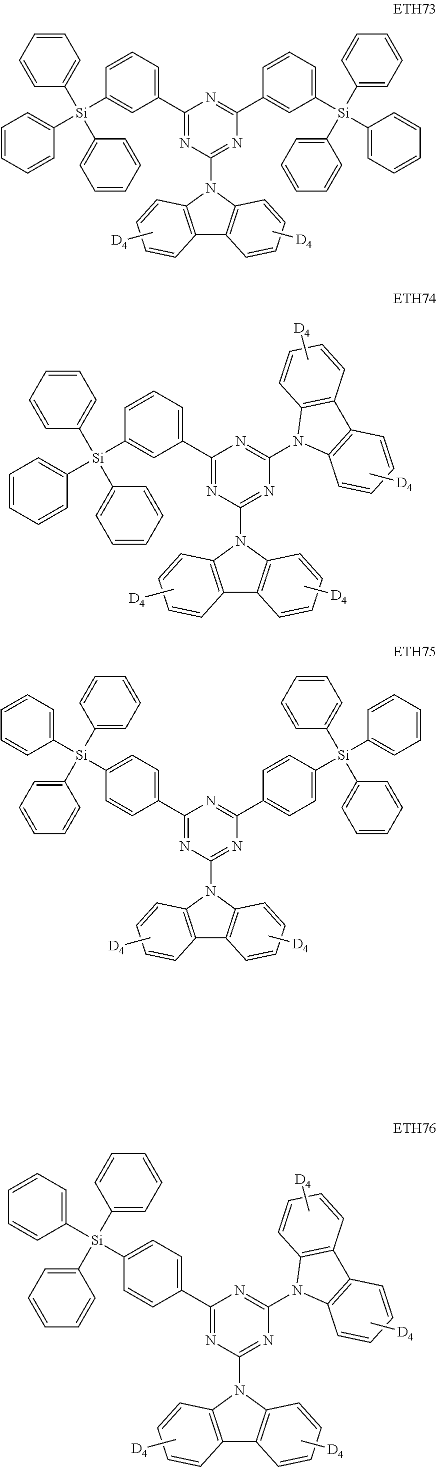

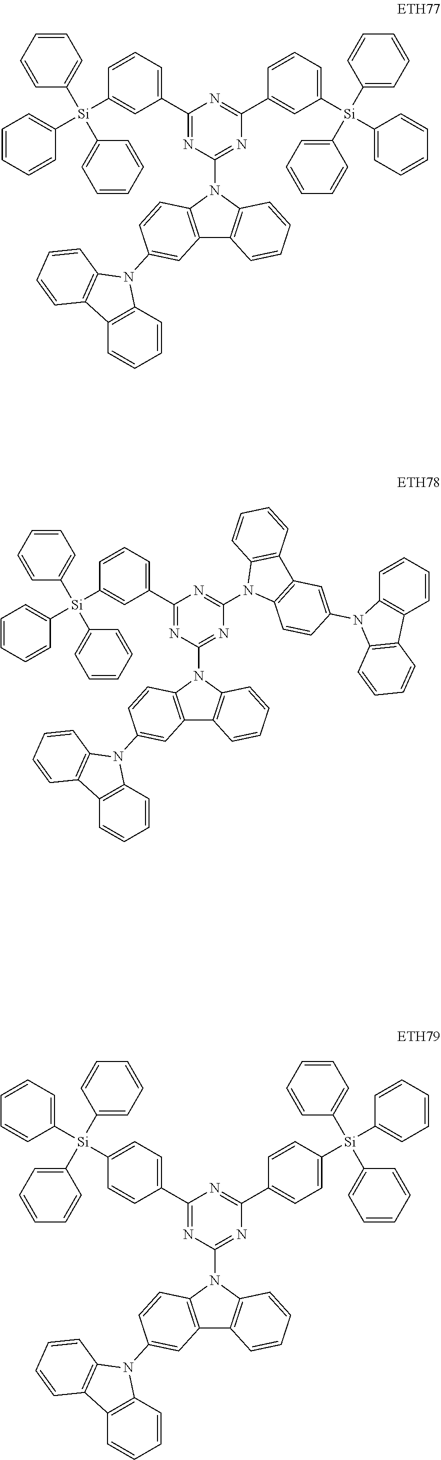 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

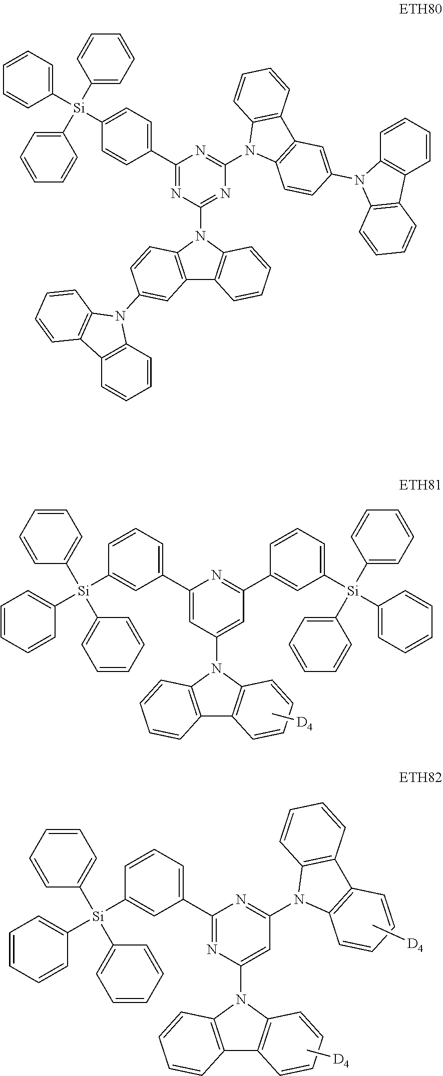

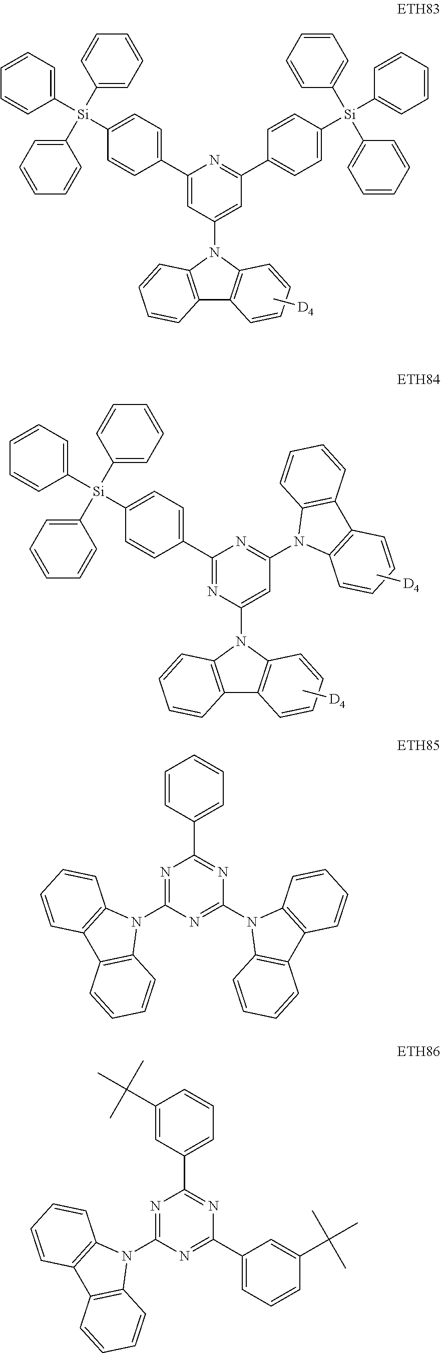

In an embodiment, the emission layer EML may include the second compound and the third compound, and the second compound and the third compound may form an exciplex. In the emission layer EML, an exciplex may be formed by a hole transport host and an electron transport host. A triplet energy of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy level (T1) of the exciplex formed by a hole transporting host and an electron transporting host may be in a range of about 2.4 eV to about 3.0 eV. A triplet energy of the exciplex may be a value that is smaller than an energy gap of each host material. The exciplex may have a triplet energy equal to or less than about 3.0 eV, which is an energy gap between the hole transporting host and the electron transporting host.

In an embodiment, the emission layer EML may include a fourth compound represented by Formula M-b. In an embodiment, the fourth compound represented by Formula M-b may be used as a phosphorescent sensitizer of an emission layer EML. In the emission layer EML, energy may be transferred from the fourth compound to the first compound, thereby emitting light.

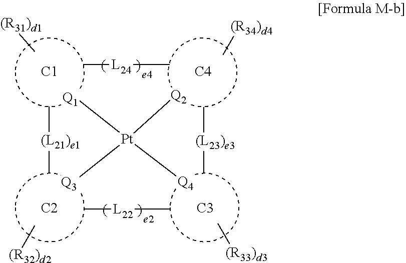

In Formula M-b, Q₁ to Q₄ may each independently be C or N; and C1 to C4 may each independently be a substituted or unsubstituted hydrocarbon ring group having 5 to 30 ring-forming carbon atoms or a substituted or unsubstituted heterocyclic group having 2 to 30 ring-forming carbon atoms.

In Formula M-b, e1 to e4 may each independently be 0 or 1; and L₂₁ to L₂₄ may each independently be a direct linkage,

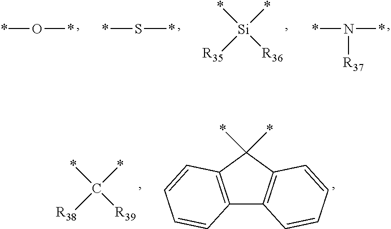

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

In Formula M-b, d1 to d4 may each independently be an integer from 0 to 4. When d1 2 or more, multiple R₃₁ groups may be the same as each other or at least one thereof may be different from the others. When d2 is 2 or more, multiple R₃₂ groups may be the same as each other or at least one thereof may be different from the others. When d3 is 2 or more, multiple R₃₃ groups may be the same as each other or at least one thereof may be different from the others. When d4 is 2 or more, multiple R₃₄ groups may be the same as each other or at least one thereof may be different from the others.

In Formula M-b, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In an embodiment, the fourth compound represented by Formula M-b maybe selected from Compound Group 4. In an embodiment, in the light emitting element ED, the fourth compound may include at least one compound selected from Compound Group 4:

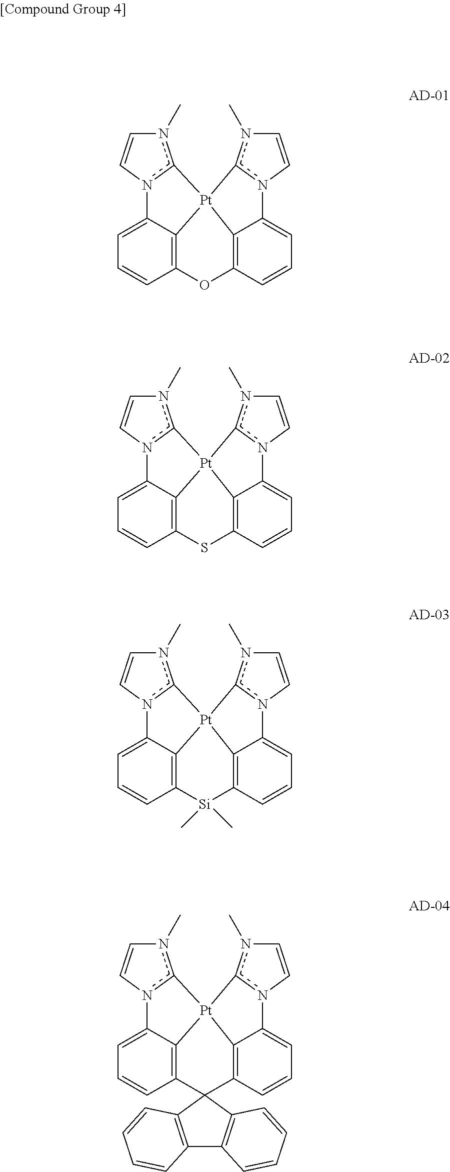

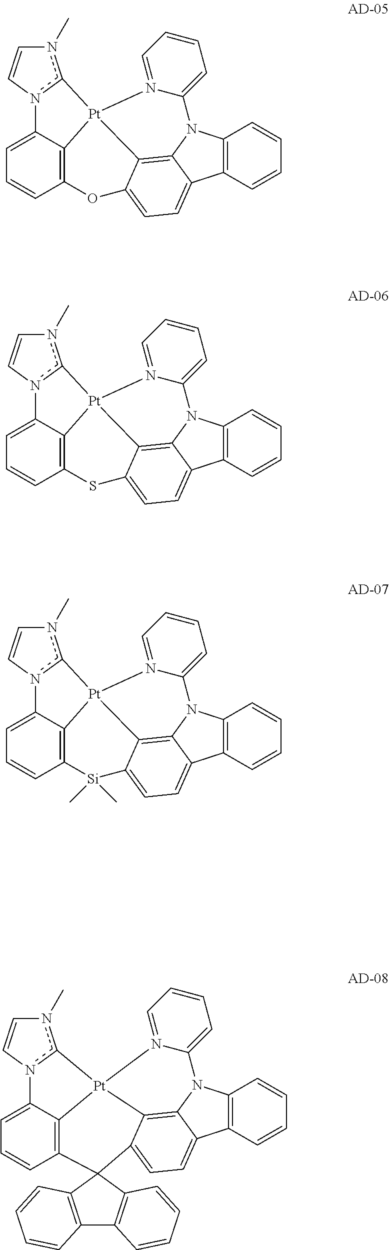

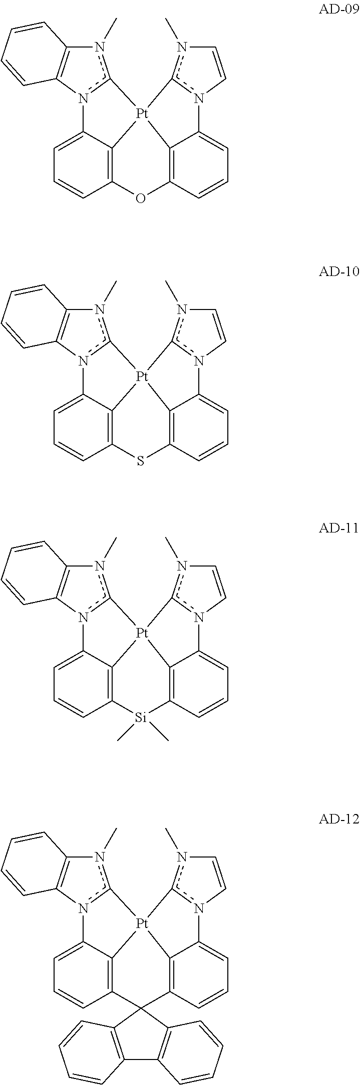

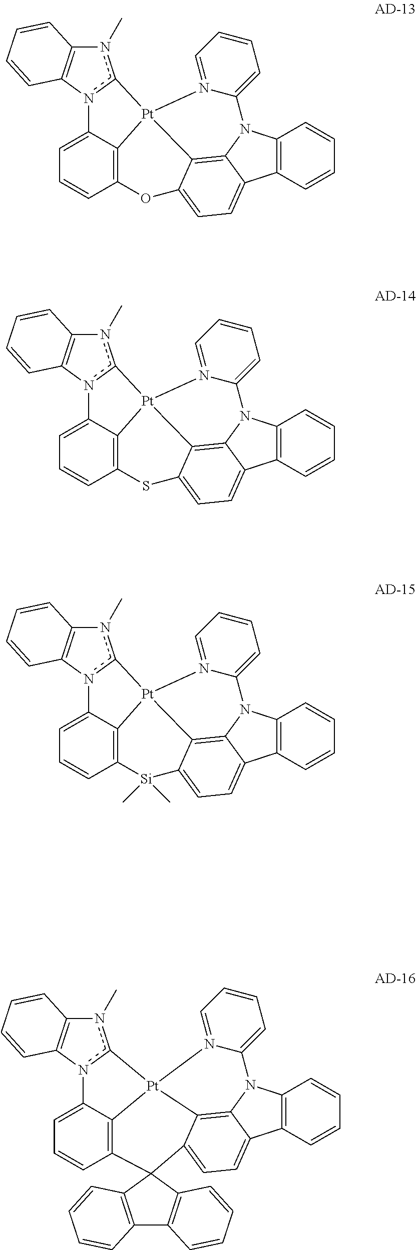

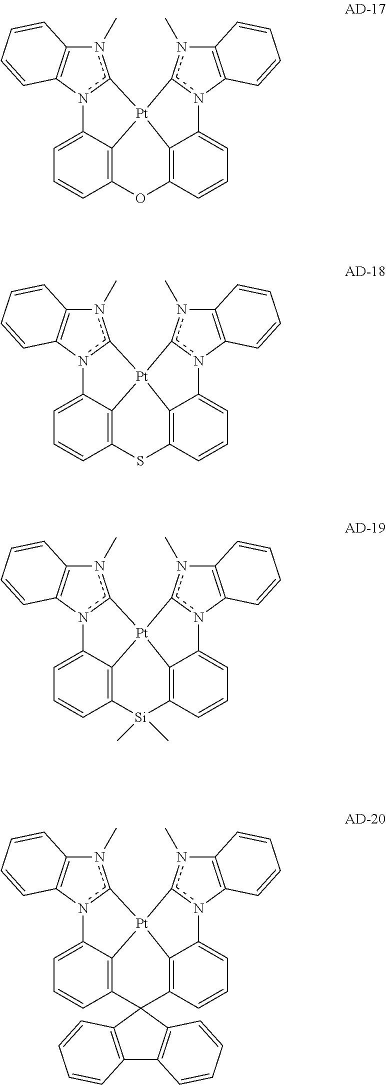

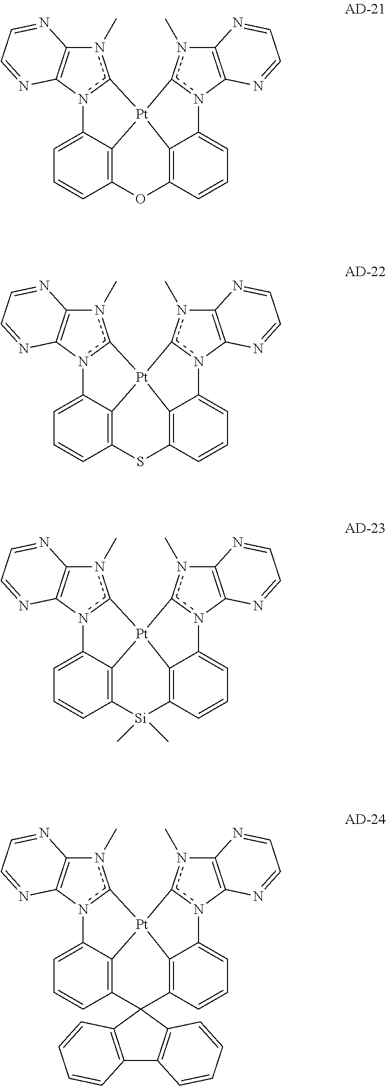

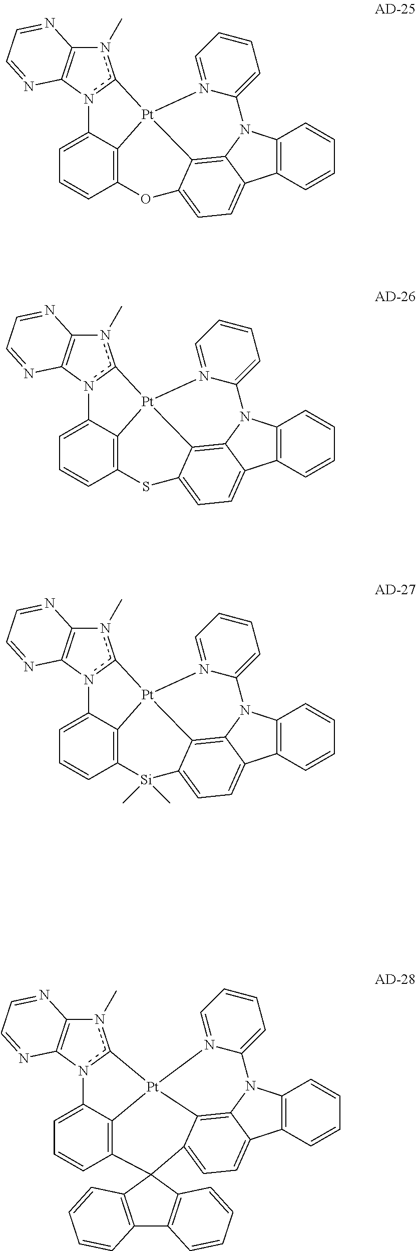

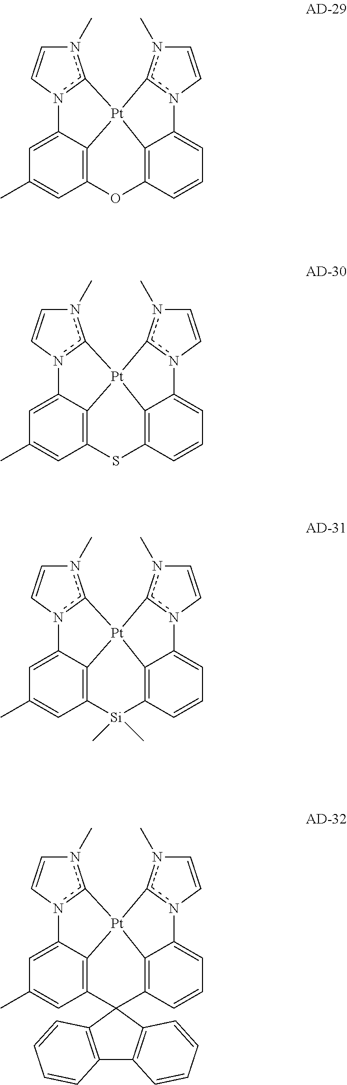

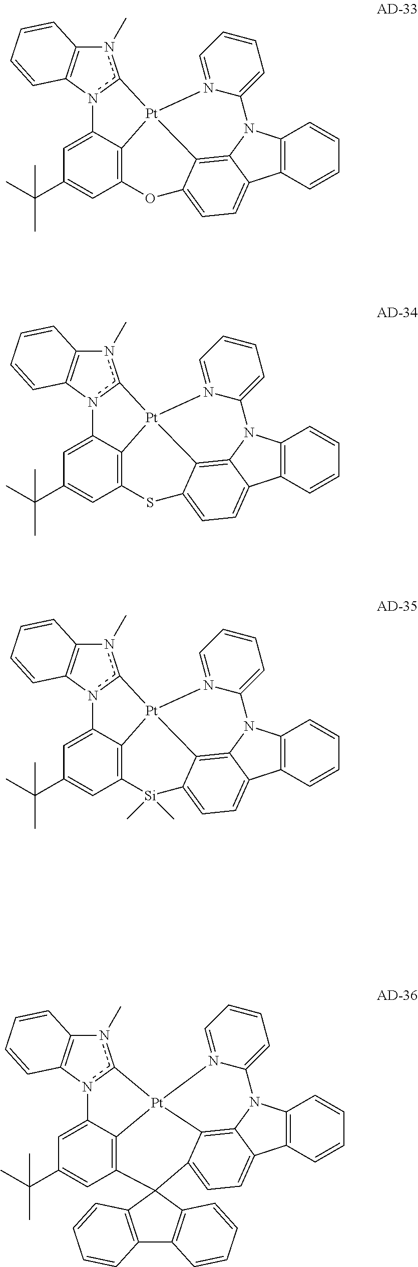

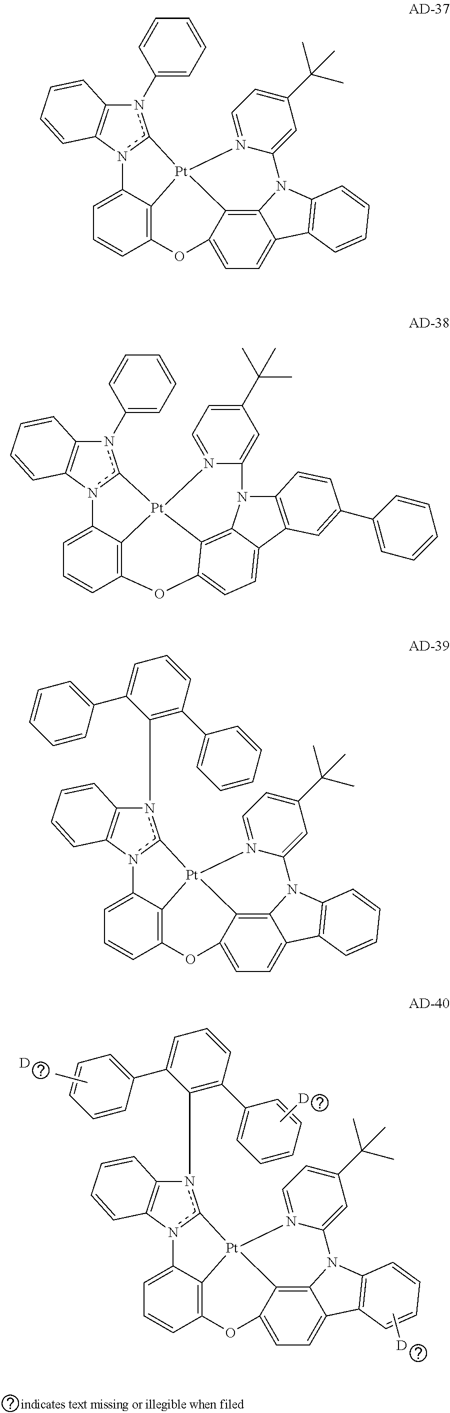

In an embodiment, the emission layer EML may include the first compound, which is a polycyclic compound according to an embodiment, and at least one of the second compound, the third compound, and the fourth compound. For example, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. The fourth compound may be referred to as a phosphorescent sensitizer. The fourth compound may emit phosphorescence or may transfer energy to the first compound as an auxiliary dopant. However, the functions of the compounds as described herein are presented only as examples, and embodiments are not limited thereto.

The light emitting element ED according to an embodiment may include all of the first compound, the second compound, the third compound, and the fourth compound, and the emission layer EML may include the combination of two host materials and two dopant materials. In the light emitting element ED, the emission layer EML may include two different hosts, the first compound may emit delayed fluorescence, and the fourth compound may include an organometallic complex, and the light emitting element ED may thus exhibit excellent luminous efficiency characteristics.

In an embodiment, the light emitting element ED may include multiple emission layers. The emission layers may be provided as a stack of emission layers to emit white light. The light emitting element including multiple emission layers may be a light emitting element having a tandem structure. When the light emitting element ED includes multiple emission layers, at least one emission layer EML may include the first compound represented by Formula 1. When the light emitting element ED includes multiple emission layers, at least one emission layer EML may include all of the first compound, the second compound, the third compound, and the fourth compound as described above. In an embodiment, the light emitting element may include the first compound represented by Formula 1 and the first-1 compound represented by Formula 1-A.

In an embodiment, the emission layer EML may further include a emission layer material of the related art, in addition to the first to fourth compounds as described herein. In the light emitting element ED, the emission layer EML may further include an anthracene derivative, a pyrene derivative, a fluoranthene derivative, a chrysene derivative, a dihydrobenzanthracene derivative, a triphenylene derivative, or the like. For example, the emission layer EML may further include an anthracene derivative or a pyrene derivative.

In the light emitting element ED according to embodiments as shown in each of FIGS. 3 to 6, the emission layer EML may include a compound represented by Formula E-1. The compound represented by Formula E-1 may be used as a fluorescent host material.

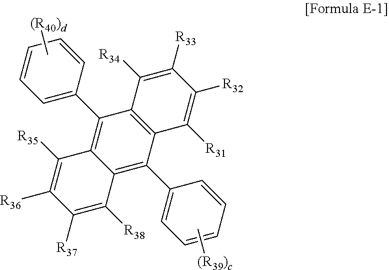

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, in Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

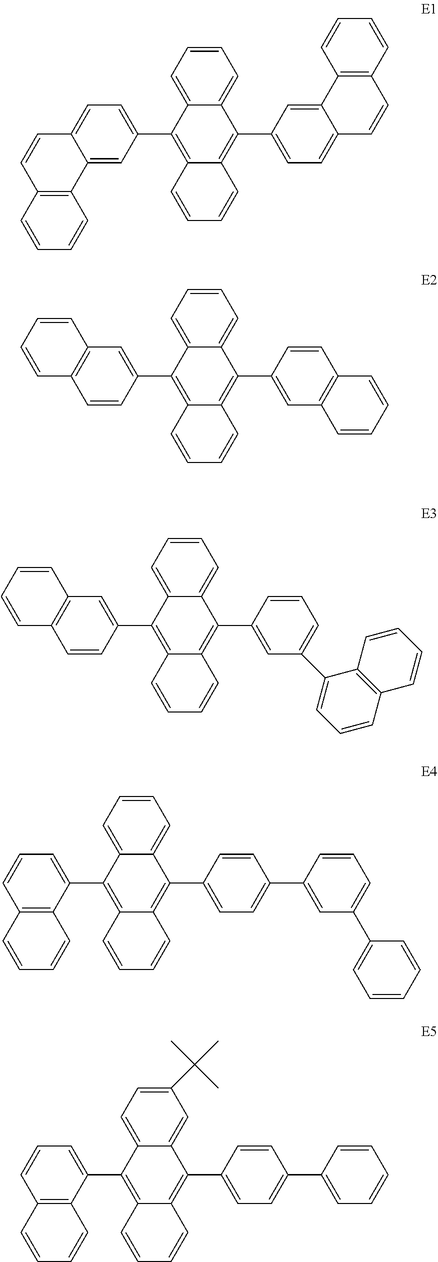

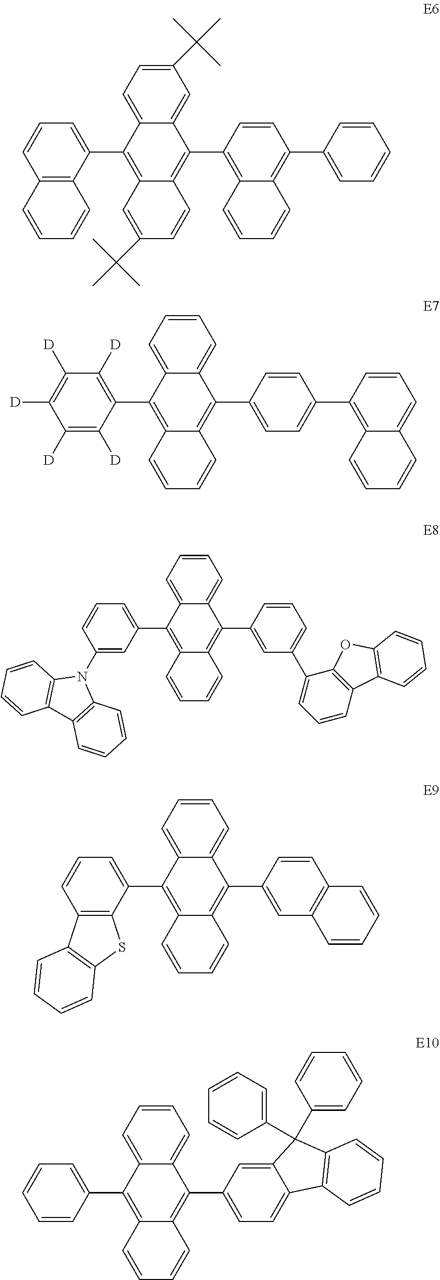

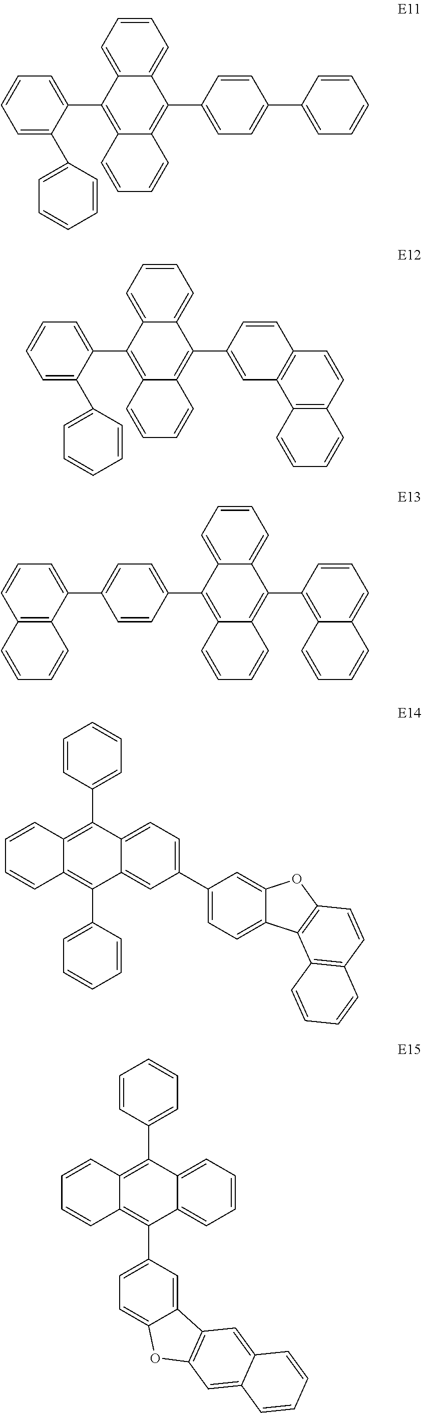

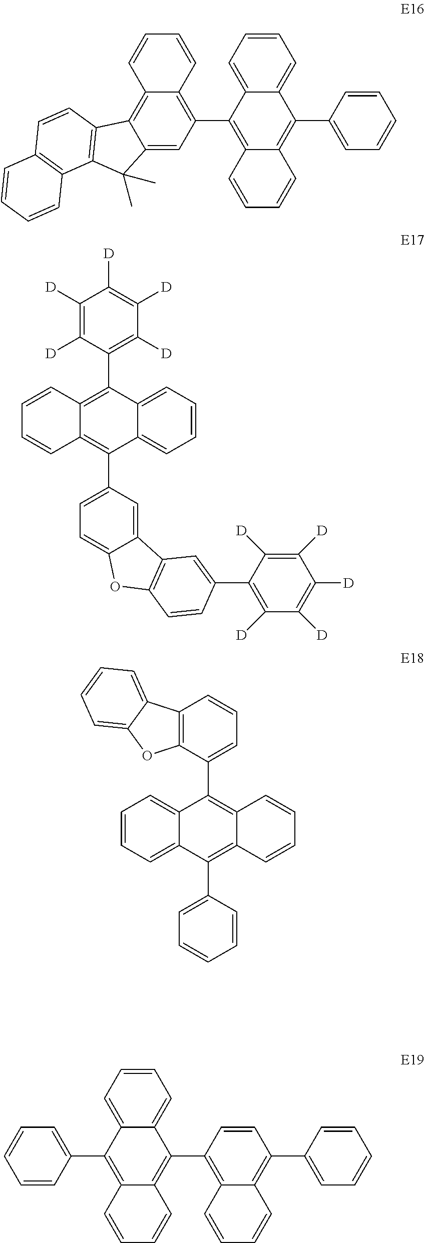

In an embodiment, the emission layer EML may include a compound represented by Formula E-2a or Formula E-2b. The compound represented by Formula E-2a or Formula E-2b may be used as a phosphorescent host material.

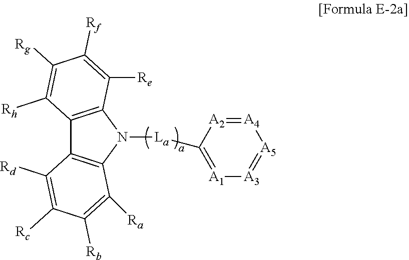

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms.

When a is 2 or more, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

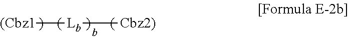

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2:

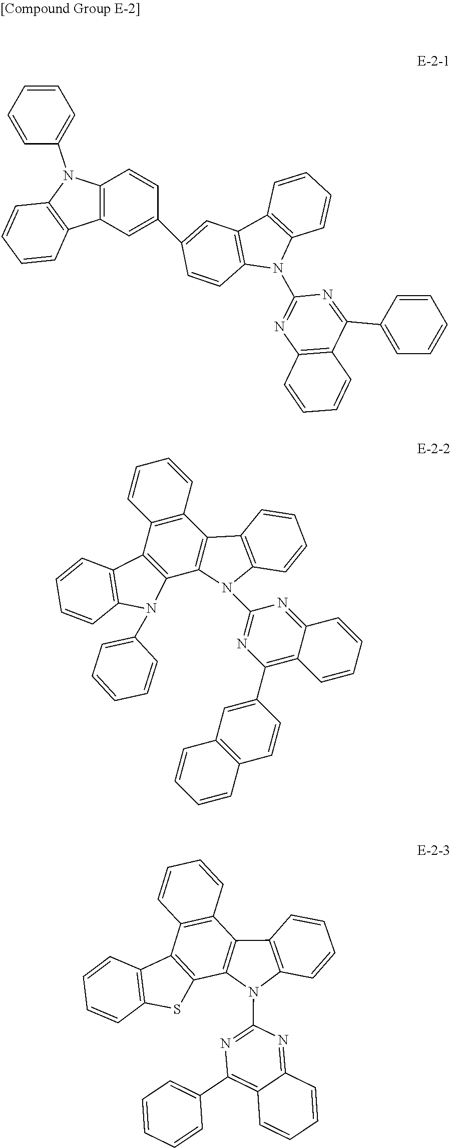 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

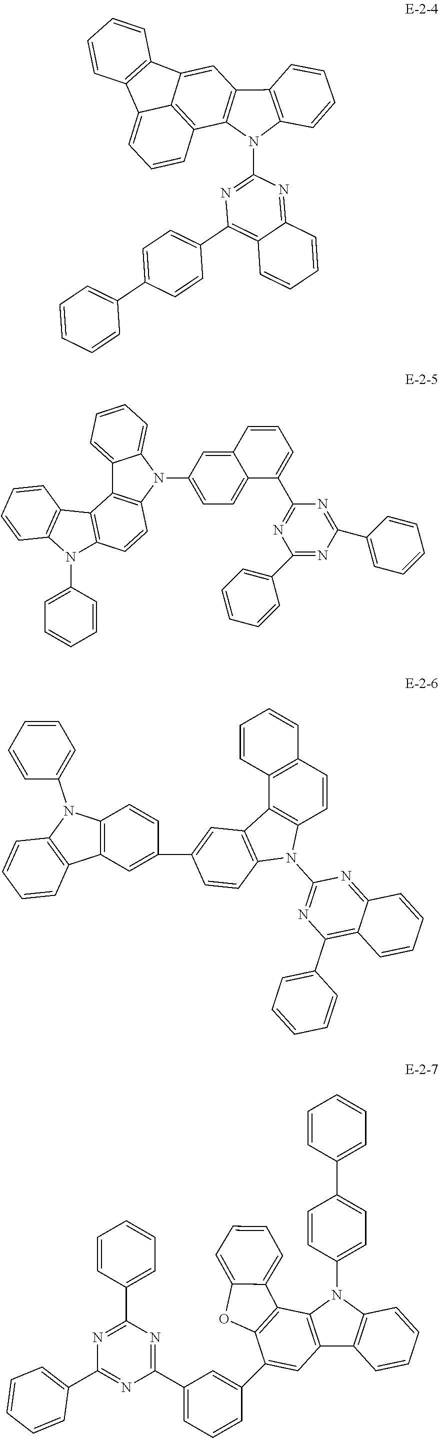 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

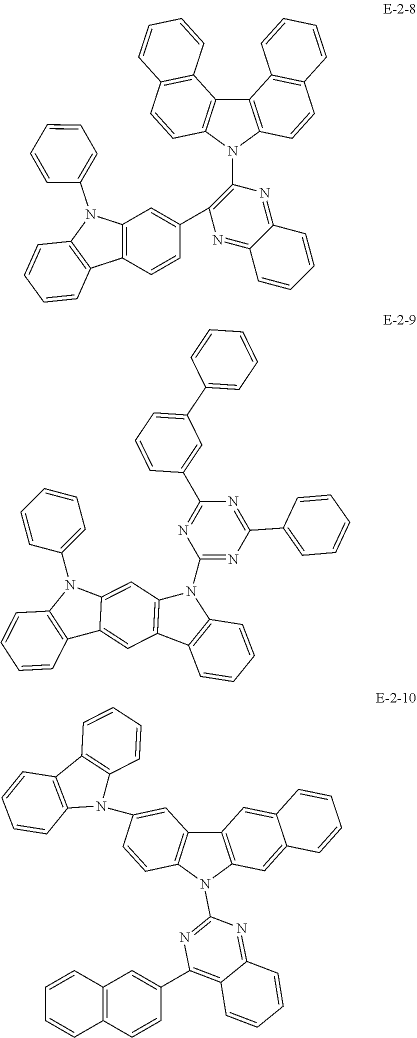 [SMILES: c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

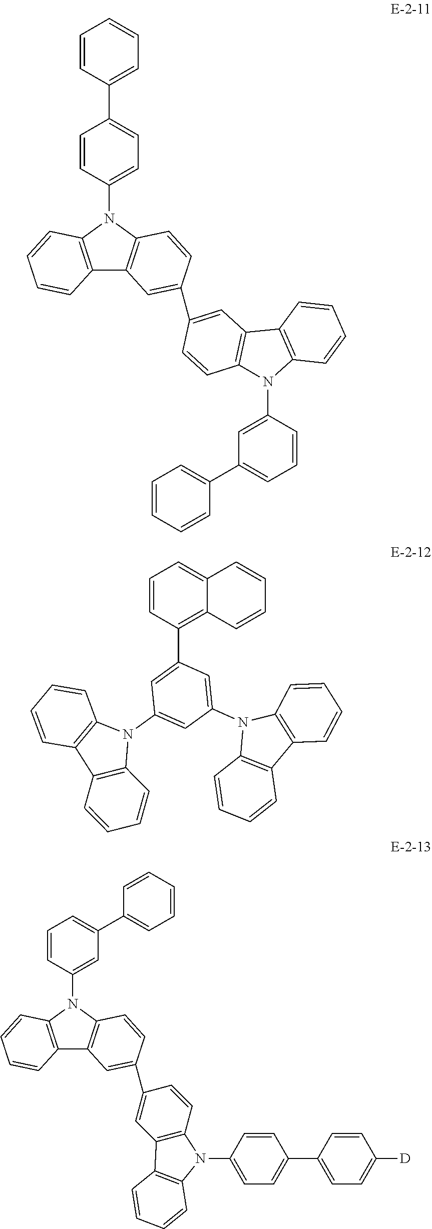

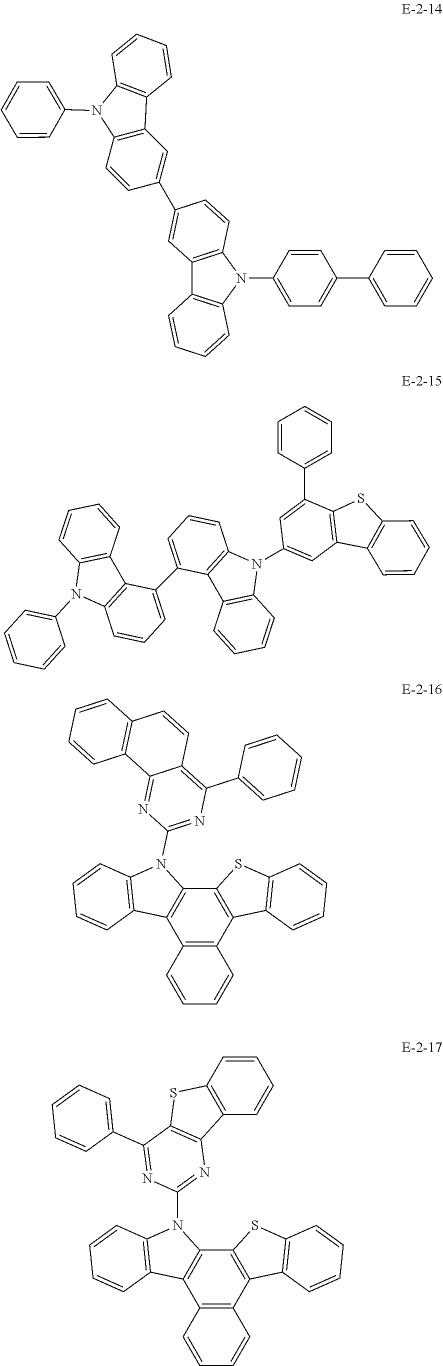 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1]

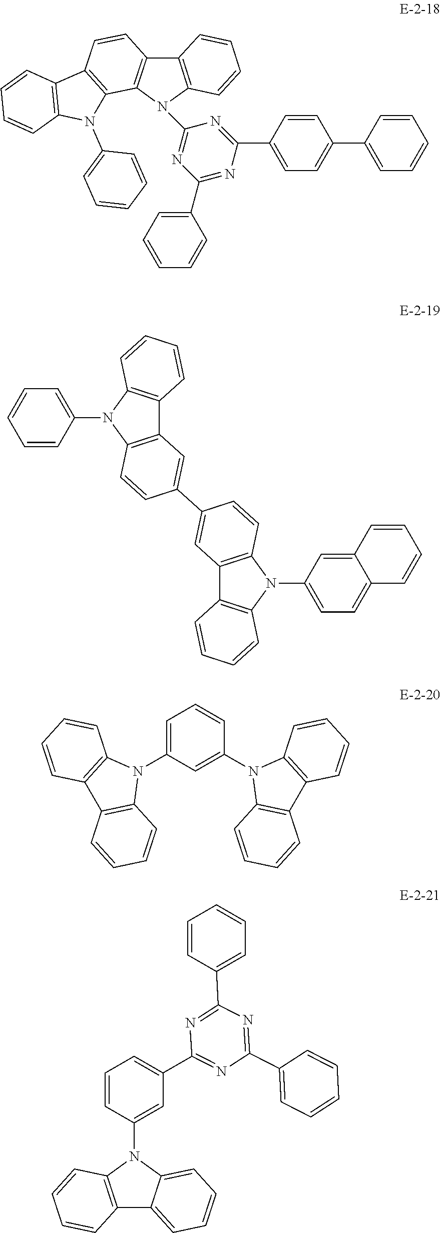 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

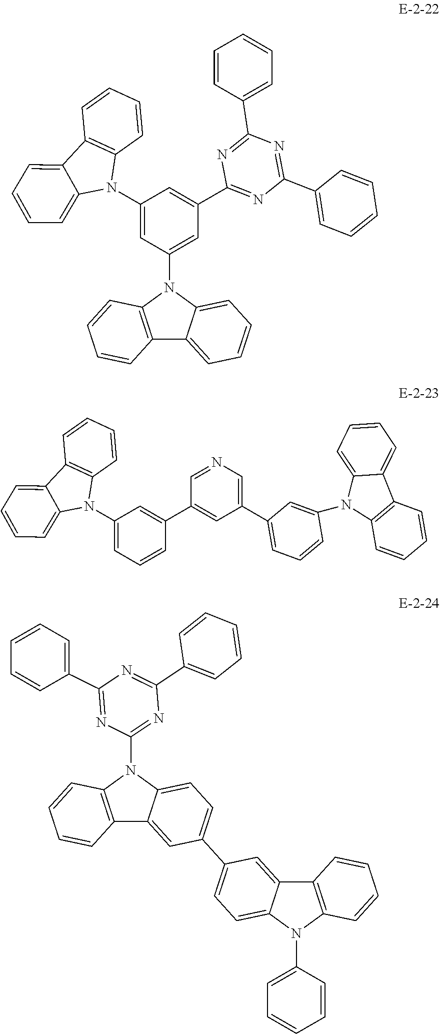 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

The emission layer EML may include a compound represented by Formula M-a. The compound represented by Formula M-a may be used as a phosphorescent dopant material. In an embodiment, the compound represented by Formula M-a may be used as an auxiliary dopant material.

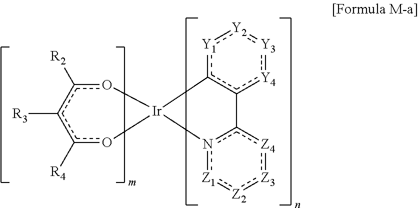

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

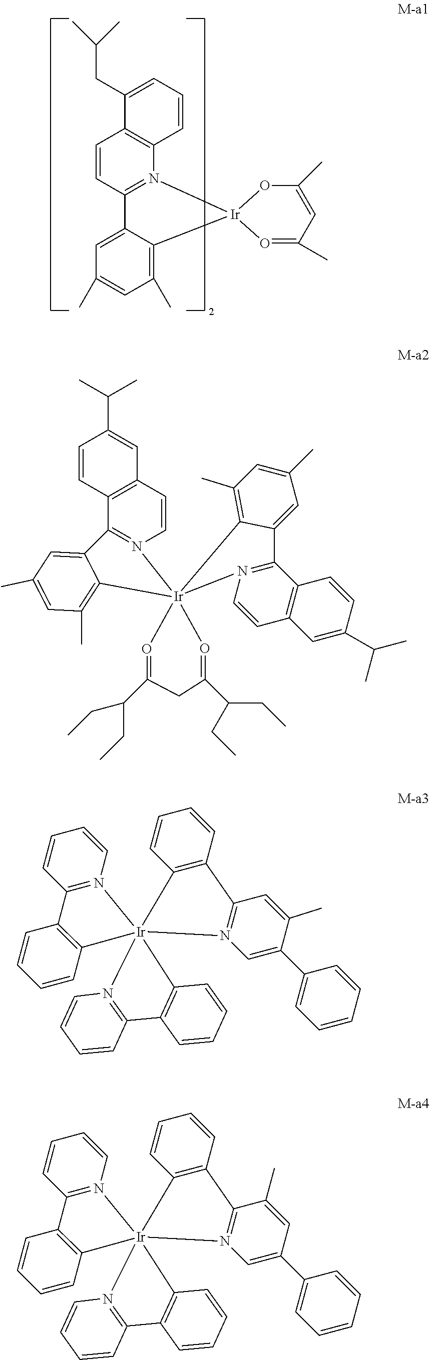

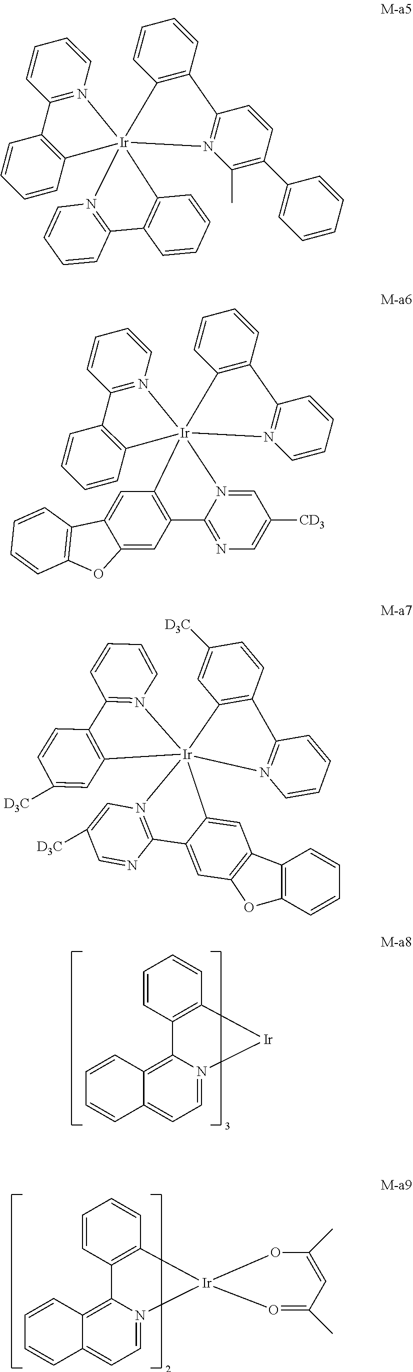

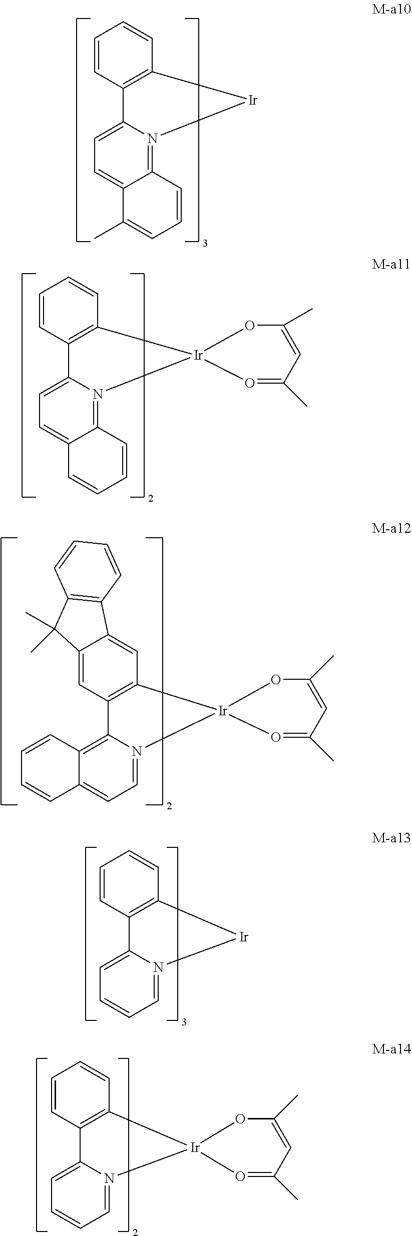

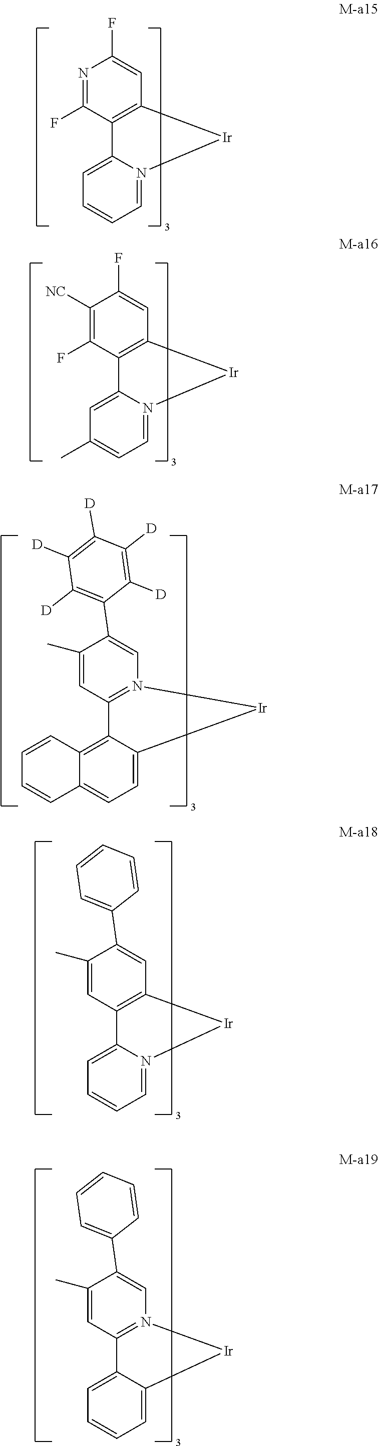

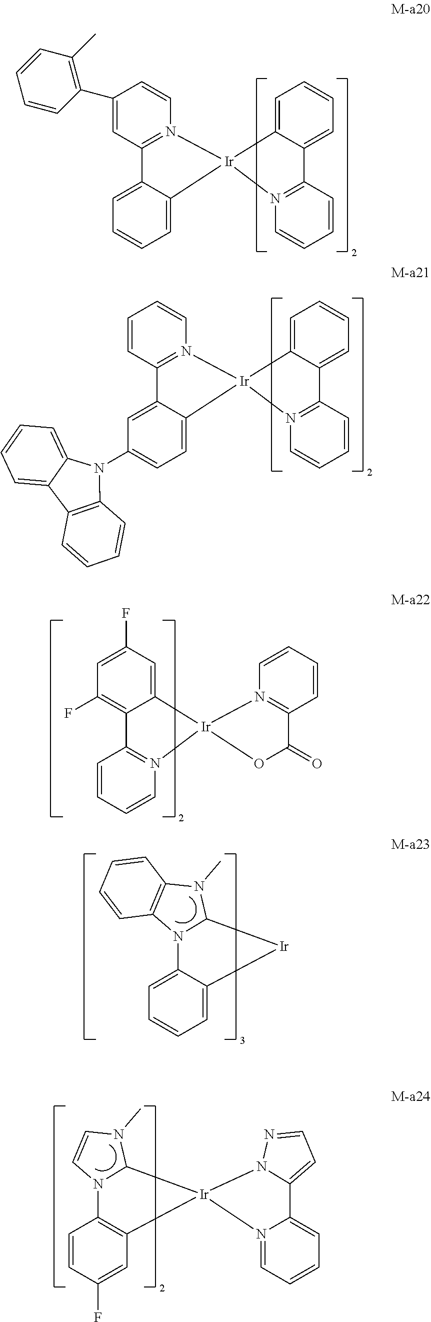

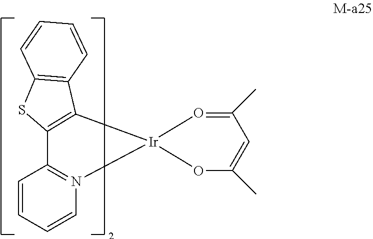

Compound M-a1 and Compound M-a2 may each be used as a red dopant material, and Compound M-a3 to Compound M-a7 may each be used as a green dopant material.

The emission layer EML may further include a compound represented by any one of Formula F-a to Formula F-c. The compound represented by one of Formula F-a to Formula F-c may be used as a fluorescence dopant material.

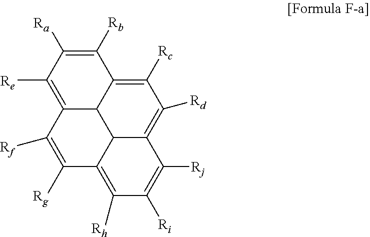

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ or Ar₂ may be a heteroaryl group containing O or S as a ring-forming atom.

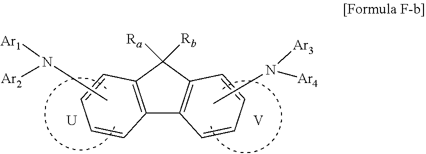

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When the number of U and V are each 0, a fused ring having a fluorene core of Formula F-b may be a cyclic compound having three rings. When the number of U and V are each 1, a fused ring having a fluorene core of Formula F-b may be a cyclic compound having five rings.

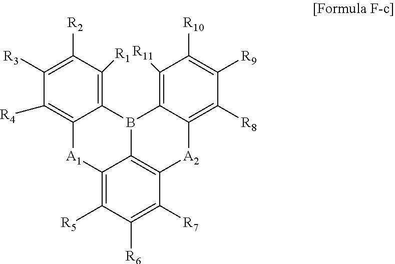

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to the substituents of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may include, as a dopant material of the related art, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (FIr6), or platinum octaethyl porphyrin (PtOEP) may be used as a phosphorescent dopant. However, embodiments are not limited thereto.

In an embodiment, the emission layer EML may include a quantum dot. The quantum dot may be a Group II-VI compound, a Group III-VI compound, a Group 1-III-VI compound, a Group III-V compound, a Group III-II-V compound, a Group IV-VI compound, a Group IV element, a Group IV compound, or any combination thereof.

The Group II-VI compound may include: a binary compound selected from the group consisting of CdSe, CdTe, CdS, ZnS, ZnSe, ZnTe, ZnO, HgS, HgSe, HgTe, MgSe, MgS, and any mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any mixture thereof, a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and any mixture thereof, or any combination thereof.

The Group III-VI compound may include: a binary compound such as In₂S₃ or In₂Se₃; a ternary compound such as InGaS₃ or InGaSe₃; or any combination thereof.

The Group 1-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and any mixture thereof, a quaternary compound such as AgInGaS₂ or CuInGaS₂; or any combination thereof.

The Group III-V compound may include: a binary compound selected from the group consisting of GaN, GaP, GaAs, GaSb, AlN, AlP, AlAs, AlSb, InN, InP, InAs, InSb, and any mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and any mixture thereof, a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any mixture thereof, or any combination thereof. In an embodiment, the Group III-V compound may further include a Group II metal. For example, InZnP, etc., may be selected as a Group III-II-V compound.

The Group IV-VI compound may include: a binary compound selected from the group consisting of SnS, SnSe, SnTe, PbS, PbSe, PbTe, and any mixture thereof, a ternary compound selected from the group consisting of SnSeS, SnSeTe, SnSTe, PbSeS, PbSeTe, PbSTe, SnPbS, SnPbSe, SnPbTe, and any mixture thereof, a quaternary compound selected from the group consisting of SnPbSSe, SnPbSeTe, SnPbSTe, and any mixture thereof, or any combination thereof. The Group IV element may be Si, Ge, or any mixture thereof. The Group IV compound may include a binary compound selected from the group consisting of SiC, SiGe, and any mixture thereof.

A binary compound, a ternary compound, or a quaternary compound may be present in a particle at a uniform concentration distribution, or may be present in a particle at a partially different concentration distribution. In an embodiment, the quantum dot may have a core/shell structure in which a quantum dot surrounds another quantum dot. A quantum dot having a core/shell structure may have a concentration gradient in which the concentration a material that is present in the shell decreases toward the core.

In embodiments, the quantum dot may have the above-described core/shell structure including a core containing nanocrystals and a shell surrounding the core. The shell of the quantum dot may serve as a protection layer to prevent the chemical deformation of the core to maintain semiconductor properties, and/or may serve a charging layer to impart electrophoresis properties to the quantum dot. The shell may be a single layer or a multilayer. Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; a ternary compound such as MgAl₂O₄, CoFe₂O₄, NiFe₂O₄, and CoMn₂O₄; or any combination thereof. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of the quantum dot is not particularly limited may be any form used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplate particles, etc.

A quantum dot may control the color of emitted light according to a particle size thereof. Accordingly, the quantum dot may have various light emission colors such as blue, red, or green.

In the light emitting elements ED according to an embodiment as shown in each of FIGS. 3 to 6, the electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure including different materials, or may have a structure in which an electron transport layer ETL/electron injection layer EIL, a hole blocking layer HBL/electron transport layer ETL/electron injection layer EIL, or an electron transport layer ETL/buffer layer (not shown)/electron injection layer EIL are stacked in its respective stated order from an emission layer EML, but embodiments are not limited thereto. The electron transport region ETR may have a thickness, for example, in a range of about 1,000 Å to about 1,500 Å.

The electron transport region ETR may be formed by using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-1:

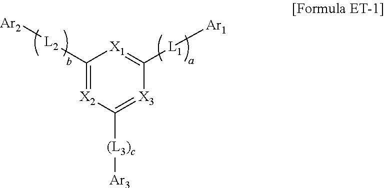

In Formula ET-1, at least one of X₁ to X₃ may each be N, and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each independently 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or any mixture thereof.

In an embodiment, the electron transport region ETR may include at least one compound selected from Compound ET1 to Compound ET36:

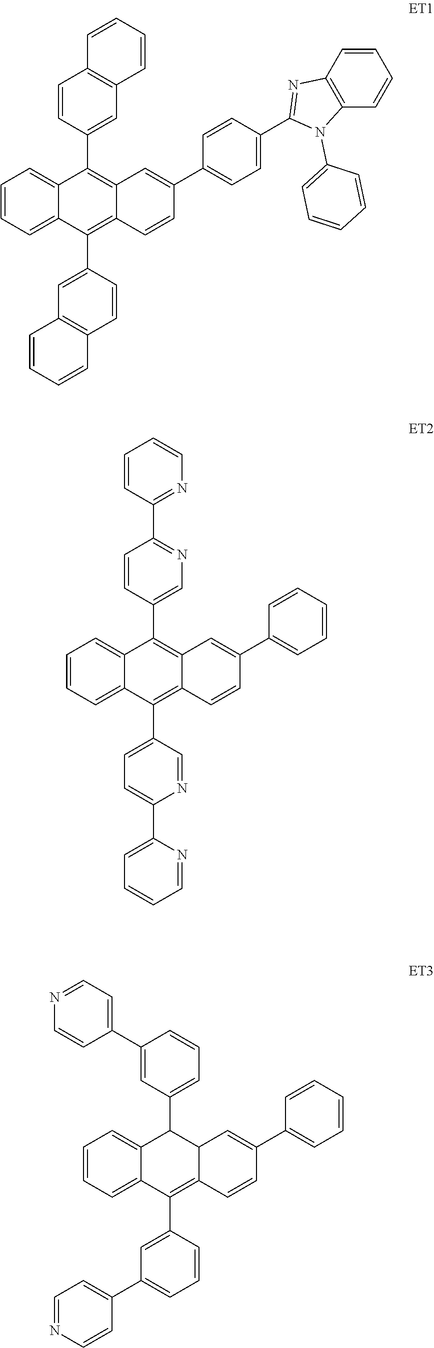

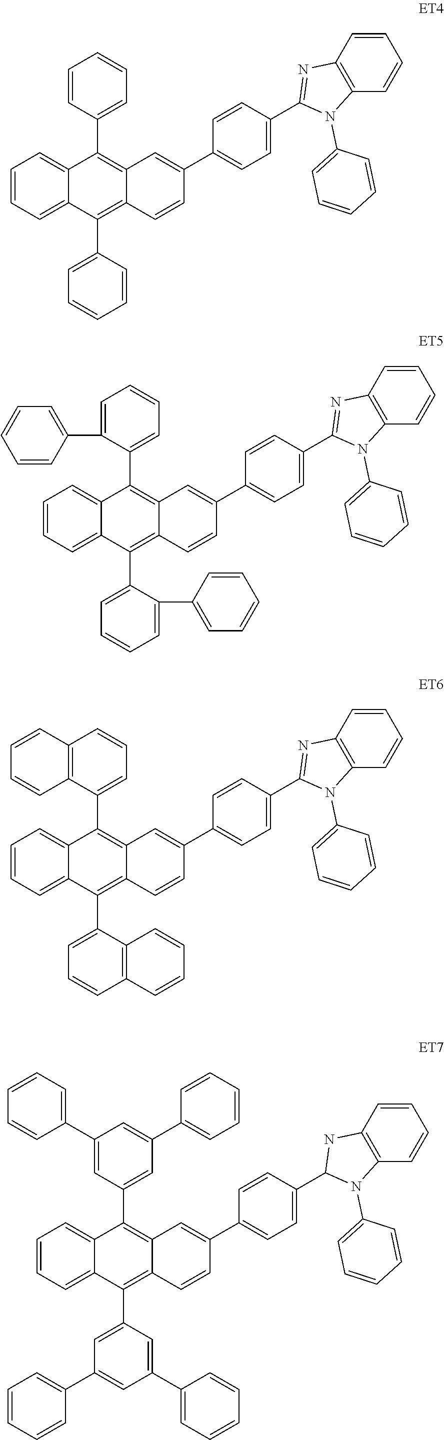

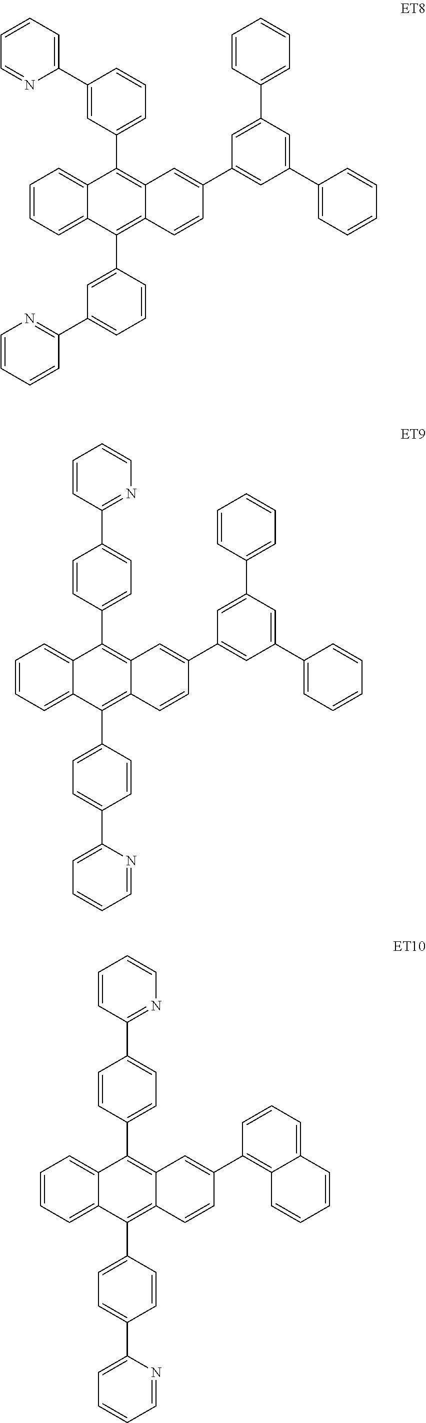 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

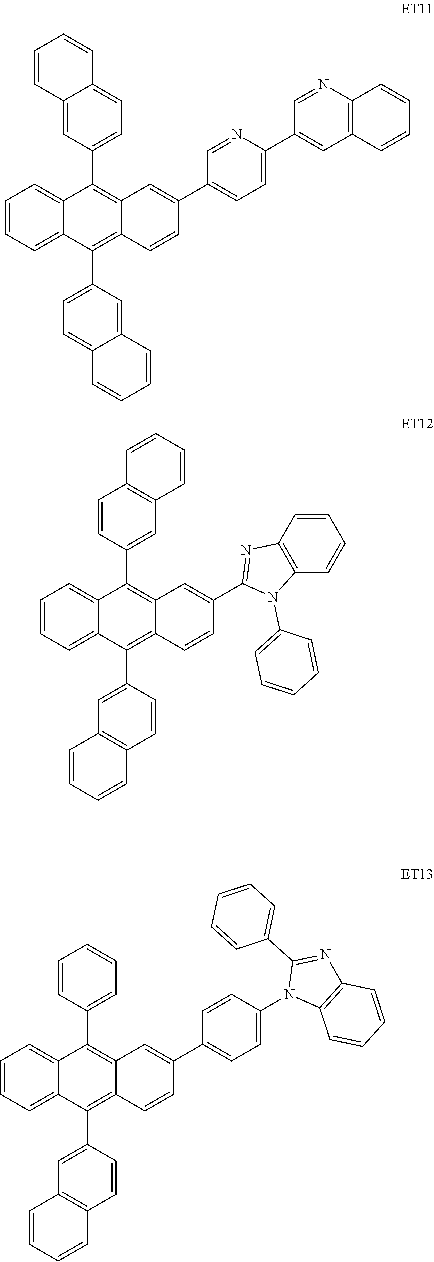 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

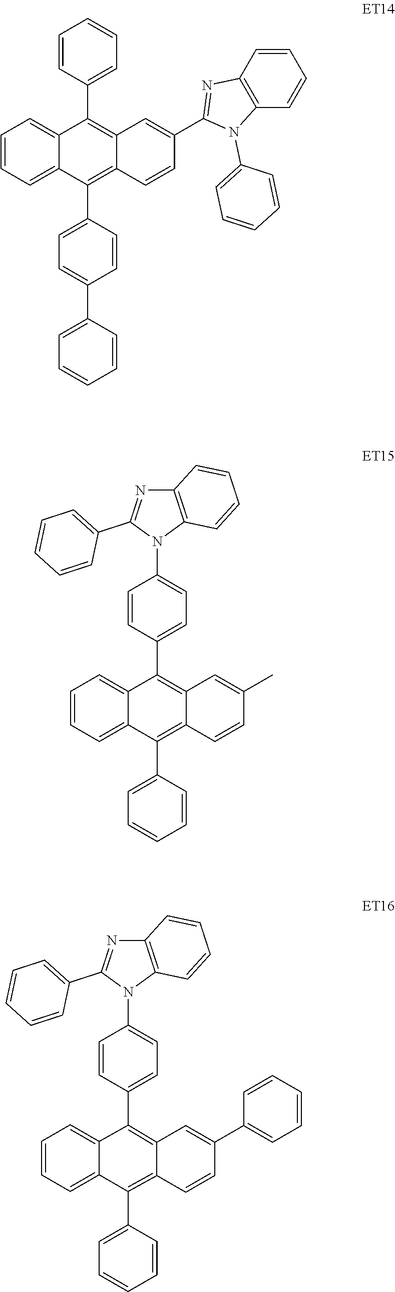 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

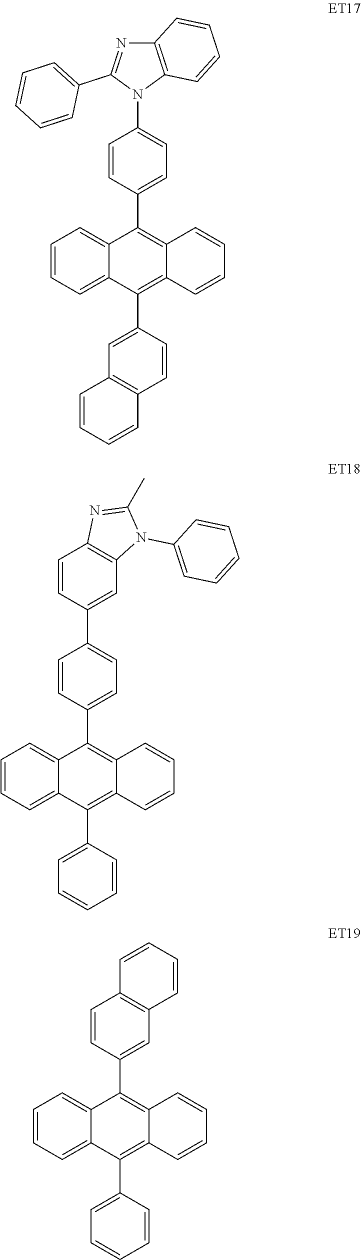

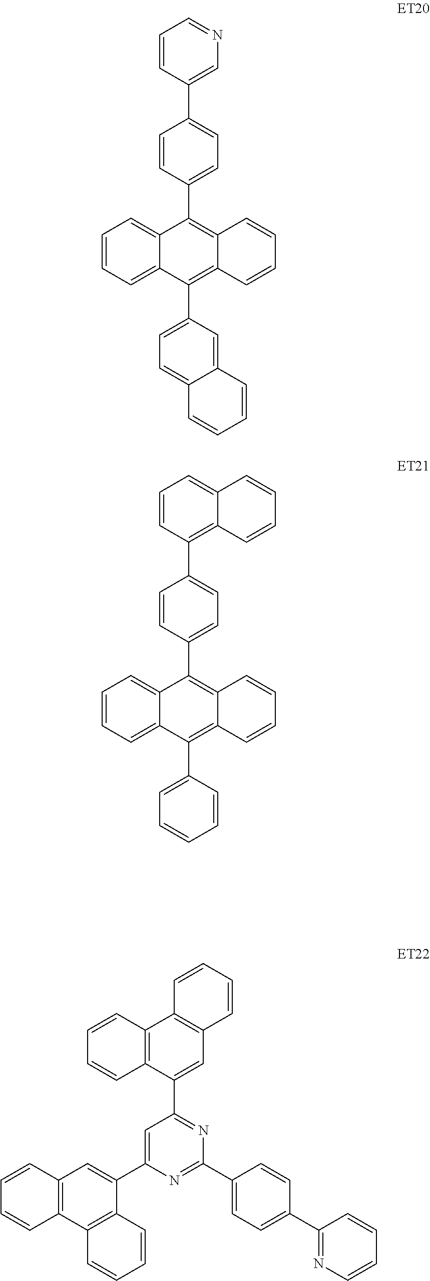

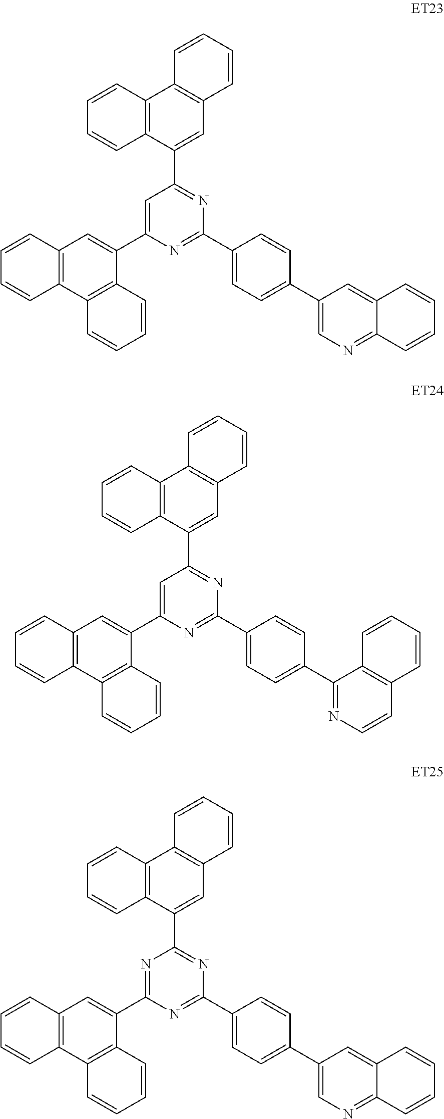 [SMILES: c1ccc2ncc(-c3ccc(-c4nc(-c5cc6ccccc6c6ccccc56)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

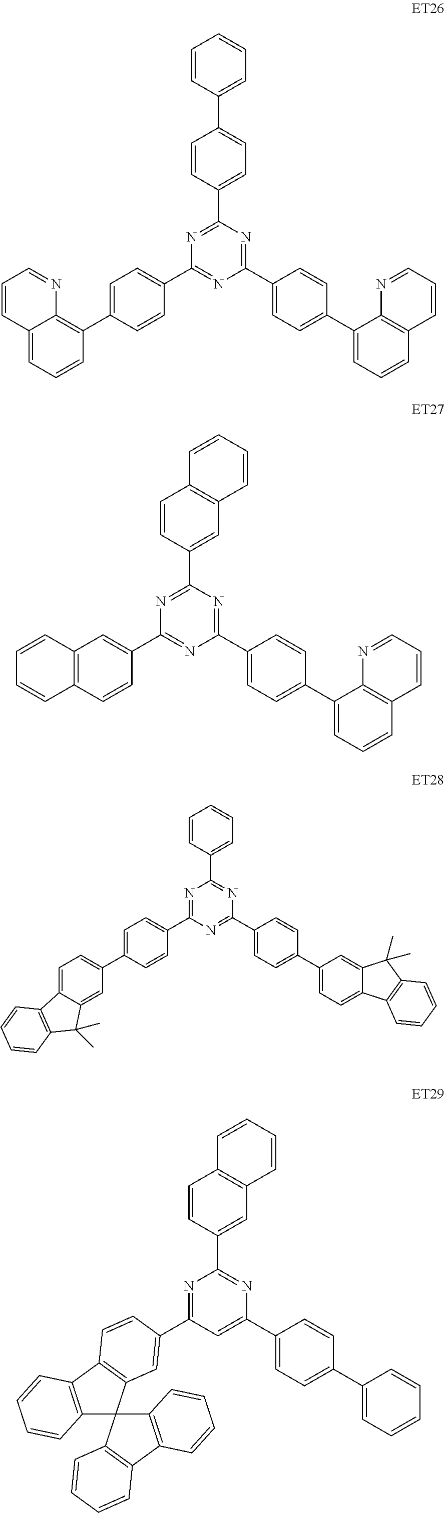 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

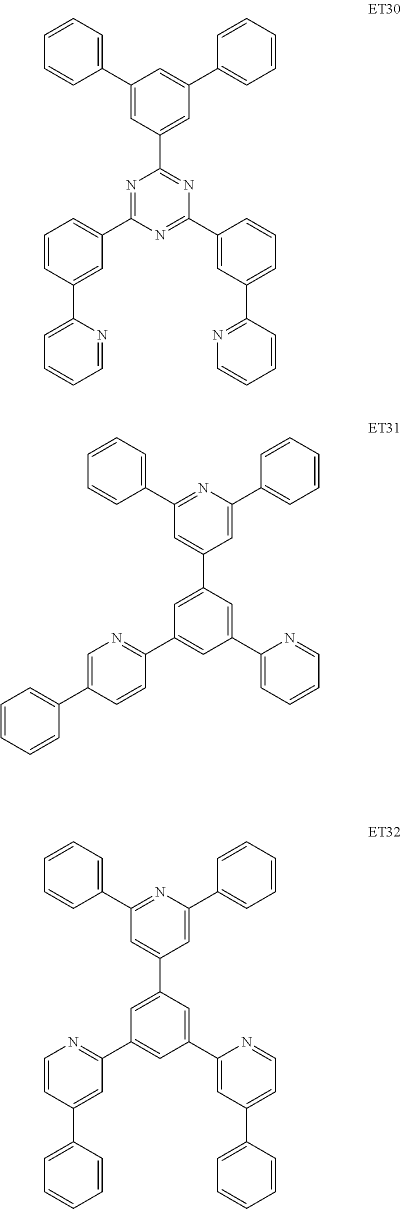 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

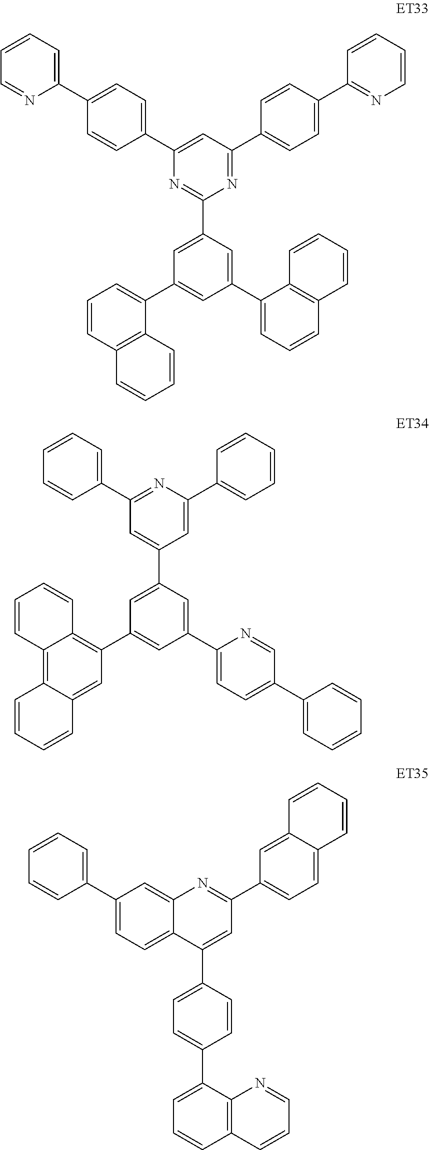

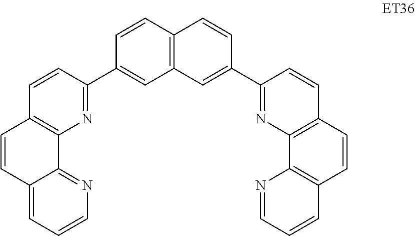 [SMILES: c1cnc2c(c1)ccc1ccc(-c3ccc4ccc(-c5ccc6ccc7cccnc7c6n5)cc4c3)nc12]

In an embodiment, the electron transport regions ETR may include a metal halide such as LiF, NaCl, CsF, RbCl, RbI, CuI, or KI; a lanthanide metal such as Yb; or a co-deposited material of the metal halide and the lanthanide metal. For example, the electron transport region ETR may include KI:Yb, RbI:Yb, LiF:Yb, etc., as a co-deposited material. The electron transport region ETR may include a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the electron transport region in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode. The second electrode may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, a compound thereof, or a mixture thereof (e.g., AgMg, AgYb, or MgYb). In another embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, the resistance of the second electrode EL2 may be decreased.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNₓ, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., or an epoxy resin, or an acrylate such as methacrylate. However, embodiments are not limited thereto, and the capping layer CPL may include at least one of Compounds P1 to P5:

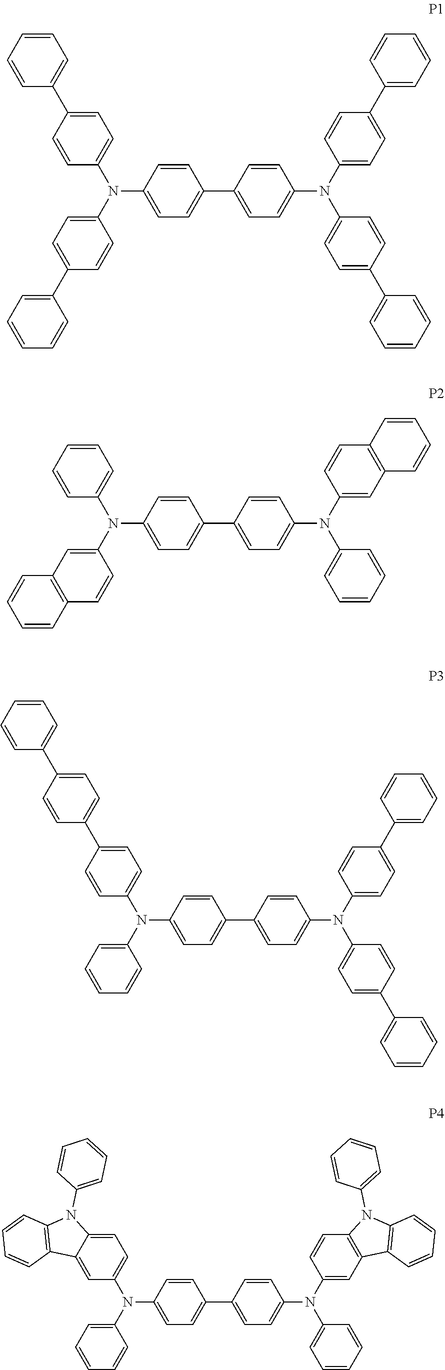 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

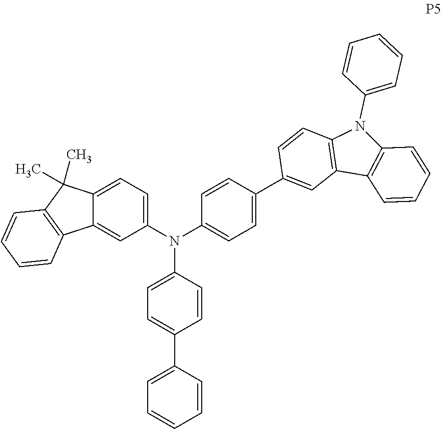 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, a refractive index of the capping layer CPL may be equal to or greater than 1.6 with respect to light in a wavelength range of about 550 nm to about 660 nm.

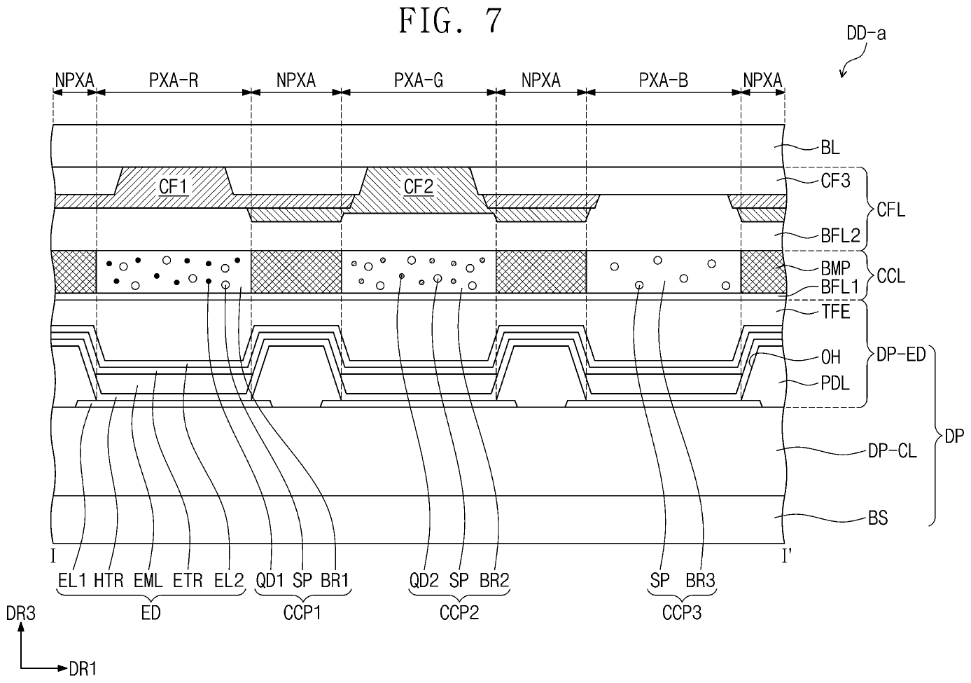

FIGS. 7 to 10 are each a schematic cross-sectional view of a display device according to an embodiment. Hereinafter, in describing the display devices according to embodiments in reference to FIGS. 7 to 10, the features which have been described above with respect to FIGS. 1 to 6 will not be explained again, and the differing features will be described.

Referring to FIG. 7, the display device DD-a according to an embodiment may include a display panel DP including a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED illustrated in FIG. 7 may be the same as a structure of a light emitting element ED according to one of FIGS. 3 to 6 as described herein.

In the display device DD-a, the emission layer EML of the light emitting element ED may include the polycyclic compound according to an embodiment.

Referring to FIG. 7, the emission layer EML may be disposed in an opening OH defined in a pixel defining film PDL. For example, the emission layer EML, which is divided by the pixel defining film PDL and correspondingly provided to each of the light emitting regions PXA-R, PXA-G, and PXA-B, may each emit light in a same wavelength range. In the display device DD-a, the emission layer EML may emit blue light. Although not shown in the drawings, in an embodiment, the emission layer EML may be provided as a common layer for all of the entire light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. In FIG. 7, it is shown that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 that transmits the first color light.

In an embodiment, the first light control part CCP1 may provide red light, which may be the second color light, and the second light control part CCP2 may provide green light, which may be the third color light. The third light control part CCP3 may transmit and provide blue light, which may be the first color light provided from the light emitting element ED. For example, the first quantum dot QD1 may be a red quantum dot, and the second quantum dot QD2 may be a green quantum dot. The quantum dots QD1 and QD2 may each be a quantum dot as described herein.

The light control layer CCL may further include a scatterer SP. The first light control part CCP1 may include the first quantum dot QD1 and a scatterer SP, the second light control part CCP2 may include the second quantum dot QD2 and a scatterer SP, and the third light control part CCP3 may not include any quantum dot but may include a scatterer SP.

The scatterer SP may be inorganic particles. For example, the scatterer SP may include at least one of TiO₂, ZnO, Al₂O₃, SiO₂, or hollow silica. The scatterer SP may include any one of TiO₂, ZnO, Al₂O₃, SiO₂, and hollow silica, or the scatterer SP may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are each a medium in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and filters CF1, CF2, and CF3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic film. The barrier layers BFL1 and BFL2 may be formed of a single layer or of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated and may be provided as one filter.

The first to third filters CF1, CF2, and CF3 may be disposed to respectively correspond to the red light emitting region PXA-R, the green light emitting region PXA-G, and the blue light emitting region PXA-B.

Although not shown in the drawings, the color filter layer CFL may include a light shielding part (not shown). The color filter layer CFL may include a light shielding part (not shown) disposed so as to overlap the boundaries of neighboring filters CF1, CF2, and CF3. The light shielding part (not shown) may be a black matrix. The light shielding part (not shown) may include an organic light shielding material or an inorganic light shielding material containing a black pigment or dye. The light shielding part (not shown) may separate boundaries between adjacent filters CF1, CF2, and CF3. In an embodiment, the light shielding part (not shown) may be formed of a blue filter.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

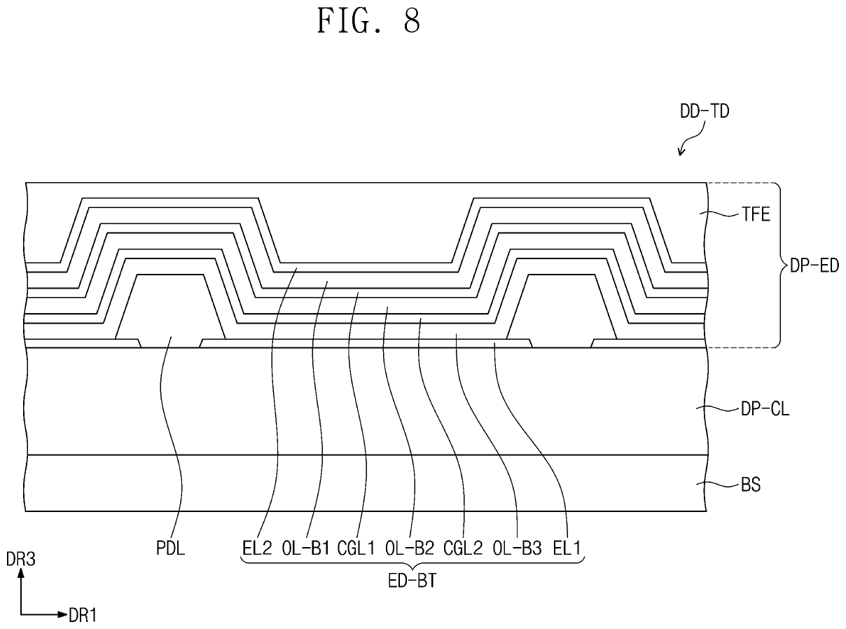

FIG. 8 is a schematic cross-sectional view of a portion of a display device according to an embodiment. In the display device DD-TD according to an embodiment, the light emitting element ED-BT may include light emitting structures OL-B1, OL-B2, and OL-B3. The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. At least one of the light emitting structures OL-B1, OL-B2, and OL-B3 may include the polycyclic compound according to an embodiment as described above. The light emitting structures OL-B1, OL-B2, and OL-B3 may each include an emission layer EML (FIG. 7) and a hole transport region HTR (FIG. 7) and an electron transport region ETR (FIG. 7) disposed with the emission layer EML located therebetween.

For example, the light emitting element ED-BT included in the display device DD-TD may be a light emitting element having a tandem structure and including multiple emission layers EML.

In an embodiment illustrated in FIG. 8, light emitted from the light emitting structures OL-B1, OL-B2, and OL-B3 may each be blue light. However, embodiments are not limited thereto, and the light emitted from the light emitting structures OL-B1, OL-B2, and OL-B3 may have wavelength ranges that are different from each other. For example, the light emitting element ED-BT that includes the light emitting structures OL-B1, OL-B2, and OL-B3, which emit light having wavelength ranges that are different from each other, may emit white light.

Charge generation layers CGL1 and CGL2 may each be disposed between neighboring light emitting structures OL-B1, OL-B2, and OL-B3. Charge generation layers CGL1 and CGL2 may each independently include a p-type charge generation layer and/or an n-type charge generation layer.

In an embodiment, at least one of the light emitting structures OL-B1, OL-B2, and OL-B3 included in the display device DD-TD may include the polycyclic compound according to an embodiment as described herein. For example, at least one of the emission layers included in the light emitting element ED-BT may include the polycyclic compound.

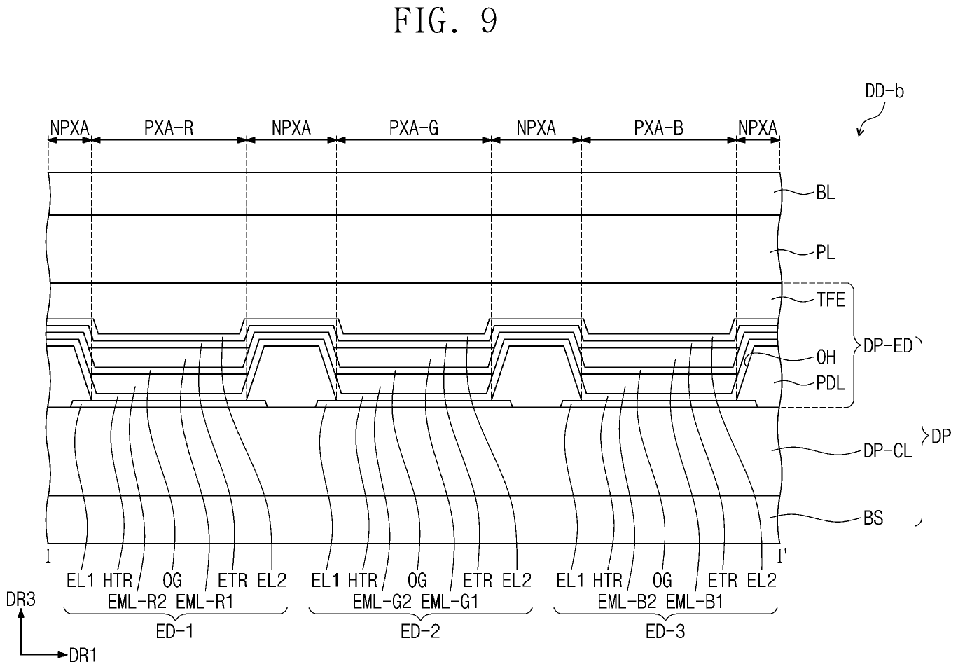

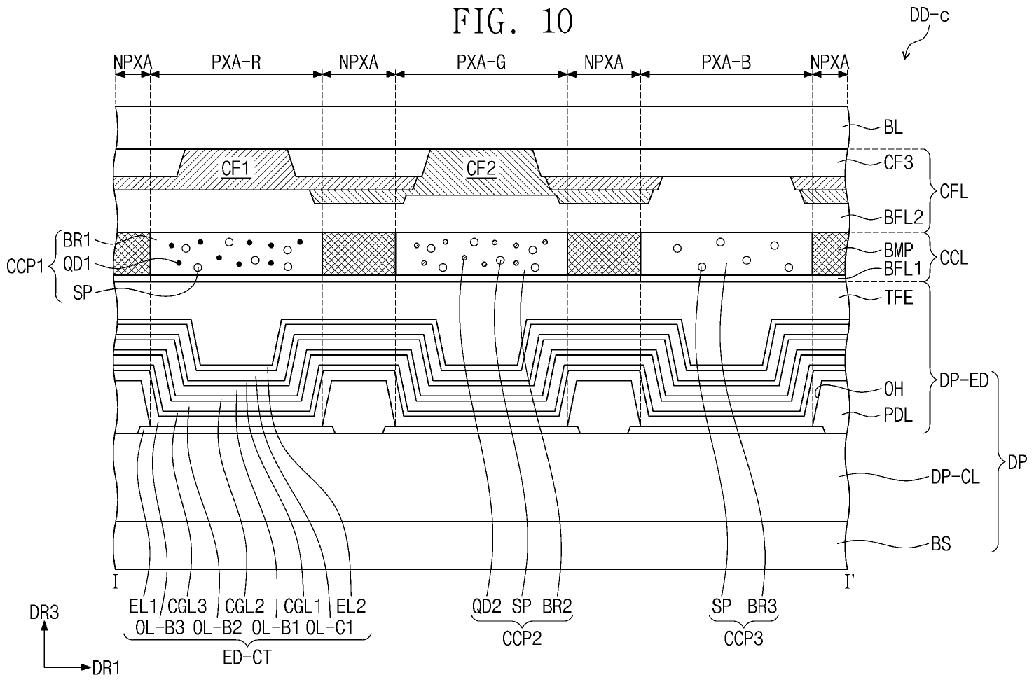

Referring to FIG. 9, the display device DD-b according to an embodiment may include light emitting elements ED-1, ED-2, and ED-3 in which two emission layers are stacked. In comparison to the display device DD illustrated in FIG. 2, the embodiment illustrated in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for all of the first to third light emitting elements ED-1, ED-2, and ED-3. However, embodiments are not limited thereto, and the emission auxiliary part OG may be provided by being patterned in the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP and may control light reflected at the display panel DP from an external light. Although not shown in the drawings, in an embodiments, the optical auxiliary layer PL may be omitted from the display device DD-b.

At least one emission layer included in the display device DD-b illustrated in FIG. 9 may include the polycyclic compound according to an embodiment as described herein. For example, in an embodiment, at least one of the first blue emission layer EML-B1 or the second blue emission layer EML-B2 may include the polycyclic compound.

In contrast to FIGS. 8 and 9, FIG. 10 illustrates a display device DD-c that is different at least in that is includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between adjacent light emitting structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

The charge generation layers CGL1, CGL2, and CGL3 which are disposed between adjacent light emitting structures OL-B1, OL-B2, OL-B3, and OL-C1 may each independently include a p-type charge generation layer and/or an n-type charge generation layer.

In the display device DD-c, at least one of the light emitting structures OL-B1, OL-B2, OL-B3, and OL-C1 may each independently include the polycyclic compound according to an embodiment as described herein. For example, in an embodiment, at least one of the first to third light emitting structures OL-B1, OL-B2, and OL-B3 may include the polycyclic compound.

The light emitting element ED according to an embodiment may include the polycyclic compound represented by Formula 1 in at least one functional layer disposed between the first electrode EL1 and the second electrode EL2, thereby exhibiting excellent luminous efficiency and improved service life characteristics. For example, the emission layer EML of the light emitting element ED may include the polycyclic compound, and the light emitting element ED may exhibit long service life characteristics.

In an embodiment, an electronic device may include a display device including light emitting elements, and a control part which controls the display device. The electronic device may be a device that is activated according to an electrical signal. The electronic device may include display devices according to various embodiments. For example, the electronic device may be not only large-sized electronic devices, such as a vehicle, a television, a monitor, or an advertising board, but the electronic device may also be a small- or a medium-sized electronic device, such as a personal computer, a laptop computer, a personal digital terminal, a display device for a vehicle, a game console, a portable electronic device, a tablet, a smart phone, or a camera.

The light emitting element ED according to an embodiment may include the polycyclic compound represented by Formula 1 in at least one functional layer disposed between the first electrode EL1 and the second electrode EL2, thereby exhibiting excellent luminous efficiency and improved service life characteristics. For example, the polycyclic compound may be included in an emission layer EML of the light emitting element ED, and the light emitting element ED may exhibit long service life characteristics.

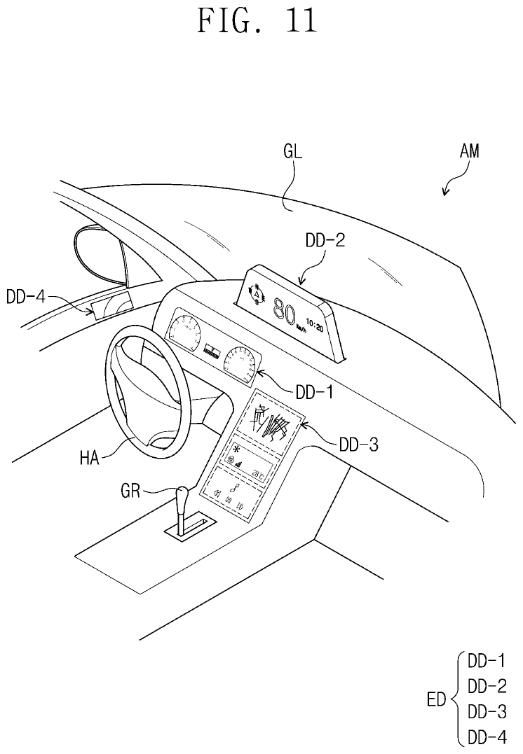

FIG. 11 is a schematic perspective view of an electronic device including a display device according to an embodiment of. FIG. 11 illustrates an example of an electronic device including display devices for a vehicle.

Referring to FIG. 11, the electronic device ED may include display devices DD-1, DD-2, DD-3, and DD-4 for a vehicle AM. FIG. 11 illustrates the first to fourth display devices DD-1, DD-2, DD-3, and DD-4 as display devices for a vehicle AM disposed inside the vehicle AM. FIG. 11 illustrates a vehicle, but this is an example, and the first to fourth display devices DD-1, DD-2, DD-3, and DD-4 may be disposed in various transportation means such as bicycles, motorcycles, trains, ships, and airplanes. At least one of the first to fourth display devices DD-1, DD-2, DD-3, and DD-4 may have a structure according to one of display devices DD, DD-a, DD-b, and DD-c, as described in reference to FIG. 1, FIG. 2, and FIGS. 7 to 10.

In an embodiment, at least one of the first to fourth display devices DD-1, DD-2, DD-3, and DD-4 may include a light emitting element ED according to an embodiment as described in reference to FIGS. 3 to 6. The first to fourth display devices DD-1, DD-2, DD-3, and DD-4 may each independently include light emitting elements ED, and the light emitting elements ED may each include a first electrode EL1, a hole transport region HTR disposed on an upper portion of the first electrode EL1, an emission layer EML disposed on an upper portion of the hole transport region HTR, an electron transport region ETR disposed on an upper portion of the emission layer EML, and a second electrode disposed on an upper portion of the electron transport region ETR. The emission layer EML may include a polycyclic compound represented by Formula 1. Accordingly, the electronic device ED may exhibit improved image quality.

Referring to FIG. 11, the vehicle AM may include a steering wheel HA and a gearshift GR for driving the vehicle AM, and a front window GL may be disposed so as to face the driver.

The first display device DD-1 may be disposed in a first region overlapping the steering wheel HA. For example, the first display device DD-1 may be a digital cluster for displaying first information of the vehicle AM. The first information may include a scale for indicating a driving speed of the vehicle AM, a scale for indicating an engine speed (for example, a tachometer showing revolutions per minute (RPM)), an image for indicating a fuel state, etc. A first scale and a second scale may each be indicated as a digital image.

The second display device DD-2 may be disposed in a second region facing the driver's seat and overlapping the front window GL. The driver's seat may be a seat in which the steering wheel HA is disposed. For example, the second display device DD-2 may be a head up display (HUD) for displaying second information of the vehicle AM. The second display device DD-2 may be optically transparent. The second information may include digital numbers for indicating a driving speed, and may further include information such as the current time.

The third display device DD-3 may be disposed in a third region adjacent to the gearshift GR. For example, the third display device DD-3 may be disposed between the driver's seat and the passenger seat and may be a center information display (CID) for a vehicle for displaying third information. The passenger seat may be a seat spaced apart from the driver's seat with the gearshift GR disposed therebetween. The third information may include information about traffic (e.g., navigation information), playing music or radio, playing video, temperatures inside the vehicle AM, etc.

The fourth display device DD-4 may be spaced apart from the steering wheel HA and the gearshift GR, and may be disposed in a fourth region adjacent to the side of the vehicle AM. For example, the fourth display device DD-4 may be a digital side-view mirror for displaying fourth information. The fourth display device DD-4 may display an image outside the vehicle AM taken by a camera module disposed outside the vehicle AM. The fourth information may include an image outside the vehicle AM.

The first to fourth information as described herein are only examples, and the first to fourth display devices DD-1, DD-2, DD-3, and DD-4 may further display information about the inside and outside of the vehicle. The first to fourth information may include different information. However, embodiments are not limited thereto, and a part of the first to fourth information may include the same information as one another.

Hereinafter, a polycyclic compound according to an embodiment and a light emitting element according to an embodiment will be described in detail with reference to the Examples and the Comparative Examples. The Examples described below are only provided as illustrations to assist in understanding the disclosure, and the scope thereof is not limited thereto.

### EXAMPLES

1. Synthesis of Polycyclic Compound

A synthesis method of the polycyclic compound according to an embodiment will be explained in detail by illustrating the synthesis methods of Compounds 6, 7, 9, 11, 30, 36, 73 and 116. In the following descriptions, the synthesis methods of the polycyclic compounds are provided as examples, but the synthesis methods of the polycyclic compound are not limited to the Examples below.

### (1) Synthesis of Compound 6

Compound 6 according to an example may be synthesized, for example, by Reaction Scheme 1:

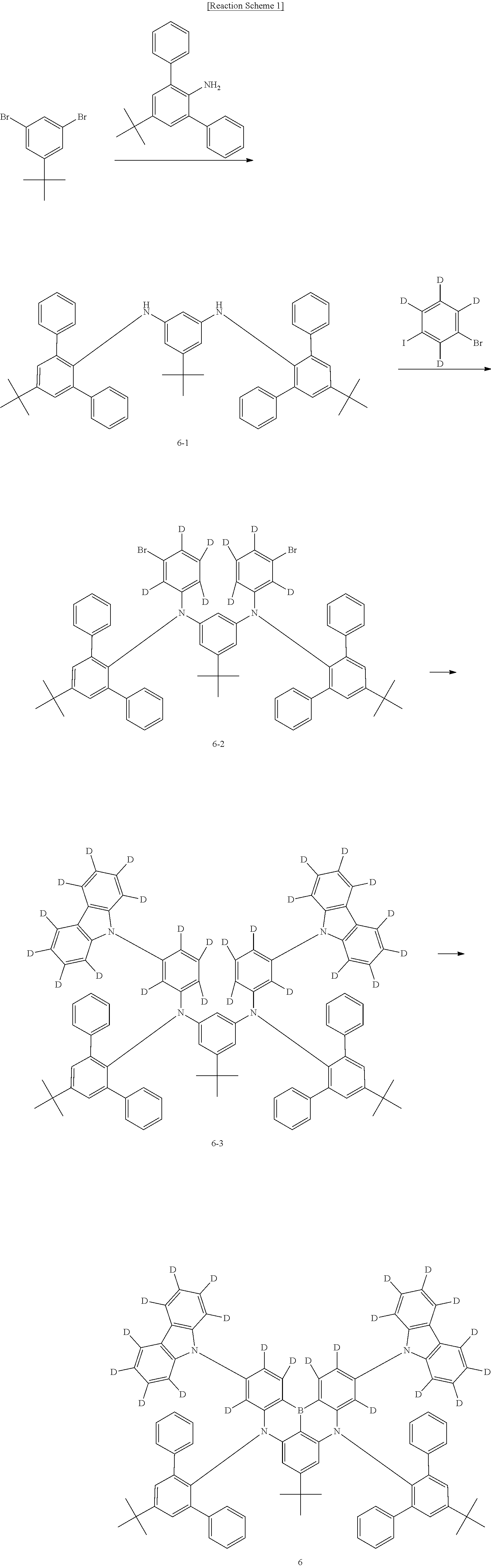

### 1) Synthesis of Intermediate 6-1

1,3-dibromo-5-(tert-butyl)benzene (1 eq), 5′-(tert-butyl)-[1,1′:3′,1″-terphenyl]-2′-amine (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride (MC) and n-hexane to obtain Intermediate 6-1. (yield: 83%)

### 2) Synthesis of Intermediate 6-2

Intermediate 6-1 (1 eq), 1-bromo-3-iodobenzene-2,4,5,6-d4 (3 eq), tris(dibenzylideneacetone)dipalladium(0) (0.15 eq), tri-tert-butylphosphine (0.3 eq), and sodium tert-butoxide (5 eq) were dissolved in o-xylene, and the resultant mixture was stirred at about 150° C. for about 60 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 6-2. (yield: 56%)

### 3) Synthesis of Intermediate 6-3

Intermediate 6-2 (1 eq), 9H-carbazole-1,2,3,4,5,6,7,8-d8 (2.4 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 6-3. (yield: 59%)

### 4) Synthesis of Compound 6

Intermediate 6-3 (1 eq) was dissolved in o-dichlorobenzene, the mixture was cooled to about 0° C., and BBr₃ (3 eq) was slowly injected thereto in a nitrogen atmosphere. After dropping was completed, the temperature was elevated to about 180° C., and the mixture was stirred for about 48 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization to obtain Compound 6. (yield: 9%)

The produced compound was identified through MS/FAB.

C₉₀H₅₃D₂₂BN₄ cal. 1245.56, found 1245.55.

### (2) Synthesis of Compound 7

Compound 7 according to an example may be synthesized, for example, by Reaction Scheme 2:

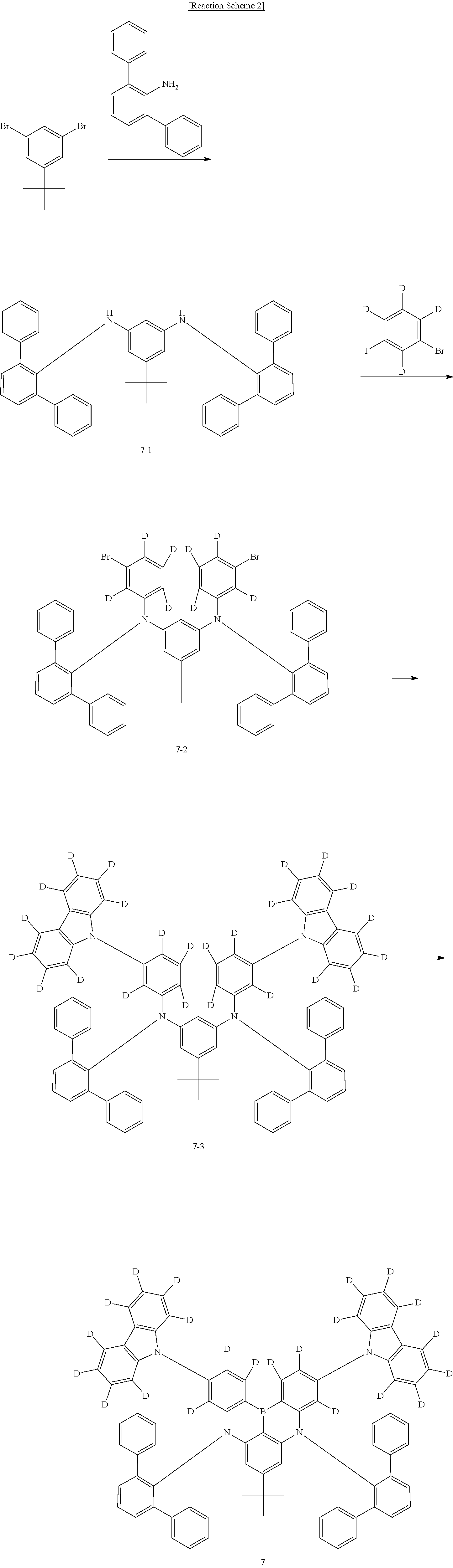

### 1) Synthesis of Intermediate 7-1

1,3-dibromo-5-(tert-butyl)benzene (1 eq), [1,1′:3′,1″-terphenyl]-2′-amine (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 7-1. (yield: 86%)

### 2) Synthesis of Intermediate 7-2

Intermediate 7-1 (1 eq), 1-bromo-3-iodobenzene-2,4,5,6-d4 (3 eq), tris(dibenzylideneacetone)dipalladium(0) (0.15 eq), tri-tert-butylphosphine (0.3 eq), and sodium tert-butoxide (5 eq) were dissolved in o-xylene, and the resultant mixture was stirred at about 150° C. for about 60 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 7-2. (yield: 52%)

### 3) Synthesis of Intermediate 7-3

Intermediate 7-2 (1 eq), 9H-carbazole-1,2,3,4,5,6,7,8-d8 (2.4 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 7-3. (yield: 66%)

### 4) Synthesis of Compound 7

Intermediate 7-3 (1 eq) was dissolved in o-dichlorobenzene, the mixture was cooled to about 0° C., and BBr₃ (3 eq) was slowly injected thereto in a nitrogen atmosphere. After dropping was completed, the temperature was elevated to about 180° C., and the mixture was stirred for about 48 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization to obtain Compound 7. (yield: 8%)

The produced compound was identified through MS/FAB.

C₈₂H₃₇D₂₂BN₄ cal. 1133.35, found 1133.34.

### (3) Synthesis of Compound 9

Compound 9 according to an example may be synthesized by, for example, Reaction Scheme 3:

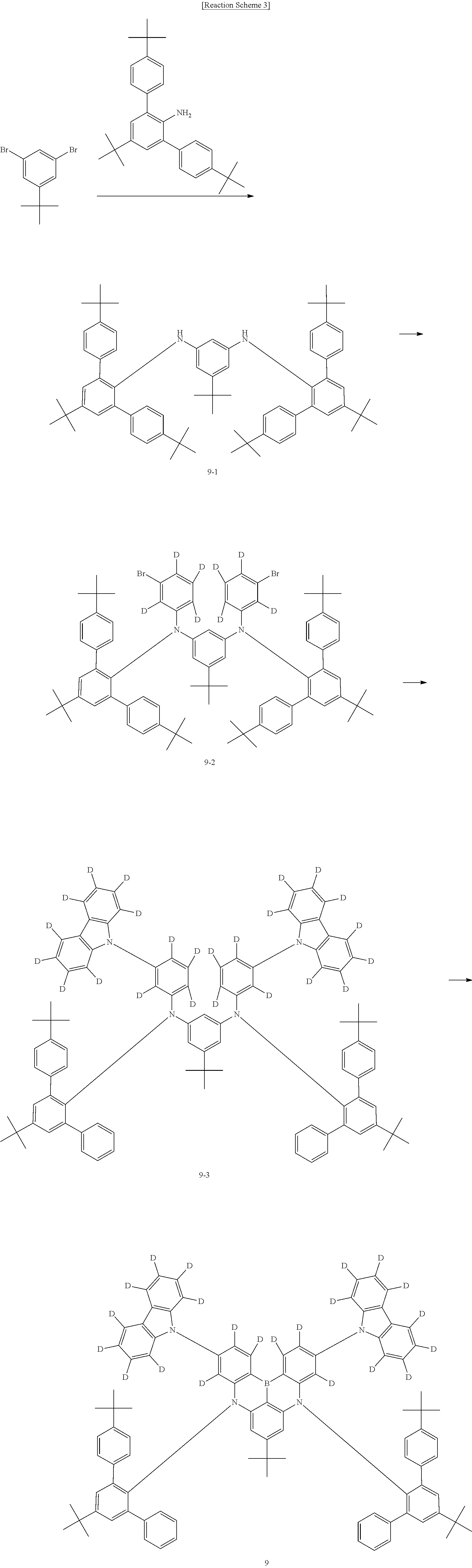

### 1) Synthesis of Intermediate 9-1

1,3-dibromo-5-(tert-butyl)benzene (1 eq), 4,4″,5′-tri-tert-butyl-[1,1′:3′,1″-terphenyl]-2′-amine (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 9-1. (yield: 75%)

### 2) Synthesis of Intermediate 9-2

Intermediate 9-1 (1 eq), 1-bromo-3-iodobenzene-2,4,5,6-d4 (3 eq), tris(dibenzylideneacetone)dipalladium(0) (0.15 eq), tri-tert-butylphosphine (0.3 eq), and sodium tert-butoxide (5 eq) were dissolved in o-xylene, and the resultant mixture was stirred at about 150° C. for about 60 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 9-2. (yield: 41%)

### 3) Synthesis of Intermediate 9-3

Intermediate 9-2 (1 eq), 9H-carbazole-1,2,3,4,5,6,7,8-d8 (2.4 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 9-3. (yield: 71%)

### 4) Synthesis of Compound 9

Intermediate 9-3 (1 eq) was dissolved in o-dichlorobenzene, the mixture was cooled to about 0° C., and BBr₃ (3 eq) was slowly injected thereto in a nitrogen atmosphere. After dropping was completed, the temperature was elevated to about 180° C., and the mixture was stirred for about 48 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization to obtain Compound 9. (yield: 5%)

The produced compound was identified through MS/FAB.

C₁₀₆H₈₅D₂₂BN₄ cal. 1469.99, found 1469.98.

### (4) Synthesis of Compound 11

Compound 11 according to an example may be synthesized, for example, by Reaction Scheme 4:

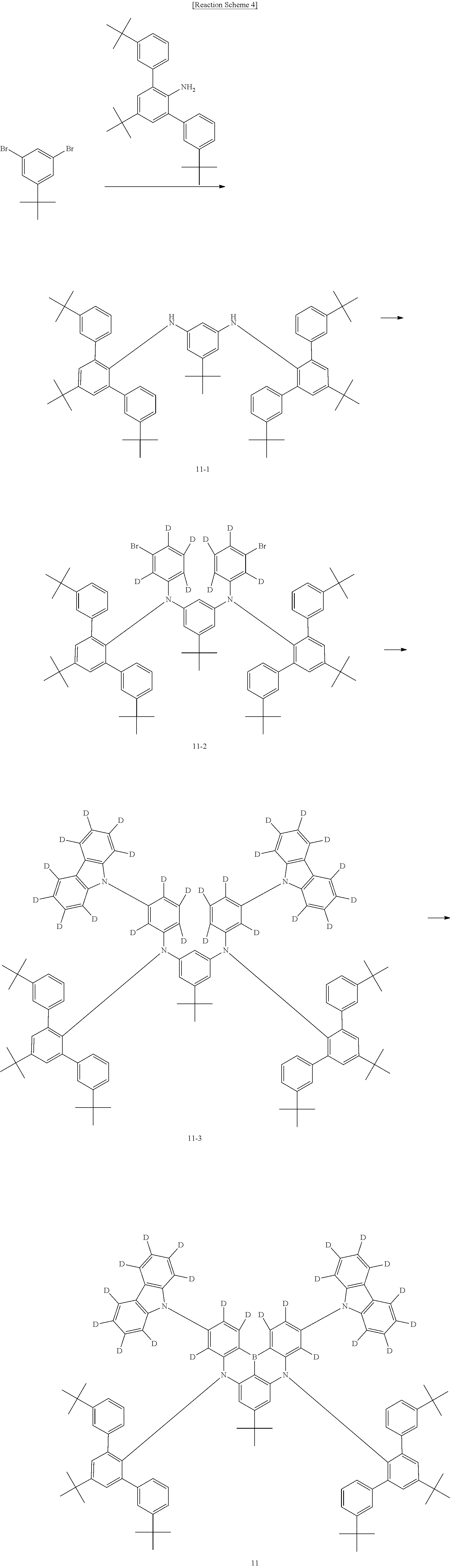

### 1) Synthesis of Intermediate 11-1

1,3-dibromo-5-(tert-butyl)benzene (1 eq), 3,3″,5′-tri-tert-butyl-[1,1′:3′,1″-terphenyl]-2′-amine (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 11-1. (yield: 59%)

### 2) Synthesis of Intermediate 11-2

Intermediate 11-1 (1 eq), 1-bromo-3-iodobenzene-2,4,5,6-d4 (3 eq), tris(dibenzylideneacetone)dipalladium(0) (0.15 eq), tri-tert-butylphosphine (0.3 eq), and sodium tert-butoxide (5 eq) were dissolved in o-xylene, and the resultant mixture was stirred at about 150° C. for about 60 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 11-2. (yield: 44%)

### 3) Synthesis of Intermediate 11-3

Intermediate 11-2 (1 eq), 9H-carbazole-1,2,3,4,5,6,7,8-d8 (2.4 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 11-3. (yield: 65%)

### 4) Synthesis of Compound 11

Intermediate 11-3 (1 eq) was dissolved in o-dichlorobenzene, the mixture was cooled to about 0° C., and BBr₃ (3 eq) was slowly injected thereto in a nitrogen atmosphere. After dropping was completed, the temperature was elevated to about 180° C., and the mixture was stirred for about 48 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization to obtain Compound 11. (yield: 4%)

The produced compound was identified through MS/FAB.

C₁₀₆H₈₅D₂₂BN₄ cal. 1469.99, found 1469.97.

### (5) Synthesis of Compound 30

Compound 30 according to an example may be synthesized, for example, by Reaction Scheme 5:

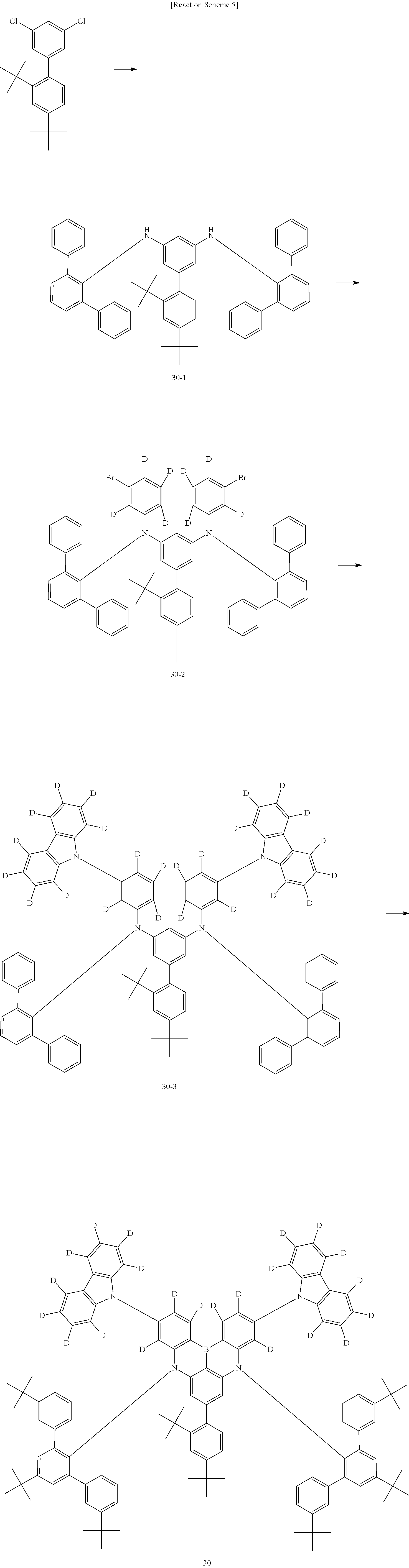

### 1) Synthesis of Intermediate 30-1

2,4-di-tert-butyl-3′,5′-dichloro-1,1′-biphenyl (1 eq), [1,1′:3′,1″-terphenyl]-2′-amine (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 30-1. (yield: 680%)

### 2) Synthesis of Intermediate 30-2

Intermediate 30-1 (1 eq), 1-bromo-3-iodobenzene-2,4,5,6-d4 (3 eq), tris(dibenzylideneacetone)dipalladium(0) (0.15 eq), tri-tert-butylphosphine (0.3 eq), and sodium tert-butoxide (5 eq) were dissolved in o-xylene, and the resultant mixture was stirred at about 150° C. for about 60 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 30-2. (yield: 580%)

### 3) Synthesis of Intermediate 30-3

Intermediate 30-2 (1 eq), 9H-carbazole-1,2,3,4,5,6,7,8-d8 (2.4 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 30-3. (yield: 72%)

### 4) Synthesis of Compound 30

Intermediate 30-3 (1 eq) was dissolved in o-dichlorobenzene, the mixture was cooled to about 0° C., and BBr₃ (3 eq) was slowly injected thereto in a nitrogen atmosphere. After dropping was completed, the temperature was elevated to about 180° C., and the mixture was stirred for about 48 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization to obtain Compound 30. (yield: 5%)

The produced compound was identified through MS/FAB.

C₉₂H₄₉D₂₂BN₄ cal. 1265.55, found 1265.54.

### (6) Synthesis of Compound 36

Compound 36 according to an example may be synthesized, for example, by Reaction Scheme 6:

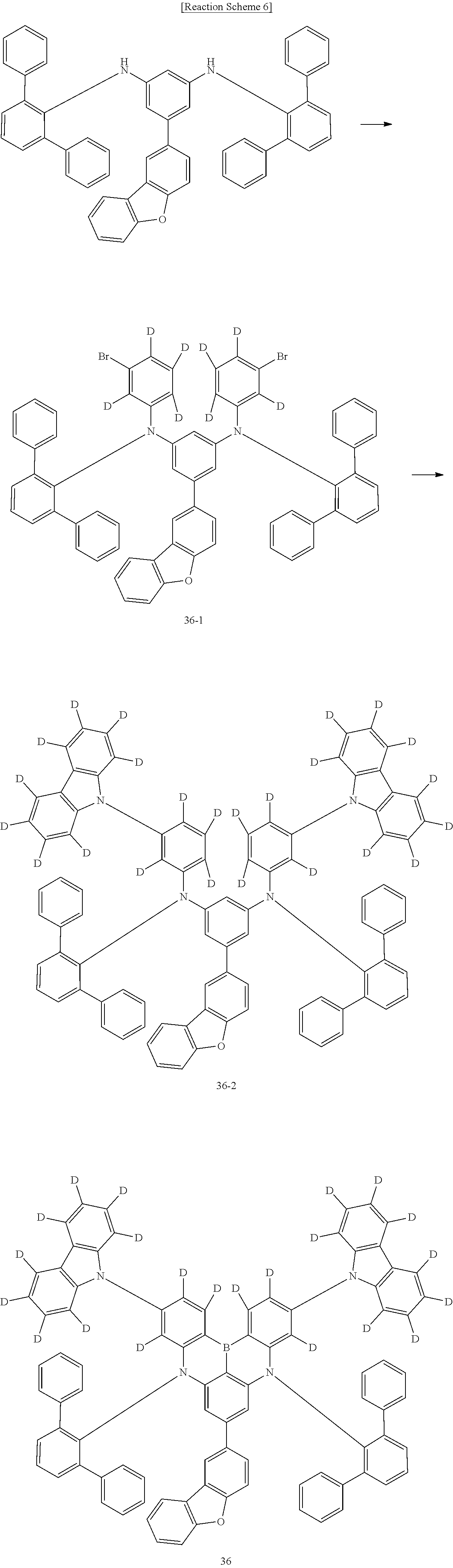

### 1) Synthesis of Intermediate 36-1

N1,N3-di([1,1′:3′,1″-terphenyl]-2′-yl)-5-(dibenzo[b,d]furan-2-yl)benzene-1,3-diamine (1 eq), 1-bromo-3-iodobenzene-2,4,5,6-d4 (3 eq), tris(dibenzylideneacetone)dipalladium(0) (0.15 eq), tri-tert-butylphosphine (0.3 eq), and sodium tert-butoxide (5 eq) were dissolved in o-xylene, and the resultant mixture was stirred at about 150° C. for about 60 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 36-1. (yield: 410%)

### 2) Synthesis of Intermediate 36-2

Intermediate 36-1 (1 eq), 9H-carbazole-1,2,3,4,5,6,7,8-d8 (2.4 eq), tris(dibenzylideneacetone)dipalladium(O) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 36-2. (yield: 70%)

### 3) Synthesis of Compound 36

Intermediate 36-2 (1 eq) was dissolved in o-dichlorobenzene, the mixture was cooled to about 0° C., and BBr₃ (3 eq) was slowly injected thereto in a nitrogen atmosphere. After dropping was completed, the temperature was elevated to about 180° C., and the mixture was stirred for about 48 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization to obtain Compound 36. (yield: 6%)

The produced compound was identified through MS/FAB.

C₉₀H₃₅D₂₂BN₄O cal. 1243.42, found 1243.41.

### (7) Synthesis of Compound 73

Compound 73 according to an example may be synthesized, for example, by Reaction Scheme 7:

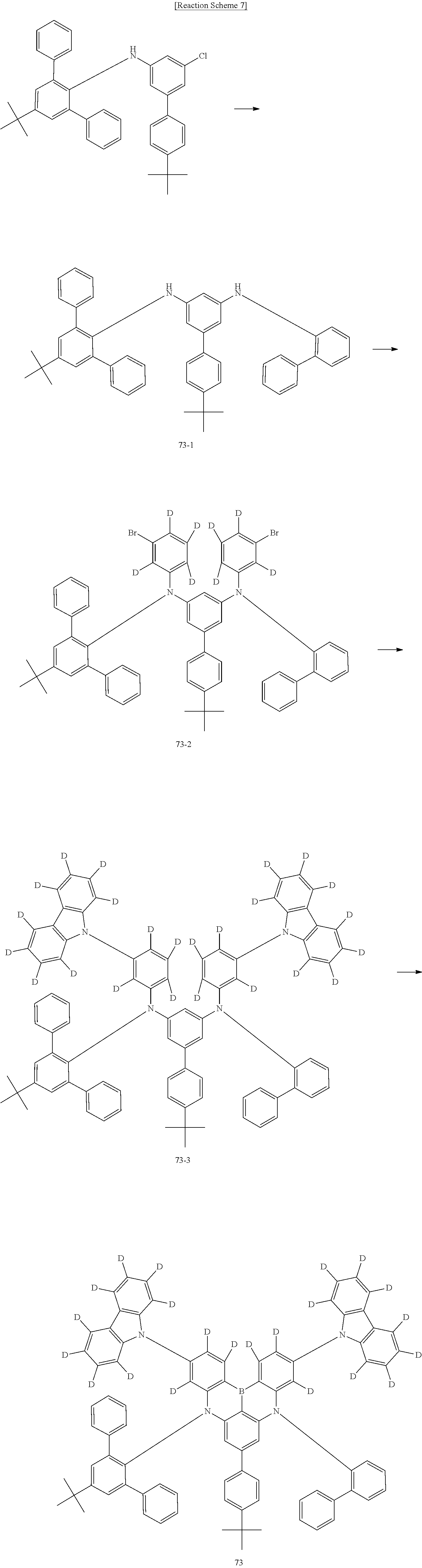

### 1) Synthesis of Intermediate 73-1

5′-(tert-butyl)-N-(4′-(tert-butyl)-5-chloro-[1,1′-biphenyl]-3-yl)-[1,1′:3′,1″-terphenyl]-2′-amine (1 eq), [1,1′-biphenyl]-2-amine (1.1 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 100° C. for about 10 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 73-1. (yield: 84%)

### 2) Synthesis of Intermediate 73-2

Intermediate 73-1 (1 eq), 1-bromo-3-iodobenzene-2,4,5,6-d4 (3 eq), tris(dibenzylideneacetone)dipalladium(0) (0.15 eq), tri-tert-butylphosphine (0.3 eq), and sodium tert-butoxide (5 eq) were dissolved in o-xylene, and the resultant mixture was stirred at about 150° C. for about 60 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 73-2. (yield: 50%)

### 3) Synthesis of Intermediate 73-3

Intermediate 73-2 (1 eq), 9H-carbazole-1,2,3,4,5,6,7,8-d8 (2.4 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 73-3. (yield: 70%)

### 4) Synthesis of Compound 73

Intermediate 73-3 (1 eq) was dissolved in o-dichlorobenzene, the mixture was cooled to about 0° C., and BBr₃ (3 eq) was slowly injected thereto in a nitrogen atmosphere. After dropping was completed, the temperature was elevated to about 180° C., and the mixture was stirred for about 48 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization to obtain Compound 73. (yield: 4%)

The produced compound was identified through MS/FAB.

C₈₆H₄₅D₂₂BN₄ cal. 1189.45, found 1189.44.

### (8) Synthesis of Compound 116

Compound 116 according to an example may be synthesized, for example, by Reaction Scheme 8:

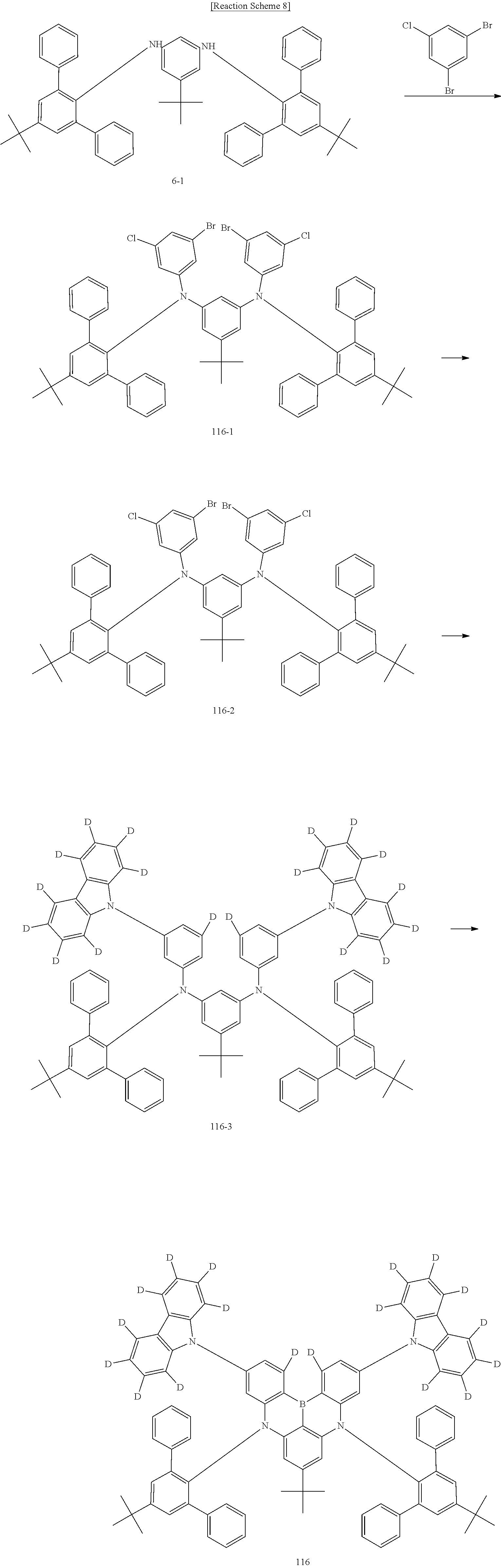

### 1) Synthesis of Intermediate 116-1

Intermediate 6-1 (1 eq), 1,3-dibromo-5-chlorobenzene (3 eq), tris(dibenzylideneacetone)dipalladium(0) (0.15 eq), tri-tert-butylphosphine (0.3 eq), and sodium tert-butoxide (5 eq) were dissolved in o-xylene, and the resultant mixture was stirred at about 150° C. for about 60 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 116-1. (yield: 34%)

### 2) Synthesis of Intermediate 116-2

Intermediate 116-1 (1 eq) was dissolved in dry THF, and cooled to about −78° C. in a nitrogen atmosphere, n-BuLi (2.4 eq) was slowly injected thereto, and the resultant mixture was stirred for about 1 hour. D₂O (4 eq) was slowly injected to the reaction mixture, and the temperature of the reaction mixture was elevated to room temperature and the mixture was stirred for another 2 hours. The mixture was purified by column chromatography to obtain Intermediate 116-2. (yield: 78%)

### 3) Synthesis of Intermediate 116-3

Intermediate 116-2 (1 eq), 9H-carbazole-1,2,3,4,5,6,7,8-d8 (2.4 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 116-3. (yield: 71%)

### 4) Synthesis of Compound 116

Intermediate 116-3 (1 eq) was dissolved in o-dichlorobenzene, the mixture was cooled to about 0° C., and BBr₃ (3 eq) was slowly injected thereto in a nitrogen atmosphere. After dropping was completed, the temperature was elevated to about 180° C., and the mixture was stirred for about 48 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization to obtain Compound 116. (yield: 4%)

The produced compound was identified through MS/FAB.

C₉₀H₅₃D₂₂BN₄ cal. 1241.54, found 1241.53.

The ¹H-NMR results of the synthesized polycyclic compounds are shown in Table 1:

TABLE 1

| Division | ¹H-NMR chemical shift (500 MHz) | MS/FAB-Cal | MS/FAB-Meas. |
|---|---|---|---|
| Compound 6 | 7.60-7.58 (4H, s), 7.01-6.95 (20H, m), 6.25 (2H, s)1.39 | 1245.562 | 1245.559 |
| | (18H, s), 1.08 (9H, s) | | |
| Compound 7 | 7.68-7.59 (6H, m), 7.02-6.97 (20H, m), 6.24 (2H, s)1.10 | 1133.346 | 1133.345 |
| | (9H, s) | | |
| Compound 9 | 7.58-7.55 (4H, s), 7.03-6.95 (16H, m), 6.35 (2H, s)1.39 | 1469.994 | 1469.988 |
| | (18H, s), 1.15 (36H, s), 1.02 (9H, s) | | |
| Compound 11 | 7.59-7.54 (4H, s), 7.02-6.96 (16H, m), 6.33 (2H, s)1.40 | 1469.994 | 1469.991 |
| | (18H, s), 1.14 (36H, s), 1.01 (9H, s) | | |
| Compound 30 | 7.68-7.50 (9H, m), 7.02-6.97 (20H, m), 6.47 (2H, s)1.36 | 1265.552 | 1265.545 |
| | (9H, s), 1.31 (9H, s) | | |
| Compound 36 | 7.89-7.83 (1H, m), 7.68-7.54 (8H, m), 7.52-7.47 (2H, | 1243.417 | 1243.408 |
| | m), 7.40-7.36 (2H, m), 7.02-6.97 (20H, m), 6.42 (2H, s) | | |
| Compound 73 | 7.61-7.48 (5H, s), 7.41-7.37 (5H, d), 7.01-6.95 (15H, | 1189.454 | 1189.448 |
| | m), 6.25 (2H, s), 1.40 (9H, s), 1.37 (9H, s) | | |
| Compound 116 | 7.61-7.58 (4H, s), 7.11-7.04 (4H, m), 7.01-6.95 (20H, | 1241.54 | 1241.53 |
| | m), 6.24 (2H, s), 1.38 (18H, s), 1.06 (9H, s) | | |

### 2. Manufacture and Evaluation of Light Emitting Elements

Light emitting element 1 including a polycyclic compound of an Example Compound or a Comparative Example Compound in the emission layer was manufactured as follows.

Compounds 6, 7, 9, 11, 30, 36, 73, and 116, which are polycyclic compounds according to the Examples, were each used as a dopant material for the emission layer to manufacture the light emitting elements of Examples 1 to 18. Comparative Example Compound C1 to Comparative Example Compound C6 were each used as a dopant material for the emission layer to manufacture the light emitting elements of Comparative Examples 1 to 12.

### (1) Manufacture of Light Emitting Elements

A glass substrate, on which an ITO electrode of about 15 Ω/cm² (about 1,200 Å) is formed as a first electrode, was cut to a size of about 50 mm×50 mm×of 0.7 mm, and cleansed by ultrasonic waves using isopropyl alcohol and pure water for about five minutes each. The glass substrate was irradiated with ultraviolet rays for about 30 minutes and exposed to ozone and cleansed, and was installed on a vacuum deposition apparatus.

On the upper portion of the first electrode, NPD was deposited to form a 300 Å-thick hole injection layer. Compound H-1-1 from Compound Group H was deposited on the upper portion of the hole injection layer to form a 200 Å-thick hole transport layer. CzSi was deposited on the upper portion of the hole transport layer to form a 100 Å-thick emission-auxiliary layer.

On the upper portion of the emission-auxiliary layer, a host mixture, a phosphorescent sensitizer, and a dopant of an Example Compound or a Comparative Example Compound were co-deposited at a weight ratio of 85:14:1 to form a 200 Å-thick emission layer. The host mixture was provided by mixing first hosts (HT1, HT2, HT3, and HT4) and second hosts (EHT85, EHT66, and EHT86) at a weight ratio of 5:5 as shown in Table 2.

The first hosts correspond to the second compound according to an embodiment, and the second hosts correspond to the third compound according to an embodiment. Compound AD-37 or Compound AD-38 from Compound Group 4 were used as a phosphorescent sensitizer as shown in Table 2. The phosphorescent sensitizer corresponds to the fourth compound according to an embodiment.

TSPO1 was deposited on the upper portion of the emission layer to form a 200 Å-thick hole blocking layer. TPBi was deposited on the upper portion of the hole blocking layer to form a 300 Å-thick electron transport layer. LiF was deposited on the upper portion of the electron transport layer to form a 10 Å-thick electron injection layer. Al was deposited on the upper portion of the electron injection layer to form a 3,000 Å-thick second electrode, thereby manufacturing a light emitting element.

### Example Compounds

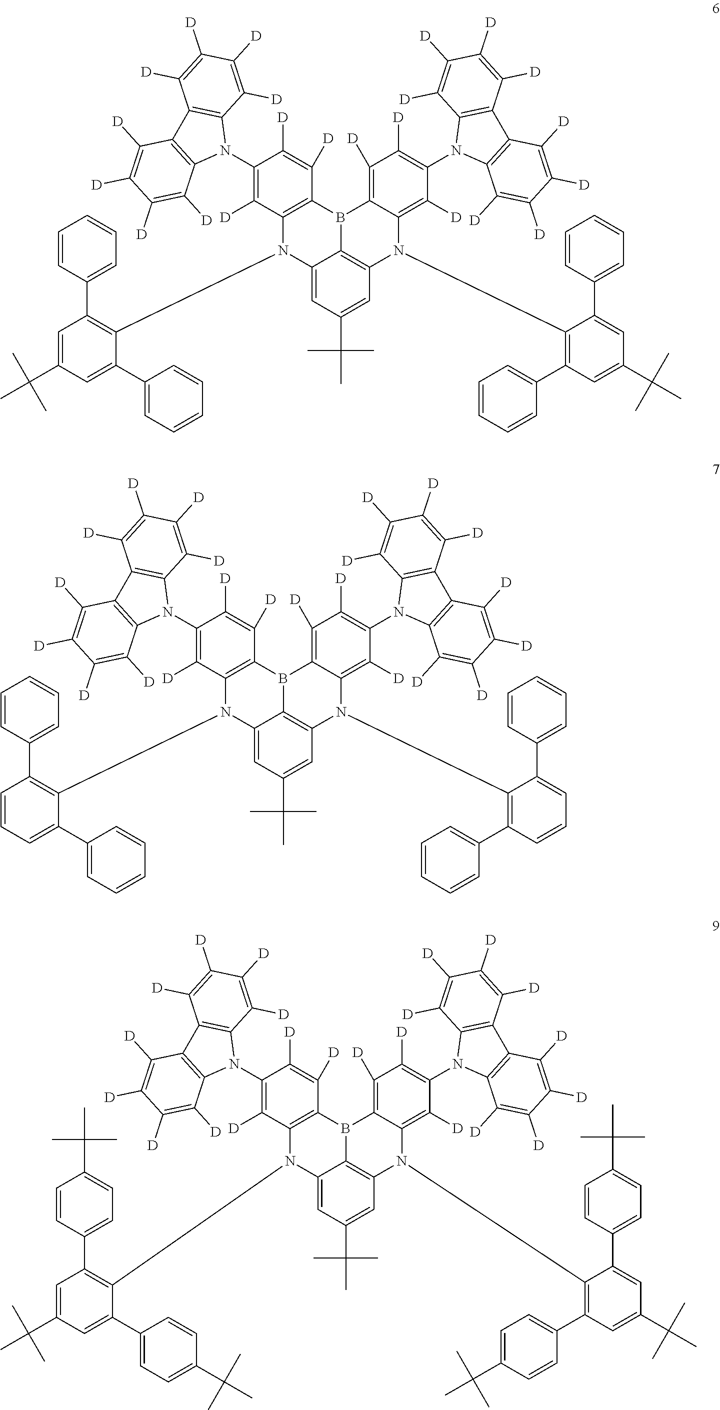

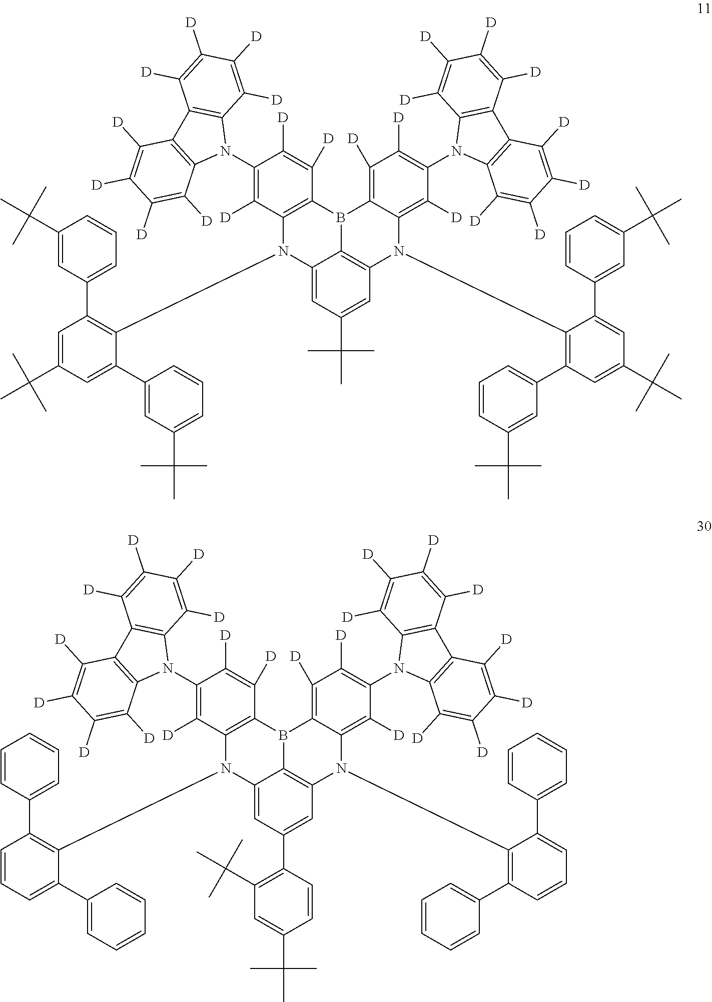

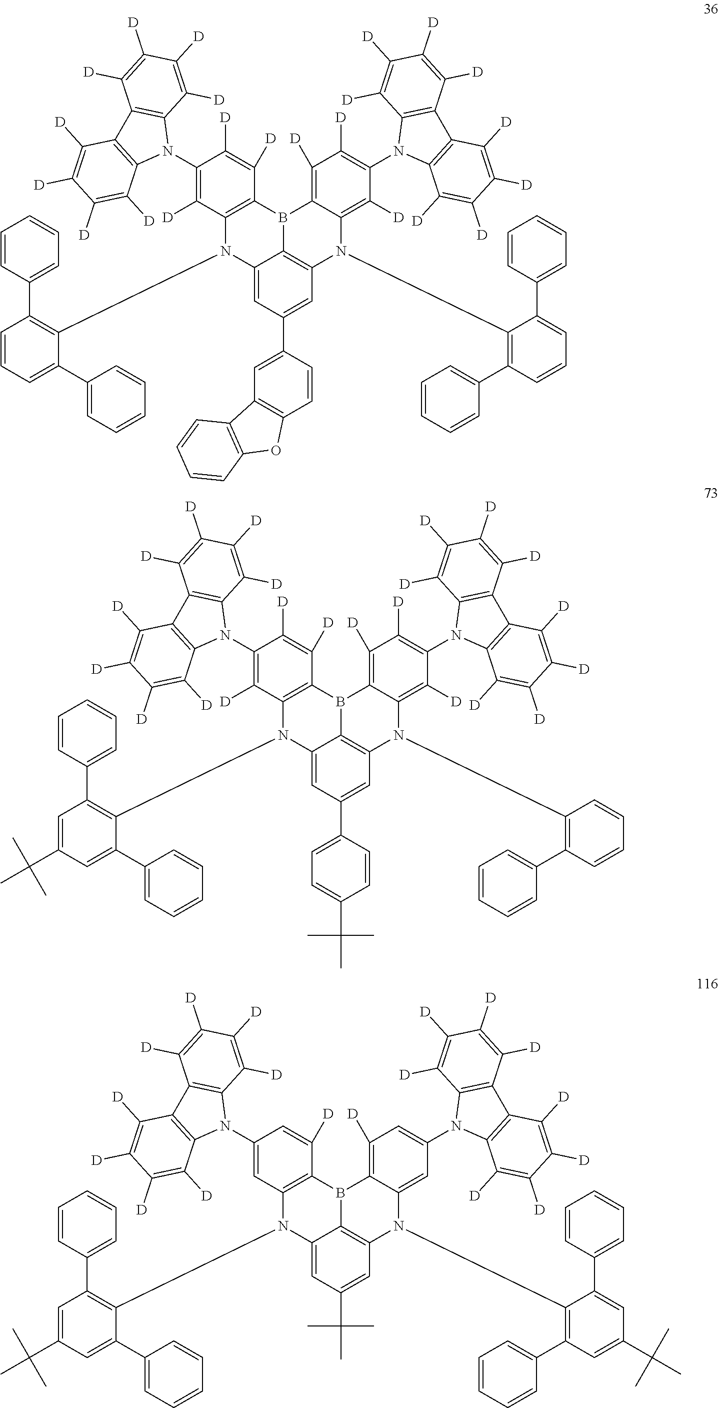

### Comparative Example Compounds

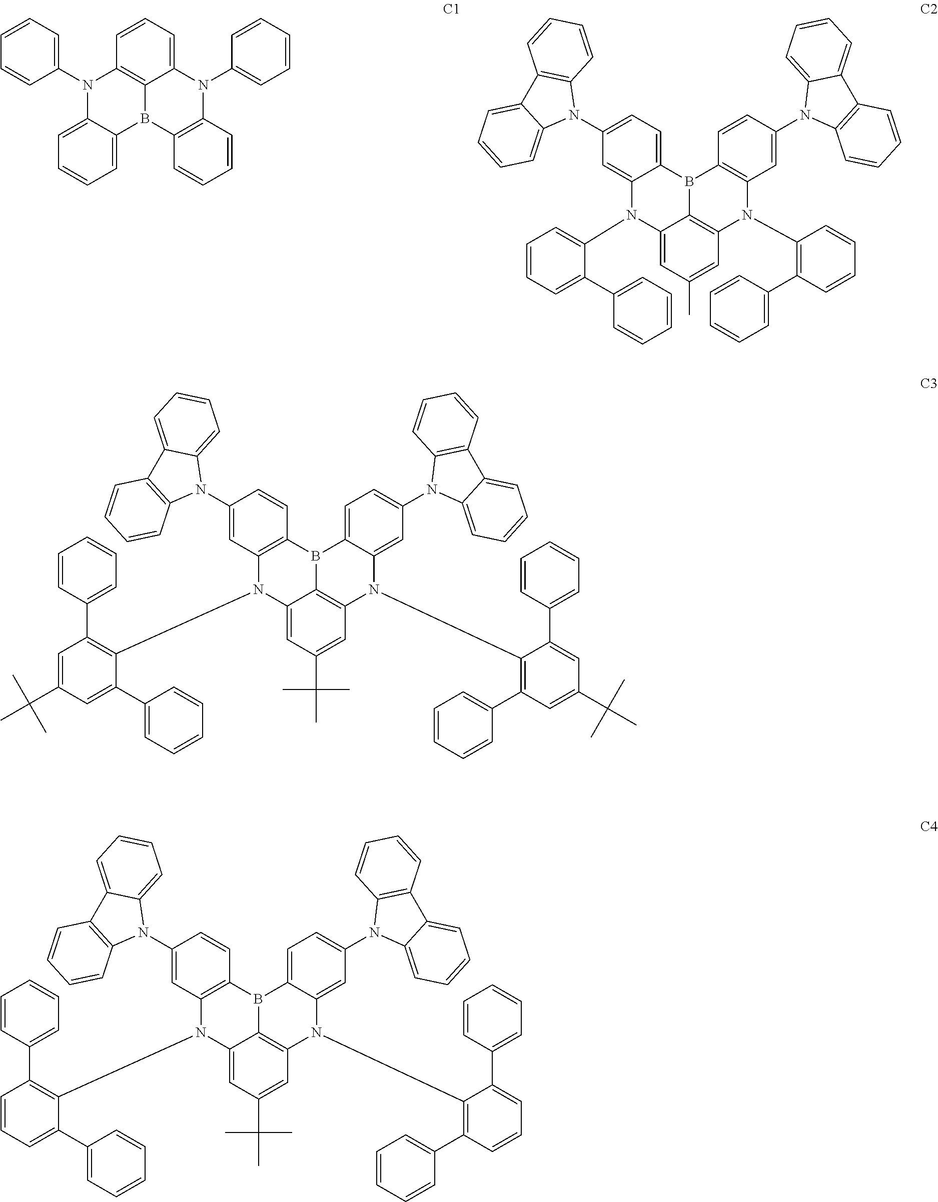 [SMILES: c1ccc(N2c3ccccc3B3c4ccccc4N(c4ccccc4)c4cccc2c43)cc1 ; Cc1cc2c3c(c1)N(c1ccccc1-c1ccccc1)c1cc(-n4c5ccccc5c5ccccc54)ccc1B3c1ccc(-n3c4ccccc4c4ccccc43)cc1N2c1ccccc1-c1ccccc1 ; CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1N2c1c(-c2ccccc2)cccc1-c1ccccc1]

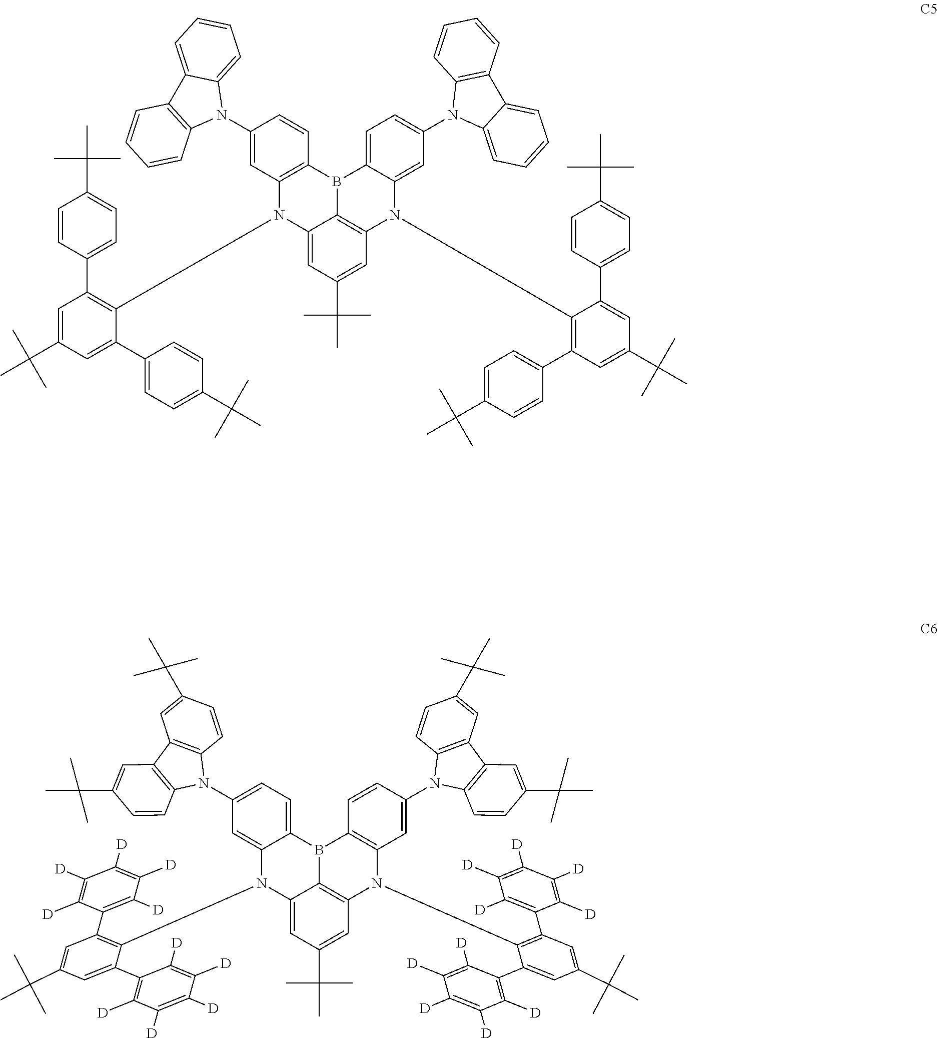

Compounds used for manufacturing the light emitting elements of the Examples and the Comparative Examples are as follows. The materials below were used to manufacture the devices by subjecting commercial products to sublimation purification.

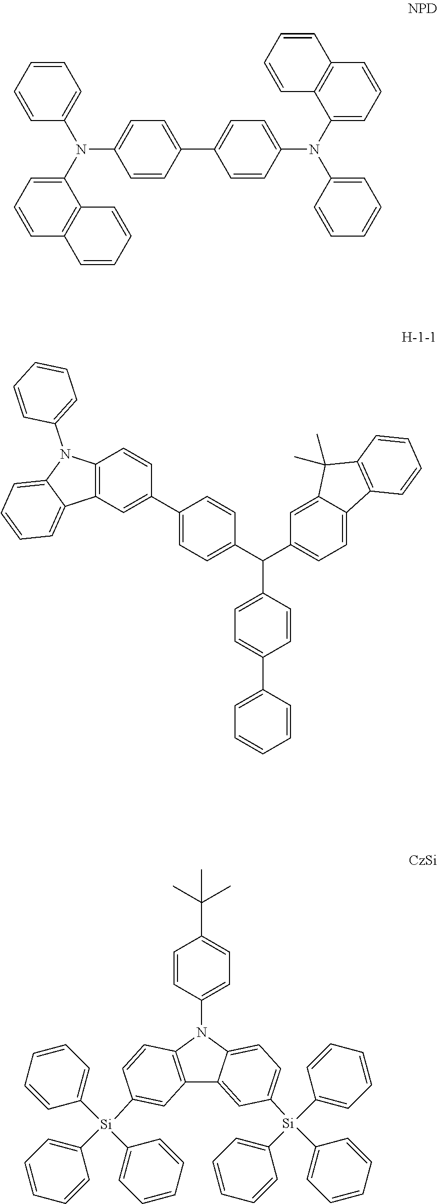 [SMILES: c1ccc(N(c2ccc(-c3ccc(N(c4ccccc4)c4cccc5ccccc45)cc3)cc2)c2cccc3ccccc23)cc1 ; CC1(C)c2ccccc2-c2ccc(C(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

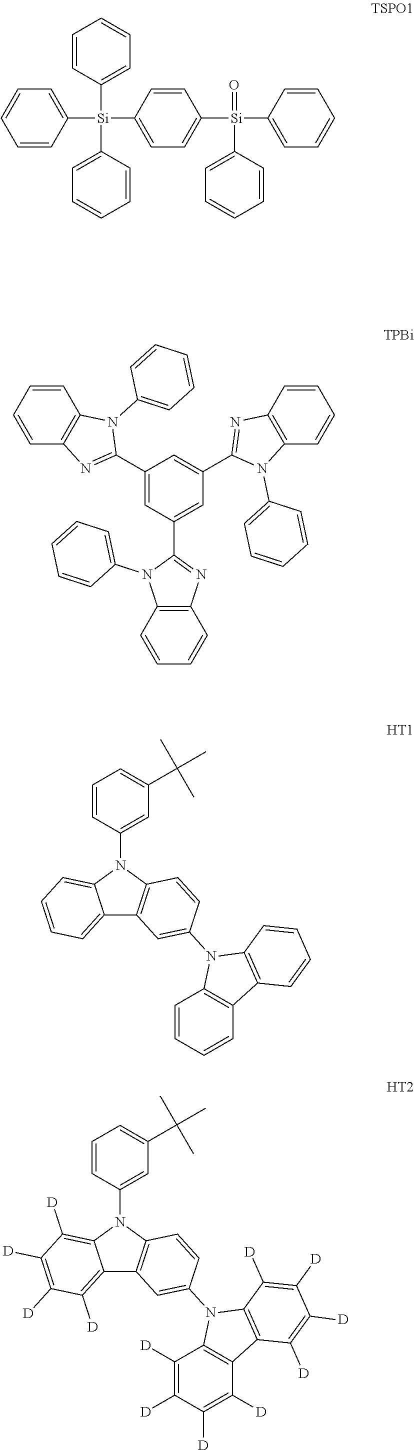

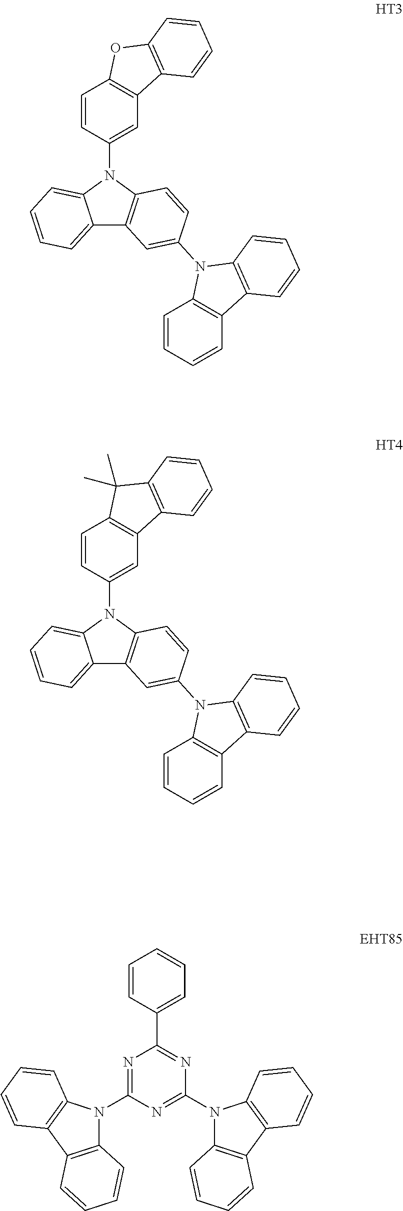 [SMILES: c1ccc2c(c1)oc1ccc(-n3c4ccccc4c4cc(-n5c6ccccc6c6ccccc65)ccc43)cc12 ; CC1(C)c2ccccc2-c2cc(-n3c4ccccc4c4cc(-n5c6ccccc6c6ccccc65)ccc43)ccc21 ; c1ccc(-c2nc(-n3c4ccccc4c4ccccc43)nc(-n3c4ccccc4c4ccccc43)n2)cc1]

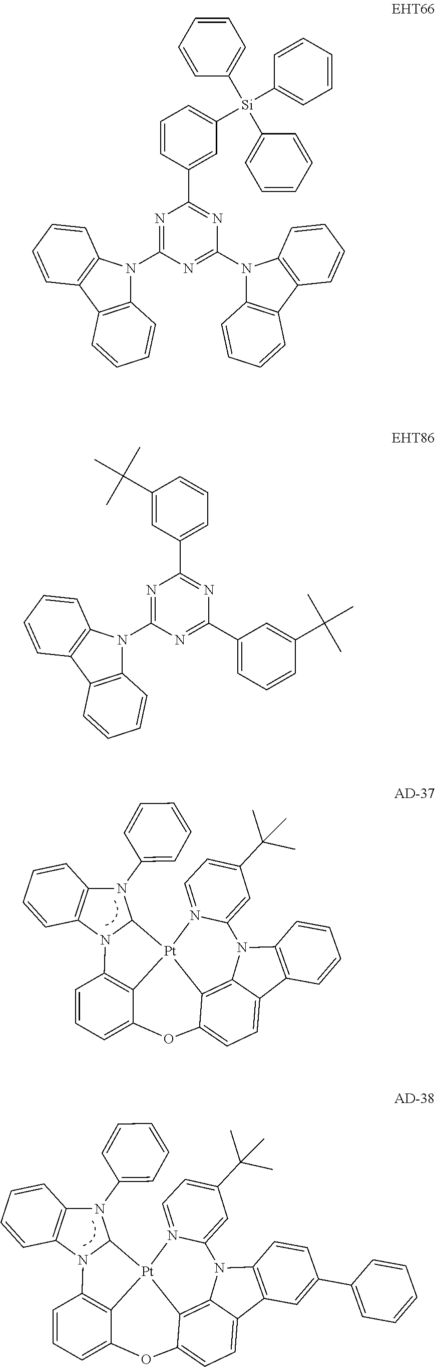

### (2) Evaluation of Light Emitting Element Characteristics

The characteristics of the light emitting elements of Examples 1 to 18 and Comparative Examples 1 to 12 were evaluated, and the results are listed in Table 2.

In Table 2, driving voltages (V), luminous efficiencies (Cd/A), and emission colors of the light emitting elements was measured at a brightness of 1,000 cd/m² by using Keithley MU 236 and a luminance meter PR650. For the element service life, the time taken to reach 9500 brightness relative to an initial brightness was measured as a service life (T₉₅).

TABLE 2

| | Second | | | | | | Service |
|---|---|---|---|---|---|---|---|
| | compound:third | | | Driving | | Luminous | life |
| | compound | Fourth | First | voltage | Efficiency | wavelength | ratio |
| | (HT:ET = 5:5) | compound | compound | (V) | (cd/A) | (nm) | (T₉₅) |
| Example 1 | HT2/EHT66 | AD-38 | 6 | 4.3 | 27.9 | 460 | 7.9 |
| Example 2 | HT2/EHT66 | AD-38 | 7 | 4.4 | 27.7 | 459 | 7.7 |
| Example 3 | HT2/EHT66 | AD-38 | 9 | 4.3 | 26.9 | 461 | 7.5 |
| Example 4 | HT2/EHT66 | AD-38 | 11 | 4.4 | 27.1 | 461 | 7.6 |
| Example 5 | HT2/EHT66 | AD-38 | 30 | 4.5 | 26.5 | 460 | 6.9 |
| Example 6 | HT2/EHT66 | AD-38 | 36 | 4.4 | 27.2 | 460 | 7.4 |
| Example 7 | HT2/EHT66 | AD-38 | 73 | 4.5 | 25.8 | 462 | 6.4 |
| Example 8 | HT3/EHT86 | AD-37 | 6 | 4.4 | 26.8 | 459 | 7.8 |
| Example 9 | HT3/EHT86 | AD-37 | 7 | 4.3 | 26.4 | 460 | 7.5 |
| Example 10 | HT3/EHT86 | AD-37 | 30 | 4.5 | 27.2 | 460 | 7.1 |
| Example 11 | HT3/EHT86 | AD-37 | 36 | 4.5 | 25.9 | 459 | 7.0 |
| Example 12 | HT1/EHT86 | AD-37 | 9 | 4.6 | 26.8 | 462 | 6.9 |
| Example 13 | HT1/EHT86 | AD-37 | 11 | 4.4 | 26.4 | 460 | 6.6 |
| Example 14 | HT1/EHT86 | AD-37 | 73 | 4.3 | 25.8 | 462 | 6.0 |
| Example 15 | HT4/EHT85 | AD-38 | 6 | 4.5 | 25.7 | 461 | 6.9 |
| Example 16 | HT4/EHT85 | AD-38 | 7 | 4.5 | 25.3 | 461 | 6.6 |
| Example 17 | HT4/EHT85 | AD-38 | 36 | 4.5 | 25.4 | 462 | 6.4 |
| Example 18 | HT4/EHT85 | AD-38 | 116 | 4.4 | 26.6 | 463 | 7.2 |
| Comparative | HT2/EHT66 | x | C1 | 5.8 | 12.9 | 459 | — |
| Example 1 | | | | | | | |
| Comparative | HT2/EHT66 | AD-38 | C1 | 4.7 | 15.2 | 462 | 1.0 |
| Example 2 | | | | | | | |
| Comparative | HT2/EHT66 | AD-38 | C2 | 4.7 | 21.5 | 464 | 2.2 |
| Example 3 | | | | | | | |
| Comparative | HT2/EHT66 | AD-38 | C3 | 4.6 | 24.4 | 462 | 4.7 |
| Example 4 | | | | | | | |
| Comparative | HT2/EHT66 | AD-38 | C4 | 4.6 | 23.4 | 462 | 4.1 |
| Example 5 | | | | | | | |
| Comparative | HT2/EHT66 | AD-38 | C5 | 4.7 | 23.7 | 461 | 4.5 |
| Example 6 | | | | | | | |
| Comparative | HT2/EHT66 | AD-38 | C6 | 4.6 | 25.1 | 459 | 5.5 |
| Example 7 | | | | | | | |
| Comparative | HT3/EHT86 | AD-37 | C2 | 4.6 | 20.8 | 464 | 2.6 |
| Example 8 | | | | | | | |
| Comparative | HT3/EHT86 | AD-37 | C3 | 4.7 | 23.5 | 461 | 4.3 |
| Example 9 | | | | | | | |
| Comparative | HT3/EHT86 | AD-37 | C4 | 4.7 | 24.3 | 461 | 4.7 |
| Example 10 | | | | | | | |
| Comparative | HT3/EHT86 | AD-37 | C5 | 4.6 | 22.9 | 462 | 4.9 |
| Example 11 | | | | | | | |
| Comparative | HT3/EHT86 | AD-37 | C6 | 4.5 | 25.7 | 459 | 5.3 |
| Example 12 | | | | | | | |

Referring to Table 2, it may be seen that the light emitting elements including the polycyclic compound of Examples 1 to 18 exhibit long service life characteristics as compared with the light emitting elements of Comparative Examples 1 to 12. It may be seen that the light emitting elements of Examples 1 to 18 exhibit excellent luminous efficiency.

The light emitting elements of Examples 1 to 18 may exhibit improved element service life because the polycyclic compound of an embodiment included in the emission layer includes C-D (carbon-deuterium) bond in the first aromatic ring and the second aromatic ring, hydrogen atom dissociation is weaker than that of C—H (carbon-hydrogen) bond, and thus the deterioration of material is slowed down. The polycyclic compound according to an embodiment has carbazole-d8 groups introduced at a para-position to the boron atom of the fused ring core, which may protect carbon 3 and carbon 6 of a carbazole group which is chemically active, and thus may contribute to exhibiting improved element service life.

In comparison, the polycyclic compound including C—H (carbon-hydrogen) bond in the first aromatic ring and the second aromatic ring is applied, and thus the hydrogen dissociation effect thereof is stronger than that of the polycyclic compound of an embodiment, and thus the light emitting elements of Comparative Examples 1 to 18 exhibits degraded service life characteristics as compared with the light emitting elements of Examples. It is thought that Comparative Example Compound C6 applied to Comparative Examples 7 and 12 has a structure in which a carbazole in which an alkyl group such as t-butyl is bonded in the molecule is introduced, there occurs a side effect in that due to the characteristics of the alkyl group which does not have an orbital, hopping deteriorates and thus a hole trap increases by a dopant containing a boron atom, and thus Comparative Examples 7 and 12 exhibit degraded service life characteristics as compared with Examples.

The light emitting element according to an embodiment may exhibit improved element characteristics with a long service life.

The polycyclic compound according to an embodiment may be included in the emission layer of the light emitting element, thereby contributing to improving luminous efficiency and service life of the light emitting element.

The polycyclic compound according to an embodiment may include a boron-containing fused ring core and deuterium atoms and a substituent containing deuterium atoms, thereby contributing to the improvement of a service life of the light emitting element.

The electronic device according to an embodiment may include the light emitting element which exhibits the above-described effects, thereby exhibiting characteristics that the quality of images is improved.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

1. A light emitting element comprising:
a first electrode;
a second electrode disposed on the first electrode; and
an emission layer disposed between the first electrode and the second electrode, wherein
the emission layer comprises:
a first compound represented by Formula 1; and
at least one of a second compound represented by Formula HT, a third compound represented by Formula ET, or a fourth compound represented by Formula M-b: 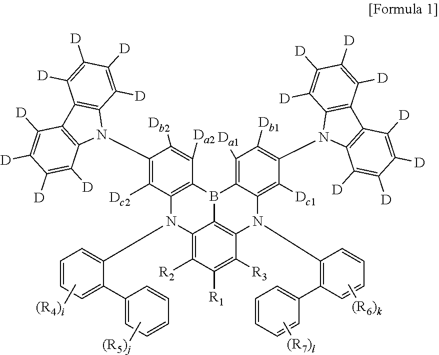
wherein in Formula 1,
D, Dₐ₁, and Dₐ₂ are each a deuterium atom,
D_{b1}, D_{b2}, D_{c1}, and D_{c2} are each independently a hydrogen atom or a deuterium atom,
R₁ to R₃ are each independently a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
R₄ to R₇ are each independently a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
i and k are each independently an integer from 0 to 4, and
j and l are each independently an integer from 0 to 5; 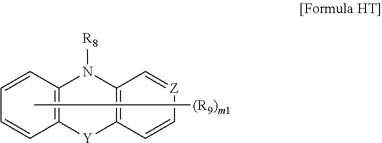
wherein in Formula HT,
m1 is an integer from 0 to 8,
R₈ and R₉ are each independently a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
Y is a direct linkage, C(R_{y1})(R_{y2}), or Si(R_{y3})(R_{y4}),
Z is C(R_{z}) or N,
R_{y1} to R_{y4} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and
R_{z} is a hydrogen atom or a deuterium atom; 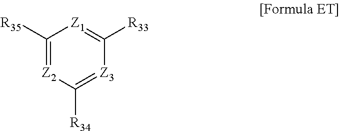
wherein in Formula ET,
Z₁ to Z₃ are each independently N or C(R₃₆),
at least one of Z₁ to Z₃ is each N, and
R₃₃ to R₃₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring: 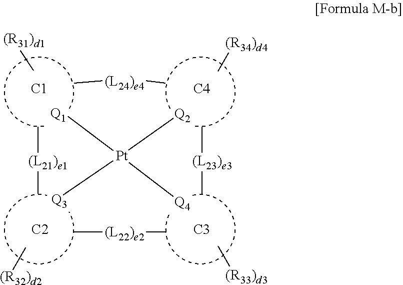
wherein in Formula M-b,
Q₁ to Q₄ are each independently C or N,
C1 to C4 are each independently a substituted or unsubstituted hydrocarbon ring group having 5 to 30 ring-forming carbon atoms or a substituted or unsubstituted heterocyclic group having 2 to 30 ring-forming carbon atoms,
e1 to e4 are each independently 0 or 1,
L₂₁ to L₂₄ are each independently a direct linkage, 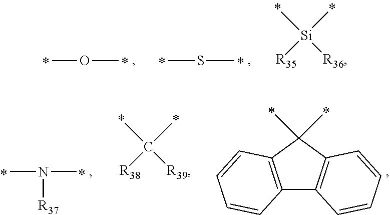
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer from 0 to 4, and
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

2. The light emitting element of claim 1, wherein the first compound represented by Formula 1 is represented by Formula 1-1: 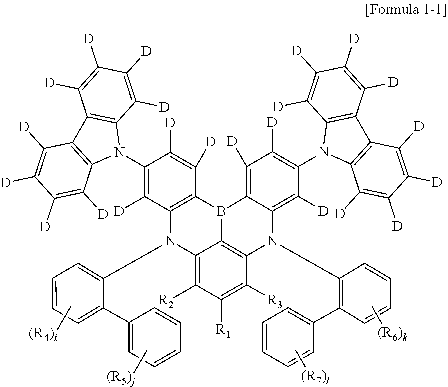
wherein in Formula 1-1,
D, R₁ to R₇, and i to 1 are the same as defined in Formula 1.

3. The light emitting element of claim 1, wherein the first compound represented by Formula 1 is represented by Formula 2: 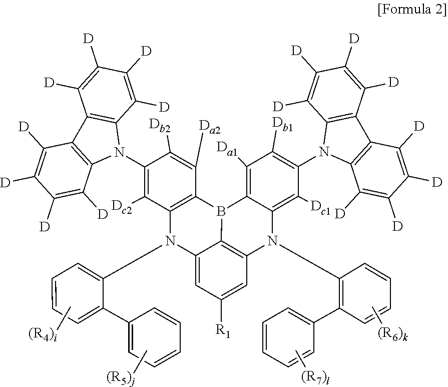
wherein in Formula 2,
D, Dₐ₁, Dₐ₂, D_{b1}, D_{b2}, D_{c1}, D_{c2}, R₁, R₄ to R₇, and i to 1 are the same as defined in Formula 1.

4. The light emitting element of claim 1, wherein the first compound represented by Formula 1 is represented by Formula 3: 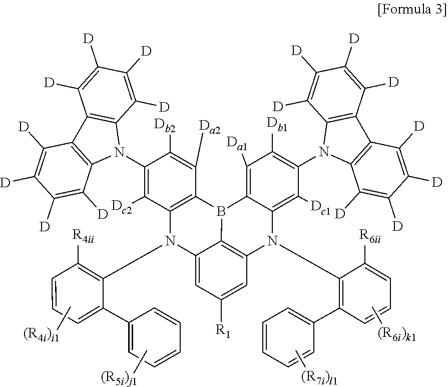
wherein in Formula 3,
R₄ᵢ, R₅ᵢ, R₆ᵢ, and R₇ᵢ are each independently a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
R₄ᵢᵢ and R₆ᵢᵢ are each independently a hydrogen atom, a deuterium atom, or a substituted or unsubstituted aryl group having 6 to 15 ring-forming carbon atoms,
i1 and k1 are each independently an integer from 0 to 3,
j1 and l1 are each independently an integer from 0 to 5, and
R₁, D, Dₐ₁, Dₐ₂, D_{b1}, D_{b2}, D_{c1}, and D_{c2} are the same as defined in Formula 1.

5. The light emitting element of claim 1, wherein the first compound represented by Formula 1 is represented by Formula 4-1 or Formula 4-2: 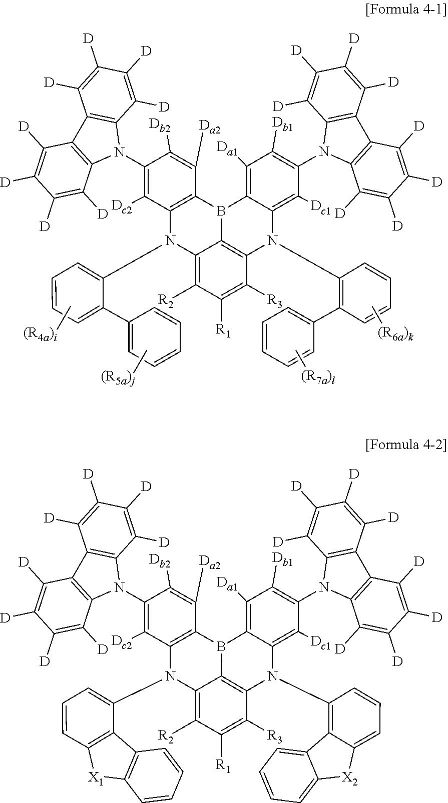
wherein in Formula 4-1,
R₄ₐ to R₇ₐ are each independently a hydrogen atom, a deuterium atom, a substituted or unsubstituted alkyl group having 1 to 10 carbon atoms, a substituted or unsubstituted aryl group having 6 to 15 ring-forming carbon atoms, or a substituted or unsubstituted heteroaryl group having 2 to 15 ring-forming carbon atoms,
wherein in Formula 4-2,
X₁ and X₂ are each independently O, S, C(Rₐ)(R_{b}), or N(R_{c}), and
Rₐ to R_{c} are each independently a hydrogen atom, a deuterium atom, or a substituted or unsubstituted aryl group having 6 to 15 ring-forming carbon atoms, or are bonded to an adjacent group to form a ring, and
wherein in Formula 4-1 and Formula 4-2,
D, Dₐ₁, Dₐ₂, D_{b1}, D_{b2}, D_{c1}, D_{c2}, R₁ to R₃, and i to 1 are the same as defined in Formula 1.

6. The light emitting element of claim 5, wherein the first compound represented by Formula 4-1 is represented by Formula 4-1a: 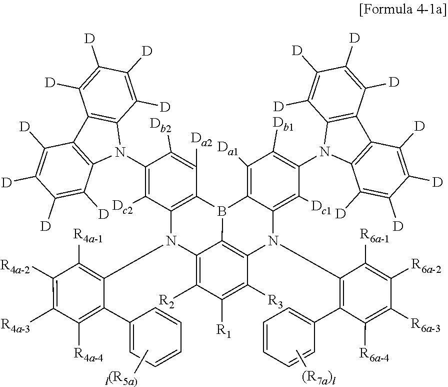
wherein in Formula 4-1a,
R₄ₐ₋₁ and R₆ₐ₋₁ are each independently a hydrogen atom, a deuterium atom, or a substituted or unsubstituted phenyl group,
R₄ₐ₋₂ to R₄ₐ₋₄ and R₆ₐ₋₂ to R₆ₐ₋₄ are each independently a hydrogen atom, a deuterium atom, a substituted or unsubstituted alkyl group having 1 to 10 carbon atoms, or a substituted or unsubstituted aryl group having 6 to 15 ring-forming carbon atoms,
D, Dₐ₁, Dₐ₂, D_{b1}, D_{b2}, D_{c1}, D_{c2}, R₁ to R₃, j, and 1 are the same as defined in Formula 1, and R₅ₐ and R₇ₐ are the same as defined in Formula 4-1.

7. The light emitting element of claim 1, wherein R₁ to R₃ are each independently a hydrogen atom, a deuterium atom, a substituted or unsubstituted t-butyl group, a substituted or unsubstituted phenyl group, a substituted or unsubstituted dibenzofuran group, or a substituted or unsubstituted carbazole group.

8. The light emitting element of claim 1, wherein R₄ to R₇ are each independently a hydrogen atom, a deuterium atom, a substituted or unsubstituted t-butyl group, or a substituted or unsubstituted phenyl group, or are bonded to an adjacent group to form a ring.

9. The light emitting element of claim 1, wherein the emission layer comprises the first compound, the second compound, and the third compound.

10. The light emitting element of claim 1, wherein the emission layer comprises the first compound, the second compound, the third compound, and the fourth compound.

11. The light emitting element of claim 1, wherein the first compound represented by Formula 1 includes at least one compound selected from Compound Group 1: 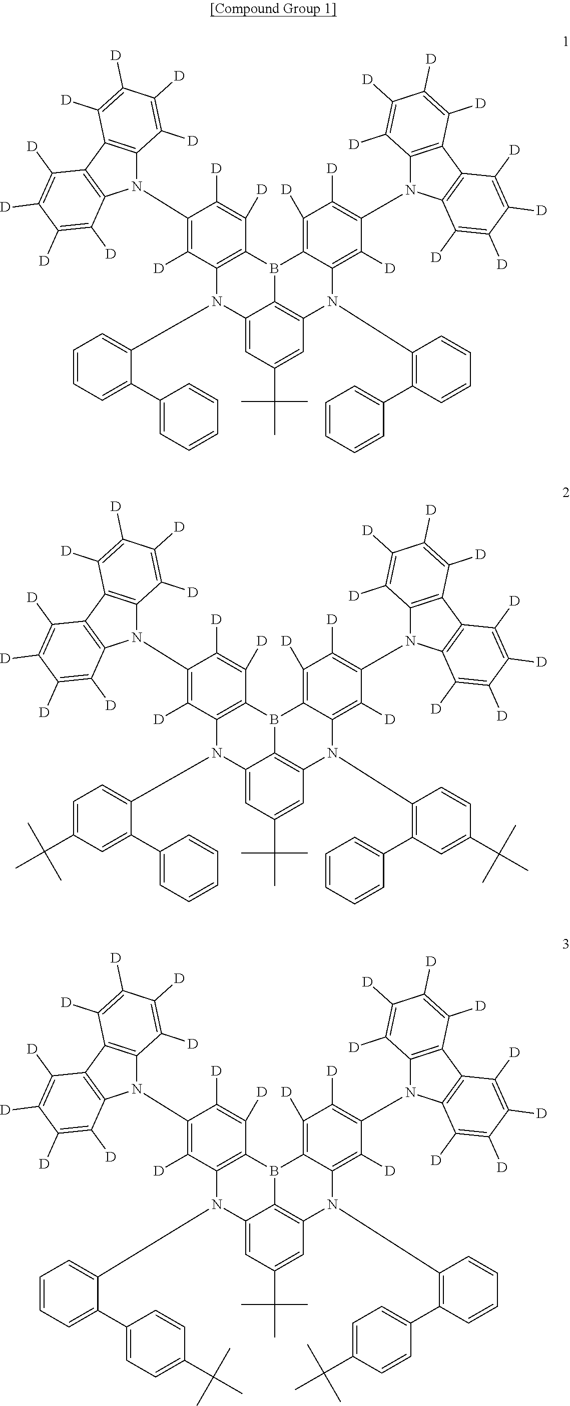 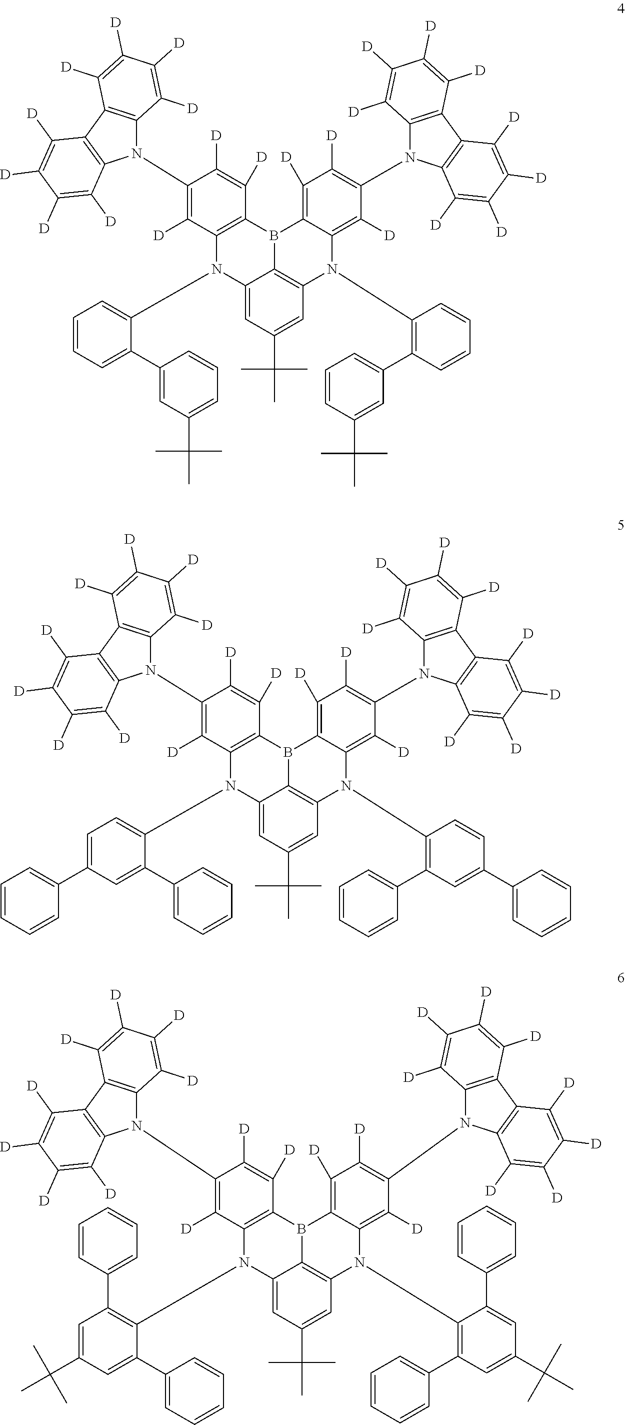 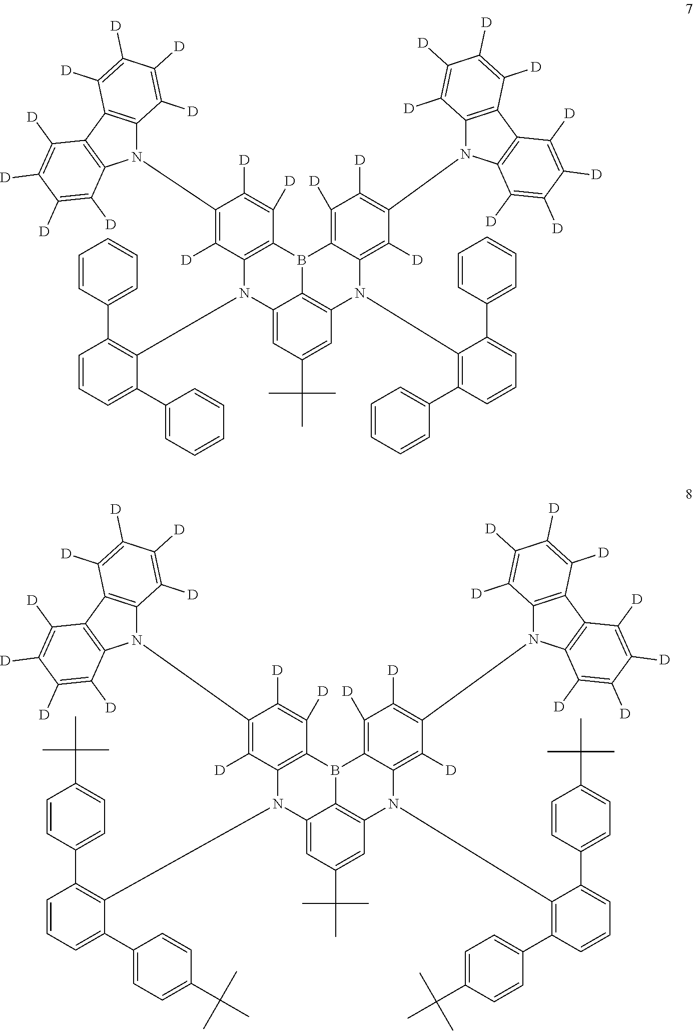 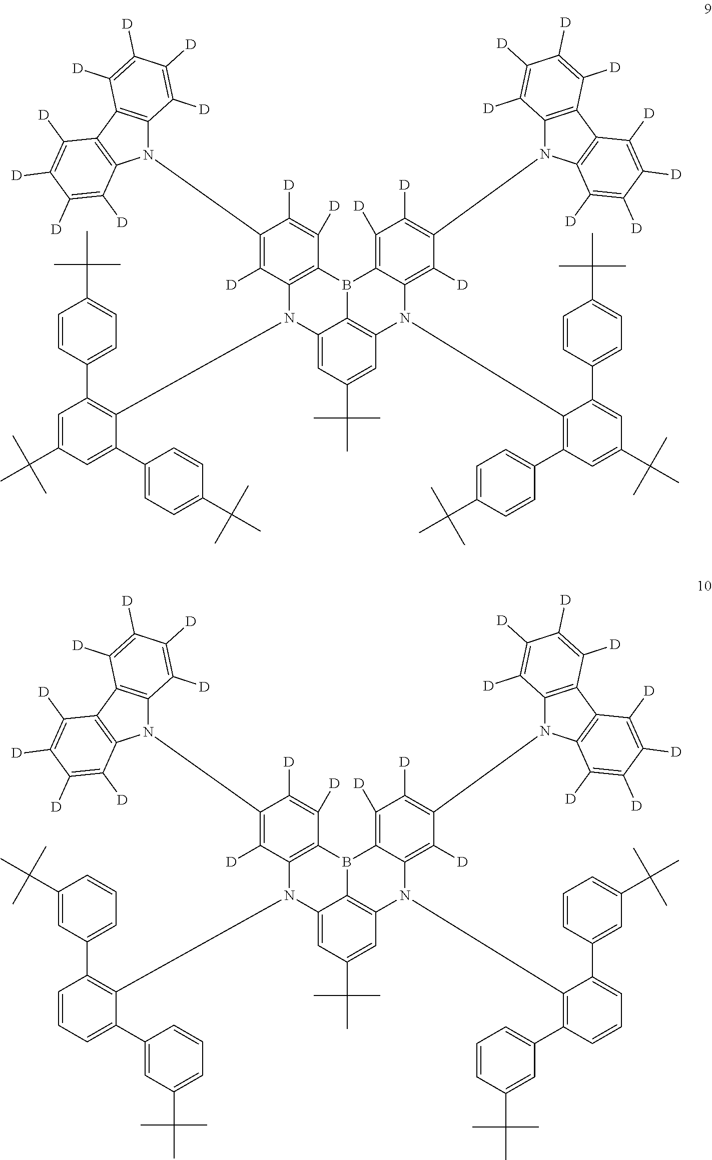 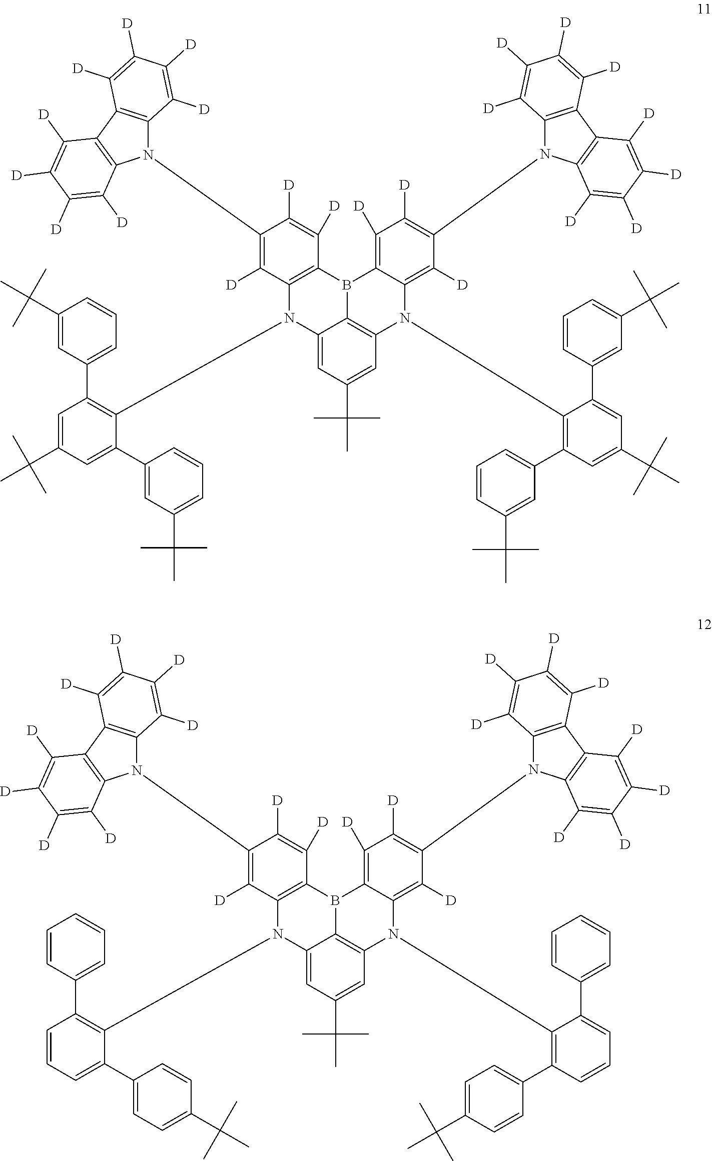 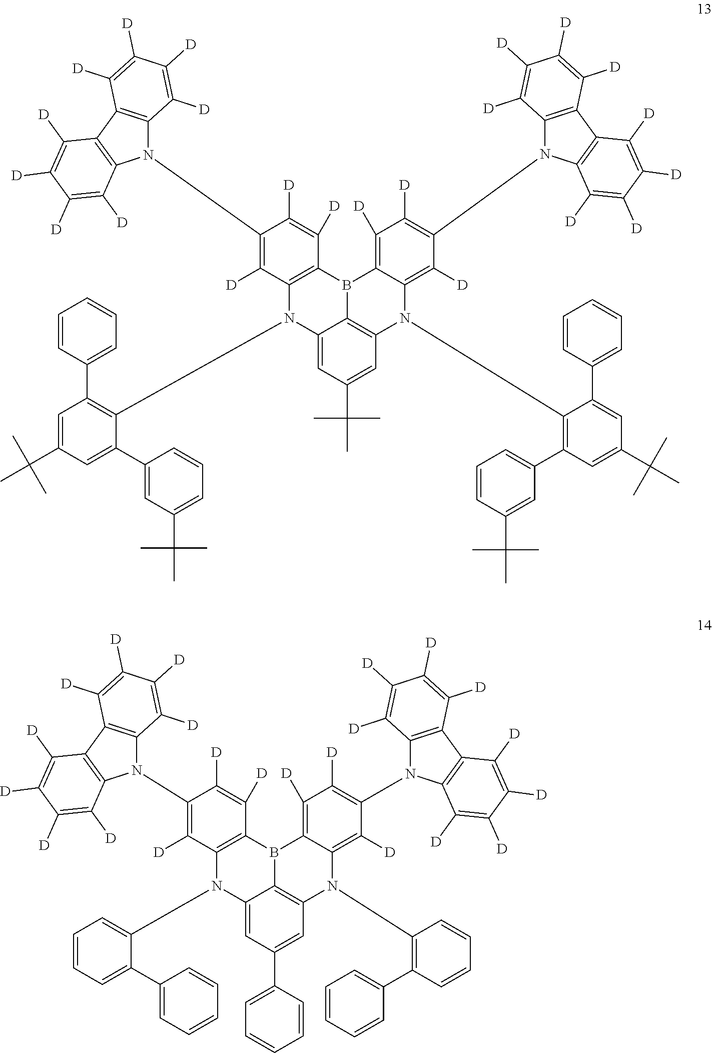 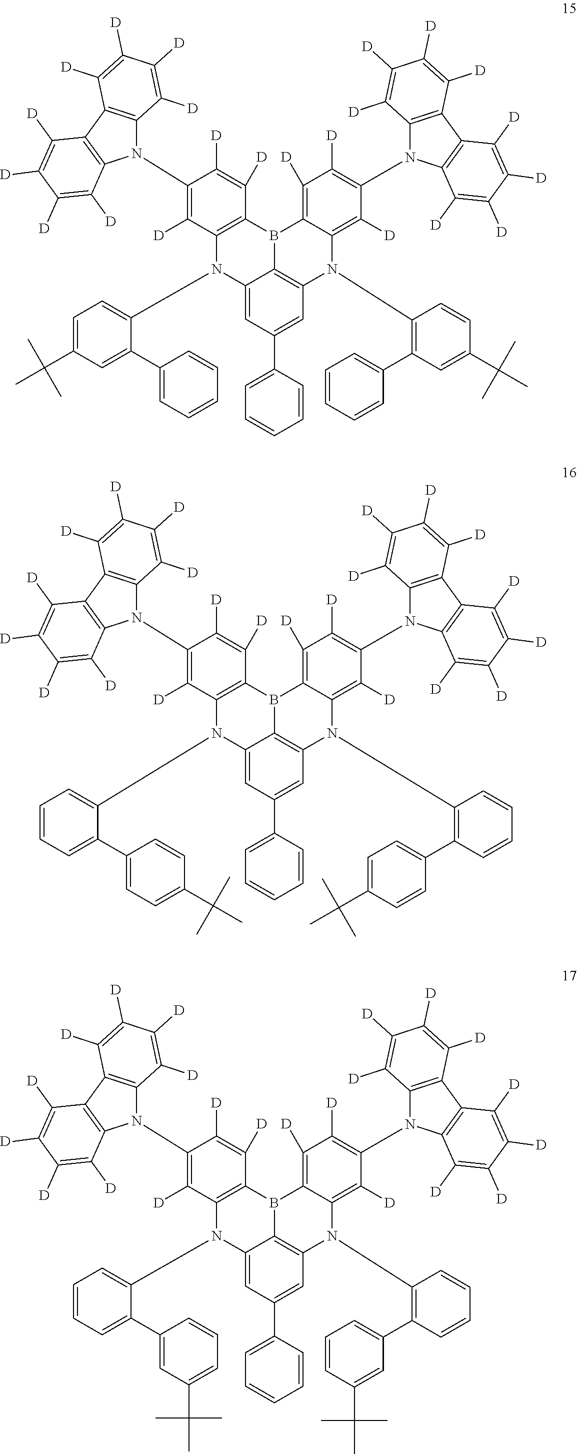 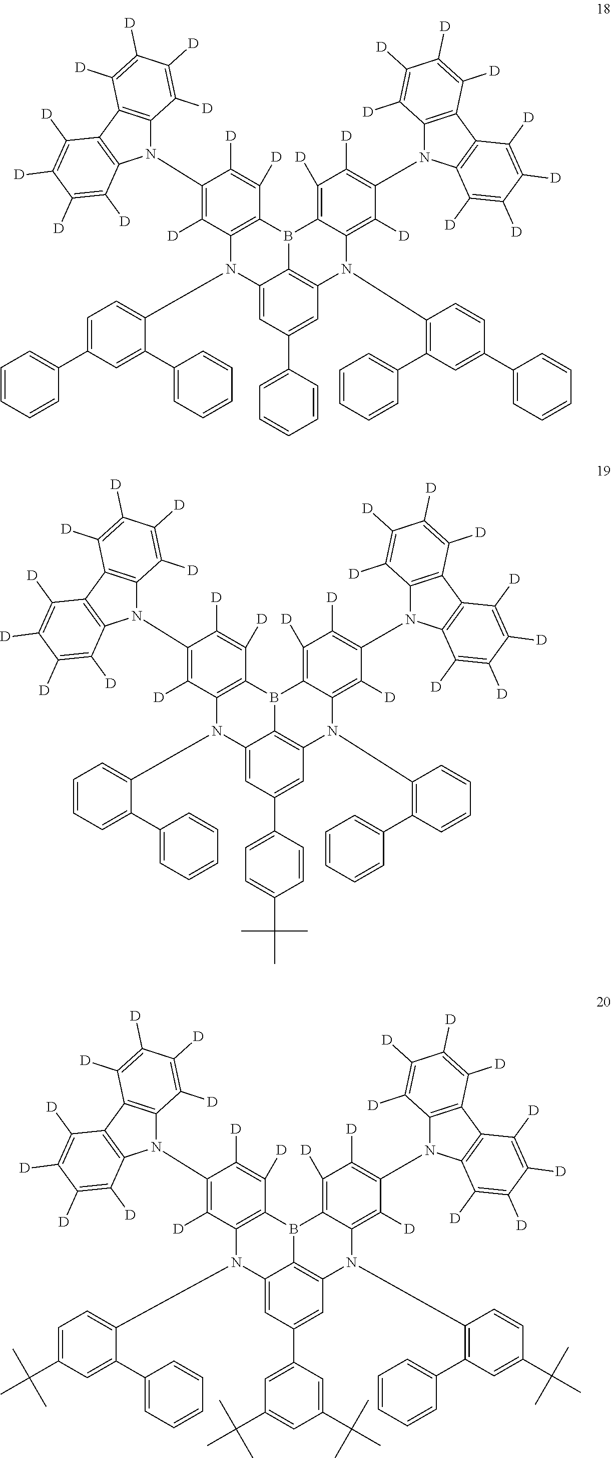 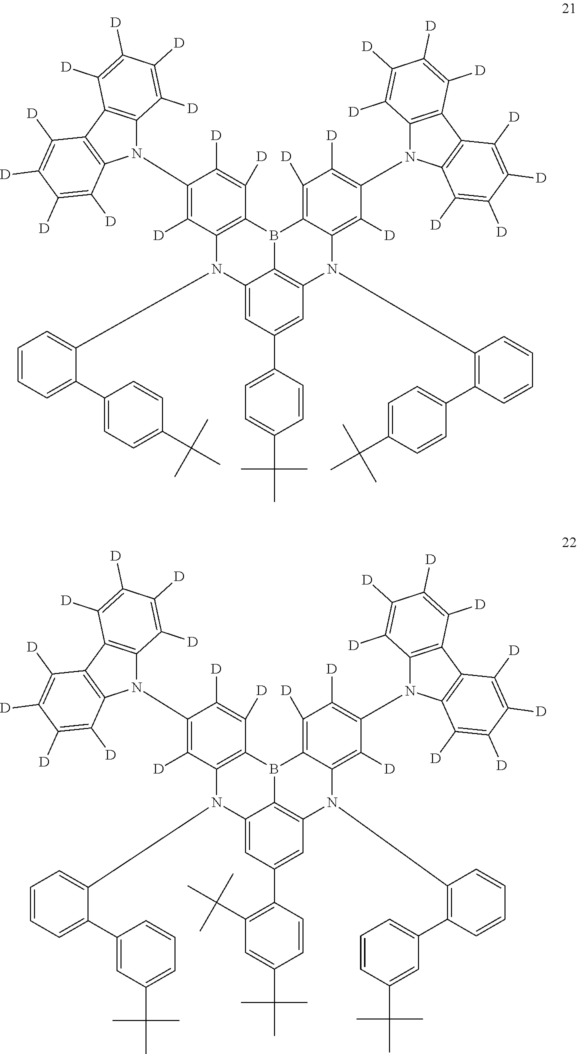 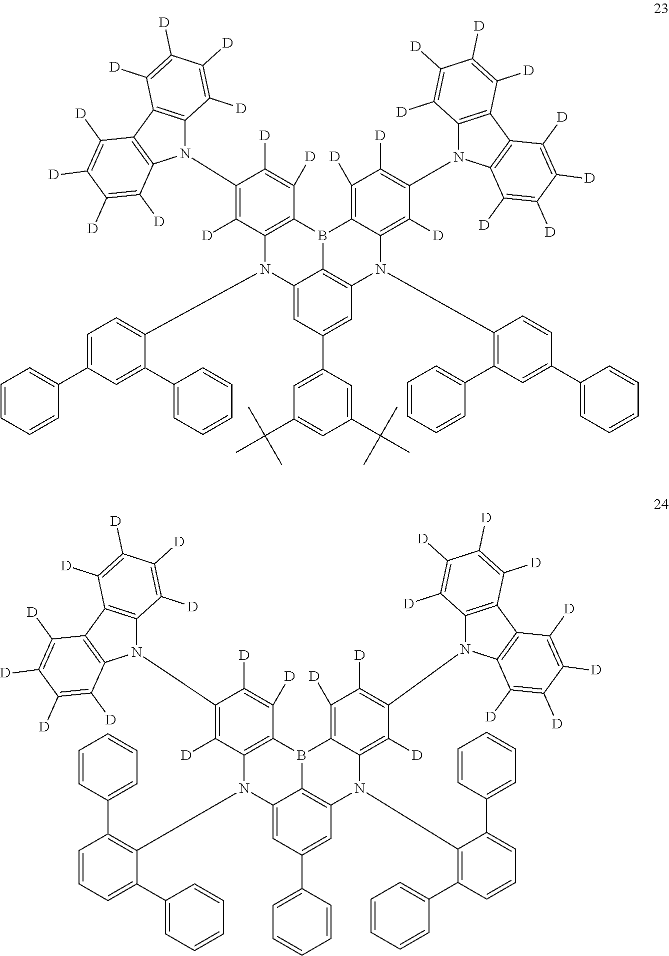 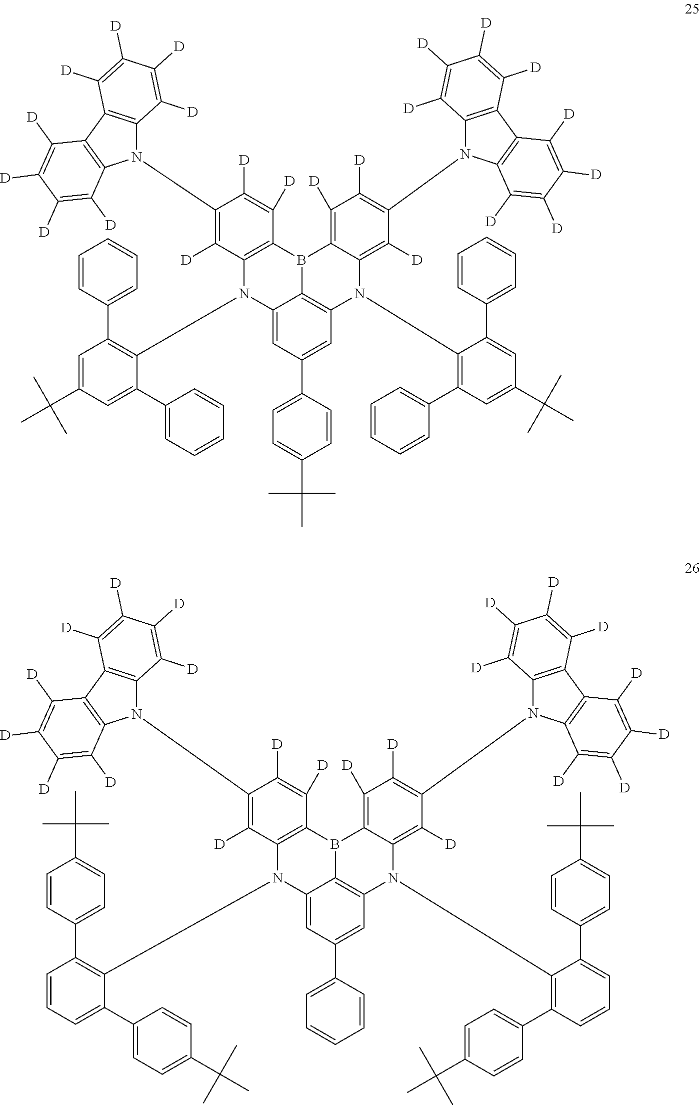 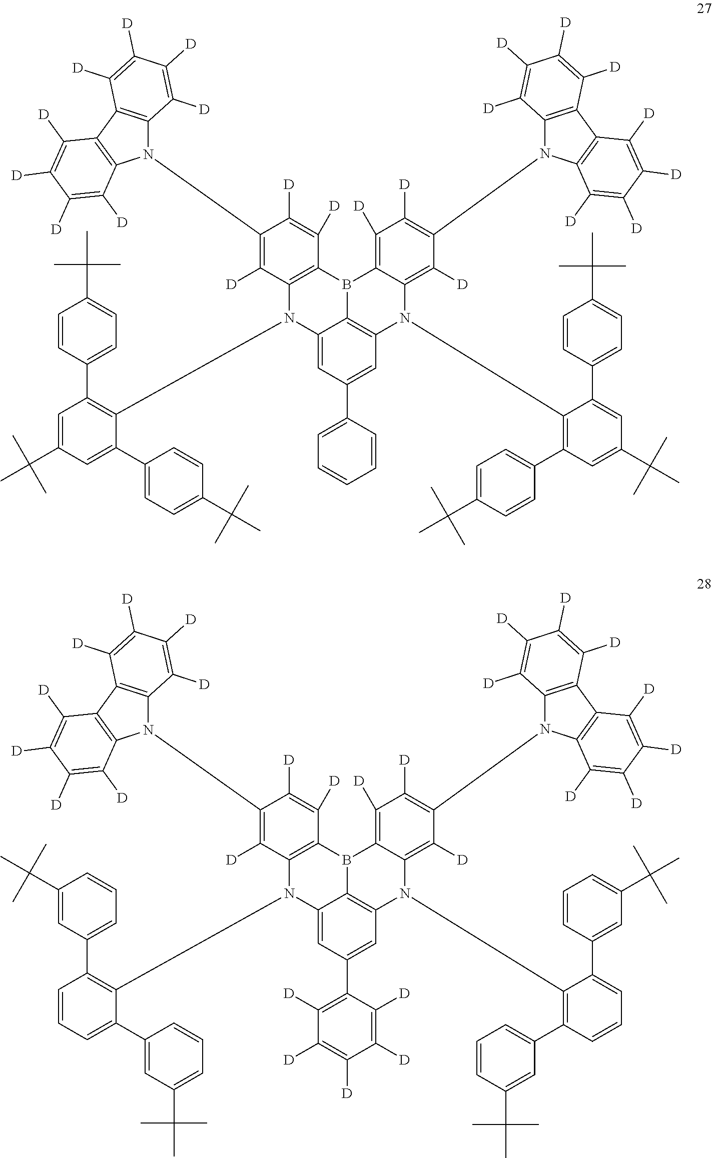 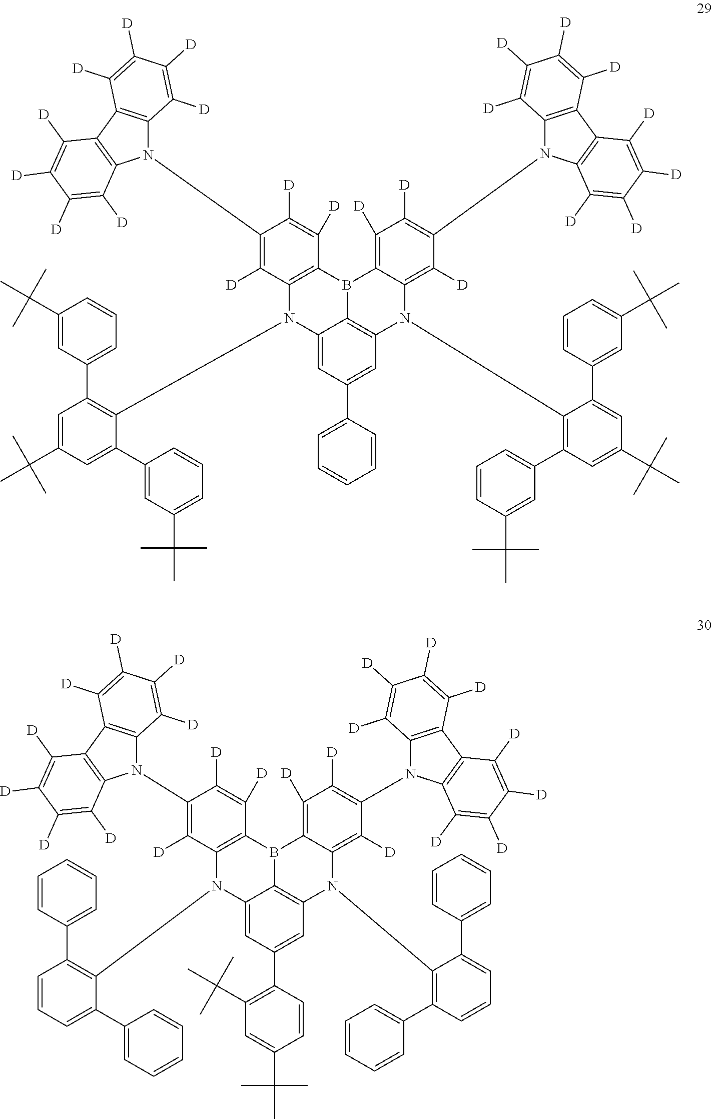 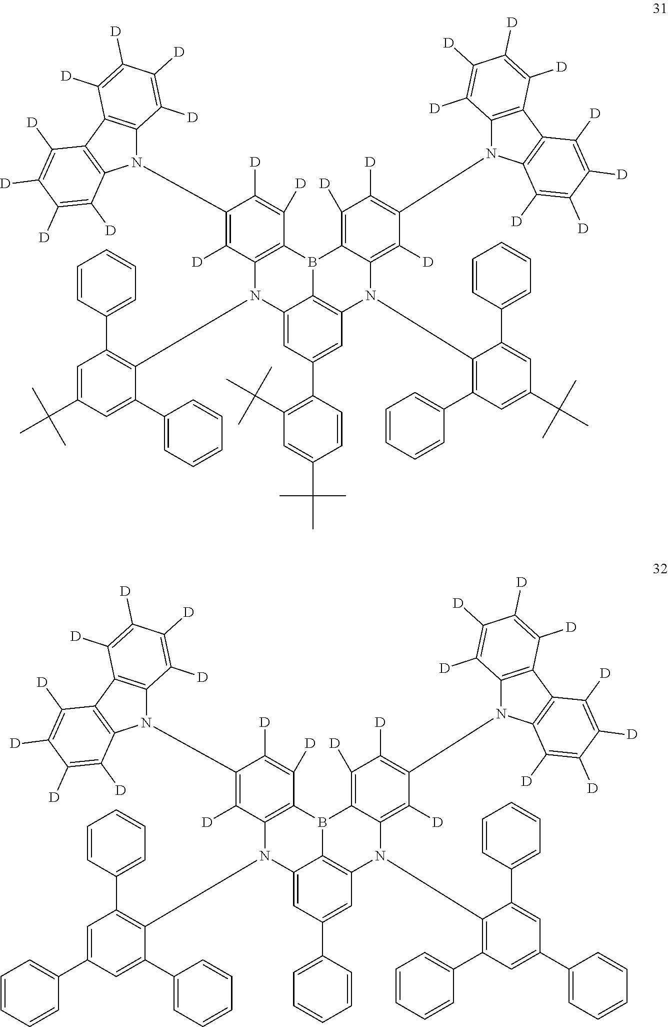 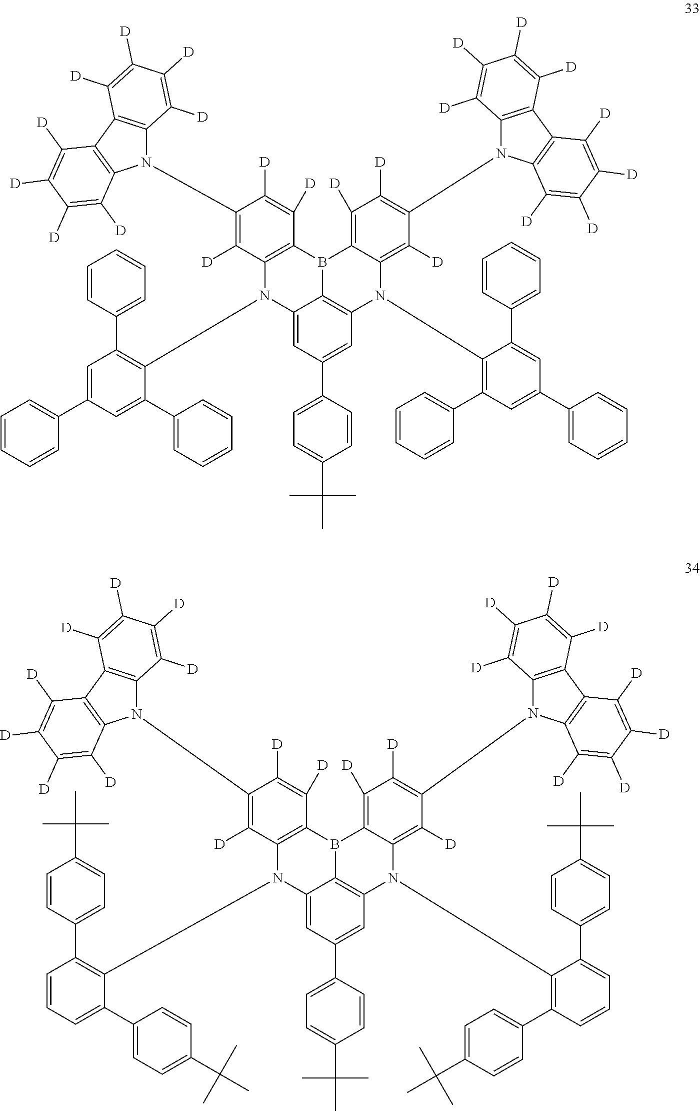 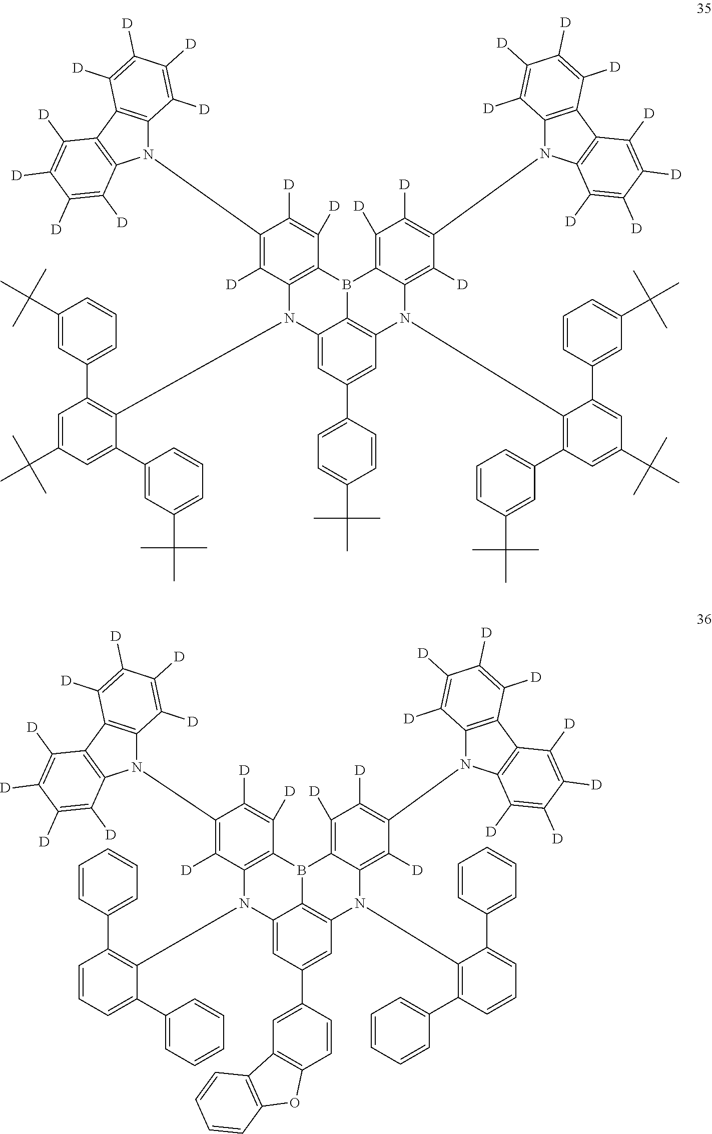 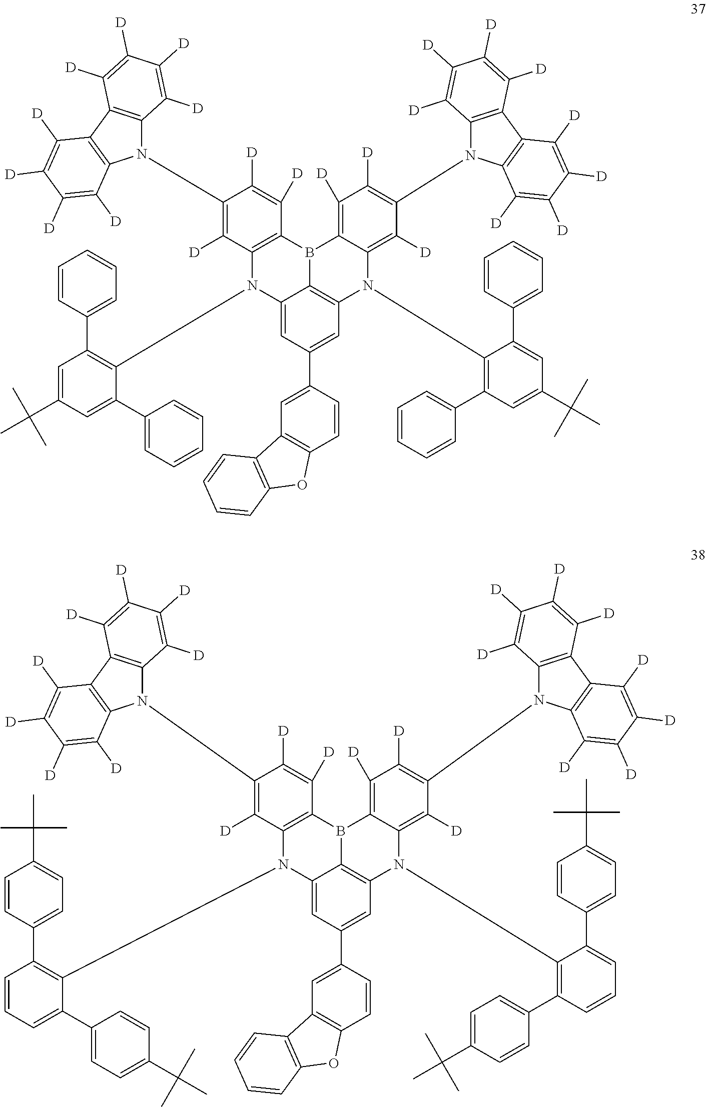 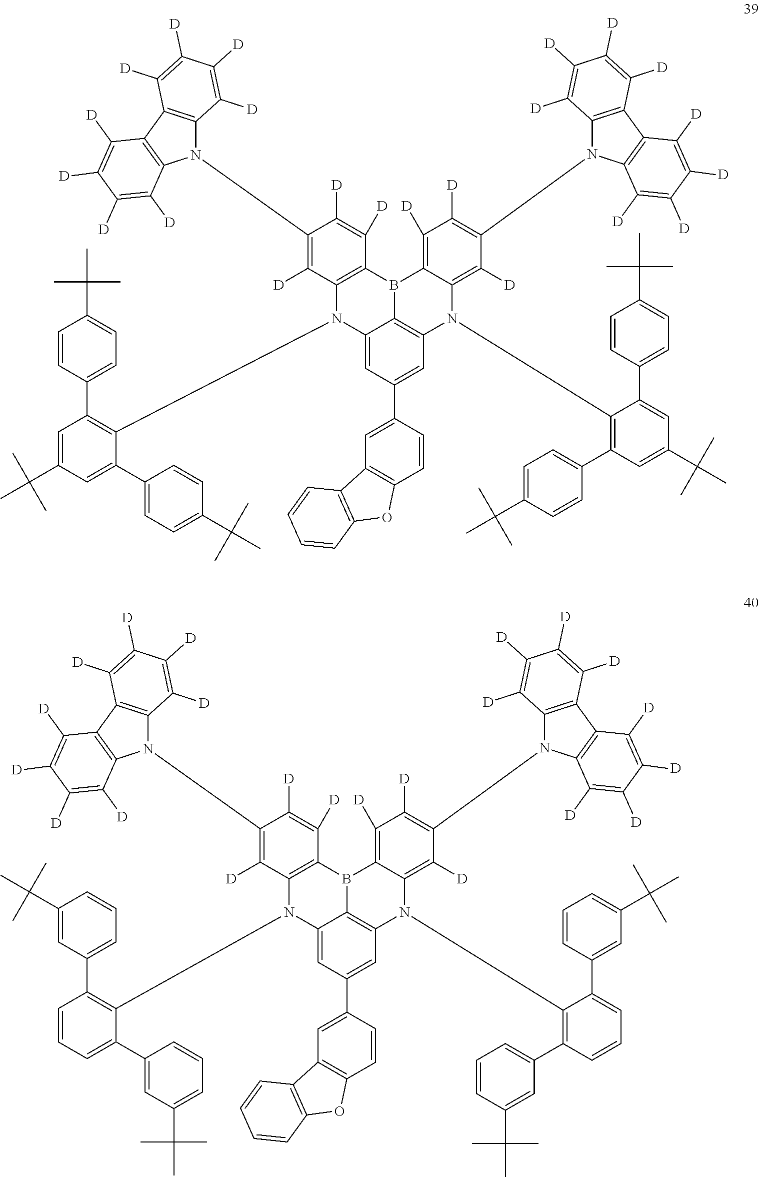 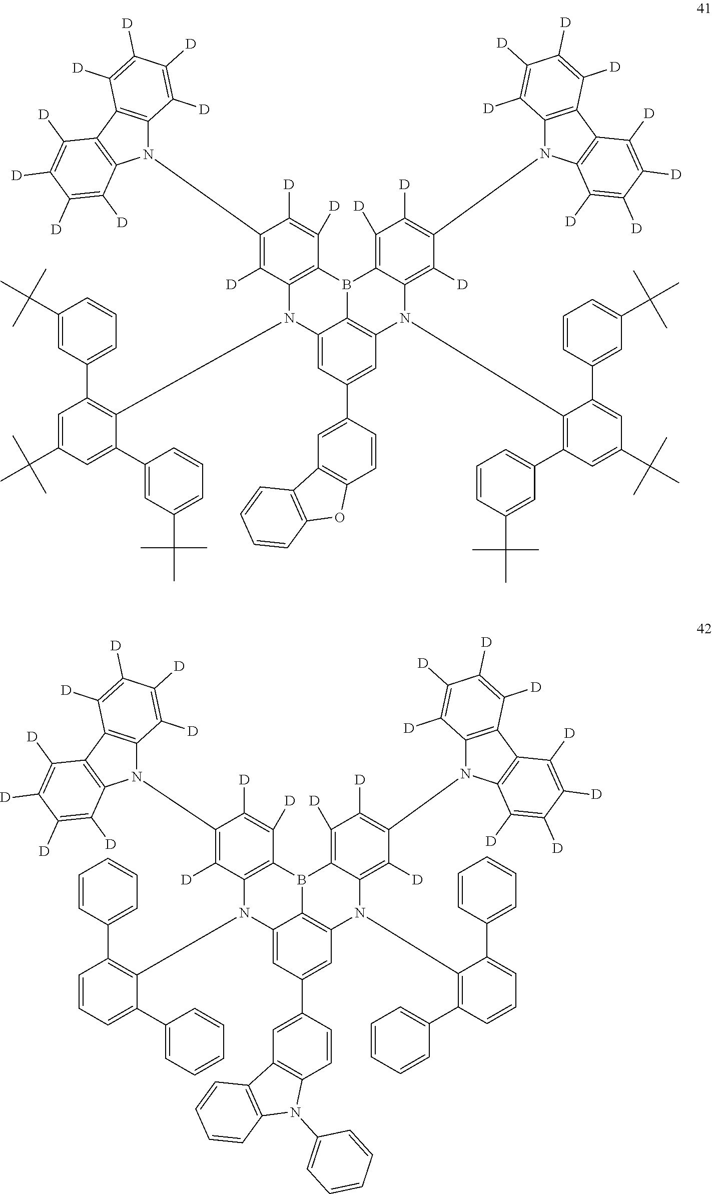 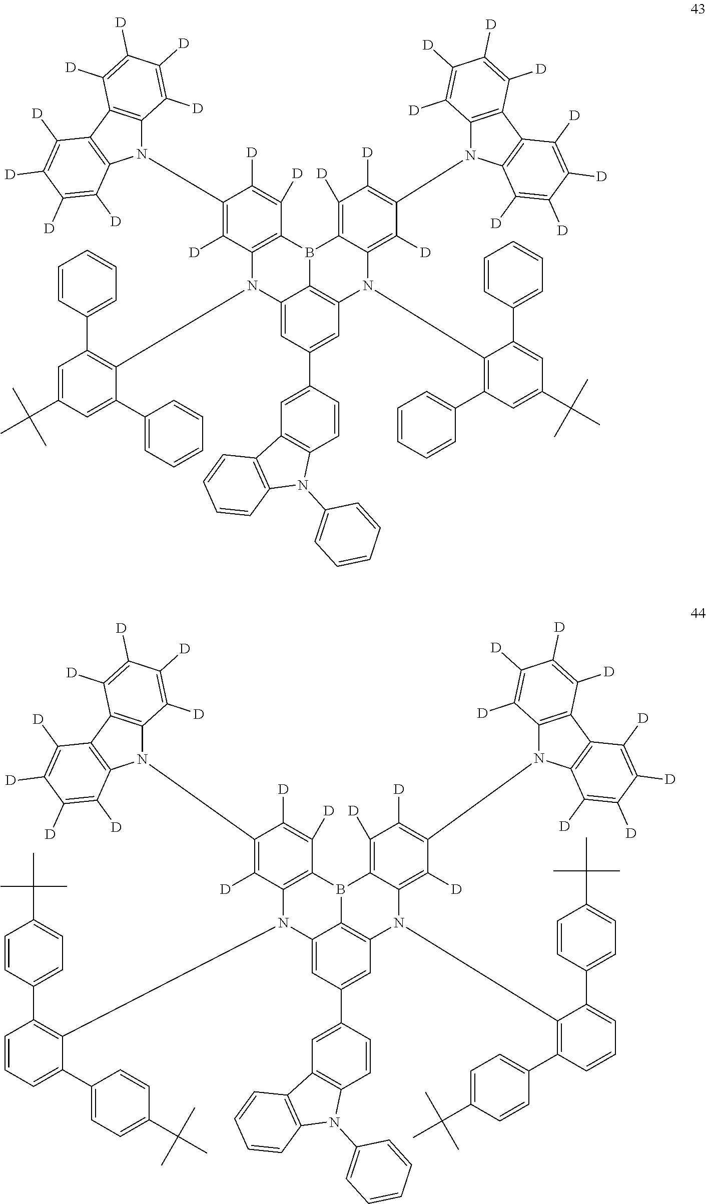 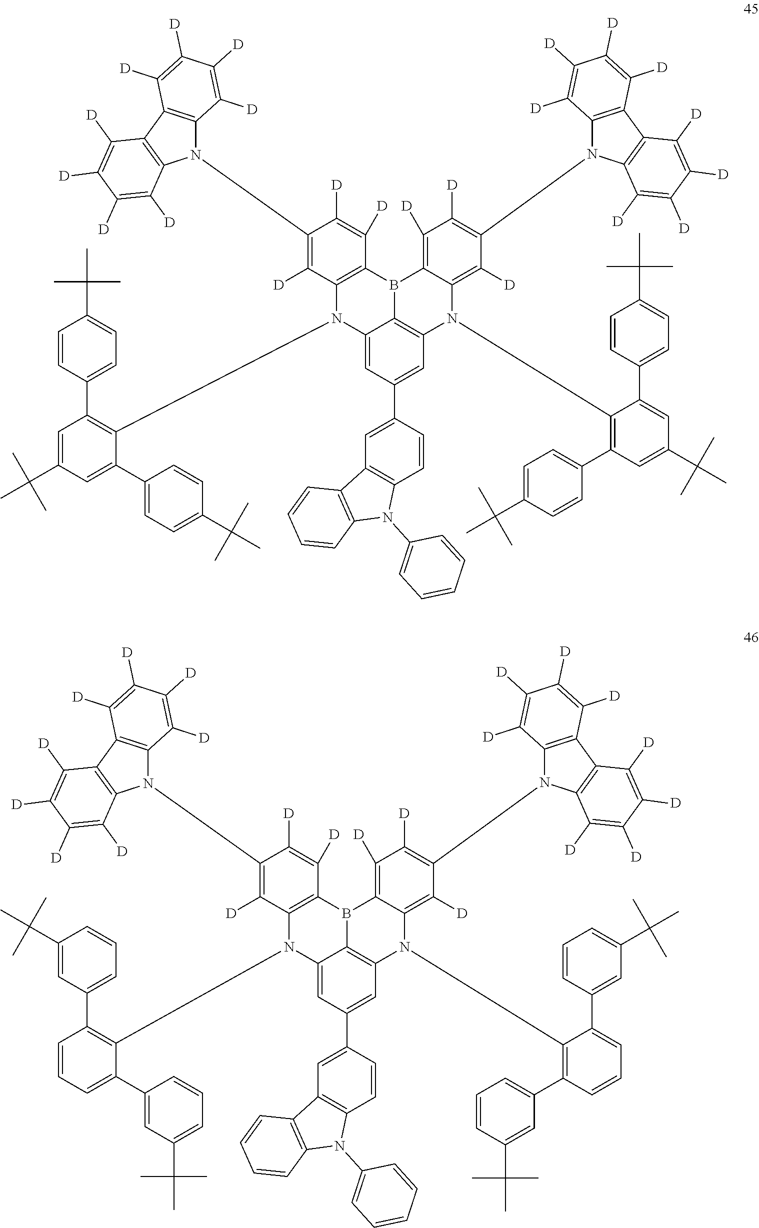 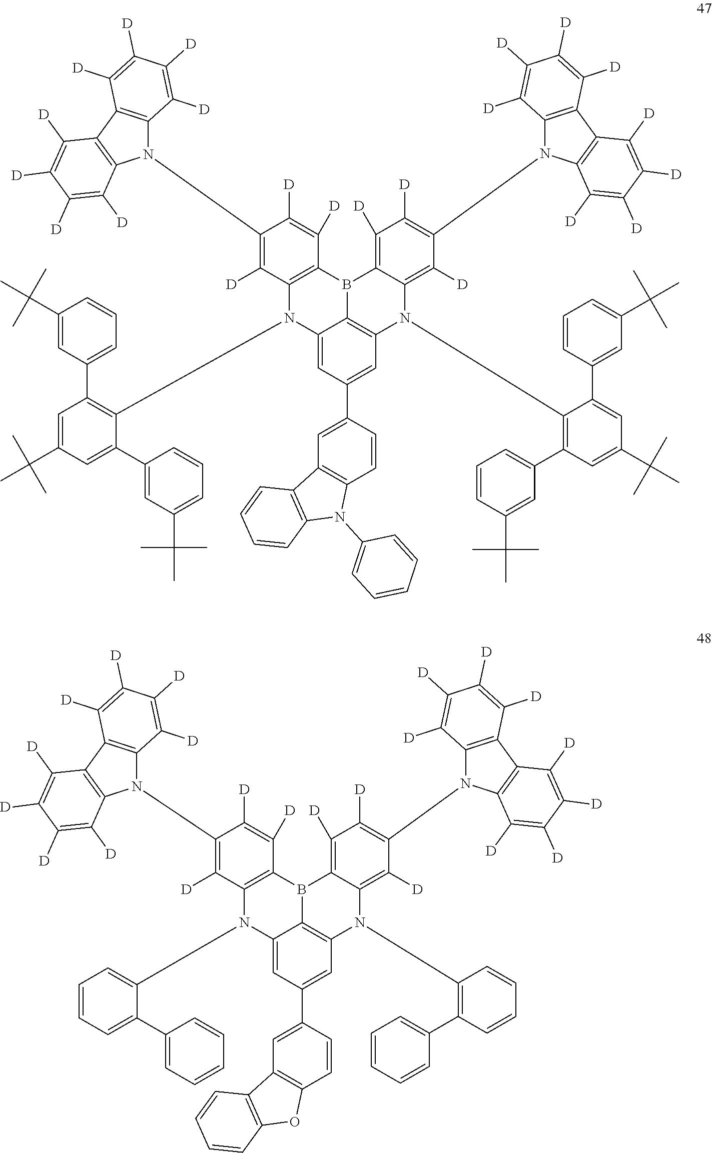 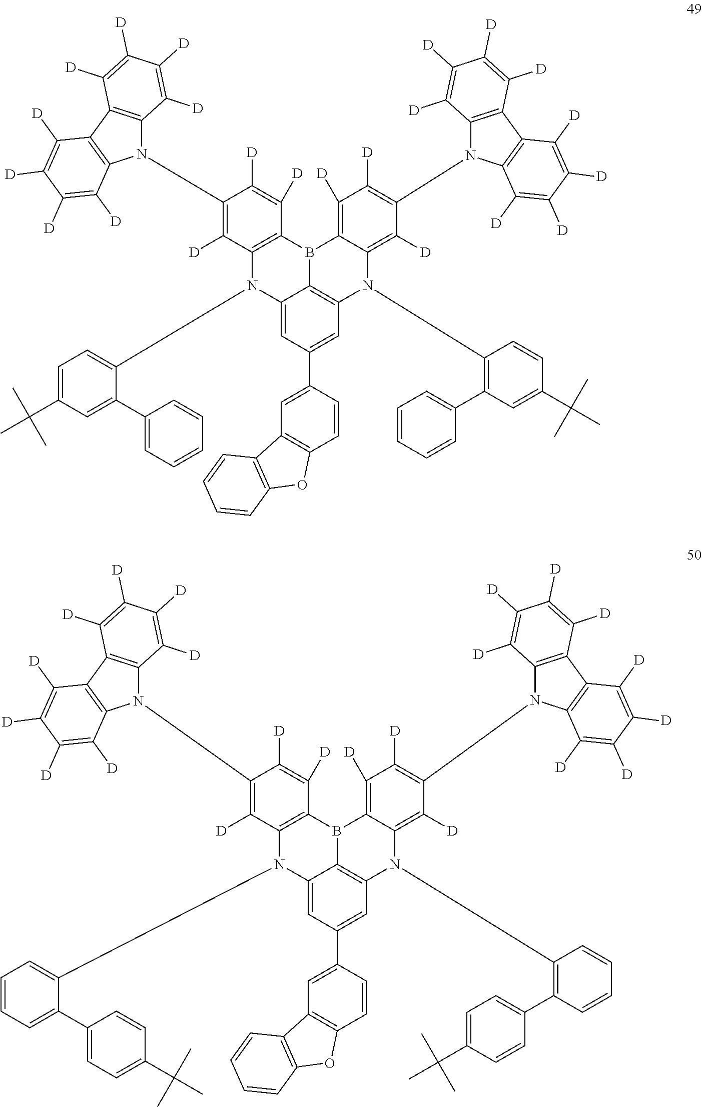 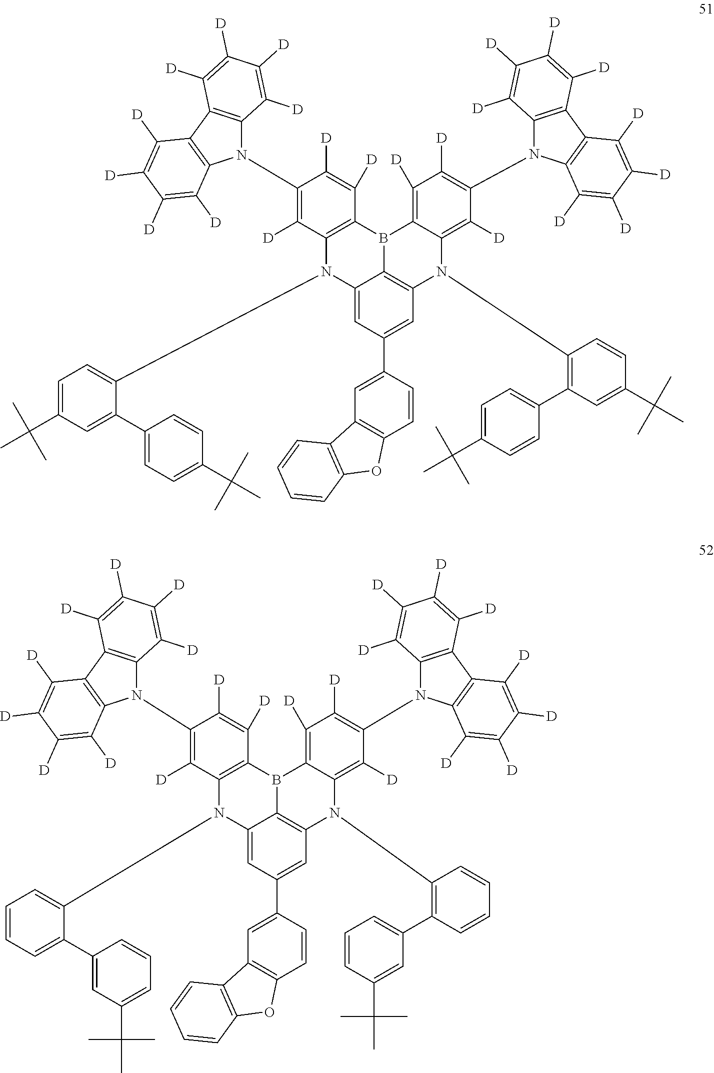 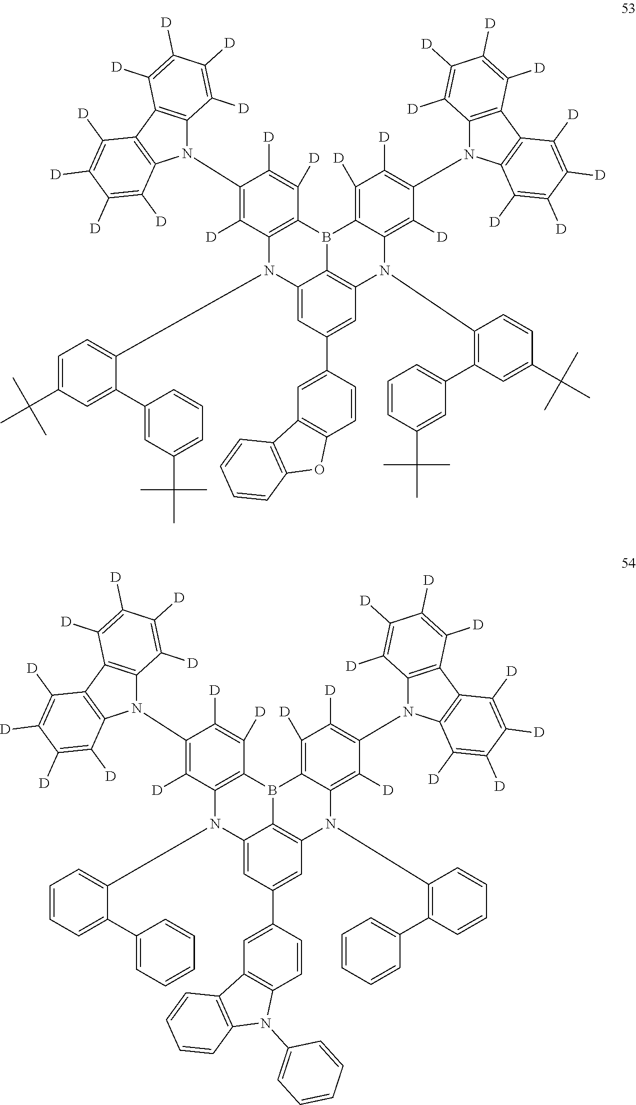 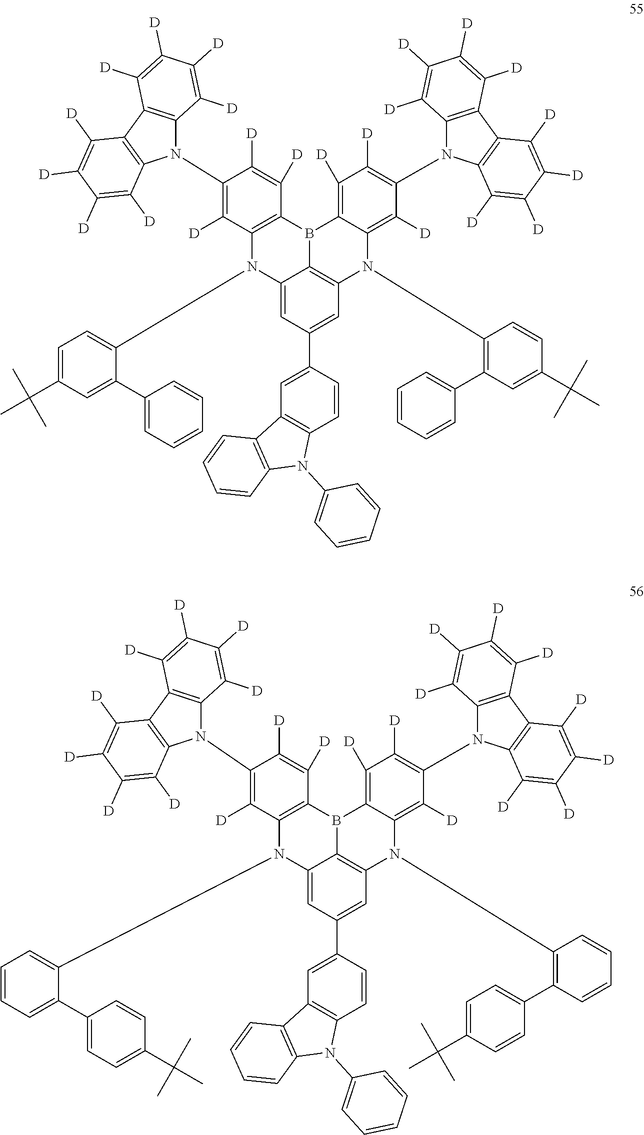 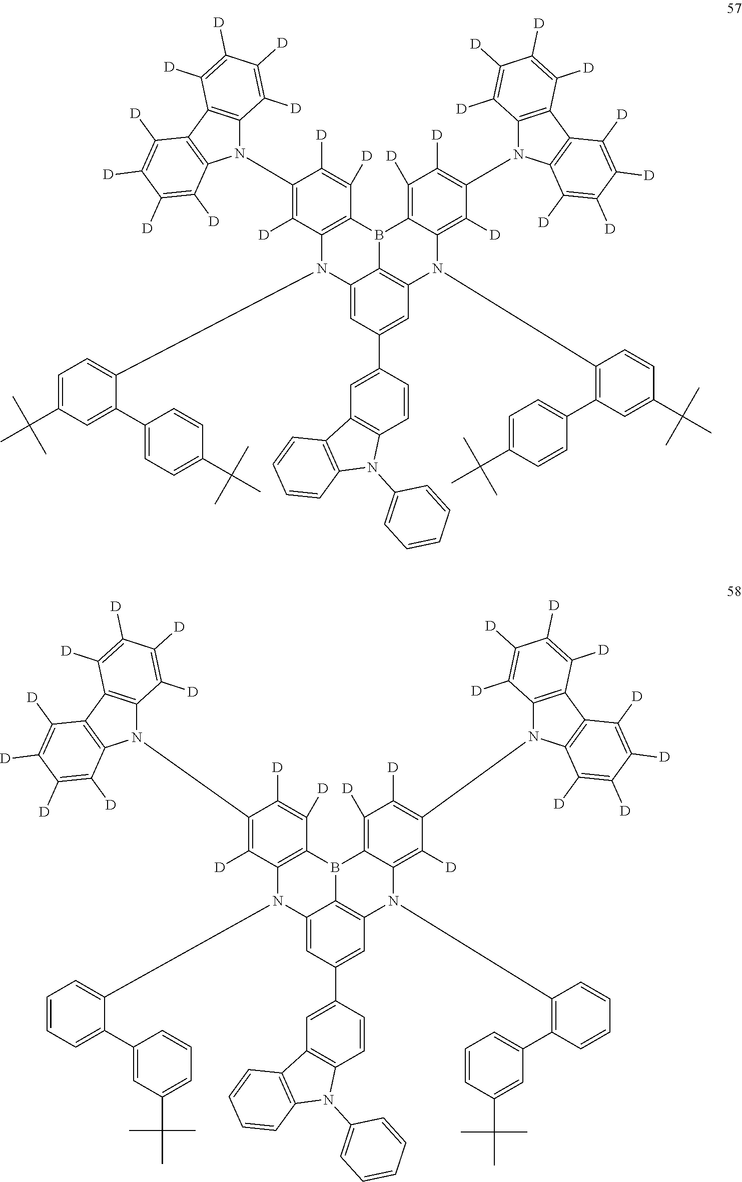 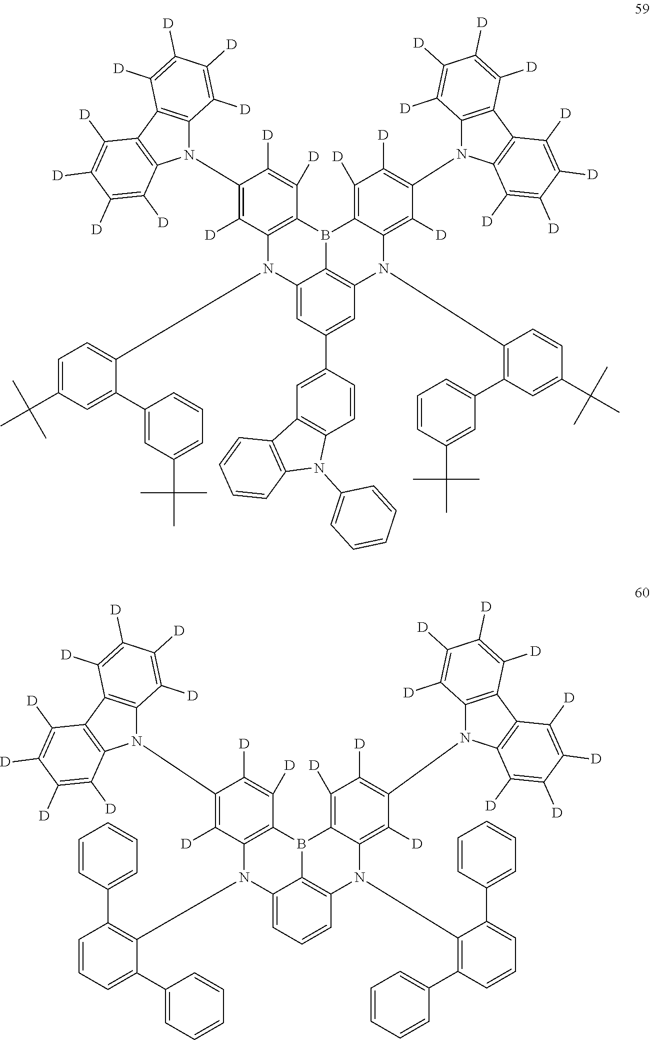 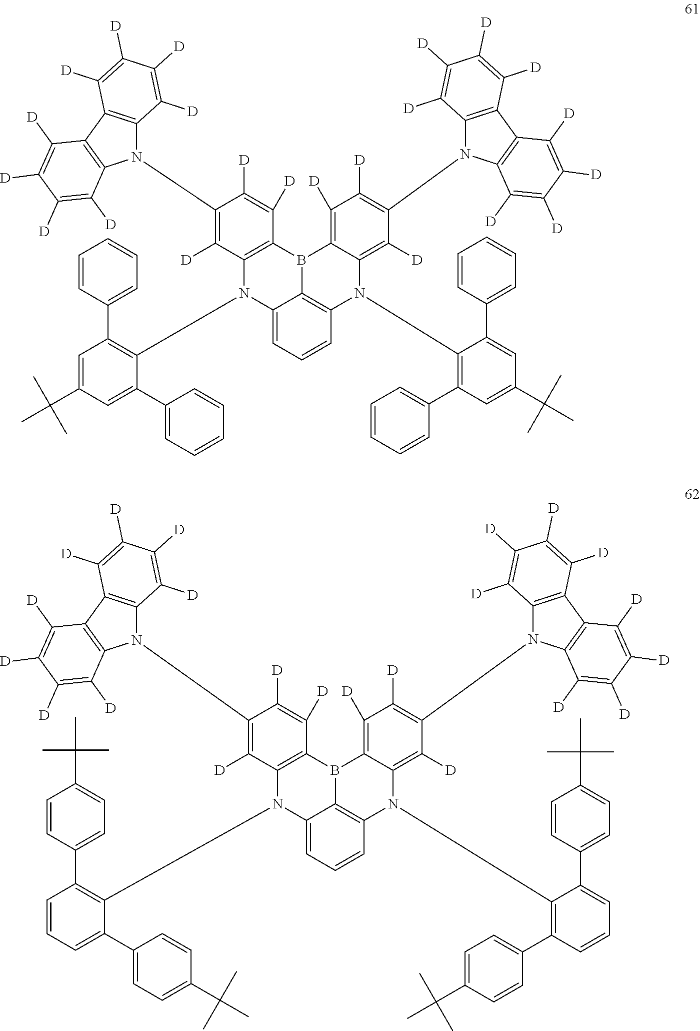 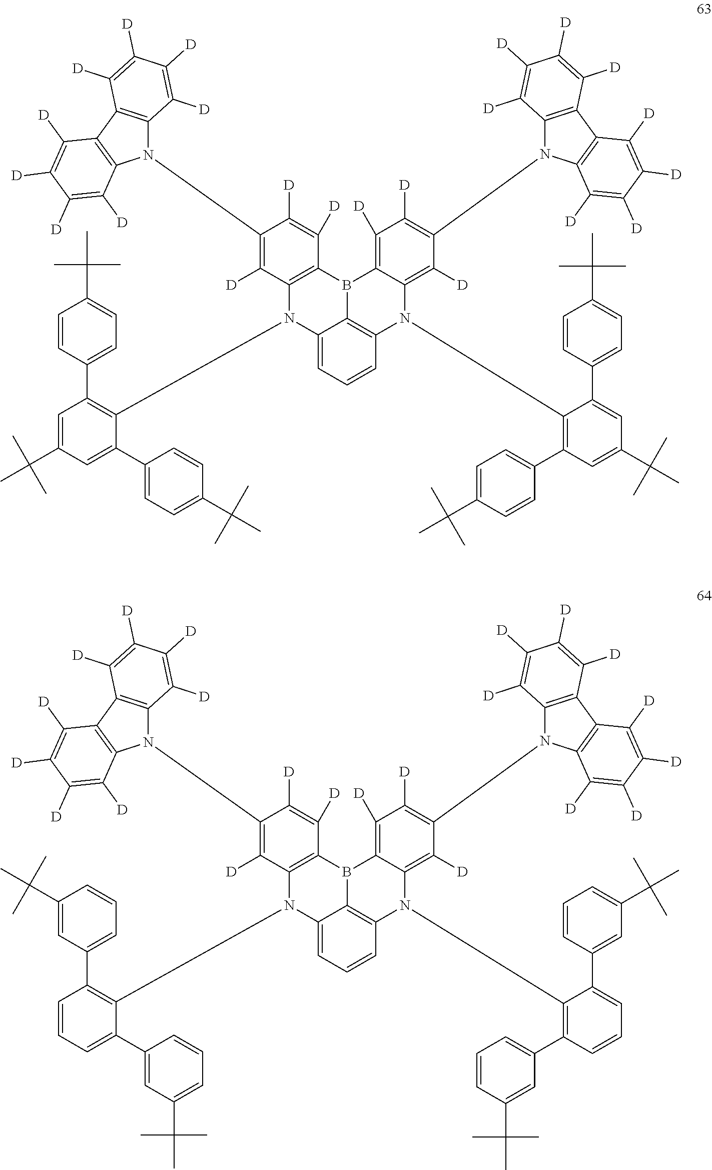 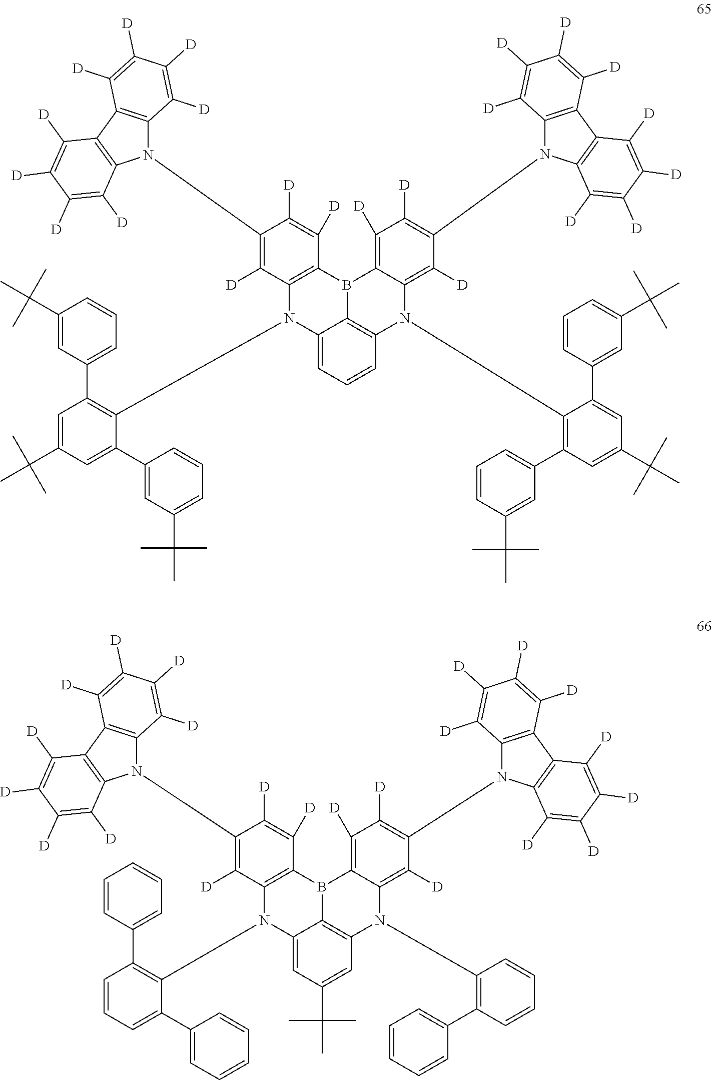 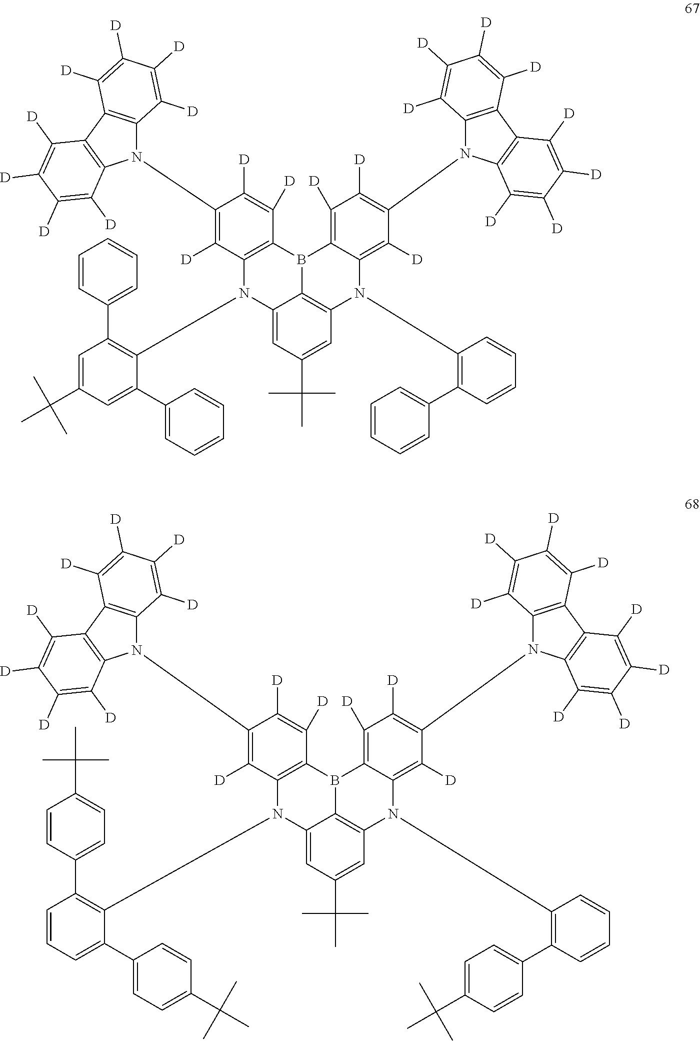 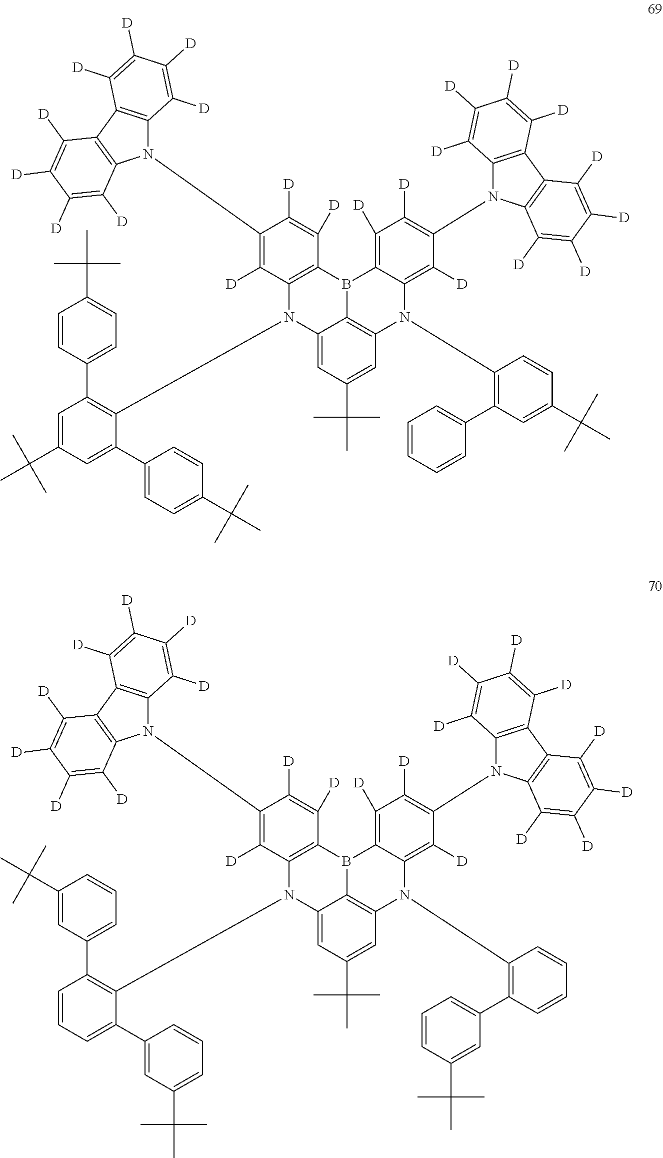 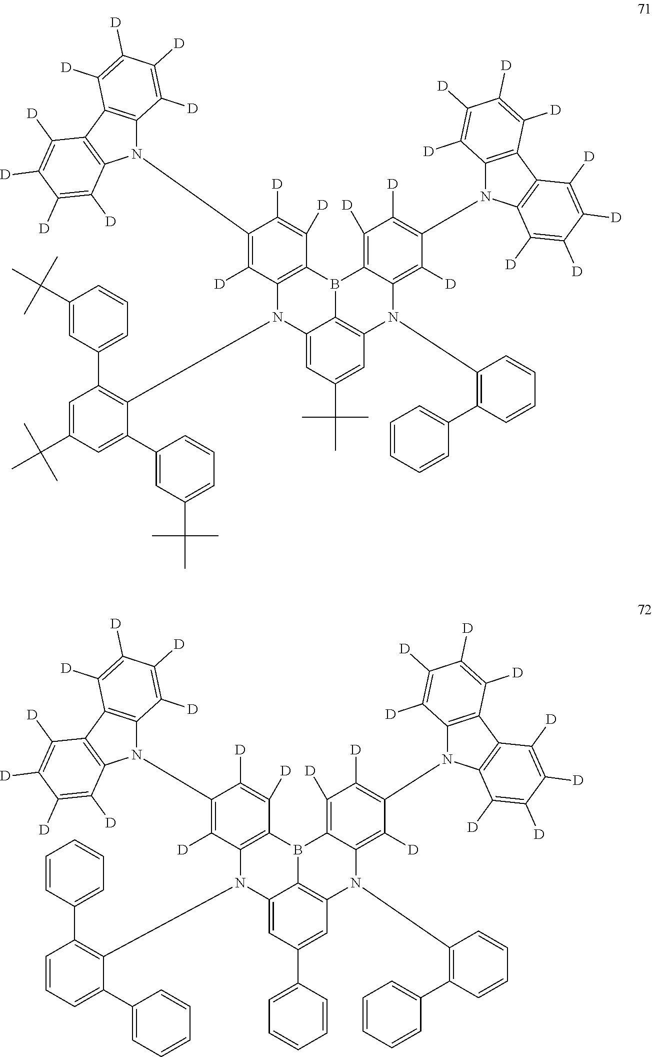 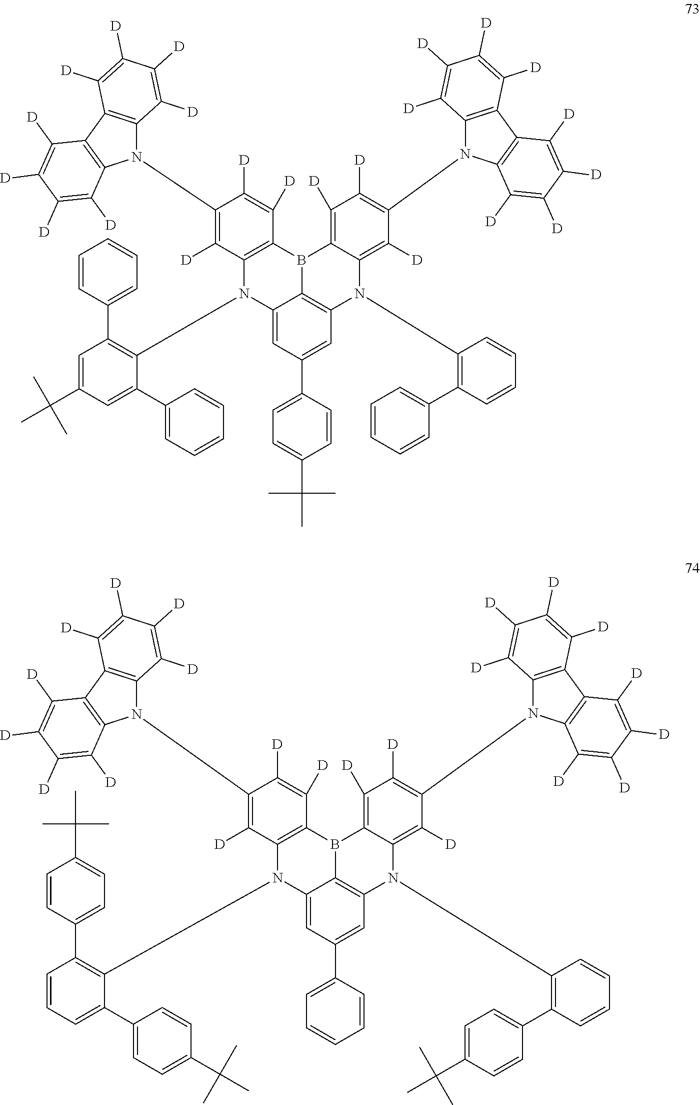 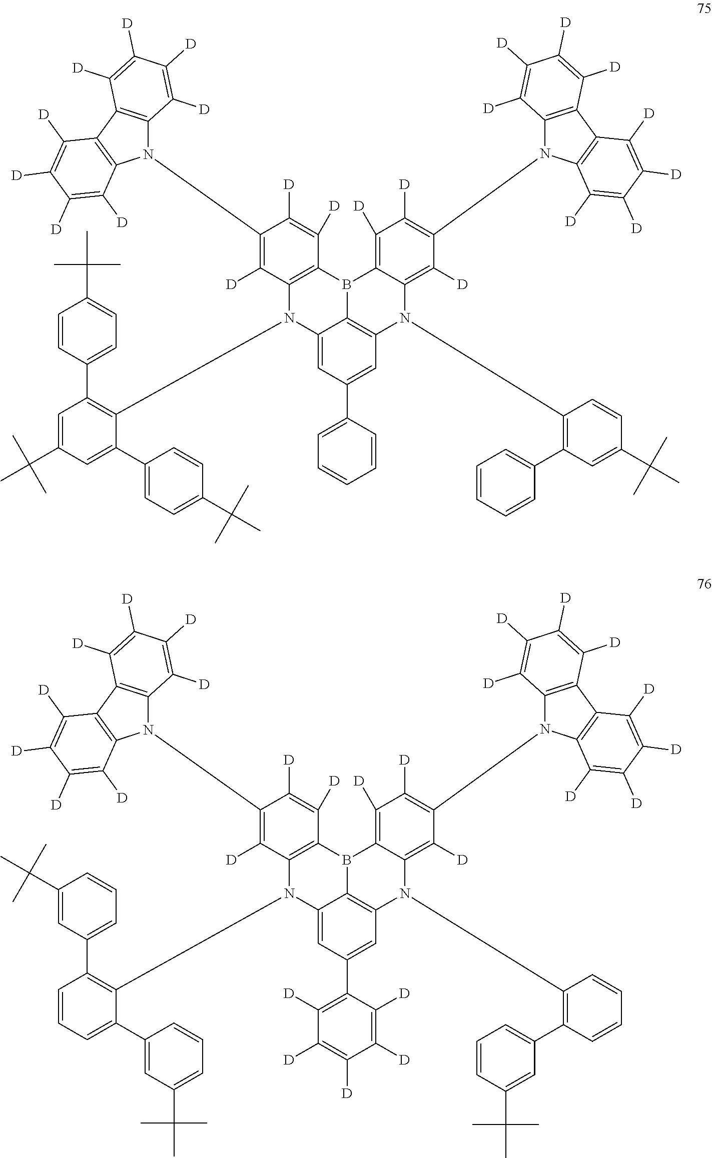 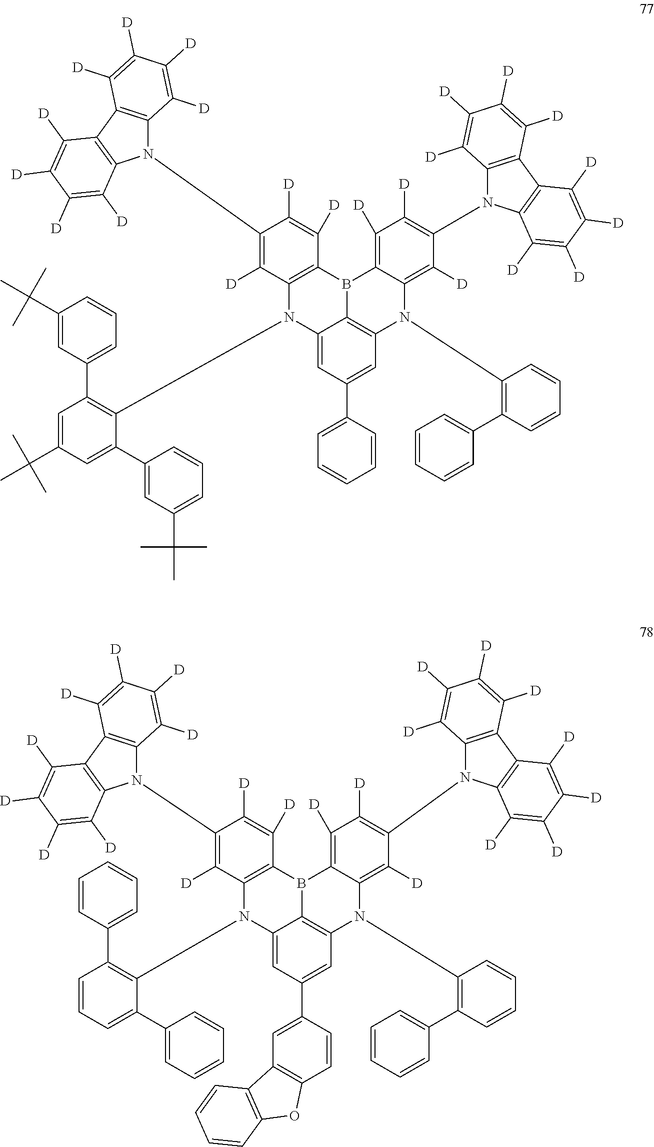 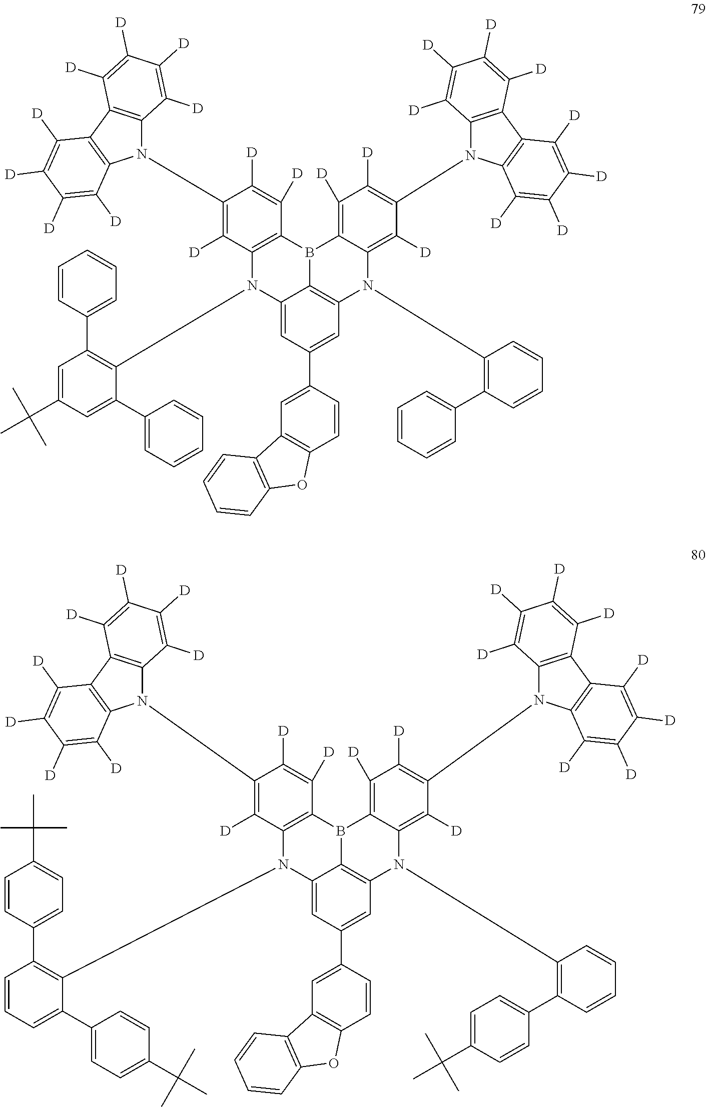 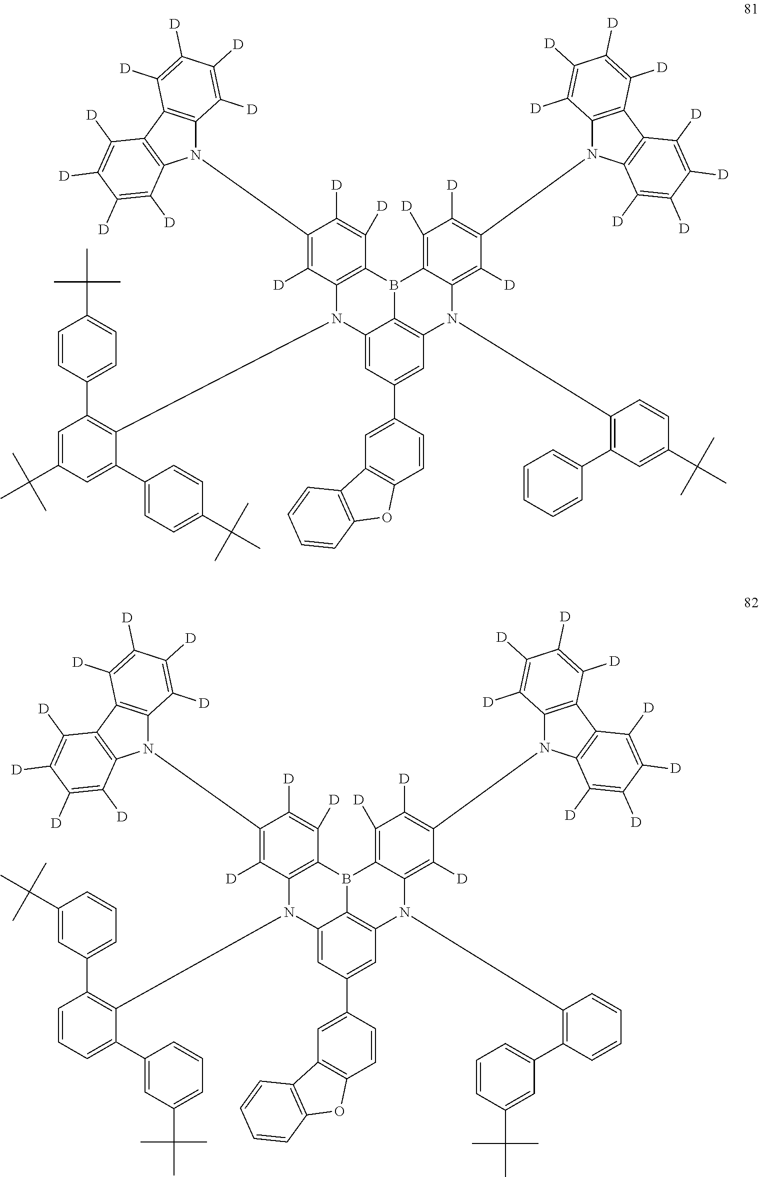 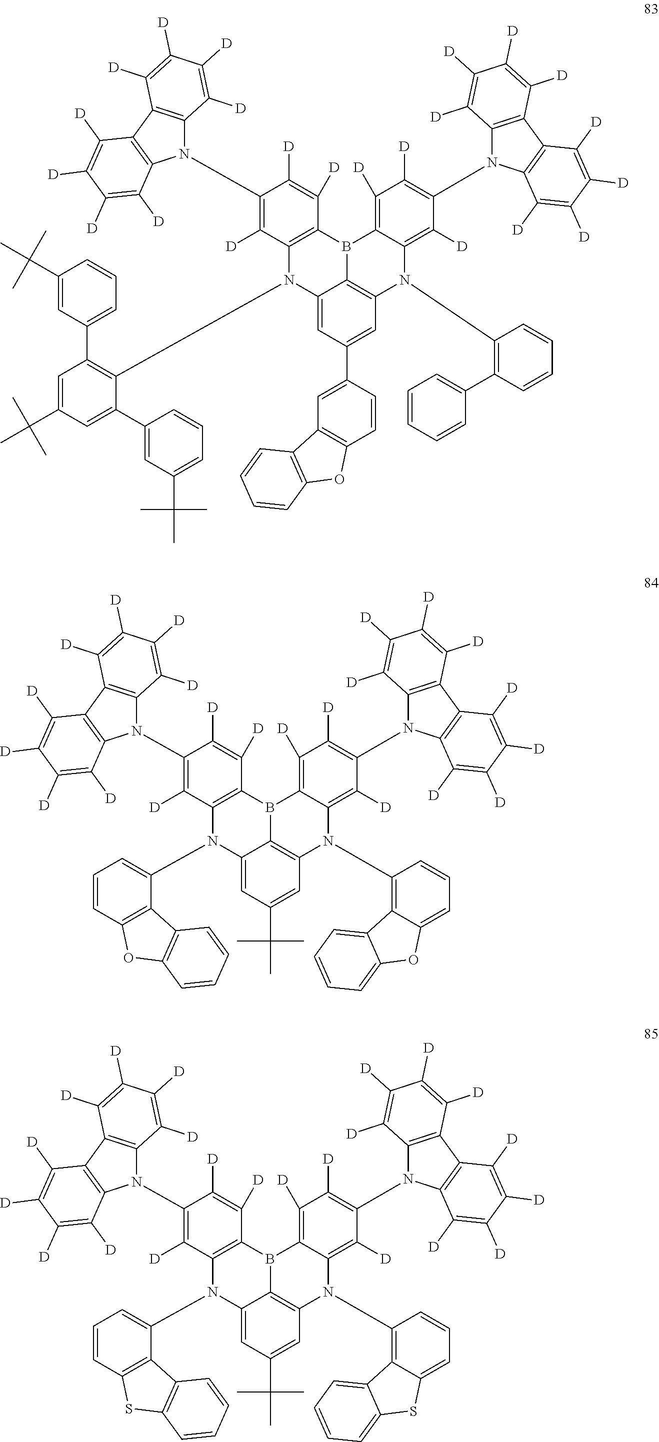 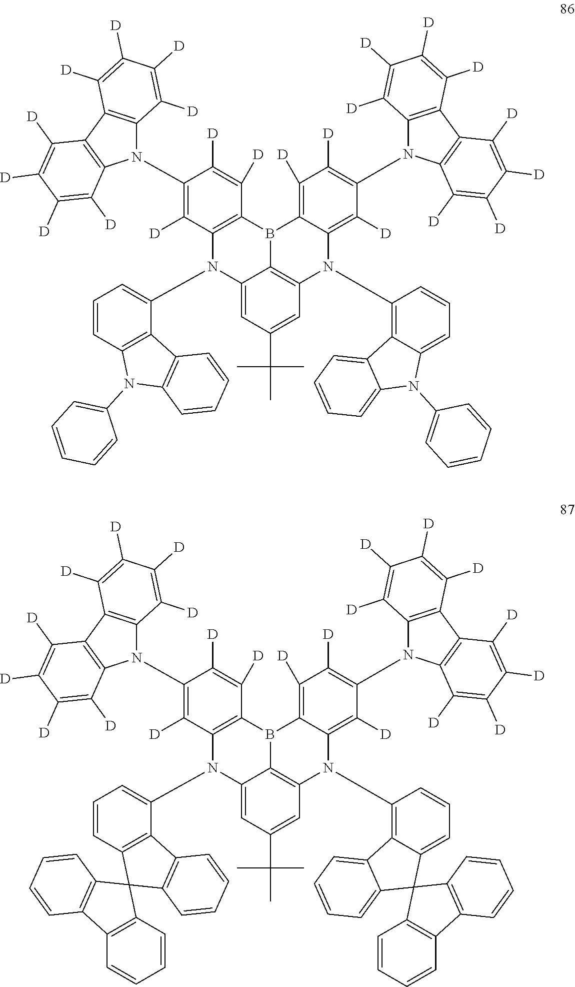 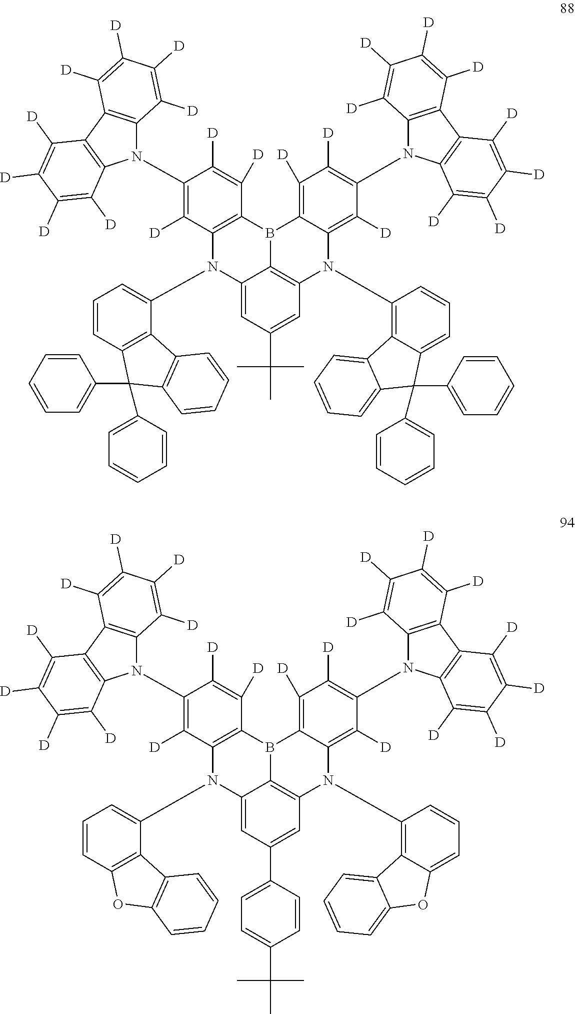 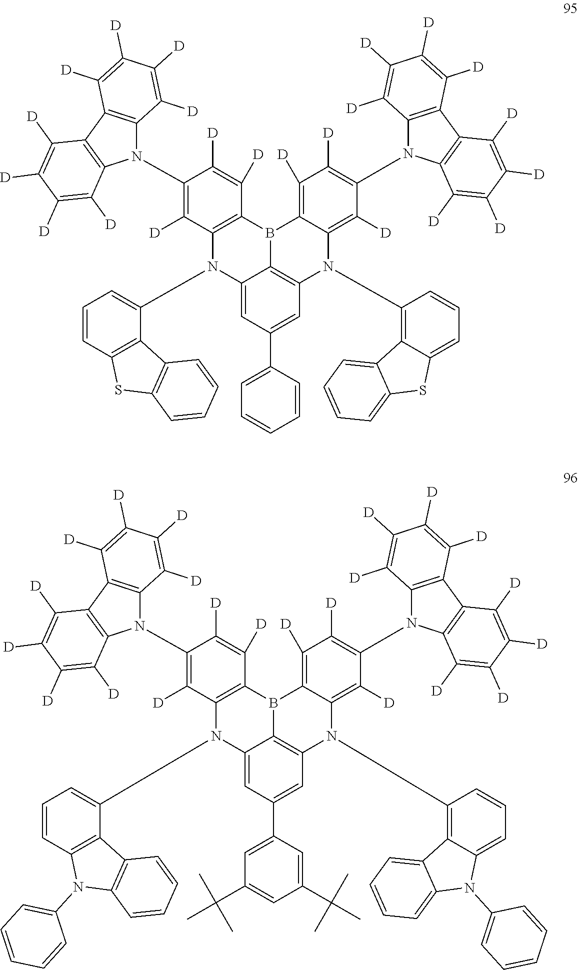 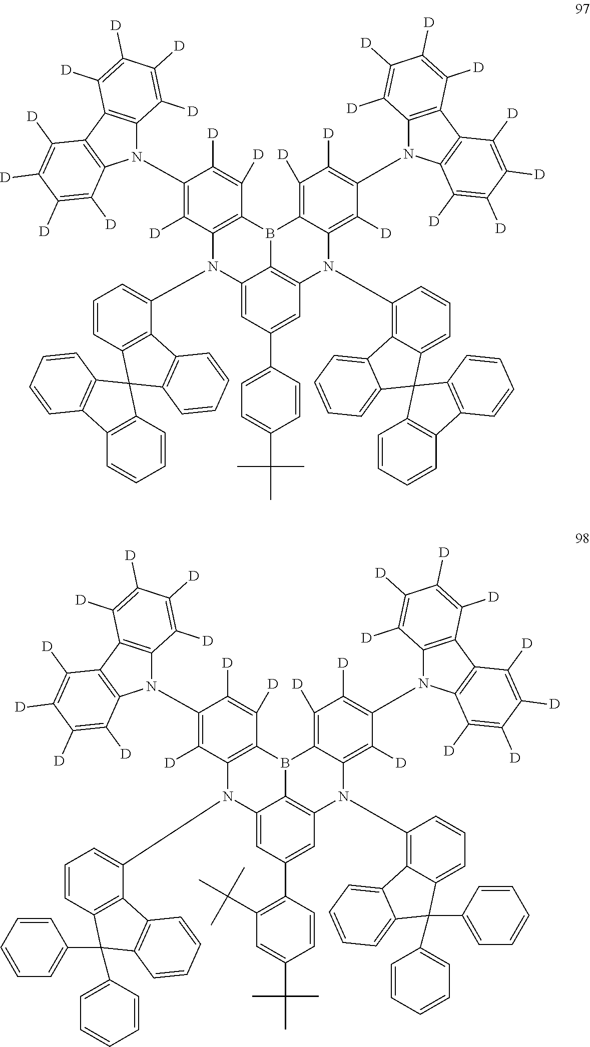 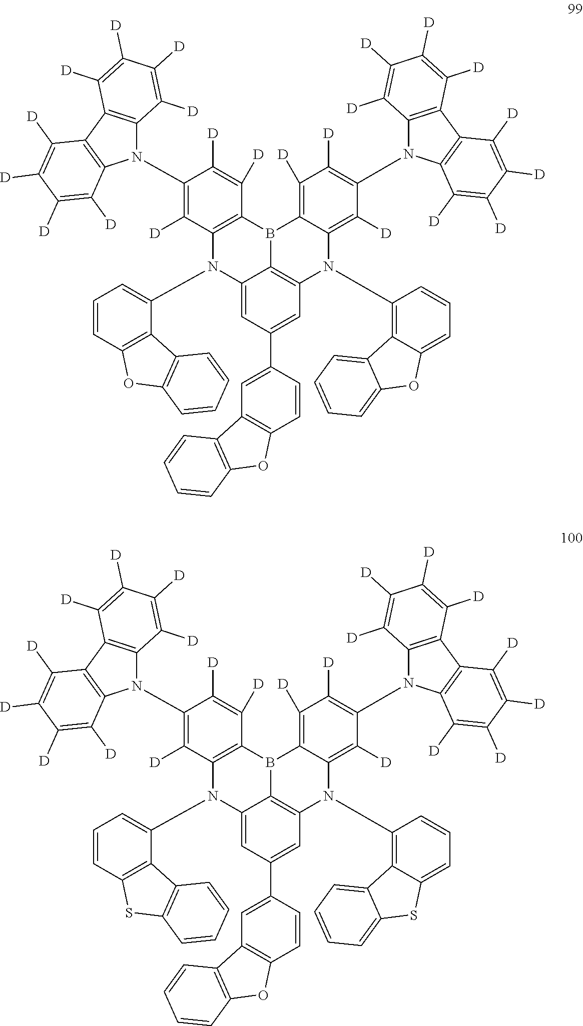 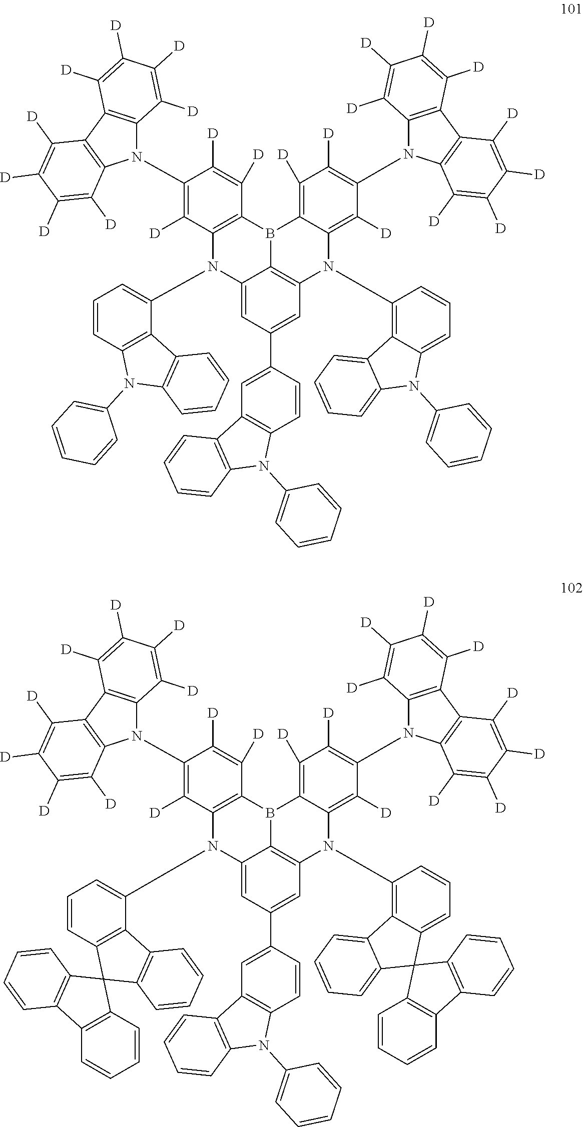 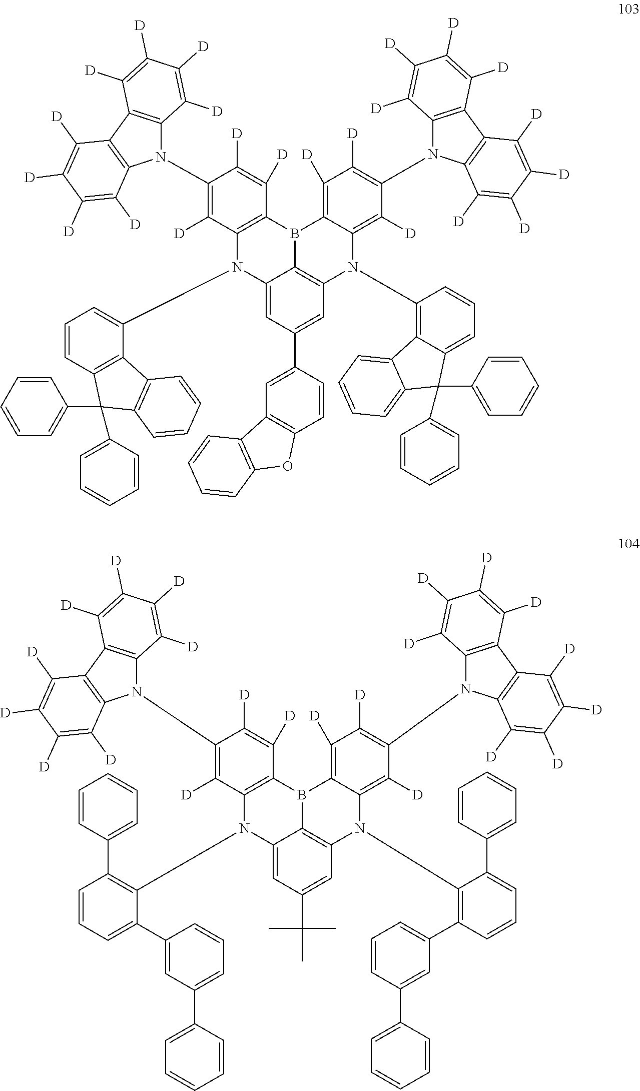 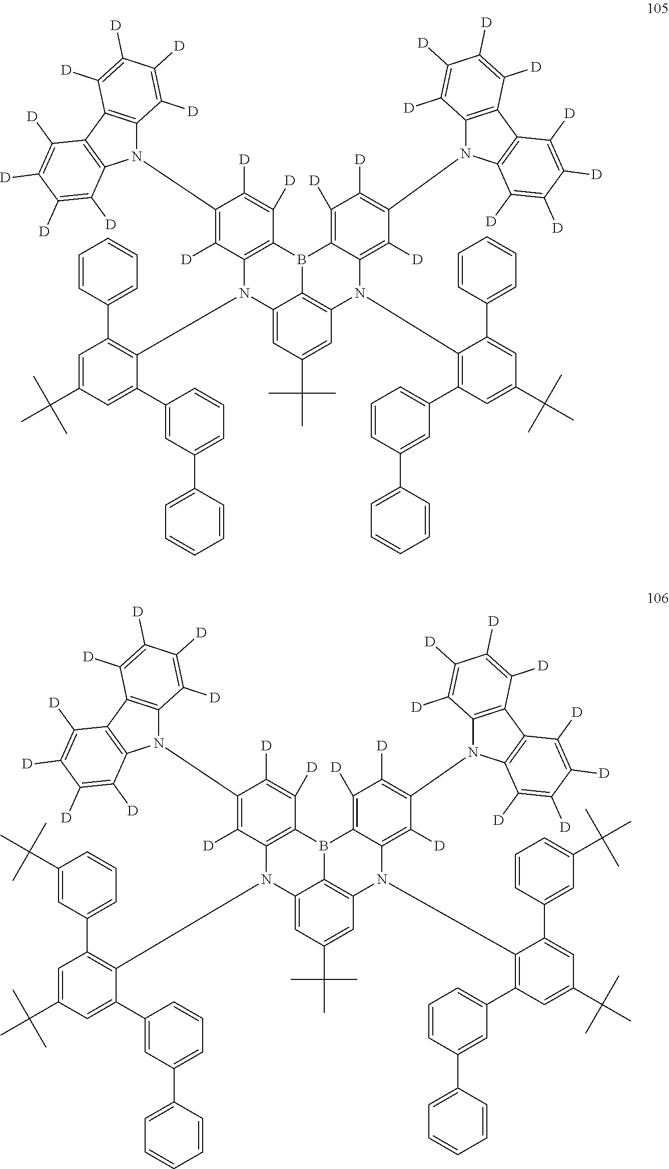 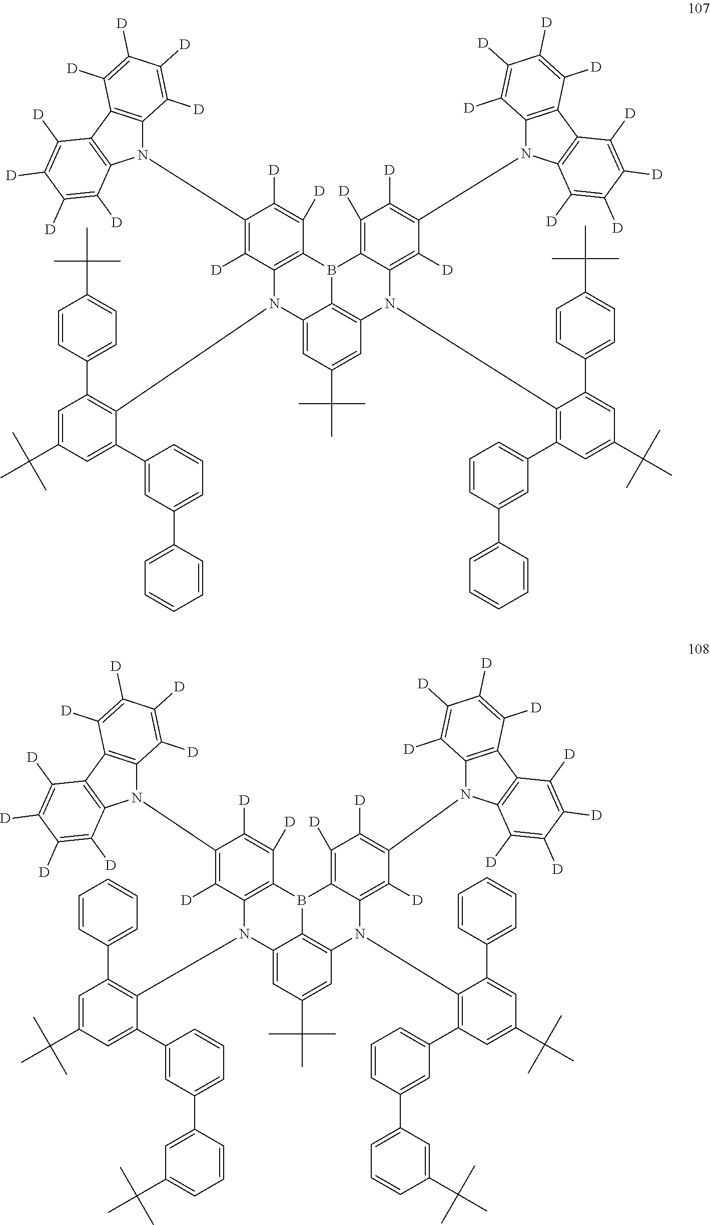 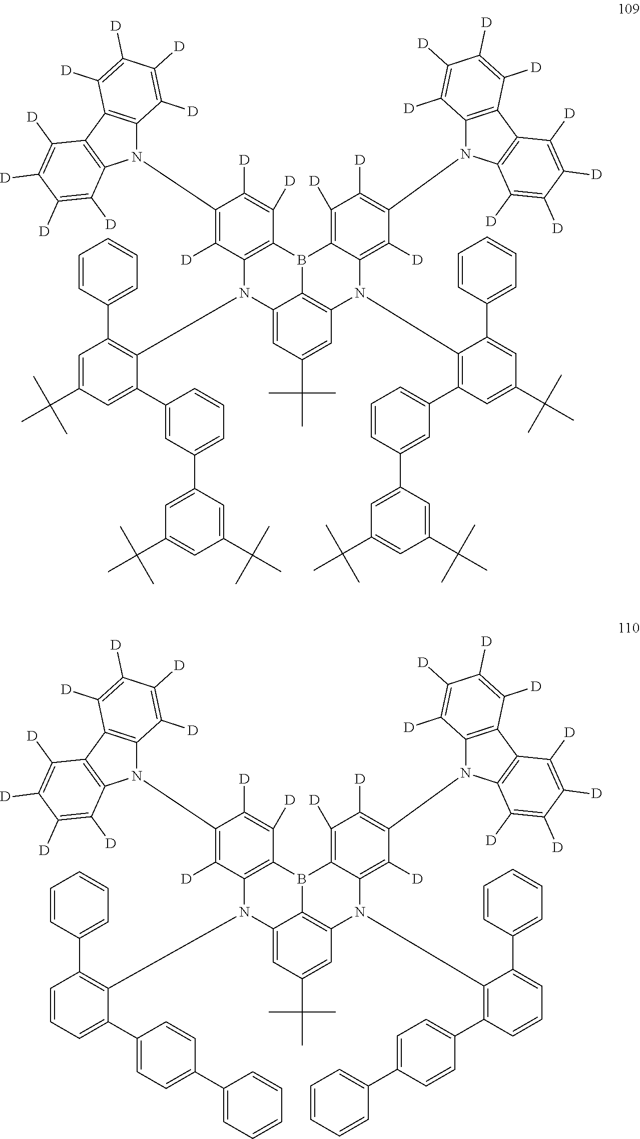 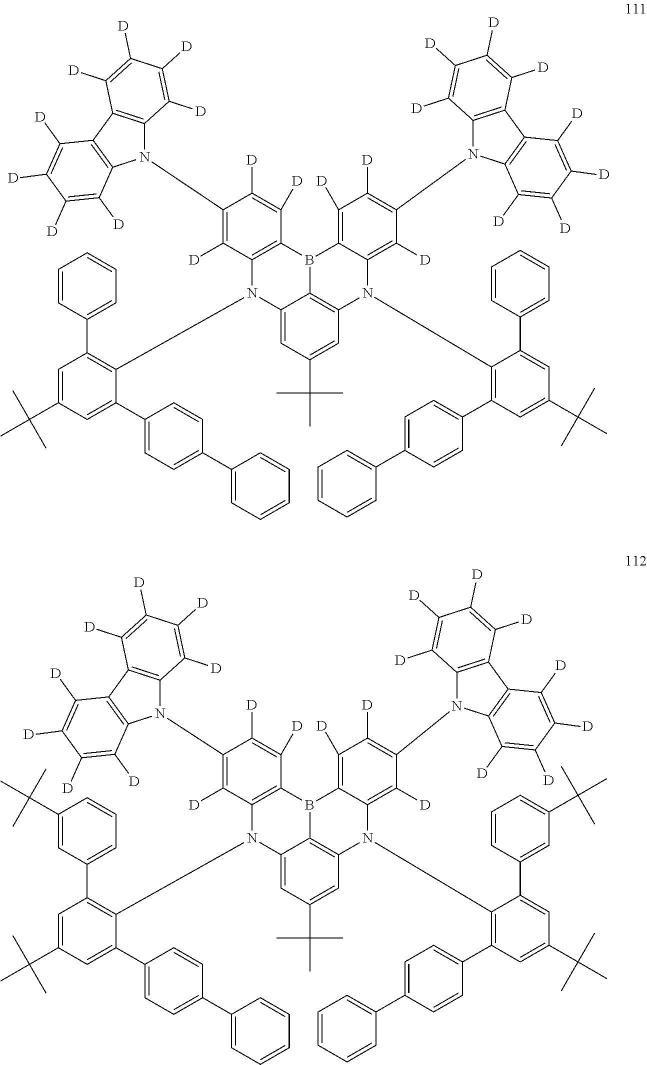 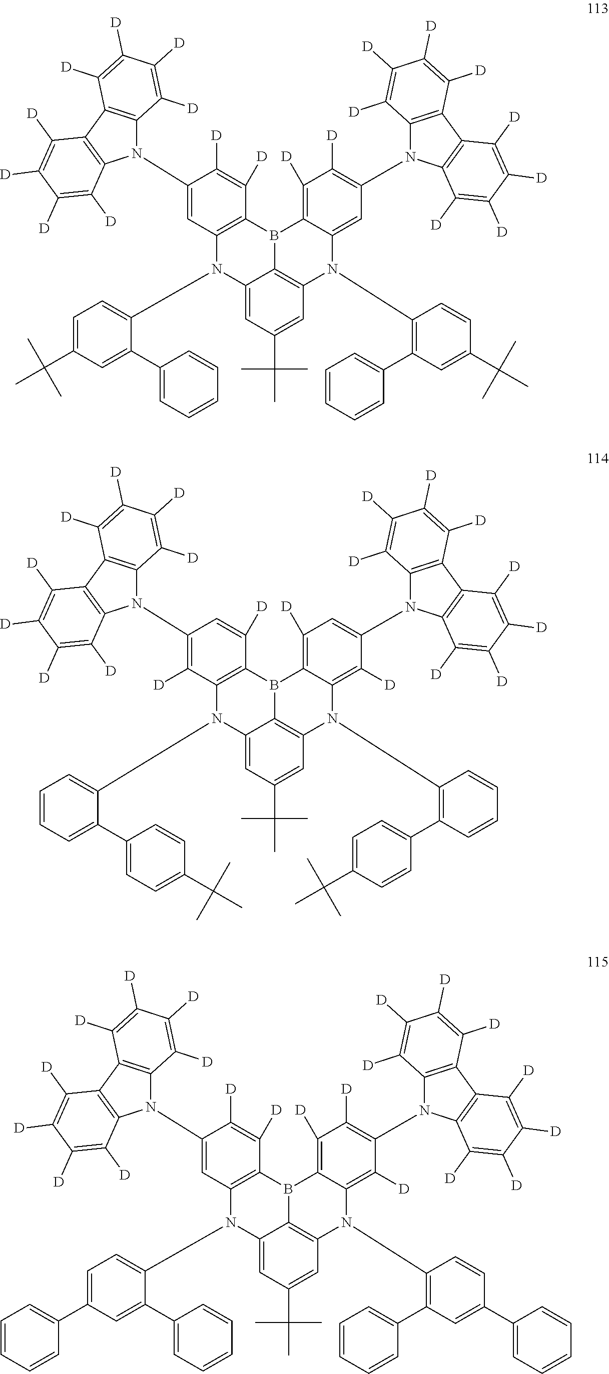 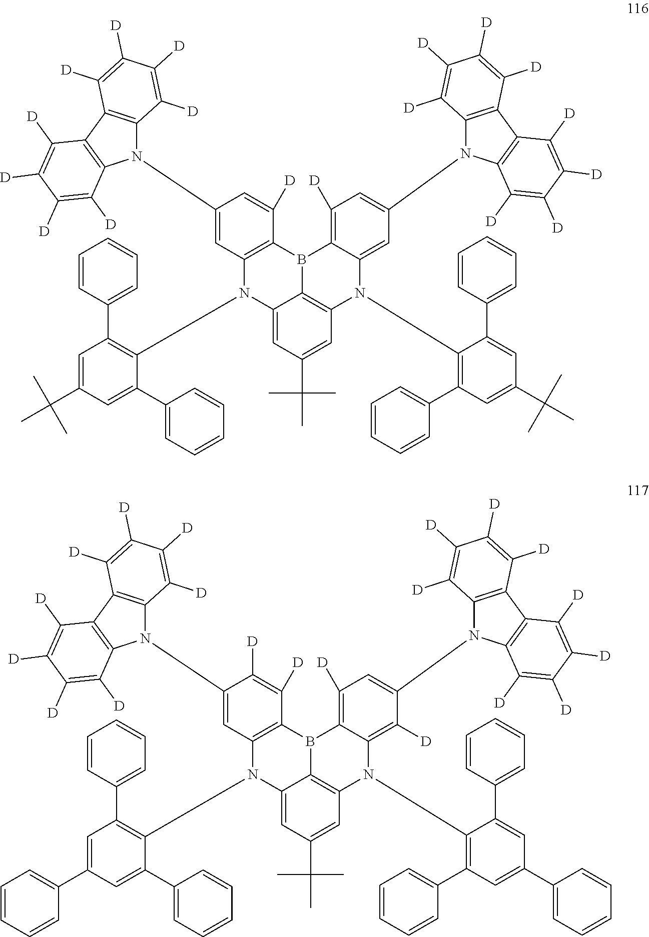 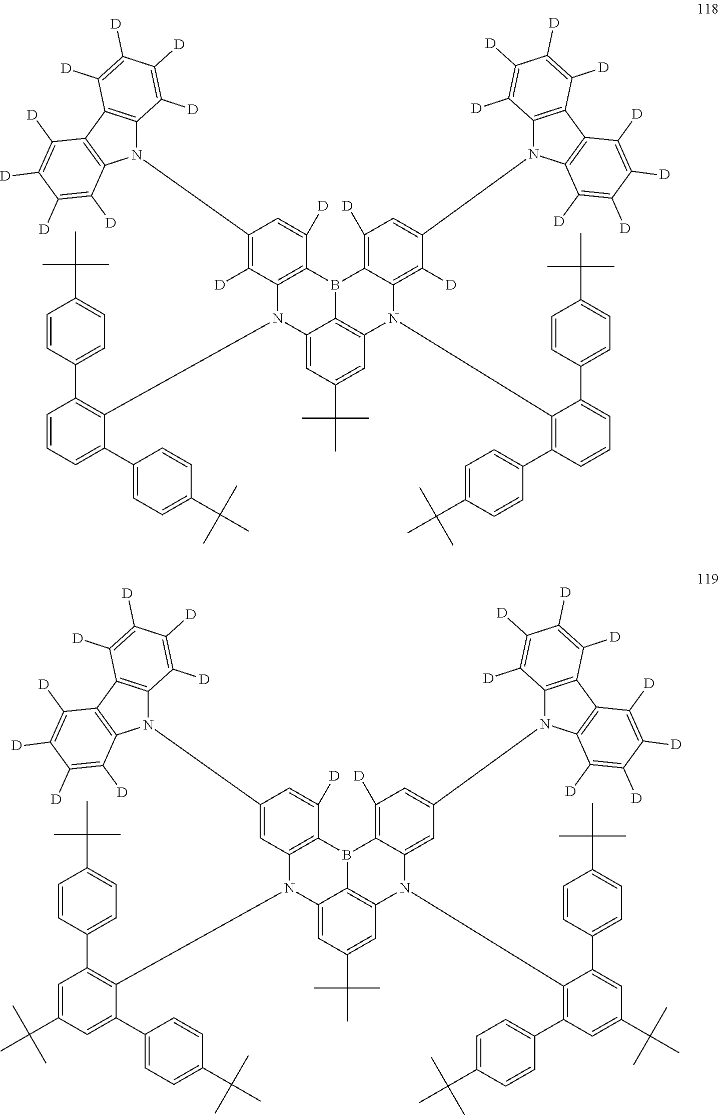 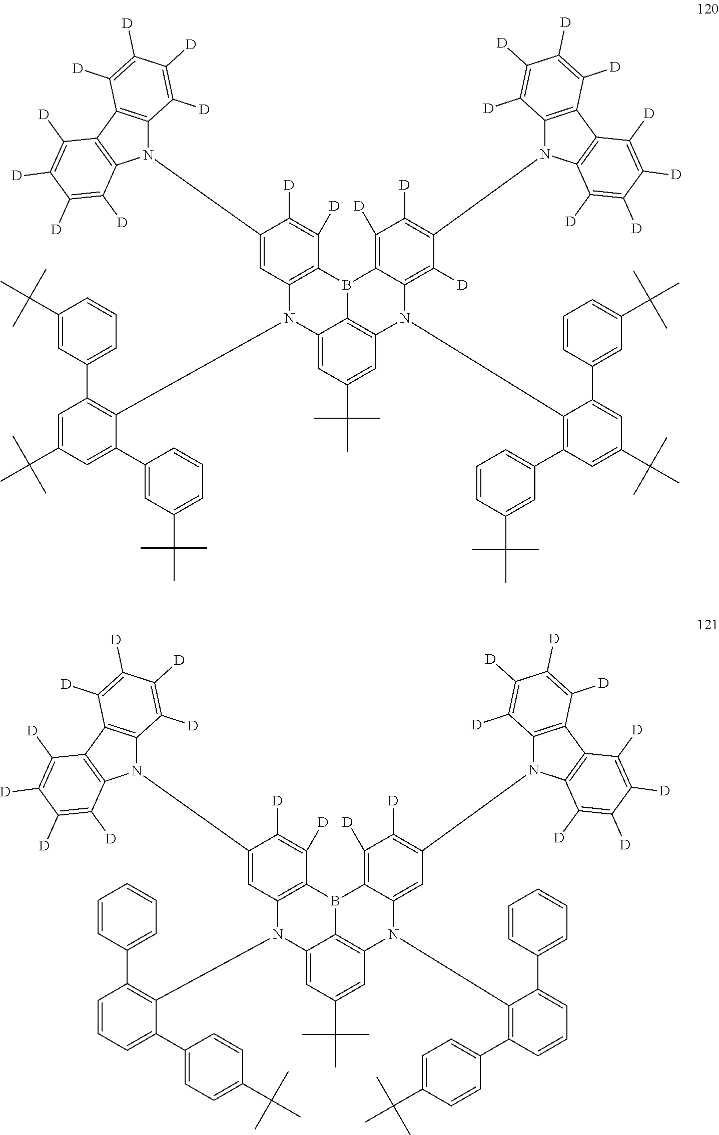 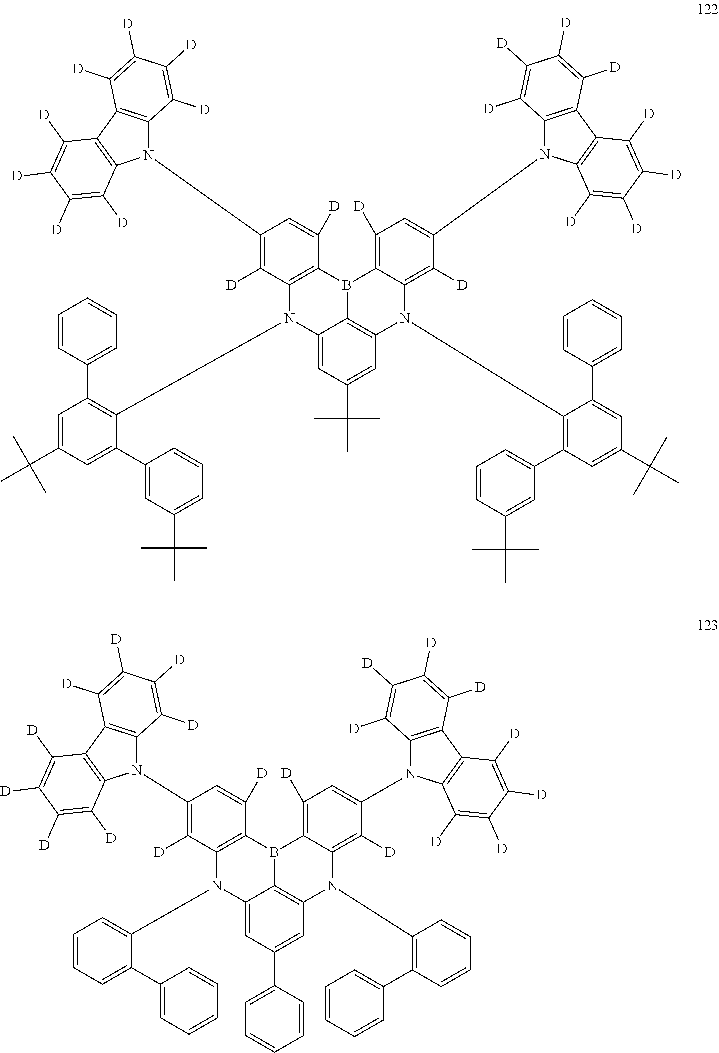 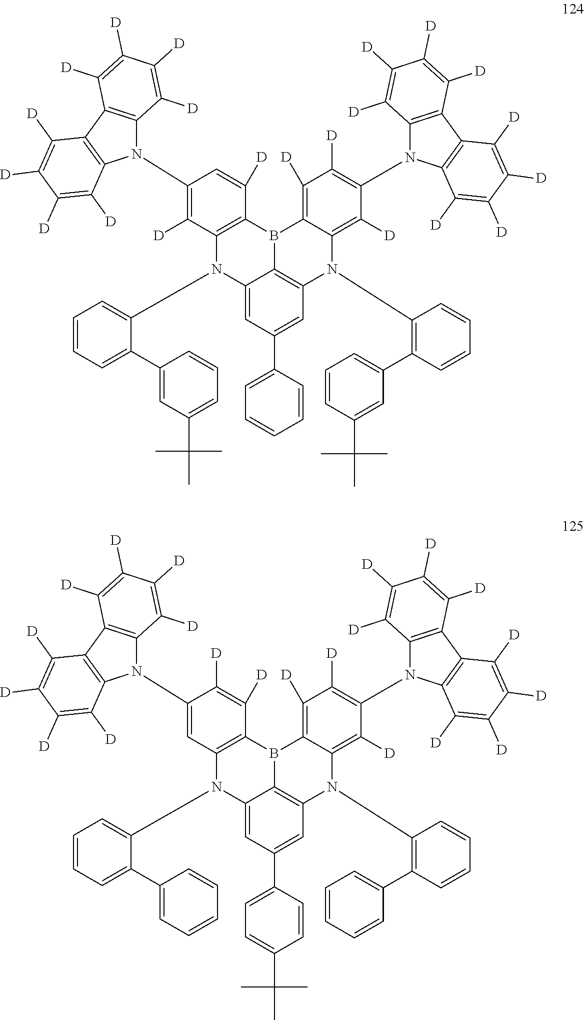 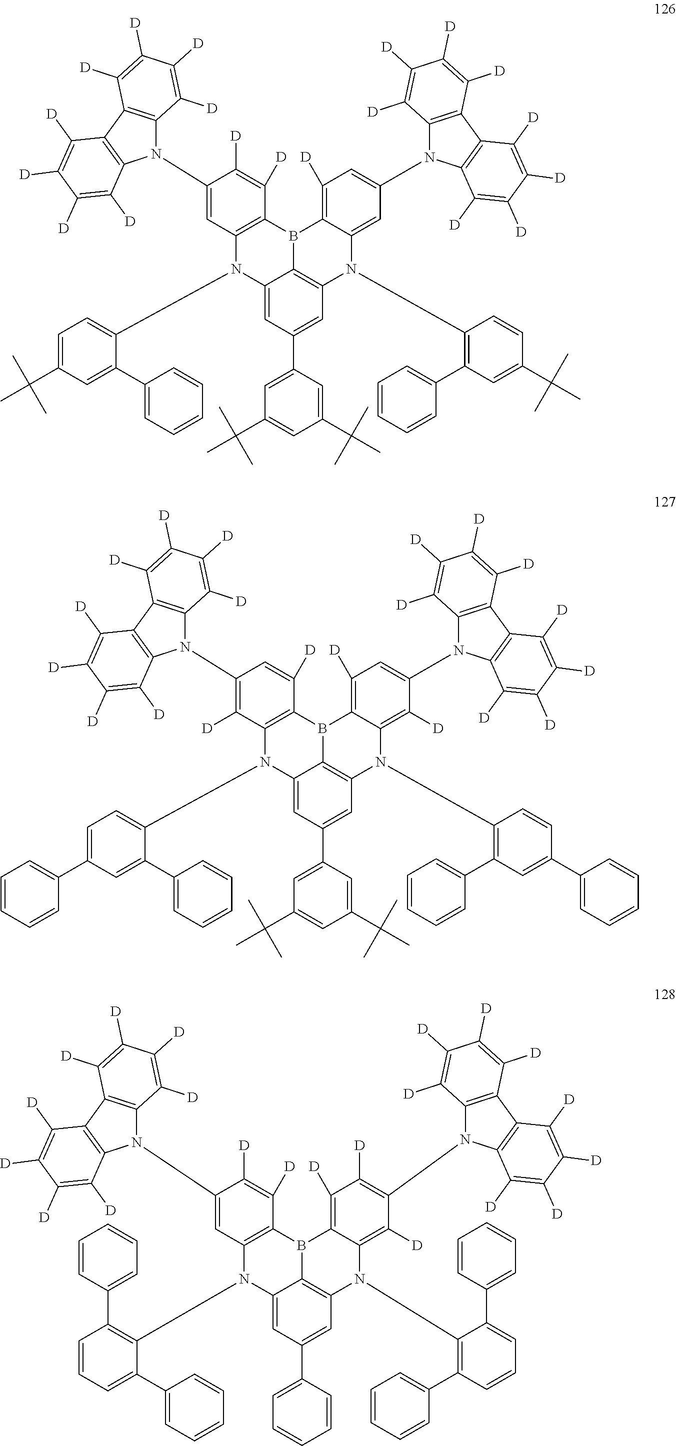 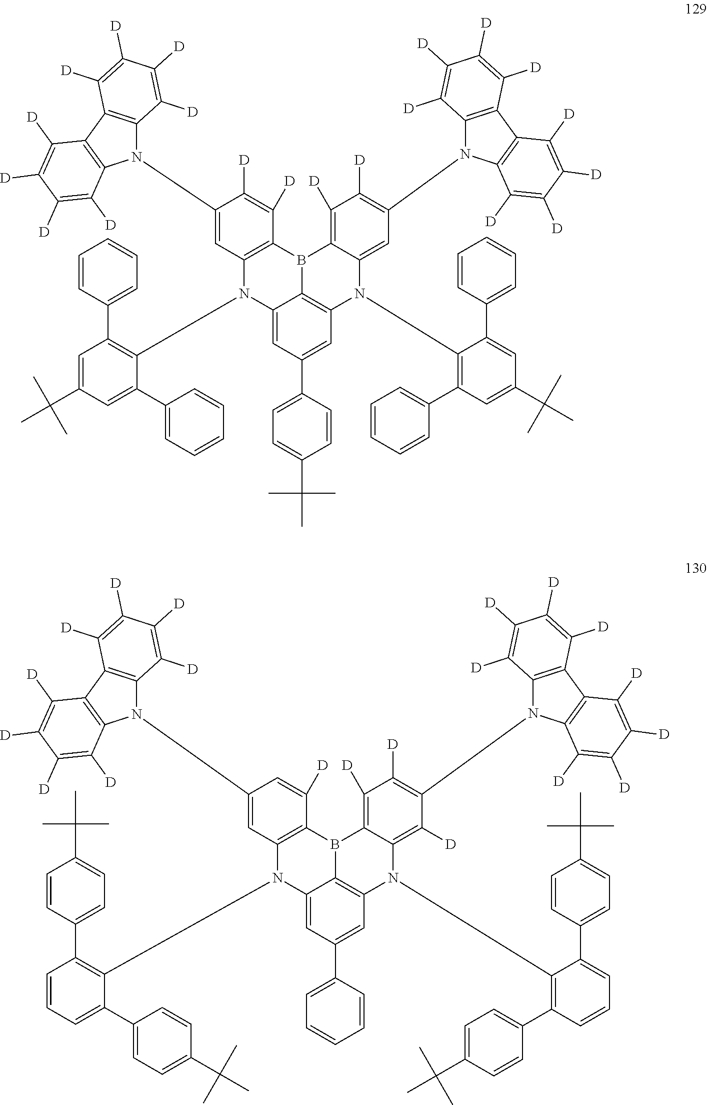 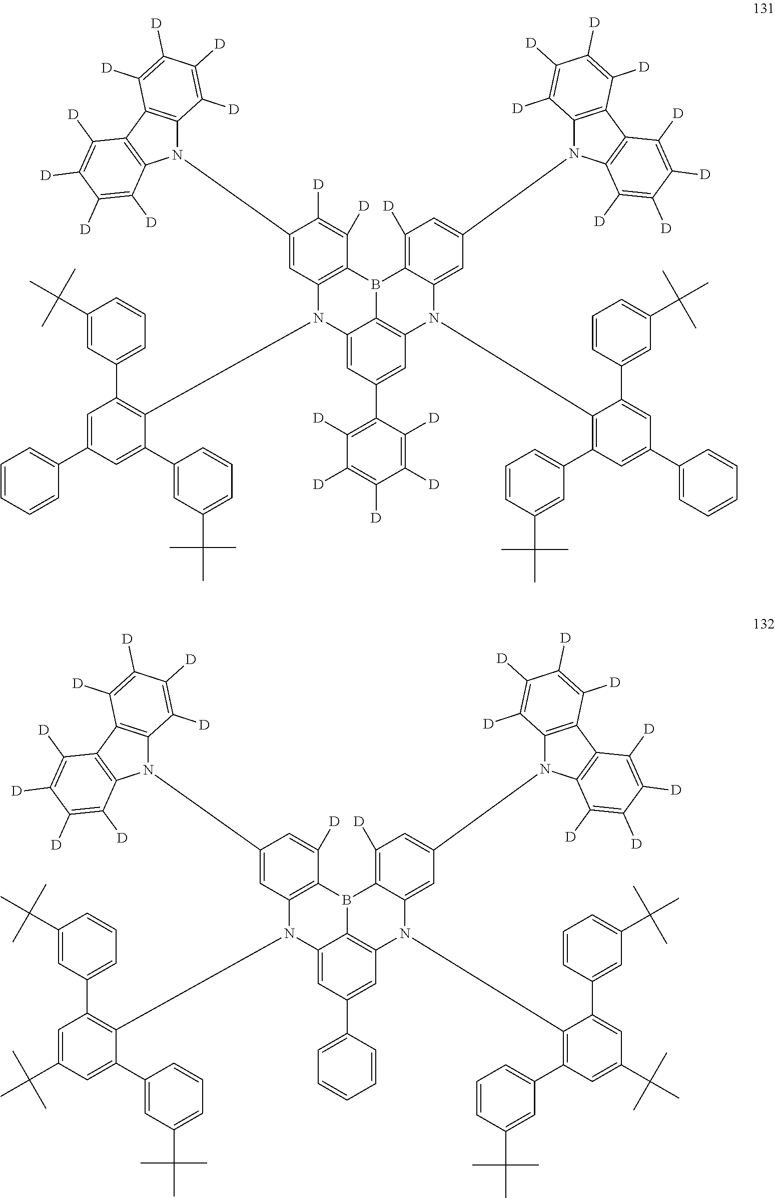 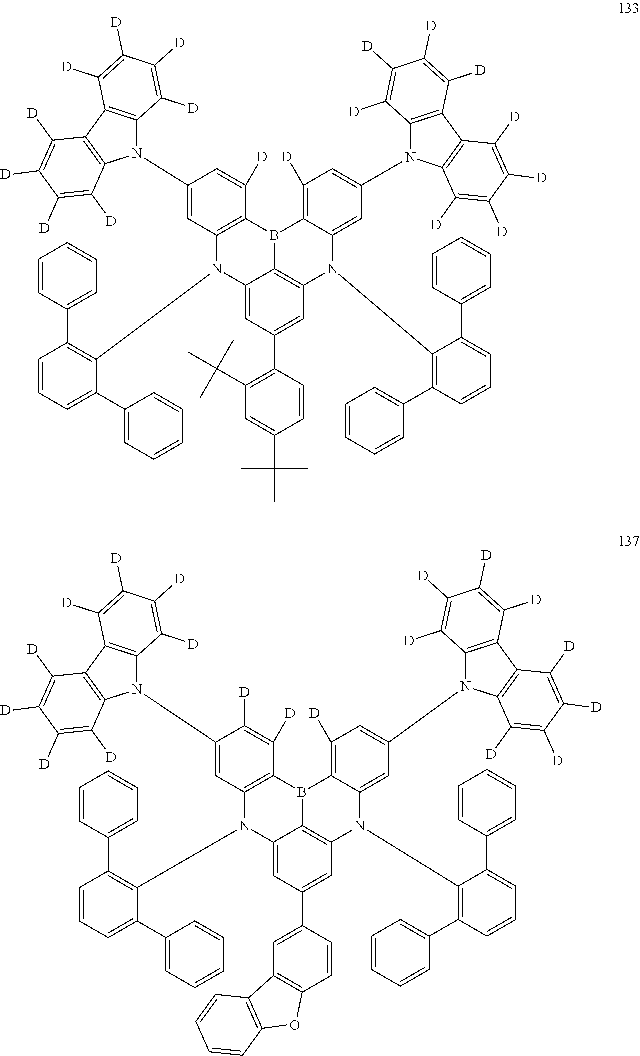 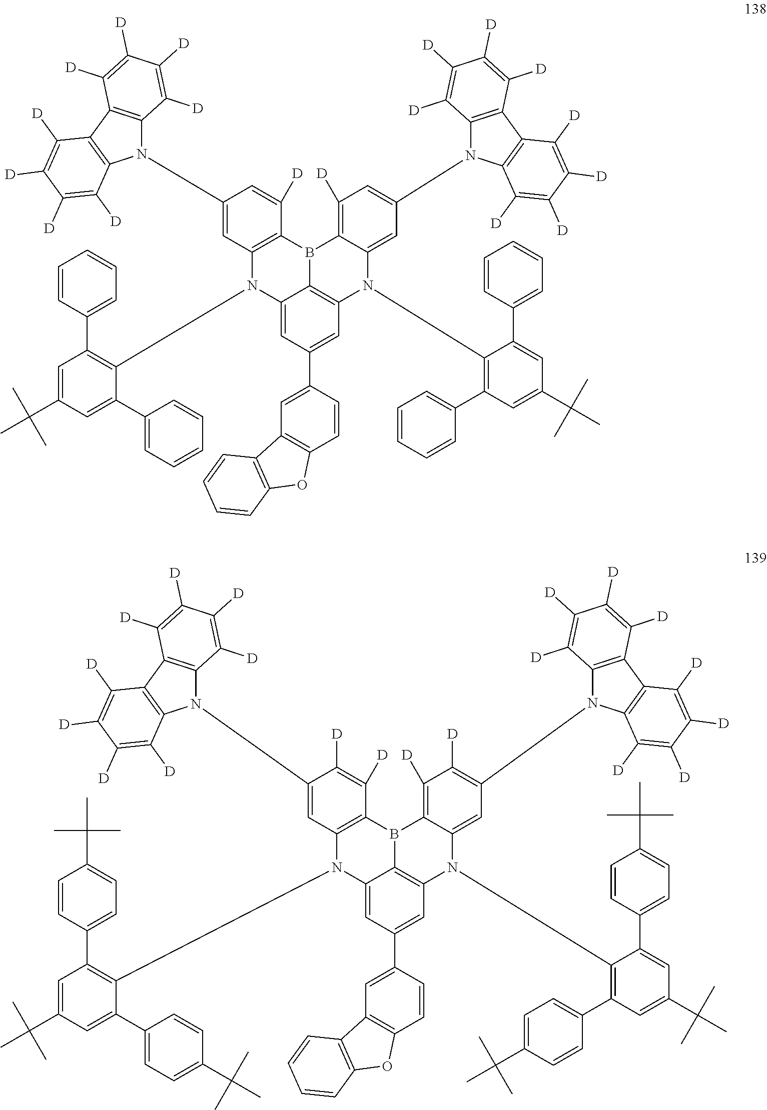 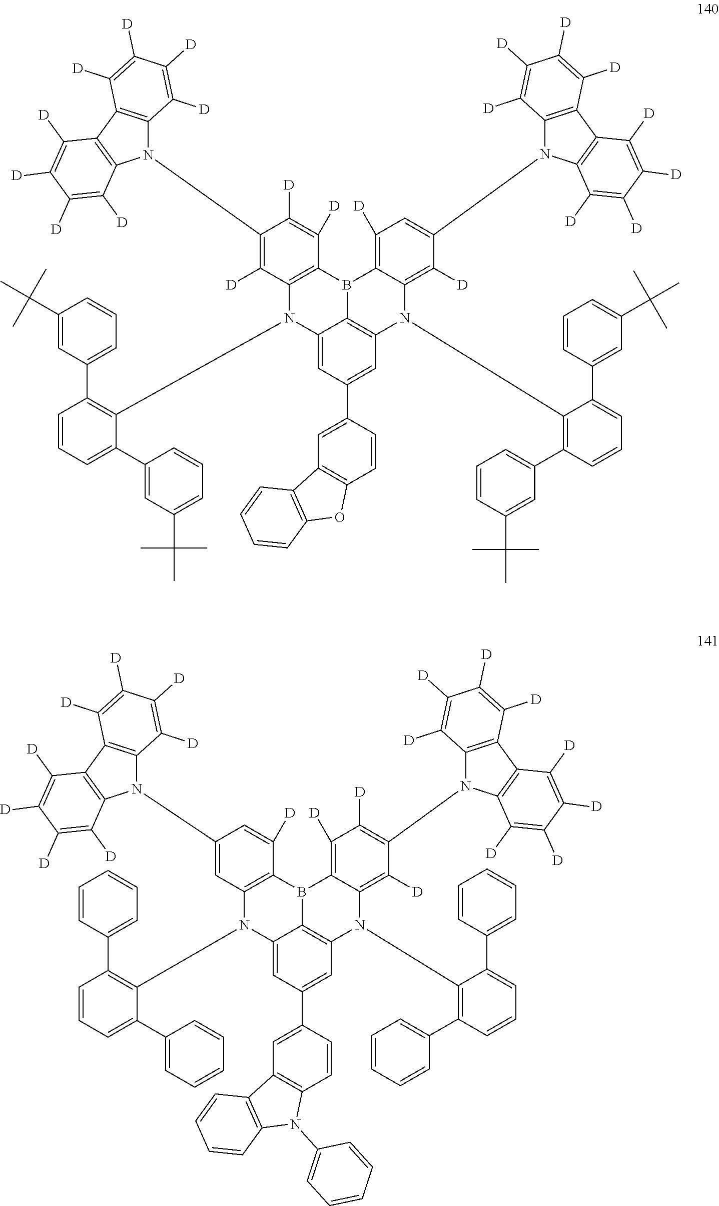 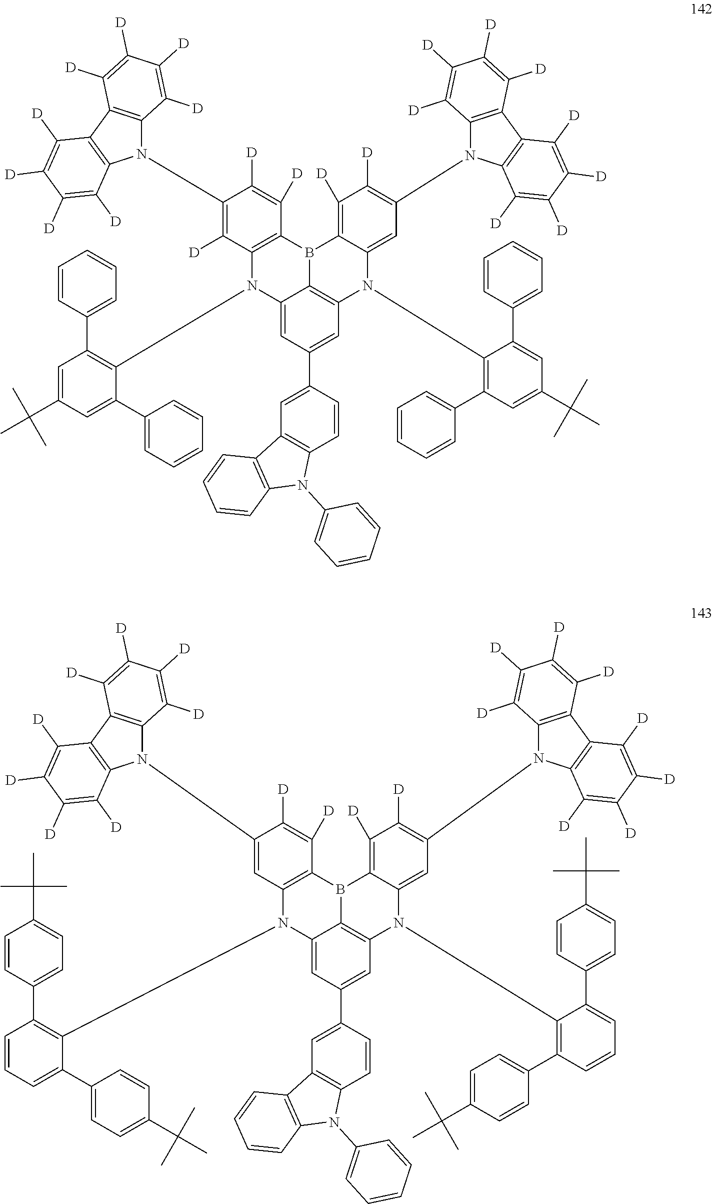 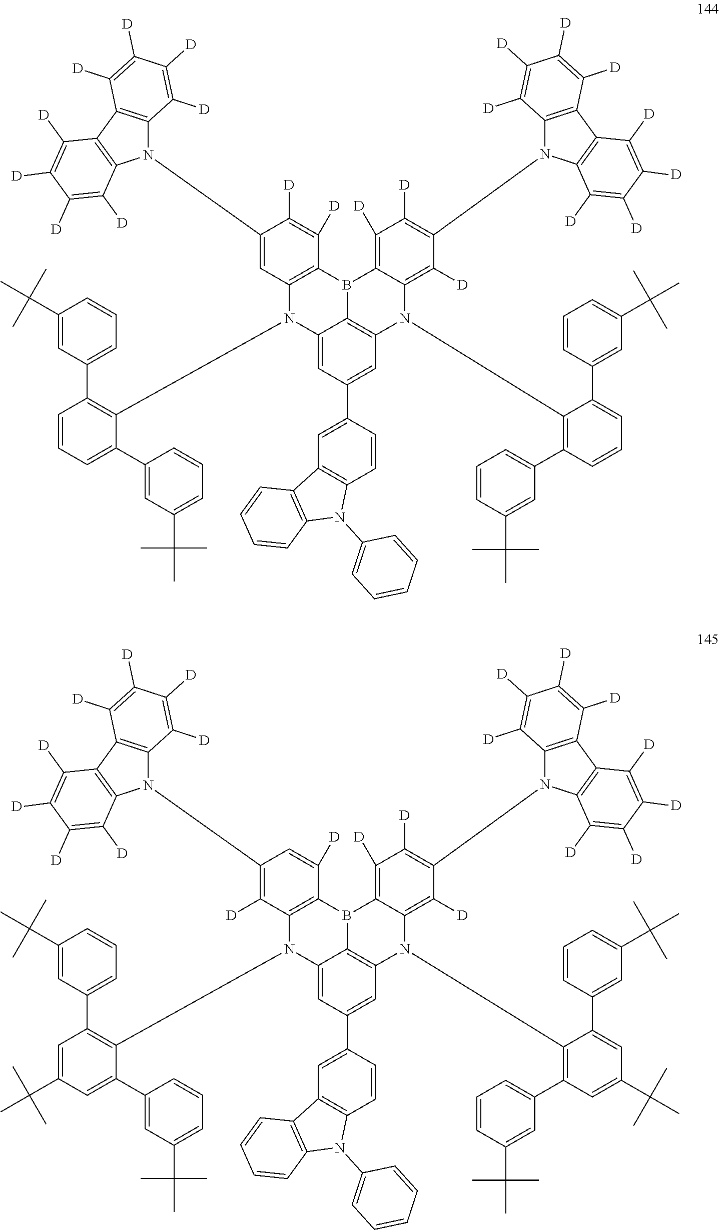 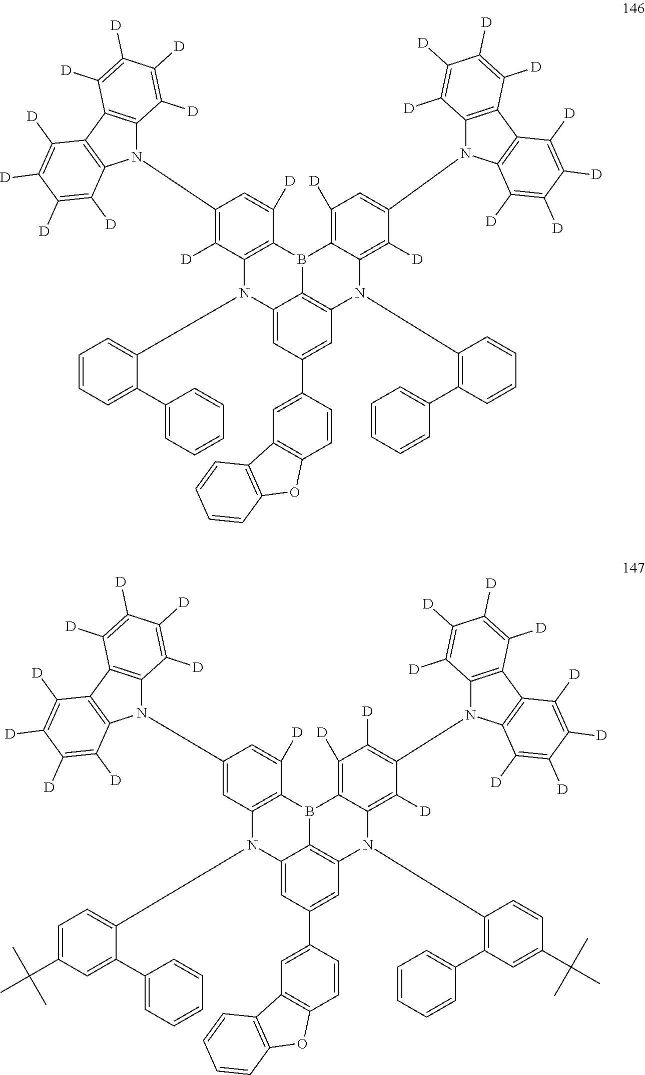 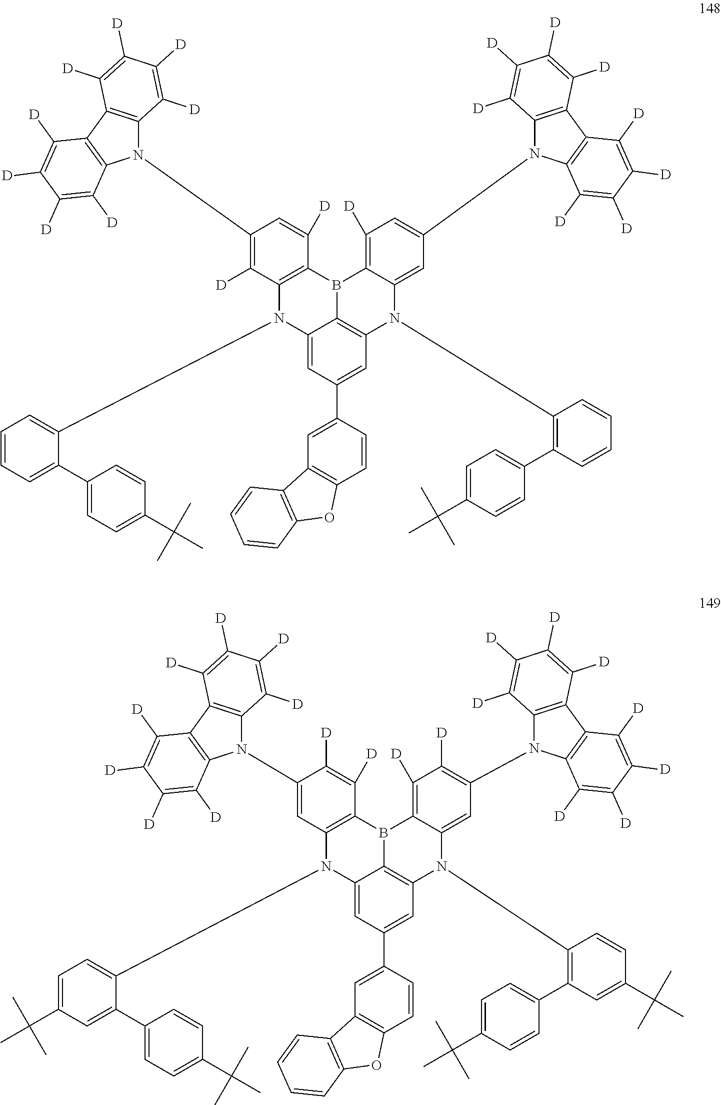 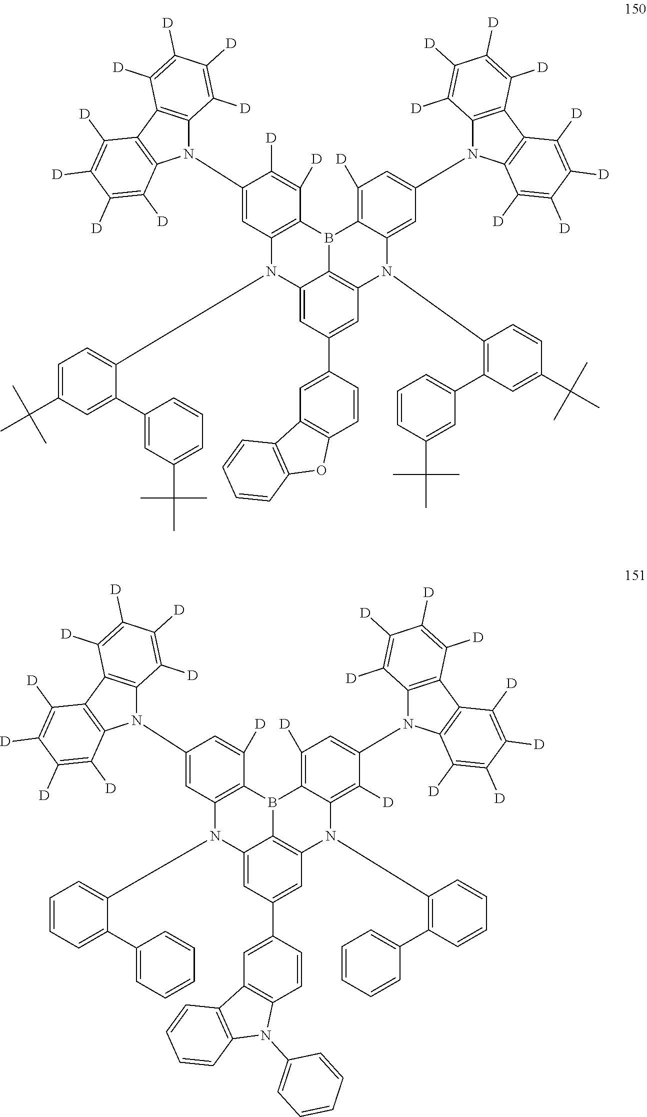 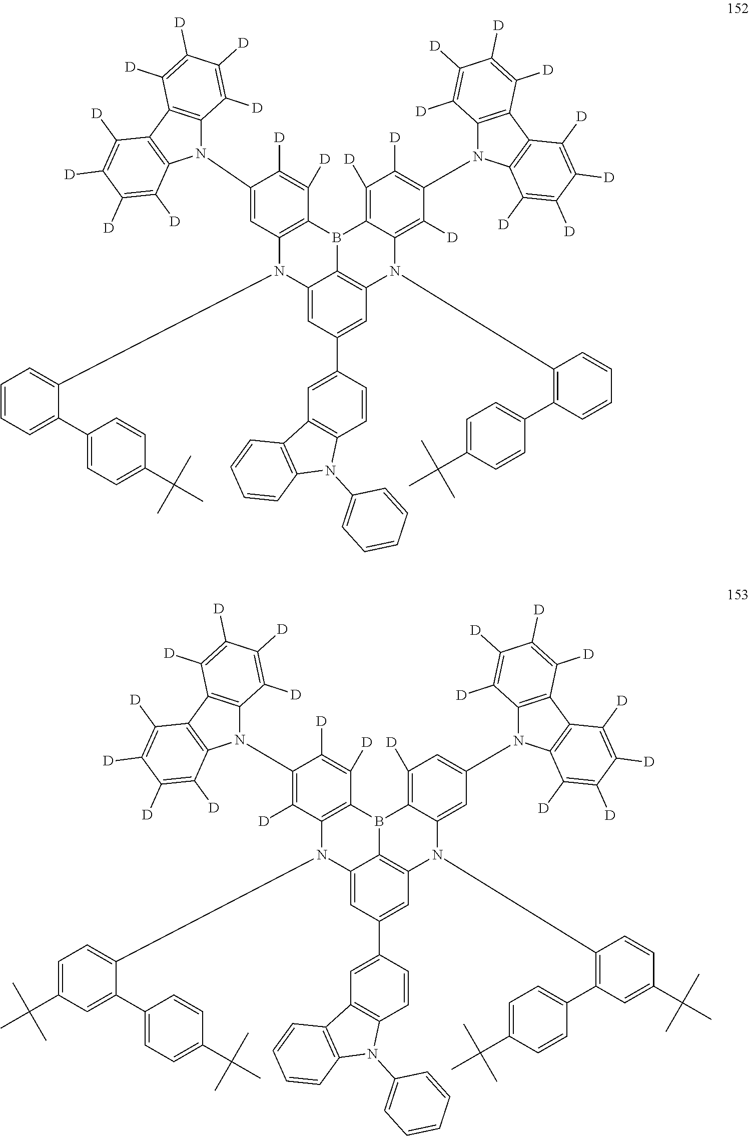 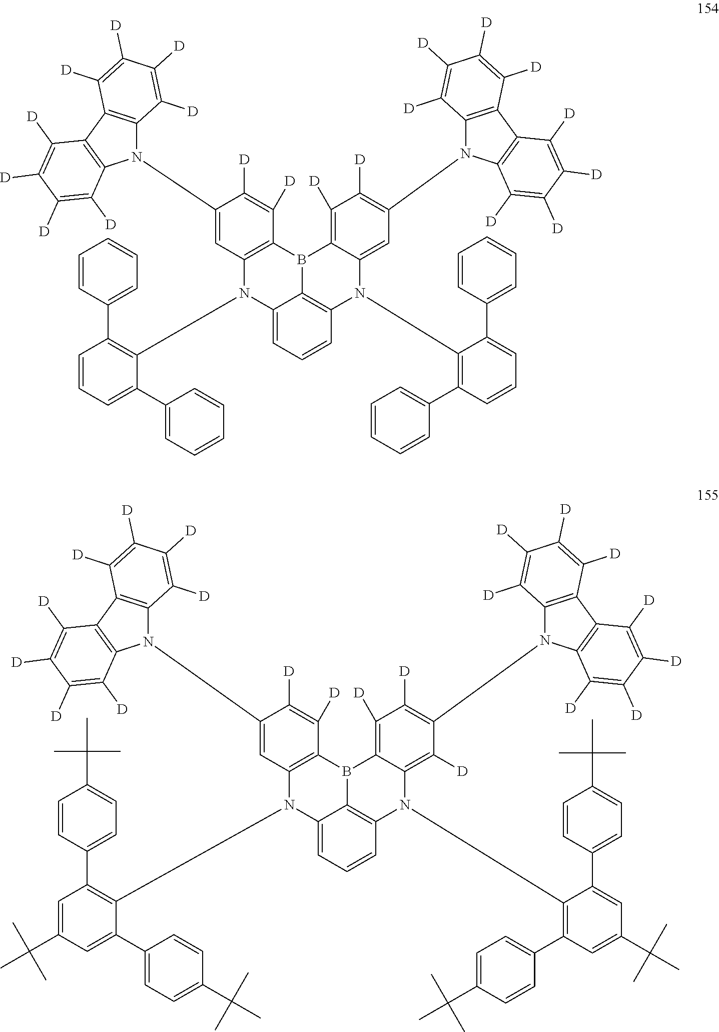 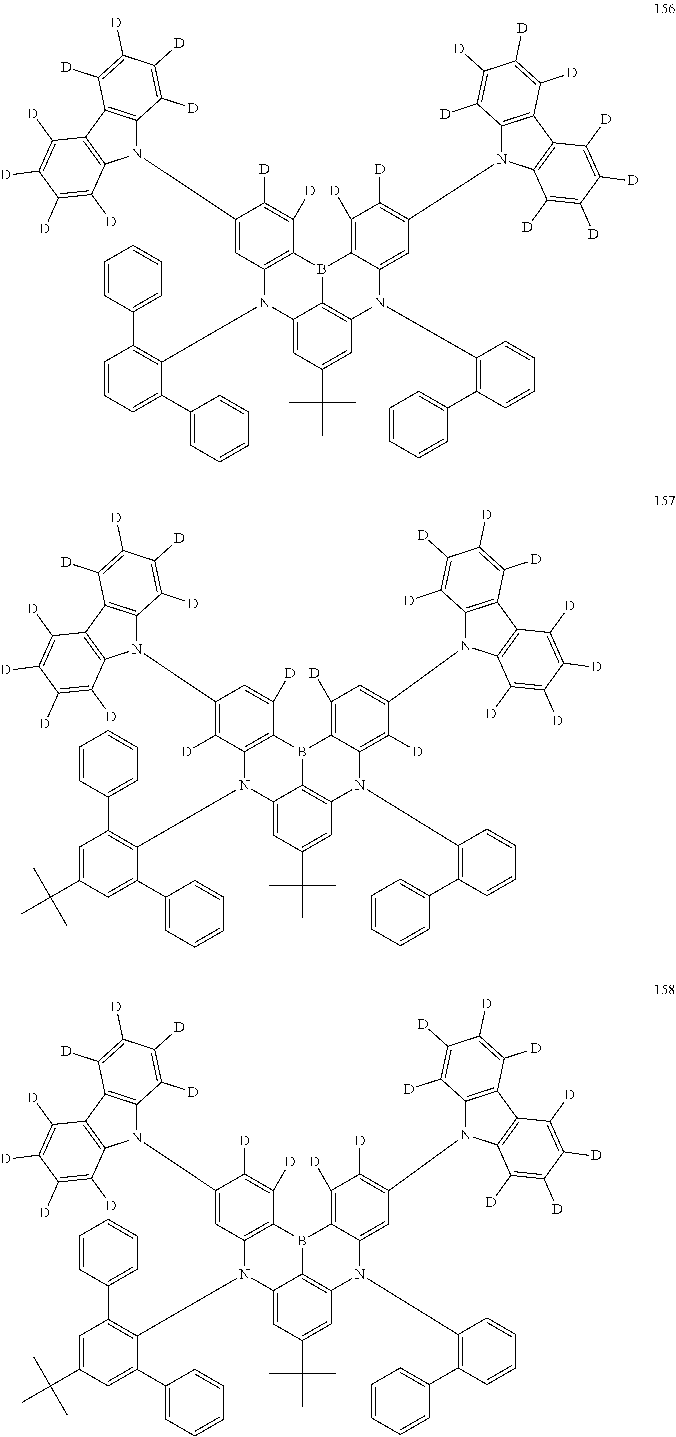 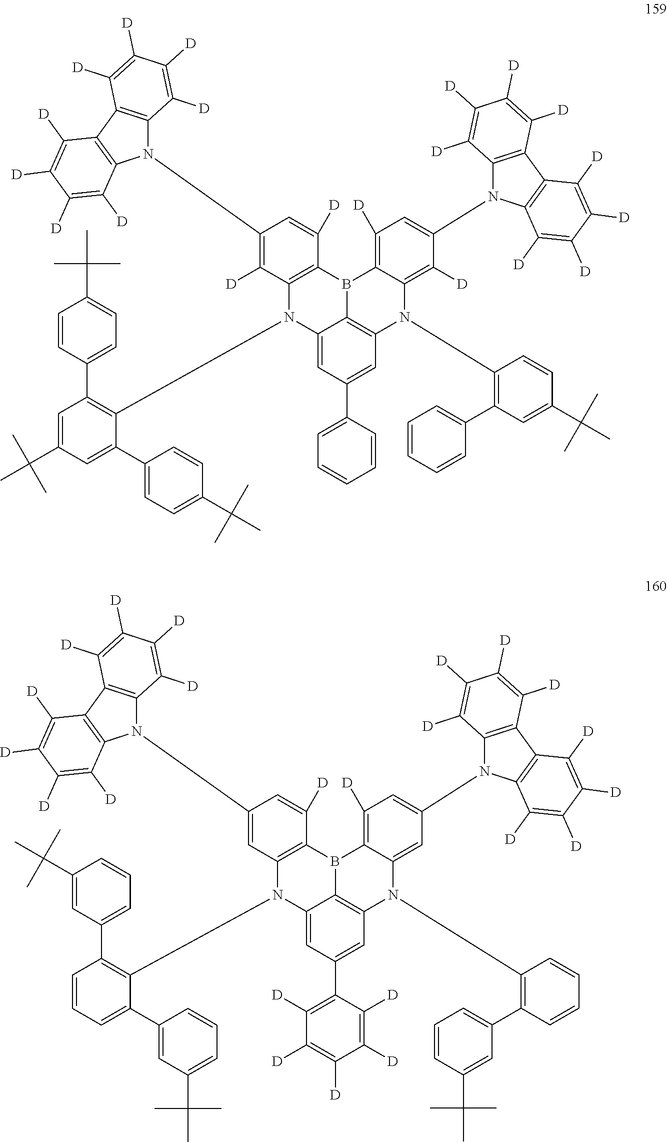 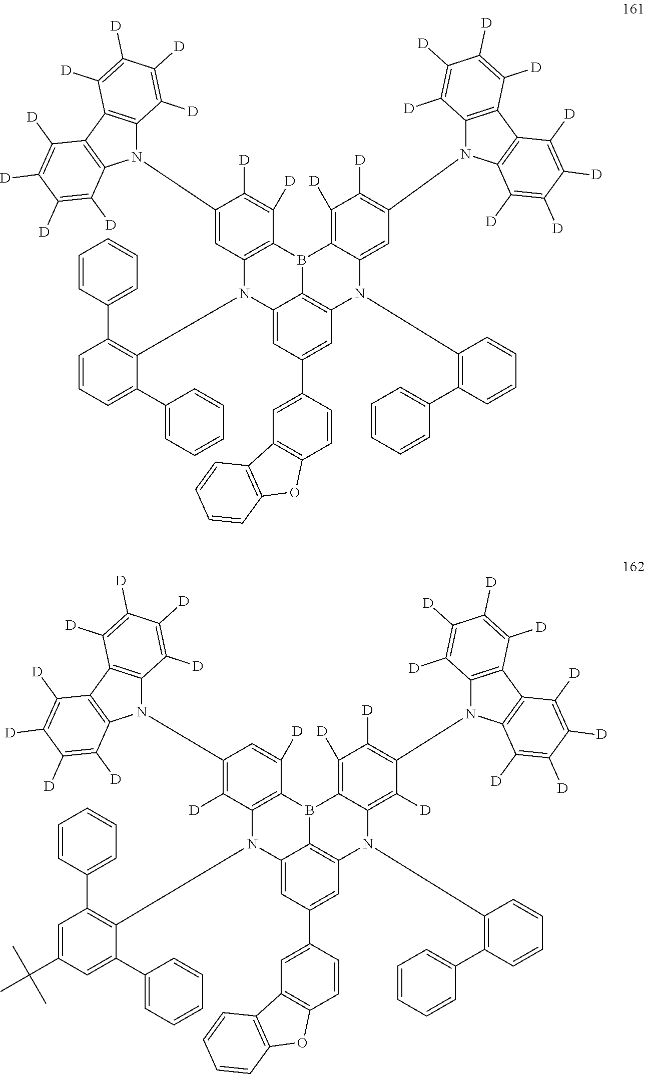 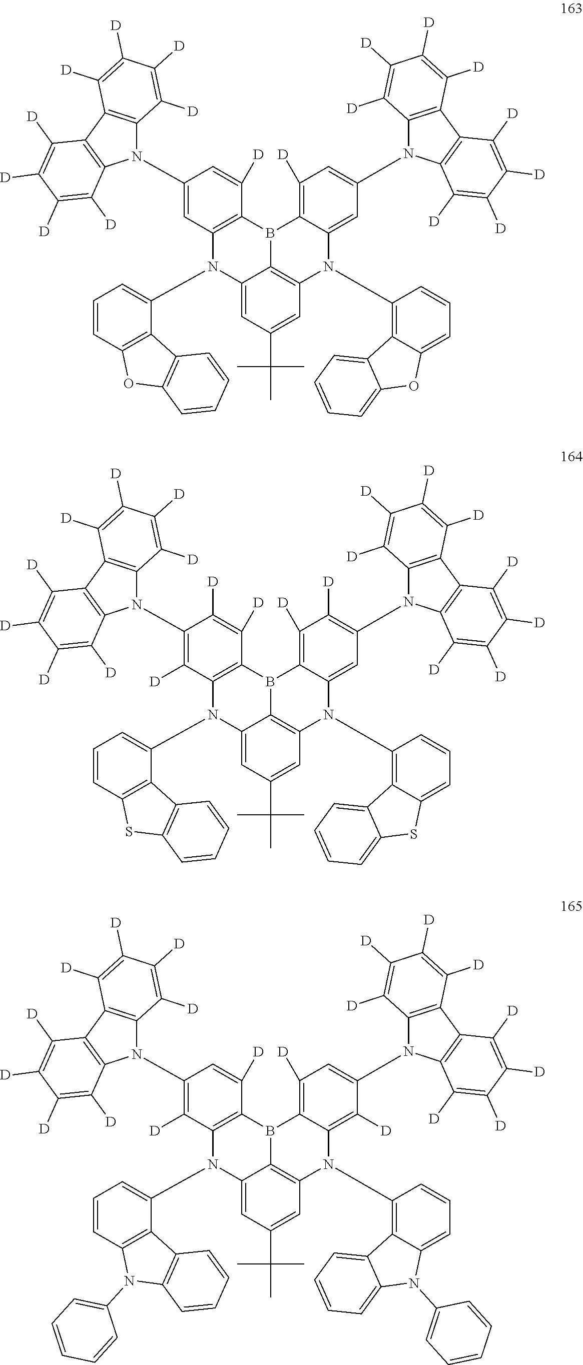 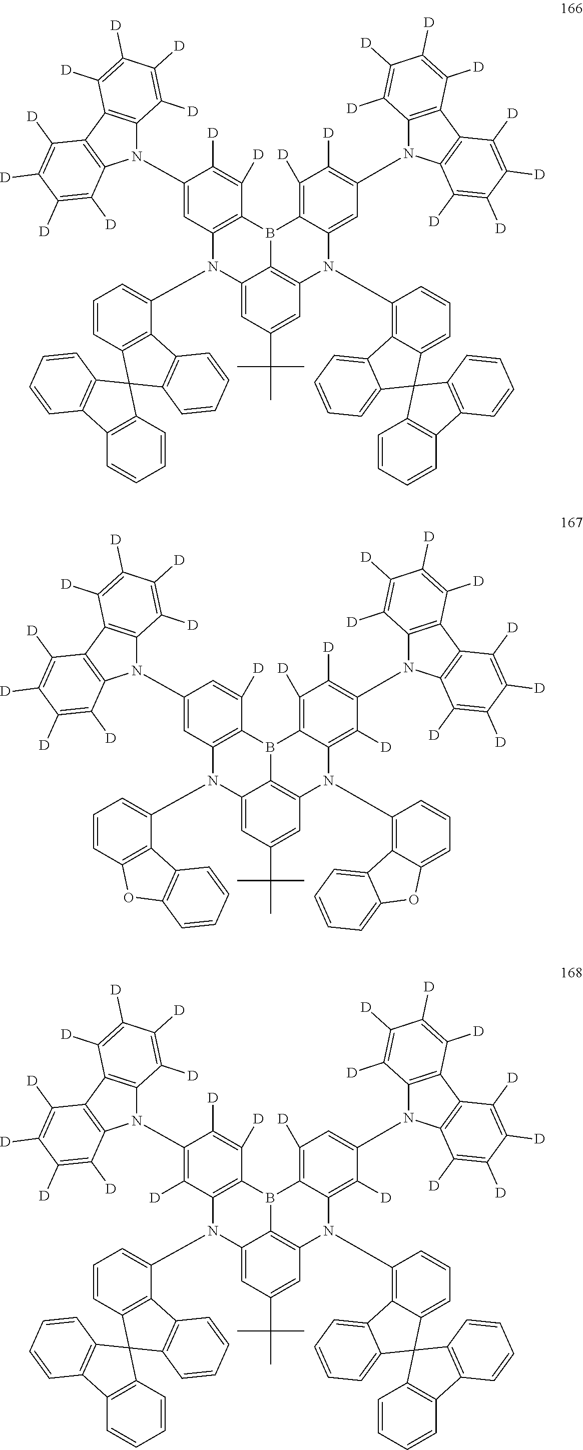 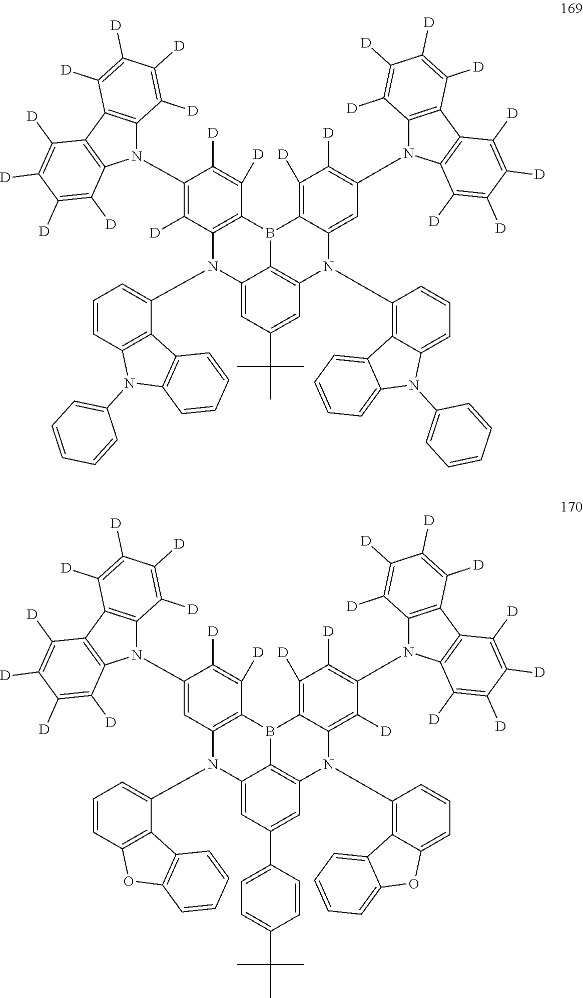 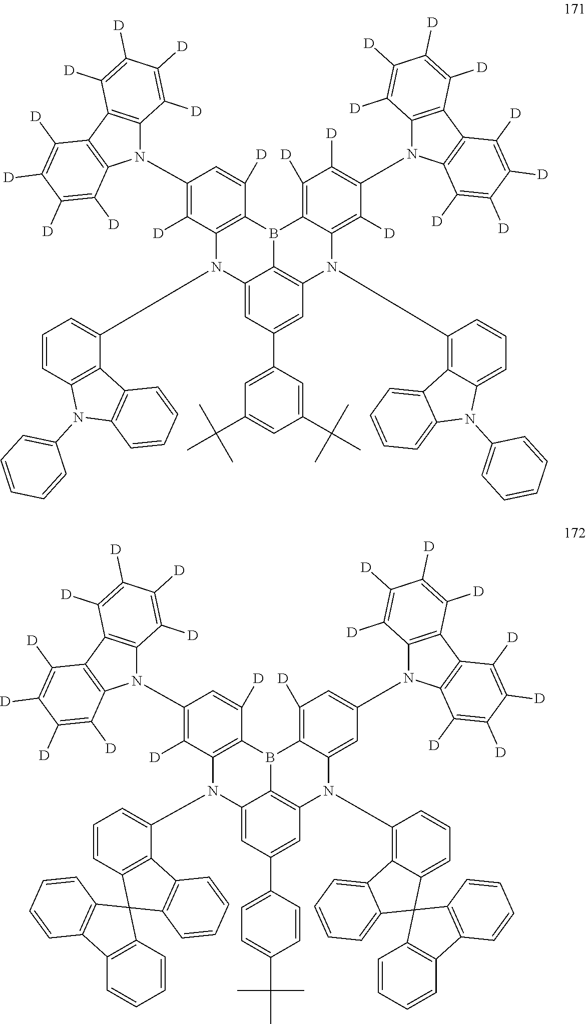 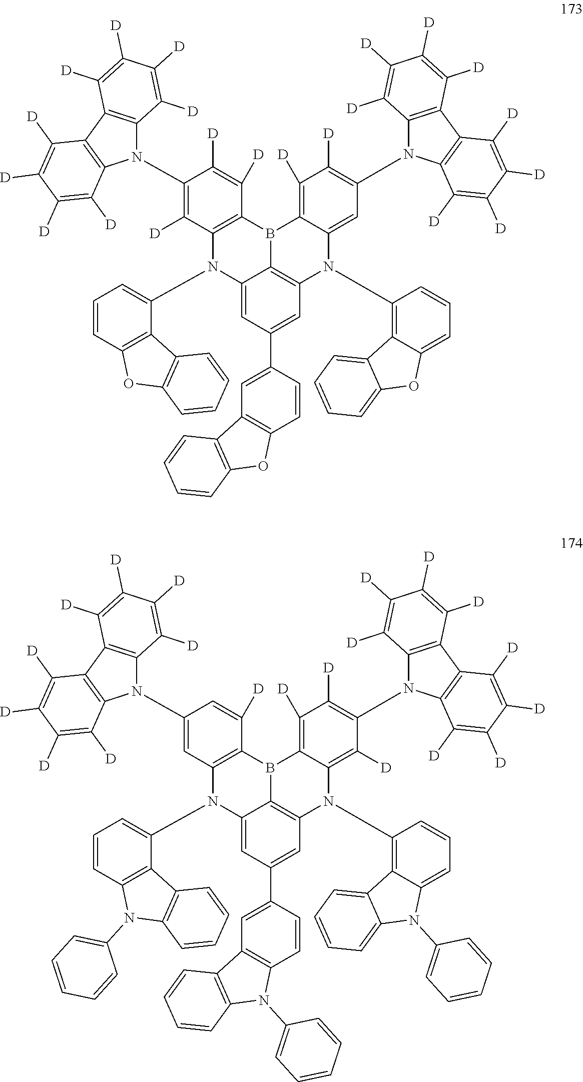 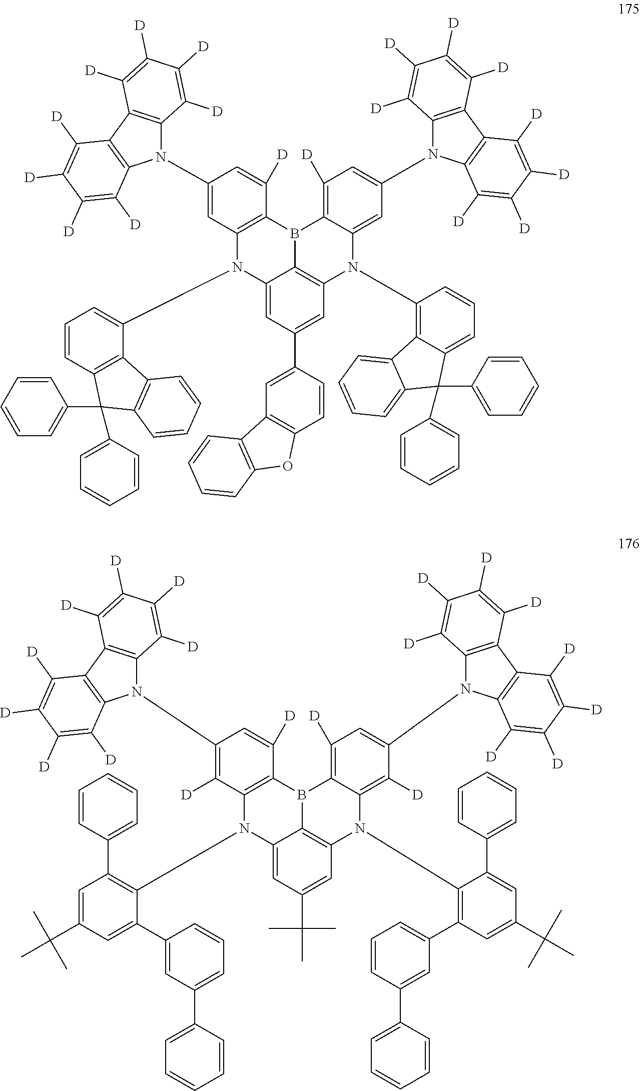 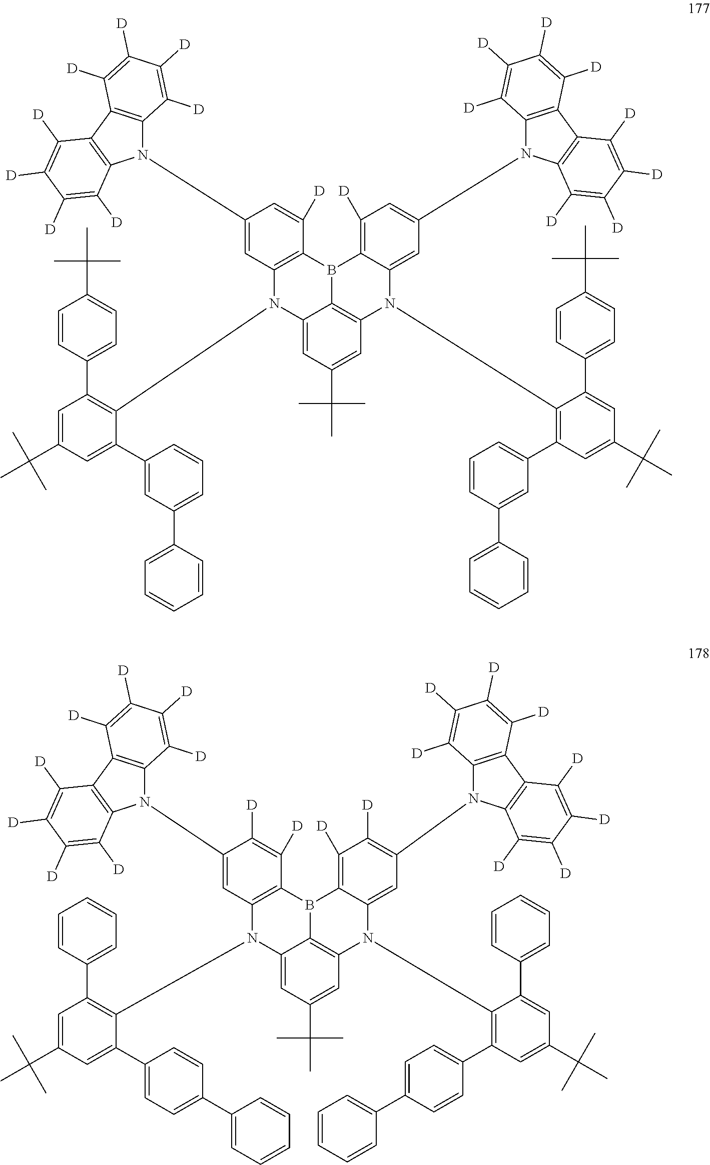
wherein in Compound Group 1,
D is a deuterium atom.

12. A light emitting element comprising:
a first electrode;
a second electrode disposed on the first electrode; and
at least one functional layer disposed between the first electrode and the second electrode, wherein
the at least one functional layer comprises a polycyclic compound represented by Formula 1: 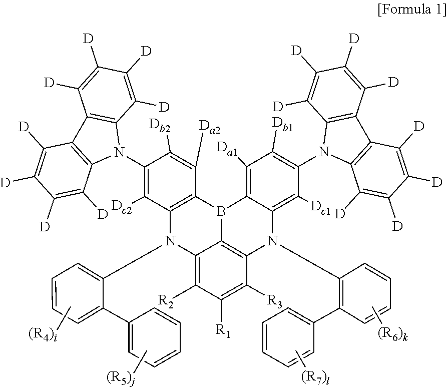
wherein in Formula 1,
D, Dₐ₁, and Dₐ₂ are each a deuterium atom,
D_{b1}, D_{b2}, D_{c1}, and D_{c2} are each independently a hydrogen atom or a deuterium atom,
R₁ to R₃ are each independently a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
R₄ to R₇ are each independently a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
i and k are each independently an integer from 0 to 4, and
j and l are each independently an integer from 0 to 5.

13. The light emitting element of claim 12, wherein
the at least one functional layer comprises:
a hole transport region disposed on the first electrode;
an emission layer disposed on the hole transport region; and
an electron transport region disposed on the emission layer, and
the emission layer comprises the polycyclic compound.

14. The light emitting element of claim 13, wherein the emission layer emits delayed fluorescence.

15. The light emitting element of claim 13, wherein
the emission layer comprises a host and a dopant, and
the dopant comprises the polycyclic compound.

16. The light emitting element of claim 12, wherein the at least one functional layer comprises a polycyclic compound represented by Formula 3: 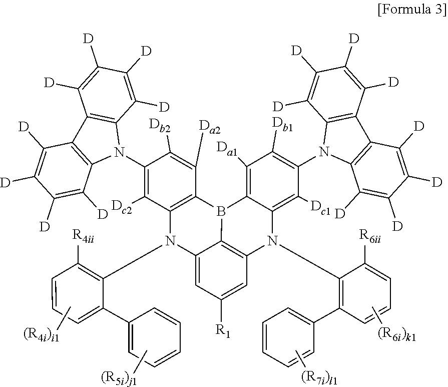
wherein in Formula 3,
R₄ᵢ, R₅ᵢ, R₆ᵢ, and R₇ᵢ are each independently a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
R₄ᵢᵢ and R₆ᵢᵢ are each independently a hydrogen atom, a deuterium atom, or a substituted or unsubstituted aryl group having 6 to 15 ring-forming carbon atoms,
i1 and k1 are each independently an integer from 0 to 3,
j1 and l1 are each independently an integer from 0 to 5, and
R₁, D, Dₐ₁, Dₐ₂, D_{b1}, D_{b2}, D_{c1}, and D_{c2} are the same as defined in Formula 1.

17. A polycyclic compound represented by Formula 1: 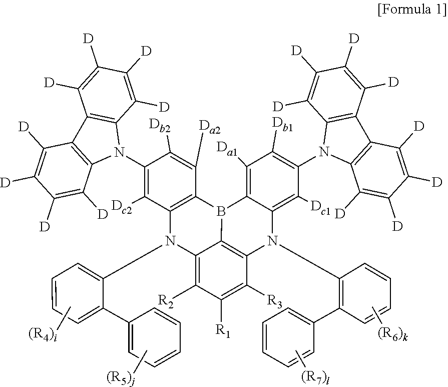
wherein in Formula 1,
D, Dₐ₁, and Dₐ₂ are each a deuterium atom,
D_{b1}, D_{b2}, D_{c1}, and D_{c2} are each independently a hydrogen atom or a deuterium atom,
R₁ to R₃ are each independently a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
R₄ to R₇ are each independently a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
i and k are each independently an integer from 0 to 4, and
j and l are each independently an integer from 0 to 5.

18. The polycyclic compound of claim 17, wherein Formula 1 is represented by Formula 2: 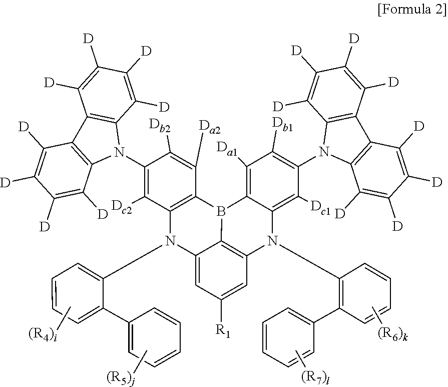
wherein in Formula 2,
D, Dₐ₁, Dₐ₂, D_{b1}, D_{b2}, D_{c1}, D_{c2}, R₁, R₄ to R₇, and i to 1 are the same as defined in Formula 1.

19. The polycyclic compound of claim 17, wherein Formula 1 is represented by Formula 3: 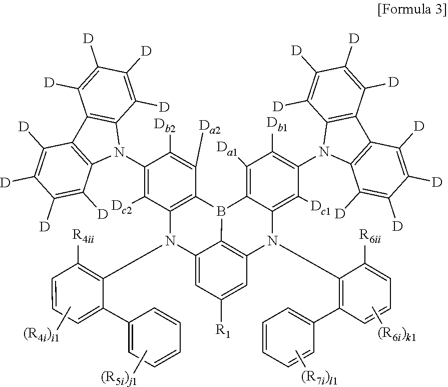
wherein in Formula 3,
R₄ᵢ, R₅ᵢ, R₆ᵢ, and R₇ᵢ are each independently a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
R₄ᵢᵢ and R₆ᵢᵢ are each independently a hydrogen atom, a deuterium atom, or a substituted or unsubstituted aryl group having 6 to 15 ring-forming carbon atoms,
i1 and k1 are each independently an integer from 0 to 3,
j1 and l1 are each independently an integer from 0 to 5, and
R₁, D, Dₐ₁, Dₐ₂, D_{b1}, D_{b2}, D_{c1}, and D_{c2} are the same as defined in Formula 1.

20. The polycyclic compound of claim 17, wherein Formula 1 is represented by Formula 4-1 or Formula 4-2: 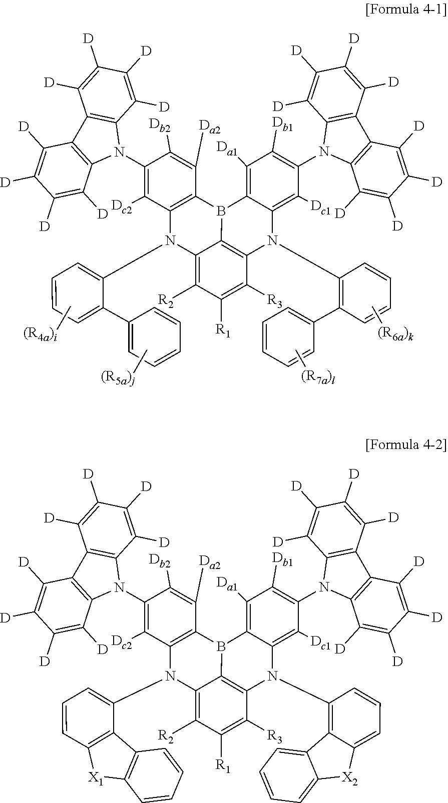
wherein in Formula 4-1,
R₄ₐ to R₇ₐ are each independently a hydrogen atom, a deuterium atom, a substituted or unsubstituted alkyl group having 1 to 10 carbon atoms, a substituted or unsubstituted aryl group having 6 to 15 ring-forming carbon atoms, or a substituted or unsubstituted heteroaryl group having 2 to 15 ring-forming carbon atoms,
wherein in Formula 4-2,
X₁ and X₂ are each independently O, S, C(Rₐ)(R_{b}), or N(R_{c}), and
Rₐ to R_{c} are each independently a hydrogen atom, a deuterium atom, or a substituted or unsubstituted aryl group having 6 to 15 ring-forming carbon atoms, or are bonded to an adjacent group to form a ring, and
wherein in Formula 4-1 and Formula 4-2,
D, Dₐ₁, Dₐ₂, D_{b1}, D_{b2}, D_{c1}, D_{c2}, R₁ to R₃, and i to 1 are the same as defined in Formula 1.

21. The polycyclic compound of claim 20, wherein Formula 4-1 is represented by Formula 4-1a: 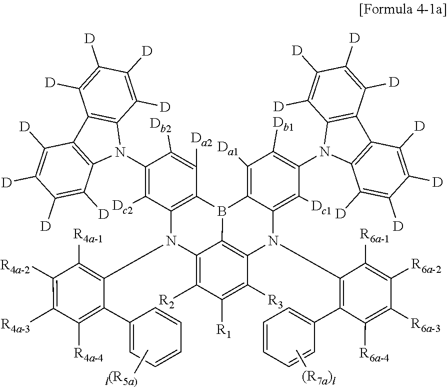
wherein in Formula 4-1a,
R₄ₐ₋₁ and R₆ₐ₋₁ are each independently a hydrogen atom, a deuterium atom, a substituted or unsubstituted phenyl group,
R₄ₐ₋₂ to R₄ₐ₋₄ and R₆ₐ₋₂ to R₆ₐ₋₄ are each independently a hydrogen atom, a deuterium atom, a substituted or unsubstituted alkyl group having 1 to 10 carbon atoms, or a substituted or unsubstituted aryl group having 6 to 15 ring-forming carbon atoms,
D, Dₐ₁, Dₐ₂, D_{b1}, D_{b2}, D_{c1}, D_{c2}, R₁ to R₃, j, and 1 are the same as defined in Formula 1, and
R₅ₐ and R₇ₐ are the same as defined in Formula 4-1.

22. The polycyclic compound of claim 17, wherein R₁ to R₃ are each independently a hydrogen atom, a deuterium atom, a substituted or unsubstituted t-butyl group, a substituted or unsubstituted phenyl group, a substituted or unsubstituted dibenzofuran group, or a substituted or unsubstituted carbazole group.

23. The polycyclic compound of claim 17, wherein R₄ to R₇ are each independently a hydrogen atom, a deuterium atom, a substituted or unsubstituted t-butyl group, or a substituted or unsubstituted phenyl group, or are bonded to an adjacent group to form a ring.

24. The polycyclic compound of claim 17, wherein the polycyclic compound represented by Formula 1 is selected from Compound Group 1: 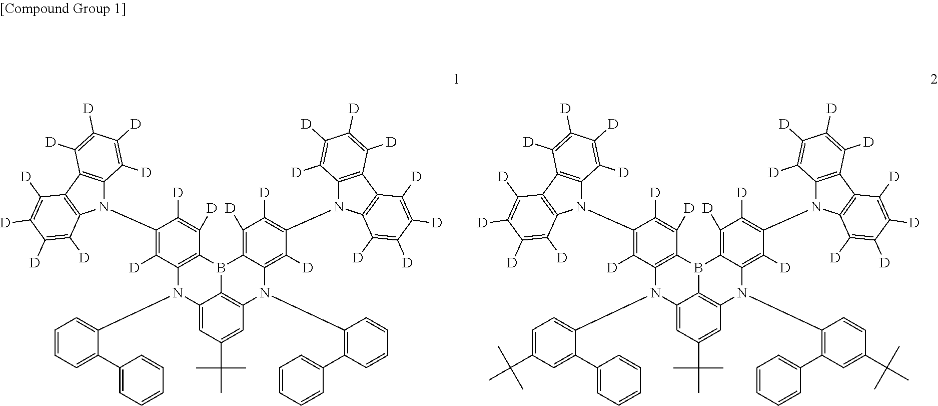 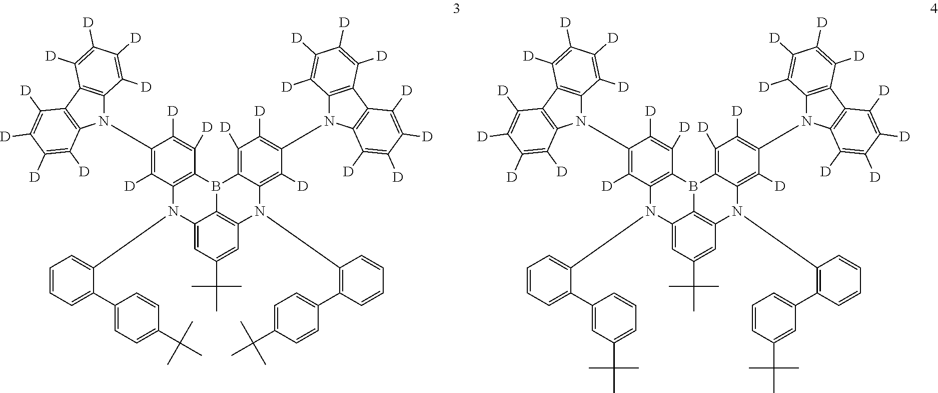 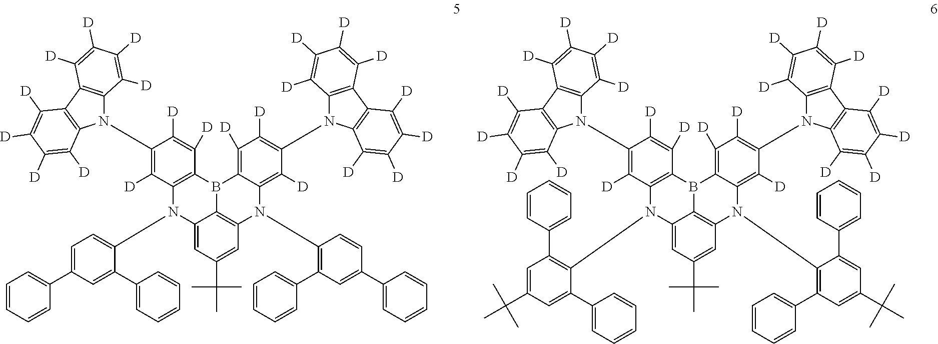 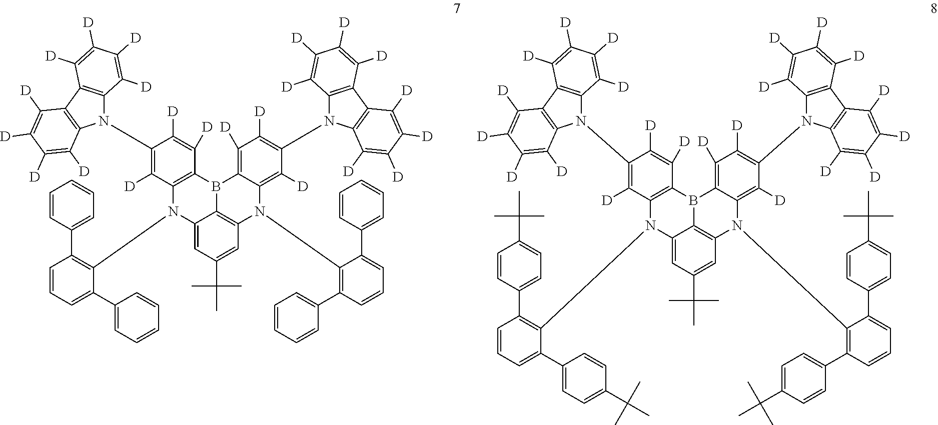 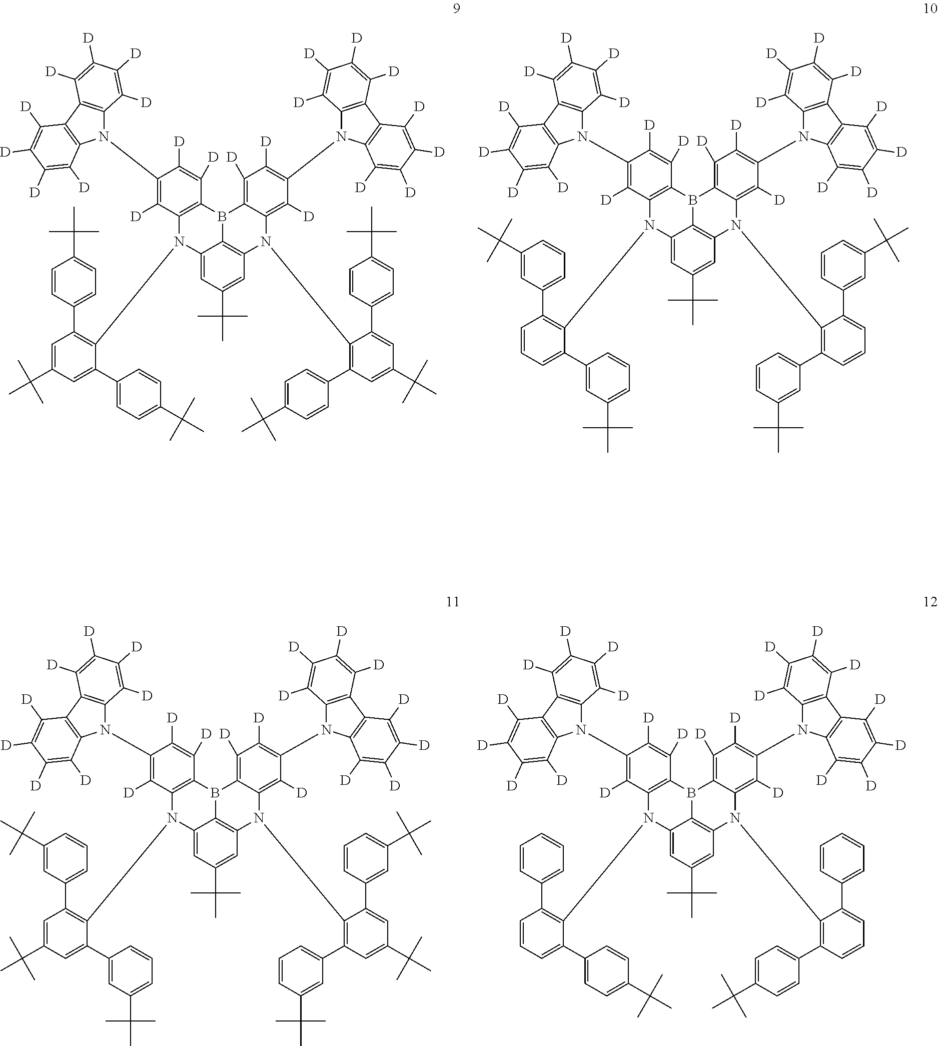 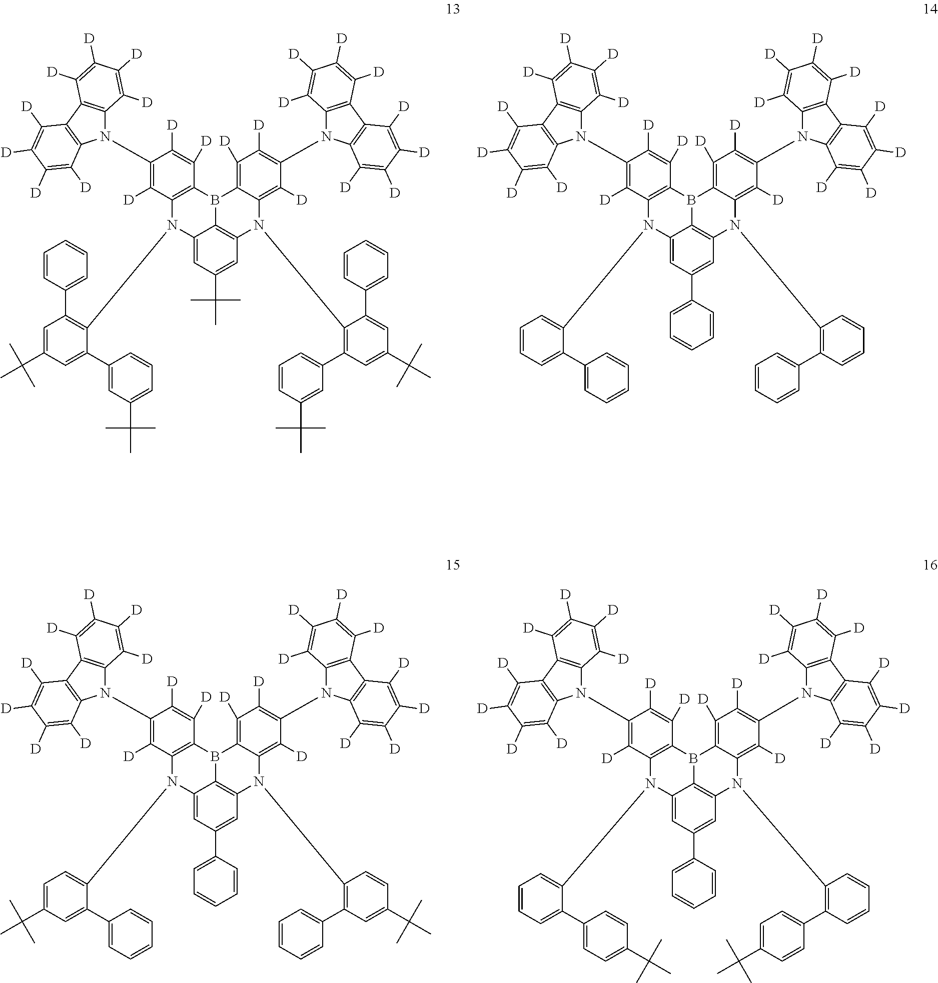 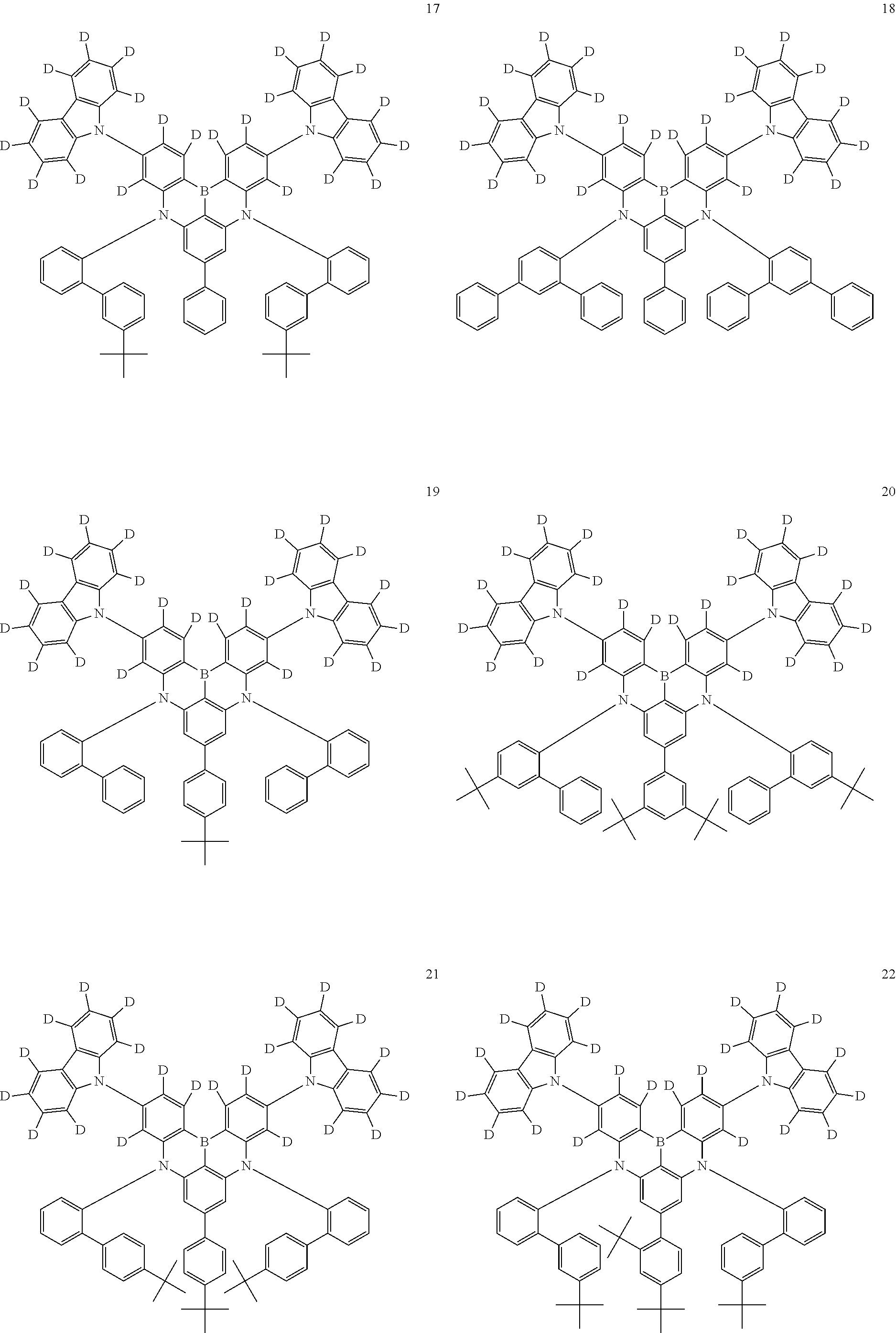 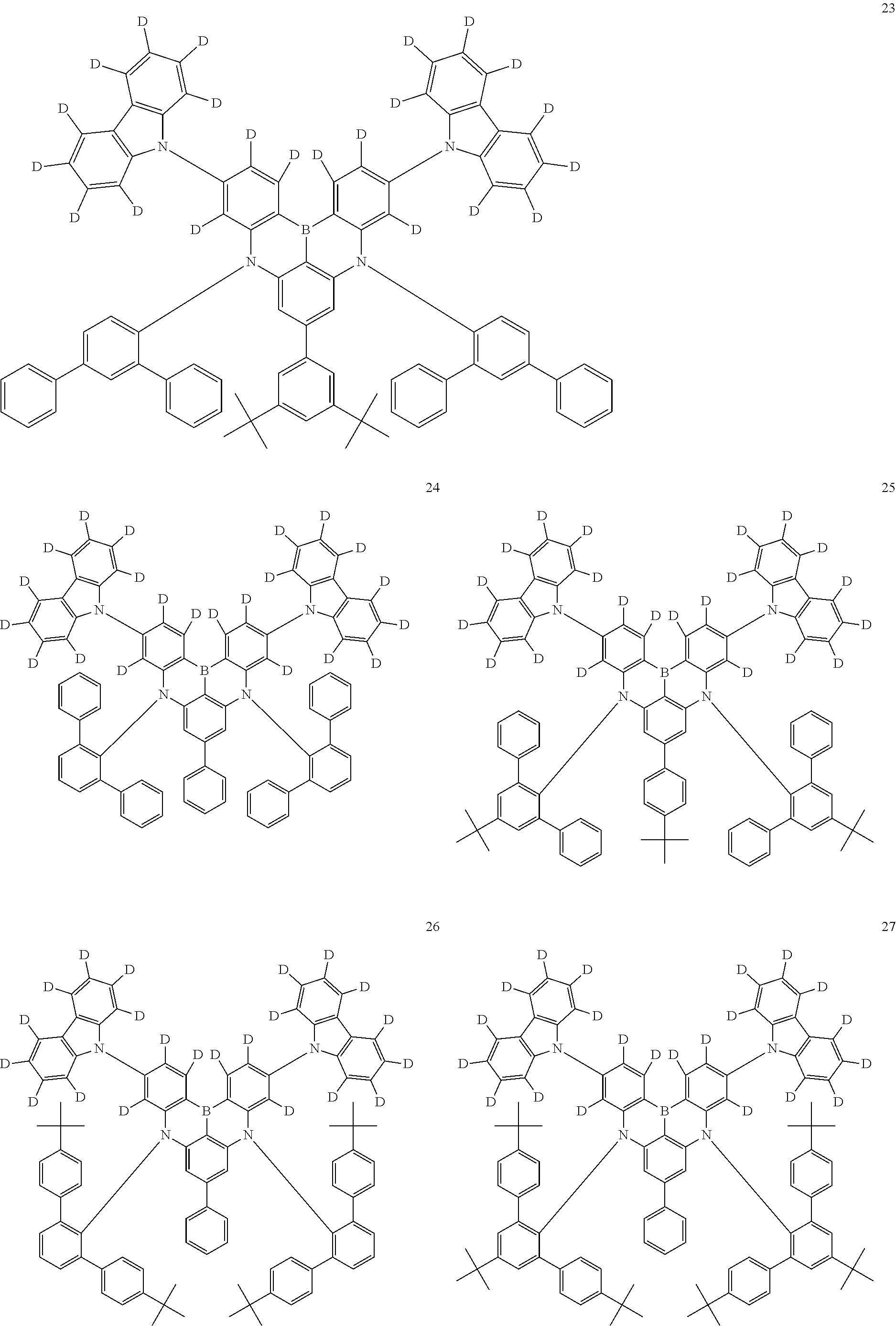 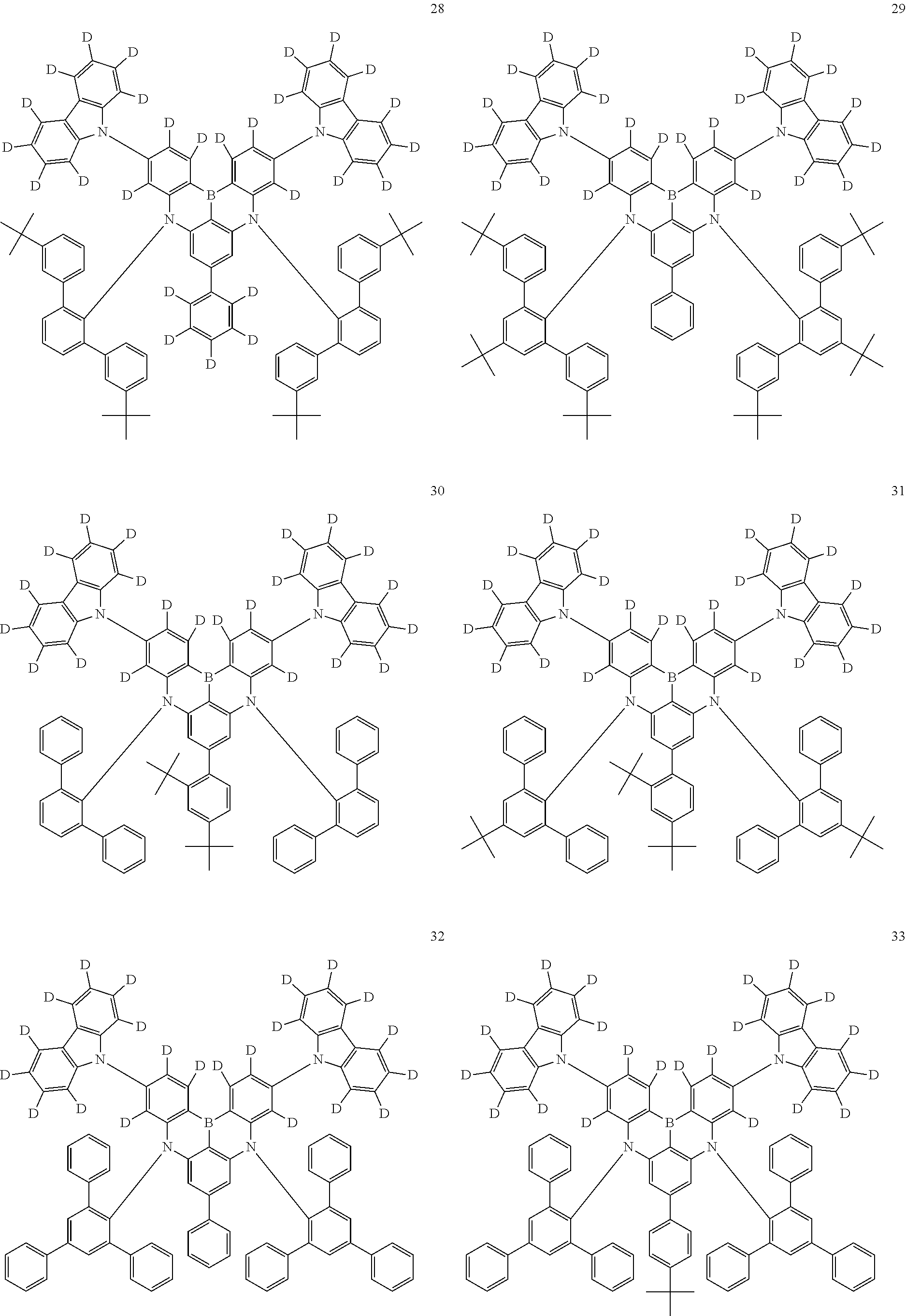 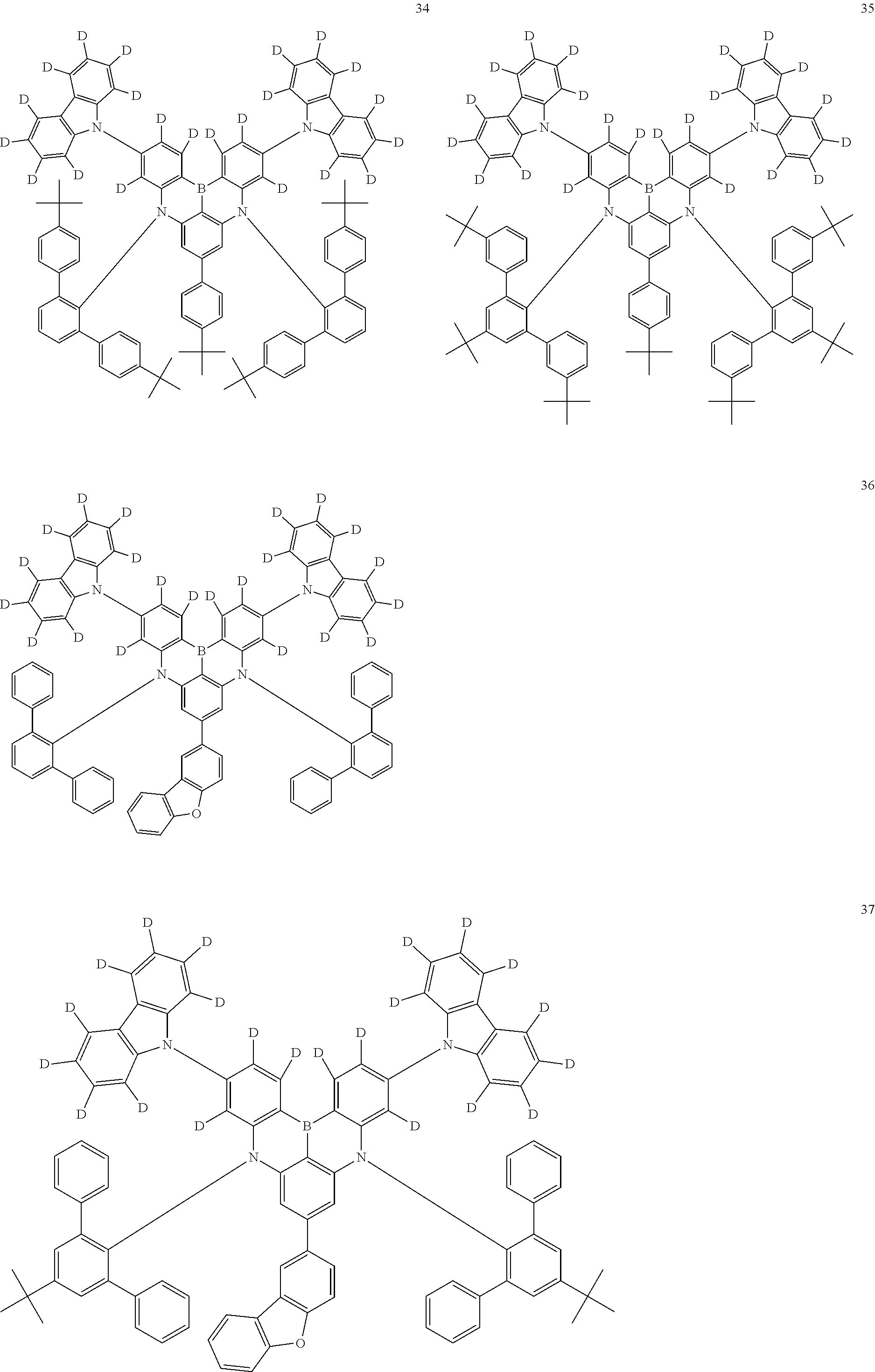 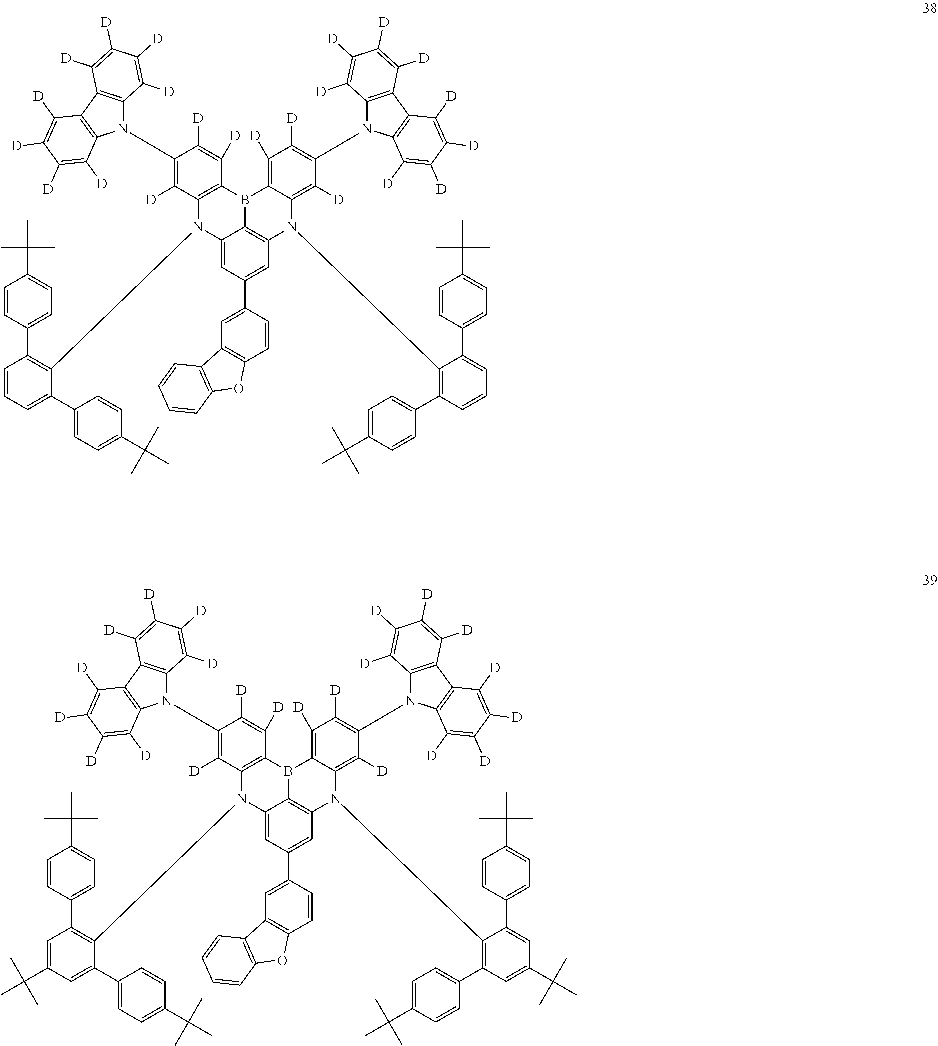 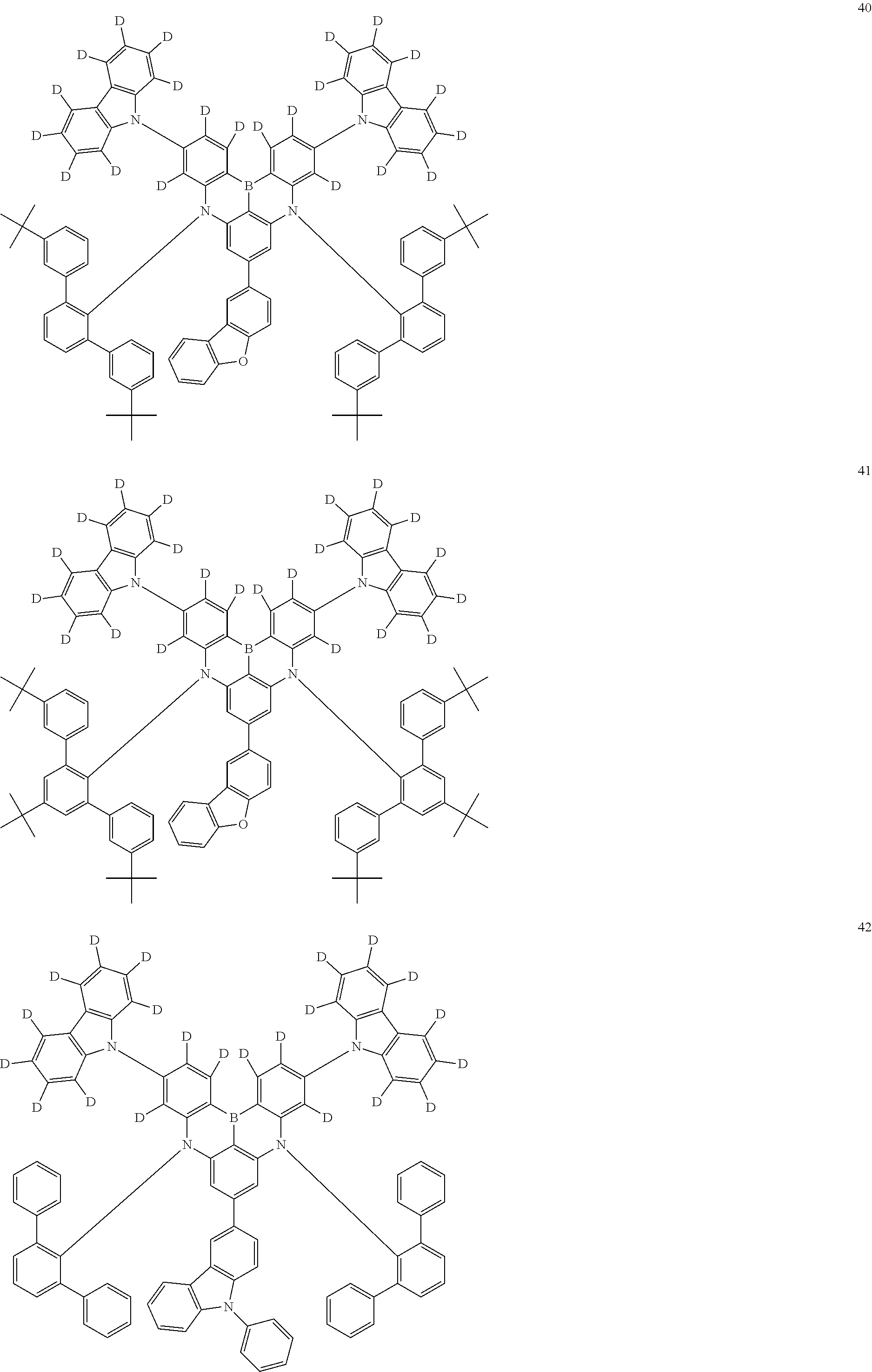 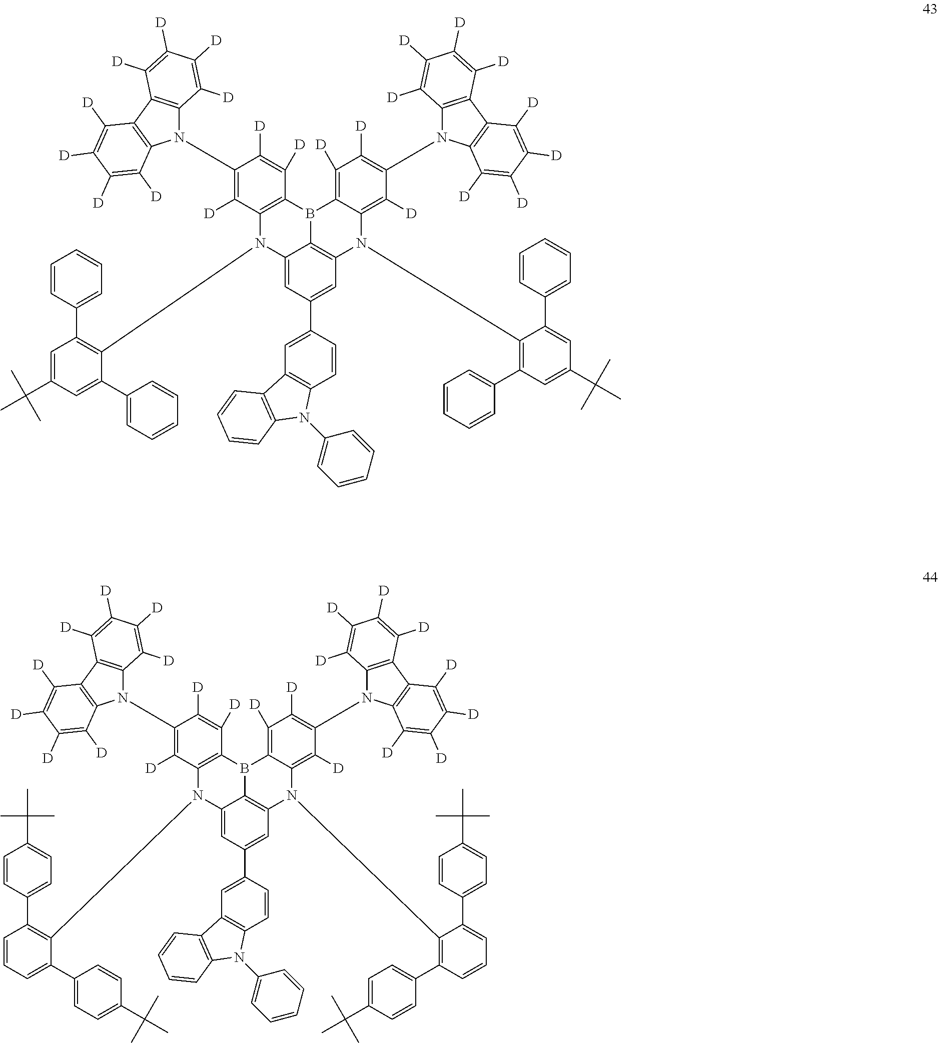 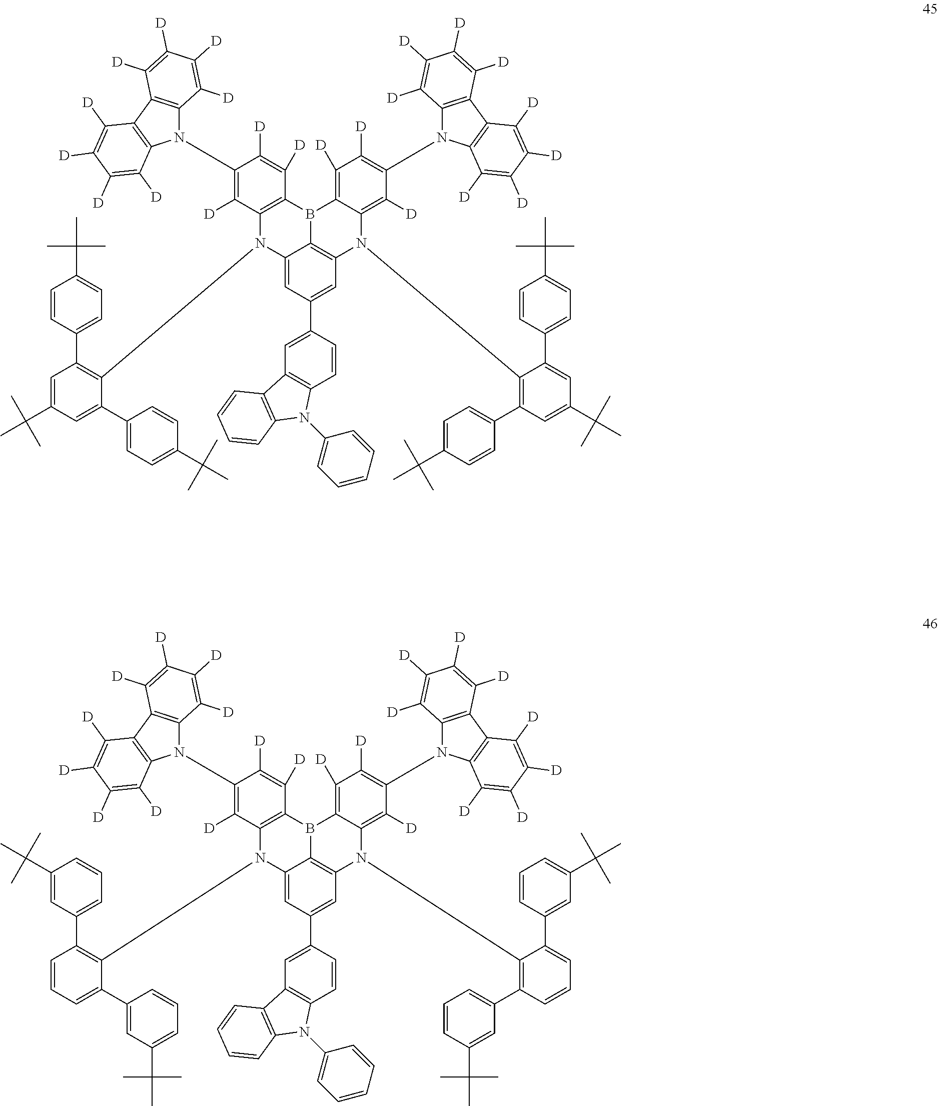 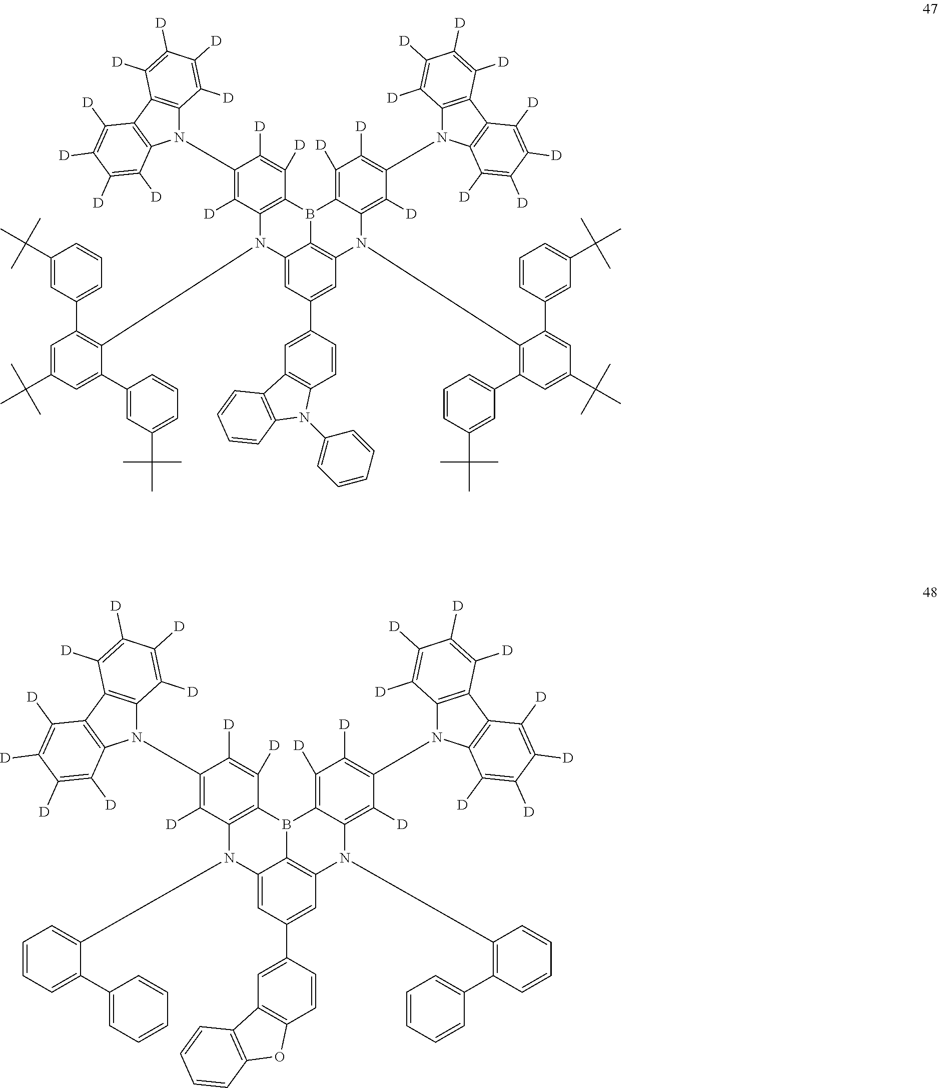 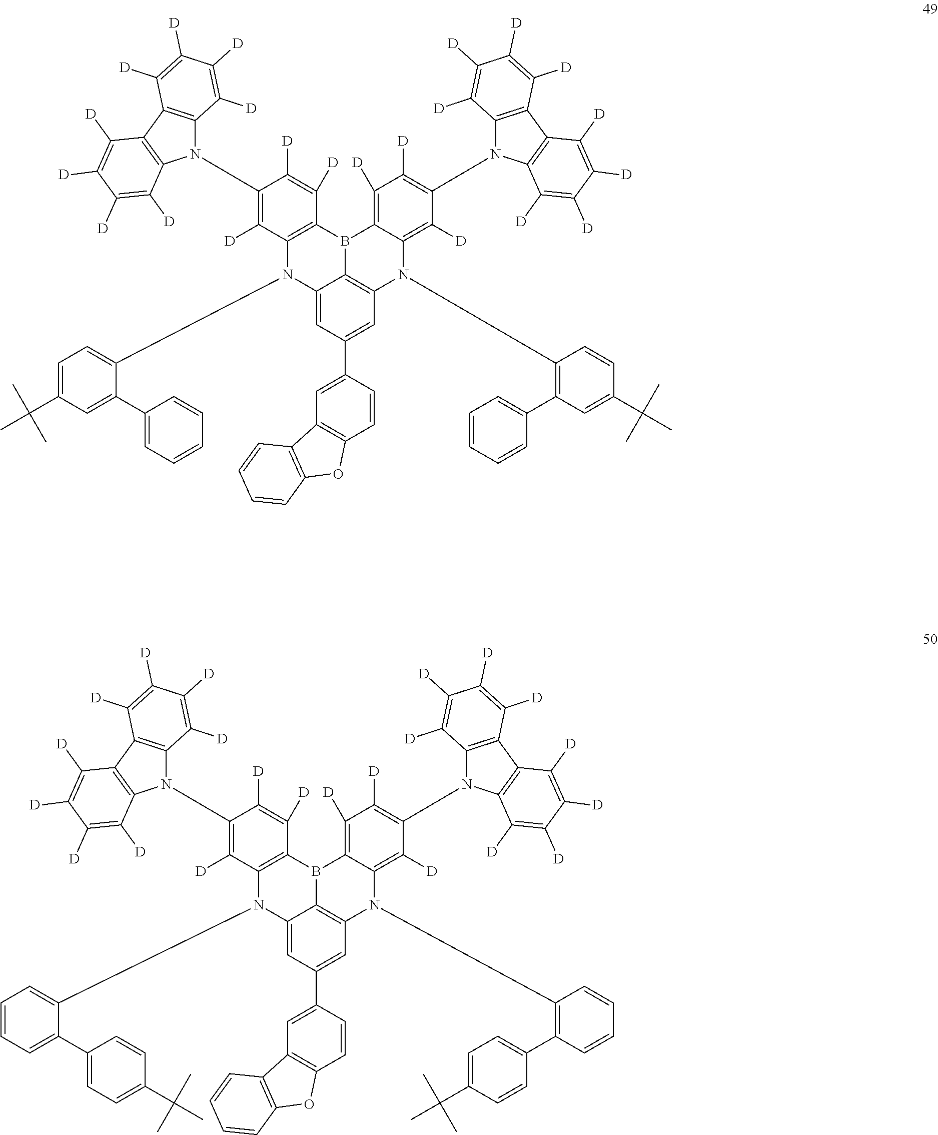 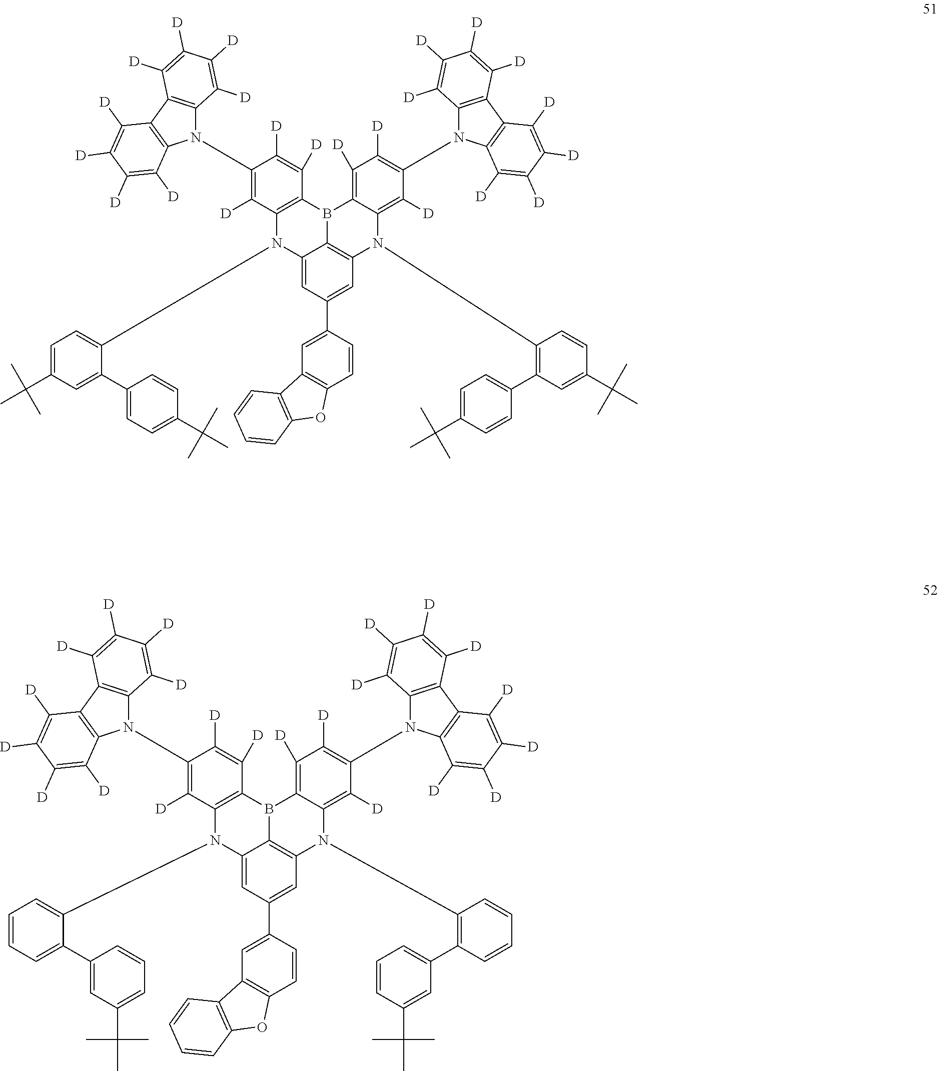 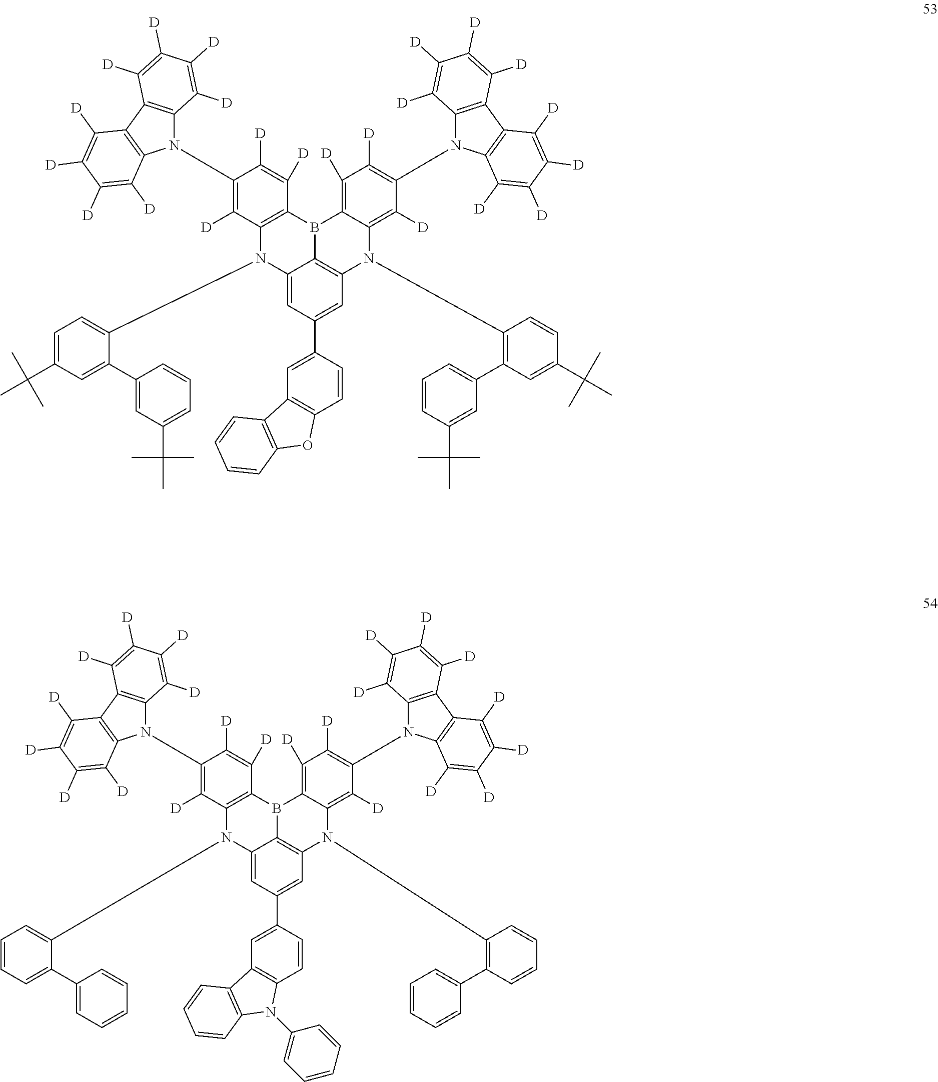 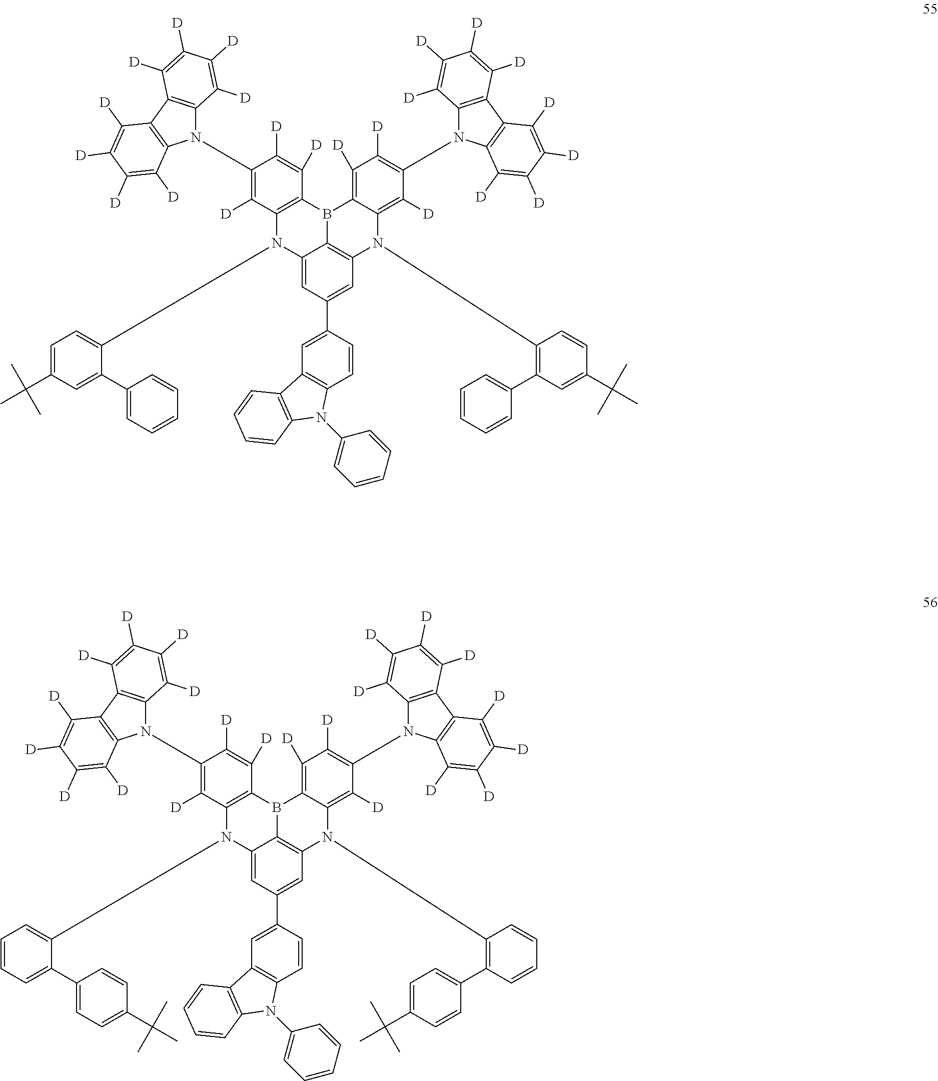 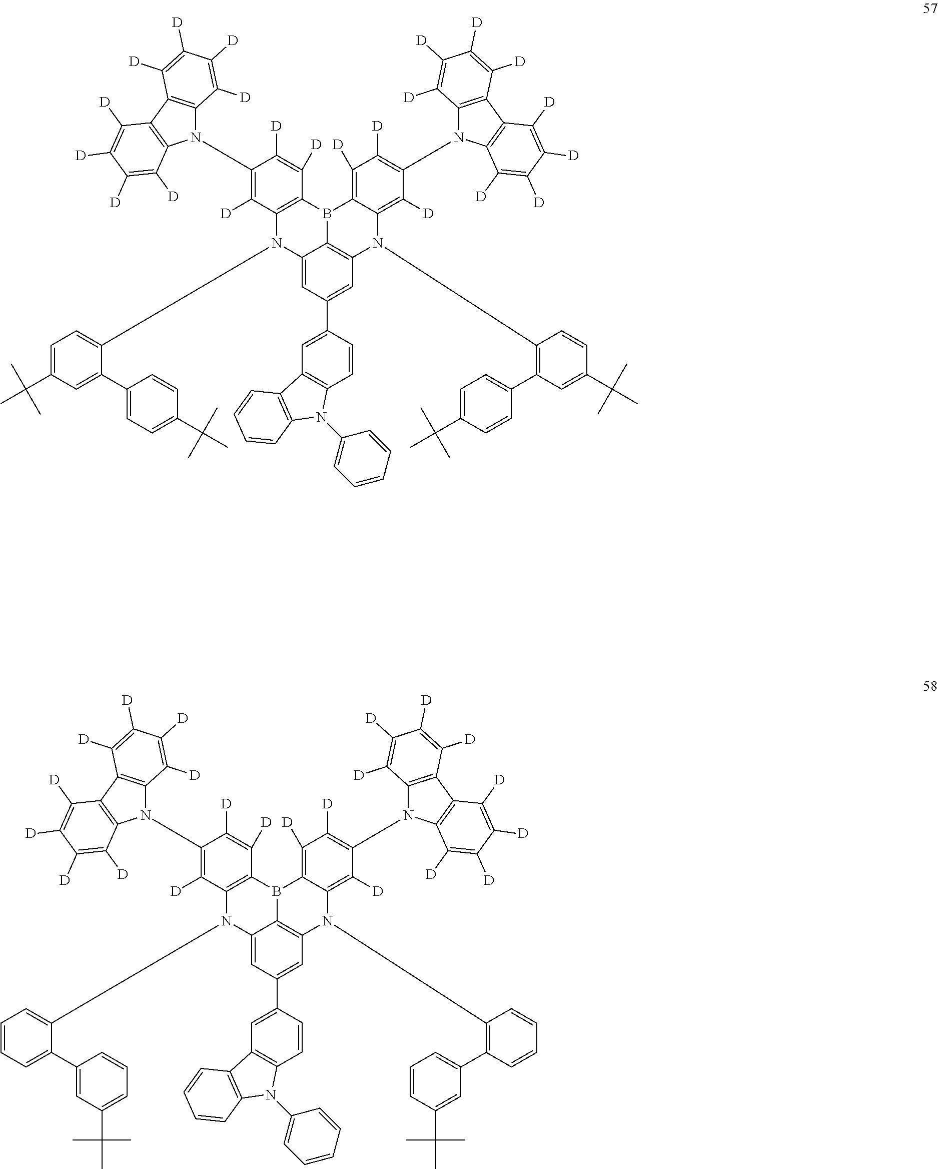 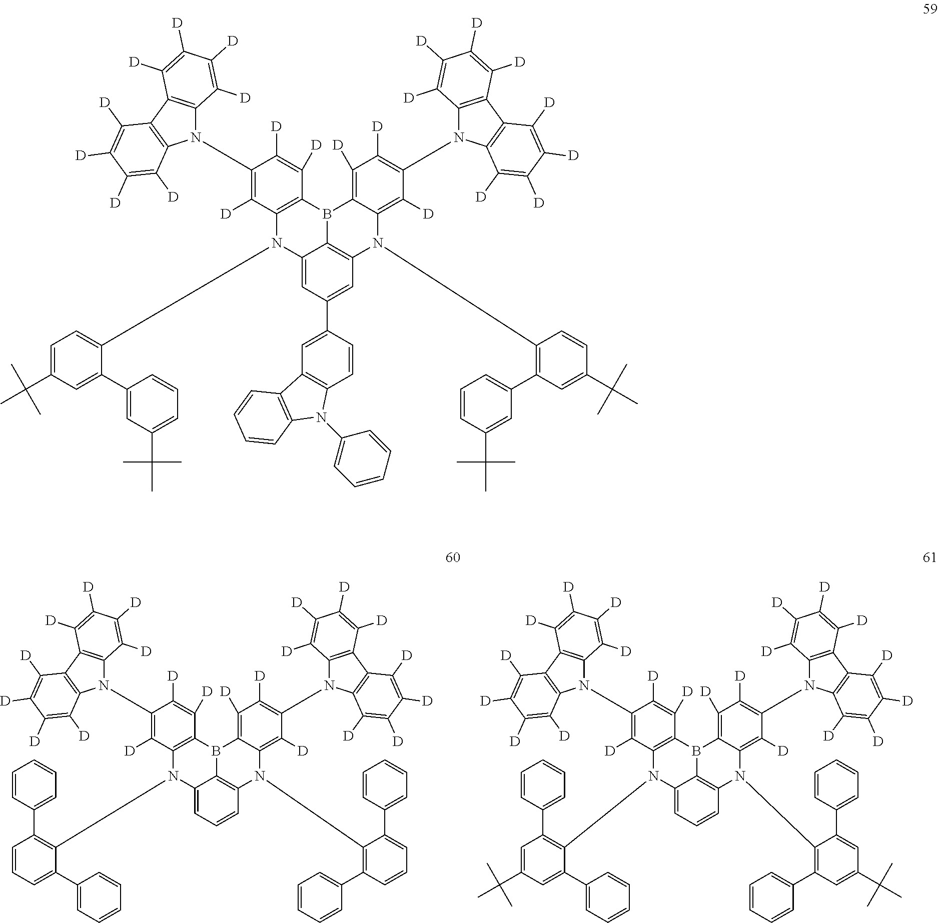 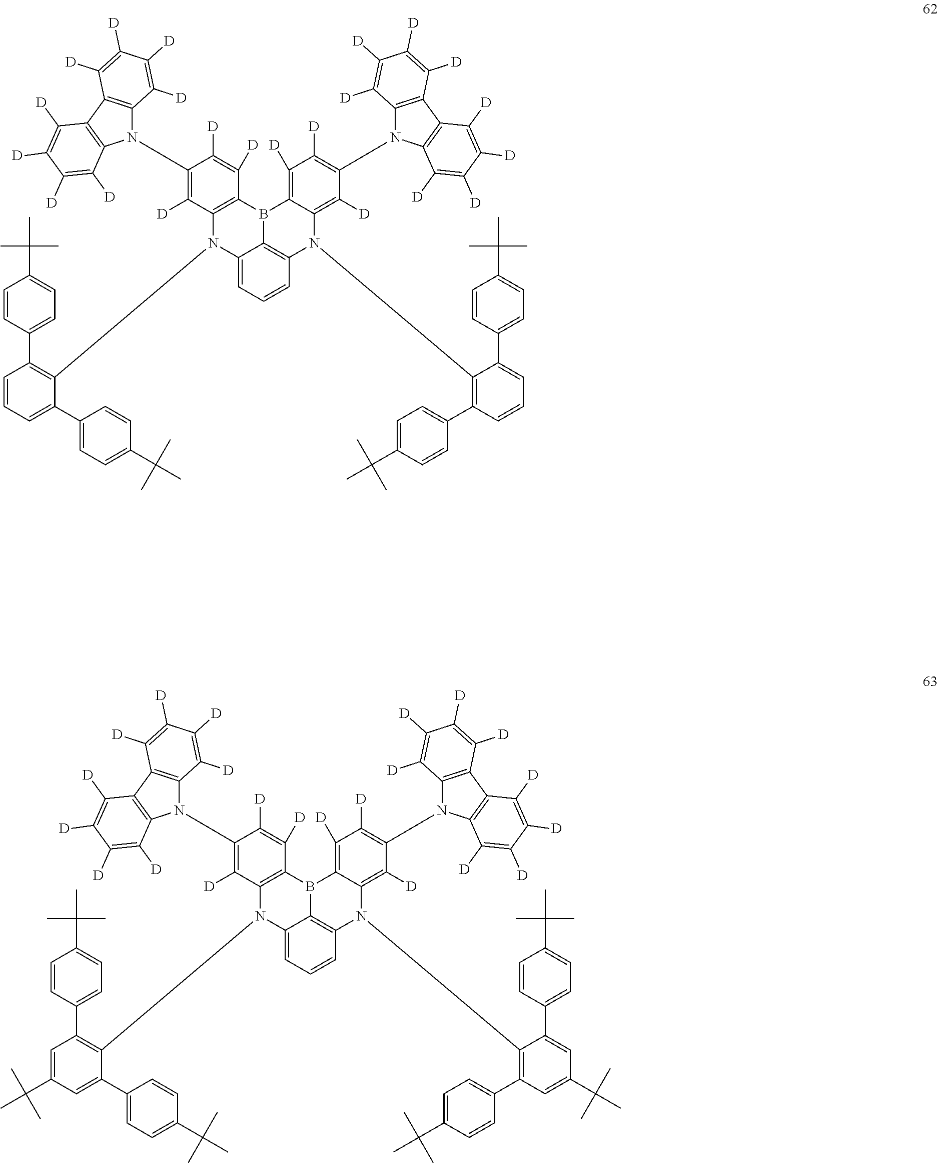 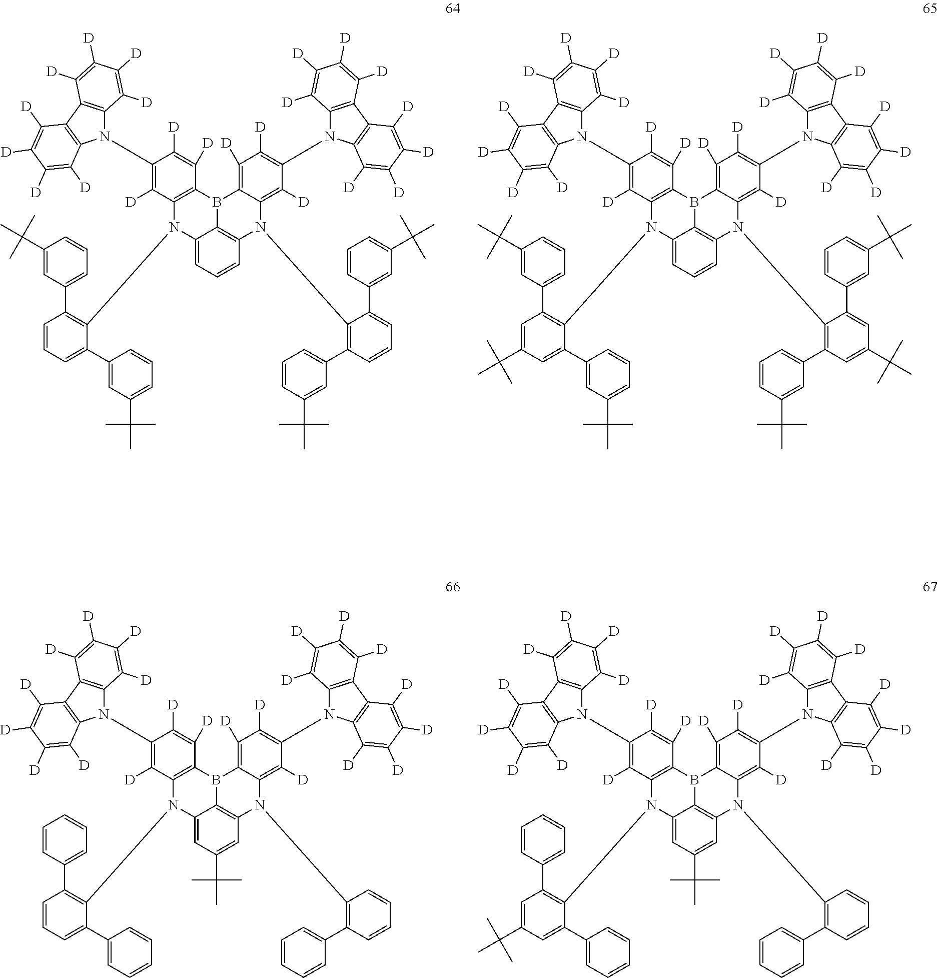 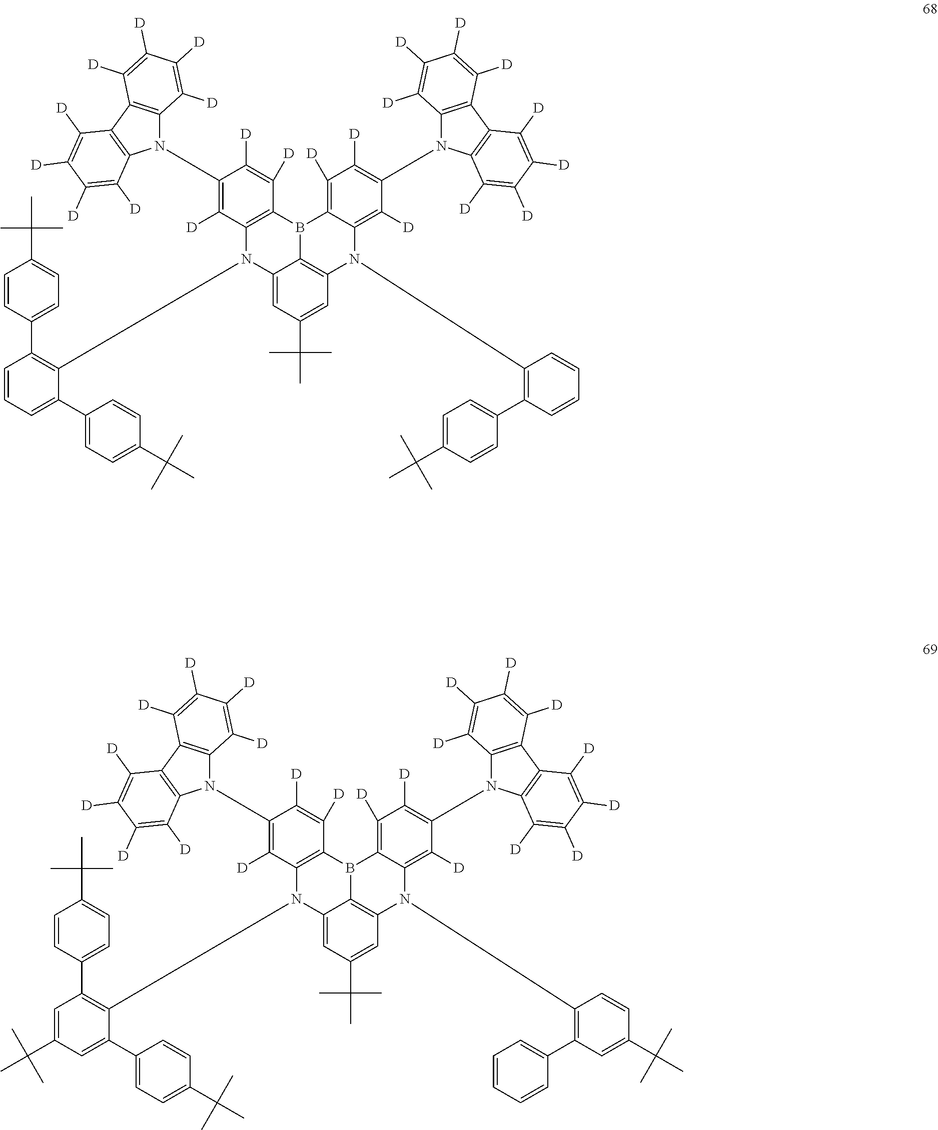 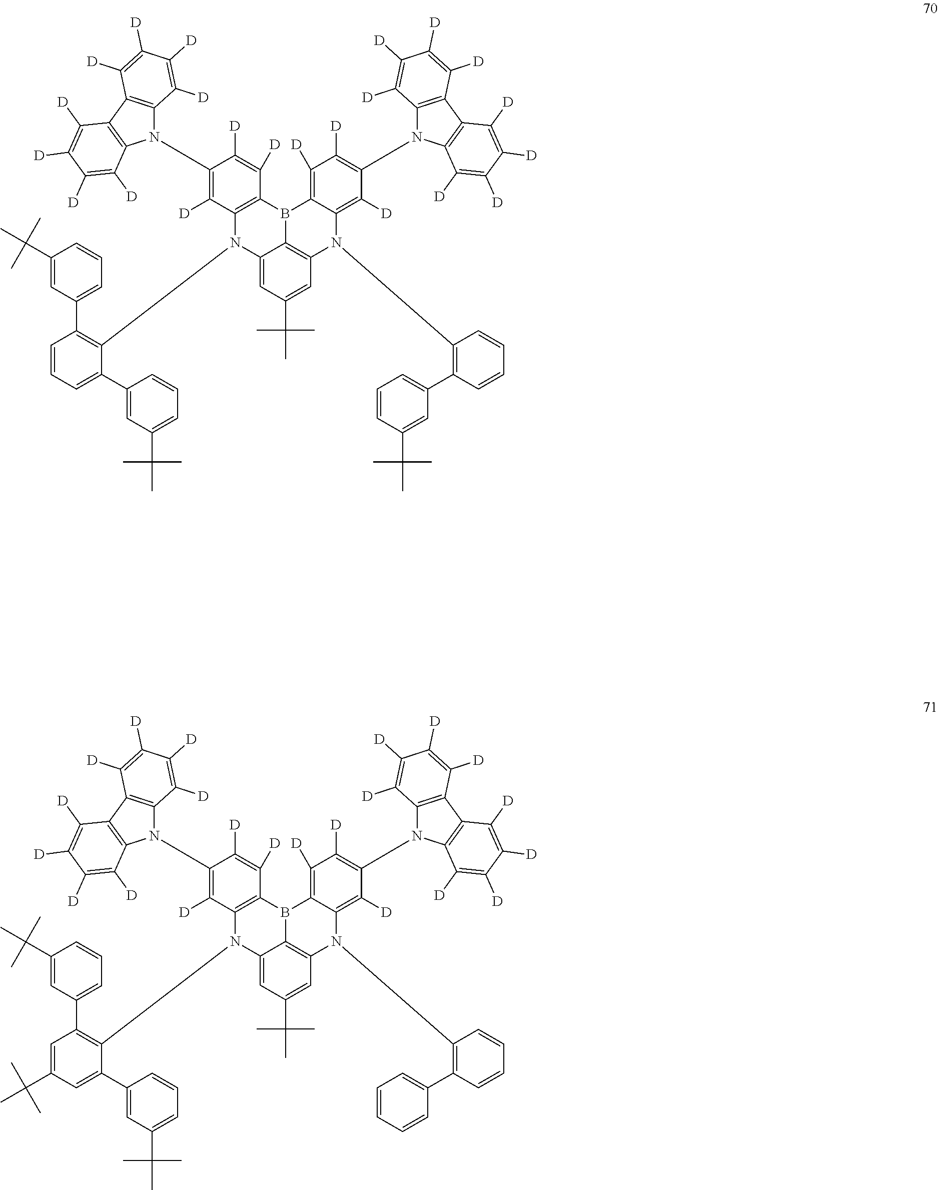 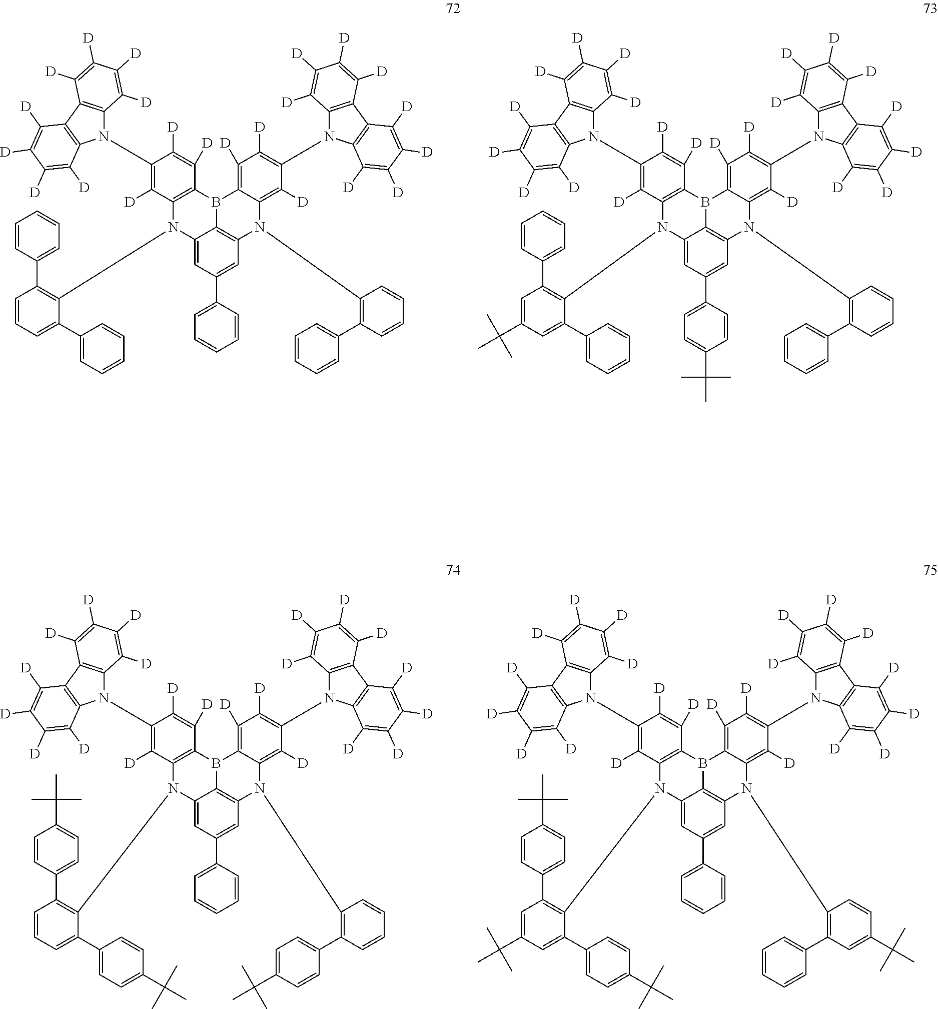 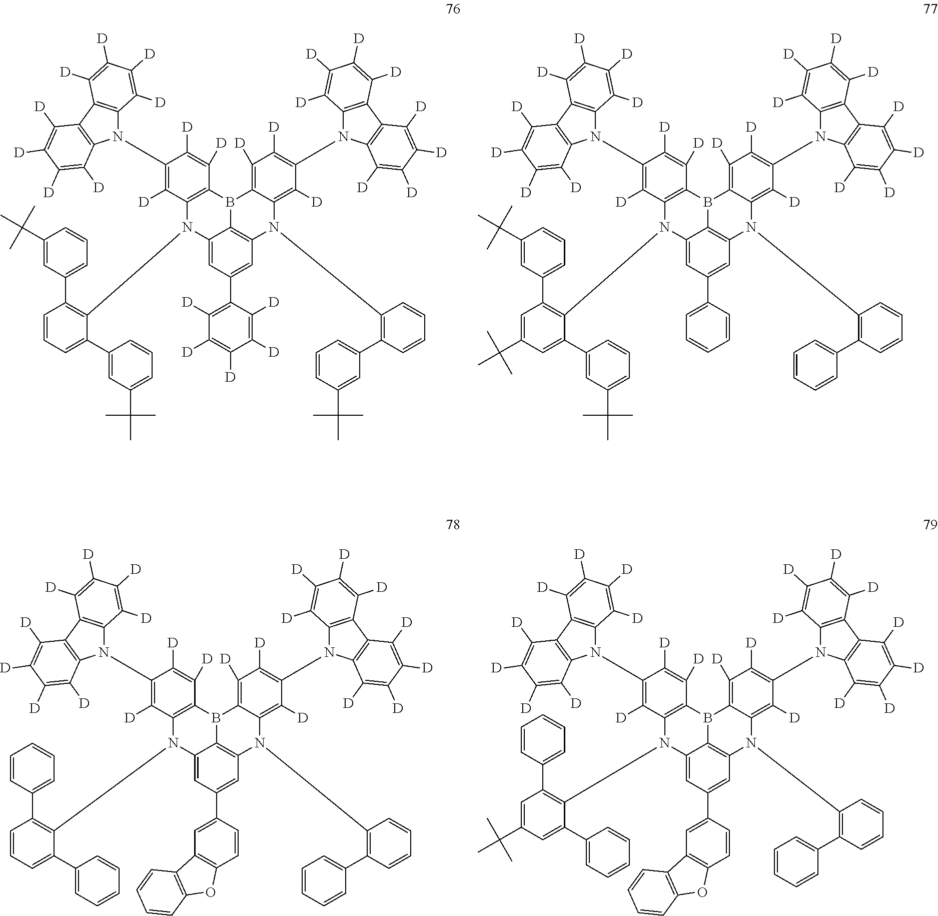 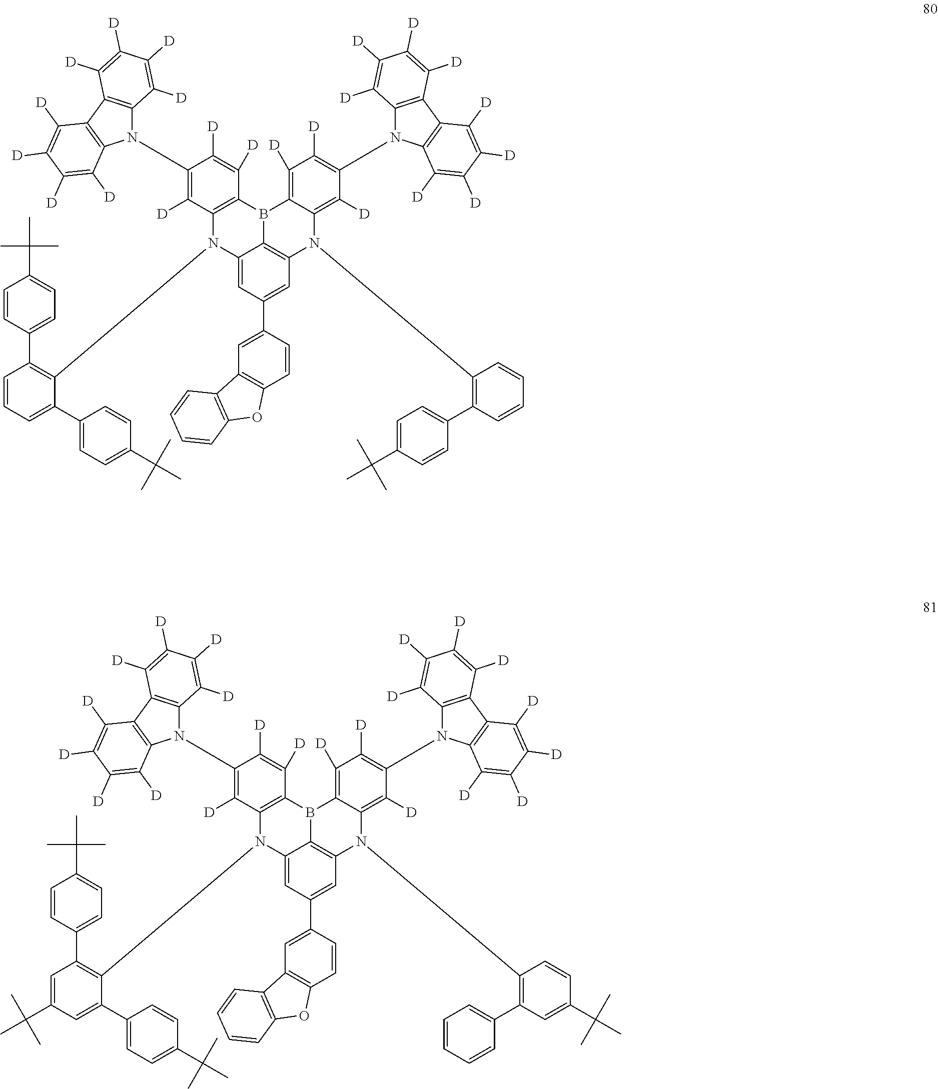 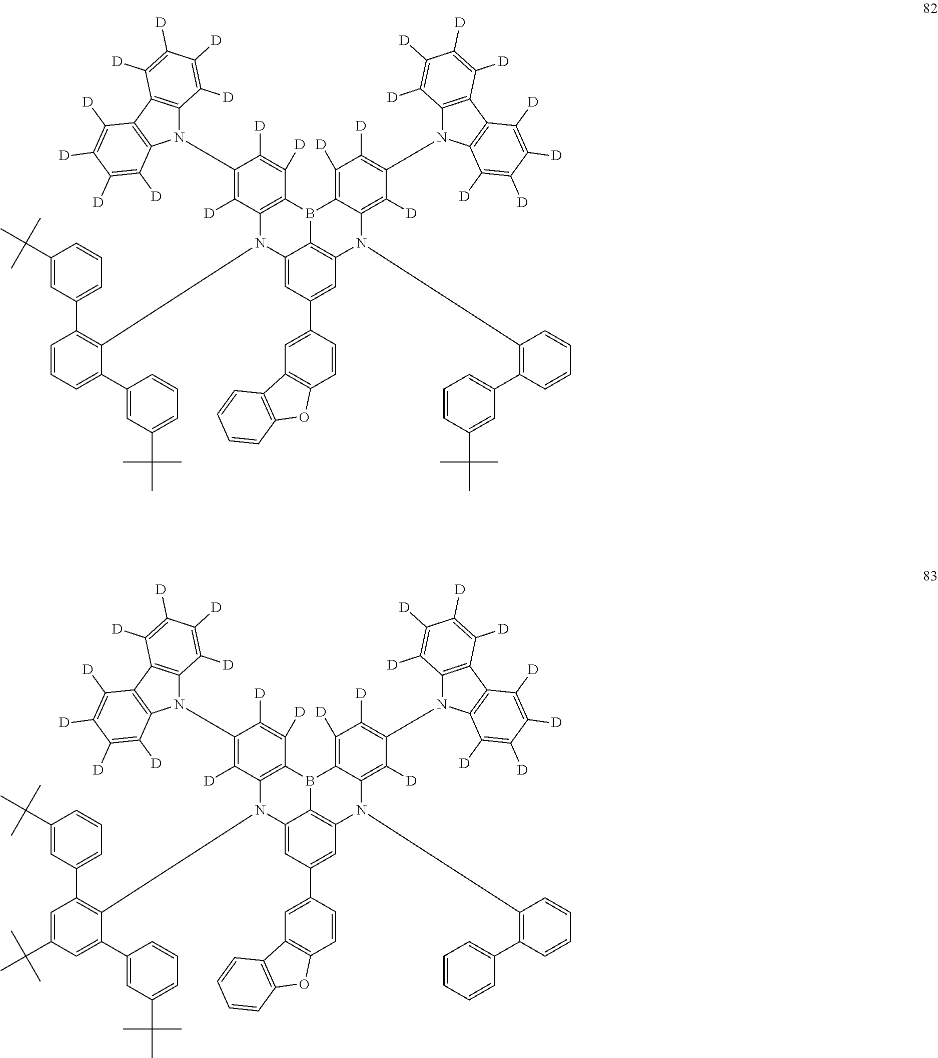 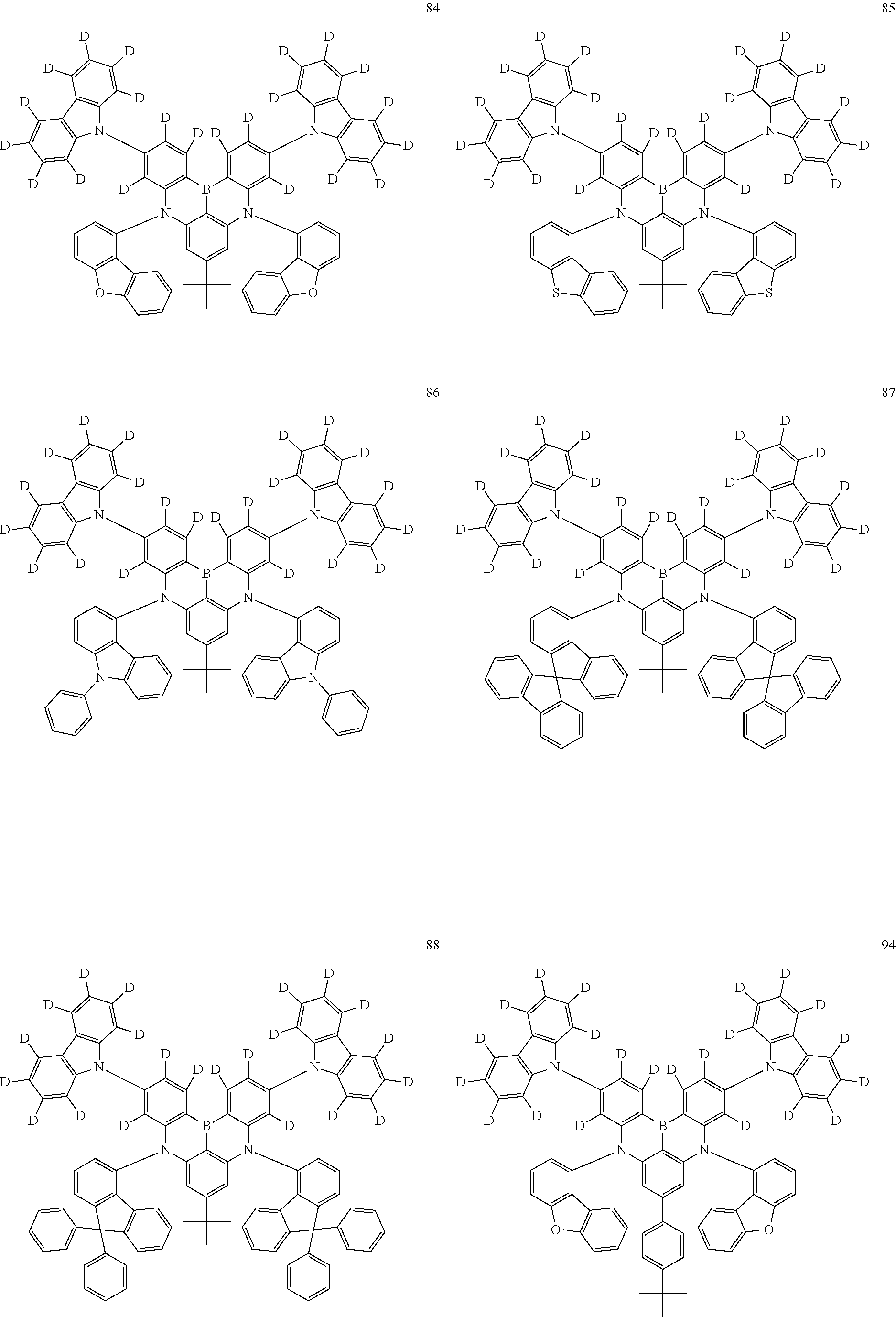 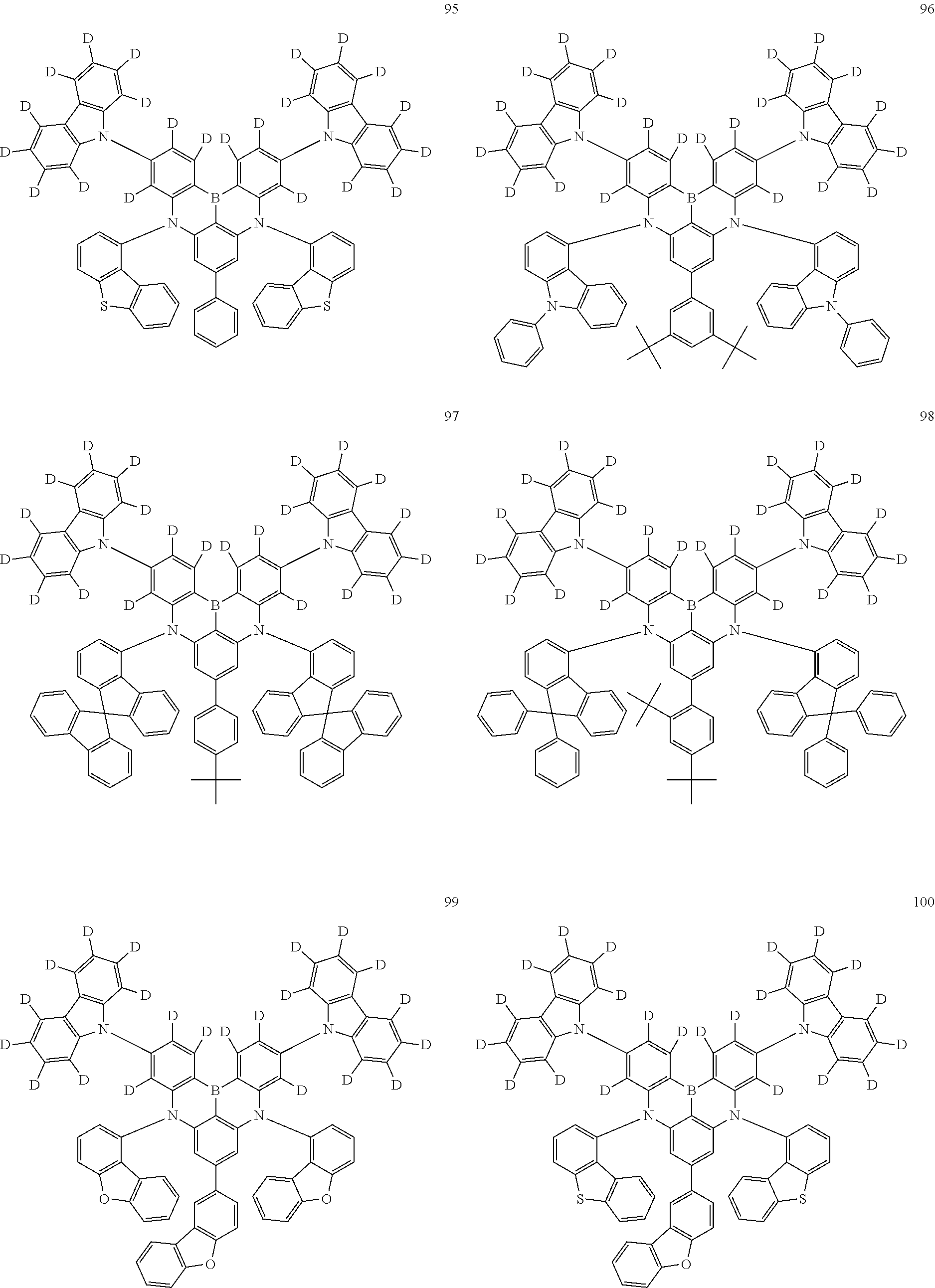 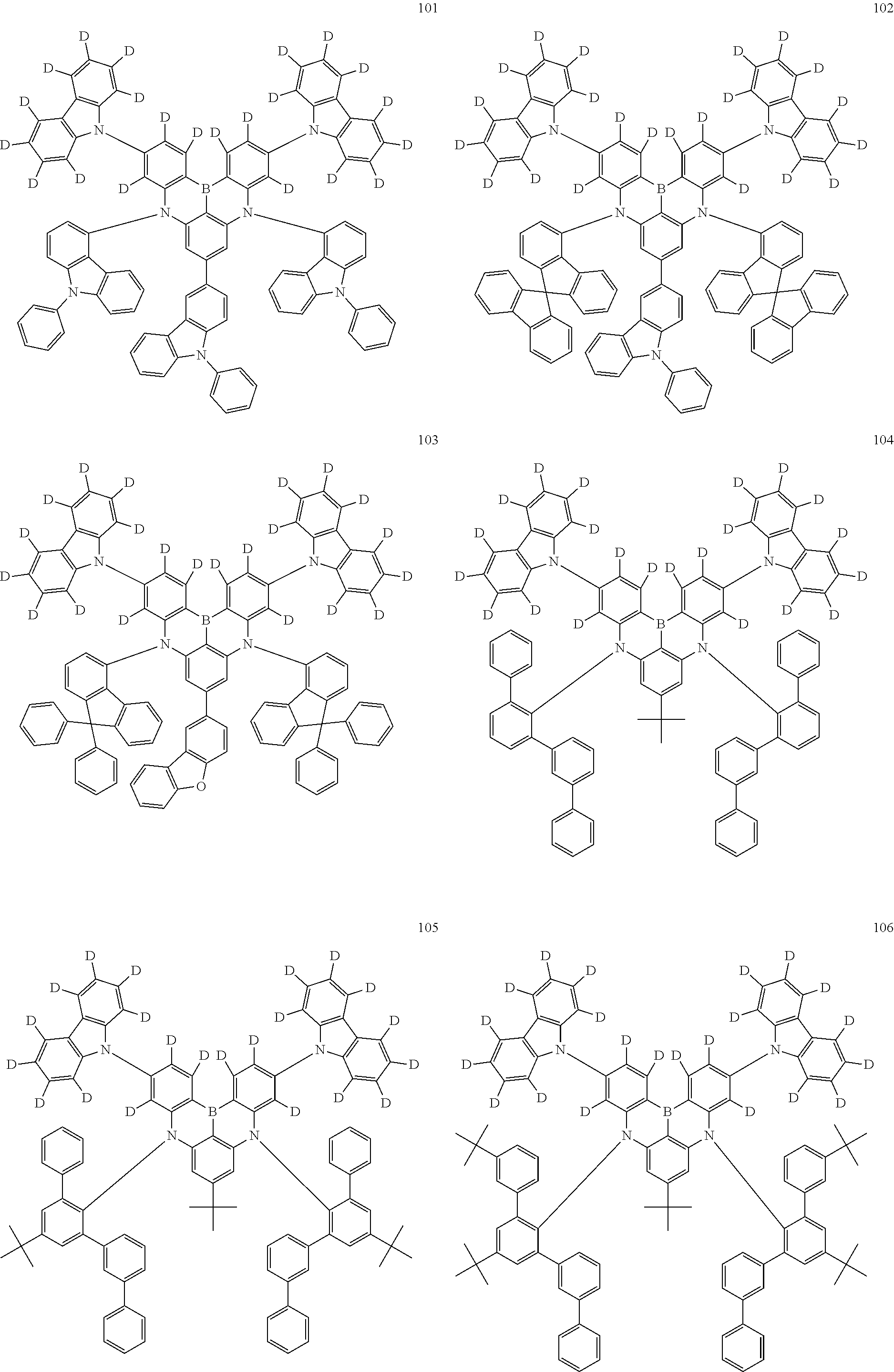 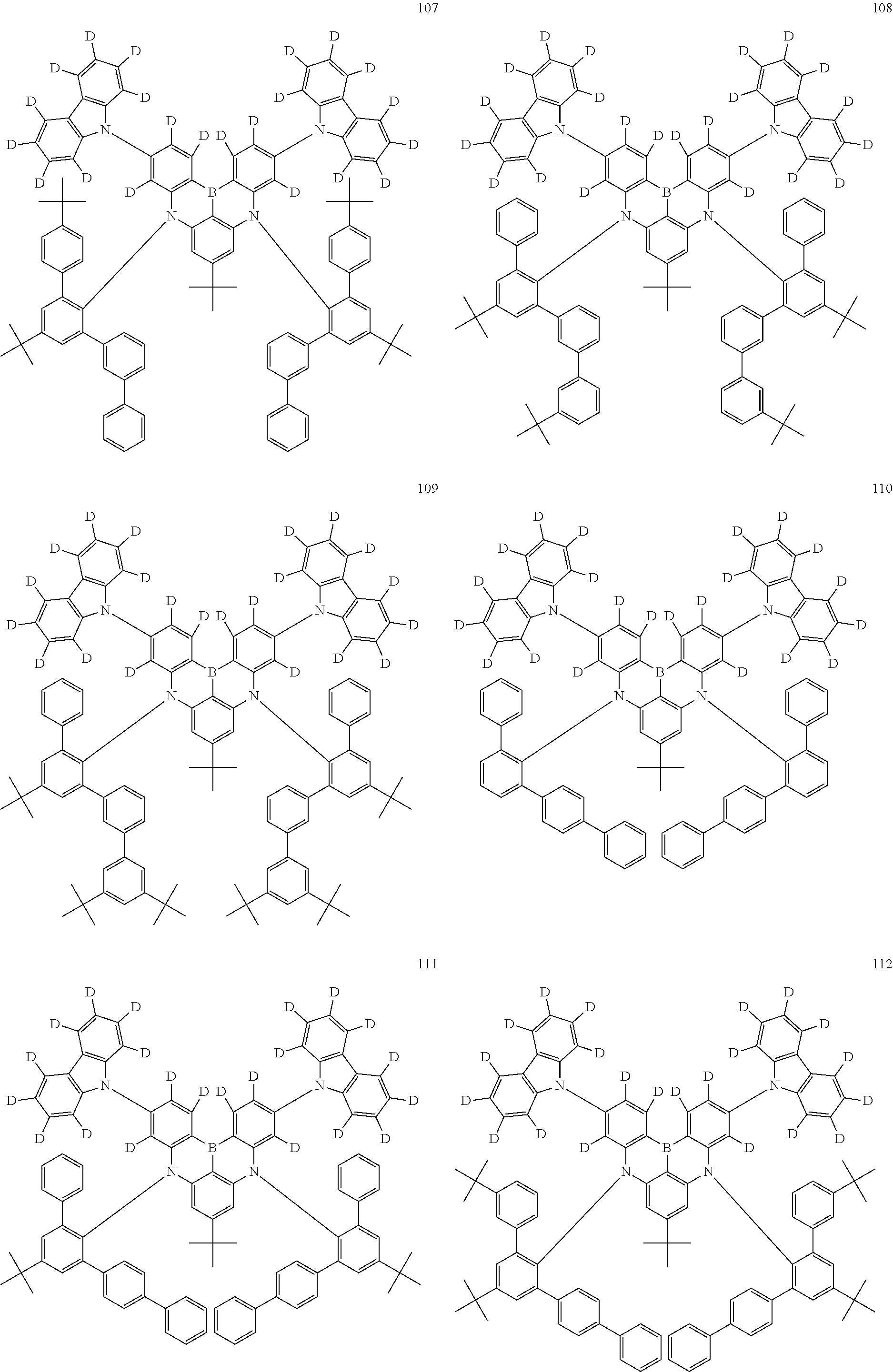 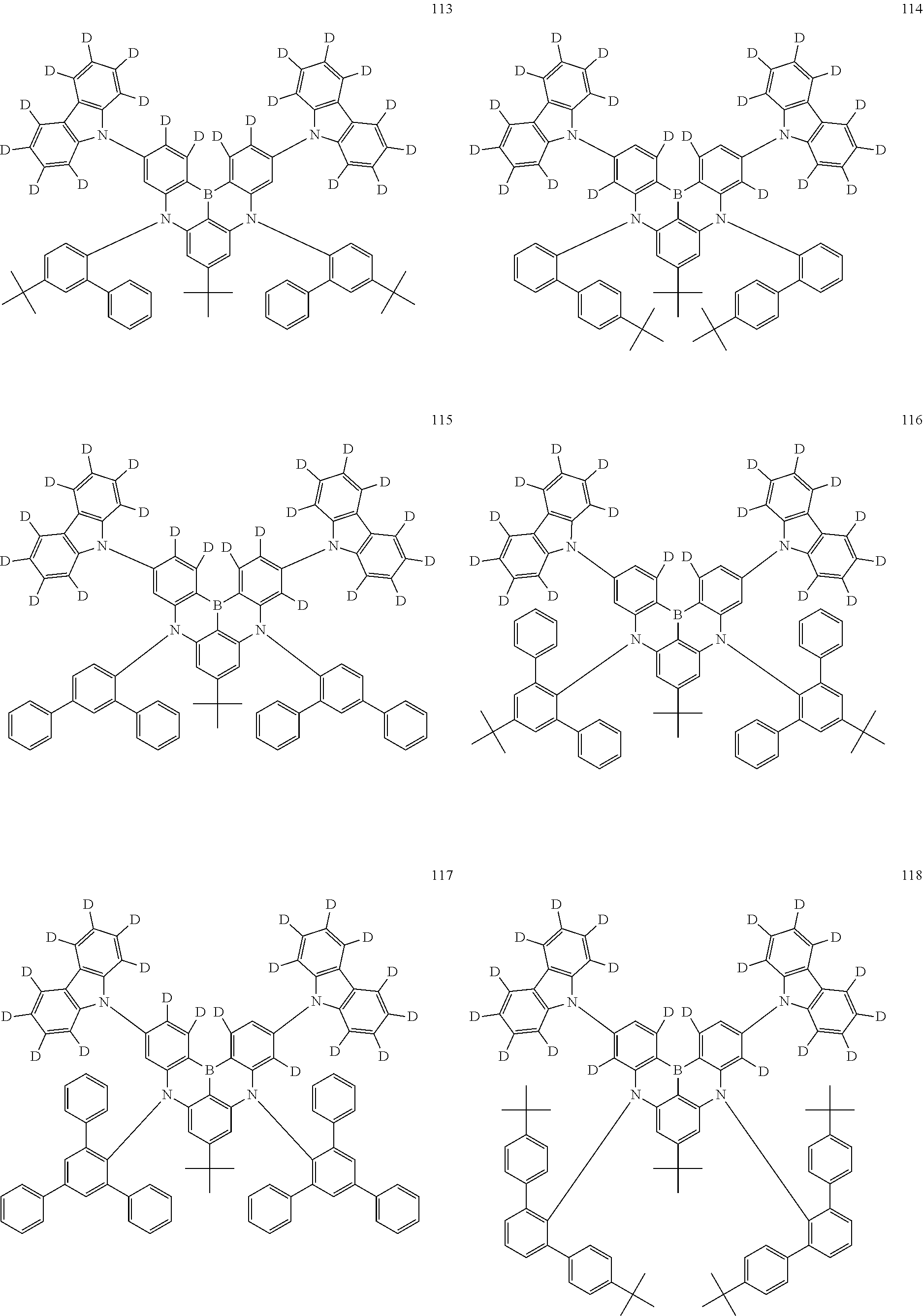 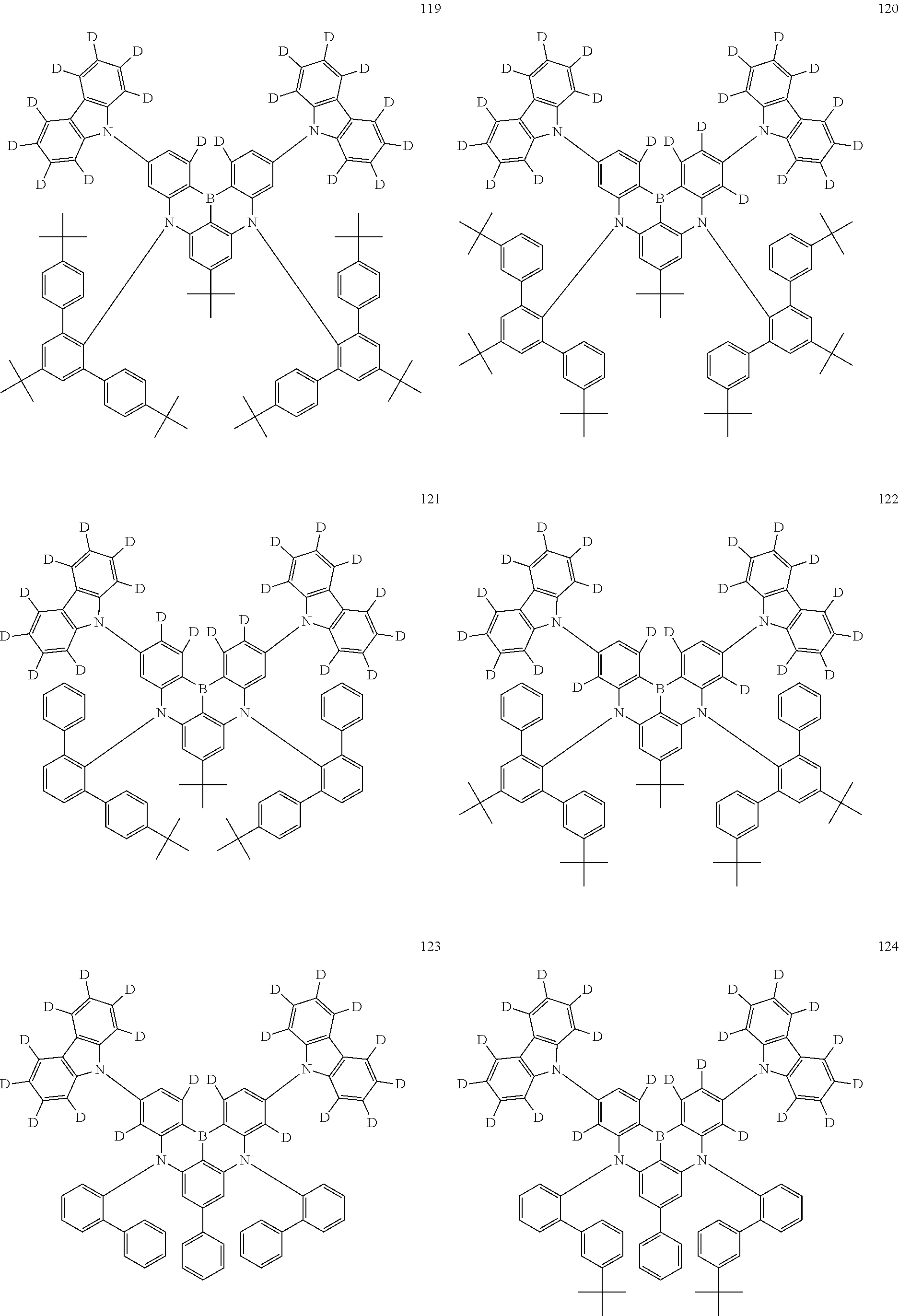 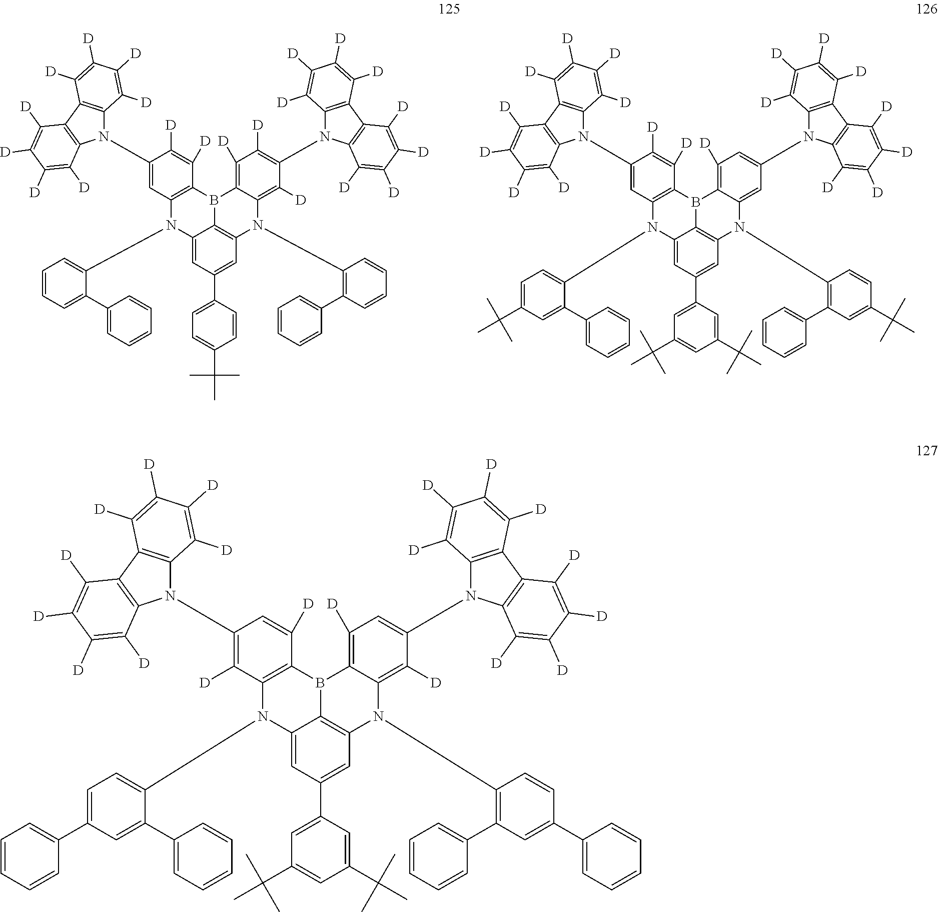 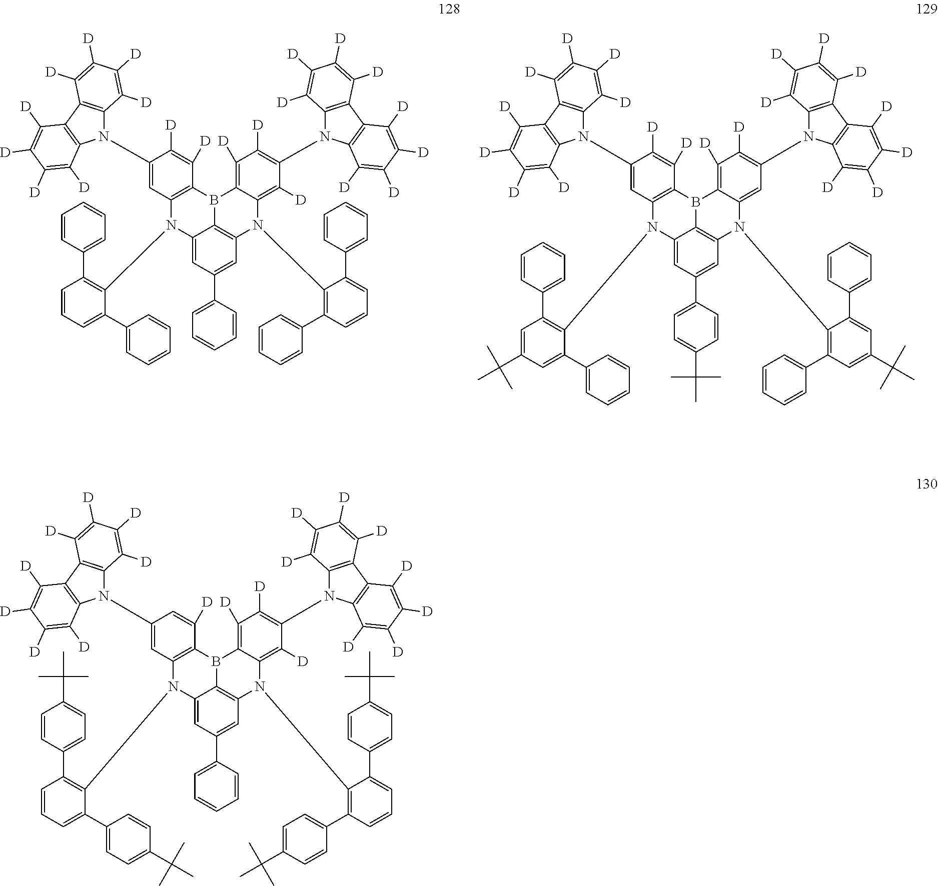 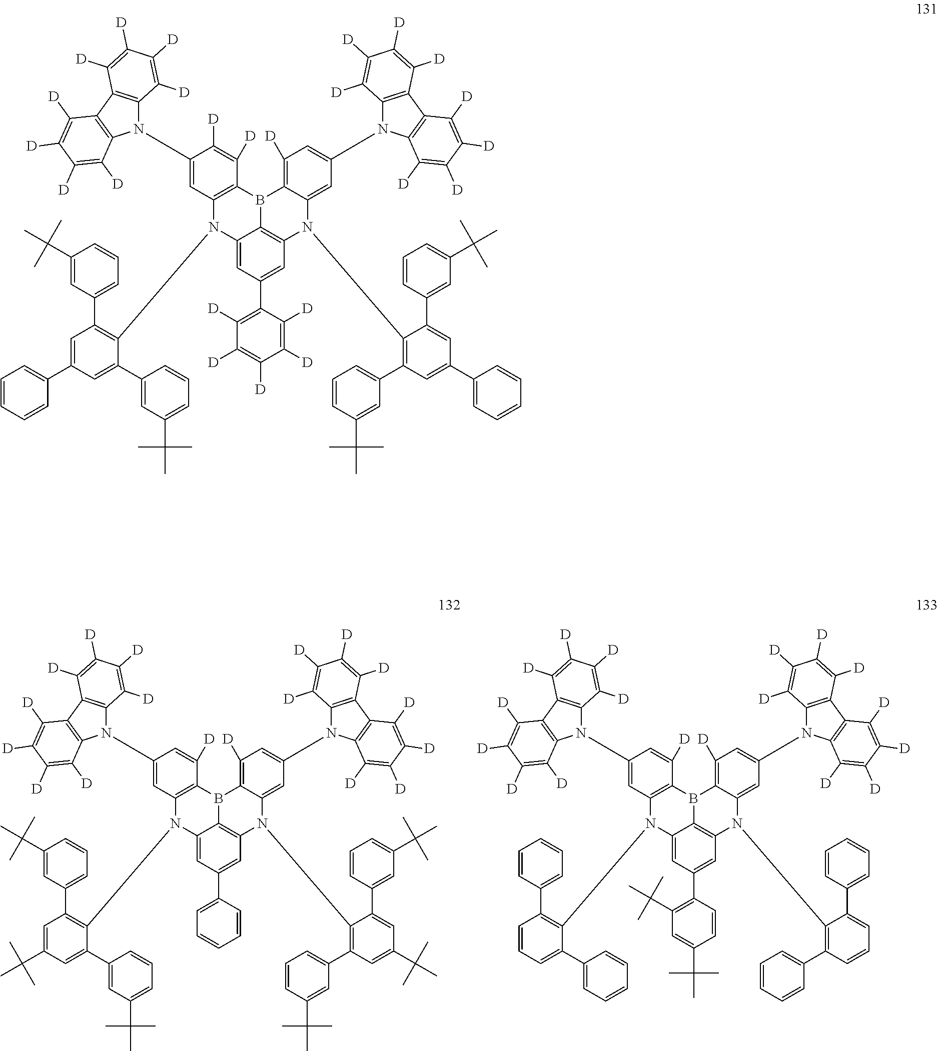 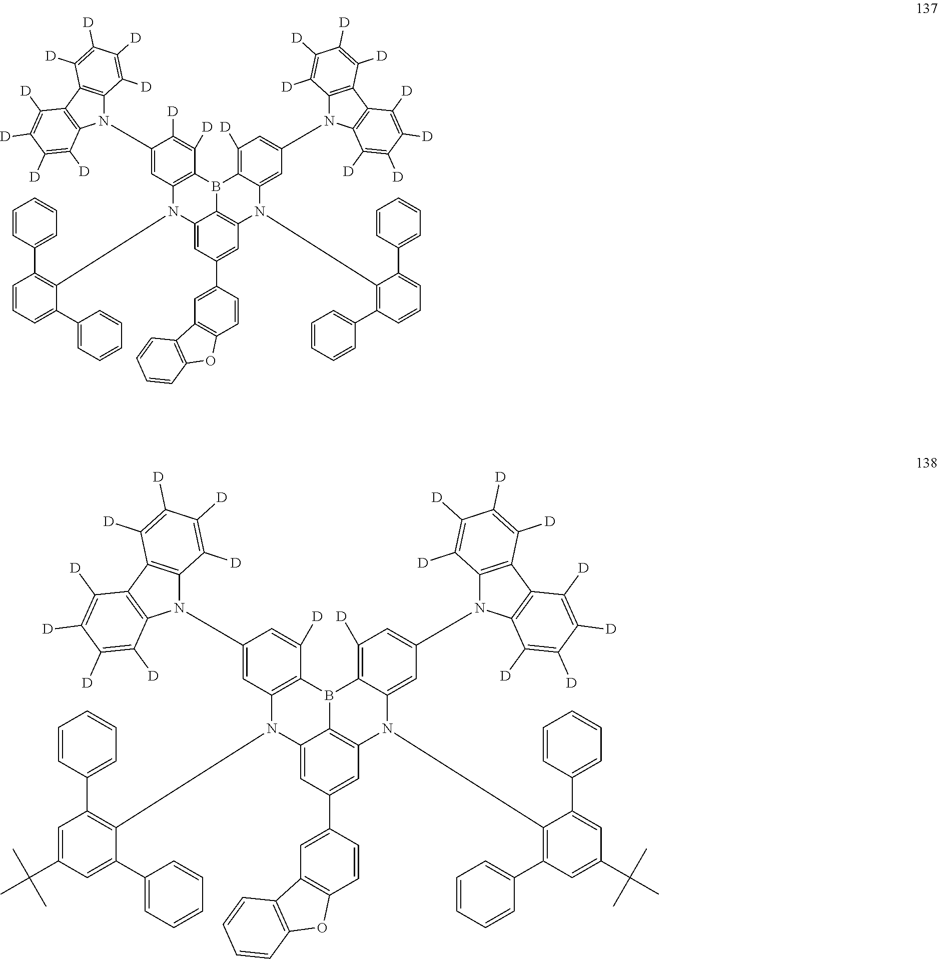 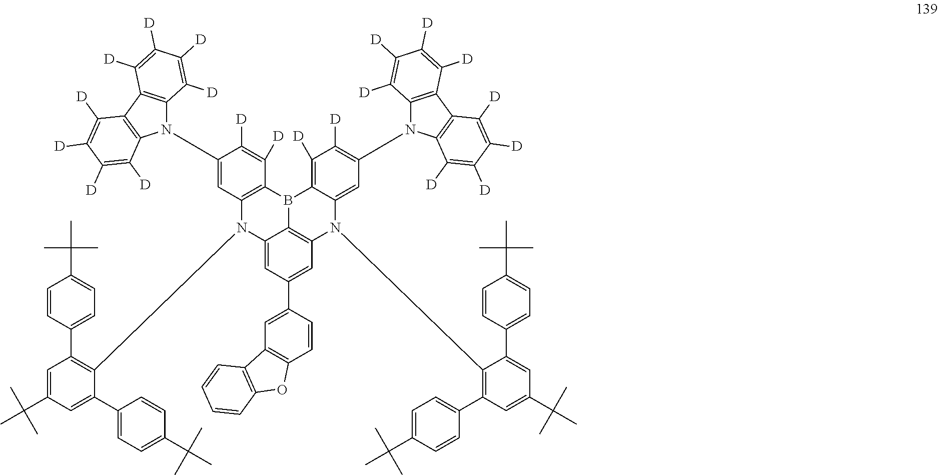 [SMILES: [2H]c1c(-n2c3c([2H])c([2H])c([2H])c([2H])c3c3c([2H])c([2H])c([2H])c([2H])c32)cc2c(c1[2H])B1c3c(cc(-c4ccc5oc6ccccc6c5c4)cc3N(c3c(-c4ccc(C(C)(C)C)cc4)cc(C(C)(C)C)cc3-c3ccc(C(C)(C)C)cc3)c3cc(-n4c5c([2H])c([2H])c([2H])c([2H])c5c5c([2H])c([2H])c([2H])c([2H])c54)c([2H])c([2H])c31)N2c1c(-c2ccc(C(C)(C)C)cc2)cc(C(C)(C)C)cc1-c1ccc(C(C)(C)C)cc1] 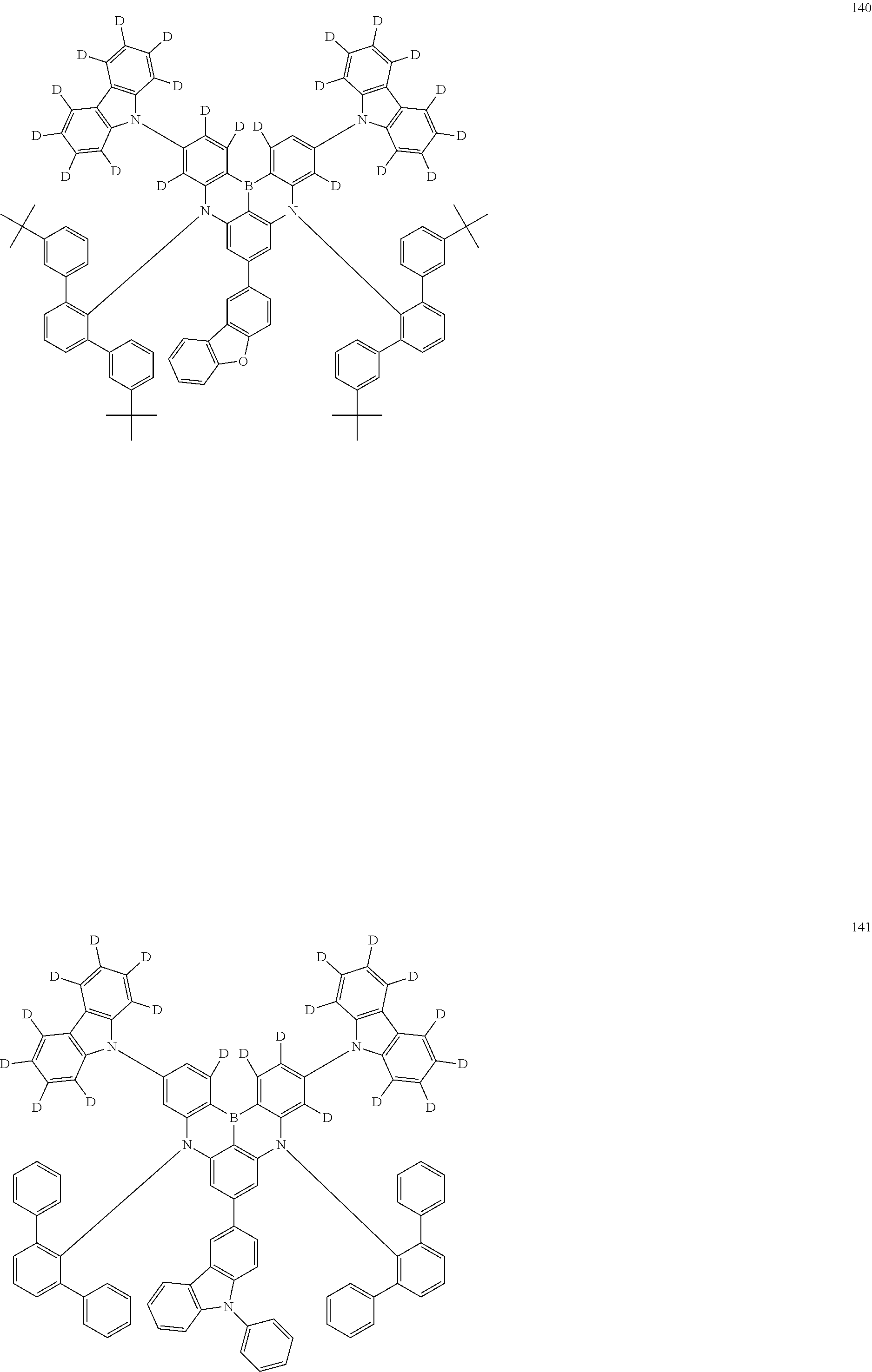 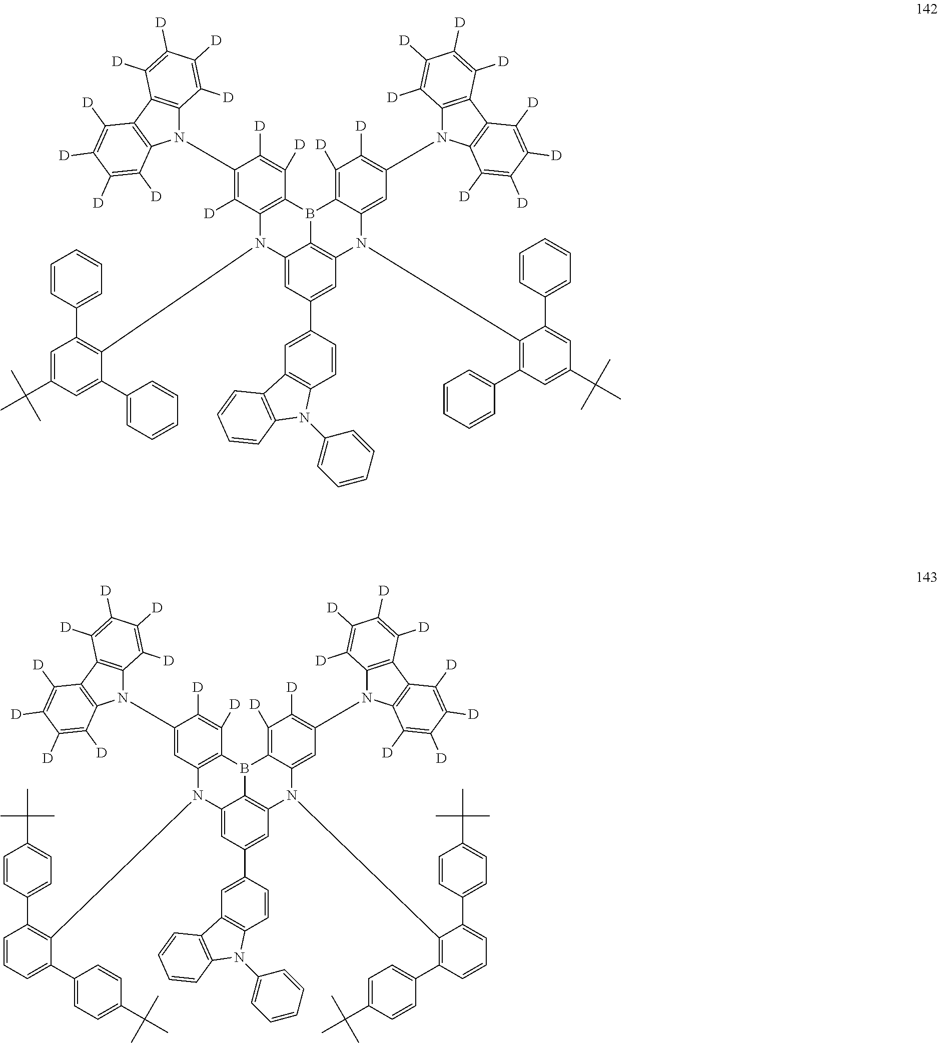 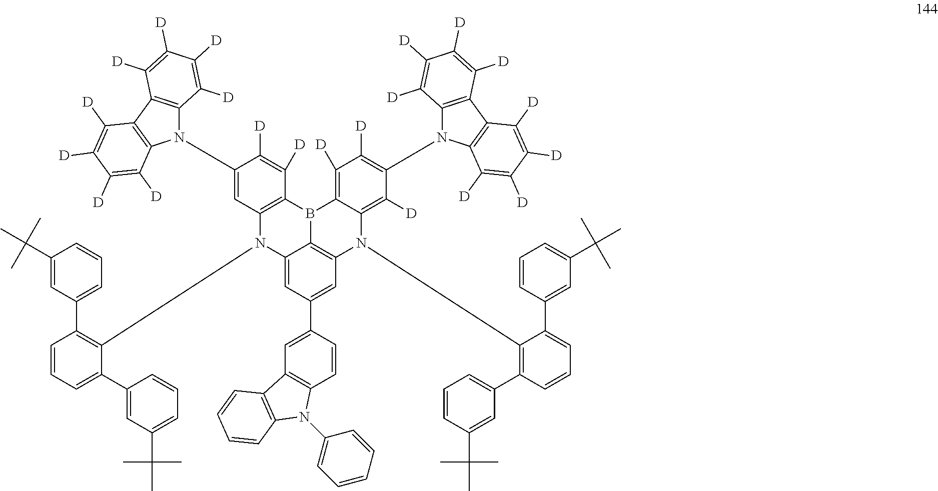 [SMILES: [2H]c1c(-n2c3c([2H])c([2H])c([2H])c([2H])c3c3c([2H])c([2H])c([2H])c([2H])c32)cc2c(c1[2H])B1c3c(cc(-c4ccc5c(c4)c4ccccc4n5-c4ccccc4)cc3N(c3c(-c4cccc(C(C)(C)C)c4)cccc3-c3cccc(C(C)(C)C)c3)c3c([2H])c(-n4c5c([2H])c([2H])c([2H])c([2H])c5c5c([2H])c([2H])c([2H])c([2H])c54)c([2H])c([2H])c31)N2c1c(-c2cccc(C(C)(C)C)c2)cccc1-c1cccc(C(C)(C)C)c1] 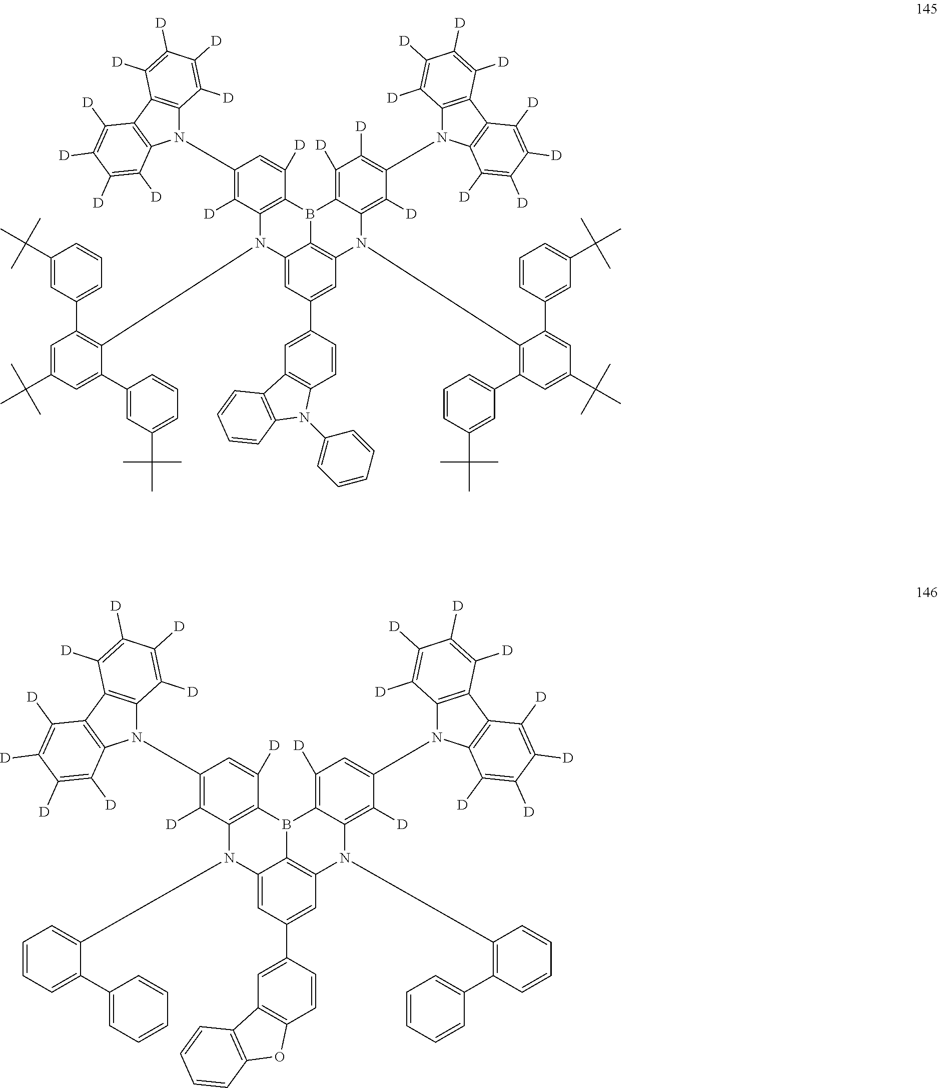 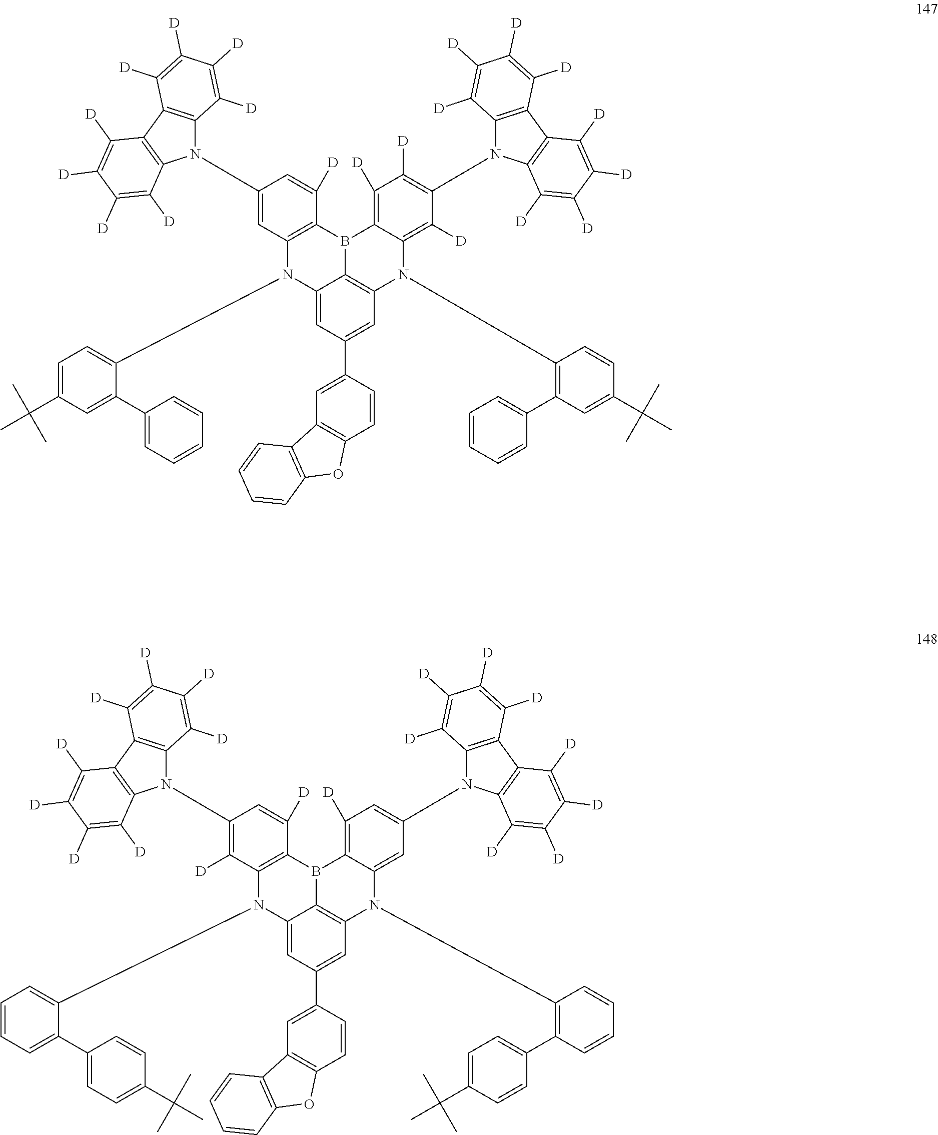 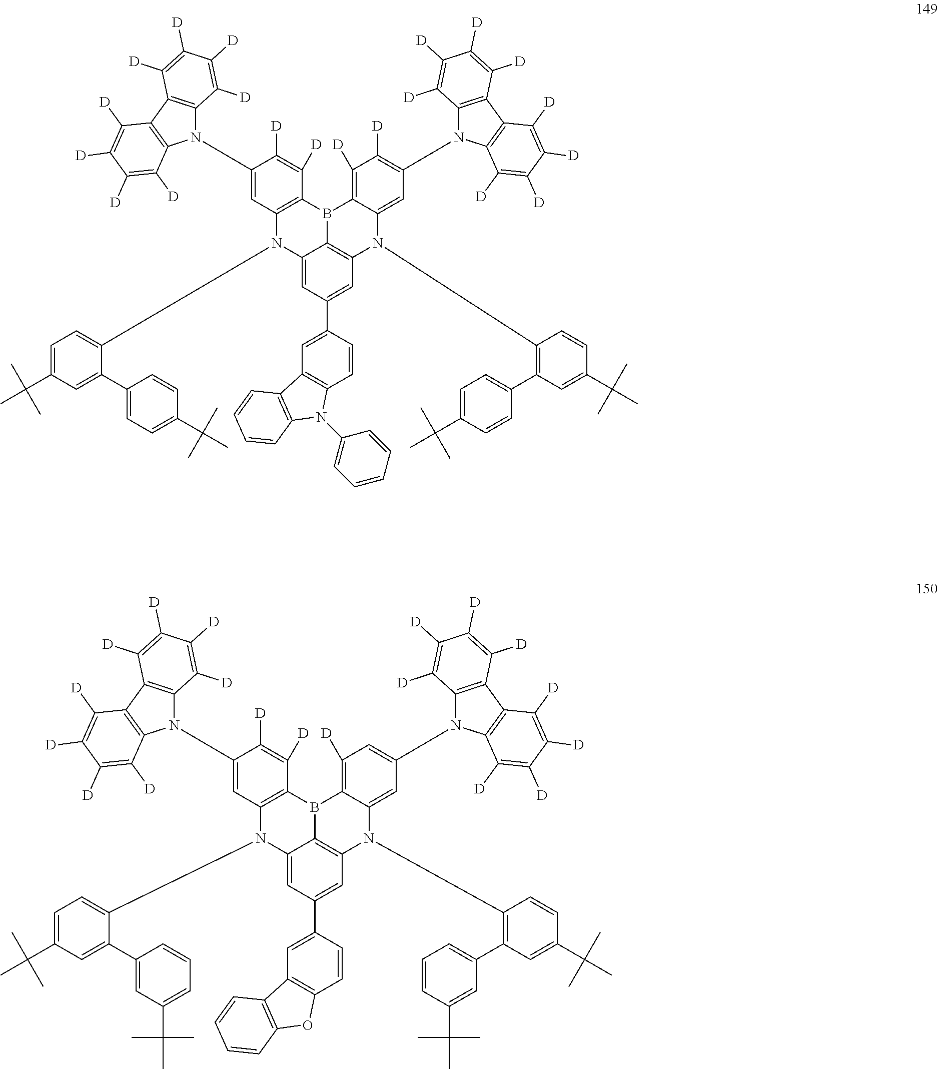 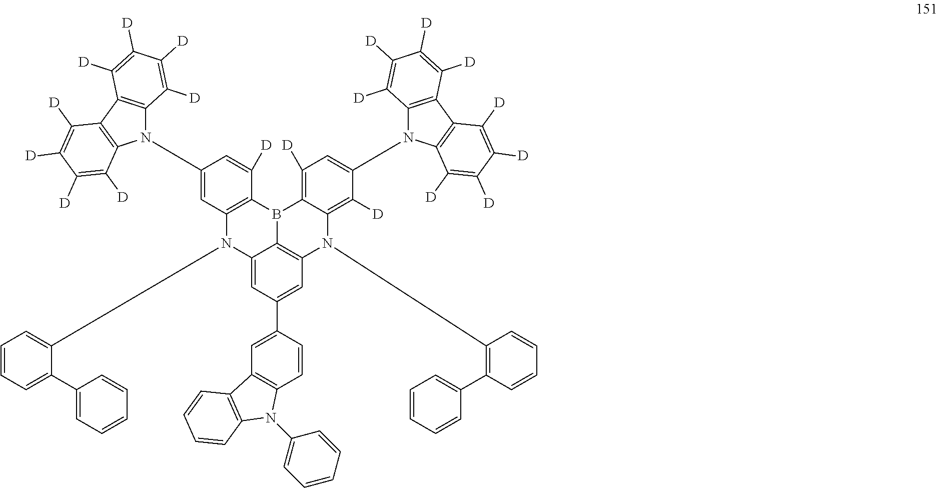 [SMILES: [2H]c1cc(-n2c3c([2H])c([2H])c([2H])c([2H])c3c3c([2H])c([2H])c([2H])c([2H])c32)cc2c1B1c3c(cc(-c4ccc5c(c4)c4ccccc4n5-c4ccccc4)cc3N(c3ccccc3-c3ccccc3)c3c([2H])c(-n4c5c([2H])c([2H])c([2H])c([2H])c5c5c([2H])c([2H])c([2H])c([2H])c54)cc([2H])c31)N2c1ccccc1-c1ccccc1] 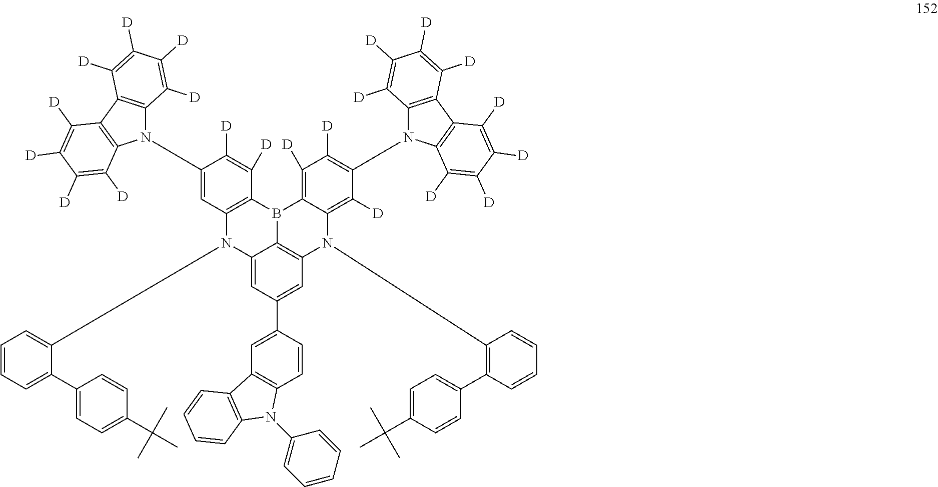 [SMILES: [2H]c1c(-n2c3c([2H])c([2H])c([2H])c([2H])c3c3c([2H])c([2H])c([2H])c([2H])c32)cc2c(c1[2H])B1c3c(cc(-c4ccc5c(c4)c4ccccc4n5-c4ccccc4)cc3N(c3ccccc3-c3ccc(C(C)(C)C)cc3)c3c([2H])c(-n4c5c([2H])c([2H])c([2H])c([2H])c5c5c([2H])c([2H])c([2H])c([2H])c54)c([2H])c([2H])c31)N2c1ccccc1-c1ccc(C(C)(C)C)cc1] 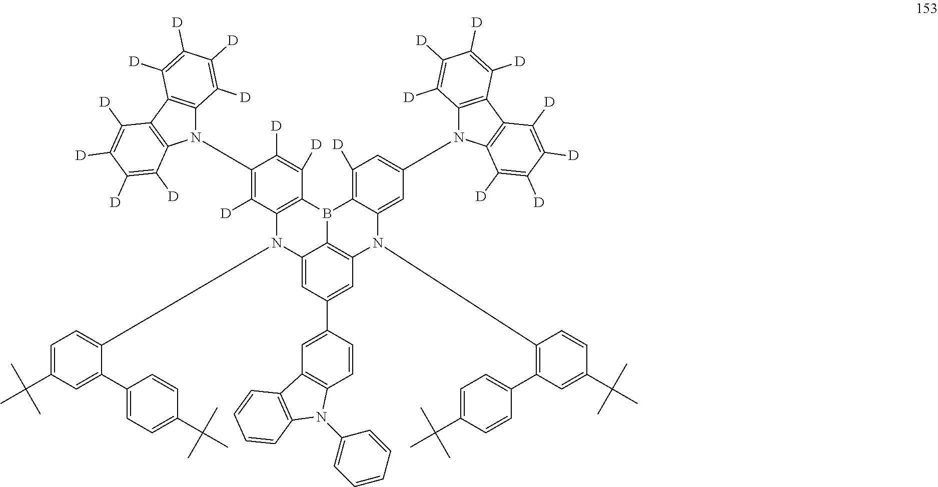 [SMILES: [2H]c1cc(-n2c3c([2H])c([2H])c([2H])c([2H])c3c3c([2H])c([2H])c([2H])c([2H])c32)cc2c1B1c3c(cc(-c4ccc5c(c4)c4ccccc4n5-c4ccccc4)cc3N(c3ccc(C(C)(C)C)cc3-c3ccc(C(C)(C)C)cc3)c3c([2H])c(-n4c5c([2H])c([2H])c([2H])c([2H])c5c5c([2H])c([2H])c([2H])c([2H])c54)c([2H])c([2H])c31)N2c1ccc(C(C)(C)C)cc1-c1ccc(C(C)(C)C)cc1] 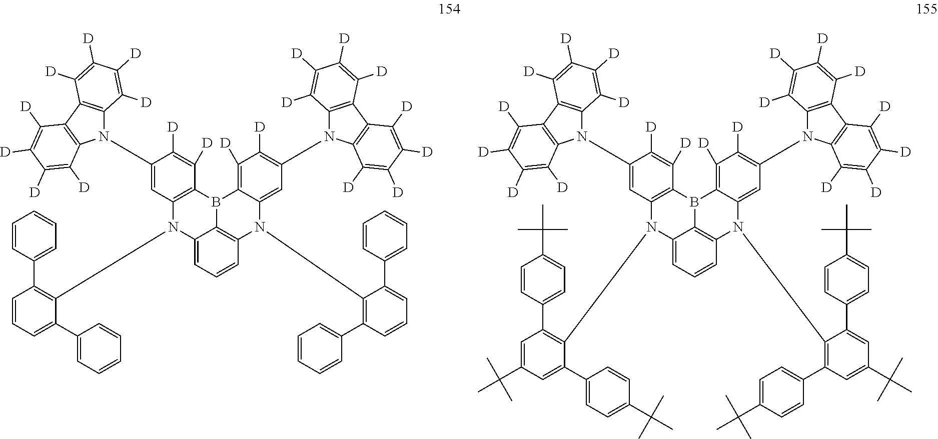 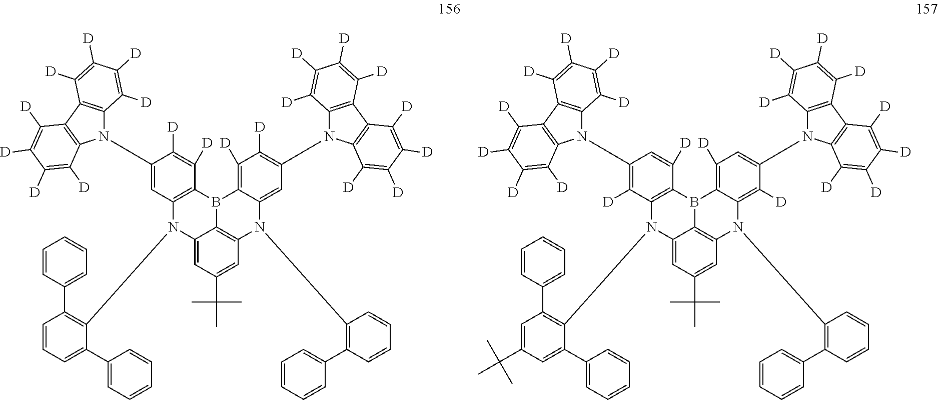 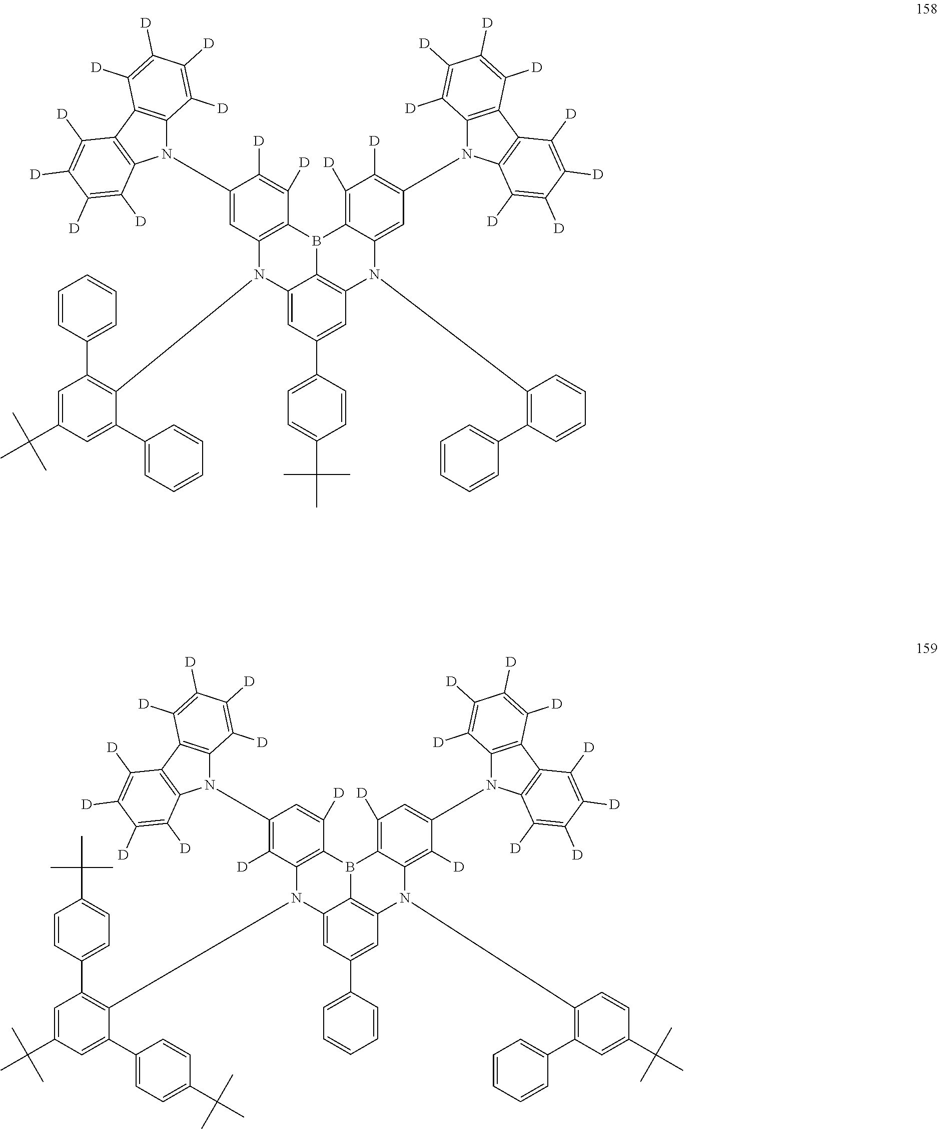 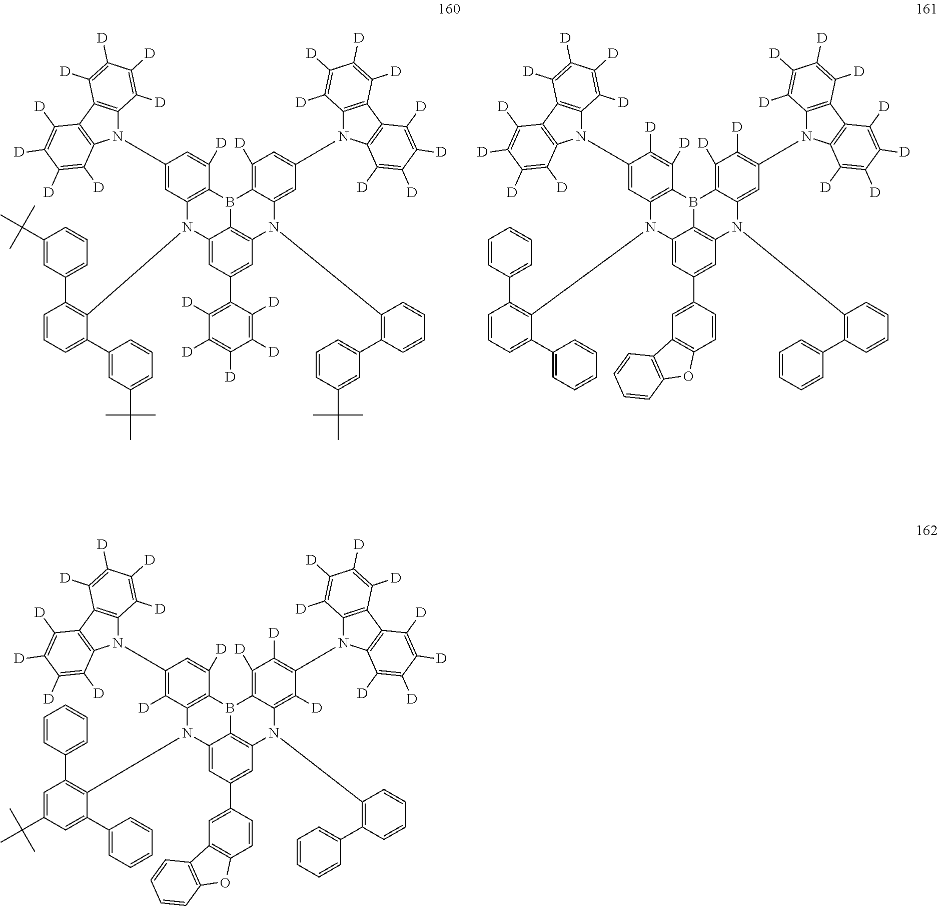 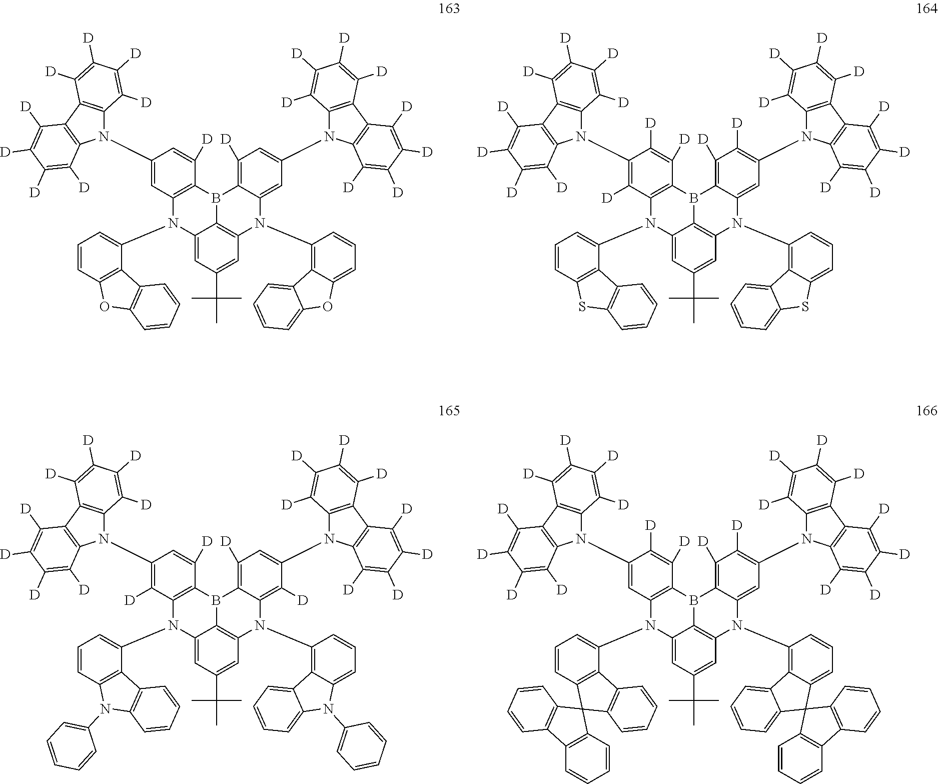 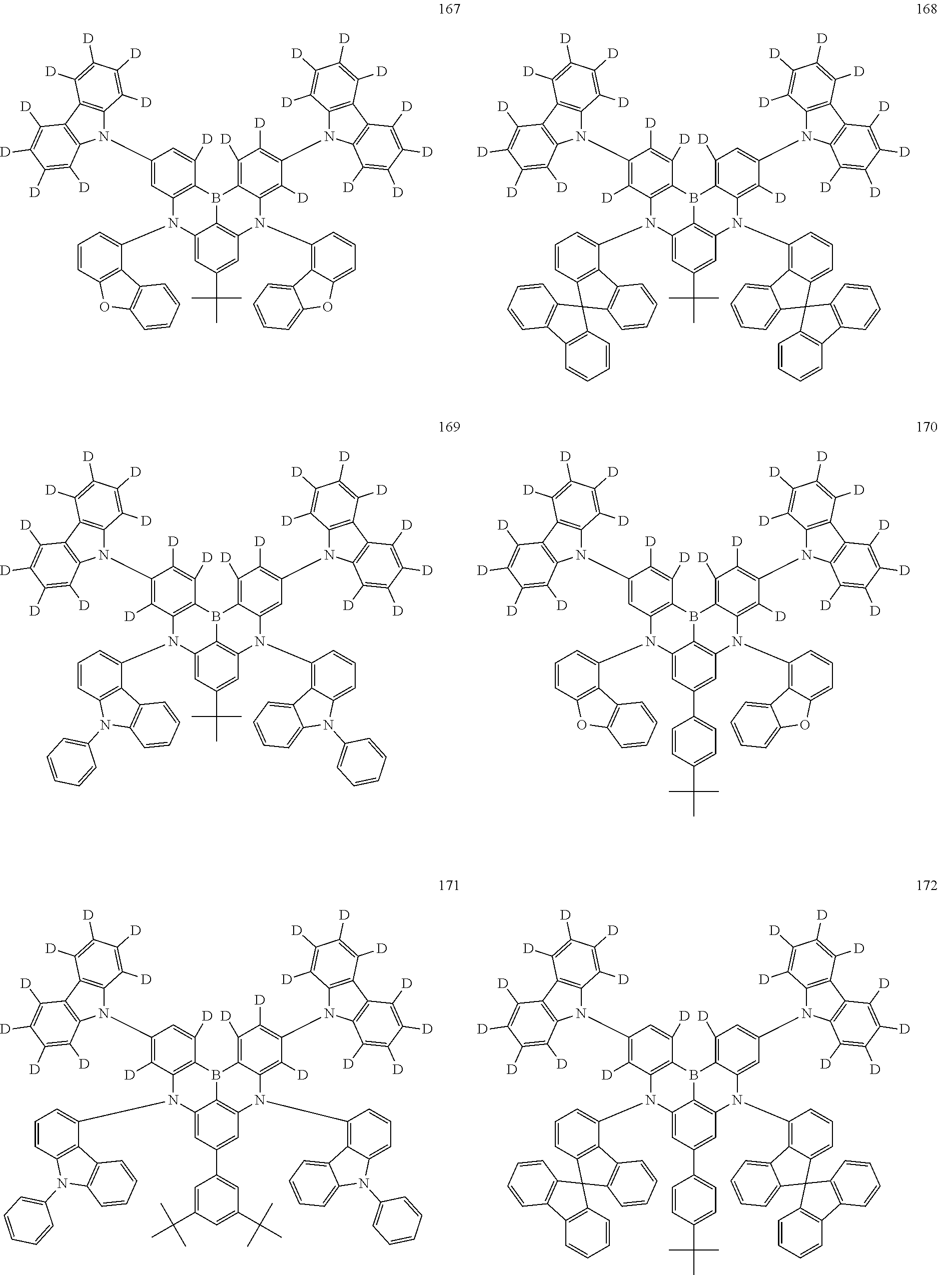 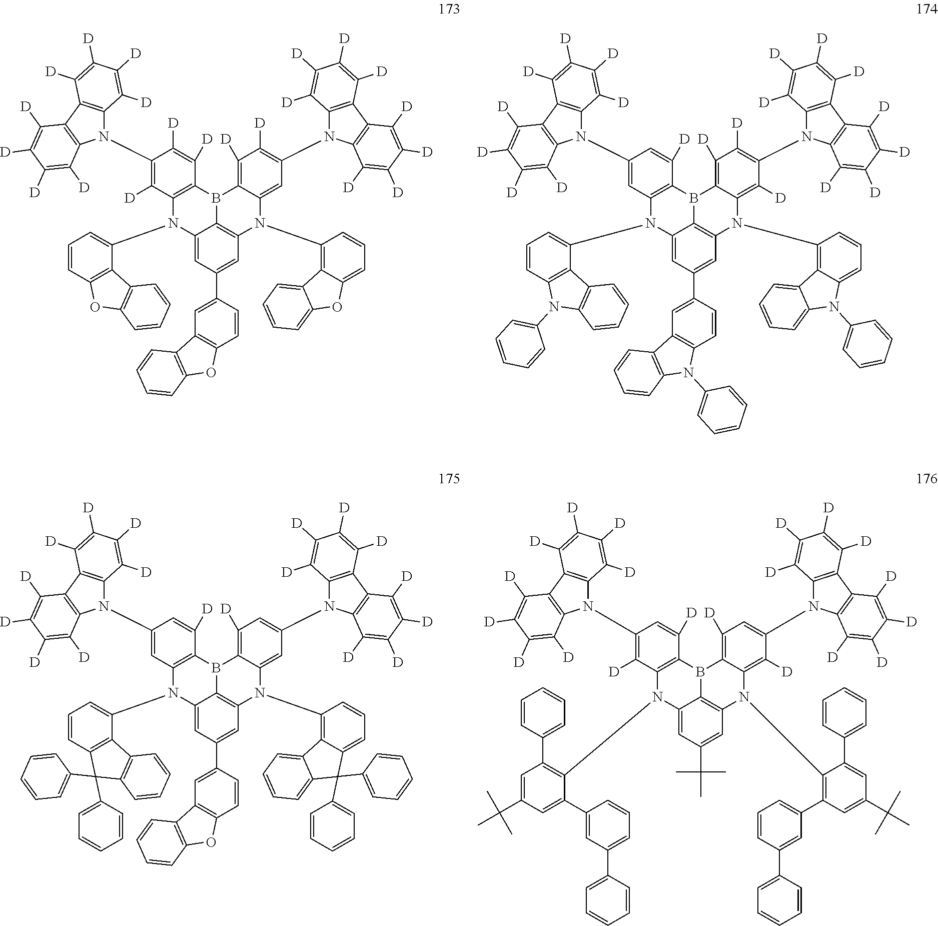 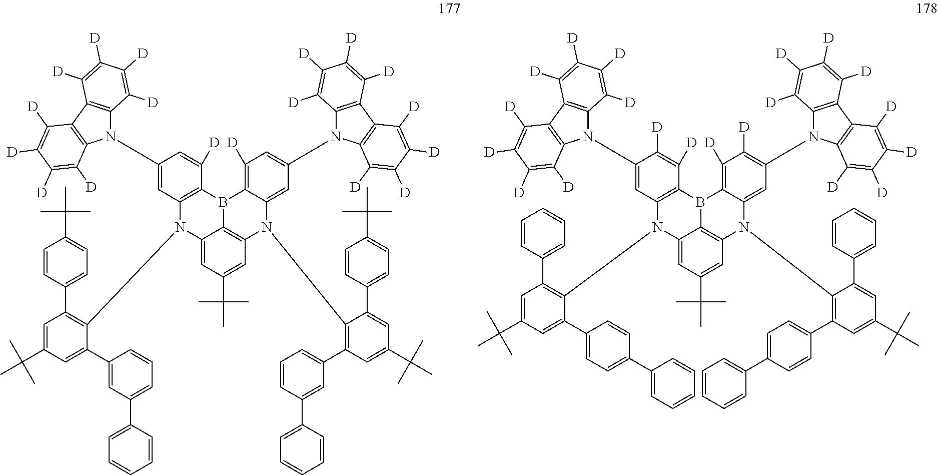
wherein in Compound Group 1,
D is a deuterium atom.

25. An electronic device comprising a display device including a plurality of light emitting elements, wherein
each of the plurality of light emitting elements comprises:
a first electrode;
a hole transport region disposed on an upper portion of the first electrode;
an emission layer disposed on an upper portion of the hole transport region;
an electron transport region disposed on an upper portion of the emission layer; and
a second electrode disposed on an upper portion of the electron transport region, and
the emission layer comprises a polycyclic compound represented by Formula 1: 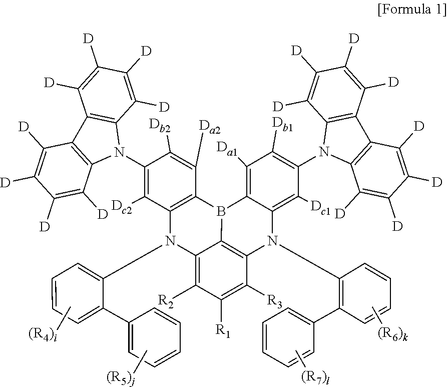
wherein in Formula 1,
D, Dₐ₁, and Dₐ₂ are each a deuterium atom,
D_{b1}, D_{b2}, D_{c1}, and D_{c2} are each independently a hydrogen atom or a deuterium atom,
R₁ to R₃ are each independently a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
R₄ to R₇ are each independently a hydrogen atom, a deuterium atom, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
i and k are each independently an integer from 0 to 4, and
j and l are each independently an integer from 0 to 5.

26. The electronic device of claim 25, wherein the electronic device is a vehicle, a television, a game console, a tablet, a smart phone, a camera, a laptop computer, a personal computer, a personal digital terminal, or an advertising board.
